(19) United States
(12) Patent Application Publication
(10) Pub. No.: US 2022/0102583 A1
(43) Pub. Date: Mar. 31, 2022

(54) µ-LED, µ-LED DEVICE, DISPLAY AND METHOD FOR THE SAME

(71) Applicant: OSRAM Opto Semiconductors GmbH, Regensburg (DE)

(72) Inventors: Thorsten BAUMHEINRICH, Altdorf (DE); Martin BEHRINGER, Regensburg (DE); Andreas BIEBERSDORF, Regensburg (DE); Ruth BOSS, Neutraubling (DE); Michael BRANDL, Mintraching (DE); Peter BRICK, Regensburg (DE); Jean-Jacques DROLET, Obertraubling (DE); Hubert HALBRITTER, Dietfurt-Toeging (DE); Laura KREINER, Regensburg (DE); Erwin LANG, Regensburg (DE); Andreas LEBER, Regensburg (DE); Tobias MEYER, Kelheim (DE); Alexander PFEUFFER, Regensburg (DE); Marc PHILIPPENS, Regensburg (DE); Jens RICHTER, Hemau (DE); Thomas SCHWARZ, Regensburg (DE); Paul TA, Fremont, CA (US); Tansen VARGHESE, Regensburg (DE); Xue WANG, Regensburg (DE); Sebastian WITTMANN, Regenstauf (DE); Julia STOLZ, Regensburg (DE); Karsten DIEKMANN, Rattenberg (DE); Karl ENGL, Niedergebraching (DE); Siegfried HERRMANN, Neukirchen (DE); Berthold HAHN, Hemau - Hohenschambach (DE); Stefan ILLEK, Donaustauf (DE); Bruno JENTZSCH, Regensburg (DE); Korbinian PERZLMAIER, Regensburg (DE); Ines PIETZONKA, Donaustauf (DE); Andreas RAUSCH, Tegernheim (DE); Kilian REGAU, Regensburg (DE); Tilman RUEGHEIMER, Regensburg (DE); Simon SCHWALENBERG, Brennberg (DE); Christopher SOELL, Veitsbronn (DE); Peter STAUSS, Regensburg (DE); Petrus SUNDGREN, Lappersdorf (DE); Hoa VU, Milpitas, CA (US); Christopher WIESMANN, Barbing (DE); Georg BOGNER, Hainsacker/Lappersdorf (DE); Patrick HOERNER, Regensburg (DE); Christoph KLEMP, Regensburg (DE); Jens MUELLER, Regensburg (DE); Kerstin NEVELING, Pentling (DE); Jong PARK, Sunnyvale, CA (US); Christine RAFAEL, Donaustauf (DE); Frank SINGER, Regenstauf (DE); Kanishk CHAND, Santa Clara, CA (US); Felix FEIX, Jena (DE); Christian MUELLER, Deuerling (DE); Eva-Maria RUMMEL, Regensburg (DE); Nicole HEITZER, Brennberg (DE); Marie ASSMANN, Kelheim (DE); Christian BERGER, Marburg (DE); Ana KANEVCE, Stuttgart (DE)

(21) Appl. No.: 17/426,456

(22) PCT Filed: Jan. 29, 2020
(86) PCT No.: PCT/EP2020/052191

§ 371 Date: Jul. 28, 2021

(30) Foreign Application Priority Data
Jan. 29, 2019 (DE) 10 2019 201 114.4
Jan. 29, 2019 (DK) PA201970059
Jan. 29, 2019 (DK) PA201970061
Jan. 31, 2019 (DE) 10 2019 102 509.5
Feb. 11, 2019 (DE) 10 2019 103 365.9
Mar. 29, 2019 (DE) 10 2019 108 260.9
Apr. 23, 2019 (DE) 10 2019 110 497.1
Apr. 23, 2019 (DE) 10 2019 110 499.8
Apr. 23, 2019 (DE) 10 2019 110 500.5
Apr. 23, 2019 (DE) 10 2019 110 523.4
May 7, 2019 (DE) 10 2019 111 766.6
May 7, 2019 (DE) 10 2019 111 767.4
May 9, 2019 (DE) 10 2019 112 124.8
May 13, 2019 (DE) 10 2019 112 490.5
May 14, 2019 (DE) 10 2019 112 604.5
May 14, 2019 (DE) 10 2019 112 605.3
May 14, 2019 (DE) 10 2019 112 609.6
May 14, 2019 (DE) 10 2019 112 616.9
May 14, 2019 (DE) 10 2019 112 639.8
May 22, 2019 (DE) 10 2019 113 636.9
May 23, 2019 (DE) 10 2019 113 768.3
May 23, 2019 (DE) 10 2019 113 791.8
May 23, 2019 (DE) 10 2019 113 792.6
May 23, 2019 (DE) 10 2019 113 793.4
May 28, 2019 (DE) 10 2019 114 321.7
May 29, 2019 (DE) 10 2019 114 442.6
Jun. 7, 2019 (DE) 10 2019 115 479.0
Jun. 12, 2019 (DE) 10 2019 115 991.1
Jun. 14, 2019 (DE) 10 2019 116 312.9
Jun. 14, 2019 (DE) 10 2019 116 313.7
Jul. 4, 2019 (DE) 10 2019 118 082.1
Jul. 4, 2019 (DE) 10 2019 118 084.8
Jul. 4, 2019 (DE) 10 2019 118 085.6
Jul. 5, 2019 (DE) 10 2019 118 251.4
Aug. 12, 2019 (DE) 10 2019 121 672.9
Sep. 20, 2019 (DE) 10 2019 125 336.5
Sep. 20, 2019 (DE) 10 2019 125 349.7
Sep. 25, 2019 (DE) 10 2019 125 875.8
Oct. 11, 2019 (DE) 10 2019 127 424.9
Oct. 11, 2019 (DE) 10 2019 127 425.7
Oct. 29, 2019 (DE) 10 2019 129 209.3
Nov. 14, 2019 (DE) 10 2019 130 821.6
Nov. 15, 2019 (DE) 10 2019 130 866.6
Nov. 15, 2019 (DE) 10 2019 130 934.4
Nov. 21, 2019 (DE) 10 2019 131 506.9
Nov. 29, 2019 (DK) PA201970060

(51) Int. Cl. H01L 33/38; H01L 27/15; H01L 25/075; H01L 21/683; H01L 33/06; H01L 33/18; H01L 33/30; H01L 33/40; H01L 33/42; H01L 33/50; G09G 3/32

(52) U.S. Cl. CPC H01L 33/38; H01L 27/156; H01L 25/0753; H01L 21/6835; H01L 33/06; H01L 33/18; G09G 2300/0842; H01L 33/405; H01L 33/42; H01L 33/50; G09G 3/32; H01L 2221/68354; H01L 2221/68368; H01L 33/30

(57) ABSTRACT

The invention relates to various aspects of a μ-LED or a μ-LED array for augmented reality or lighting applications, in particular in the automotive field. The μ-LED is characterized by particularly small dimensions in the range of a few μm.

This patent application claims the priorities of the German applications DE 10 2019 201 114.4 of 29 Jan. 2019, DE 10 2019 111 766.6 of 7 May 2019, DE 10 2019 112 124.8 of 9 May 2019, DE 10 2019 116 313.7 of 14 Jun. 2019, DE 10 2019 131 506.9 of 21 Nov. 2019, DE 10 2019 118 251.4 of 5 Jul. 2019, DE 10 2019 118 082.1 of 4 Jul. 2019, DE 10 2019 108 260.9 of 29 Mar. 2019, DE 10 2019 125 349.7 of 20 Sep. 2019, DE 10 2019 112 490.5 of 13 May 2019, DE 10 2019 112 604.5 of 14 May 2019, DE 10 2019 112 609.6 of 14 May 2019, DE 10 2019 102 509.5 of 31 Jan. 2019, DE 10 2019 115 479.0 of 7 Jun. 2019, DE 10 2019 112 616.9 of 14 May 2019, DE 10 2019 113 791.8 of 23 May 2019, DE 10 2019 110 499.8 of 23 Apr. 2019, DE 10 2019 110 523.4 of 23 Apr. 2019, DE 10 2019 130 934.4 of 15 Nov. 2019, DE 10 2019 114 321.7 of 28 May 2019, DE 10 2019 127 425.7 of 11 Oct. 2019, DE 10 2019 112 639.8 of 14 May 2019, DE 10 2019 112 605.3 of 14 May 2019, DE 10 2019 113 636.9 of 22 May 2019, DE 10 2019 103 365.9 of 11 Feb. 2019, DE 10 2019 116 312.9 of 14 Jun. 2019, DE 10 2019 115 991.1 of 12 Jun. 2019, DE 10 2019 125 875.8 of 25 Sep. 2019, DE 10 2019 127 424.9 of 11 Oct. 2019, DE 10 2019 118 085.6 of 4 Jul. 2019, DE 10 2019 125 336.5 of 20 Sep. 2019, DE 10 2019 113 793.4 of 23 May 2019, DE 10 2019 110 500.5 of 23 Apr. 2019, DE 10 2019 111 767.4 of 7 May 2019, DE 10 2019 121 672.9 of 12 Aug. 2019, DE 10 2019 118 084.8 of 4 Jul. 2019, DE 10 2019 113 768.3 of 23 May 2019, DE 10 2019 113 792.6 of 23 May 2019, DE 10 2019 110 497.1 of 23 Apr. 2019, DE 10 2019 114 442.6 of 29 May 2019, DE 10 2019 129 209.3 of 29 Oct. 2019, DE 10 2019 130 821.6 of 14 Nov. 2019 and DE 10 2019 130 866.6 of 15 Nov. 2019, the disclosures of which are incorporated herein by way of reference, as well as the priorities of the Danish applications DK PA201970059 of 29 Jan. 2019, DK PA201970060 of 29 Nov. 2019 and DK PA201970061 of 29 Jan. 2019, the disclosure of which are incorporated herein by way of reference, as well as the priority of U.S. application U.S. 62/937,552 of 19 Nov. 2019, the disclosure of which is hereby incorporated by way of reference.

### BACKGROUND

The ongoing current developments within the Internet of Things and the field of communication have opened the door for various new applications and concepts. For development, service and manufacturing purposes, these concepts and applications offer increased effectiveness and efficiency.

One aspect of new concepts is based on augmented or virtual reality. A general definition of “augmented reality” is given by an “interactive experience of the real environment, whereby the objects from it, which are in the real world, are augmented by computer generated perceptible information”.

The information is mostly transported by visualization, but is not limited to visual perception. Sometimes haptic or other sensory perceptions can be used to expand reality. In the case of visualization, the superimposed sensory-visual information can be constructive, i.e. additional to the natural environment, or it can be destructive, for example by obscuring parts of the natural environment. In some applications, it is also possible to interact with the superimposed sensory information in one way or another. In this way, augmented reality reinforces the ongoing perception of the user of the real environment.

In contrast, “virtual reality” completely replaces the real environment of the user with an environment that is completely simulated. In other words, while in an augmented reality environment the user is able to perceive the real world at least partially, in a virtual reality the environment is completely simulated and may differ significantly from reality.

Augmented Reality can be used to improve natural environmental situations, enriching the user's experience or supporting the user in performing certain tasks. For example, a user may use a display with augmented reality features to assist him in performing certain tasks. Because information about a real object is superimposed to provide clues to the user, the user is supported with additional information, allowing the user to act more quickly, safely and effectively during manufacturing, repair or other services. In the medical field, augmented reality can be used to guide and support the doctor in diagnosing and treating the patient. In development, an engineer may experience the results of his experiments directly and can therefore evaluate the results more easily. In the tourism or event industry, augmented reality can provide a user with additional information about sights, history, and the like. Augmented Reality can support the learning of activities or tasks.

### SUMMARY

In the following summary different aspects for μ-displays in the automotive and augmented reality applications are explained. This includes devices, displays, controls, process engineering methods and other aspects suitable for augmented reality and automotive applications. This includes aspects which are directed to light generation by means of displays, indicators or similar. In addition, control circuits, power supplies and aspects of light extraction, light guidance and focusing as well as applications of such devices are listed and explained by means of various examples.

Because of the various limitations and challenges posed by the small size of the light-generating components, a combination of the various aspects is not only advantageous, but often necessary. For ease of reference, this disclosure is divided into several sections with similar topics. However, this should explicitly not be understood to mean that features from one topic cannot be combined with others. Rather, aspects from different topics should be combined to create a display for augmented reality or other applications or even in the automotive sector.

For considerations of the following solutions, some terms and expressions should be explained in order to define a common and equal understanding. The terms listed are generally used with this understanding in this document. In individual cases, however, there may be deviations from the interpretation, whereby such deviation will be specifically referred to.

### “Active Matrix Display”

The term “active matrix display” was originally used for liquid crystal displays containing a matrix of thin film transistors that drive LCD pixels. Each individual pixel has a circuit with active components (usually transistors) and power supply connections. At present, however, this technology should not be limited to liquid crystals, but should also be used in particular for driving μ-LEDs or μ-displays.

### “Active Matrix Carrier Substrate”

“Active matrix carrier substrate” or “active matrix backplane” means a drive for light emitting diodes of a display with thin-film transistor circuits. The circuits may be integrated into the backplane or mounted on it. The “active matrix carrier substrate” has one or more interface contacts, which form an electrical connection to a μ-LED display structure. An “active-matrix carrier substrate” can thus be part of an active-matrix display or support it.

“Active Layer”

The active layer is referred to as the layer in an optoelectronic component or light emitting diode in which charge carriers recombine. In its simplest form, the active layer can be characterized by a region of two adjacent semiconductor layers of different conductivity type. More complex active layers comprise quantum wells (see there), multi-quantum wells or other structures that have additional properties. Similarly, the structure and material systems can be used to adjust the band gap (see there) in the active layer, which determines the wavelength and thus the color of the light.

### “Alvarez Lens Array”

With the use of Alvarez lens pairs, a beam path can be adapted to video eyewear. An adjustment optic comprises an Alvarez lens arrangement, in particular a rotatable version with a Moire lens arrangement. Here, the beam deflection is determined by the first derivative of the respective phase plate relief, which is approximated, for example, by z=ax2+by2+cx+dy+e for the transmission direction z and the transverse directions x and y, and by the offset of the two phase plates arranged in pairs in the transverse directions x and y. For further design alternatives, swivelling prisms are provided in the adjustment optics.

### “Augmented Reality (AR)”

This is an interactive experience of the real environment, where the subject of the picking up is located in the real world and is enhanced by computer-generated perceptible information. Extended reality is the computer-aided extension of the perception of reality by means of this computer-generated perceptible information. The information can address all human sensory modalities. Often, however, augmented reality is only understood to be the visual representation of information, i.e. the supplementation of images or videos with computer-generated additional information or virtual objects by means of fade-in/overlay. Applications and explanations of the mode of operation of Augmented Reality can be found in the introduction and in the following in execution examples.

### “Automotive.”

Automotive generally refers to the motor vehicle or automobile industry. This term should therefore cover this branch, but also all other branches of industry which include μ-displays or generally light displays—with very high resolution and μ-LEDs.

### “Bandgap”

Bandgap, also known as band gap or forbidden zone, is the energetic distance between the valence band and conduction band of a solid-state body. Its electrical and optical properties are largely determined by the size of the band gap. The size of the band gap is usually specified in electron volts (eV). The band gap is thus also used to differentiate between metals, semiconductors and insulators. The band gap can be adapted, i.e. changed, by various measures such as spatial doping, deforming of the crystal lattice structure or by changing the material systems. Material systems with so-called direct band gap, i.e. where the maximum of the valence band and a minimum of the conduction band in the pulse space are superimposed, allow a recombination of electron-hole pairs under emission of light.

### “Bragg Grid”

Fibre Bragg gratings are special optical interference filters inscribed in optical fibres. Wavelengths that lie within the filter bandwidth around AB are reflected. In the fiber core of an optical waveguide, a periodic modulation of the refractive index is generated by means of various methods. This creates areas with high and low refractive indexes that reflect light of a certain wavelength (bandstop). The center wavelength of the filter bandwidth in single-mode fibers results from the Bragg condition.

### “Directionality”

Directionality is the term used to describe the radiation pattern of a μ-LED or other light-emitting device. A high directionality corresponds to a high directional radiation, or a small radiation cone. In general, the aim should be to obtain a high directional radiation so that crosstalk of light into adjacent pixels is avoided as far as possible. Accordingly, the light-emitting component has a different brightness depending on the viewing angle and thus differs from a Lambert emitter.

The directionality can be changed by mechanical measures or other measures, for example on the side intended for the emission. In addition to lenses and the like, this includes photonic crystals or pillar structures (columnar structures) arranged on the emitting surface of a pixelated array or on an arrangement of, in particular, μ-LEDs. These generate a virtual band gap that reduces or prevents the propagation of a light vector along the emitting surface.

### “Far Field”

The terms near field and far field describe spatial areas around a component emitting an electromagnetic wave, which differ in their characterization. Usually the space regions are divided into three areas: reactive near field, transition field and far field. In the far field, the electromagnetic wave propagates as a plane wave independent of the radiating element.

### “Fly Screen Effect”

The Screen Door Effect (SDE) is a permanently visible image artefact in digital video projectors. The term fly screen effect describes the unwanted black space between the individual pixels or their projected information, which is caused by technical reasons, and takes the form of a fly screen. This distance is due to the construction, because between the individual LCD segments run the conductor paths for control, where light is swallowed and therefore cannot hit the screen. If small optoelectronic lighting devices and especially μ-LEDs are used or if the distance between individual light emitting diodes is too great, the resulting low packing density leads to possibly visible differences between pointy illuminated and dark areas when viewing a single pixel area. This so-called fly screen effect (screen door effect) is particularly noticeable at a short viewing distance and thus especially in applications such as VR glasses. Sub-pixel structures are usually perceived and perceived as disturbing when the illumination difference within a pixel continues periodically across the matrix arrangement. Accordingly, the fly screen effect in automotive and augmented reality applications should be avoided as far as possible.

### “Flip Chip”

Flip-chip assembly is a process of assembly and connection technology for contacting unpackaged semiconductor chips by means of contact bumps, or short “bumps”. In flip-chip mounting, the chip is mounted directly, without any further connecting wires, with the active contacting side down—towards the substrate/circuit carrier—via the bumps. This results in particularly small package dimensions and short conductor lengths. A flip-chip is thus in particular an electronic semiconductor component contacted on its rear side. The mounting may also require special transfer techniques, for example using an auxiliary carrier. The radiation direction of a flip chip is then usually the side opposite the contact surfaces.

### “Flip-flop”

A flip-flop, often called a bi-stable flip-flop or bi-stable flip-flop element, is an electronic circuit that has two stable states of the output signal. The current state depends not only on the input signals present at the moment, but also on the state that existed prior to the time under consideration. A dependence on time does not exist, but only on events. Due to the bi-stability, the flip-flop can store a data quantity of a single bit for an unlimited time. In contrast to other types of storage, however, power supply must be permanently guaranteed. The flip-flop, as the basic component of sequential circuits, is an indispensable component of digital technology and thus a fundamental component of many electronic circuits, from quartz watches to microprocessors. In particular, as an elementary one-bit memory, it is the basic element of static memory components for computers. Some designs can use different types of flip-flops or other buffer circuits to store state information. Their respective input and output signals are digital, i.e. they alternate between logical “false” and logical “true”. These values are also known as “low” 0 and “high” 1.

### “Head-Up Display”

The head-up display is a display system or projection device that allows users to maintain their head position or viewing direction by projecting information into their field of vision. The Head-up Display is an augmented reality system. In some cases, a Head-Up Display has a sensor to determine the direction of vision or orientation in space.

### “Horizontal Light Emitting Diode”

With horizontal LEDs, the electrical connections are on a common side of the LED. This is often the back of the LED facing away from the light emission surface. Horizontal LEDs therefore have contacts that are only formed on one surface side.

### “Interference Filter”

Interference filters are optical components that use the effect of interference to filter light according to frequency, i.e. color for visible light.

### “Collimation”

In optics, collimation refers to the parallel direction of divergent light beams. The corresponding lens is called collimator or convergent lens. A collimated light beam contains a large proportion of parallel rays and is therefore minimally spread when it spreads. A use in this sense refers to the spreading of light emitted by a source. A collimated beam emitted from a surface has a strong dependence on the angle of radiation. In other words, the radiance (power per unit of a fixed angle per unit of projected source area) of a collimated light source changes with increasing angle. Light can be collimated by a number of methods, for example by using a special lens placed in front of the light source. Consequently, collimated light can also be considered as light with a very high directional dependence.

### “Converter Material”

Converter material is a material, which is suitable for converting light of a first wavelength into a second wavelength. The first wavelength is shorter than the second wavelength. This includes various stable inorganic as well as organic dyes and quantum dots. The converter material can be applied and structured in various processes.

### “Lambert Lamps”

For many applications, a so-called Lambertian radiation pattern is required. This means that a light-emitting surface ideally has a uniform radiation density over its area, resulting in a vertically circular distribution of radiant intensity. Since the human eye only evaluates the luminance (luminance is the photometric equivalent of radiance), such a Lambertian material appears to be equally bright regardless of the direction of observation. Especially for curved and flexible display surfaces, this uniform, angle-independent brightness can be an important quality factor that is sometimes difficult to achieve with currently available displays due to their design and LED technology.

LEDs and μ-LEDs resemble a Lambert spotlight and emit light in a large spatial angle. Depending on the application, further measures are taken to improve the radiation characteristics or to achieve greater directionality (see there).

### “Conductivity Type”

The term “conductivity type” refers to the majority of (n- or p-) charge carriers in a given semiconductor material. In other words, a semiconductor material that is n-doped is considered to be of n-type conductivity. Accordingly, if a semiconductor material is n-type, then it is n-doped. The term “active” region in a semiconductor refers to a border region in a semiconductor between an n-doped layer and a p-doped layer. In this region, a radiative recombination of p- and n-type charge carriers takes place. In some designs, the active region is still structured and includes, for example, quantum well or quantum dot structures.

### “Light Field Display”

Virtual retinal display (VNA) or light field display is referred to a display technology that draws a raster image directly onto the retina of the eye. The user gets the impression of a screen floating in front of him. A light field display can be provided in the form of glasses, whereby a raster image is projected directly onto the retina of a user's eye. In the virtual retina display, a direct retinal projection creates an image within the user's eye. The light field display is an augmented reality system.

### “Lithography” or “Photolithography”

Photolithography is one of the central methods of semiconductor and microsystem technology for the production of integrated circuits and other products. The image of a photomask is transferred onto a photosensitive photoresist by means of exposure. Afterwards, the exposed areas of the photoresist are dissolved (alternatively, the unexposed areas can be dissolved if the photoresist is cured under light). This creates a lithographic mask that allows further processing by chemical and physical processes, such as applying material to the open areas or etching depressions in the open areas. Later, the remaining photoresist can also be removed.

### “μ-LED”

A μ-LED is an optoelectronic component whose edge lengths are less than 70 μm, especially down to less than 20 μm, especially in the range of 1 μm to 10 μm. Another range is between 10 to 30 μm. This results in an area of a few hundred μm² down to several tens of μm². For example, a μ-LED can comprise an area of about 60 μm² with an edge length of about 8 μm. In some cases, a μ-LED has an edge length of 5 μm or less, resulting in a size of less than 30 μm². Typical heights of such μ-LEDs are, for example, in the range of 1.5 μm to 10 μm.

In addition to classic lighting applications, displays are the main applications for μ-LEDs. The μ-LEDs form pixels or subpixels and emit light of a defined color. Due to their small pixel size and high density with a small pitch, μ-LEDs are suitable for small monolithic displays for AR applications, among other things.

Due to the above-mentioned very small size of a μ-LED, the production and processing is significantly more difficult compared to previous larger LEDs. The same applies to additional elements such as contacts, package, lenses etc. Some aspects that can be realized with larger optoelectronic components cannot be produced with μ-LEDs or only in a different way. In this respect, a μ-LED is therefore significantly different from a conventional LED, i.e. a light emitting device with an edge length of 200 μm or more.

### “μ-LED Array”

See at μ-Display

### “μ-Display”

A μ-display or μ-LED array is a matrix with a plurality of pixels arranged in defined rows and columns. With regard to its functionality, a μ-LED array often forms a matrix of μ-LEDs of the same type and color. Therefore, it rather provides a lighting surface. The purpose of a μ-display, on the other hand, is to transmit information, which often results in the demand for different colors or an addressable control for each individual pixel or subpixel. A μ-display can be made up of several μ-LED arrays, which are arranged together on a backplane or other carrier. Likewise, a μ-LED array can also form a μ-Display.

The size of each pixel is in the order of a few μm, similar to μ-LEDs. Consequently, the overall dimension of a μ display with 1920*1080 pixels with a μ-LED size of 5 μm per pixel and directly adjacent pixels is in the order of a few 10 mm². In other words, a μ-display or μ-LED array is a small-sized arrangement, which is realized by means of μ-LEDs.

μ-displays or μ-LED arrays can be formed from the same, i.e. from one work piece. The μ-LEDs of the μ-LED array can be monolithic. Such μ-displays or μ-LED arrays are called monolithic μ-LED arrays or μ-displays.

Alternatively, both assemblies can be formed by growing μ-LEDs individually on a substrate and then arranging them individually or in groups on a carrier at a desired distance from each other using a so-called Pick & Place process. Such μ-displays or μ-LED arrays are called non-monolithic. For non-monolithic μ-displays or μ-LED arrays, other distances between individual μ-LEDs are also possible. These distances can be chosen flexibly depending on the application and design. Thus, such μ-displays or μ-LED arrays can also be called pitch-expanded. In the case of pitch-expanded μ-displays or μ-LED arrays, this means that the μ-LEDs are arranged at a greater distance than on the growth substrate when transferred to a carrier. In a non-monolithic μ-display or μ-LED array, each individual pixel can comprise a blue light-emitting μ-LED and a green light-emitting μ-LED as well as a red light-emitting μ-LED.

To take advantage of different advantages of monolithic μ-LED arrays and non-monolithic μ-LED arrays in a single module, monolithic μ-LED arrays can be combined with non-monolithic μ-LED arrays in a μ-display. Thus, μ-displays can be used to realize different functions or applications. Such a display is called a hybrid display.

### “μ-LED Nano Column”

A μ-LED nano column is generally a stack of semiconductor layers with an active layer, thus forming a μ-LED. The μ-LED nano column has an edge length smaller than the height of the column. For example, the edge length of a μ-LED nanopillar is approximately 10 nm to 300 nm, while the height of the device can be in the range of 200 nm to 1 μm or more.

“μ-rod”

μ-rod or Rod designates in particular a geometric structure, in particular a rod or bar or generally a longitudinally extending, for example cylindrical, structure. μ-rods are produced with spatial dimensions in the μm to nanometer range. Thus, nanorods are also included here.

### “Nanorods”

In nanotechnology, nanorods are a design of nanoscale objects. Each of their dimensions is in the range of about 10 nm to 500 nm. They may be synthesized from metal or semiconducting materials. Aspect ratios (length divided by width) are 3 to 5. Nanorods are produced by direct chemical synthesis. A combination of ligands acts as a shape control agent and attaches to different facets of the nanorod with different strengths. This allows different shapes of the nanorod with different growth rates to produce an elongated object. μLED nanopillars are such nanorods.

### “Miniature LED”

Their dimensions range from 100 μm to 750 μm, especially in the range larger than 150 μm.

### “Moiré Effect” and “Moiré Lens Arrangement”

The moiré effect refers to an apparent coarse raster that is created by overlaying regular, finer rasters. The resulting pattern, whose appearance is similar to patterns resulting from interference, is a special case of the aliasing effect by subsampling. In the field of signal analysis, aliasing effects are errors that occur when the signal to be sampled contains frequency components that are higher than half the sampling frequency. In image processing and computer graphics, aliasing effects occur when images are scanned and result in patterns that are not included in the original image. A moire lens array is a special case of an Alvarez lens array.

### “Monolithic Construction Element”

A monolithic construction element is a construction element made of one piece. A typical such device is for example a monolithic pixel array, where the array is made of one piece and the μ-LEDs of the array are manufactured together on one carrier.

### “Optical Mode”

A mode is the description of certain temporally stationary properties of a wave. The wave is described as the sum of different modes. The modes differ in the spatial distribution of the intensity. The shape of the modes is determined by the boundary conditions under which the wave propagates. The analysis according to vibration modes can be applied to both standing and continuous waves. For electromagnetic waves, such as light, laser and radio waves, the following types of modes are distinguished: TEM or transverse electromagnetic mode, TE or H modes, TM or E modes. TEM or transverse electromagnetic mode: Both the electric and the magnetic field components are always perpendicular to the direction of propagation. This mode is only propagation-capable if either two conductors (equipotential surfaces) insulated from each other are available, for example in a coaxial cable, or no electrical conductor is available, for example in gas lasers or optical fibers. TE or H modes: Only the electric field component is perpendicular to the direction of propagation, while the magnetic field component is in the direction of propagation. TM or E modes: Only the magnetic field component is perpendicular to the propagation direction, while the electric field component points in the propagation direction.

### “Optoelectronic Device”

An optoelectronic component is a semiconductor body that generates light by recombination of charge carriers during operation and emits it. The light generated can range from the infrared to the ultraviolet range, with the wavelength depending on various parameters, including the material system used and doping. An optoelectronic component is also called a light emitting diode.

For the purpose of this disclosure, the term optoelectronic device or also light-emitting device is used synonymously. A μ-LED (see there) is thus a special optoelectronic device with regard to its geometry. In displays, optoelectronic components are usually monolithic or as individual components placed on a matrix.

### “Passive Matrix Backplane” or “Passive Matrix Carrier Substrate”

A passive matrix display is a matrix display, in which the individual pixels are driven passively (without additional electronic components in the individual pixels). A light emitting diode of a display can be controlled by means of IC circuits. In contrast, displays with active pixels driven by transistors are referred to as active matrix displays. A passive matrix carrier substrate is part of a passive matrix display and carries it.

### “Photonic Crystal” or “Photonic Structure”

A photonic structure can be a photonic crystal, a quasi-periodic or deterministically aperiodic photonic structure. The photonic structure generates a band structure for photons by a periodic variation of the optical refractive index. This band structure can comprise a band gap in a certain frequency range. As a result, photons cannot propagate through the photonic structure in all spatial directions. In particular, propagation parallel to a surface is often blocked, but perpendicular to it is possible. In this way, the photonic structure or the photonic crystal determines a propagation in a certain direction. It blocks or reduces this in one direction and thus generates a beam or a bundle of rays of radiation directed as required into the room or radiation area provided for this purpose.

Photonic crystals are photonic structures occurring or created in transparent solids. Photonic crystals are not necessarily crystalline—their name derives from analogous diffraction and reflection effects of X-rays in crystals due to their lattice constants. The structure dimensions are equal to or greater than a quarter of the corresponding wavelength of the photons, i.e. they are in the range of fractions of a μm to several μm. They are produced by classical lithography or also by self-organizing processes.

Similar or the same property of a photonic crystal can alternatively be produced with non-periodic but nevertheless ordered structures. Such structures are especially quasiperiodic structures or deterministically aperiodic structures. These can be for example spiral photonic arrangements.

In particular, so-called two-dimensional photonic crystals are mentioned here as examples, which exhibit a periodic variation of the optical refractive index in two mutually perpendicular spatial directions, especially in two spatial directions parallel to the light-emitting surface and perpendicular to each other.

However, there are also one-dimensional photonic structures, especially one-dimensional photonic crystals. A one-dimensional photonic crystal exhibits a periodic variation of the refractive index along one direction. This direction can be parallel to the light exit plane. Due to the one-dimensional structure, a beam can be formed in a first spatial direction. Thereby a photonic effect can be achieved already with a few periods in the photonic structure. For example, the photonic structure can be designed in such a way that the electromagnetic radiation is at least approximately collimated with respect to the first spatial direction. Thus, a collimated beam can be generated at least with respect to the first direction in space.

### “Pixel”

Pixel, pixel, image cell or picture element refers to the individual color values of a digital raster graphic as well as the area elements required to capture or display a color value in an image sensor or screen with raster control. A pixel is thus an addressable element in a display device and comprises at least one light-emitting device. A pixel has a certain size and adjacent pixels are separated by a defined distance or pixel space. In displays, especially μ-displays, often three (or in case of additional redundancy several) subpixels of different color are combined to one pixel.

### “Planar Array”

A planar array is an essentially flat surface. It is often smooth and without protruding structures. Roughness of the surface is usually not desired and does not have the desired functionality. A planar array is for example a monolithic, planar array with several optoelectronic components.

### “Pulse Width Modulation”

Pulse width modulation or PWM is a type of modulation for driving a component, in particular a μ-LED. Here the PWM signal controls a switch that is configured to switch a current through the respective μ-LED on and off so that the μ-LED either emits light or does not emit light. With the PWM, the output provides a square wave signal with a fixed frequency f. The relative quantity of the switch-on time compared to the switch-off time during each period T (=1/f) determines the brightness of the light emitted by the μ-LED. The longer the switch-on time, the brighter the light.

### “Quantum Well”

A quantum well or quantum well refers to a potential in a band structure in one or more semiconductor materials that restricts the freedom of movement of a particle in a spatial dimension (usually in the z-direction). As a result, only one planar region (x, y plane) can be occupied by charge carriers. The width of the quantum well significantly determines the quantum mechanical states that the particles can assume and leads to the formation of energy levels (sub-bands), i.e. the particle can only assume discrete (potential) energy values.

### “Recombination”

In general, a distinction is made between radiative and non-radiative recombination. In the latter case, a photon is generated which can leave a component. A non-radiative recombination leads to the generation of phonons, which heat a component. The ratio of radiative to non-radiative recombination is a relevant parameter and depends, among other things, on the size of the component. In general, the smaller the component, the smaller the ratio and non-radiative recombination increases in relation to radiative recombination.

### “Refresh Time”

Refresh time is the time after which a cell of a display or similar must be rewritten so that it either does not lose the information or the refresh is predetermined by external circumstances.

### “Die” or “Light-Emitting Body”

A light-emitting body or also a die is a semiconductor structure which is separated from a wafer after production on a wafer and which is suitable for generating light after an electrical contact during operation. In this context, a die is a semiconductor structure, which contains an active layer for light generation. The die is usually separated after contacting, but can also be processed further in the form of arrays.

### “Slot Antenna”

A slot antenna is a special type of antenna in which instead of surrounding a metallic structure in space with air (as a non-conductor), an interruption of a metallic structure (e.g. a metal plate, a waveguide, etc.) is provided. This interruption causes an emission of an electromagnetic wave whose wavelength depends on the geometry of the interruption. The interruption often follows the principle of the dipole, but can theoretically have any other geometry. A slot antenna thus comprises a metallic structure with a cavity resonator having a length of the order of magnitude of wavelengths of visible light. The metallic structure can be located in or surrounded by an insulating material. Usually, the metallic structure is earthed to set a certain potential.

### “Field of Vision”

Field of view (FOV) refers to the area in the field of view of an optical device, a sun sensor, the image area of a camera (film or picking up sensor) or a transparent display within which events or changes can be perceived and recorded. In particular, a field of view is an area that can be seen by a human being without movement of the eyes. With reference to augmented reality and an apparent object placed in front of the eye, the field of view comprises the area indicated as a number of degrees of the angle of vision during stable fixation of the eye.

### “Subpixels”

A subpixel (approximately “subpixel”) describes the inner structure of a pixel. In general, the term subpixel is associated with a higher resolution than can be expected from a single pixel. A pixel can also consist of several smaller subpixels, each of which radiates a single color. The overall color impression of a pixel is created by mixing the individual subpixels. A subpixel is thus the smallest addressable unit in a display device. A subpixel also comprises a certain size that is smaller than the size of the pixel to which the subpixel is assigned.

### “Vertical Light Emitting Diode”

In contrast to the horizontal LED, a vertical LED comprises one electrical connection on the front and one on the back of the LED. One of the two sides also forms the light emission surface. Vertical LEDs thus comprise contacts that are formed towards two opposite main surface sides. Accordingly, it is necessary to deposit an electrically conductive but transparent material so that on the one hand, electrical contact is ensured and on the other hand, light can pass through.

### “Virtual Reality”

Virtual reality, or VR for short, is the representation and simultaneous perception of reality and its physical properties in a real-time computer-generated, interactive virtual environment. A virtual reality can completely replace the real environment of an operator with a fully simulated environment.

In the following sections, various aspects on μ-LED semiconductors structures are explained. These include structures and material systems for light generation. However, these aspects also concern aspects of processing.

An essential aspect, both in the field of Augmented Reality and Automotive displays or other display arrangements with μ-LEDs is the aspect that adjacent μ-LEDs of an arrangement are also spaced as μ-display or μ-array in such a way that the human eye cannot resolve or recognize the individual μ-LEDs in this arrangement. In particular, individual rows or columns of a row-wise or column-wise arrangement of μ-LEDs cannot be resolved or recognized by the human eye. For this purpose, the distances between the μ-LEDs or pixel density and pixel pitch of the μ-LED array are also adjusted to the distance of the user from the μ-LED array so that the eye of a user cannot resolve or detect the individual μ-LEDs of the μ-LED array in the respective application.

μ-LED arrays have the advantages of comparatively low energy consumption and high brightness of up to 106 Cd/m2 compared to arrays with organic LEDs (OLEDs) and liquid crystal displays (LCDs). In addition, μ-LED arrays enable a very high pixel density of up to 5000 pixels per inch (PPI) and, when used in displays, a very high frame rate in the nanosecond range. In addition, μ-LED arrays have a very long lifetime compared to OLEDs and LCDs and a very good stability against environmental influences. Furthermore, the use of μ-LED arrays makes it possible to adjust the values for the contrast range and/or resolution to desired values of these parameters, for example depending on an application.

Furthermore, arrays of μ-LEDs allow the adaptation of a lighting surface formed by the μ-LEDs to a desired shape. Thus, the application is not limited to normal displays, but arrays of μ-LEDs can also be used in the automotive sector, for example to use curved surfaces as displays or lighting arrangements. The surface can be used to display information as well as a simple illuminated surface for illumination or lighting.

One aspect deals with the generation of different colors in monolithic displays. In a monolithic μ-LED array, each individual pixel can comprise, for example, a blue light-emitting μ-LED, and each μ-LED can also contain a conversion material for converting blue light partially or completely into secondary light, which together with the blue primary light produces a mixed light, for example white light. Monolithic μ-LED arrays enable luminous surfaces with high luminance and can therefore be advantageously used in automotive lighting, for example as light sources for vehicle headlights.

Non-monolithic μ-displays or μ-LED arrays, on the other hand, allow the use of gaps between adjacent pixels or μ-LEDs for the arrangement of other components, for example electronic components for operating the μ-LEDs or sensors or detectors. Non-monolithic μ-LED arrays can, for example, be advantageously used for displays and for displays with integrated sensors, especially touchscreens, as well as for operating elements.

Some aspects relate to the principle that electrically conductive structures can force emission of electrical radiation at a dedicated frequency. Accordingly, a concept is proposed here in which a slotted antenna structure is used to induce emission of light and increase the ratio of radiative recombination to non-radiative recombination in an active region of a semiconductor element. In general, the ratio of radiative recombination changes to the disadvantage of radiative recombination when μ-LEDs or active areas become smaller.

Such a structure would lead to further advantages besides an improvement of the above ratio, since the emitted wavelength depends mainly on geometrical parameters of the slotted antenna adapted by physical properties of the environment. Consequently, light of different colors can be generated by using different mechanical structures. Furthermore, slotted antenna structures allow a directional light emission, which could be beneficial for implementation in applications requiring strong collimation.

In one embodiment, a light-emitting device comprises an electrically conductive structure. The electrically conductive structure forms a slotted antenna structure and has an upper main surface and a lower main surface opposite the upper main surface and is separated by a layer thickness. A cavity is located within the electrically conductive structure. The cavity has a width and a specific length on which the wavelength of the light generated by the device depends. The width is smaller than the corresponding length of the cavity.

In some variants, the slotted antenna structure comprises a metal plate of a certain thickness comprising a slot or cavity in it. Similar to the above, the slot has a width and specific length. The light emitting device also comprises a stack of semiconductor layers along a first principal direction, which is located within a cavity and extends at least over the upper main surface. The semiconductor layer stack can be an LED nanopillar and has a first electrical contact, a second electrical contact and an active area. In some variants, the active area of the semiconductor layer stack may be arranged between the first and second contact. The active region of the semiconductor layer stack can be implemented by a single pn junction as well as by a quantum well, multi-quantum well or multi-quantum well or any combination thereof. The semiconductor layer stack may have a length greater than its corresponding width. For example, the semiconductor layer stack may be at least twice as long as its width. It can also be 5 times or up to 10 times longer than wide.

To define light and to support radiative recombination via non-radiative recombination of the semiconductor layer stack during operation, the length of the cavity is based essentially on n/2 of a wavelength of light to be emitted during operation, where n is a natural number. In this respect, it should be noted that various physical parameters change the emission behaviour and the medium wavelength of an emission, so that the actual length of the cavity may be easily adjustable. These parameters can be combined in a so-called shortening factor, which can be measured and/or calculated from the physical parameters. For the purpose of this application, the shortening factor is taken into account when it is pointed out that the length of the cavity is essentially based on n/2 of a wavelength of light emitted during operation.

In some variants, the electrically conductive structure has a distance between the upper and lower main surfaces (called thickness) that is greater than a thickness of the active area of the semiconductor layer stack. The active area can be placed inside the cavity and especially between the levels defined by the upper main surface and the lower main surface. Such design will place the active region into the cavity, which supports the condition of radiative recombination within the active region. With respect to the length of the cavity, the semiconductor layer stack can be placed essentially in the center of the cavity. Accordingly, the center of the semiconductor layer stack is essentially located at half the length of the cavity. In this implementation, the semiconductor layer stack and the slotted antenna form a dipole structure, in which the main emission wavelength is given by approximately twice the cavity length adjusted by the shortening factor.

In some other implementations, the semiconductor layer stack will be placed in the direction of the end portion of the cavity, for example at an edge of the cavity length. In yet another implementation, the light-emitting device may have two semiconductor layer stacks placed at the respective ends of the cavity, as described here.

The semiconductor layer stack can extend beyond the electrically conductive structure. This means that the first and second electrical contacts of the semiconductor layer stack are also located above the upper main surface or accordingly below the lower main surface. Accordingly, the semiconductor layer stack can be a so-called vertical layer stack. Depending on the application, the first contact can be a p-contact and the second contact an n-contact or vice versa. To contact the semiconductor layer stack outside the cavity can simplify the implementation and also reduce undesired effects.

To form a cavity to support the emission of visible light requires a cavity length in the range of several hundred nanometers. Since the semiconductor layer stack and the active region can be placed in the cavity, a diameter of the footprint of the semiconductor layer stack and the active region in particular is smaller than a wavelength emitted by the device during operation. The slit should generally be longer than it is wide. In some aspects, the length to width ratio may be between 30:1 and 5:1, in particular between 15:1 and 5:1. If the ratio is less than 5:1, but also for other ratios, a reflective but insulated layer may be provided along the sidewall of the semiconductor layer stack so that light with a component perpendicular to the length of the cavity is reflected. This suppresses light that wants to propagate perpendicular to the length of the cavity.

In some variants, the cavity extends through the electrically conductive structure, forming a slot. The slot has a rectangular shape but can also have round edges at its end section due to the manufacturing process. In some other variants, the cavity is more of a recess, with a through-hole placed where the semiconductor layer stack is located. In other words, the cavity is partially closed at the lower main surface except for the hole where the stack is located and extends through the electrically conductive structure.

In some aspects, the slot may also have a rectangular shape, with the semiconductor layer stack being located in the common corner of the two sub-slots.

Another aspect relates to insulating the electrically conductive structure and separating the structure from the stack. A transparent insulating layer is applied at least to the upper main surface of the electrically conductive structure. However, a contact of the semiconductor layer stack is not covered by the insulating material, but either extends over the insulating material or reaches a level of the surface of the insulating material opposite the electrically conductive structure. In this implementation, the light-emitting device also comprises a contact layer deposited on the transparent insulating layer and in contact with the first electrical contact. The contact layer may also be insulated by another layer applied to the contact layer. This layer (or the contact layer) may be structured to improve the emission characteristics of the device. Apart from coating or roughening, the surface to increase light extraction, periodic structures such as photonic crystals and the like can be placed on the top surface. Other optics such as microlenses and the like can be used.

In some other aspects, a transparent insulating layer also covers the lower main surface, the other contact of the semiconductor layer stack and the transparent insulating layer, by covering the lower main surface, form a substantially flat surface. However, the electrically conductive structure is not completely covered by an insulating layer, because the structure should be connected to a reference potential to act as a slotted antenna. Therefore, the electrically conductive structure also has at least one contact. In this context, the electrically conductive structure may comprise the same potential as a connection of the semiconductor layer stack. The layer stack would then be connected to the electrically conductive structure. However, it is also possible to imprint a different potential of the electrically conductive structure.

The light emitted by such a device can show a broad spectrum, i.e. the emission spectrum is centered on a central wavelength (as mentioned above) while it also contains other frequency components. Also, the spectrum of emitted light from elements with nominally identical cavities is broadened. To reduce the spectrum and provide light of a special center wave with a narrow spectrum, a color filter can be placed over the upper main surface corresponding to the emission surface. The filter could be a narrow ribbon pass. In some variants, a converter may be arranged over the top main surface to convert light from a first wavelength to a color of a second longer wavelength. Using a converter enables the light emitting device to be optimized for a given wavelength and then convert the light to another desired wavelength.

Another aspect concerns the implementation of a variety of such light emitting devices, especially for the production of a μ-LED display together with suitable driver and control circuits. Such an arrangement comprises at least two light emitting devices as described above. The at least two devices can now share a common electrically conductive structure. In the common electrically conductive structure, some cavities may be arranged, each of which belongs to a corresponding light emitting device. In addition or as an alternative, the μ-LED array may also have a common transparent insulating layer applied at least on the upper main surface of the electrically conductive structure. If the electrically conductive structure is a separate one for each light-emitting device, the insulating layer may also fill the spaces between the conductive structures of each device.

In some variants, a common filter or other structure applied over at least two light-emitting devices may be provided. This will provide some redundancy in case of damage from one light emitting device and also reduce the complexity of the implementation, because the color filter can now be applied over a larger area (compared to an application using only a stack and cavity).

In order to control the light emitting devices separately, at least one of the contact types, either the p-contact or the n-contact, is not connected to each other so that the light emitting devices can be addressed and controlled separately.

In a μ-LED array of the above-mentioned type, some light emitting devices may comprise a color filter to set the color of the corresponding light emitting device. These color filters can have different properties. For example, a color filter of the at least two light-emitting devices may have different band-pass or filter characteristics with respect to a color filter of the other of the two light-emitting devices. Therefore, different colors can be obtained. This can be useful, if the light-emitting devices have a very wide emission spectrum spanning two or more regions of interest. For example, the light-emitting devices may have an emission spectrum that overlaps green and blue components. Appropriate color filters can be used to filter the unwanted portion of the spectrum. A similar solution is presented when light-emitting devices each have a converter.

A converter of one of the at least two light-emitting devices may be different from a converter of the other of the at least two light-emitting devices. Thus, different colors can be achieved with cavities of the same length, pixels can be easily built up from 3 or 6 or 9 subpixels of the same cavity, with corresponding converters arranged above the cavities. Each pixel thus created can then share the same electrically conductive structure.

In addition to the μ-LED form described above, other designs are also conceivable. Most of them have a surface that is suitable for light generation. Such light emitting diodes are then combined and RGB modules are manufactured from them. This applies not only to designs of larger LEDs, but also to modules with small components. For modules with very small light emitting diodes in the range of μ-LEDs, however, the production of individual and transfer of such μ-LEDs can be connected with a very high effort.

Monolithic μ-LEDs, i.e. μ-LEDs grown together on a carrier in columns and rows, therefore offer the possibility to produce μ-display modules without a component transfer of μ-LEDs.

For some applications, however, such μ-LEDs must be designed to emit different colors. In this case, μ-LEDs emitting light in the blue, green and red spectrum form one μ-pixel each. Three, or in the redundant case of several such μ-pixels, form one pixel. To create an RGB μ-display or corresponding modules, μ-LEDs can be manufactured with different material systems that emit colored light during operation. A monolithic design is thus made more difficult.

Another approach is described by the following aspects and presented procedures. For example, in a method of manufacturing a μ-LED array of pixels, it is proposed to form pairs of coated material volumes in the form of a polyhedron or a prism on a growth support. The term material volumes refers to a semiconductor body produced on a surface of a carrier. The coated material volumes are designed with an active layer so that they are suitable for emitting light. In this respect, such coated material volumes can also be called μ-LEDs due to their size. In a second step, a converter material matched to a defined color is inserted between material volumes of a pair. These colors can be red and green, for example. In some aspects the material volume, or the μ-LED produced in this way, can be designed to emit light of blue color, so that a converter between two material volumes is not necessary.

With a total of 4 such bars of material volumes and μ-LEDs, respectively, the individual generation of blue, green and red light is thus possible. The converter material lies at least in the middle between two material volumes, which can be electrically controlled simultaneously. In some aspects, the converter material also partially extends to the surface of the material volumes. With additional material volumes, redundancy can be created so that even if one volume fails, light of the desired wavelength can still be emitted. The material volume can have the shape of an elongated cuboid or a ingot shape own. However, other regular polyhedra, e.g. a parallelepiped, straight prism or similar shapes such as truncated pyramids, obelisks, wedges or regular polyhedra are also conceivable.

According to a second aspect, a μ-LED array, in particular for one pixel, is further proposed which has pairs in the form of a polyhedron or prism of comprehensive coated material volumes on a carrier substrate. A converter material is inserted between a pair of such material volumes, which converts light emitted from the material volumes into light of a further wavelength. This conversion is often complete.

To produce the material volumes, a core in the form of a bar is first formed on the carrier substrate and this is epitaxially overgrown with several layers. Suitable photostructures are used for this purpose. The material system for the core and the individual layers may be an III-V semiconductor system, for example on GaN basis. Since the material volumes are defined in the geometry by epitaxial growth, RGB pixels can be arranged on a very small area. The converter arrangement in the cavity allows redundancy and easy fabrication by means of jetting- or dispensing processes. In this way, μ-display can be generated as RGB-display based on a redundant 3D-bar arrangement.

An electrical connection is possible without any further wiring technique, especially by means of through-holes that go through the carrier. In this way SMT (“surface mounted technology”) components can be formed. Alternatively, the material volumes can also be formed monolithically with conductor structures present in the carrier.

As already mentioned above, a first doped layer and a second doped layer are deposited over a core. Between the first and second layer is an active layer. The latter may comprise one or more quantum well structures. The first and/or second layer also comprises current widening layers, doping gradients or other measures to enable low possible resistance and high current densities to the active layer. Further measures, including current confinement to keep the current away from the edges of the material volumes are described in this disclosure and can be used to create the material volumes. These include quantum well intermixing and others. For each pair, electrical contact is made to a p-contact area and to an n-contact area via metallization. In some aspects, one or both areas may be common, i.e. the material volumes share one or two common contact areas.

According to a further embodiment, a growth layer can be formed on the growth support, which has areas free from masking to which the number of material volumes can be applied. According to another embodiment, the growth layer can include n-doping and especially GaN. The masking can comprise SiO2 or SiN. The growth layer can be made of the same material (e.g. GaN) as the core of the material volume, also doped depending on the application.

According to another embodiment, the material volumes can be generated with their longitudinal axes parallel to each other and in the same geometry. According to a further embodiment, a deposition of first reflective metallization, in particular those providing a solder, takes place on the sides of the material volumes covered with the active and the further layers that face away from the growth carrier, whereby p-contacts, in particular strip-shaped ones, can be formed. According to further aspects, a solder metallization layer is deposited on a main surface of a flat carrier, whereby the solder metallization layer can be connected, in particular bonded, to the first metallization of the material volumes forming p-contacts.

In some embodiments, the growth layer is removed in certain areas, in particular by etching (RIE (Reactive Ion Etching) or ICP (Inductively Coupled Plasma Etching). A passivation is deposited on the exposed areas of the growth layer, which can completely cover the surfaces of the exposed areas. Either areas are left out or the passivation is opened again. In some aspects, the latter opening is carried out along the longitudinal axes of the material volumes on their surfaces facing away from the substrate. Then strip-shaped second metallization forming n-contacts are applied to the exposed areas of the material volumes.

Depending on the design, at least some of the sidewalls that have been passivated are also coated with a metallization. This becomes reflective, so that light is reflected from there. In the case of two adjacent coated material volumes, these sidewall mirror metallization can be produced alternately facing away from and towards each other. In such designs, it is intended to fill the free space between two adjacent coated material volumes, in which the sidewall mirror metallization are produced facing away from each other, with a converter material.

At and along the passivation layer of the n-contacts, the sidewall mirror metallization and metallic intermediate connections deposited as third metallization, an electrical connection to, in particular strip-shaped n-contact areas deposited as fourth metallization is formed. These can be on the same side of the carrier. Alternatively, vias are provided, contact areas on a side facing away from the metal volumes. The vias are electrically isolated from the solder metallization layer and the carrier by a passivation layer. Of course, p and n areas can also be interchanged.

According to another design, the p-contact vias can be formed in the area of a respective converter material. Al or Ag or other suitable materials can be used as metallization.

If the length of the bars is reduced, so-called μ-rods are obtained. These are constructed as columns and also contain an active layer that extends over the surface along the longitudinal axis and thus basically radiates light in all directions during operation. Such μ-rods can be generated multiple times on a carrier by means of self-organization or orientation-dependent crystal growth. The rather small structures allow μ-LEDs to be produced especially for μ-displays, whereby only epitaxial process parameters have to be changed. μ-rods of this type have spatial dimensions in the range of less than [μm]-down to the nanometer range.

Since the light generated by μ-rods radiates in essentially all directions in space, the light portion that is radiated directly upwards is rather small due to the small footprint. Therefore, it may be intended to surround the μ-rods with one of the reflective structures revealed further down. The μ-rod is thus arranged in a kind of cavity, with the walls of this cavity being bevelled and reflective. In some aspects, the cover electrode disclosed below may also be provided.

Another possibility is described as follows. This is based on the principle of separating the μ-rods and then aligning and contacting them parallel to a substrate. In this way horizontally aligned μ-rods, which each form a subpixel.

According to a first aspect, an electronic component, and in particular a μ-LED, is proposed in which a μ-rod running essentially parallel to a carrier is connected to a carrier. For this purpose, the μ-rod has an elongated core with a first doping, the core being coated on the outside from a layer sequence from a first longitudinal end to a second longitudinal end free from the layer sequence. The layer sequence also comprises an active layer, which in some aspects may comprises quantum well structures or the like. In addition, special doping or other measures as disclosed in this application may be used to restrict a current to low defect areas of the active layer. The μ-rod is electrically and mechanically connected at the first longitudinal end to a first contact region of the substrate by means of the layer sequence and a first contact, and is electrically and mechanically connected at the second longitudinal end to a second contact region of the substrate by means of the core and a second contact. Finally, the layer sequence is electrically insulated from the second contact by means of a masking. Thus, the μ-rod is arranged elongated and substantially parallel to the carrier. Although this increases the space consumption, this design still allows a high light output to be achieved with a low power consumption.

In a process for producing such an electronic component, and a μ-LED electrically connected on a carrier, a μ-rod is produced in a first step, which can be contacted at its first end and at its second end, the ends contacting differently doped layers. This generation can be achieved in essential steps by epitaxial material deposition. The μ-rod thus has an elongated core with a first doping, the core having been grown outwardly, in particular epitaxially, by one or more layer sequences from a first longitudinal end to a second longitudinal end free from the layer sequence.

The μ-rod thus generated is then arranged along a carrier substantially parallel to it. At its first longitudinal end, the layer sequence having a first contact is electrically and mechanically connected to a first contact area of the carrier. At its second longitudinal end, the core is electrically and mechanically connected to a second contact area of the carrier by means of a second contact. Here the layer sequence is electrically insulated from the second contact by means of an insulating layer.

The high flexibility in manufacturing the μ-rods allows adjusting their light emission to a desired wavelength range or desired wavelength. In some aspects, the geometry of a μ-rod is designed for a light of a certain wavelength. The geometry can have different lengths or diameters of the μ-rods as well as different thicknesses of the individual layers. With different diameters μ-rods can be manufactured which emit light of different wavelengths during operation. Quantum wells or quantum wells can be provided in the active layer. The μ-rods can be designed as polyhedron, prism, pyramid or wedge along the longitudinal axis. It can have four or even six corners in cross section. The μ-rod can be covered in some aspects by an additional converter material or in the further processed state by it, so that radiated light is converted.

If the μ-rod is parallel along its longitudinal axis on the carrier, in some aspects it may be convenient to apply a reflective layer between the carrier and the μ-rod. In this context, reference should be made to embodiments elsewhere where a carrier has a reflector structure surrounding a μ-LED so that light from the μ-LED arranged inside is deflected by the reflector structure. Such a reflector structure can also be arranged around groups of μ-rod arranged on the carrier.

In one aspect, three μ-rods forming a group are arranged in parallel on the carrier and electrically and mechanically connected to the contact areas of the carrier. The μ-rods can be designed to emit red, green or blue light. These thus form a pixel. Several such arrangements can be provided in rows and columns to form a μ-display. As mentioned above, the diameters of the μ-rods can be different for red, green and blue light. The μ-rods are so different in size. By permuting the μ-rods for multiple pixels, visual artefacts can be reduced due to periodicity.

Some aspects deal with the production and generation of the contacts. For example, the first contact, especially a p-contact, at the first longitudinal end of a respective μ-rod facing away from the insulation layer can be made in different ways. This includes epitaxial growth, especially by means of a seed layer photostructured by oxygen plasma etching. The contact can also be formed by sputtering. At the first contact, in some aspects at least one contact plane is formed as a contact surface to the first contact area of the carrier. The second contact is created in a similar way.

As already briefly indicated with the μ-rods, these can be generated by a certain self-organisation. Thereby the crystal orientation is used to produce a directed crystal growth. If three-dimensional, light-emitting heterostructures for optoelectronic semiconductor devices, e.g. μ-LEDs, are particularly small in size, controlled 3D shaping and the production of stress-free active layers with surface sections at an angle to each other is difficult. For μ-LEDs with nitrides such as GaN grown on sapphire with an active layer comprising InxGa1-xN quantum wells, it has already been proposed to fabricate them in the form of a triangular profile perpendicular to the <11-00> or <112-0> direction or to shape a Hexagonal Pyramid. For GaN-based semiconductor structures, a mask with hexagonal apertures aligned to the <11-00>- or <112-0> direction of GaN is used for lateral epitaxial overgrowth. For AlInGaP-based semiconductor structures on GaAs, it is proposed to apply the orientation of opposite corners of the hexagonal openings of the mask with an angular error smaller than 10° to the <110> direction of (001) n-GaAs. For ZnSe-based semiconductor structures, the angular error should be less than 15° to the <112> direction of (111) n-GaAs as epitaxial substrate. However, these applied approaches are not or only limitedly usable for very small structures, especially in the range of less than 70 μm edge length.

The methods disclosed in the following also allow the specification of small μ-LEDs or optoelectronic semiconductor devices, which have a high efficiency with regard to the ratio of luminous flux and absorbed electrical power. Correspondingly, such μ-LEDs in monolithic form or as individual pixels can form part of a μ-display.

The starting point of the concept proposed here is an optoelectronic semiconductor device comprising a three-dimensional light-emitting heterostructure with a first conductive semiconductor layer, an active layer and a second conductive semiconductor layer, the first and the second conductive semiconductor layer having different doping. According to the proposed principle, the light-emitting heterostructure comprises aluminum gallium arsenide (AlxGa1-xAs) and/or aluminum indium gallium phosphide (AlInGaP) and/or aluminum gallium indium phosphide arsenide and is formed three-dimensionally by growing it on a mold layer. The mould layer comprises a {110} oriented side surface. Optionally, a flat top surface {111} can be provided. For a high conversion rate and especially to reduce the non-radiative recombination at the edges of a light-emitting heterostructure with [μm] dimensions, the formation of a stress-free, three-dimensional layer structure with low lattice defects is necessary. It was recognized that the mold layer, which forms the base for the fabrication of the three-dimensional light-emitting heterostructure, should be selectively epitaxially deposited on a gallium arsenide (111)B epitaxial substrate.

In the present case, a gallium arsenide (111)B epitaxial substrate is understood to be a carrier substrate for selective epitaxy consisting of gallium arsenide with a (111) oriented surface used for epitaxial growth according to Miller indexing, the termination of the surface plane being formed by arsenic atoms. The gallium arsenide (111)B epitaxial substrate can be used doped or undoped. Compared to gallium arsenide (111)A with a gallium termination, an improved controllability of selective epitaxy is achieved, which is attributed to a higher volatility of the arsenic atoms. It is expected that due to the arsenic termination of gallium arsenide (111)B there will be a sufficient number of uniformly distributed As defects to improve nucleation, so that the initial phase of epitaxial layer formation can be advantageously controlled by externally adjustable epitaxial process parameters, such as temperature and feed of starting materials.

For the selectively epitaxially grown moulded layer on the gallium arsenide (111)B epitaxial substrate, the preferred material is gallium arsenide and/or aluminum gallium arsenide and/or aluminum gallium indium phosphide. The material of the mould layer can be undoped, n-doped or p-doped. Furthermore, it is provided for a further embodiment to create a Bragg mirror stack with a sequence of SiOₓ— and SiNₓ— layers within or on the mold layer, also epitaxially.

A lithographically structured dielectric layer, for example of SiOx, SiNx or SiOxNy, serves as a mask on the gallium arsenide (111)B epitaxial substrate. The openings in the mask are selected so that the base area of the shaped layer preferably has an edge length of 50 nm to 100 μm. In an embodiment, the shaping of the mask structure and its orientation relative to the crystal direction of the gallium arsenide (111)B epitaxial substrate supports the formation of at least one {110} oriented side surface of the molded layer. In some aspects, a molded layer is in the shape of a three-sided pyramid with (−1-10), (−10-1) and (0-1-1) oriented side faces. For another advantageous design, the form layer has a top surface with the orientation (−1-1-1) in addition to the side surfaces with the orientation (−1-10), (−10-1) and (0-1-1), so that for another preferred design example a form layer is present which is designed as a truncated three-sided pyramid.

The proposed method results in a precisely epitaxially grown shaped body with a defined contour and low crystal-internal stresses and a reduced number of lattice defects, on which the light-emitting heterostructure is epitaxially grown on the basis of aluminum gallium arsenide (AlxGa1-xAs) and/or aluminum indium gallium phosphide (AlInGaP). Their three-dimensionality increases the area of the active layer and allows an improved light extraction for photons emitted parallel to the layer. In addition, the invention leads to an enclosure of the edge areas of the light-emitting heterostructure, in which at least the active layer can reach as far as the mask acting as an electrical insulator for selective epitaxy. The mask may comprise SiOx, SiNx or SiOxNy. This results in a closed light-emitting heterostructure without the need for additional passivation at the edges, which reduces non-radiative recombination and thus increases the efficiency of light generation. This border effect results from the side surface of the molded layer which is oriented {110} towards the mask and which extends at least to the mask edge. Consequently, the molded layer can be formed flat with a substrate parallel top layer with (111) orientation. Preference is given to a form layer with a transverse extension parallel to the epitaxial substrate of less than 20 μm and a vertical extension perpendicular to the epitaxial substrate of less than 5 μm. In order to set a desired contour, the form layer can be reworked after selective epitaxial growth by means of wet chemical processing. For a preferred design, the contouring of the form layer is exclusively done by selective epitaxial growth.

With the light-emitting heterostructure based on aluminum gallium arsenide (AlxGa1-xAs) and/or aluminum indium gallium phosphide (AlInGaP), wavelengths in the range of 560 nm to 1080 nm can be generated. To complete a μ-LED the optoelectronic semiconductor structure is supplemented by light guiding, contact and passivation layers. Embodiments are possible, for which the main radiation direction is in the growth direction of the layer stack of the semiconductor device or against the growth direction. Furthermore, light extraction is possible on the p- or n-side of the light-emitting heterostructure. Further measures for light guidance, collimation or even conversion into another color are disclosed in this application.

For a variant with a main radiation direction in the growth direction of the layer stack of the light-emitting heterostructure, a layer sequence with a transparent contact layer for the second conductive semiconductor layer, e.g. a layer of indium tin oxide (ITO), is located above this. For a possible embodiment, the ITO layer is deposited over the entire top side of the light-emitting heterostructure. Furthermore, a Bragg mirror stack (DBR) can be provided below the light-emitting heterostructure.

The electrical contacting of the first conductive semiconductor layer of the light-emitting heterostructure from below is most easily achieved by a conductive gallium arsenide (111)B epitaxial substrate applied with the appropriate doping and a shaped layer selectively epitaxially grown and also doped on top of it.

If a matrix arrangement of light emitting heterostructures is processed in parallel, it can be used as a matrix for a μ-LED display depending on the processing used. The structures are generated monolithically arranged in rows and columns.

Alternatively, the heterostructures can be separated in groups or individually by a laser separation process or similar without damaging the active layers protected at the edges by the masking layer. Light sources separated in this way can form μ-LEDs that comprise extended contact areas and can be mounted on complementary contact areas of an IC chip without separate wire bonding in the simplest case.

For another variant with main radiation direction in growth direction, the active layer is locally limited by quantum wells and located in the area of the {110} oriented side surfaces or a (111) oriented top surface. An opaque metallization can be provided over the non-emitting sections of the heterostructure, forming for example a ring contact. Additional passivation and carrier layers may also be provided. Also conceivable are light guide structures at the exit windows, in the simplest case a surface roughening to increase the out-coupling rate. A surface can also be created by joint processing, and then additionally processed to form collimators, photonic crystals or other elements that further improve the radiation characteristics.

To realize light emission with a main emission direction opposite to the growth direction, first, the gallium arsenide (111)B epitaxial substrate and at least part of the mold layer are removed and in a further step, a transparent contact layer is applied below the light-emitting heterostructure. Such a light source is suitable for IC chip assembly with bonding.

For a further alternative, a temporary support above the three-dimensional light-emitting heterostructure is used for the removal of the gallium arsenide (111)B epitaxial substrate and the molded layer. These bottom layers are replaced by a metallization and a carrier substrate. Then the temporary carrier can be replaced by a topside passivation and light-emitting structure. Such a design is suitable for designs that are contacted by double bonding on an IC chip.

In addition to the various aspects of a geometric shape or orientation of the crystal, it was also found that radiative recombination decreases compared to non-radiative recombination the smaller the area of the active layer is. The reason for this seems to be defects in the active layer, which are mainly formed in the edge area of the μ-LED, because processing (singulation or etching) causes changes in the crystal structure therein, which increase the defect density. In general, it can be said that the larger the edge area becomes in relation to the surface of the active layer, the greater the number of defects becomes and thus the non-radiative recombination increases. It has also been recognized that the defect density has an effect on the efficiency of a light emitting diode both at high and low current densities and, together with the current density, makes an important contribution to aging (and thus reduces the efficiency of the light emitting diode).

A prerequisite for automotive applications is that μ-displays and their individual pixels must have sufficient luminosity, i.e. be able to carry relatively high current densities. On the other hand, a high contrast range is important for augmented reality applications, i.e. the μ-LEDs of a display should be able to handle both high and low current densities equally well. Accordingly, the efficiency should be high or even increased at low currents.

In view of these requirements on the one hand and the effect of defects on the other hand, it is therefore desirable either to reduce the defect density in the active layer, especially in the edge region, or to keep the charge carriers away from the edge region.

One measure to improve the low current behaviour is the Quantum Well Intermixing, which is used in various aspects in the manufacture of active semiconductor components. The band gap in this area is changed by the exchange of lattice atoms between the quantum well active layer and the surrounding barrier material. This exchange process can take place particularly efficiently if suitable impurity atoms, especially dopant atoms, are introduced into the semiconductor. This changes the band gap in the area covered by the exchange process, so that the charge carriers feel a force that can have a repulsive effect. For this purpose, dopants can be used, for example, which migrate into the active layer through a diffusion process and cause quantum well intermixing there. This method has also been successfully tested for optoelectronic devices based on III-V semiconductors, such as Ga, In, Al and P, As.

However, it was also observed that with smaller dimensions of light emitting diodes made of this material system and especially μ-LEDs, an increasing reduction in luminosity sets in over a relatively short period of time. Compared to components without quantum well intermixing, this degradation already occurs at significantly lower load current levels. In other words, quantum well intermixing leads to a reduction in the luminosity of a μ-LED even at low currents, although this is not observable with larger LEDs.

A method has now been found which not only significantly reduces this effect, but also almost completely prevents a reduction in luminous efficiency induced by interference points, at least over a longer period of time. This makes the process particularly suitable for the production of μ-LEDs.

For this purpose, a method is proposed for manufacturing a semiconductor device, in particular a μ-LED, in which a semiconductor structure is provided in a first step. This semiconductor structure can be produced, inter alia, by growth of differently doped layers and/or layers of different material composition and has, inter alia, a first n-doped layer, a second p-doped layer and an active layer with at least one quantum well arranged between them. The p-doped layer was provided with a first dopant for doping.

In a second step, a patterned mask is deposited on the semiconductor structure and especially on the p-doped layer. The mask is intended to protect areas of the active layer intended for the generation of electromagnetic radiation from the introduction of the second dopant. The mask material can comprise either a dielectric (silicon oxide, silicon nitride, . . . ), metal (Ti, . . . ) or semiconductor material.

The p-doped layer not covered by the patterned mask is then doped with a second dopant by a diffusion process with first process parameters. The process parameters and the mask material are selected in such a way that quantum well intermixing is produced in areas of the active layer which are not covered by any area of the patterned mask. The masking produces a relatively sharp lateral transition region in the intermixing of the at least one quantum well, so that the degree of intermixing in the quantum well decreases sharply at the boundary defined by the mask. This generates a relatively sharp change in the band gap of the quantum well.

According to the proposed principle, the diffusion process is followed by a final temperature step in which second process parameters are set that differ from the first process parameters. Without any further addition of the second dopant, the semiconductor is now subjected to an annealing step with these second process parameters.

This downstream curing step with different process parameters and without a second dopant is designed in such a way that the significant improvement in low current efficiency achieved with the first step is maintained over a longer period of operation.

The inventors recognized that the process of adding the second dopant at first process parameters is both causally important for the generation of quantum well intermixing and for the later degradation. Atoms of the second dopant diffuse into the semiconductor layer stack and into the active layer, or quantum well, where they can replace atoms of the original crystal lattice. These are either atoms of the first dopant, but also atoms of the actual lattice material. The atoms displaced to interstitial sites are mobile, and it is assumed that they play a major role in the degradation of the optoelectronic device. An additional annealing step with simultaneously changed process parameters during which the dopant is not added further reduces the subsequent reduction in efficiency. In a further aspect, suitable environmental conditions are provided for the annealing step by offering a supporting pressure with an element forming the crystal lattice (e.g. by providing a suitable precursor).

By suitable choice of this element, the lattice atoms displaced by the second dopant are offered a reaction possibility at the surface of the semiconductor and the free mobility of these atoms is thus prevented. If the displaced lattice atoms are, for example, atoms of group III, this process can be preferably initiated by a supporting pressure with an element of group V. The interstitial atoms produced by the diffusion process therefore diffuse to the surface during the healing step according to the invention and are bound there. By reducing the number of interstitial atoms participating in the degradation mechanism, the service life of the component increases considerably.

In one-step of the healing process, the precursor can be added right at the beginning or only after reaching the second process parameter. The concentration of the precursor can also change during the annealing step, so that sufficient precursor material is available to saturate the lattice atoms displaced by the dopant.

In a further aspect, this precursor may particularly include the elements phosphorus or arsenic, especially in compounds such as PH3, ASH3 TBAs or TBP.

Another aspect deals with the first and second process parameters. In one aspect, the parameters include at least one of the following parameters or a combination of them: temperature, temperature change over a defined period of time, pressure, pressure change over a defined period of time, composition and flow of a gas, in particular a precursor, and duration of the annealing step. For example, the second process parameters include a defined second temperature, which is higher than the temperature during the addition of the second dopant. In other words, a temperature during the annealing step is higher than a temperature during the generation of the quantum well intermixing. Also, the time durations of doping and annealing can be different.

In another aspect a second dopant is used, which is different from the first dopant. For example, Zn can be used as the second dopant. For example, an III-V semiconductor material is used as the material system for the semiconductor structure. This can have at least one of the following material systems: InP, AlP, GaP, GaAlP, InGaP, InAlP, GaAlP or InGaAlP. Other III-V semiconductors can also be considered as material systems, for example with As.

Another aspect is given by an optoelectronic component. This comprises a semiconductor structure with an III-V semiconductor material. The semiconductor structure comprises an n-doped layer, a p-doped layer and an active layer with at least one quantum well between them. The p-doped layer comprises a first dopant. Furthermore, the device has a light-generating region, in particular a central region in the active layer, which is laterally surrounded by a second region in the active layer. The band gap of the second region is larger than that of the central region because a second dopant is introduced into the second region which has caused quantum well intermixing in the at least one quantum well of the active layer located in the second region.

In another aspect, a structured mask is arranged on the p-doped layer so that it covers a first subarea of the p-doped layer. In a subregion of the p-doped layer not covered by the mask, a second dopant is introduced, which generates quantum well intermixing in the active layer located below this subregion. The size of the mask is substantially the same size as the first subregion. By selecting the supporting pressure during the healing step according to the invention, a material displaced by the second dopant is converted into a layer covering parts of the surface. The diffusion process during the annealing seems to remove the material from interstitial sites, so that it no longer leads to non-radiative recombination centers in the quantum well, and thus the efficiency of the optoelectronic device does not decrease even over a longer period of time. Accordingly, a layer of an III-valent material of the III-V semiconductor material and an element of a precursor material, in particular P or As, is formed on a surface of the intermixed subregion of the p-doped layer.

Another aspect of the improvement of quantum well intermixing is presented in the following procedure. For this purpose, a method is proposed for the manufacture of a semiconductor component, in particular an optoelectronic component or a μ-LED, in which a semiconductor structure is provided in a first step. This semiconductor structure can be generated, inter alia, by growth of differently doped layers and/or layers of different material composition and has, inter alia, a first n-doped layer, a second p-doped layer and an active layer with at least one quantum well arranged between them. The p-doped layer was provided with a first dopant for doping.

In a second step, a patterned mask is deposited on the semiconductor structure and especially on the p-doped layer. The mask is intended to protect an area of the active layer intended for generating electromagnetic radiation from the penetration of a second dopant. The mask material can either be a dielectric (silicon oxide, silicon nitride, . . . ), metal (Ti, . . . ) or semiconductor material.

The p-doped layer not covered by the patterned mask is then doped with the second dopant so that quantum well intermixing is generated in areas of the active layer not covered by any area of the patterned mask. Doping the p-doped layer with the second dopant can be performed by gas phase diffusion using a precursor with the second dopant. In other processes, the precursor is thermally decomposed in a gas phase reaction, the dopant is absorbed at the semiconductor surface and diffused into the semiconductor and a quantum well intermixing is generated. Since all these sub-processes have different temperature dependencies, the temperature range in which efficient quantum well intermixing can be realized is very limited (typically for InP- or GaAs-based semiconductors: 520+/−20° C.).

According to the proposed principle, the step of applying the dopant by means of precursor and diffusion is now specified. This creates a process sequence for efficient quantum well intermixing by gas phase diffusion, which allows an enlargement of the process window and thus an optimization of the process sequence for the realization of age-stable optoelectronic devices.

This specified process sequence has the following steps:
depositing the second dopant on the surface of the p-doped layer by decomposition of the precursor at a first temperature selected such that substantially no diffusion of the second dopant into the p-doped layer takes place; and
Diffusion of the deposited second dopant into the p-doped layer at a second temperature, which is higher than the first temperature.

The inventors recognized that the process control of doping with the second dopant has a significant influence on reducing the charge carrier concentration in those areas, in which a reduction in luminous efficiency induced by impurities occurs over a longer period of time. This is due, among other things, to the fact that the process control can increase the doping barrier in the active layer below the mask edge.

In process control according to the proposed principle, the step of diffusion of the dopant-containing precursor in the gas phase is explicitly separated in the steps:
depositing decomposition products comprising the second dopant on the surface of the semiconductor structure; and
diffusion of the second dopant into the semiconductor structure.

Due to the separation, the temperature for the diffusion step with the generation of the quantum well intermixing can be freely selected and, in particular, can be increased to values at which a surface coating by the second dopant is no longer possible due to excessive desorption (>520° C.). This can be advantageously used to improve the aging behaviour of optoelectronic components.

The second dopant is of the same dopant type as the first dopant and is formed from Zn, Mg, etc. The quantity of the deposited second dopant can be selected in such a way that it diffuses substantially completely into the p-doped layer during the diffusion process at a second temperature. Thus, only a quantity sufficient for diffusion and generation of quantum well intermixing is provided, but not beyond.

In a further aspect, the amount of the deposited second dopant is chosen, for example, in such a way that in areas of the active layer over which no area of the structured mask is located, a barrier for the lateral diffusion of charge carriers is formed, which is composed of a barrier produced by the second dopant as well as a barrier caused by quantum well intermixing.

In an further embodiment of this aspect, the amount of the second dopant is chosen such that in areas of the active layer over which no area of the patterned mask lies, a barrier for the lateral diffusion of charge carriers generated by the second dopant is greater than a barrier caused by quantum well intermixing. Furthermore, the amount of the second dopant can also be chosen such that the band gap in the active layer in the regions, which lie below the structured mask, is smaller than the band gap in the active layer in the regions above which no region of the structured mask lies.

In another aspect, the doping process is followed by a last temperature step at a third temperature, which is higher than the second temperature. Without further addition of the second dopant, the semiconductor is now subjected to an annealing step at this third temperature. This downstream annealing step at a higher temperature and without a second dopant is designed in such a way that the significant improvement in low current efficiency achieved with the doping process is maintained over a longer operating period.

The inventors recognized that the process of introducing the second dopant at a first temperature and the subsequent diffusion of the second dopant at a second temperature is both causal for the generation of quantum well intermixing and is also important for the subsequent degradation. Atoms of the second dopant diffuse into the semiconductor layer stack and into the active layer, or quantum well, where they can replace atoms of the original crystal lattice. These are either atoms of the first dopant, but also atoms of the actual lattice material. The atoms displaced to interstitial sites are mobile and it is assumed that they play a major role in the degradation of the optoelectronic device. By an additional annealing step at a higher third temperature and during which no further dopant is added, a subsequent decrease in efficiency is reduced.

In a further aspect, suitable environmental conditions are provided for the annealing step by offering a supporting pressure with an element forming the crystal lattice (e.g. by providing a suitable further precursor). By suitable choice of this element, the lattice atoms displaced by the second dopant are offered a reaction possibility at the surface of the semiconductor and the free mobility of these atoms is thus prevented. If, for example, the displaced lattice atoms are group III atoms, this process can be started by a supporting pressure with an element of group V. The interstitial atoms produced by the diffusion process therefore diffuse to the surface during the annealing step according to the invention and are bound there. By reducing the number of interstitial atoms participating in the degradation mechanism, the service life of the component increases considerably.

Accordingly, according to this aspect, the healing process includes the steps providing a further precursor comprising an element from the fifth main group, in particular P or As; and/or forming a layer of a III-V semiconductor material on the surface of the p-doped layer.

In one-step of the annealing process, the precursor can be added right at the beginning or only after reaching the second process parameter. The concentration of the precursor can also change during the annealing step, so that sufficient precursor material is available to saturate the lattice atoms displaced by the dopant.

In another aspect, this further precursor may contain in particular the elements phosphorus or arsenic, especially in compounds such as PH3, ASH3, TBAs or TBP.

Another point of view deals with the process parameters, which can be chosen differently during the steps of deposition, diffusion and annealing. In one aspect, the parameters include at least one of the following parameters or a combination thereof: temperature, temperature change over a defined period of time during one of the aforementioned steps, pressure, pressure change over a defined period of time during one of the aforementioned steps, composition and flow of a gas, in particular a precursor, and duration of the curing step.

For example, the process parameters include a defined first temperature during the supply of the second dopant, which is selected such that substantially no diffusion of the second dopant into the p-doped layer takes place during the deposition of the second dopant on the p-doped layer, a second temperature during the diffusion process of the second dopant, which is higher than the first temperature, for example, and a third temperature during the annealing step, which is again higher than the second temperature. In other words, one temperature during the annealing step is higher than the two temperatures during the creation of the quantum well intermixing. Also, the time periods for the addition of the second dopant, the diffusion process and the annealing can be different.

In another aspect a second dopant is used, which is different from the first dopant. For example, Zn or Mg can be used as the second dopant. For example, an III-V semiconductor material is used as the material system for the semiconductor structure. This can have at least one of the following material combinations: InP, AlP, GaP, GaAlP, InGaP, InAlP, GaAlP or InGaAlP. Other III-V semiconductors can also be considered as material systems, for example with As.

Another aspect is given by an optoelectronic component. This comprises a semiconductor structure with an III-V semiconductor material. The semiconductor structure comprises an n-doped layer, a p-doped layer and an active layer with at least one quantum well between them. The p-doped layer comprises a first dopant. Furthermore, the device comprises a light-generating region, in particular a central region in the active layer, which is laterally surrounded by a second region in the active layer. The band gap of the second region is larger than that of the central region due to a second dopant introduced into the second region which has caused quantum well intermixing in the at least one quantum well of the active layer located in the second region.

Due to this impurity induced local quantum well intermixing in the second region, but not in the first region, barriers are formed in the active layer, which limit a lateral movement of charge carriers in the quantum well in the active layer of the optoelectronic device to this first region of the active layer. This largely prevents, for example, that current for operating the optoelectronic device flows in the edge regions of the optoelectronic device, i.e. through the second region enclosing the first region. This reduces non-radiative recombination of charge carriers caused by non-radiative recombination centers or a high non-radiative surface recombination in the second region, which thus leads to an improved performance of the devices.

In another aspect, a structured mask is arranged on the p-doped layer so that it covers a first subregion of the p-doped layer. In a subregion of the p-doped layer not covered by the mask, a second dopant is introduced, which produces quantum well intermixing in the active layer located below this subregion. The size of the mask is essentially the same size as the first subregion.

By choosing the supporting pressure during the annealing step according to the invention, a material displaced by the second dopant on interstitial sites is converted into a layer covering parts of the surface. The diffusion process during the annealing seems to remove the material from interstitial sites so that it no longer leads to non-radiative recombination centers in the quantum well and thus the efficiency of the optoelectronic device does not decrease even over a longer period of time. Accordingly, a layer of an III-valent material of the III-V semiconductor material and an element of a precursor material, in particular P or As, is formed on a surface of the intermixed subregion of the p-doped layer.

As already mentioned in the above concepts, the effectiveness of quantum well intermixing and the introduction of the impurities has an influence on the ageing behaviour of the μ-LED. Although this can be reduced with the measures revealed here, it was found that a measurable and sometimes relevant effect remains, especially at higher load current densities, especially with very small components such as μ-LEDs whose edge length is only a few μm. The reason is apparently a location or position dependent concentration gradient of the diffusing material. This is determined by the arrangement and structure of the photomask.

Correspondingly, in one aspect an optoelectronic device is proposed which comprises an n-doped first layer, a p-doped second layer with a first dopant and an active layer. The latter is located between the n-doped first layer and the p-doped second layer and has at least one quantum well. According to the invention, the active layer can be divided into at least two regions, which are in particular adjacent to one another. The second region is concentrically arranged around a first region, in particular an optically active region, and comprises quantum well intermixing.

The concentric arrangement of a quantum well intermixing around the optically active region corresponding to this aspect, means that the first region, in particular, the optically active region, is completely enclosed by the second region and the two region are arranged around a common centre of their respective surfaces. Within the manufacturing tolerances, however, a slight deviation of the centres from each other, as well as a deliberate shifting is also conceivable.

The inventors realized that the introduction of the impurities and quantum well intermixing probably depends on the offered open area over which the substance to be diffused is introduced. Since impurities in the corners of a square or rectangular active layer (or according to a rectangular structure given by a photomask) can diffuse from more than one side, the corner regions have a higher impurity concentration or quantum well intermixing than, for example, the regions in the middle of the side lengths. This effect is undesirable in some situations and is avoided by the chosen concentric arrangement, since the absence of a corner does not lead to such a greater diffusion in such a situation.

Quantum well intermixing can be achieved by doping the second region with a second dopant such as magnesium, zinc, or cadmium (Mg, Zn, Cd). However, this is not intended to be a restrictive selection for one dopant, but any other dopant of the same type that the skilled person can think of can be used for doping.

By locally applying a diffusion mask to the semiconductor structure and by means of, for example, a diffusion process, the second dopant enters the active layer in regions and quantum well intermixing occurs in the corresponding unmasked region in the existing quantum well. The region where quantum well intermixing occurs forms the second region. Correspondingly, according to this aspect, the optoelectronic device comprises a second dopant, which is essentially uniformly arranged in the second region.

In the first region, especially in the optically active region, quantum well intermixing is largely prevented in another aspect. More precisely, after this aspect, quantum well intermixing does not occur in the first region. Correspondingly, after the diffusion process there is almost no second dopant in the first region. This aspect can also be realized by the above-mentioned measures.

Due to this impurity induced local quantum well intermixing in the second region, but not in the first region, barriers are formed in the active layer, which limit a lateral movement of charge carriers in the quantum well in the active layer of the optoelectronic device to this first region of the active layer. This largely prevents, for example, that current for operating the optoelectronic device flows in the edge regions of the optoelectronic device, i.e. through the second region enclosing the first region. This reduces non-radiative recombination of charge carriers caused by non-radiative recombination centers or a high non-radiative surface recombination in the second region, which thus leads to an improved performance of the devices.

To achieve further improvement, in another aspect the two areas are at least approximately circular. The absence of corners has the consequence that impurities diffuse more evenly into the second area and no local maxima induced by corners are formed. The circular formation, or the approximately circular formation of the two regions, thus has the effect that the concentration of the introduced impurities along the circumference of the two regions is as homogeneous as possible. This in turn has the consequence that performance losses due to surface recombination in the second area are reduced.

Circular in this context means that a polygon with a number of corners greater than or equal to 6 corners is also possible, e.g. 8, 10 or more corners, since a positive effect of the power increase of the optoelectronic component has already been recognized for this shape. Likewise, the term circular can also include elliptical, as well as oval and other rounded convex shapes.

The diffusion process for the generation of the quantum well intermixing in the second region can mean in a further aspect that the second dopant is not only formed in the active layer in the second region, but also in the second p-doped layer and also at least partially in a region of the n-doped layer adjacent to the active layer. However, this is not necessarily to be understood to mean that the regions in the second p-doped layer and in the first n-doped layer in which the second dopant is formed are congruent with the second region in the active layer, but congruence is also possible.

In another aspect, an optoelectronic device and in particular a μ-LED is proposed, in which the second region comprises a substantially uniform band gap modified by quantum well intermixing. The second region is concentrically arranged around a first region. This means that in this region, the energy of the band gap comprises a largely constant value and only towards the edges of the region, the band gap increases or decreases or comprises an increase or decrease of the energy of the band gaps.

In contrast, the at least one quantum well in the first region, especially in the optically active region, has a smaller band gap than the second region. Accordingly, the barrier between the first and the second region is generated according to one of the above-mentioned aspects. The transition between the two band gaps can be a step with a sharp edge or an easy flowing transition.

Furthermore, the at least one quantum well in the first region, in particular the optically active region, comprises substantially no quantum well intermixing and thus there is substantially no second dopant in this region.

In addition to a geometrical consideration of the performance improvement in the range of a single μ-LED, it is also possible to provide measures that cause an improvement for a quantum well intermixing at wafer level. μ-LEDs are mostly produced as a variety of such structures on wafer level. The production can be monolithic or the μ-LEDs can be intended for later separation. In the former case, quantum well intermixing can also be used as a barrier against electrical crosstalk. In the latter case, quantum well intermixing can already be used during production to modify the region later forming the edge.

In one aspect a semiconductor structure is presented, which comprises an n-doped first layer, a p-doped second layer with a first dopant and an active layer. The latter is located between the n-doped first layer and the p-doped second layer and has at least one quantum well. According to the invention, the active layer can be divided into a plurality of first regions, in particular optically active regions, and at least one-second region. The plurality of first optically active regions and the at least one second region are particularly adjacent to each other. Furthermore, the plurality of first regions are arranged spaced apart from one another in a hexagonal pattern and are enclosed by the at least one second region which has a QWI.

For example, each of the numerous first, especially optically active, regions of the semiconductor structure can form a part of one optoelectronic component each. Accordingly, the semiconductor structure can be formed from a large number of individual optoelectronic components, which can then be separated by, for example, an etching process through the epitaxial layers or by laser cutting and subsequent substrate removal.

The plurality of first regions is for example circular. In comparison to a square μ-LED structure, the absence of corners results in a more homogeneous introduction of impurities and quantum well intermixing along the boundary of the later μ-LED. This in turn means that non-radiative recombination can be reduced in the boundary region of the second region and accordingly the power of each individual optoelectronic device can be increased.

Circular in this context means that a polygon with a number of corners greater than or equal to 6 corners is also possible, e.g. 8, 10 or more corners, since a positive effect of the power increase of an optoelectronic component can already be seen for this shape. Likewise, the term circular can also include elliptical, as well as oval and other rounded convex shapes.

By locally applying a mask to the semiconductor structure and by means of, for example, a diffusion process, a second dopant enters the active layer in certain regions and a QWI occurs in the corresponding area in the existing quantum well. The region where quantum well intermixing takes place forms the at least one second region. The semiconductor structure accordingly comprises a second dopant, in particular a dopant different from the first dopant arranged in the p-doped second layer, which is arranged substantially uniformly in the at least one second region.

In the large number of first regions, however, QWI is largely prevented by the application of the mask. More precisely, quantum well intermixing does not occur in the plurality of first regions. Correspondingly, after the diffusion process, there is no second dopant located in the plurality of first regions and therefore no second dopant is located in the active layer in the quantum well in the region of the first regions.

The division into first and second areas and the associated QWI enables the first regions to be used as optically active regions in the later operation of the end devices, especially the μ-LEDs. Accordingly, the first optically active regions are referred to in the following as the first optically active regions.

Due to this impurity induced local quantum well intermixing in at least one second region but not in the plurality of first optically active regions, electronic barriers are formed in the active layer by the changing band structure, which limit a lateral movement of charge carriers in quantum well in the active layer of the semiconductor structure to the plurality of first optically active regions of the active layer. This largely prevents, for example, the flow of current for operating an optoelectronic device in the edge regions of the optoelectronic device, i.e. through the second region enclosing the first region. Since non-radiating recombination centers often exist in the edge regions of a single μ-LED structure, the charge carriers are thus kept away from these edge regions, which leads to an improved performance of the devices.

In practice, however, the introduction of the impurities and thus quantum well intermixing depends on the size of the open area over which the substance to be diffused is introduced. Correspondingly, a hexagonal arrangement of the plurality of first optically active regions results in larger areas on the semiconductor structure in the interstices of three first optically active regions arranged in a triangle, i.e. local maxima with a higher impurity concentration, than in the areas directly between two adjacent first optically active regions. These maxima result from the fact that the diffusion process works more efficiently in the area of larger regions exposed to the second dopant than in smaller gaps between two first optically active regions covered by, for example, a mask. This effect is undesirable in some situations, since it is important to achieve a very homogeneous diffusion pattern in the semiconductor structure to improve the low current efficiency of the optoelectronic components.

Accordingly, in a further aspect a semiconductor structure is presented, which comprises an n-doped first layer, a p-doped second layer with a first dopant and an active layer. The latter is located between the n-doped first layer and the p-doped second layer and comprises at least one quantum well. According to the invention, the active layer can be divided into a plurality of first regions, in particular optically active regions, at least one second region and at least one third region. The plurality of first optically active regions and the at least one second region are particularly adjacent to each other. Furthermore, the plurality of first optically active areas are arranged spaced apart from one another in a hexagonal pattern and are enclosed by the at least one second area which includes QWI. In addition, the at least one third region is arranged in the spaces between the plurality of first optically active regions and the second region and in particular adjoins the at least one second region.

In contrast to the aspect described above, the active layer is divided into at least one third region in addition to the plurality of first optically active regions and the at least one second region.

The at least one third region is arranged in such a way that the regions in which local maxima with a higher impurity concentration would occur in accordance with the aspect described above are made inaccessible for quantum well intermixing, for example by applying a mask, and quantum well intermixing thus largely does not occur in these regions, as well as in the plurality of first optically active regions. Correspondingly, after the diffusion process there is largely no second dopant in the at least one third region and in the plurality of first optically active regions.

Further, the at least one second region encloses the plurality of first optically active regions such that each of the plurality of first optically active regions is concentrically surrounded by part of the at least one second region or individually by one of a plurality of second regions. Accordingly, the at least one second regions results, for example, from contiguous ring segments each of which is arranged around one of the plurality of first optically active areas, or from a plurality of ring-shaped individual areas each of which is arranged concentrically around one of the plurality of first optically active regions. Likewise, the term annular may also include circular, elliptical, as well as oval and other rounded convex shapes, which are arranged substantially concentrically around and fully enclose the plurality of first optically active regions.

The at least one third region is adjacent to the at least one second region. Correspondingly, the at least one third region may have a continuous mesh-like surface arranged around the plurality of annular second regions. In a further aspect, however, a large number of third regions can each at least approximately represent the shape of a deltoid curve. This can be formed, for example, by exactly three second regions arranged in a triangle, which are at least approximately circular or ring-shaped. In the same way, the plurality of third regions can be circular and be arranged in the middle of three first regions arranged in a triangle, which are at least approximately circular.

The decisive factor in the arrangement of the at least one third region is that, for example, by applying a mask such as a dielectric or, for example, a photoresist mask, local maxima with a higher impurity concentration in the second region are reduced during the diffusion process in order to achieve a diffusion pattern in the semiconductor structure that is as homogeneous as possible.

Quantum well intermixing can be achieved by doping the second region with a second dopant such as magnesium, zinc, or cadmium (Mg, Zn, Cd). However, this is not intended to be a limiting choice for the dopant, but any other dopant of the same type imaginable to the expert can be used for doping.

In a further aspect, the diffusion process for producing quantum well intermixing in at least one second region can result in the second dopant being formed not only in the active layer in the second region, but also in the second p-doped layer and also at least partially in a region of the n-doped layer adjacent to the active layer. However, this is not necessarily to be understood to mean that the regions in the second p-doped layer and in the first n-doped layer in which the second dopant is formed are congruent with the at least one second region in the active layer, but congruence is also possible.

In another aspect, a semiconductor structure is proposed in which the at least one second region has a substantially uniform band gap created by quantum well intermixing. This means that in this region, the energy of the band gap has a largely constant value, and only towards the edges of the region, the band gap becomes larger or smaller.

In contrast, the at least one quantum well in the plurality of first optically active regions and in the at least one third region has a smaller band gap than in the at least one second region. Accordingly, the barrier generated according to one of the above-mentioned aspects results between the plurality of first optically active regions and the second region and between the at least one third region and the second region. The transition between the band gaps can be either a step with a sharp edge or an easily flowing transition.

In another aspect, the plurality of first optically active regions and the at least one third region has a substantially identical band gap. This results, among other things, from the fact that the at least one quantum well in the plurality of first optically active regions and in the at least one third region comprises substantially no quantum well intermixing and thus essentially no second dopant occurs in these regions.

The semiconductor structure, which can be formed from a plurality of individual optoelectronic components, is separated into the plurality of optoelectronic components according to a further aspect by, for example, an etching process through the epitaxial layers or by laser cutting and subsequent substrate removal. The section of each of the plurality of optoelectronic components is thereby for example circular and comprises at least one of the plurality of first optically active regions, as well as a section of the at least one second region. The first optically active region and the second region are in particular arranged concentrically in the circular cut-out. Correspondingly, it follows that the at least one third region of the semiconductor structure is not part of the plurality of individual optoelectronic components and thus represents in particular a scrap of the separation process.

In the case of small light emitting diodes, particularly of the color red, further miniaturization of the chip size, especially below 50 μm, is difficult due to non-radiative recombination at the outer edges of the chips. Up to now, this difficulty has not been given much attention with red light emitting diodes based on the AlGaInP material system, as the chip size has not fallen below about 100 μm². Further up, quantum well intermixing is used to reduce the proportion of non-radiative recombination. In the following aspects, a concept is presented in which charge carriers are transferred from one edge of a chip by means of a magnetic constriction be kept away.

According to a first aspect an optoelectronic device, in particular a vertical μ-LED for a monolithic μ-display is proposed. This has a layer stack with an active layer running in one plane. A main direction of movement of charge carriers, i.e. electrons and holes, is perpendicular to this plane and through the active layer. In the latter, the desired radiative recombination takes place. However, the defect density is higher in the circumferential edge of the active layer, so that these defects can lead to non-radiative recombination. A magnetization element is provided accordingly. This is configured to provide magnetic field lines that run through at least parts of the layer stack in such a way that the moving charge carriers are kept away from edge regions of X-Y cross-sectional areas of the layer stack.

According to a second aspect, a method for the reduction of non-radiative recombination, especially in the region of an active layer, especially a μ-LED, is proposed. The vertical μ-LED comprises a layer stack, in which layers extending along an X-Y plane are stacked together along a Z-axis perpendicular to the X-Y plane, whereby a main direction of movement of charge carriers along the Z-axis, and in particular this axis runs centrally through X-Y cross-sectional areas of the layer stack. The method comprises the step of generating magnetic field lines by means of which the charge carriers are kept away from edge regions of X-Y cross-sectional surfaces of the layer stack.

By means of the proposed arrangement, magnetic effects are used to influence effectively the lateral distribution of a current flow within a μ-LED. This is intended to keep charge carriers (i.e. electrons or optionally holes as well) away from an edge region of the active layer. Thus, a kind of electron lens is realized. In this way, a scalability to smaller chip sizes can be achieved. Non-radiative recombination at the chip edges are thus reduced.

According to a further embodiment, the magnetizing element can provide the magnetic field lines in the region of an active layer and/or against the main direction of motion of the charge carriers in a region in front of the active layer running towards a pole of a magnetic dipole or along the Z-axis. It is useful to arrange the magnetization element in such a way that it provides magnetic field lines only in the edge regions of the X-Y cross-sectional areas of the layer stack.

In an embodiment, the magnetizing element comprises a number of, in particular strip-shaped, current lines running along a lateral surface of the stack of layers, with a current flow of one current line in each case being provided antiparallel to the current flow through the optoelectronic component. Alternatively, the magnetizing element can be provided by means of a number of permanent magnet dipoles, which circulate around the layer stack along an X-Y plane, in particular arranged in the region of the active layer and/or against the main direction of movement of the charge carriers in a region in front of the active layer. Instead of permanent magnet dipoles, electromagnets can also be used, the current flow of which can be provided in particular by means of the current flow through the optoelectronic component.

In accordance with a further embodiment, the magnetizing element can be in the form of a magnetic material, in particular manganese, which circulates around the layer stack along an X-Y plane in the region of an active layer and/or against the main direction of movement of the charge carriers in a region in front of the active layer, deposited on a lateral surface of the layer stack and magnetized by means of an external magnetic field.

According to a further embodiment, the layer stack can have an electrically insulating and passivating coating, particularly on the outer surface of the layer stack. In this context, the layer stack is a columnar μ-LED. Simplified, it comprises a p-doped layer, an n-doped layer and an active layer arranged in between. The latter can be configured as a quantum well or multiquantum well. Corresponding designs of a μ-LED with further measures are part of this disclosure. It is understood that the layer stack described here or the μ-LED used here can be replaced or supplemented by the embodiments disclosed in this disclosure. For example, the magnetic current constriction can simultaneously exhibit reflective properties so that light cannot escape on the side surface. In one aspect, it is possible to make two opposite side faces reflective and use them to transport current and to place a dielectric mirror on the other two side faces. In another aspect, an outcoupling layer on the surface can have a photonic structure.

Besides the production of a semiconductor and measures to improve light generation, another aspect deals with the direction of light emission. Particularly for μ-displays and also for many area displays a defined radiation characteristic should be achieved. Light generated in a μ-LED should on the one hand not interact with neighbouring μ-LEDs, on the other hand, the light should also be decoupled in order to optimise the light efficiency at a given current intensity. In the following aspects, different measures are presented to improve the radiation characteristics of an optoelectronic device or μ-LED by adding a layer around the active layer or the μ-LED surrounding reflective layers or mirror.

With some μ-LEDs, light is emitted laterally. This effect is often undesirable, because crosstalk to neighbouring pixels can lead to interference or other effects that worsen the visual impression. In addition, the light yield is lower. A Lambertian radiation characteristic of the display is also required for many applications. This means in particular that the display should be equally bright when viewed from all sides. A strong edge emission of the chip results in a non-Lambertian radiation characteristic.

The smallest μ-LED chips can be realized with a vertical design, i.e. with one contact each on the top and bottom side of the chip. In order to connect electrically a vertical μ-LED to a substrate, a so-called “top contact” must be deposited and structured on a second contact of the μ-LED (opposite or above the substrate). A planarization and/or passivation layer is also applied around the chip.

According to a first aspect, a method for manufacturing an array with at least one light-emitting body is proposed. The light-emitting body can be, among others, a μ-LED, one of the μ-rod already presented here, a μ-LED column or another component whose light also emerges laterally with a component parallel to the active layer. In the process, a first contact region and a second contact region are structured on one side of a substrate. The light-emitting body is also applied to the structure or produced there by structuring from several semiconductor layers.

Then a first metal mirror layer and a second metal mirror layer are applied, wherein the first metal mirror layer electrically connects a contact layer applied to a second contact of the light-emitting body with the second contact region and the second metal mirror layer is formed on a reflector structure arranged on the substrate. The reflector structure can be obtained from a planarization layer with subsequent structuring. In some aspects, the reflector structure frames the light-emitting body at a distance. In other aspects, part of the planarization layer can be structured so that it surrounds the light-emitting body.

An optoelectronic component comprises a light-emitting body electrically contacted, in particular by means of a first metal mirror layer, and a micro-reflector structure, in particular surrounding it, coated with a second metal mirror layer.

According to a second aspect, an array with at least one light emitting body is proposed, where on one side of a substrate a first contact of a vertical light emitting body is connected to a first contact area. On the same side of the substrate, a second contact of the vertical light-emitting body facing away from the substrate is connected to a second contact region by means of a, in particular semi-transparent, contact layer and a first metal mirror layer. In addition, a reflector structure is formed which has a second metal mirror layer on its side flanks and which surrounds the light-emitting body at a distance. The reflector structure includes reflective sidewalls in some aspects. These can run at an angle to deflect the light. In other aspects, the sidewall can also be non-linear, for example, square or parabolic.

The processing of a second contact or a top contact can be used to produce optical outcoupling structures on the substrate in a single step. A top contact here is formed in particular by a second contact of the light-emitting body, a contact layer, a first metal mirror layer and a second contact region. Here, the contact layer attached to the second contact of the light-emitting body is electrically connected to the second contact region by means of the first metal mirror layer.

An optical outcoupling structure is formed here by means of a reflector structure, in particular a micro-reflector structure, which is coated by means of a second metal mirror layer.

To establish a top contact, the light-emitting bodies are first embedded in a planarization layer. This can be opened photolithographically at the second contact area for the second contact or for the top contact (upper contact) on the substrate. This structuring process is used to form structures for reflectors, especially μ-reflectors, on the substrate from the planarization layer in the same step. After deposition of a transparent contact layer, a structured application of a metal mirror layer can be performed as a metal bridge between the second contact and the second contact area.

This is necessary because the contact layer is not suitable for bridging large differences in height. This metallization process can be used to mirror simultaneously reflector structures.

This makes the production of displays more cost-effective and faster, as conventional separate lithography processes for forming reflectors are no longer required. By providing reflectors from a planarization layer with a top contact metal mirror layer, efficiency and contrast can be increased and the radiation characteristics of the display improved without additional processing effort.

Some other aspects are mainly concerned with the arrangement and contacting of vertical μ-LEDs with a transparent and electrical cover layer. One of the aims is to improve the display properties when the number of pixels per unit area is high. Due to the spatial position of the electrical contact of a vertical μ-LED on the upper side facing away from the carrier substrate, the use of a transparent or at least partially transparent conductive material is considered, as already explained in this application. Known materials for this purpose are, for example, materials such as ITO (indium tin oxide), a transparent or partially transparent semiconducting mixed oxide for visible light, but this material has a relatively high surface resistance.

Therefore, a pixel element in the form of one or more μ-LEDs is proposed to generate a pixel of a display, which has a flat carrier substrate. A carrier substrate can be understood here as a backplane or carrier surface that provides a mechanically stabilizing holding function and additionally a supply of electrical connections for μ-LEDs. Possible materials for the carrier substrate can be insulating compounds, but also semiconductors such as silicon or III-V semiconductor materials. According to an example, the carrier substrate is designed to be flexible or bendable.

At least one μ-LED is arranged on the carrier substrate and designed to emit light transverse to a carrier substrate plane in a direction away from the carrier substrate. The at least one μ-LED can be attached to the carrier substrate, for example by gluing, fusing or as a result of an epitaxial layer process. The μ-LED is configured as a so-called vertical chip, with at least one contact in a spatial region of the μ-LED remote from the carrier substrate. The at least one μ-LED thus has an electrical contact on its upper side facing away from the carrier substrate. An upper side is to be understood here as a lateral surface or an area of an outer surface of the μ-LED where at least a part of the upper side is directed parallel to the carrier substrate plane.

Embodiment of the vertical μ-LEDs are mentioned here. These include, but are not limited to, the above-mentioned pairs of bars with converter material arranged in between, the upright or horizontally aligned μ-rods or even the antenna structure. Quantum well intermixing may be provided to prevent carriers from an edge or border of the active layer.

The electrical contact can, for example, be a metallic or generally electrically conductive surface. The idea here is that this surface should come into contact with a layer above it relative to the carrier substrate plane. The pixel element has an at least partially electrically conductive flat contact layer on the upper side of the emitter chip. This is electrically connected to the electrical contact of the emitter chip.

In other words, for example, an additional layer can be processed over the at least one μ-LED that comes into direct contact with the electrical contact of the at least one μ-LED. For example, this two-dimensional contacting layer can extend in one piece over a plurality of μ-LEDs and pixel elements. According to an example, this contacting layer forms a common cathode or a common anode. According to an example, the thickness of this contacting layer is between 80 and 150 nm.

The flat contacting layer is at least partially transparent for the light emitted by the at least one μ-LED. This means that light emitted by the at least one μ-LED can at least partially pass through the contacting layer. The known ITO materials can be used for this purpose, for example. A conductor track is provided on the contacting layer, which is electrically connected to the contacting layer over its entire surface. The electrical conductivity of the conductor track is greater than the electrical conductivity of the contacting layer. The conductor track can be designed, for example, planar or as a flat surface or strip.

The material of the conductor track is selected so that it has better electrical conduction properties than, for example, the ITO material. In other words, the conductor path is intended to bridge less conductive spatial regions of the contacting layer and thus cause an overall reduced electrical resistance across the contacting layer, also known as improved transverse conductivity. For this purpose, the conductor track should be connected to the contacting layer at at least two points remote from each other in order to reduce a total resistance of the arrangement of conductor track and contacting layer between these two points due to the increased conductivity of the conductor track.

For example, a conductor track can be understood as a bus bar, distribution bar or similar electrically conductive structure. According to an example, the conductor track is designed as a spatially delimited structure as part of the contacting layer itself. This can mean, for example, that within the contacting layer there are areas with different structures or with a modified combination of materials or substances, which have an improved electrical conductivity. A material of the conductor track can, for example, contain silver, aluminum, gold, chrome or nickel-vanadium.

According to an example, the contacting layer can be located in a gap between two adjacent μ-LEDs. In other words, the structure and arrangement of the μ-LEDs between the respective μ-LEDs results in gaps, which can be advantageously provided for accommodating the contacting layer. According to an example, the electrical contact of the at least one μ-LED is arranged on a lateral surface of the at least one μ-LED. In other words, the contacting layer contacts the contact of the at least one μ-LED for example in the area of the gap between two μ-LEDs.

In one aspect, the conductor path between two μ-LEDs arranged adjacent to each other on the carrier substrate is located outside a primary radiation range of the μ-LEDs. The consideration here is that the μ-LED, due to its structure, emits a large proportion of the light at right angles to the carrier substrate plane and away from this carrier substrate plane. It may be desirable that a high proportion of the light is emitted as vertically as possible, i.e. with a conical or ideally Lambertian radiation characteristic.

As a result, there is a need to suppress unwanted light outside this advantageous primary beam area to avoid crosstalk, crosstalk and unwanted reflections. For this reason, the mostly light-transparent tracks should not shade or restrict this primary beam area and are therefore advantageously positioned outside this primary beam area or beam corridor. This can be achieved in particular by creating a suitable spatial region for this purpose through the spaces between the μ-LEDs.

In one aspect, the track is designed to absorb and/or reflect light components of the light emitted by the at least one μ-LED outside of the primary emission range in order to shape the beam of the at least one μ-LED. In other words, this means that in addition to the function of improved electrical conductivity, an absorption function or reflection function of the conductive path with respect to the light emitted by the μ-LED can also be used.

The conductor path is thus deliberately placed in an area around the primary beam area of the at least one μ-LED, so that a beam-shaping effect is achieved. For example, the conductor path can be designed as a ring-shaped flat conductor structure running around an area of the at least one μ-LED. If three μ-LEDs are used as sub-pixels, each forming one pixel, the conductor structure can run around each pixel. According to another example, beam shaping can be achieved by providing a breakthrough in the conductor path through which the emitted light can pass.

In order to achieve improved absorption of unwanted light components outside a primary emission range of a μ-LED, the conductor path comprises according to an aspect a light-absorbing layer on its side facing the carrier substrate. This can be, according to an example, a separately applied layer of an absorbing material, but can also be implemented by surface structures on the conductor track.

In one aspect, the conductor path extends over a large area with a large number of μ-LEDs. In addition, recesses are provided on the conductor track in the area of the respective primary radiation areas of the μ-LEDs to pass through the light emitted by the respective μ-LEDs. These recesses can be, for example, breakthroughs, holes, gaps or similar structures through which the light emitted by the μ-LED can pass. In other words, the track can be provided as a continuous layer or as a continuous element. This can, among other things, advantageously permit more complex forms of apertures or recesses for beam shaping.

In one aspect, the conductor track is deposited to one side of the contacting layer facing away from the carrier substrate. In other words, the conductor path is located on a top side of the contacting layer, for example as an element that is sequentially applied subsequently during the manufacturing process. In another aspect, the conductor track is deposited to a side of the contacting layer facing the carrier substrate. In other words, the track is under an ITO bonding layer when viewed from the carrier substrate.

According to another aspect, the conductor track is applied to the carrier substrate. The adjacent arrangement of several μ-LEDs to each other results in corresponding gaps. These gaps can reach down to a height or level of the carrier substrate itself. It is conceivable here that a planarization layer is not continuous, but is recessed in the area of this gap. A manufacturing advantage can be that the conductor path is produced directly on the carrier substrate and the contacting layer is applied vertically above it.

According to an aspect, the at least one μ-LED is located in a cavity of the carrier substrate and the conductor track is located outside the cavity. The carrier substrate can thus be understood as a structured surface, for example, which is not continuously flat or planar, but comprises depressions. The μ-LEDs are placed in these recesses or pits, whereby sidewalls of these recesses can be used as a reflection surface for beam shaping. In order to avoid shading and absorption, one or more conductive tracks are placed outside the depression.

According to an aspect, a connecting element is provided on the pixel element for the electrical connection of the contacting layer with a terminal element of the carrier substrate. The consideration here can be seen in the fact that a contacting layer arranged above the carrier substrate forms, for example, a common anode or a common cathode and must therefore be electrically connected. This can be achieved by a connection element being attached electrically conductively with one end to the contacting layer and with another end to a conductor structure of the carrier substrate. This connection element can, for example, be arranged on an outer edge area of one or more pixel elements.

Another aspect deals with the production of one or more pixel elements for a display. In a first step, a flat carrier substrate is provided and a large number of light-emitting components are manufactured on it. The components can be produced with common methods by depositing, doping and structuring different semiconductor layers. Typical material systems are based on GaN, including for example GaN, GaNP, GaNInP, GaNAlP and others. The large number of light-emitting devices have a main radiation direction that points away from the carrier substrate. In addition, an electrical contact is provided on the surface of each of the plurality of light-emitting devices facing away from the carrier substrate. Furthermore, an at least partially electrically conductive flat contacting layer is deposited, which is electrically connected to the electrical contacts of the plurality of light-emitting components. The contacting layer can extend in one aspect over the carrier substrate and cover the components. The contacting layer is at least partially transparent to the light emitted by the semiconductor components during operation. At least one conductor track is provided on the contacting layer, which is electrically connected to the contacting layer and is connected flat to the contacting layer. Here the electrical conductivity of the conductor track is greater than an electrical conductivity of the contacting layer.

The aspects presented above for a reflective layer or mirror can also be applied to other designs of μ-LED realizations, for example to the vertical μ-LEDs with circumferential structure. Various designs based on vertical or horizontal μ-LED architectures are suitable for the production of μ-LED displays. Short switching times combined with sufficient current carrying capacity are of particular importance. At the same time, the light emitted should be as collimated as possible.

When horizontal μ-LEDs are used, both the anode and cathode contacts are usually realized by means of separate metallic lead wires, both contacts are located on the underside of the chip. For both the cathode and the anode, the metallic leads are led to each pixel. When vertical μ-LED chips are used, the anode contact on the underside of the chip is realized by separate metallic leads, while the cathode contact on the top of each chip is realized by a common cathode. In both cases, the supply lines should be as short as possible to keep parasitic capacitances low.

As already explained, the μ-LEDs are manufactured either monolithically or individually and then further processed on a substrate. The backplane (in case of a backplane assembly; in case of a monolithic assembly, the backplane can also serve as a substrate or the growth substrate is replaced by the backplane) contains the control electronics. A distinction is made between passive matrix backplanes with IC circuits and active matrix backplanes with TFT circuits. In passive matrix backplanes with IC circuits for driving the LED, the cathode and anode leads are usually routed directly to the pixels or in subpixels. The pixels or subpixels are controlled by the micro-integrated circuits.

In the realization of active matrix backplanes, the individual pixels are controlled by integrated TFT circuits (TFT=Thin Film Transistor).

An arrangement is now proposed in which the supply lines can be kept short in order to achieve high switching times. In addition, a common cathode or anode connection is realized. This arrangement is particularly suitable for generating pixels for a μ-display module, which in turn can be individually addressed and controlled. The setup can be supplemented with additional measures, such as the above-mentioned circumferential mirror structures. This also reduces optical crosstalk into adjacent pixels in some aspects.

According to a first aspect, a device with a substrate and a μ-LED die fixed to one side of the substrate is proposed. The chip comprises an electrical contact on a side facing away from the substrate, which is electrically connected to an electrical control contact by means of a mirror coating, whereby the mirror coating at least partially covers the substrate surface facing the die.

The mirroring therefore has two functions. On the one hand, it serves to deflect light in the direction of radiation, on the other hand, it transports the current. By means of the common cover contact or the common cover electrode, fast-switching times for μ-displays can be realized. This enables the provision of pulse width modulation dimming concepts, especially for improving panel efficiency in combination with an improvement of optical parameters, such as the angle dependence of an emission and the contrast.

In a method of manufacturing such an arrangement, a substrate with a number of contacts is first provided on the surface and a μ-LED die is attached to one of these contacts. The attachment can use conventional transfer and attachment techniques, some of which are also presented in this disclosure. The μ-LED die is configured as a vertical die and also includes a contact on one of the substrate surfaces. A reflective layer is formed on the substrate surface, which is electrically connected to an electrical control contact on the surface of the substrate and covers the surface at least partially. In a last step, a transparent cover electrode is formed on the further contact, which electrically contacts the mirror coating.

In addition, the use of a mirror coating to expand the current, improve the current carrying capacity and switching times can also be implemented in combination with cavity structures. Such cavities can then also be used to improve decoupling efficiency, the angle dependence of emissions and contrast. For this purpose, some aspects of the substrate include an elevation surrounding the μ-LED die. Alternatively, instead of an elevation, a cavity can be provided in the substrate surface in which the μ-LED die is located. In addition to one μ-LED die, three μ-LED die can be surrounded or arranged so that they form a single pixel as subpixels.

In both cases, optionally bevelled side surfaces of the cavity or the elevation are provided with the mirror coating. This structure is similar to the one mentioned above. The angle of these side surfaces with the substrate surface can have different values depending on the desired characteristics. In particular, it can also change so that the side flanks show a parabolic or other non-linear course. In some aspects, the circumferential mirror structure disclosed in this application can be used. The height of the elevation or the depth of the cavity is chosen so that the μ-LED die is flush with the top of the elevation or cavity. This allows the cover electrode to terminate. This is particularly useful, if the mirror coating is arranged on the top side so that the cover electrode rests on the mirror coating.

In some aspects, a gap between μ-LED die or the region within an elevation or a cavity is filled with a transparent insulation layer, which thus surrounds the dies. The transparent insulation layer closes especially at the level of the remote contact of the die, so that the cover electrode rests on the insulating material.

In some aspects, the mirror surface arranged on the substrate surface and possibly surrounding structure surrounds not only one but a large number of dies. These can be designed as redundant chips, so that if one chip fails, the other one can take over the function. A more uniform radiation is generated by a circumferentially arranged mirror surface. Several dies can also be arranged within the circumferential mirror surface to generate light of different wavelengths. A circumferential mirror surface can separate different pixels from each other so that optical crosstalk between pixels is reduced.

The mirror coating is connected in series with the cover electrode and the control contact of the substrate and comprises a highly reflective material, in particular of Al, Ag, AgPdCu, Nd, Nb, La, Au, Cu, Pd, Pt, Mg, Mo, Cr, Ni, Os, Sn, Zn as well as alloys or combinations thereof. These others also effectively increase the current. The cover electrode may comprise a transparent electrically conductive oxide layer, in particular a material made of ITO, IGZO. Further examples of cover electrode material can be transparent conductive oxides, such as metal oxides, zinc oxide, tin oxide, cadmium oxide, indium-doped tin oxide (ITO), aluminum-doped tin oxide (AZO), Zn₂SnO₄, CdSnO₃, ZnSnO₃, In₄Sn₃O₁₂ or mixtures of different transparent conductive oxides.

The transparent insulating layer may include SiO or other insulating transparent materials mentioned here.

According to a further embodiment, the direct electrical contact of the cover electrode with the mirror coating can be created by means of a contacting overlap of a cover electrode surface and a mirror coating surface, especially on the surface of the elevation or at one end of a recess or cavity. In this way, a reliable low-impedance contact can also be provided. Particularly in the case of several such cavities or elevations arranged in series, the cover electrode can rest on several mirror coatings. This allows the current to be applied to the cover electrode over a large area and at several positions.

In some aspects, the mirror layer runs along the surface of the substrate and especially partly around the μ-LED die(s). This increases the reflection over a large area, including the substrate surface.

In order to ensure contact, a direct electrical contact of the cover electrode with the mirror coating is provided by a through-hole plating or a via of the mirror coating material through a planarization and/or insulation layer. Additional process steps for realizing a metallic contact between the conductive oxide of the cover electrode and the contact areas on the backplane/substrate are not necessary. A simple bridge can be created from, for example, the ITO cover contact to the CrAl contact area for ACF bonding. This can lead to further cost savings. This via can be realized as openings. In other designs, however, a trench or other structure can be provided in the transparent insulation layer, the inner walls of which are filled with a conductive reflective layer for contacting. This creates a good electrical contact on the one hand and a reflective structure on the other hand and in addition to good light reflection, optical crosstalk is reduced in some areas.

In some cases, the isolation layer at the edge of a pixel is bevelled and the reflective layer is exposed. The cover electrode extends along this sloped surface and thus contacts the reflective layer. In this way, a compact design can be provided. The flanks or inner walls of the opening have an angle depending on the desired radiation characteristics. These can correspond to those revealed here. In this way, further material breakage at transition edges can be avoided.

Another aspect deals with the production of a pixel or μ-LED module, which comprises a plurality of these μ-LED dies arranged in rows and columns. Each pixel can be embedded in a cavity or surrounded by a raised area. The cover electrode can thus be used as a common connection for a plurality of such μ-LED dies. Decoupling structures can also be provided on the cover electrode. The photonic structures disclosed herein are particularly suitable for further collimation of light. Converters can also be attached to the cover electrode. In this way, a μ-LED die type can be used which, for example, generates blue light in order to convert it by means of the converter layer. In this case, further reflective structures can be built on the cover electrode to avoid optical crosstalk into another pixel. In addition, photonic structures that collimate the converted light are also conceivable here again.

Nano light emitting diode arrays applied in a matrix arrangement and vertically layered nanopillars or nano rods are already described in this disclosure in connection with the stimulated emission in the slotted antenna structure. A characteristic of nanopillars is their high aspect ratio, i.e. their height compared to their footprint, which is typically in the range of 1 μm² and smaller.

Compared to light emitting diodes with planar-extended semiconductor layer stacks, the quasi one-dimensionality of a nanopillar and the resulting reduced requirement for lattice matching offers the advantage of a more flexible material composition for the formation of the active layer. This results in an improved spectral adjustability of the light emission, which can additionally be influenced by the targeted incorporation of strains and the determination of the expansion of the active layer. This results in the possibility of the stimulated emission described above. However, columns for the emission of different colored light can also be created with different material systems and/or tensions or doping.

Depending on the manufacturing variant, nanopillars are produced starting from a planar semiconductor layer system with layers that comprise a different conductivity type (n- or μ-doping). An active layer in the semiconductor layer system typically comprises a quantum well structure. By means of photolithographic techniques, a structuring is then carried out which extends at least into the depth of the active layer and which serves to work out nanopillars with a laterally bounded disc-shaped active zone from the planar semiconductor layer system.

A second manufacturing variant for a nano-luminescent diode device is achieved by epitaxial growth of nano-layer structures in the form of upright nanocolumns of III-V semiconductors, in particular (AlxInyGa1-x-y)N, starting from a structured n-gallium nitride layer on a carrier substrate, such as Al₂O₃, SiC or ZnO. The nanopillars have a core-shell structure with an elongated core, an active layer covering the core and a shell layer with a charge carrier polarity different from the material of the core.

The area between adjacent nanopillars is filled with an insulating material that serves as a base for a transparent contacting layer. Alternatively, the upper contact layer can form bridge structures spanning air-filled sections between the nanopillars.

The starting point of the following considerations for improving a nano-light emitting diode array is an array comprising a carrier substrate and a nanopillar at least indirectly connected to the carrier substrate and pointing in a longitudinal direction from the latter. Preferably, a matrix arrangement with several nanopillars is present on the carrier substrate. Each nanopillar comprises a semiconductor sequence with at least one active layer, which generates electromagnetic radiation and is arranged in such a way that at least part of the radiation emission is transverse to the longitudinal direction. According to the proposed concept, a reflector device is arranged on the carrier substrate laterally to the nanopillar, which deflects the radiation emission transversely to the longitudinal direction at least partially into a main radiation direction running parallel to the longitudinal direction. This reduces the radiation angle of the nano light emitting diode arrangement and, due to the precollimation achieved, facilitates beam coupling into optical components following in the beam path.

For advantageous embodiment, the reflector device comprises a first reflective optical element and a second reflective optical element arranged on different sides of an associated nanopillar. It is also advantageous to provide a reflector device between each two adjacent nanopillars.

The nanopillar emitting electromagnetic radiation can be part of a pixel for a lighting or display device. For a possible design, each pixel comprises a single nanopillar and a reflector device associated with and surrounding it. For a further embodiment, a pixel comprises several nanopillars according to some aspects, whereby the reflector device associated with the pixel may surround the nanopillars of the pixel. For a design alternative, there are multiple reflector devices within a pixel, wherein a separate reflector device is provided for each of the nanopillars of the pixel.

A pixel can be designed for spectral adaptability of light emission, for example as an RGB pixel. For designs with several nanopillars per pixel, they can be designed for different colors. It is conceivable either to adapt the active layer of the respective nanopillar or to adjust the color by locally embedding the nanopillars in different light conversion materials. Furthermore, the n- and/or the p-contacts are structured so that a pixel and/or parts of a pixel, in particular individual nanopillars or groups of nanopillars, can be individually energized.

For an embodiment, the nano light emitting diode array has a molded layer that is monolithically formed with a layer of the semiconductor sequence of the nano column. These layers can be one-piece and result from a common manufacturing process or from successive manufacturing steps with the same substrate.

To improve the degree of reflection, the reflector device has a metallic reflective layer and/or a Bragg mirror in some aspects. In other aspects, the embodiment features a Fresnel lens arrangement incorporated into the reflector device to improve the collimation effect further. Furthermore, a wavelength conversion element is arranged for further shaping in the beam path between the nanopillar and the reflector device, wherein a first wavelength conversion element associated with a first nanopillar is arranged for emitting electromagnetic radiation, which is spectrally different from the emission of a second wavelength conversion element associated with a second nanopillar. For an embodiment alternative of the nano-luminous diode arrangement, at least some of the nanopillars have a lateral direction in which no reflector device is arranged. Instead, an optical separating element may be provided in this direction between adjacent nanopillars.

The method of manufacturing a nano light emitting diode device according to these principles comprises a photolithographic patterning of at least one shaped layer of the reflector device and/or a layer of the semiconductor sequence of the nano column. Furthermore, a structuring of the reflector device with an anisotropic etching process is provided as well as the application of an etch stop layer to form the nanopillar with a high aspect ratio. For a further preferred manufacturing process, the form layer of the reflector device and/or a layer of the semiconductor sequence of the nanopillar is epitaxially grown. A further manufacturing alternative is offered by a nano stamping process.

As already mentioned several times, the light emerging from the sidewalls is deflected by a reflector layer to reduce light loss. In another approach a reflective interface is proposed, which is placed directly on the lateral surface of the optoelectronic device. Accordingly, this approach can be realized in monolithic structures as well as in single optoelectronic devices. This approach can also be applied to a μ-LED nanopillar or a semiconductor layer stack, as proposed for example in the antenna structure.

In one aspect, an optoelectronic device comprises at least one optoelectronic light source based on semiconductor materials, in particular in the form of a μ-LED, which has an active zone for generating light, a light exit surface for the generated light being formed on an upper side of the light source, the light source having, in addition to the upper side, at least one further boundary surface which delimits the light source on the side and/or downwards, and a dielectric reflector which is configured to reflect the generated light being arranged at the boundary surface.

In contrast to or in addition to the other measures of a reflecting mirror, here a dielectric reflector is applied directly to the interface. Without the dielectric reflector, light generated in the light source could escape sideways and/or downwards and, in particular, enter a material of a carrier of the device surrounding the light source. In contrast, the dielectric reflector at least partially reflects light incident on the interface back into the interior of the light source. The use of the dielectric reflector can thus at least partially prevent light escaping sideways and/or downwards from the light source. Ideally, the reflected light escapes through the light exit surface, for example after further reflections. The light yield can thus be increased by the dielectric reflector. At the same time, the component is very small.

The interface may have a lateral surface circumferentially surrounding the light source and a lower surface of the light source, the lower surface being opposite the upper surface. The dielectric reflector can be arranged exclusively on the side surface or exclusively on the bottom surface. Alternatively, the dielectric reflector can be arranged on the side surface as well as on the bottom. Therefore, with the exception of the top surface, the dielectric reflector can be arranged on the entire boundary surface bounding the light source. The dielectric reflector can therefore surround the entire light source—with the exception of the top side —, which allows a relatively large increase in light yield.

The dielectric reflector can comprise a sequence, in particular periodic or non-periodic, of a number of material layers lying one above the other, at least two directly successive material layers having different refractive indices. In particular, the dielectric reflector can consist of a periodic sequence of two alternating dielectric material layers, which have different refractive indices. The thickness of the material layers can be adapted to a wavelength of the light emitted by the light source to achieve the highest possible reflection.

A non-periodic sequence of material layers can, at least in some embodiments, create a comparable mirror effect with thinner layers—compared to a periodic layer sequence. In particular, the dielectric reflector can be adapted as a Bragg mirror. Bragg mirrors are known per se. They are also known as distributed Bragg reflectors, abbreviated DBR.

A Bragg mirror can be formed by a periodic arrangement of two alternating thin layers of material with different refractive indices. Usually the layers consist of dielectrics based on semiconductor materials. At an interface between two layers of material, part of the incident light is reflected according to the so-called Fresnel formulas. A constructive interference between the reflected beams is formed when the wavelength is close to four times the optical wavelength in the respective material layer.

The wavelength range in which the reflection of Bragg mirrors is very high, especially with vertically incident light, and can at least theoretically reach 100% with a very high number of alternating layers, is called stop band. Light whose wavelength lies within the stop band of a Bragg mirror is reflected at least to a high degree and ideally cannot propagate through the Bragg mirror.

The reflector designed as a Bragg mirror is therefore preferably designed so that the wavelength of the light emitted by the light source lies within the stop band, especially in its center. The material layers of the Bragg reflector are then matched in thickness to the wavelength of the emitted light. The optical thickness of the layers is preferably a quarter of the wavelength of the emitted light. The optical thickness corresponds to the product of layer thickness and optical refractive index.

Some aspects of this concept also apply to an optoelectronic arrangement such as a display array or monolithic array or a headlamp such as a matrix headlamp, the optoelectronic arrangement comprising a plurality of the proposed optoelectronic devices, the light sources of the optoelectronic devices being arrayed. Each light source can form one pixel of the display order or monolithic array. It may be provided that each light source emits light in one of a number of predetermined colors, for example red, green and blue. Each light source can form a sub-pixel of a pixel, where a pixel is formed by several light sources, each of which emits light in one of the colors.

The light sources of optoelectronic devices may be embedded in a carrier, in particular in such a way that only the light exit surfaces of the light sources constitute free external surfaces, while a respective interface of the light sources is surrounded by carrier material. The dielectric reflector of an optoelectronic device may be located between the interface of the light source and the carrier material. For example, the substrate may comprise one or more layers of semiconductor materials. The layers may include electrical conductors, for example in the form of one or more layers of conductive tracks. Electronic circuits may also be present to supply or control the light sources. For example, the conductors can be used to supply the light sources with electrical power.

Further aspects of the concept presented also relate to a method of manufacturing an optoelectronic device, in particular a display device or headlamp, in which an optoelectronic light source based on semiconductor materials is provided, wherein the light source has an active zone for generating light and, on an upper side, a light exit surface for the generated light, and wherein a dielectric reflector is arranged at at least one interface of the light source, which is configured to reflect the generated light, and wherein the interface limits the light source to the side and/or downwards.

The interface may form the remaining outer surface of the light source with the exception of the upper surface. The reflector may cover all or part of the interface.

Likewise, a method of manufacturing an optoelectronic device, such as a display arrangement or a headlight arrangement, shall be presented. In some aspects, in the method, the light sources of a plurality of optoelectronic devices of the invention are arrayed and embedded in a carrier in such a way that only the light exit surfaces of the light sources are free external surfaces, while material of the carrier surrounds the interfaces of the light sources. A dielectric reflector can be arranged between the material of the carrier and a respective interface of a light source. This step can be done before a light source is embedded in the substrate.

The proposed concept also concerns a method of manufacturing an optoelectronic arrangement, for example a monolithic array or a headlamp, in particular with a large number of the proposed optoelectronic devices or μ-LEDs. In the method, a plurality of optoelectronic light sources based on semiconductor materials are formed in an array on a carrier in such a way that each light source has an active zone for generating light and a free, outer upper side as a light exit surface for the light, and wherein for each light source a dielectric reflector is arranged at at least one boundary surface which delimits the light source laterally and/or downwardly with respect to a material of the carrier, which dielectric reflector is configured to reflect the generated light.

The arrangement of the dielectric reflector may include the application of material for the dielectric reflector by means of atomic layer deposition. The materials for forming the dielectric reflector can be deposited in extremely thin layers. Layer thicknesses corresponding to atomic monolayers can be realized. This makes it possible to deposit layers with precisely defined thicknesses even on non-planar (e.g. curved) surfaces. Atomic layer deposition is a simple way to produce a reflector, in particular a Bragg mirror.

As material for the dielectric layers of the reflector with high refractive index can be used for example Nb₂O₅, TiO₂, ZrO₂, HfO₂, Al₂O₃, Ta₂O₅ or ZnO. For the dielectric layers with low refractive index, SiO₂, SiN, SiON or MgF₂ can be used.

The placement of the dielectric reflector may include placing the material for at least one layer of the dielectric reflector by a first method and placing the material for the other layers by a second method. In particular, a layer directly adjacent to the interface of a light source can be arranged by means of the first method. The first method can be, for example, a vapour phase deposition method, such as in particular CVD (for chemical vapour deposition) or PE-CVD (for plasma-enhanced chemical vapour deposition). This allows unevenness at the interface, for example a rough surface resulting from an etching process, to be covered by a more conformal deposition. The other layers of the dielectric mirror can then be created on a smooth surface.

The second process may be atomic layer deposition. In this way layers for the dielectric reflector with defined thicknesses can be formed.

Another aspect also concerns a process for the manufacture of an optoelectronic arrangement or in which method optoelectronic light sources based on semiconductor materials are arranged in an array on a carrier in such a way that each light source has an active zone for generating light and, on the upper side, a free, externally located upper side as a light exit surface for the light, the light sources being arranged in such a way that there is at least a slight gap between adjacent light sources on the upper side with an intermediate space behind it, wherein for each light source at least one light exit surface is located on the carrier, the light source is arranged in relation to a boundary surface bounding material of the support to the side and/or downwards, a dielectric reflector is arranged which is configured to reflect the light generated in the light source, and wherein the dielectric reflectors of the light sources are formed by introducing, for example by means of atomic layer deposition, material for the dielectric reflectors from the top side into the respective gap between adjacent light sources and the dielectric reflectors are formed in the respective gap located behind a gap.

At least the light exit surfaces of the light sources can be covered, especially with a photomask, while the dielectric reflectors are formed in the gaps. The photomask can be removed after finishing the reflectors. The headlamp mentioned as an example can be a matrix headlamp. Accordingly, the headlamp arrangement can be a matrix headlamp arrangement.

A further aspect is concerned with improving the radiation characteristics of a μ-LED, which is a dielectric filter with additional reflecting sides. An optoelectronic device, in particular a μ-LED according to a first aspect of the present disclosure, comprises at least a semiconductor element, a dielectric filter and a reflective material. Furthermore, the optoelectronic device may contain components, for example the components described in this disclosure.

The at least one semiconductor element contains an active region designed to generate light. It can be configured in particular as a vertical or horizontal μ-LED. Measures like quantum well intermixing and similar are possible to increase the efficiency of the device. Furthermore the at least one semiconductor element comprises a first main surface, a second main surface opposite to the first main surface and at least one side surface extending between the two main surfaces. For example, the at least one semiconductor element may have three or four or more side surfaces. However, it is also possible that the at least one semiconductor element has round main surfaces and therefore has only one side surface.

The dielectric filter is located above the first main surface of the at least one semiconductor element and is configured to transmit only light entering the dielectric filter in predetermined directions.

For example, the dielectric filter can be designed in such a way that it only transmits light in a given angular cone. The angle cone is aligned with its axis perpendicular to the first main surface of the at least one semiconductor element. The angle between the surface or surface lines of the cone and the axis of the cone, i.e. half the opening angle of the cone, can have a predetermined value. For example, the half aperture angle of the cone may be maximum 5° or maximum 15° or maximum 30° or maximum 60°. Light components entering the dielectric filter from the semiconductor element at an angle within the predetermined angle cone are transmitted, the remaining light components are substantially not transmitted and, for example, reflected back into the semiconductor element. This enables a high directionality of the light emitted by the optoelectronic device.

The dielectric filter may be designed such that the angle cone has a very small aperture angle, which means that substantially only light exiting the semiconductor element perpendicular to the first main surface is transmitted by the dielectric filter.

The dielectric filter can be formed by a stack of dielectric layers, which are applied to the semiconductor element by coating and in particular have a high transmission. For example, the dielectric layers in the stack may alternately have a low and a high refractive index. As material for the dielectric layers with high refractive index, for example Nb₂O₅, TiO₂, ZrO₂, HfO₂, Al₂O₃, Ta₂O₅ or ZnO can be used. For the dielectric layers with low refractive index SiO₂, SiN, SiON or MgF₂ can be used. The stack of dielectric layers with alternating high and low refractive index can be configured as a Bragg filter. Furthermore, the dielectric filter can be a photonic crystal.

The reflective material is deposited on the side surface(s) of the at least one semiconductor element and the dielectric filter. It may be provided that the reflective material covers at least one or more or all of the side faces of the at least one semiconductor element. In the same way, the reflective material may cover at least one or more or all of the lateral faces of the dielectric filter. In one configuration, the reflective material completely encloses laterally both the at least one semiconductor element and the dielectric filter.

The reflective material may be reflective to the light emitted by the at least one semiconductor element or at least one wavelength range of that light. Consequently, light which emerges through the side faces of the at least one semiconductor element or the dielectric filter is reflected back again, thereby increasing the efficiency of the optoelectronic device.

Several components can also be provided. These in turn comprise one or more semiconductor elements, each of which has the properties described above. A dielectric filter is arranged on each semiconductor element. In addition, the semiconductor elements are surrounded by the reflective material. Additionally or alternatively, several components with their semiconductor elements can also be surrounded by such a mirror. For example, such an embodiment allows redundancy to be provided so that if one semiconductor element fails, a redundant semiconductor element can take over the function. The semiconductor elements can, for example, be arranged in an array, i.e. a regular arrangement.

The optoelectronic component may be contained in a display, i.e. an indicating device. Each of the semiconductor elements can represent one pixel of the display. In addition, each of the semiconductor elements can represent a sub-pixel of a pixel, each pixel being formed by several sub-pixels emitting, for example, light with the colors red, green and blue.

The reflective material surrounding the individual semiconductor elements and the respective dielectric filters on each side achieves a high contrast between adjacent pixels. A high pixel density is also possible. According to an embodiment, the semiconductor elements are designed as μ-LEDs. A μ-LED has small lateral expansions in the light emitting plane, especially in the μm range. In contrast to μ-LEDs in a monolithic array, separate μ-LEDs each form a self-contained unit that can be set and operated individually and also at a greater distance from each other. The light emitted by the semiconductor elements can, for example, be light in the visible range, ultraviolet (UV) light and/or infrared (IR) light.

In addition to displays, the optoelectronic component can also be used in AR (augmented reality) applications or in other applications for pixelated arrays or pixelated light sources, for example, according to the first aspect of the disclosure.

According to an embodiment, at least one or more or all side surfaces of the at least one semiconductor element run diagonally at the height of the active zone. This means that at least a part of the respective side face encloses an angle with the first main surface of the at least one semiconductor element which is unequal to 90° and in particular smaller than 90°. The at least one semiconductor element may be bevelled over its entire height or only partially, the active region should in any case be located in the bevelled area. The lateral faces, which are totally or partially tapered, can form an interface with an insulating layer having a low refractive index. Light emitted in the horizontal direction is reflected by the tapered side surfaces towards the component surface.

The at least one semiconductor element may have a first electrical connection and a second electrical connection. For example, one terminal may represent a cathode and the other terminal an anode. Furthermore, the reflective material may be electrically conductive and electrically coupled to the first terminal of the at least one semiconductor element. In particular, the first terminal may be connected to an n-doped region of the at least one semiconductor element. The reflective material thus provides both an optical separation between adjacent pixels and also causes an electrical contact to the at least one semiconductor element.

If several optoelectronic components with a large number of semiconductor elements are provided, the reflective as well as electrically conductive material surrounding the respective semiconductor elements can be interconnected, which makes it possible to drive jointly the first terminals of the semiconductor elements from outside. In this case, the second terminals of the semiconductor elements can be individually controlled, for example, via the underside of the semiconductor elements. Since only one contact with a good resolution has to be defined, this design is advantageous for the production and also facilitates the production of very small pixels where the area would not be sufficient to attach two separate contacts to the underside of the chip. The reflective material can, for example, be or contain a metal and can be electrodeposited.

A reflective layer may be disposed below the second main surface of the at least one semiconductor element. As a result, light emerging through the second main surface is reflected back into the semiconductor element and emerges from the optoelectronic device completely through the top surface. Furthermore, the reflective layer may be electrically conductive and may be coupled to the second terminal of the at least one semiconductor element. For example, the second terminal can be connected to a p-doped region of the at least one semiconductor element. The reflective layer thus serves, in addition to its reflective properties, to create an electrical contact with the at least one semiconductor element. It may be provided that the second terminal of each semiconductor element can be individually controlled.

The same material can, but does not have to be used for the reflective layer as for the reflective material. For example, a metal can be used for the reflective layer.

Alternatively to the embodiment described above, the reflective layer may be electrically insulating and one or more electrically conductive layers may be arranged above and/or below the reflective layer, in particular coupled to the second terminal of the at least one semiconductor element. In this case, the reflecting layer may, for example, be a dielectric mirror and may be arranged in particular over a metal layer. The electrical contact is then made via a feedthrough through the dielectric layer or via a lateral surface of the dielectric layer. Furthermore, an electrically conductive and transparent layer can be arranged above the reflecting layer, i.e. between the at least one semiconductor element and the reflecting layer. The material for the electrically conductive and transparent layer can be indium tin oxide (ITO), for example.

According to an embodiment, a silver mirror is arranged below the electrically conductive and transparent layer, for example of indium tin oxide, and the dielectric mirror. Alternatively, only an electrically conductive and transparent layer, for example of indium tin oxide, and a silver mirror can be arranged below the at least one semiconductor element.

An electrically insulating first material can be arranged between the reflective material and the reflective layer. The electrically insulating first material may also be in direct contact with one or more of the lateral faces of the at least one semiconductor element, in particular with the bevelled part of the lateral faces. Furthermore, the electrically insulating first material may have a lower refractive index than the at least one semiconductor element, in particular than the at least one semiconductor element in the region of the interface with the electrically insulating first material. The electrically insulating first material thus provides electrical insulation between the first and second terminals of the at least one semiconductor element. Furthermore, light can be reflected back at the interface between the at least one semiconductor element and the electrically insulating first material due to the refractive index contrast.

The electrically insulating first material may, for example, consist of SiO₂ and be deposited in a deposition process, in particular a gas phase deposition process, for example with TEOS (tetraethylorthosilicate), or another process, for example based on silane, in order to be able to fill high aspect ratios.

Between the at least one semiconductor element and the dielectric filter, i.e. on the first main surface of the at least one semiconductor element, there may be a layer with a roughened surface which is designed to deflect light in other spatial directions or to scatter light. The layer may have a Lambertian radiation characteristic. Furthermore, the layer can be configured in such a way that light components are deflected at angles beyond the limit angle for total reflection, so that in principle all components can be decoupled and do not remain “trapped” in the component.

The layer described above can, for example, consist of a randomly or deterministically structured semiconductor surface. The surface may have a roughened structure with sloping edges, whereby the roughened structure in the case of μ-LEDs has a height of a few 100 nm at most. The roughened structure can be created by etching, for example.

It is still possible not to use the layer described above and instead roughen the first main surface of the at least one semiconductor element. For this purpose, for example, a random or deterministic topology can be etched into the first main surface in order to achieve a Lambertian radiation characteristic in particular. The roughened first main surface of the at least one semiconductor element may have the same properties as the roughened surface of the layer described above.

On the roughened surface of the at least one semiconductor element or the layer arranged above it, a further layer, for example of SiO₂, may be deposited which has a different refractive index than the layer below it and also has a flat upper surface. This additional layer enables the application of the dielectric filter due to its flat upper surface and at the same time maintains the functionality of the underlying roughened surface due to the refractive index difference.

The small lateral extension of a pixel of 50 μm or less allows a low height of at least one semiconductor element in the μm-range. In particular, the at least one semiconductor element may have a lateral expansion or edge length of at most 50 μm and/or a height of at most 1 μm to 2 μm.

As described above, a device may contain several optoelectronic components, which may be of the shapes described in this application. Each of the semiconductor elements of a device, together with the associated dielectric filter and the reflective layer disposed beneath the respective semiconductor element, may be completely surrounded laterally by the reflective material. According to an embodiment, the semiconductor elements are arranged in an array with adjacent semiconductor elements separated by the reflecting material. Consequently, the reflective material forms a grating and adjacent semiconductor elements are separated only by the grating.

If the reflective material is also electrically conductive, the first terminals of all semiconductor elements can be connected to a common external terminal via the reflective material. The second terminals of the semiconductor elements can be individually controlled.

According to an alternative design, the several semiconductor elements, each surrounded laterally by the reflective material, are arranged next to each other, with an electrically insulating second material between adjacent semiconductor elements. For example, the electrically insulating second material can be a potting material.

The reflective material can also be electrically conductive in this embodiment. In order to connect the first terminals of the semiconductor elements to a common external terminal, conductive tracks may extend above and/or below and/or within the electrically insulating second material connecting the first terminals of the semiconductor elements to the common external terminal. The second terminals of the semiconductor elements can be driven individually.

A process according to a second aspect of the present application is used to manufacture an optoelectronic device. The method comprises providing at least one semiconductor element having an active region adapted to generate light, and placing a dielectric filter above a first main surface of the at least one semiconductor element. The dielectric filter is adapted to transmit only light in predetermined directions. A reflective material is further deposited on at least one side surface of the at least one semiconductor element and on at least one side surface of the dielectric filter.

The method of manufacturing an optoelectronic device according to the second aspect of the application may have the above-described configurations of the optoelectronic device according to the first aspect of the application.

In the following aspects of the Processing and methods for the production of a μ-LED or a μ-display or module are examined in more detail. However, as already explained above, aspects of processing also include aspects relating to semiconductor structures or materials and vice versa. In this respect, the following aspects can be combined with the previous ones without any problems.

Due to the manufacturing process and the extremely small dimensions of individual optical elements, it can sometimes happen that individual pixel elements from the plurality of pixels in a display can be defective. This problem has an increased impact on monolithic μ-display modules, since defects or variations in production lead very quickly to the failure of a pixel due to its small size. If the defect density becomes too high, the entire module has to be replaced. Especially with monolithic displays, individual defective pixels cannot be replaced.

Known solutions try to compensate for a failed pixel, for example, by adjusting surrounding or adjacent pixels to a higher luminosity and thereby at least partially compensating for the missing light of the defective pixel. Since in many cases the replacement or repair of these defective pixels does not appear to be economically and procedurally sensible, it is desirable to be able to use a manufactured display with sufficiently good quality despite isolated defective pixels.

The aspects described below concerning Pixel elements with electrically separated and optically coupled subpixels can compensate for such small defects so that an improved yield is achieved while maintaining the quality of the μ-displays or μ-display modules. These aspects are based on the consideration to use measures suitable for the prevention of optical crosstalk. Therefore, the measures proposed in the following are not only suitable for the above mentioned task, but a reduction of optical crosstalk has further advantages, if μ-LEDs are very close to each other especially in monolithic components and a good optical separation should be achieved. In very densely packed monolithic arrays or μ-displays or μ-display modules, a clean optical separation between pixels is necessary to prevent the emitted light of a μ-LED from radiating into an area of an adjacent pixel. To prevent optical crosstalk, trenches, or more generally, optically separating structures are often provided between two μ-LEDs. While on the one hand optical crosstalk should be suppressed to achieve a sufficiently good high-contrast image quality, the failure of a pixel may be more noticeable.

Therefore, an optical pixel element is proposed to generate a pixel of a display, which is formed by at least two subpixels. According to an example, 2, 4, 6, 9, 12 or 16 subpixels are provided per pixel element. In other words, a redundancy is created here, whereby the two subpixels receive the same driving information and are designed for the same wavelength, for example. So if one subpixel of these at least two subpixels fails, the pixel element can still emit light at this wavelength. According to an example, the luminosity of a subpixel can be adjusted to compensate for the missing light of a failed subpixel. According to an example, the subpixels are configured as so-called fields. For example, if a pixel element is designed as a rectangular structure, the subpixels within the structure of the pixel element are formed by a further subdivision into fields. Each of these subpixels in a field can be accessed independently of the subpixels in other fields.

The subpixels each have an optical emitter area. This is intended to ensure that each subpixel can be individually controlled and function independently. The emitter region comprises a p-n junction, one or more quantum well structures or other active layers intended for light generation. The emitter region is configured with a contact on its underside, which is intended for connection to a control unit or control electronics.

The control electronics is configured to control electrically the individual pixel elements as well as the individual subpixels. For example, the drive electronics or the control unit may be configured to detect a defect in a subpixel and no longer use the defective subpixel. Furthermore, according to an example, the drive electronics can be configured to drive an adjacent subpixel in such a way that a luminosity is increased in such a way that a luminosity of an adjacent failed subpixel is compensated. For this purpose, the control electronics can be provided with a memory unit, for example, which stores an operating state of a subpixel. In other words, a central acquisition of subpixels that are detected as defective can take place in the memory, in order to carry out defect compensation by luminosity adjustment or switching on or off of adjacent subpixels or pixel elements, if necessary. In another embodiment, for example, the time in which a subpixel is active can be increased to compensate for a failed subpixel. If, on the other hand, all subpixels are functional, the control circuit can also control them all with reduced luminosity, reduced duration or even multiplexed. Using functional subpixels with lower current and/or time duration may increase the lifetime of the subpixels.

To separate two adjacent subpixels within a pixel element from each other, a subpixel separation element is provided. The subpixel separating element has an electrically separating effect with regard to the control of the respective emitter chips or the control of the subpixels. In other words, this subpixel separating element can be configured in such a way that electrical interaction between the emitter chips of the adjacent subpixels is prevented.

Especially due to the use of semiconductors and the small distances between the emitter areas of the individual subpixels in the [μm] range, the control of an emitter chip can have secondary electrical or electromagnetic effects on spatially adjacent or surrounding areas. Under certain circumstances, this can lead to an adjacent emitter chip also being activated when driving a primary emitter chip. The subpixel separation element is therefore configured to prevent electrical crosstalk or electrical crosstalk to the adjacent subpixel and possible activation of the adjacent subpixel.

On the other hand, the subpixel separation element should be designed to couple optically the emitter chips of the neighbouring subpixels with respect to the emitted light, so that the visual impression that individual subpixels are switched off is counteracted. By optical coupling is meant here that light generated by a primary emitter chip or a primary subpixel can cross over to the adjacent subpixel by optical crosstalk. This is an advantageous way to prevent a dark dot or dark spot from being created by the defect of a subpixel. Instead, light from the adjacent subpixel can pass over and be emitted in the direction of emission from the defective subpixel. This is an advantageous way to compensate for the visible effect of a defective subpixel. The subpixel separating element therefore has no optical separating effect and should not be achieved.

This is an advantage if a subpixel fails. Due to the lack of optical separation, the pixel is still perceived as a whole and there is no different visual impression than when both subpixels are active. In one aspect, the subpixel separation element can be designed in such a way that it separates electrically but does not promote optical separation or even crosstalk. In one variant, the subpixel separating element is only drawn up to just before the active layer of the two subpixels or into the active layer. In other words, the subpixel separation element electrically separates two subpixel elements otherwise connected via common layers.

In one aspect, the subpixels have a common epitaxial layer. In many cases, pixel elements or entire displays are constructed in such a way that a common layer or several superimposed layers are grown, connecting a large number of subpixels and/or pixel elements. This can also be used to provide a common electrical contact or connection. According to an example, the epitaxial layer has Group III elements gallium, indium or aluminum, and Group V elements nitrogen, arsenic or phosphorus, or combinations thereof, or material systems with the mentioned elements. Among other things, this can influence the color and wavelength of the emitted light of a light emitting diode. The epitaxial layer can also have active semiconductor layers, e.g. a p-doped region and an n-doped region including the active interface regions.

For example, an emitter chip is arranged on a first side of the epitaxial layer transverse to a longitudinal extension of an epitaxial layer plane. Its light is then emitted across the epitaxial layer in the direction of a second opposite side of the epitaxial layer and radiated from there. The subpixel separation element extends trench-like into the epitaxial layer across the epitaxial layer plane, starting from the first side of the epitaxial layer where the emitter chip or the μ-LED is arranged.

In other words, the subpixel separation element is implemented here as a recess, gap, slit or similar structure, which can also be filled with an electrically insulating material. The insulating material should also be optically transparent to facilitate optical crosstalk. According to an example, the length of the trench is selected in such a way that drive signals to a subpixel do not electrically cross over to a secondary adjacent subpixel of the same pixel. Such a trench-like structure increases, among other things, the electrical resistance due to the significantly longer path of the current flow, thus creating electrical decoupling.

The optical effects that affect the emitted light, in turn, affect an area of the epitaxial layer that is further in the middle or further towards the second far side of the epitaxial layer. Thus, the depth of the trench is chosen to ensure electrical decoupling, but on the other hand, the trench ends before an area of the epitaxial layer where light can be transmitted between two adjacent subpixels. For example, the emitter chip's direction of emission runs across the epitaxial layer to allow light to exit at the opposite second side.

According to an example, the trench runs at a right angle relative to the epitaxial layer plane. Assuming this course of the trench, another example shows that a length dl of the trench is smaller than an overall thickness of the epitaxial layer. It is assumed that the epitaxial layer has at least approximately the same total thickness over a large number of pixel elements and subpixels. According to another example, the length dl of the trench between the pixel elements is equal to the thickness of the epitaxial layer. In other words, the trench is continuous from the first side of the epitaxial layer to the second side of the epitaxial layer. According to another example, the trench runs continuously diagonally through the epitaxial layer at an angle between 0 and 90° relative to the epitaxial layer plane.

In one aspect, each pixel element or its subpixel elements comprises several semiconductor layers in the form of a layer sequence, with an active layer for generating light. The active layer may comprise quantum wells or any other structure prepared to generate light. In an aspect, one or more layers extend over several pixels or subpixels. For example, the active layer may be intended to extend over several subpixels of a color. According to an aspect, the subpixels or pixel elements are electrically contactable and/or controllable independently of each other. For this purpose, for example, contacts can be provided on the side of the subpixels that is remote from an epitaxial layer. These can be mechanical contacts, solder connections, clamp connections or similar. The decisive factor here is that the subpixels of the individual subpixels can be contacted and electrically operated without significant interaction with the adjacent subpixels of the adjacent subpixels. This can be especially advantageous for detecting the functional or operating state of a subpixel, since diagnostic information can be generated individually for each subpixel. It is also useful to switch individual subpixels on or off without including the adjacent subpixels. This reduces thermal or other stress on the subpixels at higher intensities, since several subpixels can be operated simultaneously at lower intensities.

According to another aspect, the contacting of the individual subpixels takes place via a carrier substrate. On the one hand, the carrier substrate should provide mechanical stability and, on the other hand, integrate the fine conductor structures for the individual contacting of the individual sub-pixels. Other elements such as control electronics or driver circuits can also be integrated in the carrier substrate and especially in silicon wafers. This can have the same material system, but also a different material system via matching layers. In this way, silicon can also be used as a carrier material. This means that circuits for control in particular can be easily implemented in this carrier.

According to an example, a brightness of the pixel element can be adjusted by switching individual subpixels off or on. The advantage here is that switching off or switching on alone can already provide effective brightness control. This can, for example, significantly simplify a control electronics or a control unit. According to another example, the brightness of one or more subpixels of the pixel element can also be adjusted. Hereby a brightness can be adjusted or calibrated in even finer gradations, or a color spectrum can be adjusted or calibrated more precisely in interaction with different wavelengths of the subpixels of the same pixel element. The brightness can be adjusted by PWM control. If a subpixel has failed, an equivalent brightness can still be achieved by extending the PWM control accordingly. Conversely, if the subpixels are intact, the PWM drive can be adjusted, allowing the subpixels to operate at their maximum efficiency and possibly also resulting in lower thermal stress and thus a longer lifetime.

If, for example, eight subpixels are structured in a pixel element, a brightness dynamic of 2\hat{ }3 levels can be achieved without varying other control variables such as current or on-time. In other words, a dynamic range can be increased by a factor of 2\hat{ }3 in this design variant. This can also limit the complexity of the control electronics and thus the corresponding costs.

In another aspect, a μ-display is proposed, which has a plurality of pixel elements as described above and below. According to an aspect, such a μ-display can be an optical semiconductor display, e.g. for applications in the augmented reality area or in the automotive sector, where small displays with very high resolutions are used. Such a display can also be used in portable devices such as smart watches or wearables.

A pixel element separation layer is provided between two adjacent pixel elements. This is configured in such a way that the adjacent pixel elements are electrically separated with respect to the control of the respective pixel elements. Furthermore, the pixel element separation layer is configured in such a way that the light emitted by the pixel elements is optically separated. A pixel element separation layer can initially be understood abstractly as any structure or material that separates two pixel elements from each other. Usually, a large number of such pixel elements are arranged next to each other in one plane, for example on a carrier surface, and are connected to control electronics via contacts. In this way, a display can be formed in its entirety.

The electrical and electromagnetic separation is intended to ensure that a pixel element can be driven independently of the adjacent adjacent pixel elements and that there is minimal or no electrical or electromagnetic interaction, in particular no optical interaction. This is important for the sole purpose of being able to generate each pixel independently of the others for displaying a specific image content on the display. The optical separation in turn is necessary in order to achieve sufficient sharpness and contrast, or the ability to separate the individual pixels from one another on the display.

In an aspect, several pixel elements have a common epitaxial layer. The pixel element separation layer is trench-like and extends transversely to the epitaxial layer plane in the emission direction of the emitter chips. In other words, the pixel element separation layer is adapted as a trench, slit, slot or similar recess, which either does not contain any solid material or, for example, comprises a reflecting or absorbing material. In one example, the pixel separation element is filled with an insulating material in which a mirror layer is incorporated. The insulating material electrically separates two adjacent pixels and the mirror element prevents optical crosstalk. In some embodiments, the mirror element is also designed to collimate or support the light.

The pixel element separation layer is configured to prevent electrical or electromagnetic signals from being transmitted from one pixel element to another pixel element. At the same time, the pixel element separation layer should achieve that as little or no light as possible is emitted from one pixel element to an adjacent pixel element. In an example, the pixel element separation layer can be formed simply by placing two separated pixel elements next to each other when they are arranged, resulting in a corresponding insulating or reflective boundary layer. According to an example, the trench is perpendicular to the epitaxial layer plane, and a length of the pixel element separation layer is less than or equal to the thickness of the epitaxial layer.

According to another aspect, the trench depth of the pixel element separation layer is greater than a trench depth of the subpixel separation layer. This is supposed to offer the advantage that the pixel element separation layer causes an electrical as well as an optical separation by its greater length. On the other hand, only an electrical separation is achieved due to the smaller trench depth between the subpixels, whereby optical crosstalk is definitely desired. In some aspects, the depth of the pixel element separation layer reaches through the active layer of second adjacent pixels and separates them. In addition, the pixel element separation layer can reach to the emitting surface or just below.

In a further aspect, a procedure for calibrating a pixel element is proposed. This procedure is based on the idea that when a display is put into operation an optimal control should be possible. This can mean, for example, that defective subpixels are to be detected as such and then no further control is carried out. In this way, error messages or malfunctions can be avoided. By building up the pixel elements with the subpixels, it can be achieved that each subpixel can be individually controlled and checked.

Therefore, in a first step a subpixel of a pixel element is controlled, for example by an electronic control unit or a control unit. The next step is the acquisition of defect information of a subpixel. In other words, the control electronics can be configured and adapted in such a way that a malfunction or defect is detected. For this purpose, for example, a current intensity can be measured or other electrical quantities can be evaluated.

In a further step, the defect information is stored in a memory unit of the control unit. This information can be used, for example, to optimise the control by the control electronics. If, for example, a certain luminous intensity is to be achieved and it is known that a certain subpixel is defective, the control electronics can control the neighbouring subpixels in a correspondingly differentiated manner, for example to compensate for a luminous intensity. As a result, a quantity of light emitted by the pixel element would be exactly or nearly unchanged despite a defective subpixel and would not be noticed by a user.

In a further aspect of the method, the control, acquisition and storage is carried out sequentially for all individual subpixels of a pixel element. In other words, an electronic control unit can be configured in such a way that it checks all available subpixels one after the other via the individual separately addressable emitter chips and thus detects a functional state of the entire pixel element. According to an example, this can be done once when a display is switched on or after a certain period of time.

An extension of pixelated or other emitters, where optical and electrical crosstalk is reduced, is presented in the following concepts.

In conventional monolithic pixel arrays, it is common in some aspects to etch through the active zone in order to separate and address the individual pixels individually. However, the etching process through the active layer causes defects, which on the one hand can lead to, increased leakage currents at the edges and on the other hand produce additional non-radiative recombination. As the pixels become smaller and smaller, the relative damage area effectively increases. Conventionally, the edge of the etched active zone is passivated by various methods to solve the problem. Such methods are regrowth, in-situ passivation, diffusion of species to shift the pn-junction and increase the band gap around the active zone, and wet etch washing to remove the damage as far as possible.

Under the proposed principle, a pixel structure with a material bridge, which at least still includes the active layer. This reduces an increased defect density in the area of the active layer.

Thus an array of optoelectronic pixels or subpixels, in particular a micropixel emitter array, a micropixel detector array, or a combined micropixel detector-emitter array, comprises a respective pixel or subpixel forming an active zone between an n-doped layer and a p-doped layer. According to the proposed principle, between two adjacent formed pixels, material of the layer sequence from the n-doped side and from the p-doped side up to or in cladding layers or up to or at least partially into the active zone is interrupted or removed. In this way material transitions with a maximum thickness dC are formed, whereby electrical and/or optical conductivities in the material transition are reduced.

According to a second aspect, a method for the production of an array of optoelectronic pixels or subpixels is proposed, in which in a first step along the array a whole-surface layer sequence with an n-doped layer and a p-doped layer is provided, between which an active zone suitable for light emission is formed. Subsequently, between adjacent pixels to be formed, material of the layer sequence is removed from the n-doped side and from the p-doped side up to or into undoped cladding layers or up to shortly before or to the active zone. The removal can be done by an etching process. After removal, however, a material transition remains between the adjacent pixels, which comprises the active region and optionally a small area above, below or from both sides. This comprises a maximum thickness dC at which electrical and/or optical conductivity is effectively reduced by the material transition.

With the proposed concept, an array of pixels can be created over a large area. Material is removed by the etching process, but a material transition remains between adjacent pixels or sub-pixels, which encompasses the active layer. Thus, the etching process does not increase the defect density in the area of the active layer, especially in the pixel areas. Nevertheless, the individual pixels or sub-pixels are optically and electrically separated from each other. It is therefore proposed to manufacture micropixel emitter arrays and micropixel detector arrays formed by micropixels without etching through the active zone in such a way that optical and electrical crosstalk as well as performance and reliability losses of etched active zones are avoided. In this way, etching defects are avoided or their number is effectively reduced.

In this context, pixel or subpixel each denotes a μ-LED that emits light during operation. As a rule, several subpixels of different colors are combined into one pixel, also known as an image element.

According to one embodiment, the removed material can be at least partially replaced by a filler material. In other words, after the partial removal of the material and especially the nor p-doped layers, the space created is filled up again, resulting in a planar surface. This allows the functions of mechanical support, bonding and/or electrical insulation to be provided.

According to a further embodiment, the removed material can be at least partially replaced by a material that has a relatively small band gap and thus absorbs light from the active zone. This effectively reduces optical crosstalk. Alternatively, the removed material can be at least partially replaced with a material having a high refractive index, in particular higher than the refractive index of one of the cladding layers or the active zone. This can effectively create highly refractive interfaces that stop the propagation of fundamental modes. Further alternative light absorbing material and/or material with high refractive index can be applied at a respective material transition in one aspect. Thus, the material influences a wave guide in the material transition and prevents crosstalk.

According to a further embodiment, the material with a high refractive index can be formed by diffusing or implanting a material increasing the refractive index into a filling material, in particular into a respective cladding layer. This allows the arrays to be easily and effectively improved with respect to crosstalk without etching.

Another aspect concerns a reduction of electrical crosstalk. According to this, a material for increasing light absorption and/or a material for increasing electrical resistance can be introduced into the active zone of a respective material transition. The corresponding procedures are relatively simple to carry out. Thus, the arrays can be effectively improved with respect to crosstalk in a simple way without etching.

According to a further embodiment, at least one optical structure, in particular a photonic crystal and/or a Bragg mirror, can be generated along the material transitions, at or in these. These are particularly effective elements for reducing optical crosstalk. Such a photonic crystal or structure can also be used to improve collimation of light.

In another aspect, an electrical bias can be applied to the two main surfaces of the material transitions by means of two opposite electrical contacts and an electrical field can be generated by a respective material transition. This is an effective element in reducing optical crosstalk. In this case, the electric field is generated by applying a bias voltage. This bias voltage can, for example, be derived from or originate from the voltage for operating the pixels. However, in some aspects such a field can also be determined by an inherent material property. In one aspect, for example, it is intended that an electric field is generated by means of an n-doped material and/or p-doped material applied to or grown on at least one of the two main surfaces of the material transitions by a respective material transition. Electric fields are thus built into the corresponding array, whereby it is not necessary to apply a voltage.

According to a further embodiment, the exposed main surfaces of the material transitions and/or exposed surface areas of the pixels can be electrically insulated and passivated by means of a respective passivation layer, in particular one containing silicon dioxide. In this way, current flow through selected areas of an array, in particular through the material transition acting as a waveguide, can be effectively and selectively prevented. The main surfaces of the pixels can be electrically contacted by means of contact layers, so that a vertical optical component is thereby produced. One of the main surfaces can be electrically connected to each other via a shared layer. According to a further embodiment, the material and/or the material transitions between a pixel and its neighbouring pixels can be formed differently to each other, especially depending on the direction.

For the production of a μ-LED display, it seems to be useful to during the processing to provide subunits of μ-LEDs, and separate these to be able to process them further. In this way, the subunits can be tested individually. If μ-LEDs in the subunits fail, it is not necessary to replace the entire μ-display, but only the subunit. On the other hand, by adapting one process step, the production can be made more flexible, so that different sizes can be produced. This approach is particularly suitable as a modular architecture for μ-LEDs.

According to an aspect of the modular architecture, a method for manufacturing μ-LED modules is proposed, with the steps
Creating at least one layer stack providing a base module on a carrier;
depositing of a first contact to a surface area of the layer stack facing away from the carrier;
depositing of a second contact to a surface area of a first layer facing away from the carrier.

Alternatively, the following steps can be taken:
Generating at least one layer stack providing a base module, comprising a first layer formed on a carrier, on which an active transition layer and on which a second layer is formed;
opening a surface area of the first layer facing away from the substrate;
Connecting a first contact to a surface area of the second layer facing away from the carrier;
Connecting a second contact to the surface area of the first layer facing away from the carrier.

Accordingly, a μ-LED module then comprises at least one layer stack providing a base module, having a first layer formed on a carrier, on which an active transition layer and on which a second layer is formed, a first contact being connected to a surface region of the second layer facing away from the carrier, a second contact being connected to a surface region of the first layer facing away from the carrier.

In this way, a base module can be created as the basic component of a μ-LED module with, in particular, a contact level for the contacts. The base module is part of a larger system, but in its simplest form, it can in turn comprise a μ-LED. In one aspect, the base module contains several, at least two μ-LEDs. These can be controlled individually or can be adapted as redundant forms. Thus, according to a building block or modular principle, a whole can be divided into parts, which are called modules. With a rectangular or any other arbitrary shape and a common function of light emission, the modules can be easily joined together.

Starting point is a μ-LED with a horizontal architecture. The size of this optoelectronic component is designed to meet the requirements of the display sector, where the smallest chip sizes are required due to very narrow pixel pitches, in terms of emission area (about 300 μm2 or less). In order to meet the requirements of other applications such as video wall, the μ-LED architecture is designed in such a way that by a simple adaptation of one process step, namely the use of another mask for layer stack or mesa structuring, light emitting diodes can be produced that consist of several subunits of this smallest μ-LED.

For example, the basic size for a base module is 15 μm×10 μm. With the mask and a suitable contacting or separation, a component with 15 μm×20 μm or 30 μm×30 μm would be just as easy to produce, which in turn is suitable for various μ-LED display applications. As already mentioned, a component comprises one or more base modules, which in turn may comprise one or more μ-LEDs.

The modular design with the smallest chip currently required as the base unit or base module, with the possibility of converting it into a larger component with a multiple of the dimensions of the base unit, the base module, by only a minor adjustment during processing, saves resources during development and opens up a certain freedom in the production of such components. If, for example, applications in the μ-LED range with a different brightness or pixel pitch are required, the chips required for this can be produced relatively easily.

In one aspect, not only the mesa (stack of layers) is structured differently, but also a contact layer. To do this, two steps are varied, but it is no longer necessary to ensure that all contact pads are connected. By using a horizontal chip architecture, further process steps for n-contact connection, such as for the vertical chip after mounting on the target substrate, can be avoided. This can simplify manufacturing and thus reduce costs compared to other manufacturing techniques.

According to another aspect, the second contact can be formed by means of a dielectric to the transition layer and the second layer electrically insulated to and at the surface area of the second layer facing away from the carrier.

Depending on the application requirements, base modules are designed as a matrix along an X-Y plane along at least one row and along at least one column, with base modules of a respective row having the same orientation. The base modules of two adjacent rows are oriented in the same way if necessary. In this way, an electrical series connection of base modules can be easily implemented.

Alternatively, the base modules of two adjacent lines are oriented in opposite directions, whereby identical contacts are arranged adjacent to each other. In this way, an electrical parallel connection of base modules is easily realized. Since in horizontal μ-LEDs both contacts for n and p are located on the bottom side, it is advantageous to arrange the chips alternately in rows. In a 2×X configuration of the chip, the contacts for the p side for both base elements are located in the middle of the chip, the n contacts on the outside, thus minimizing the risk of a potential short circuit.

Removal of the at least one light emitting diode module from the plurality of base modules is in some aspects carried out by means of a deep edge structuring through the first layer, in particular from the side of the second layer. It can be carried out by means of laser lift-off, namely from the side of a carrier facing away from the module. An etching process would also be conceivable.

Another aspect deals with the question whether and to what extent such Sub-units with sensor can be provided. For μ-displays especially in the field of Augmented Reality but also for automotive applications, it can be useful to provide sensors to record reactions or other parameters of a user. For example, in an application in the field of Augmented Reality, one or more photo sensors can be provided in order to detect the direction of gaze or a change from one direction of gaze. The amount of light can also be recorded, for example to brighten or darken an image. The same sensors can also be used for displays in automotive applications. Sensors can also be used to detect the driver's attention in order to initiate measures if necessary in case of detected fatigue.

The inventors have recognized that future displays may not have sensors that are placed outside the display. Instead, the functionality of sensors behind or in a full-surface μ-display should be made possible as an alternative to previous separate solutions.

The subdivision into μ-LED modules revealed here is used for this purpose. Redundant places for subpixels can be equipped with sensors instead of μ-LEDs. According to a first aspect a μ-display with a target matrix is proposed, which is formed on a first carrier or end carrier. The matrix or μ-display has positions that can be filled with μ-LEDs. In addition, a number of components, in particular μ-LEDs, are formed on a second carrier or replacement carrier, so that a start matrix with the same spacing as the target matrix is created from positions that can be filled with components. Furthermore, the μ-LEDs are grouped on the replacement carrier to form a number of modules and these modules are separated from the second carrier, the modules being positioned and electrically connected on the first carrier in the target matrix in such a way that a number of positions which are unoccupied by components remain in the target matrix, at which at least one sensor element is positioned and electrically connected at least in part in each case. The vacant positions of the target matrix correspond in some aspects to sub-pixel positions or pixel positions.

Furthermore, the modules or sub-units of μ-LEDs disclosed in this application are now provided. Their size or spacing corresponds to the corresponding parameters of the occupiable positions of the target matrix. The subunits are grouped into modules and positioned and electrically contacted on the target matrix in such a way that a number of unoccupied positions remain in the matrix, to which at least one sensor element is at least partially positioned and electrically connected. Modules or sub-units are thus positioned on a display module or a display so that some positions remain unoccupied, which can thus be equipped with sensors. In this way, the sensors become part of the display. This has several advantages. For example, light falling on the display can be measured directly and then the illuminance of the module or even individual μ-LEDs can be adjusted depending on the location.

According to a second aspect, a process for the production of a μ-display is proposed. This has a target matrix with positions formed on a first carrier or end carrier and which can be occupied by μ-LEDs, arranged in rows and columns. The positions that can be occupied can correspond to subpixels. In addition, the locations show a size and spacing that substantially correspond to the modules disclosed herein. In other words, the target matrix comprises locations arranged in rows and columns and can be occupied by modules of μ-LEDs.

The modules are now produced as shown here, for example with flat and deep mesa etching and grouped into modules. The modules produced in this way are removed from the replacement carrier and positioned in the free spaces on the target matrix on the end carrier and electrically connected to the end carrier. During this process, however, previously defined positions are left free. These are then filled with at least one sensor element each, which is positioned and electrically connected.

The end carrier can have line connections for the modules and the individual μ-LEDs. In addition, in some aspects the end carrier also includes at least one current source and/or control electronics for the applied modules or μ-LEDs. In another aspect, the end carrier also contains the electronics for reading out the at least one sensor element. The at least one sensor element can include a photosensor. Further examples are given below.

The prepared modules or sub-units of μ-LEDs and the corresponding area of the target matrix on the final carrier must be identically gridded or have the same size and, if necessary, the same periodicity. The spacing should be the same, especially if larger modules with several rows or columns are transferred and applied to the final carrier.

In one aspect, one or more contact areas of a module or subunit are congruent with a relevant contact area of occupiable positions on the end carrier. Thus, the modules can be integrated into the target matrix on the end carrier. The modules can thus be inserted or integrated into the target matrix on the end carrier.

It is thus possible to construct a display in which the modules, especially the μ-LED modules, are arranged at the same distance from each other for all components. Thus, in one aspect, a target matrix of a display is assembled with a very small distance between the occupiable spaces. In this aspect, each place that can be occupied can be populated with the smallest module to be produced. This results in a display that allows a very high resolution due to the small size of the pixels and the small distance between them and due to which the display can be brought very close to a user's eye.

Alternatively, it is possible to separate further the occupiable positions of the target matrix. Likewise, in some aspects, several of the subunits revealed here can be arranged on such an occupiable location. In some aspects, the positions of the target matrix arranged in rows or columns can each have a distance b from each other. The μ-LED modules each have the same size and a distance a from each other. Distance a can be equal to distance b, which is substantially the same as above. However, distance b can also be a multiple of distance a. Since the contact surfaces for the μ-LED module or subunit are also included in the occupiable areas, the available space increases with a larger distance b between the occupiable areas. In this way, larger modules can be used or several modules can be combined. If, for example, the distance b is 2.5 times the distance a, a module can be placed on an occupiable position which is composed of 4 individual modules and there is still a distance between the modules placed on adjacent positions.

This design allows different eye sensitivities and resolutions to be taken into account. The smaller the distances a and b are, the higher the resolution, the less sensitive the eye of an user can be. Thus, different displays with different pixel or subpixel sizes and pixel distances can be realized with the same μ-LED modules. This may be an advantage in that μ-LED modules can be manufactured independently of the target matrix, its carrier and its wiring.

The already disclosed flat mesa etching, which serves for the electrical contacting of the pixels and the formation of the μ-LED modules and the target matrix and in which etching is performed in the μ-LED grid, is combined with a so-called deep etching, in which the chip grid and the modules can then be defined. This chip grid can differ from the pixel chip grid depending on the application. For example, one could then produce 2×2 large chips with 4 subpixels each (4 base units). One base unit is one μ-LED each. By skillfully designing the mask for the second mesa etching, one could also create pixels each comprising one base unit less. By stringing these pixels together, a display with “holes” in the size of one base unit or multiples thereof is created. These “holes” or “missing subpixels” can then be used to accommodate various sensors, for example. This combination makes it possible to create subpixels with redundancy, whereby in some cases the redundant subpixels are replaced by the sensor.

For this purpose, it is expedient that μ-LEDs are provided with a uniform chip architecture and the same or easily variable size of chips for the production of displays. The techniques described here can be used for this purpose. When producing modules of the disclosed type, it is possible, for example, to use the cover electrode disclosed in this application or the surrounding structure to increase the light yield. In some aspects, the modules can be further processed afterwards, for example by applying a photoelectric structure. At this point, however, it should also be mentioned that the μ-LED modules can already be provided with such a structure in their manufacturing process.

In some aspects, the μ-LEDs are combined into rectangular or square modules, which in turn can be combined in any way, especially into rows. By manufacturing by means of flat and deep etching, wafers can be prepared from such modules, which can then be separated as required for the target matrix. In this way, modules of different sizes can be realized. The free positioning makes it possible to leave specific positions unoccupied. Groups of cells or even entire rows or columns can also be left unoccupied. Finally, these modules can be used to equip displays whose target matrix has a different arrangement of vacant positions, e.g. not in rows and columns.

According to an embodiment, at least one module can have four pixel elements in two rows and two columns. Each pixel element can comprise one or more subpixels. In another configuration, a module can have four subpixel elements, which are also arranged in a 2×2 matrix. This is an embodiment easy to handle. In another embodiment, at least one module can have two rows and two columns, but only three components. This is an embodiment easy to handle, where an unoccupied position is already provided with the module.

In a further configuration, at least seven modules each with four pixel elements and at least two modules each with three pixel elements can be positioned and electrically connected in the target matrix on the end carrier in such a way that at least two positions unoccupied by pixel elements are created, at which in each case at least one sensor element is positioned and electrically connected. Here, too, the modules can be designed as desired and can be linked to one another on the end carrier or positioned next to one another in such a way that vacant positions can be generated in a targeted manner. Here too, the pixel elements either comprise several subpixel elements and corresponding μ-LEDs or each pixel element is itself a μ-LED.

According to a further embodiment, the positions occupied by sensor elements can be framed by components. In this way, clearly defined positions, positions not occupied by components, can be explicitly provided for sensor elements.

In some aspects, the modules can be created as subpixels. Modules emitting in different colors may have been created on different second or substitute carriers.

According to various embodiments, a large number of sensor elements may be configured as part of a sensor device formed on the first carrier or end carrier to receive electromagnetic radiation incident on a first side of the first carrier. In this way, different radiation spectra can be detected depending on the application. According to a further embodiment, a sensor element can be formed as a photodiode, in the form of a phototransistor, in the form of a photo-resistor, in the form of an ambient light sensor, in the form of an infrared sensor, in the form of an ultraviolet sensor, in the form of a proximity sensor or in the form of an infrared component. The sensor can also be a vitality sensor that records a vital parameter. The display device is therefore versatile. A vital sign can, for example, be the body temperature.

In another configuration, the vital sign monitoring sensor may be located within a display screen or behind the rear surface of a display screen, the sensor being designed to measure one or more parameters of a user. In addition to body temperature, this parameter includes, for example, the direction of vision of the eye, pupil size, skin resistance or similar.

According to a further design, a component can have a first layer formed on a carrier, on which an active transition layer is formed and on which a second layer is formed. A first contact is connected to a surface area of the second layer facing away from the carrier, and a second contact is connected to a surface area of the first layer facing away from the carrier. This embodiment corresponds to a vertical μ-LED. In this way, the components can be contacted from only one side. In further aspects, the second contact can be electrically insulated from the transition layer and the second layer by means of a dielectric to and on the surface area of the second layer facing away from the carrier.

In addition to the production of monolithic pixel arrays, μ-LEDs can also be applied to a carrier board and subsequently contacted. Due to the size of individual μ-LEDs, they are difficult to transfer and contact individually. For this reason, for some applications in the automotive sector, video walls or in special cases in augmented reality applications, μ-LEDs are first applied to a slightly larger carrier and then contacted with leads on a circuit board. The circuit board can again be a video wall, pixel matrix or a similar screen arrangement. Such arrangements sometimes require special connection techniques, which also differ from arrangement to arrangement and technology or manufacturing process. This makes the provision of different μ-LEDs or modules with such devices quite complex.

Thus, there is a need to Pixel module for different mounts which meet various requirements and are particularly suitable for manufacturing processes for video wall NPP of different generations, i.e. also for LED matrices in AR or VR applications or flexible displays in the automotive sector.

In one embodiment, a μ-LED module comprises a body with a first main surface and four side surfaces. At least three contact pads are arranged on the first main surface. These are designed to be connected electrically to one optoelectronic component each. For example, the three, or a subset of these are connected to a μ-LED with an edge length of 10 μm or less. According to the proposal, several contact bars are also provided. Each contact bar electrically connects one of the at least three contact pads. In addition, the contact webs on the first main surface lead to at least one of the four side surfaces. In other words, the contact bars are arranged on the first main surface and the at least one of the side surfaces. The contact bars form contact lugs on the side surface, i.e. they are designed for external contacting.

With the proposed μ-LED module, rewiring is thus possible, so that the module can be easily connected to the predefined connection points on a carrier or matrix. In particular, the significantly smaller μ-LEDs on the module can be arranged in advance, so that additional space for electrical connection is created with the module. This allows a higher flexibility and the use of such modules for different applications.

In addition to a module with three μ-LEDs, which can be combined into one pixel, for example, several μ-LEDs can also be combined into a larger module in this way. The individual μ-LEDs can be manufactured separately, allowing the optimum technology for the respective μ-LED to be used. Single μ-LEDs can also be designed redundantly. Larger modules are also called segments. Beside single μ-LEDs, special modules with flat and deep mesa etching, as shown here, can be used. A design in bar form or with the proposed antenna structure would also be conceivable. The proposed rewiring allows modules and μ-LEDs to be manufactured individually and adapted to the respective application.

In one embodiment, the contact ridges only run along the sidewalls, in another embodiment they are also connected to contact pads on a second main surface, the underside of the μ-LED module. This means that there are contact pads on both the upper side (for the μ-LEDs) and the lower side of the μ-LED module. This makes the μ-LED module suitable for both SMT (surface mounted technology) manufacturing processes as well as for contact bar processes in which contact bars on the carrier are brought up to the side surfaces of the module. The design makes the module more flexible and can also better compensate for manufacturing tolerances of the carrier (e.g. in contact bar length or size).

In a further embodiment, a second side face of the four side faces will only have the fourth contact web. This contact bar can be marked, for example, to be loaded in operation with a special potential. In addition, it can also differ optically from the other contact bridges, for example by its size on the side surface. This ensures that the module is placed in the correct position during transfer. In another embodiment, two of the three contact bars are arranged on different side surfaces. In one example, four contact ridges are provided, each of which is arranged on one side surface and preferably connected to a contact pad on the underside of the module, i.e. the second main surface.

In another example, contact bars are also arranged on the first main surface. These run to the edges and then along the edges of the side faces in the direction of a second main face, e.g. the bottom of the module.

Another aspect concerns the configuration of the module body. For example, the body of the module comprises a prism with the base of a rectangle or other square surface. In one embodiment, a second main surface is provided, which is opposite the first main surface and comprises a larger area than the latter. Alternatively, the first main surface may be designed to form an angle of 90° or more with each of the four lateral surfaces. This forms a prismatic or square truncated pyramid. In another configuration, the side faces are not perpendicular to the first major surface.

In a further aspect, the contact bars and/or contact pads comprise a, in particular vapour-deposited, metal tag, the thickness of which is less than 5 μm, in particular less than 2 μm or even less than 1 μm. For example, a thickness of the contact bars and contact pads can be in the range of 100 nm to 50 nm. These can be produced by appropriate photolithographic processes. Depending on the design, the metal tags and contact pads can also be deposited on an insulating layer of the module body, for example by MOCVD or similar processes. Contact pads on the bottom side can be produced in a separate step. In a further embodiment, the module body comprises at least one through-hole plated at least partially filled with an electrically conductive material, the electrically conductive material on the first main surface being connected to or forming one of at least three contact pads arranged on the first main surface.

The module body can be configured with continuous main surfaces. In another configuration, the body may comprise a recess on the first or second main surface in which at least a contact bar runs. A contact bar on the second main surface can be connected to a via and lead to a contact pad. Likewise, a contact bar can connect at least one μ-LED arranged on the first main surface to the through-hole plating.

The body can contain or be formed from silicon. It can be surrounded by an insulating layer, for example silicon dioxide, to prevent a short circuit. The silicon material may be free at one point to which a reference potential can be connected. Vias through the body are also lined with insulating material. Contact bars and contact pads are applied to the insulating layer. The module body can have a thickness of less than 30 μm, especially in the range of 5 μm to 15 μm. This allows a very low overall height of only a few 10 μm to be achieved. The overall height of the module can be further reduced by an additional recess in which the optical components are inserted.

Another aspect relates to a process for manufacturing a μ-LED module in which, among other things, a membrane wafer is structured so that it has a large number of substantially V-shaped trench-shaped recesses. The depressions are designed in such a way that a first main surface of the structured membrane wafer bounded by trenches forms an angle of 90° or greater with the flanks of the trenches. Then, several contact pads are generated on the first main surface of the membrane wafer. Optionally and/or additionally, leads, contact tabs and contact bars can be generated on the first main surface and the side surfaces. Then at least one optoelectronic component, in particular a μ-LED, is applied to the module and electrically conductively connected to a contact pad. In a subsequent step, a temporary carrier is provided and the membrane wafer is etched back up to or just before the trenches after rebonding with the temporary carrier. Finally, backside contacts are applied and optionally separated.

As already explained, in monolithic arrays a pixel error can be reduced by providing a redundant subpixel. Electrical crosstalk is avoided, while optical crosstalk between the redundant subpixels is still possible. A similar problem exists with separated pixels. Although it may be possible to test the functionality before separating, due to the small size of μ-LEDs during transfer to the backplane in production, positioning or connection errors may occur. In addition to continuous improvements of the process steps in manufacturing, there is the approach to make each pixel of a Pixel array with redundant μ-LEDs or more precisely, to provide redundant positions on which μ-LEDs can be placed. This can mean, for example, that for each RGB subpixel of a pixel two or more μ-LED chips are used instead of just one μ-LED chip for one color, which leads to an overcrowding of subpixels per pixel for most pixels. Another approach is to repair defective subpixels of a pixel. After a function text, faulty subpixels are switched off and replaced by working subpixels.

A method of making an array of pixels or an array of pixels comprising inter alia providing a substrate for arraying pixels on the substrate and electrically contacting the pixels, the substrate providing a set of primary contacts for a pixel, the set of primary contacts of the pixel being for electrically contacting a group of sub-pixels of the pixel, the substrate providing a set of spare contacts for the pixel.

Then the primary contacts of the pixel are equipped with a group of μ-LEDs, whereby the set of spare contacts of the pixel is not equipped. Then defective μ-LEDs in the group of μ-LEDs are identified and one of the possibly several replacement contacts of the set of replacement contacts of the pixel is equipped with a replacement subpixel for the defective μ-LED. In this context, a pixel may comprise one or more subpixels. The pixel may also be configured for the connection of a vertical or a horizontal μ-LED. Accordingly, a primary contact can comprise at least one contact area (in the case of a vertical μ-LED) or two contact areas (when equipped with horizontal μ-LEDs). One of the two contact areas can be used by several μ-LEDs, including the redundant one. If equipped with vertical μ-LEDs, one of the cover electrodes presented here may be provided. The pixel field can also be surrounded by a surrounding mirror layer.

In addition to separate μ-LEDs, the μ-LED modules or base modules disclosed here can also be assembled. For example, a μ-LED module can comprise two base modules, so that one base module is provided as a redundant unit.

The method according to the invention thus allows the assembly of the primary contacts for each pixel of a pixel field with a designated group of subpixels. One primary contact is equipped with one subpixel each. In each pixel, the defective subpixels on the primary contacts can then be determined. For an identified, faulty subpixel in a pixel, a replacement contact for the pixel is fitted with a replacement subpixel in a subsequent step. Thus, only one replacement contact in a pixel is equipped with a subpixel to replace functionally a subpixel identified as faulty on the primary contacts.

A redundant assembly of the pixels with several subpixels of the same color is therefore not necessary. In comparison to the redundancy concepts known from the state of the art, much fewer subpixels are used in a pixel field to be produced, since an increased assembly is only carried out after the identification of faulty subpixels. The manufacturing costs can thus be reduced.

In addition, control techniques can be used in this application to test the functionality of a μ-LED on the one hand and to disconnect safely the faulty μ-LED in case of a failure, especially in case of a “SHORT” by melting a fuse or other measures. This allows the faulty one to remain on the pixel, thus eliminating the need for additional process steps.

It is also possible to refill the replacement contacts for a pixel individually if faulty subpixels are identified. It is also possible to replenish the spare contacts of a pixel several times, following further functional tests in a continuous processing. This increases the probability of success of the placement process. In addition, it is possible to reproduce subpixels, e.g. in the form of μ-LED chips, with selected characteristic data, for example to achieve a correct color calibration in a particular pixel.

according to an embodiment, the steps of identifying a defective subpixel in the group of subpixels and providing a replacement contact with a replacement subpixel for the identified subpixel may be repeated until there replacement subpixel it attached to the pixel for each subpixel identified as defective. For all defective subpixels of a pixel, the substrate can thus be populated with replacement subpixels in a subsequent process step.

According to another aspect, a subpixel identified as faulty does not need to be removed if the faulty pixel is declared “OPEN”, i.e. no leakage current flows through the damaged or destroyed pixel. Circuitry measures can also be provided to separate an electrical contact for an identified, faulty subpixel. A current flow to the faulty subpixel when operating the pixel array can thus be avoided. Corresponding concepts are disclosed in this application and can be used for this purpose.

Compared to repair concepts, the process of removing defective subpixels can be omitted. This makes the manufacturing process faster and more cost-effective. The risk of damaging the pixel field when removing defective subpixels is eliminated. A repair by removing a defective subpixel allows the further use of the primary contact area that becomes free. However, residues and damage reduce the probability of success of a second placement and bonding process. The replacement contacts provided are free of residues and damage.

It may be provided that a subpixel identified as defective and the replacement subpixel are intended to emit light of the same color. A faulty subpixel is thus replaced by a replacement subpixel, which at least approximately emits the same color, as the faulty subpixel would have if it were functional.

The group of subpixels of a given pixel can comprise one or more sets of RGB subpixels. RGB stands for red, green and blue. The group of subpixels can therefore have three subpixels, for example. One subpixel can be configured to emit red light, another subpixel can be configured to emit green light, and yet another subpixel can be configured to emit blue light. By additive mixing of the three basic colors red, green and blue, any or nearly any color can be generated in a known manner.

The group of subpixels can also have more than one subpixel to create each primary color. For example, the group of subpixels can have 6 subpixels, with two subpixels each for creating red, green, and blue, respectively.

According to an embodiment, it is intended that no replacement contact of the pixel is equipped with a replacement subpixel if no defective subpixel is found in the pixel. The pixel field can therefore contain pixels for which the replacement contact or contacts are not fitted.

Another aspect deals with the design of the primary contacts. These are configured for anode-side and/or cathode-side contacting of the subpixels of a pixel. For example, the contacts can be configured in such a way that so-called flip chips can be arranged on these contacts and electrically connected. Flip chips are optoelectronic chips whose electrical p and n contacts are on the same surface side. The replacement contacts can also be configured for contacting the replacement sub-pixels of a pixel on the anode side and/or the cathode side. The redundancy of the contact areas for the subpixels of a respective pixel achieved by the replacement contacts can thus relate to both the cathode and the anode of a subpixel or only to one of the two connections.

In this context, a subpixel or replacement subpixel is formed by a μ-LED, which is placed on the respective contact and connected electrically and mechanically. Equipping the replacement contact with a replacement subpixel for the subpixel identified as defective can be done independently of the color of the light emitted by the replacement subpixel. Normally, each primary contact is populated and only the replacement contacts of the μ-LEDs declared as faulty. However, a primary contact does not have to differ from a secondary contact in terms of circuitry or even its structure on the surface. In this respect, a combined assembly can therefore also be carried out. In this context, it can also be said that the first contact assembled by a μ-LED of a color represents the primary contact.

The proposed concept also concerns a pixel array with a substrate for an array of pixels arranged on the substrate and for the electrical contacting of the pixels, where the substrate provides a set of primary contacts for a pixel. The set of primary contacts is intended for electrical contacting of a group of sub-pixels. The substrate also provides a set of spare contacts for the pixel. According to the proposed principle, the primary contacts are populated with the group of subpixels, wherein the group of subpixels comprises a faulty, deactivated subpixel, and wherein a replacement contact of the set of replacement contacts of the pixel is populated with a replacement subpixel as a replacement for the faulty, deactivated subpixel.

With at least two pixels of the pixel field, the number of occupied spare contacts may be different. This results from the fact that in a pixel the spare contacts are only populated with spare subpixels if subpixels on the primary contacts are identified incorrectly.

The above concepts for reducing defect or crosstalk improve the yield of functional elements during production. Several aspects deal with measures to improve a transfer of μ-LEDs. For this purpose, μ-LEDs are now increasingly being developed, whose edge lengths are usually less than 100 μm, often between 70 μm and 20 μm. For special applications in the field of augmented reality, the dimensions are also less than 20 μm, for example in the range of 1 μm to 10 μm or even 1 μm to 5 μm.

One of the technical challenges associated with μ-LEDs is in particular the manufacturing process, since a large number of μ-LEDs not only have to be produced but also installed in matrices or modules. In order to produce such modules or even larger displays, the μ-LEDs produced are transferred either as individual chips or ready in the modules presented here to a carrier surface of the module or display, where they are fixed and electrically connected. With several million LEDs to be transferred, this process is critical in terms of speed and accuracy.

Various processes are known for this, such as the transfer printing process. These use a flat stamp to simultaneously pick up a large number of μ-LEDs from a wafer, move them to the carrier surface of the subsequent display and precisely assemble them there to form a large-area overall arrangement. An elastomer stamp, for example, can be used for this purpose, to which the individual μ-LEDs can adhere without being mechanically or electrically damaged thanks to suitable surface structures and material properties. Depending on the process technology, this can be problematic, as the μ-LEDs can tilt, shift or twist when they are detached. It is therefore desirable to enable the mounting of μ-LEDs with reduced holding forces or damage.

The aspects and ideas described in the following are based on the following considerations: When using mass transfer processes, i.e. the simultaneous localized relocation of a large number of semiconductor chips, the μ-LEDs are picked up or lifted from a wafer with the aid of a suitable tool. This requires the chips to have an exact and determinable position on the wafer, for example to be able to position a tool such as an elastomer stamp with its cushion structures as precisely as possible over the respective μ-LED. At the same time, a surface structure should always be homogeneously and uniformly positioned in space so that a transfer tool can attach itself to a chip surface in a standardized manner with a high probability of success.

According to a first aspect, a method for providing a μ-LED is proposed in which a first electrically conductive contact layer is arranged on a first main surface side of the functional layer stack facing away from the substrate. The layer stack is configured as an optically active layer stack and accordingly forms in particular a μ-LED. Then at least one support layer attached to the substrate is provided which carries the μ-LED. Due to the holding structure, the contacted functional layer stack can be broken off during lift-off. Subsequently, a sacrificial layer, which is applied between a second main surface side of the functional layer stack facing the substrate and the substrate and in particular comprises AlGaAs or InGaAlP, is at least partially removed. After the partial removal, a second electrically conductive contact layer can be applied to the second main surface side of the functional layer stack in the area of the removed sacrificial layer

In the process presented here, lithographic processing of a functional layer stack takes place only on one side of a substrate, thus avoiding additional rebonding if necessary. The holding structure can in turn be lithographically adapted to the requirements, the size of the layer stack and other parameters. At the same time, the layer stack is contacted on both sides, thus forming a vertical μ-LED.

According to a second aspect a μ-LED is proposed, which comprises a functional layer stack. A first electrically conductive contact layer is attached to a first main surface side of the functional layer stack facing away from a substrate and a second electrically conductive contact layer is attached to a second main surface side of the functional layer stack facing the substrate. In this case, the contacted functional layer stack is supported, in particular freely, by at least one holding structure attached to the substrate. The holding structure allows the contacted functional layer stack to be broken off in further process steps during lift-off. Accordingly, the layer stack or the μ-LED exhibits a break-off edge after lift-off and in all subsequent process steps.

With the measures proposed here, no rebonding is necessary and a simple alignment of a lithographic masking is possible. The formation of a vertical μ-LED is possible just like a horizontal LED. Absorption is reduced and light extraction through the horizontal surface is increased, whereas thinner epitaxially generated layers are possible. Without bonding, the epi-structure of a layer sequence is subject to less mechanical stress. In addition, the sacrificial layer allows a more precise etching process, since the etching process can be very selective for the sacrificial layer. The contact layer can therefore be made thinner.

In some aspects, the support structure may in particular include InGaAlP or AlGaAs or BCB or an oxide, for example SiO2, or a nitride or a combination of such materials, and in particular be electrically non-conductive. In this case, it can also be configured to passivate the stack of layers. The support structure can be at least partially epitaxially grown or generated by vapour deposition or electroplating. In contrast, the sacrificial layer can have AlGaAs or InGaAlP and can be etched away wet-chemically. The first and/or second electrically conductive contact layers can be produced by sputtering, vaporizing, galvanically or epitaxially. The contact layers can be transparent and contain ITO or ZnO or a metal. In order to avoid oxidation or degradation, some aspects are provided for, one flank of the contacted functional layer stack must be covered by a passivation layer. Alternatively, it would be possible to diffuse a metal, in particular Zn, from one flank of the contacted functional layer stack into an outer edge region of the functional layer stack. This changes the band structure in the edge area and thus keeps charge carriers away from the area affected by an increased defect density.

In order to securely attach the retaining structure, it can extend into the substrate from the first main surface side of the functional layer stack.

According to a further embodiment, a first supporting layer, in particular comprising InGaAlP and/or AlGaAs, can be formed on the functional layer stack on the first main surface side thereof, to which the first electrically conductive contact layer can be attached, the first supporting layer and the first electrically conductive contact layer being attached to the substrate at least at one point and thus together can provide the holding structure.

Another point of view deals with the question how a Avoidance of breakage edges and improved lift-off can be achieved.

A solution is proposed here, in which a mechanical connection between the μ-LED and a surrounding or underlying substrate is maintained using crystalline, dielectric support structures. However, this mechanical connection is configured in such a way that on the one hand it reliably holds the μ-LED chip in place mechanically, but on the other hand it breaks when the smallest possible bending force or tensile force is exerted, thus releasing the chip for removal.

In particular, a carrier structure is proposed to accommodate flat microchips or μ-LEDs. A carrier structure in this context means an arrangement that can accommodate a plurality of such μ-LEDs, for example with edge lengths in the range of 5 μm to 20 μm or smaller. The main purpose here is to achieve a mechanically stable fixation, for example relative to a grid or a matrix, making the best possible use of the available space. Furthermore, this carrier structure should be suitable for providing the large number of microchips for transfer with the aid of a transfer tool.

The carrier structure also has at least two receiving elements that are connected to the carrier substrate. A mounting element in this case is to be understood as a mechanism or functional element that is suitable for fixing a μ-LED spatially by mechanical contact, if necessary in interaction with other mounting elements, or for holding it in a defined spatial position. A mounting element can have diameters in the range of 1 μm, for example. In one example, a microchip is attached to two picking up elements.

In some aspects, the carrier structure comprises a flat carrier substrate. Such a carrier substrate can be, for example, a wafer, a foil, a frame or similar from the field of semiconductor production. In addition to its function as a base plate or base material for the semiconductor manufacturing process, a wafer can also provide a support or carrier function in preparation for a subsequent mass transfer. In addition, flexible materials such as films are also suitable as carrier substrates.

According to an example, a receiving element can be configured in a columnar, pillar-like or pile-like manner starting from the carrier substrate. In one embodiment, the microchip rests at its corners or edges on the at least two receptacle elements partially but not completely. The mounting elements are connected to the carrier substrate and are designed to hold a microchip detachably between the at least two mounting elements in such a way that μ-LED can be moved out with a defined minimum force perpendicular to the plane of the carrier structure.

In other words, on the one hand, a sufficiently secure hold of the μ-LED by the mounting elements should be achieved, on the other hand, the possibility should be deliberately created to detach the μ-LED with as little force as possible and, for example, to feed it to a transfer tool. For this purpose, it may be necessary to provide a contact surface for each support element that is smaller than 1/20, in particular smaller than 1/40 and in particular in the range from 1/80 to 1/50 smaller than the chip area of the μ-LED. In an alternative configuration, an edge length of the μ-LED is at least by a factor of 10, in particular at least by a factor of 20, greater than an edge length of the support element.

“Detachable” is to be understood to mean that there is no permanent, e.g. materially coherent connection such as fusing, gluing or similar between the microchip and the receiving element, but a non-destructive, detachable connection. The attachment can be based on a physical connection, such as an adhesive connection by Van-De-Waal forces or electron bridges. The same can be given by different materials and a suitable selection of them between the μ-LED and the receiving elements. This is intended in particular to avoid breaking or similar processes that would involve the destruction of material structures with the corresponding fragments, particles or splinters. Instead, alternative adhesion mechanisms such as the exploitation of mechanical friction or delamination are used here. In particular, known limited or restricted adhesion properties of materials or material combinations are exploited. According to an example, the μ-LED is placed between two or more holding elements.

At the contact surfaces, for example, adhesive forces or other adhesion forces arise, which allow mechanical fixing of the μ-LED in space. If a defined minimum force is applied to the μ-LED, e.g. by an attached transfer tool, this results in detachment forces at the contact surfaces between the μ-LED and the mounting elements. This defined minimum force can be influenced by a suitable selection of materials or material combinations at these contact surfaces.

The contact surfaces or overlaps can, for example, comprises an area dimension in the range of 0.05 μm² to 1 μm². In this case it is desirable to achieve a secure hold of the μ-LED on the carrier structure on the one hand. On the other hand, it is substantial for an effective and fast mass transfer of the μ-LED that the μ-LEDs can be lifted upwards and detached with as little force as possible. For this purpose, it may be necessary to provide for a ratio between the contact area of each element and chip and the total chip area of less than 1/20, in particular less than 1/40 and in particular in the range from 1/80 to 1/50 smaller than the chip area. In an alternative configuration, an edge length of the μ-LED is at least by a factor of 10, in particular at least by a factor of 20, greater than an edge length of the receiving element. The available area of the pick-up element may be larger, but the μ-LED rests on only a part of this area. The contact area of the chip is therefore at least 20 times, in particular at least 40 times smaller than the total chip area.

A suitable compromise must be found here, for example by the appropriate selection of materials or material combinations and the dimensioning and placement of the contact surfaces. The defined minimum force can also be influenced by designing the size and shape of these contact surfaces. Large contact areas consequently lead to a higher minimum force required to detach the μ-LED from the carrier structure. In addition to holding principles caused by friction or lamination, magnetic, electrical or similar holding forces are also conceivable.

According to another example, it is also possible that the carrier structure has only one single holding element to hold a μ-LED. Due to the low weight of the semiconductor structures, it is conceivable that a contact surface between the single holding element and the μ-LED, which is suitable in its shape and sufficiently dimensioned in terms of its size, could provide sufficient hold in combination with a suitably high minimum force for detaching the μ-LED.

In one embodiment, a substrate for the production of the μ-LEDs can also serve as a carrier structure. In such a case, a sacrificial layer may be provided. During the manufacturing process, the μ-LED is connected to the growth substrate. To expose the finished μ-LED, for example, this intermediate sacrificial layer is removed by gas or plasma-based etching processes so that a gap is created between the μ-LED and the wafer. A thickness of the sacrificial layer is, for example, 100 nm (nanometers) to 500 nm. The idea here is that when the sacrificial layer is removed, the receptacle elements take over a holding function for the μ-LED on the carrier structure. The mounting elements can have the shape of an anchor.

A pull-off of the μ-LED is usually done in a direction away from the carrier substrate, with a force vector that is at least partially perpendicular to a carrier substrate plane, which is to be understood in x-y-direction. The pick-up elements remain on the carrier substrate and in particular do not break. Thus, no residues of the pick-up element remain on the μ-LED, which could cause problems during subsequent processing.

According to an aspect, at least one mounting element is configured to simultaneously hold and/or support another, adjacently arranged μ-LED. The considerations regarding this feature can be summarized as follows: Holding structures for μ-LEDs often require space, which ideally should be minimized in order to achieve a higher yield on a wafer. Due to the manufacturing process, the μ-LEDs in turn are arranged next to each other on a wafer in a regular structure.

There are gaps in between due to the process. The inventors now propose to position a mounting element between two adjacent μ-LEDs so that this one mounting element supports or accommodates several adjacent μ-LEDs. The advantage here is that less than one entire holding structure per component can be achieved mathematically. This can reduce the total number of holding elements, thus saving space and consequently costs. In addition, an overall chip yield remains substantially constant, since no additional space is required for the holding structure on the wafer, which would be at the expense of the number of μ-LEDs.

For example, a receptacle element may have contact surfaces arranged opposite one another, which are then in mechanical contact with the adjacent μ-LED in this direction. The pick-up elements can then be distributed and arranged over a surface of the carrier substrate in such a way that a minimum number of pick-up elements are used to hold the μ-LEDs securely. This can be advantageous, for example, for the effective use of a transfer tool to enable effective and fast pick-up of the μ-LEDs. According to an aspect, the mounting elements are arranged on the carrier substrate in such a way that one μ-LED is held by exactly three mounting elements. The choice of three holding elements can be an advantageous compromise in that a good spatial stabilization in combination with a favorable distribution of the holding forces can be achieved. A shifting or tilting, especially in lateral direction on the carrier substrate can be effectively prevented here. In doing so, a support element can act on the microchip at different lateral areas in the X-direction and Y-direction, for example in the center, off-center or at an edge or corner. Several pick-up elements can also be arranged on one and the same side of a μ-LED.

According to an aspect, a delamination layer is provided on the μ-LED or on the mounting element to move the μ-LEDs out of the carrier structure. The term “delamination” is used here to describe a detachment process that occurs when two surfaces, or more generally, the connection of two layers, come into contact. This can affect similar materials, but also material connections or different material surfaces.

The deliberate creation of a so-called delamination layer is intended to prevent breakage or material-destroying or structure-altering processes and instead cause non-destructive separation of the layers or surfaces from one another. Certain combinations of materials can be used, for example a combination of SiO₂ and Al₂O₃, but also the use of non-oxidizing metals such as silver, gold or similar materials in combination with a dielectric such as SiO₂. In one aspect, the surface of the picking up element is thus surrounded by the delamination layer, so that the delamination layer is formed between the μ-LED and the picking up element. The delamination layer can only be a few nm thick, for example in the range of 5 nm to 50 nm. The delamination layer can also be formed as an etch stop layer in one aspect or optionally extend over other parts of the carrier structure.

According to an aspect, the picking up elements are arranged in a mesa trench of a semiconductor wafer. As already mentioned, an optimal use of space on a wafer to increase the yield is generally desirable. Holding structures for μ-LEDs often require additional space. In the manufacturing process, various process steps are used to create three-dimensional structures in which, for example, a μ-LED is formed at the end as an elevation or mesa. So-called mesa trenches are formed between these individual μ-LEDs.

The term mesa trench is used to describe a comparatively steep flank like feature on the sides of a μ-LED, whereby the trench, i.e. the area without epitaxy, references the deep structure in between. For example, the mesa can have a slope steepness in the range of 30° to 75°, especially of 45°. The idea here is to place the pick-up element exactly in this already available spatial area without taking up additional space on the wafer. This allows a better utilization of the available space on the wafer.

According to an aspect, the supporting structure and the receiving elements are made in one piece. This can mean, for example, that the receiving elements are part of the carrier substrate. The carrier substrate can be a wafer, but also a PCB board, foil, frame or similar structure. In the latter cases, this means that the mounting elements themselves are made of a different material and/or structure than the carrier substrate. This can be achieved in a manufacturing process, for example, by preserving the originally existing wafer structures in a locally limited manner through the various process steps and not removing them by etching processes, for example. These structures then serve as holding elements and holding structure for the finished μ-LEDs.

In one aspect, the mounting elements are designed to hold a μ-LED on the side and from a lower side of the μ-LED. In order to hold a μ-LED on an underlying carrier substrate, it can be useful on the one hand to create a partial contact surface or bearing surface that provides a mechanical stop in the Z-direction, i.e. in the direction of the carrier substrate. At the same time, a spatial fixation in lateral direction, i.e. in X-direction and Y-direction, can be achieved by additionally providing a lateral stop. In this way, a stable spatial fixation can be achieved in the direction of the carrier substrate and in the lateral direction on the one hand, and on the other hand, a slight lifting of the μ-LEDs away from the carrier substrate in the Z-direction can be made possible by a transfer process or a transfer tool.

In one aspect, the mounting elements have μ-LED holding surfaces that slope away at an angle relative to the carrier substrate plane, so that when the μ-LEDs are moved away from the mounting elements, a holding force on the μ-LED is reduced. In other words, the holding surfaces move away from the μ-LED the further the μ-LED is moved in the direction away from the carrier substrate. This can also be understood to mean that a holding force is successively reduced when the μ-LED is lifted away from the carrier structure by a transfer tool, for example. This is primarily intended to reduce the force required to pull off the μ-LED, in particular to reduce runtimes of the process steps and to increase the quality of a transfer process.

Traditionally, there are various ways of transferring chips from a carrier wafer to a corresponding target substrate.

State of the art transfer processes such as laser transfer printing or “self-assembly” of individual micro light emitting diode chips from a solution or electrostatically activated or diamagnetic transfer processes are known.

An extension of these concepts is achieved with the electrostatic transfer explained in more detail. A method is to be specified with which optoelectronic semiconductor chips with particularly small dimensions, i.e. μ-LEDs, can be picked up and deposited and at the same time, those μ-LEDs, which have certain defects, can be sorted out. Furthermore, a corresponding device for picking up and depositing optoelectronic semiconductor chips is to be created.

The proposed concept is based on the aspect that electron-hole pairs are generated in μ-LEDs and generally in optoelectronic semiconductor chips. The μ-LEDs may each have a semiconductor layer with a photosensitive region, also called optically active region. In the optically active region, charge carriers or electron-hole pairs can be generated by appropriate excitation, especially by incident light. An electron-hole pair consists of a defect electron and an electron, which has been brought from its ground state in the crystal to an excited state by the absorption of energy.

The electron-hole pairs can be separated from each other by suitable properties of the semiconductor material, such as two regions with different concentrations of dopants, like a p-n junction. As a result, charges are generated in the respective semiconductor chips, which create a dipole field outside the semiconductor chips. This process is also known as the photovoltaic effect. The strength of the dipole field generated by a particular semiconductor chip depends on the properties of the semiconductor chip. Semiconductor chips can have defects, such as short circuits, shunts or reduced efficiency, which typically lead to an accelerated discharge of the charges generated by the excitation and thus to a reduced dipole field. Furthermore, according to the proposed method, a pick-up tool is provided, which serves to pick up the μ-LEDs or the optoelectronic semiconductor chips and to place them at predetermined positions or locations, for example on a board on which the μ-LEDs are to be mounted. This process is also referred to as “pick and place” in the English language technical literature. It is also intended that the pick-up tool generates an electric field at least at certain locations, for example by being electrically charged at these locations. The μ-LEDs are picked up by the pick-up tool during or after the generation of the electron-hole pairs.

The electric field generated by the pick-up tool interacts with the dipole fields of the optoelectronic semiconductor chips, creating an attractive or repulsive force between the pick-up tool and the optoelectronic semiconductor chips. The electrostatic interaction or force can superimpose an interaction or force that exists between the pick-up tool and the optoelectronic semiconductor chips even without the electric dipole fields caused by the electron-hole pairs. For example, a van der Waals attraction or an electrostatic attraction can exist between the pick-up tool and the respective optoelectronic semiconductor chips even without the dipole charge generated by the excitation. The additional electrostatic attraction makes it possible to overcome a threshold above which the μ-LEDs are released from a carrier on which the μ-LEDs are arranged and are picked up by the pick-up tool.

The force required to remove the optoelectronic semiconductor chips from the carrier may be greater than the force required to hold the removed optoelectronic semiconductor chips by the pick-up tool. Therefore, the electrostatic force may only be required to remove the optoelectronic semiconductor chips and not to hold them. Consequently, the presence of the electric dipole fields is only necessary to remove the optoelectronic semiconductor chips, but not necessarily to hold the optoelectronic semiconductor chips afterwards.

μ-LEDs with certain defects, for example short circuits, shunts, low efficiency or other defects, have a lower dipole field when excited than μ-LEDs without such defects. Accordingly, the electrostatic interaction between the pick-up tool and the defective μ-LEDs is so small that the latter cannot be picked up by the pick-up tool and remain on the carrier. In other words, the electrostatic interaction between the pick-up tool and the μ-LEDs is selected in such a way that only in functioning μ-LEDs is the acting force sufficiently strong. In other words, the electric field generated by the pick-up tool is chosen so that only in interaction with functional μ-LEDs is the resulting electrostatic force sufficient to lift the μ-LEDs off. For defective μ-LEDs that have a lower dipole field, the interaction is not sufficiently strong.

Therefore, the concept presented here makes it possible that defective μ-LEDs are not picked up and, accordingly, not mounted, thus considerably reducing the repair effort caused by mounting defective optoelectronic semiconductor chips. It should also be mentioned here that the interaction also depends on the mass or size of the μ-LEDs and must therefore be selected accordingly for a nominal size so that a functional μ-LED just sticks.

Alternatively, by appropriate design, μ-LEDs or optoelectronic semiconductor chips with certain defects that reduce the dipole field can be caused to be picked up by the pick-up tool and “good” μ-LEDs with higher dipole fields can be rejected by the pick-up tool and remain on the substrate. Such configuration also causes a separation of good and defective μ-LEDs and optoelectronic semiconductor chips.

The pick-up tool can be made of a suitable material to generate an electric field. For example, the pick-up tool may have polydimethylsiloxane (PDMS) in which metal contacts are embedded. The metal contacts can be connected to an electrical power source to charge the PDMS material to generate the electric field. Furthermore, the mounting tool can be made of a suitable electrically charged material, which generates an electric field by itself.

Another option for generating the electric field is to generate the electric field, for example by contacts inside or on the surface of the pick-up tool and an electric voltage. The electric field can also extend between the pick-up tool and an electrical contact, with the μ-LEDs located between the pick-up tool and the electrical contact. The electrical contact can, for example, be the carrier on which the μ-LEDs or optoelectronic semiconductor chips are placed or integrated into the carrier.

The μ-LEDs can be produced on a semiconductor wafer and then separated, for example by sawing. After separation, the μ-LEDs can be mounted on a circuit board or other carrier using the method described here. It is also possible to transfer not only individual μ-LEDs but also μ-LED modules or smaller arrays of contiguous μ-LEDs using this process. In this context, reference is made to the μ-LED modules or structures described in this application, which can be easily transferred using the proposed transfer method.

Due to their small dimensions and possibly large number, no conventional methods can be used economically for μ-LEDs, where the LEDs are first tested and then mounted on a circuit board. Unlike conventional methods, the process described in the present application makes it possible to sort out defective μ-LEDs before mounting them.

The excitation of the μ-LEDs to generate the electron-hole pairs can be achieved by irradiating the μ-LEDs with light, especially UV light. The light spectrum must have a wavelength or a wavelength range that allows excitation, especially photoluminescence excitation. In particular, the excitation radiation must have a higher energy than the radiation emitted by the optoelectronic semiconductor chips so that electron hole pairs can be generated directly. Consequently, the wavelength of the excitation radiation must be shorter than the wavelength of the radiation emitted by the optoelectronic semiconductor chips. For example, blue μ-LEDs emit light at about 460 nm. In this case, the excitation radiation should have a wavelength of 440 nm or shorter, for example a wavelength of approx. 420 nm.

The light used to generate the electron-hole pairs can fall on the μ-LEDs through the pick-up tool. To make this possible, the pick-up tool can be made at least partially of a material that is at least partially transparent or translucent to the light. Furthermore, openings or light guides can be integrated into the pick-up tool through which the light reaches the μ-LEDs.

The μ-LEDs or semiconductor chips can be arranged on a carrier or substrate before being picked up by the pick-up tool. The light used to generate the electron-hole pairs can pass through the carrier or substrate onto the μ-LEDs. For this purpose, the carrier or substrate may be made at least partially of a material that is at least partially transparent or transmissive to the light, or openings or light guides may be integrated into the carrier or substrate.

Alternatively, the light can be radiated laterally or at an angle onto the μ-LEDs or all optoelectronic semiconductor chips.

It may be envisaged that electron-hole pairs are not generated in all μ-LEDs or optoelectronic semiconductor chips, but only selectively in some of the devices. For example, a plurality of μ-LEDs fabricated on a wafer can be provided and the electron-hole pairs are only generated in selected μ-LEDs of the plurality of optoelectronic semiconductor chips. Then, except for the defective μ-LEDs of this selection, only these μ-LEDs are picked up by the pick-up tool. The selective excitation of the μ-LEDs can be achieved, for example, by passing the light for generating the electron-hole pairs through a mask.

Another possibility for picking up only a selection of μ-LEDs is that the pick-up tool generates an electric field only in predetermined areas. This can be achieved, for example, by at least partially individually controlling the metal contacts embedded in the pick-up tool. By means of this selection it is possible to create suitable distances of μ-LEDs to be recorded (e.g. only every third, fourth, tenth etc.). The distances can be selected in such a way that the recorded μ-LEDs can be placed directly on the target matrix.

According to one embodiment, the pick-up tool has a plurality of protrusions or stamps on a surface facing the μ-LEDs. When the pick-up tool is lowered, only the protrusions come into contact with the optoelectronic semiconductor chips, so that only the protrusions pick up μ-LEDs. The areas between the elevations and the areas outside the elevations do not pick-up optoelectronic semiconductor chips. Here too, the elevations can be arranged at predefined distances corresponding to the places to be occupied in a target matrix. In this application a further concept is revealed, which continues this aspect.

Alternatively, at least in one area, the pick-up tool may have a continuous flat surface intended for picking up the μ-LEDs. This allows greater flexibility, since μ-LEDs or optoelectronic semiconductor chips arranged in different patterns and/or with different spacing can be picked up.

Furthermore, the pick-up tool can have the shape of a cylinder, which is rolled over the μ-LEDs to pick up the μ-LEDs. For example, the pick-up tool can be shaped like the drum of a laser printer. To pick up the μ-LEDs, the cylindrical pick-up tool can be moved over the μ-LEDs. Alternatively, the axis of rotation of the cylindrical pick-up tool can be stationary and the carrier with the optoelectronic semiconductor chips can be slid under the pick-up tool.

To deposit the μ-LEDs, the electrical charge of the pick-up tool can be changed via the metal contacts. For example, the polarity of the metal contacts can be reversed. This leads to a repulsive electrical interaction between the pick-up tool and the μ-LEDs polarized by the electron-hole pairs. As a result, the μ-LEDs either are noticed or hit the target matrix.

Furthermore, the charge can also be changed only at certain positions or in certain areas of the pick-up tool, so that certain μ-LEDs are selectively deposited.

Another way of depositing the μ-LEDs is that the carrier or substrate to which the μ-LEDs are applied generates an adhesive force that is greater than the attractive force between the pick-up tool and the μ-LEDs. For example, the surface of the carrier or substrate can be coated with an adhesive, a lacquer, a soldering material or other suitable materials. Furthermore, the μ-LEDs can be detached from the mounting tool by mechanical forces, for example by shearing or acceleration forces.

According to one embodiment, the pick-up tool directly touches the μ-LEDs or optoelectronic semiconductor chips to pick them up. During the transfer of the optoelectronic semiconductor chips, the pick-up tool holds them by means of Van der Waals forces.

Another aspect concerns a device intended for picking up and placing optoelectronic semiconductor chips. The device can be, for example, a pick and place machine or be integrated into a pick and place machine.

The device comprises an excitation element for generating electron-hole pairs in μ-LEDs or optoelectronic semiconductor chips and a pick-up tool for picking up and placing the μ-LEDs or optoelectronic semiconductor chips. The electron-hole pairs generate electrical dipole fields in the vicinity of the μ-LEDs or optoelectronic semiconductor chips. The pick-up tool is configured in such a way that it generates an electric field, which interacts with the electric dipole fields of the μ-LEDs, or optoelectronic semiconductor chips in order to pick them up. The picked up μ-LEDs or optoelectronic semiconductor chips are transferred to predetermined locations and deposited there.

According to one embodiment, the excitation element is designed to generate light with a predetermined wavelength or a predetermined wavelength range to generate the electron-hole pairs in the μ-LEDs or optoelectronic semiconductor chips. The excitation element may, for example, comprise a light source and/or a light guide.

The excitation element can be arranged in such a way that the light for generating the electron-hole pairs is incident on the μ-LEDs through the pick-up tool or through a carrier on which the μ-LEDs are arranged. The pick-up tool may have a plurality of projections on a surface facing the μ-LEDs or the optoelectronic semiconductor chips. The μ-LEDs or the optoelectronic semiconductor chips can be picked up by the projections of the pick-up tool.

Alternatively, at least a portion of a surface of the pick-up tool facing the μ-LEDs or optoelectronic semiconductor chips may be continuously flat and configured to receive the μ-LEDs or optoelectronic semiconductor chips.

Furthermore, the device for picking up and depositing μ-LEDs or optoelectronic semiconductor chips can have the above-described configurations of the method for picking up and depositing μ-LEDs or optoelectronic semiconductor chips.

A further aspect for the realization of μ-displays concerns a solution in which a double transfer process is used for the transport and positioning of μ-LEDs on a backplane substrate, wherein an intermediate carrier is formed in the target size of the array, in particular the display, and has an identical μ-LED density as the wafer on which the μ-LEDs are manufactured. During the transfer to the target substrate, a thinning of the microchips is carried out, whereby in the best case the microchips of one color are transferred from the intermediate carrier to the target substrate by a correspondingly large transfer stamp in a single transfer step per color red, green. An average number of transfer steps per array can be effectively reduced by more than one order of magnitude by means of such a two-stage transfer process. This results in cost savings in the production of large area μ-displays by reducing the number of stamping steps by using an intermediate carrier

According to some aspects, a process for the production of a number (n or less) of arrays A of optoelectronic pixels, which are in particular μ-displays. The process can also be carried out for each of the colors red, green and blue. In a first step, a large number of μ-LEDs with a first density are generated on a wafer or carrier substrate. Then a first transfer stamp is used to transfer the μ-LEDs to an intermediate carrier with the first density. Then a second transfer step is performed by means of a second transfer stamp. This transfers the μ-LEDs from the intermediate carrier to a target substrate with a second density that is a factor n (n in particular an integer) smaller than the first density. The target substrate provides a common array surface for a respective one of the arrays, in particular for all three colors, the size of the intermediate carrier being equal to or larger than that of the second transfer stamp and the size of the second transfer stamp being equal to or smaller than the array surface by a factor k (k in particular an integer).

In a further aspect, an intermediate carrier can be provided on which module areas removed from the carrier substrate can be set down from the first transfer stamp. The intermediate carrier can have several module areas. In this way, an intermediate carrier is provided on which module areas can be temporarily transferred completely, but which can also be removed again in a second transfer step in order to transfer to a final target substrate.

The μ-LEDs on a carrier substrate can be manufactured in such a way that they can be removed from the carrier substrate individually or in parallel by means of anchor elements. The adhesive force on the intermediate carrier must be stronger than the adhesive force of the μ-LEDs on the first transfer stamp. If the μ-LEDs are removed from the intermediate carrier for a second time, the adhesive force of the μ-LEDs on the second transfer stamp must be correspondingly greater than the adhesive force on the intermediate carrier. Likewise, the transfer from the second transfer stamp to the final substrate surface must be possible by a suitable choice of adhesive, intervias or soldering on the target substrate. The coordination of adhesive and release forces by a suitable material selection and a suitable process control for the two stamping processes leads to the provision of a starting structure.

For this purpose, the system proposes a start structure that uses a two-level use of anchor elements. On the one hand, anchor elements are used for entire module areas on which many thousands or many millions of μ-LEDs are arranged. Secondly, anchor elements are used for the transfer of μ-LEDs from the intermediate carrier to the target substrate.

According to another aspect, when creating the μ-LEDs, they can be created together with the respective module areas, which can each be connected to the carrier substrate. According to a further embodiment, when generating the μ-LEDs, first anchor elements for connecting with a first adhesive force can be formed between the module areas and the wafer and/or second anchor elements for connecting with a second adhesive force can be formed between the μ-LEDs and the module areas.

A further aspect concerns the lift-off force. A lift-off force is a force that must be applied at least to perform a lift-off. For example, when performing the first transfer steps, the lifting force of the lifting first transfer die can be set to be greater than the first adhesive force and less than the second adhesive force so that the module areas can be lifted off the wafer and transferred to the intermediate carrier. Correspondingly, it is conceivable in a further aspect that, when carrying out the second transfer steps, the lifting force of the lifting second transfer stamp is set greater than the second adhesive force in such a way that the microchips can be lifted off the module areas and transferred to the target substrate.

In another aspect, release elements are formed between wafer and module areas and/or between μ-LEDs and module areas in such a way that after their removal, a first and/or a second defined adhesive force is set in each case. It is also conceivable that when generating the μ-LEDs between the module areas and the wafer, additional first release elements for connecting with an additional first adhesive force and/or between the microchips and the module areas, additional optional second release elements for connecting with an additional second adhesive force are formed.

According to another embodiment, when carrying out the first transfer steps, the lifting force of the lifting first transfer die can be set to be greater than the total first adhesive force and less than the total second adhesive force so that the module areas can be lifted off the wafer and transferred to the intermediate carrier. Alternatively or additionally, when carrying out the second transfer steps, the lifting force of the lifting second transfer stamp can be set to be greater than the total second adhesive force so that the microchips can be lifted off the module areas and transferred to the target substrate.

In a further aspect of this, the additional second adhesive force can be reduced to zero by removing the second release elements beforehand. In this way, the lifting force of the lifting second transfer stamp need not be greater than the lifting force of the lifting first transfer stamp.

According to another embodiment, materials with a greater adhesive force than the second defined adhesive force can be used to carry out the second transfer step for the adhesion of the module areas to the intermediate carrier. The second adhesive force is set accordingly for the second transfer step using separate anchor elements and, if necessary, release elements. It is conceivable to form lifting elements directly on the module areas for lifting and transferring the module areas to the intermediate carrier in order to carry out the first transfer step.

A further aspect deals with the correct positioning of the module areas on the intermediate carrier or even the target substrate. In one aspect of this, positioning elements are formed directly on the module areas to carry out the first transfer steps for the precise transfer of the module areas to the intermediate carrier. These positioning elements serve as orientation for the first transfer stamp. The positioning elements can be provided by means of the lifting elements.

According to another embodiment, for the execution of the second transfer steps, tapping elements can be formed on the second transfer die for thinning out the μ-LEDs into the second density. The density of these elements corresponds to the second density of a display.

According to another aspect, the size of the rectangular first transfer die can be chosen smaller by a factor of s to the size of the round carrier substrate in such a way that the size of an area of lost μ-LEDs at the edge of the carrier substrate for the first transfer to completely fill the receiving area is small, in particular per color less than or equal to 20% or less than or equal to 30% of the carrier substrate area. Alternatively, the size of the rectangular first transfer stamp can be selected to be smaller than the size of the intermediate carrier by a factor r in such a way that the number of first transfer steps r for the first transfer for complete loading of the intermediate carrier is small, in particular per color less than or equal to 10 or less than or equal to 50.

According to another embodiment, the shape of the intermediate carrier can correspond to the shape of the second transfer stamp and this in particular to the shape of the array surface. The shape of the array of optoelectronic pixels can be rectangular, trapezoidal, triangular or polygonal, have rounded corners, or be any other free form. According to another embodiment, the intermediate carrier can be equipped with tested module areas from one carrier substrate or from different carrier substrates. According to another embodiment, the distances between the μ-LEDs on the respective wafer can correspond to the distance between the μ-LEDs on the intermediate carrier.

According to a further embodiment, the distances between μ-LEDs on a respective intermediate carrier and on a respective target substrate in an x-direction can be different from those in a y-direction. According to another embodiment, the target substrate can be equipped with module areas of several intermediate carriers.

According to another embodiment, the color of the microchips of a respective intermediate carrier can be monochrome red, green or blue and the number of n color arrays can be formed from three intermediate carriers, which have microchips of different colors to each other.

According to another embodiment, first first release elements can be selectively removed between wafer and module areas and then second release elements between microchips and module areas.

In addition to the structure of a μ-LED and various methods for its manufacture, the following are also possible aspects of light extraction essential for the realization of the possibilities described herein.

In one aspect a rear decoupling can be provided. For this purpose, a semiconductor layer stack with a first doped and a second doped layer is provided, which is arranged on a substrate. The area of the substrate facing away from the layer stack is designed for light extraction. The layer stack comprises an active region which is arranged between the first doped and the second doped layer. The layer stack is provided with a reflective contact on the surface facing away from the substrate. The reflective contact extends isolated from the doped layers along a side surface to the substrate surface. The shape of this reflective contact is spherical or paraboloidal or ellipsoidal to direct the light generated in the active layer towards the substrate. The substrate is either very thin or transparent. Further light shaping and/or outcoupling measures can be provided on the area of the substrate facing away from the layer stack.

In the previous aspects of improving light extraction, the focus was on the directionality of the emitted light, among other things. For many applications, however, a Lambertian radiation characteristic is required. This means that a light-emitting surface ideally has a uniform radiation density over its area, resulting in a vertically circular distribution of radiant intensity. For a user, this surface then appears equally bright from different viewing angles. In addition, such a uniform distribution can be more easily reshaped by light-shaping elements arranged downstream.

It is therefore proposed that an optical pixel element for generating a pixel of a display should comprise of a flat carrier substrate and at least one μ-LED with rear output. The μ-LED forms an optical emitter chip. A flat carrier substrate is understood to be, for example, a silicon wafer, semiconductor materials such as LTPS or IGZO, insulation material or similar suitable flat carrier structure, which can accommodate a large number of μ-LEDs arranged next to each other on its surface.

The function of such a carrier substrate is, among other things, the accommodation of functional elements such as ICs, electronics, power sources for the μ-LEDs, electrical contacts, lines and connections, but also, in particular, the accommodation of the light-emitting μ-LEDs. The carrier substrate can be rigid or flexible. Typical dimensions of a carrier substrate can, for example, be 0.5-1.1 mm thick. Polyimide substrates with thicknesses in the range of 15 μm are also known.

The at least one μ-LED is arranged on one side of the carrier substrate. In other words, the carrier substrate has two opposite main surfaces, which are referred to here as the assembly side and the display side. The assembly side is the surface of the carrier substrate, often also referred to as the top side, which accommodates the at least one μ-LED and which may further comprise optical or electrical and mechanical components or layers.

The display side should describe the side of the carrier substrate facing a user and on which the pixels for display should be perceived. In addition, a carrier substrate plane is described, which extends parallel to the two main surfaces of the carrier substrate in the same plane. The at least one μ-LED is configured to emit light transverse to the carrier substrate plane in a direction away from the carrier substrate. However, this property should not exclude that light components are also emitted directly or indirectly in the direction of the mounting side of the carrier substrate.

A flat reflector element is provided on the pixel element. This is based on the idea that a more uniform spatial distribution of the light over the surface of the pixel element can be achieved by reflection. For this purpose, the reflector element is spatially arranged on the assembly side relative to the at least one μ-LED and configured with regard to its shape and composition in such a way that light emitted by the at least one μ-LED is reflected in the direction of the carrier substrate.

In other words, the reflector element is placed in an area around the at least one μ-LED through which the emitted light of the μ-LED passes. This reflector element can, according to an example, be a separate prefabricated microelement that is separately applied. Typical dimensions of such a reflector element can range from 10 μm to 300 μm in diameter, depending on the design variant also in particular between 10 μm and 100 μm. According to an aspect, the reflector element is configured as a reflective coating or layer of at least one μ-LED. According to an example, the at least one μ-LED can have a transparent or partially transparent coating such as IGZO on its surface, to which a reflective layer is then applied.

The reflective layer can, for example, be metallic or contain a metal in a mixture of substances. The aim here is that as much of the light emitted by the at least one μ-LED as possible is reflected in order to achieve a high yield. The carrier substrate is configured to be at least partially transparent so that light reflected by the reflector element strikes the surface of the mounting side of the carrier substrate and propagates through the carrier substrate. This light emerges at least partially on the opposite display side of the carrier substrate and can thus be perceived as a pixel by the viewer.

In other words, the emitted light is decoupled at the back or rear of the opposite display side of the carrier substrate. The reflection effects, refraction effects and, if necessary, damping effects can thus be used to achieve advantageous more uniform illumination and a more homogeneous distribution of luminous intensity. According to an example, the reflector element is arranged and configured in such a way that a Lambertian radiation characteristic is achieved.

In one aspect, the reflector element has a diffuser layer on its side facing the at least one μ-LED. This is intended in particular to scatter the light reflected by the at least one μ-LED. Alternatively or additionally, a reflector material comprises diffuser particles. By diffusion is meant here that a further scattering or distribution of the light in a surrounding spatial area should be achieved. This can also have a beneficial effect on the scattering or distribution of light and thus achieve a more uniform or homogeneous distribution of the light intensity, especially on the display side of the carrier substrate.

A diffuser layer can be understood as an additional layer on the reflector element, which can be either uniform throughout, but also interrupted or only partially applied. In one aspect, the diffuser layer and/or the diffuser particles have Al₂O₃ and/or TiO₂. These materials can support a diffusion of the emitted light due to their structural properties. While a diffuser layer can only be applied to the surface of the reflector, diffuser particles can, for example, be part of a mixture of materials of the entire reflector and thus be easier to manufacture.

According to an aspect, the reflector element surrounds roundly, polygon-like or parabolically the at least one μ-LED. The underlying consideration can be seen in the fact that in many cases the at least one μ-LED has a spatially wide radiation pattern. This means that light is emitted in a wide angular range starting from a small area. It is desirable that as much of this emitted light as possible is captured by the reflector element and deflected or reflected towards the display side of the carrier substrate. In this context, it may also be provided, for example, that the at least one μ-LED comprises a first and a second μ-LED provided for redundancy. This can take over the function of the first μ-LED in the event of production-related failure of the first μ-LED. Control and manufacturing techniques are disclosed in this notification. The reflector element, which surrounds both μ-LEDs thus ensures uniform radiation regardless of which of the two μ-LEDs is activated during operation. In another aspect, the reflector element surrounds at least three individual μ-LEDs, which emit different colors during operation. This means that a reflector element can be provided for each pixel of a μ-display.

Depending on the radiation pattern of the at least one μ-LED, according to an example, arc-shaped, round, dome-like, cap-like or similar shapes of the reflector element are conceivable. The reflector element can, also according to an example, be made in one or more parts or be provided with recesses or interruptions. According to another example, the reflector element has different reflection properties depending on the wavelength of the light. This can be achieved, for example, by microstructures on the reflector element or its structural composition.

According to an example, the reflector element is configured as a flat surface which is arranged perpendicular to the carrier substrate plane above the at least one μ-LED. According to an aspect, the reflector element forms an electrical contact of the at least one μ-LED. The consideration here is that due to the metallic design of the reflector element, for example, a simultaneous use as a connecting contact for the μ-LED can be considered. For this purpose, an electrical contact with one of the μ-LED connections must be provided according to an example.

According to an aspect, the reflector element is configured and shaped in such a way that at least 90% of the light emitted by at least one μ-LED impinges on the assembly side of the carrier substrate at an angle of 45°-90° relative to the carrier substrate plane. According to an example, this proportion is at least 95%, according to another example at least 80%. The underlying idea is the need for the highest possible yield. This means that as much of the light emitted by at least one μ-LED as possible should be emitted on the display side of the carrier substrate.

One effect that can occur with flat transparent or partially transparent substrates is total reflection. This means that light hitting the surface of the placement side at an acute angle is refracted when entering the denser medium of the carrier substrate. As a result, the light is reflected multiple times within the carrier substrate between the placement side and the display side and does not exit the carrier substrate because of the too acute angles to the interfaces. These proportions are usually to be considered as losses. In order to avoid these losses, it may be desirable for the light to strike the surface of the placement side of the carrier substrate at the greatest possible angle, ideally perpendicularly. Accordingly, the reflector element is configured to create these angular relationships and in particular to reduce crosstalk between the pixel elements. In one aspect, the carrier substrate comprises polyimide or glass. Polyimide is a material that can be used especially for flexible displays. Glass can serve as a mechanically very stable base material for rigid displays.

According to an aspect, a passivation layer is additionally provided to attenuate or eliminate reflections at mesa edges of the at least one μ-LED. A mesa edge is defined as a wall or contour that generally slopes steeply to form the boundary of the at least one μ-LED. This is arranged with its surface transverse to the carrier substrate plane. To avoid crosstalk, it is desirable that no light passes over in the direction of the respective adjacent pixel element. For this purpose, light components that emerge in this direction should be eliminated or at least attenuated by an appropriate damping layer or passivation layer. The advantage here can be better contrast and reduction of optical crosstalk.

According to an aspect, a light-absorbing coating is provided on the assembly side and/or the display side of the carrier substrate outside the reflector element. It can be considered desirable that the non-active areas between the μ-LEDs, especially between different pixels, are opaque or attenuate light in order to improve contrast and darker impression. The light-absorbing coating is therefore placed outside the reflector element. According to an aspect, the display side of the carrier substrate has a roughened or uneven and/or roughened structure. This structure is such that it causes scattering or diffusion effects for the wavelength of the relevant light spectrum. This can have the advantage, for example, that a higher proportion of the light transmitted through the carrier substrate can be coupled out at the display side. Due to the rough structure, more favorable microstructural angular relationships are created, which can allow more effective decoupling.

According to an aspect, a color filter element is arranged on the display side of the carrier substrate opposite the reflector element. This color filter element allows a primary color spectrum of the least one μ-LED to pass and attenuates other color spectra. An advantage can be a better color rendering and better contrasts by eliminating light portions of adjacent pixel elements with different colors.

Furthermore, a process for the production of an optical pixel element is proposed. In a first step, at least one μ-LED is attached to a mounting side of a flat carrier substrate. Then a reflector element is produced, for example as a reflective layer of the at least one μ-LED. According to an example, before attaching the at least one μ-LED to the carrier substrate, a display side of the carrier substrate is processed for microstructuring and/or roughening. An advantage can be seen in the fact that the respective surfaces can be finished before the more sensitive electronic and optical components are applied to the assembly side.

A substantial aspect of light extraction is the ability to suppress unwanted light components. In some applications, a highly directional light is also desired. The μ-LED or pixel should therefore not have a Lambertian characteristic but a high directionality. In some cases, on the other hand, an unconverted portion of the converted light should be blocked or at least deflected in such a way that it does not reduce the visual impression.

Some of these properties can be achieved by providing a photonic structure or photonic crystal on the exit side of the light. In the following, some aspects are described, which illustrate different measures to collimate generated light to reduce the emission angle or otherwise shape it. Besides micro lenses or other measures, these include photonic structures. These change the emission behaviour by creating a “prohibited” area where light emission is not allowed. Accordingly, light emission in one or more directions can be suppressed or promoted.

In some aspects, an optoelectronic device may have a stack of layers with an active region for generating electromagnetic radiation. The device comprises at least one further layer having a photonic crystal structure. At least some of the layers of the layer stack are semiconductor layers. The stack of layers may include a p-doped layer and an n-doped layer, as well as a p-doped and an n-doped Gallium Nitride (GaN) layer forming the active region between the two layers. It should be noted that the layer stack forms a μ-LED, which may have one or more features of this disclosure in terms of geometry, material system, structure or processing.

At least one layer on the stack of layers can have a photonic crystal structure, especially a 2-dimensional structure. The photonic crystal structure can be arranged at least in a portion of the layer and can be formed for example by wire-like or cylindrical structures having a longitudinal direction which is at least substantially parallel to the growth direction of the layer. The structure forming the photonic crystal, such as the wires or cylinders, may comprise a first material, for example the material of the layer, while the space between the structure may be made of or filled with a second material having a different refractive index than the first material. The second material can be air or another substance, for example a conversion material.

The photonic crystal structure can be used to manipulate light generated in the active region as the light passes through the photonic crystal structure. In particular, the photonic crystal structure can be arranged so that light passing along the direction of growth can pass through the photonic crystal structure, while light passing at an angle close to or at 90 degrees with respect to the direction of growth cannot pass through the photonic crystal structure. This is particularly the case for light having wavelengths, which are within a photonic band gap formed by the photonic crystal structure.

In some aspects, the periodicity is at about half of a specific wavelength. This is the wavelength corresponding to the wavelength of electromagnetic radiation that must be diffracted by the photonic crystal structure. Thus, a periodicity in the range of 350 nm to 650 nm is appropriate for operation in the visible region of the spectrum—or even less, depending on the average refractive index. The repeating ranges of different dielectric constants in the photonic crystal structure can therefore be produced in this order of magnitude. In some aspects, an integer multiple of the corresponding wavelength can also be used.

In some embodiments, the layer with the photonic crystal structure is a dielectric layer, which contains or consists of silicon dioxide, SiO₂, for example. This can be an additional layer, which is added to the usual layers of a μ-LED. The same fabrication technology can therefore be used for GaN and GaP systems. The different manufacturing variants and possibilities can also be transferred to a converter layer. Thus, a greater bundling or collimation can be achieved compared to standard LEDs without such a structure. Also, the extraction efficiency with a photonic crystal structure applied in one layer is improved compared to a conventional LED without a photonic crystal structure.

In some aspects, the optoelectronic device may comprise one or more mirror layers arranged on top of the layer with the photonic crystal structure. The mirror layer or layers may be arranged to form an angle-selective mirror, for example as a cover layer. The concentration of the emitted light can be further improved. With beam-shaping structures, as given by using a layer with a photonic crystal structure, up to 50% more light can be emitted into a 30 cone or less on the chip plane compared to a standard chip having a roughened surface. Such beam shaping allows high efficiency and low cost in projection applications. For μ-LED or monolithic display applications it may even be a requirement.

The different photonic decoupling structures create a certain roughness and surface structures on the surface, depending on their design. In addition, light emitting diodes often have a structured surface in the past to improve light outcoupling. In contrast, the stamping technology currently used to place μ-LEDs on electrical contacts is only possible for μ-LEDs with planar or flat surfaces.

Therefore a method of making photonic structures on a μ-LED, in which an optical outcoupling structure is created in a surface region of a semiconductor body providing the μ-LED. The surface area with the outcoupling structure is then further processed and planarized. In this way, a planar surface is obtained, but light shaping and outcoupling is still improved by means of the outcoupling structure.

Accordingly, a μ-LED thus contains a decoupling structure, which is arranged in a planar surface area. The output structure can also have light-shaping features, such as the photonic structures revealed here. This allows light to be emitted from a surface perpendicular to it.

In one aspect, the surface region of the semiconductor body is structured by generating a random topology at the surface region. A random topology involves directly roughening the surface of the surface region. Alternatively, a transparent second material, especially Nb₂O₅ with a high refractive index can be applied and then roughened.

In another aspect, the surface area is structured by an ordered topology and then planarized according to the explanations revealed here. For this purpose, photonic crystals or non-periodic photonic structures, especially quasi-periodic or deterministic aperiodic photonic structures, are introduced into a second transparent material. Interstitial spaces are filled and then planarized. Filling is done with a transparent third material with a low refractive index, especially smaller than 1.5, especially SiO₂.

The planarization is done by mechanical or chemical-mechanical polishing (CMP). This creates a planarized surface with a roughness in the range of less than 20 nanometers, in particular less than 1 nanometer, as the mean roughness value.

As already mentioned, a photonic crystal or other structure can be applied to the μ-LED or μ-LED array to form the beam of an LED or μ-LED. However, in some applications it is common to use non μ-LEDs that emit light of different wavelengths in one operation. Instead, one type of μ-LED is used and its emitted light is then converted. For this purpose, a converter material is applied to the surface of the μ-LED in the main radiation direction. The photonic crystal as light-shaping structure is arranged above the converter material as already revealed in some examples.

In the following, further aspects are explained, which are based on the idea of unification of light shaping and converting structure so that a particularly space-saving arrangement of the individual elements and thus a particularly small design of an optoelectronic component is possible. This achieves that the radiation emitted by the component is specifically radiated into a certain area of space, while radiation into other areas is reliably prevented in a comparatively simple way. In addition, all solutions with photonic structures presented here are characterized by high energy efficiency and thus by a comparatively good light yield compared to the known technical solutions.

In this context, some aspects first concern a converter element for a μ-LED. The converter element comprises at least one layer with a converter material which, when excited by an incident excitation radiation, emits a converted radiation into an emission area. The converter element is characterized in that the layer has a photonic structure at least in some areas, on which the converter material is arranged at least in sections. The photonic structure is designed in such a way that the radiation is emitted as a directed beam of rays into the emission area. Thus, a layer is provided which is structured in a suitable manner, wherein a converter material is applied in or on the structure, which emits converted radiation when excited by an excitation or pump radiation.

By combining the components converter material on the one hand and structured layer for targeted beam guidance and/or shaping on the other hand, an element is created in a particularly space-saving manner which enables a targeted emission of radiation into the radiation source's radiation area, limited to a desired spatial area. In this context, it is conceivable that both the converted radiation emitted by the converter element and the excitation radiation are directed in a suitable manner so that radiation is only emitted in a certain direction, while the emission of such radiation in other directions and/or areas is excluded or at least significantly reduced.

In general, it is conceivable that the photonic structure is coated with a suitable converter material at least in some areas and/or at least individual areas, for example depressions in the structure, are filled with the suitable converter material. The structure is configured in such a way that the emitted converted radiation is emitted as a beam of rays in a desired direction of the radiation area. Thus, light is both converted and shaped by the photonic structure. In this context, it is conceivable to adapt the photonic structure in a suitable way so that different areas are present into which a beam of radiation is emitted. In this way, converter elements can be provided which adjust the radiation characteristics of an optoelectronic component or a μ-LED in which they are used as required. In particular, it is possible to provide a converter element by which the emission profile of an optoelectronic component for which the converter element is used can be changed in such a way that the radiation no longer follows Lambert's law, but instead a beam or bundle of rays is generated which is directed in a specific direction.

The converter material may include the materials disclosed in this application and may be doped with various rare earth elements. As host material the already mentioned YAG or LuAG can be used. It is also possible to use the already mentioned quantum dots as converter material. The photonic structure normally does not change the spectral properties of a quantum dot. Besides the adaptation of the photonic structure to the emission spectrum of the quantum dots, they can also be located in the area of the structure itself, e.g. in formed trenches

The regular photonic structure or a regular photonic crystal offers the advantage that the optical properties of the converter element can be adjusted particularly reliably, safely and reproducibly with an appropriate structured layer. The structure is configured in such a way that radiation of a certain wavelength or a certain wavelength range can penetrate the layer in a specifically defined direction, while this radiation cannot penetrate the layer in other directions. Alternatively or additionally, the structured layer can be configured in such a way that it is transparent or non-transparent for radiation of a specific wavelength over at least a large range.

Furthermore, it is useful if the photonic structure has at least one recess in which the converter material is located. Preferably, in this context it is intended that the photonic structure has a plurality of elevations and depressions, the depressions being at least partially filled with the suitable converter material. In this way, a converter element can be realized comparatively easily, in which the structure provided according to the invention is combined with the converter material in such a way that the converted radiation is emitted only in a specifically limited radiation range and thus in a particularly targeted manner. In principle, it is conceivable in this regard that the converter element is configured in such a way that the excitation radiation is directed by the photonic structure in a targeted manner onto areas of the converter material provided for this purpose and/or that the converted radiation impinges on the structure and is thus emitted as a targeted beam of radiation into the desired radiation emission range.

In some aspects, the layer with the photonic structure is configured such that the layer comprises at least one optical band gap. In this context, a band gap is understood to be the energetic range of the layer that lies between the valence band and the conduction band. Due to the band gap, the solid used for the layer and thus the converter element provided with the layer are transparent to radiation in a certain frequency range. The optical properties of the converter element can be specifically adjusted by adjusting the band gap and/or selecting a solid state material. In particular, it is possible to adapt the layer in such a way that only a part of the incident radiation passes through the layer and is emitted into the emission range. In some aspects, it is useful if the photonic structure of the layer has an average thickness of at least 500 nm, so that an optical band gap is created.

In some embodiments, it is provided that the layer with the photonic structure is configured in such a way that the directed beam of rays is emitted perpendicular to a plane in which the layer is arranged. In contrast, radiation components that are emitted into other spatial areas are reliably suppressed.

Further aspects concern optical filter elements and other measures. In one aspect, an optical filter element can be arranged at least on one side of the layer. In some aspects, such a filter element is designed as a filter layer, which is applied flat on the structured layer with the converter material. With the aid of such a filter element or such a filter layer, it is possible that only a certain part of a radiation impinges on the layer with the converter material or that only a certain part of the converted radiation emitted by the structured layer with the converter material is emitted into the desired spatial region. The filter element, in particular the filter layer, is thus adapted in some aspects in such a way that only that part of a radiation can pass through the filter element or the filter layer which is required as excitation radiation or which is to be emitted specifically into the emission range.

Furthermore, some aspects concern a radiation source with a μ-LED, which radiates an excitation radiation into a converter element, which is configured according to at least one of the previously described embodiments of a converter element. The converter element in turn has at least one layer with a converter material which, when excited by the excitation radiation emitted by the μ-LED, is excited to emit a converted radiation into a radiation emission area. In this context it is conceivable that a μ-LED is combined with a converter element in such a way that the entire excitation radiation emitted by the LED is converted into converted radiation or that only a part of the excitation radiation emitted by the LED is converted into converted radiation. Again, it is substantial that the radiation emitted into the radiation source's beam area is only directed into a desired spatial region. The radiation source thus generates a directed beam of light or a directed beam of radiation that is emitted in a specifically selected direction or in a specifically selected radiation range.

According to another aspect, the structured layer with the converter material is part of a semiconductor substrate of the μ-LED. The photonic structure can be formed accordingly in a semiconductor substrate of the μ-LED. In this context, it is also conceivable that the structure is produced by targeted etching of the LED semiconductor substrate and the structure is then at least partially coated with converter material and/or the converter material is filled into etched-out depressions in the structure.

Furthermore, in some aspects it is planned that the structure with the converter material is configured in such a way that the converted radiation is emitted perpendicular to a plane in which the semiconductor substrate is located, into the emission area. The structure is configured in such a way that converted radiation is only emitted perpendicular to the surface of the μ-LED chip into the emission area due to a bandgap effect. Due to this technical solution, a high directionality of the converted radiation emitted by the converter element is achieved. In this context, it is also possible that the photonic structure, for example in the form of a photonic crystal, is arranged only in the uppermost layer of the semiconductor material of the μ-LED or also at least partially in the active zone. It is again advantageous if the photonic structure has a layer thickness of at least 500 nm in order to generate reliably an optical band gap.

In one embodiment at least one filter layer is provided, which is arranged on one side of the structured layer. By means of a filter layer, the excitation radiation generated by the μ-LED is suppressed in certain wavelength ranges. In this way, especially etendue-limited systems based on full conversion of the excitation radiation can be made significantly more efficient than known technical solutions by means of directed radiation generation in the structured layer of the converter element.

The radiation source may be configured to emit visible white light or visible converted light with the colors characteristic of the RGB color space, namely red, green and blue. According to one embodiment, the radiation source can be a pixelated array, in which, for example, individual pixels of a larger component can be switched on and off individually.

The use of a photonic structure, as described herein, in combination with the above-mentioned μ-LEDs makes it possible to do without lenses or similar collimating elements. Furthermore, a photonic structure can improve the contrast between adjacent pixels due to the provided directionality.

In addition, some aspects also concern a process for manufacturing a radiation source that has at least one of the special properties described above. The process is characterized by the fact that the structure is formed by at least one etching step in a semiconductor substrate of the LED. It is advantageous here if the structure, in particular specifically selected recesses in the structure, are at least partially filled with the converter material.

Some further aspects deal with a μ-display with a photonic structure for the emission of directed light. Especially in displays that feature μ-LEDs, the dimensions of individual μ-LEDs can be very small, so that when a photonic structure is formed, only a few periods have space on the surface of a single μ-LED. It is therefore proposed to form a photonic structure over a large area on an array of several μ-LEDs. Such arrays can be pixelated arrays of μ-LEDs, for example, where one pixel forms a light source. Monolithic pixel arrays also fall under this category as do assembled LED modules with a smooth surface, for example the cover electrode disclosed in this application.

Another example is an arrangement of single μ-LEDs or smaller modules of μ-LEDs, which can also be provided in the form of an array. Such μ-LED modules are also disclosed in this application. μ-LEDs are normally Lambertian emitters and therefore emit light in a large solid angle. For pixelated arrays, and especially for μ-displays, however, as already explained, a directed emission perpendicular to the light emission surface is important or desirable for a variety of applications.

Thus, an optoelectronic device comprises an assembly having a plurality of light sources for generating light emerging from a light exit surface from the optoelectronic device, and at least one photonic structure disposed between the light exit surface and the plurality of light sources. By means of the at least one photonic structure, which may be in particular a photonic crystal or pillar structures, also referred to herein as columnar structures, beam shaping of the emitted light is effected before the light leaves the device through the light exit surface.

The photonic structure may be configured in particular for beam shaping of the light generated by the light sources. The photonic structure can in particular be configured in such a way that the light emerges at least substantially perpendicularly from the light exit surface. The directionality of the emitted light is thus considerably improved.

According to one embodiment, the arrangement is an array comprising a plurality of light sources, in particular μ-LEDs, arranged in rows and columns. The μ-LEDs are organized in pixels or subpixels and can be controlled separately. In some aspects, the arrangement is realized as a monolithic array, in other aspects, the arrangement is equipped with μ-LED modules or separate μ-LEDs. The array comprises one containing or contacting the μ-LEDs or light sources at least partially and one photonic crystal. This is arranged or formed in the layer. The photonic crystal can thus be arranged directly in the layer in which the pixels of the array are arranged. Alternatively, the photonic crystal is arranged in the layer above the light sources, so that the photonic crystal is still located between the light sources and the light exit surface.

The layer may comprise a semiconductor material and the photonic crystal may be structured in the semiconductor material. Examples of semiconductor materials are GaN or AlInGaP material systems. Examples of other possible material systems are AlN, GaP and InGaAs.

The photonic crystal can be realised by forming a periodic variation of the optical refractive index in the semiconductor material, using a material with a high refractive index, such as Nb₂O₅ (niobium (V) oxide), and introducing it into the semiconductor material accordingly to form a periodic or deterministically aperiodic structure. The photonic structures can be filled with a material of low refractive index, such as SiO₂. Thus, a refractive index variation between a high and a low index occurs. The photonic crystal is preferably formed as a two-dimensional photonic crystal, which exhibits a periodic variation of the optical refractive index in a plane parallel to the light exit direction in two mutually perpendicular spatial directions.

The photonic crystal can be realized by means of holes or recesses, which are inserted into a material with a high refractive index, for example Nb₂O₅. The photonic crystal can thus be formed or be formed by forming the corresponding structuring in the material with high refractive index. In contrast, the material surrounding the holes or recesses has a different refractive index.

In a further aspect, the arrangement comprises a plurality of μ-LEDs as light sources, the μ-LEDs being arranged in a first layer and a photonic crystal being arranged or formed in a further, second layer. The second layer is located between the first layer and the light emitting surface. In combination with a particularly array-like arrangement of μ-LEDs, a photonic crystal can be provided in an additional, second layer above the first layer comprising the μ-LEDs. This is preferably designed as a two-dimensional photonic crystal and is realized in the form of a periodic variation of the optical refractive index in two spatial directions running parallel to the light exit surface and perpendicular to one another. As an example of a material with a high refractive index of the second layer, Nb₂O₅ can again be mentioned here, and the photonic crystal can be structured by means of holes or recesses in the material with the high refractive index. The photonic structures can be filled with a material with a lower refractive index, for example SiO₂. Thus, the second layer has a structure of a material with two different refractive indices.

μ-LEDs can be differentiated between horizontal and vertical μ-LEDs. With horizontal LEDs, the electrical connections are located on the back of the LED facing away from the light emission surface. In contrast, in the case of a vertical LED, one electrical connection is located on the front and one on the back of the LED. The front side faces the light emission surface.

In pixelated arrays, where the electrical contacts of both polarities are on the backside, the whole array surface can be structured, e.g. in form of a photonic crystal, especially without leaving mesa trenches or contact areas. A similar arrangement results for arrangements of horizontal μ-LEDs under a carrier substrate. According to an embodiment, in an array or an arrangement of horizontal μ-LEDs for the electrical contacting of the light sources, both poles can be electrically connected in each case by means of a contacting layer reflecting the generated light, the contacting layer lying under the photonic structure and the light sources, viewed from an upper light exit surface. The contacting layer can thereby have at least two electrically separated areas in order to avoid a short circuit between the poles.

According to another configuration, in the case of an arrangement of vertical light emitting diodes for the electrical contacting of the light sources, a first connecting contact facing away from the light-emitting surface, in particular a positive one, can be electrically connected to a contacting layer reflecting the generated light, the contacting layer lying below the photonic structure and the light sources as seen from an upper light-emitting surface. On the other hand, the respective other, in particular negative, second connecting contact, which faces the light exit surface, can be electrically connected by means of a layer of an electrically conductive and optically transparent material, in particular ITO. A filling material can be arranged between the layer and the reflective contacting layer. In some aspects, this electrically conductive layer may itself be structured to produce photonic properties. In other aspects, the photonic structure is created over the electrically conductive layer.

According to an embodiment, each of the light sources or the μ-LEDs can have a recombination zone and the photonic crystal can be located so close to the recombination zones that the photonic structure changes an optical state density present in the region of the recombination zones, in particular in such a way that a band gap is generated for at least one optical mode with a direction of propagation parallel and/or at a small angle to the light exit surface.

To effect the optical band gap in the recombination zone, it is useful if the photonic crystal is very close to the recombination zone. In addition, to form the band gap, it is useful if the height of the photonic crystal is large when viewed in a direction perpendicular to the light-emitting surface, in particular equal to or above 300 nm. By means of the photonic structure, directionality can thus be achieved for the emitted light already in the light generation region, since the emission of light with a direction of propagation parallel and/or at a small angle to the light exit surface can be suppressed. Light can then only be generated in a limited emission cone perpendicular to the light exit surface. The aperture angle of the emission cone depends on the photonic crystal and can be a small value, for example, maximum 20°, maximum 15°, maximum 10° or maximum 5°.

The photonic crystal can be arranged in relation to a plane parallel to the light-emitting surface independently of the positioning of the light points.

The photonic structure may comprise a plurality of pillar structures extending at least partially between the light-emitting surface and the plurality of light sources, one pillar being associated with each light source and aligned with the light-emitting surface when viewed in a direction perpendicular to the light-emitting surface. The pillars or columns have a longitudinal axis, which preferably extends perpendicular to the light-emitting surface. When a pillar and an associated light source are aligned, the extended longitudinal axis of the pillar intersects the centre of the light source.

Viewed transversely to the longitudinal axis, the pillars can have a circular, square or polygonal cross-section. Pillars preferably have an aspect ratio height to diameter of at least 3:1, with the height measured in the direction of the longitudinal axis of the pillars. In particular, pillars are made of a material with a high refractive index, such as Nb₂O₅. Due to the higher refractive index compared to the surrounding material, the light emission in a direction parallel to the longitudinal axis of the pillars can be increased compared to other spatial directions. The pillars act as wave guides. Light is more efficiently coupled out along the longitudinal axis of the pillars than along other propagation directions. Directionality in the direction of the longitudinal axis of light can thus be improved. Since the longitudinal axis of the light is preferably perpendicular to the light exit surface, improved light extraction perpendicular to the light exit surface can also be achieved.

The arrangement may be an array comprising as light sources a plurality of μ-LEDs arranged in pixels arranged in a first layer and the pillars may be arranged in a further, second layer, the second layer being positioned between the first layer and the light emitting surface. Thus, the pillars can be arranged on the surface of the pixelated array. The pillar or column structures can be free-standing and made of a material with a high refractive index. In addition, the free space between the pillars can be filled with a filling material, e.g. SiO₂, with a low refractive index.

In another aspect, the arrangement can be an array that has as light sources a plurality of pixels arranged in a first layer, and the pillars can also be arranged in the first layer. In particular, the pillars may be arranged in the first layer such that at least a respective part of a pillar is closer to the light emitting surface than the light source associated with the pillar. The pillar can thus act as an optical waveguide between the light source and the light-emitting surface. The pillars can be formed from a semiconductor material of the array provided in the first layer, the semiconductor material having a high refractive index. In particular, semiconductor material in the first layer can be removed by etching in such a way that the pillars remain stationary. The free spaces between the pillars can in turn be filled with a low refractive material.

In a further aspect, the arrangement can be an array that has as light sources a plurality of μ-LEDs arranged in pixels, with the pixels being formed in the pillars. An array can thus be created in such a way that the individual pixels have the form of pillars. Each pillar is preferably a μ-LED and functions as a single pixel. Seen in relation to the longitudinal axis of a pillar, the length of the pillar can correspond to half a wavelength of the emitted light, and the recombination zone of the μ-LED formed by a pillar is preferably located in the centre of the pillar. Thus, the recombination zone lies in a local maximum of the photonic state density. The light emission parallel to the longitudinal direction of the pillars can thus be significantly increased. Due to the waveguide effect, the light with propagation direction parallel to the longitudinal axis is additionally coupled out more effectively than light of other propagation directions.

The aspect ratio of height to diameter of a pillar is preferably 3:1, and at common emission wavelengths, the pillars have a height of about 100 nm and a diameter of 30 nm. Also up-scaled, larger heights and diameters, respectively are possible, which are easier to manufacture. In such a case, it is useful if the aspect ratio remains the same, for example the 3:1 mentioned above, but in a fixed ratio to the wavelength of the light to be influenced. The space between the pillars containing the light sources can be filled with material, for example SiO₂, which has a lower refractive index than the semiconductor material for the pillars.

In the case of a pillar with a light source, a p-contact can be made on the underside of the pillar facing away from the light-emitting surface. For example, an n-contact can be made at half the height of the pillars on the top of the pillar. The n-contact can be produced by a transparent conductive material, especially as an intermediate layer in the filling material or as the top layer above the pillars. A possible material for an n-contact layer is for example ITO (indium tin oxide). An inverse arrangement of n- and p-contact is also possible.

In particular, in the case of an arrangement of light emitting diodes, in particular vertical light emitting diodes in the form of pillars or columns for electrical contacting, a respective first pole, in particular a positive pole, may be electrically connected to a reflective contacting layer which may be formed on and/or along first longitudinal ends of the light emitting diodes. The respective other, in particular negative, second pole can be electrically connected to a further layer of an electrically conductive and optically transparent material, in particular ITO. This layer can be arranged as an intermediate layer in the middle of the pillars or columns or at and/or along second longitudinal ends of the pillars, the second longitudinal ends being opposite the first longitudinal ends.

According to another aspect, an optoelectronic device is proposed for generating an emission of light directed perpendicularly to an emitting surface from an, in particular planar, pixel array or from an array of μ-LEDs, whereby optically acting structures, in particular nanostructures such as a photonic crystal or a pillar structure, are structured along the entire emitting surface to the perpendicularly directed emission of the light. According to a further aspect, a method is proposed for the manufacture of an optoelectronic device for generating an emission of light directed perpendicularly to an emitting surface from an, in particular planar, pixelated array or from an array of μ-LEDs, wherein optically acting structures are structured along the entire emitting surface to the perpendicularly directed emission of the light.

Planar array means in particular plane array. A surface of an array or field is also preferably smooth. A pixelated array is especially a monolithic, pixelated array.

All mentioned materials, especially the materials in a photonic crystal, a pillar, or the filling materials preferably have a low absorption coefficient. The absorption coefficient is here in particular a measure of the reduction in the intensity of electromagnetic radiation when passing through a given material.

The photonic crystal can be produced using a lithography technique known per se. Possible technologies known per se are, for example, nanoimprint lithography or immersion EUV stepper, where EUV stands for extreme ultraviolet radiation.

Another possible application of photonic crystals is based on the property of polarizing electromagnetic radiation, especially visible light, with respect to the direction of oscillation. With the help of photonic structures for polarization of electromagnetic radiation, it is especially possible to take special pictures and show them on suitable displays. To create images, which give the impression of a three-dimensional image to a user, usually several complementary polarization, directions are combined in a suitable way.

It is therefore regularly a problem that the lighting units, which can provide polarized light on demand, comprise a number of additional optical components in addition to the emitter used to generate light. This makes the construction of corresponding lighting units comparatively complex and increases the costs of production. Furthermore, the different components require a not inconsiderable amount of installation space, so that efforts to miniaturize the lighting units required for augmented reality applications or in the field of consumer electronics, often reach their limits. More recent requirements in the automotive sector also point to the desire to create images that create a three-dimensional effect on the user.

To solve this and other problems, an arrangement or an optoelectronic component is proposed with at least one emitter unit, in particular a μ-LED, which emits radiation via a light exit surface. The component also comprises a polarization element, which is connected at least in sections to the light-emitting surface and changes a polarization and/or an intensity of the radiation emitted by the emitter unit when the radiation passes through the polarization element. The arrangement is characterized in that the polarizing element comprises a three-dimensional photonic structure.

The device or optoelectronic component can be a pixel element of a μ-display or a μ-display module. The emitter unit can be formed by a μ-LED. One or more such modules, in which several pixels are arranged in rows and columns, can thus generate one or more images, which may give the user the impression of a three-dimensional image.

The formulation that the polarizing element changes a polarization also includes the generation of polarized radiation from non-polarized radiation. The polarizing element can also only change the intensity of the radiation, possibly depending on the wavelength, without producing or changing a polarization. The term “polarizing element” is therefore not to be interpreted narrowly in the sense that a change or generation of polarization must be provided for in all configurations.

The proposed solution provides an optoelectronic component in which the radiation generated by the emitter, for example a μ-LED, passes directly into the polarizing element, so that a particularly compact unit for providing demand-polarized radiation is realized, which in turn can be combined with further such components and/or a polarizing element, preferably with at least one polarizing element that has complementary properties.

The substantial advantage of using a three-dimensional photonic structure, in particular a photonic crystal, for polarizing electromagnetic radiation, whereby preferably visible light is polarized, is that a particularly compact, space-saving solution is provided by the arrangement of the photonic structure in the area of the light exit surface of the emitter. With the aid of the specially configured polarizing element adjacent to the light-emitting surface, it is possible to polarize electromagnetic radiation in a targeted manner and still minimize the losses of radiation whose polarization does not correspond to the polarization direction of the polarizing element. In general, it is conceivable that the photonic structure is arranged on the light-emitting surface, or that a photonic structure is formed in a suitable manner in a semiconductor layer on which the light-emitting surface is located or to which the light-emitting surface is adjacent in the direction of the beam.

Here it is of particular advantage that the three-dimensional structures used as polarization elements can be used to change the radiation characteristics of an illumination unit with regard to its polarization properties in a particularly effective way, thus enabling discrimination of different wavelengths by different polarization properties or radiation directions.

According to an aspect, the emitter unit has at least one μ-LED. In this context, it is conceivable that the μ-LED emits preferably white, red, green or blue light, which is irradiated into the polarizing element and by means of the polarizing element the radiation is polarized in an oscillation direction. In this context, the μ-LED may also comprise a converter material so that the light emitted by the μ-LED is converted by the converter material into a desired wavelength and thus color.

Furthermore, according to another aspect, the emitter unit, in particular a μ-LED, as well as the polarization element are to be formed from different layers, which are arranged in a layer stack one above the other. Again, it is substantial that the radiation generated in at least one layer of the emitter reaches the likewise layer-shaped polarizing element before the radiation from the layer stack is emitted into the environment. In this context, it is advantageous that the three-dimensional structure used as a polarization element is located on or in the same semiconductor chip as the emitter unit.

When using an emitter unit with a μ-LED, it is also conceivable that the photonic structure is applied to the μ-LED chip or at least is part of the μ-LED chip. Various designs of such a μ-LED are disclosed in this application. The μ-LED may be monolithically manufactured and may be part of a larger array of μ-LEDs arranged in rows and columns. These can be processed and manufactured together. The μ-LEDs for individual colors can be combined into a pixel and surrounded with a structure to improve light guidance, especially to the main beam direction.

Such an embodiment provides a particularly space-saving and energy-efficient optoelectronic component with which polarized radiation is already generated directly at chip level without the need for additional optical elements in the downstream beam path.

In other aspects, the polarization element has spiral and/or rod-shaped structural elements. In this case, the three-dimensional photonic structure is adapted in such a way that light emitted by the emitter unit or the μ-LED only leaves the photonic structure with a certain polarization. A corresponding three-dimensional photonic structure with spiral and/or rod-shaped structural elements in the area of the light exit surface is only irradiated by radiation with a specific polarization direction. The design and dimensioning of the structure is preferably adapted to the radiation emitted by the emitter unit. A spiral structure achieves a circular polarization, while a rod-shaped structure causes a linear polarization of the radiation passing through the structure.

According to further aspects, it is also conceivable that when using a converter material, the three-dimensional photonic structure is located in the beam path between the μ-LED and the converter element or behind the converter element, by which the excitation radiation and/or the converted radiation is polarized in a suitable way. The combination of converter element and three-dimensional photonic structure in the same layer can also be realized. Thus, directly polarized, converted light can be generated.

For example, converter material can be filled into the three-dimensional photonic structure. The converter material can be doped with Ce³⁺ (Ce for cerium), Eu²⁺ (Eu for europium), Mn⁴⁺ (Mn for manganese) or neodymium ions. As host material, for example YAG or LuAG can be used. YAG stands for Yttrium-Aluminium-Garnet. LuAG stands for lutetium aluminum garnet.

Quantum dots can also be filled into the three-dimensional photonic structure as converter material. Quantum dots can be very small, for example in the range of 10 nm. They are therefore particularly suitable for filling the three-dimensional photonic structure. In general, it is conceivable that the structure is produced by etching material out of the layer, in which the structure is to be formed. The recesses thus formed can then be filled with converter material containing, for example, quantum dots. The quantum dots can, for example, be introduced into a liquid material with which the recesses are filled. The liquid material can be at least partially vaporized so that the quantum dots remain in the recesses. In the process, part of the liquid material can solidify. The quantum dots can therefore be embedded in a matrix.

The photonic structure normally does not change the spectral properties of a quantum dot. However, a quantum dot has a narrow-band emission spectrum. The photonic structure can be adapted to this narrowband emission spectrum, which can improve the directional selectivity caused by the photonic structure. By means of a photonic structure, the radiation characteristics of quantum dots can thus be influenced very efficiently as converters.

In other aspects, the polarizing element has at least one three-dimensional photonic crystal. It is also conceivable that the polarizing element comprises at least two two-dimensional photonic crystals, which are arranged one behind the other along a beam path of the radiation penetrating the polarizing element.

It is useful to use one three-dimensional photonic crystal or at least two two-dimensional photonic crystals arranged one behind the other in the optical path so that the structure on which the radiation impinges is transparent to radiation of a specific wavelength or several specific wavelengths and/or only transmits it in a specific direction. In this way, the desired polarization of the radiation impinging on the polarizing element can also be adjusted. In this context, it is conceivable to produce the structure directly in the converter material or to insert it into an additional layer of another material. The property of the three-dimensional photonic structure is preferably designed such that the transmission conditions are different for different wavelengths. In this way it is possible, for example, that converted radiation can pass the polarizing element unhindered while the excitation radiation is deflected. It is also conceivable that at least one of the radiations, namely excitation radiation on the one hand and converted radiation on the other hand, only passes through the polarizing element with a certain polarization.

In some embodiments, it may also be provided that the polarizing element has at least two different transmittances depending on a wavelength of the radiation passing through the polarizing element. In this context, a further embodiment provides that the emitter unit comprises a μ-LED and a converter element with a converter material which, excited by excitation radiation emitted by the μ-LED, emits converted radiation, and that excitation radiation incident on the polarizing element is polarized and/or absorbed differently when passing through the polarizing element compared to the converted radiation passing through.

The properties of the three-dimensional photonic structure are thus such that the transmission conditions are different for different wavelengths. In this case, it is conceivable, for example, that converted light can pass unhindered through the three-dimensional photonic structure while the excitation radiation is deflected. It is also conceivable that converted radiation only leaves the three-dimensional photonic structure with a certain polarization.

Furthermore, for some aspects it is conceivable that one of the two radiations, which have different wavelengths, is discriminated against by the different properties of the polarizing element in terms of polarization and direction of propagation. It is therefore preferable that in a combination of a μ-LED and a converter element, by which a full conversion is realized, a part of the excitation radiation is filtered out except for a comparatively small radiation portion with a special wavelength, which leads to the fact that a thinner layer of the converter material can be used.

The structure described herein can be produced in a particularly small way. In some aspects, for example, an emitter unit with a μ-LED is provided, and the three-dimensional structure of the polarization element is applied directly on the μ-LED chip, preferably on the semiconductor layer of the μ-LED, through which the generated radiation reaches the light emission surface. According to such embodiment, the three-dimensional photonic structure is located directly on or in the μ-LED chip. With such a technical solution, the polarized radiation emission can be used to improve the resolution for the generation of images, and components for beam generation can be made comparatively small. This can be achieved, for example, by imaging the radiation emitted by several components or by several illumination units with complementary properties via common optics. Optics that are suitable for this purpose are disclosed in this application. Illumination units adapted in this way are thus particularly suitable for augmented reality applications and/or in the field of consumer electronics.

Another aspect relates to a method of manufacturing an optoelectronic component having at least one emitter unit which emits radiation via a light-emitting surface, and having a polarizing element, which adjoins the light-emitting surface at least in sections and changes a polarization and/or an intensity of a radiation emanating from the emitter unit when the radiation passes through the polarizing element.

This method can be further developed by using a μ-LED, or an array of μ-LEDs, as emitter unit, on whose light-emitting surface a three-dimensional photonic structure is applied as polarization element, for example by two-photon lithography or glancing angle deposition, and/or the photonic structure is introduced into a semiconductor layer of the μ-LED adjacent to the light-emitting surface. The three-dimensional structure can be dimensioned depending on the wavelength of the radiation emitted by the μ-LED.

Thus, an optoelectronic device based on the principles and structures or objects disclosed in this application may be used in a device for the production of three-dimensional images, in particular for presentation on a display, monitor or screen. In some aspects, the three-dimensional impression in a user is based on the fact that light of different polarity is directed to the two eyes, the respective light, or the generated image or represented objects, being displayed at slightly different positions.

In particular, based on the techniques presented here, three-dimensional images can be generated computer-aided for augmented reality applications or in the automotive sector. It is an advantage here that the optoelectronic components disclosed in this application with a three-dimensional photonic structure as polarization element change the radiation characteristic of μ-LEDs with respect to the polarization properties and thus a discrimination of different wavelengths due to different, wavelength-specific polarization properties or radiation directions can be achieved.

The polarized radiation can be generated directly on the substrate with the emitter unit, in particular at the level of a μ-LED chip, or the selectivity can be improved with full conversion. This eliminates the need for separate elements, which could lead to positioning errors or deviations. Due to the emission of specifically polarized radiation, the resolution of three-dimensional representations can be improved and at the same time, the components or illumination units required for image generation can be reduced in size. This can be achieved, for example, by imaging the light of several components with complementary properties via common optics on a display, a screen or even directly on the retina of a user. Particularly for augmented reality applications and in the field of consumer electronics, three-dimensional images can be created by combining complementary polarization elements.

In some other aspects, a photonic structure or a photonic crystal can be used to far-field characteristics of an optoelectronic component can be specifically altered. Therefore, among other things, an arrangement is proposed which comprises at least one optoelectronic emitter unit, which emits electromagnetic radiation via a light exit surface. In addition, a photonic structure is provided for beam shaping of the electromagnetic radiation before it exits via the light exit surface, wherein the photonic structure shapes the electromagnetic radiation in such a way that the electromagnetic radiation has a certain and defined far field.

The optoelectronic emitter unit is adapted as a μ-LED. The optoelectronic emitter unit can also have an array with several μ-LEDs. This provides a photonic structure over a plurality of such μ-LEDs.

Due to the photonic structure, the radiation characteristic of the optoelectronic emitter unit of the arrangement changes from a Lambertian radiator to a defined radiation characteristic in the far field. The formulation that the electromagnetic radiation has a certain far field thus means in particular that the radiation characteristic is defined in the far field and differs from the radiation characteristic of a Lambert emitter. The far field refers to a region, which, depending on the application, is at least a few centimetres or even a few metres away from the lighting unit so that the magnetic and electronic fields are perpendicular to each other.

The photonic structure may be located, especially in a layer, below the light-emitting surface and/or between the optoelectronic emitter unit and the light-emitting surface. Thus, the light must pass through it before finally leaving the component. The photonic structure can thus be integrated into the arrangement, making it compact. The photonic structure can also be integrated into the light-emitting surface, or an end face of the photonic structure can form the light-emitting surface.

In some aspects, the photonic structure is a one-dimensional photonic structure, especially a one-dimensional photonic crystal. For example, the photonic structure may be configured such that the electromagnetic radiation is at least approximately collimated with respect to a first spatial direction. Thus, a collimated beam can be generated at least with respect to the first direction in space.

A collimating optical system can be arranged downstream of the light exit surface, viewed in the direction of emission, the optical system being designed to collimate the electromagnetic radiation in a further, second spatial direction which is orthogonal to the first spatial direction. The first direction and the second direction can be mutually orthogonal directions, which are parallel to the plane light-emitting surface. Thus, a beam collimated in both directions can be produced, which is directed along the main radiation direction away from the light-emitting surface and orthogonal to both the first and second directions.

According to an embodiment of the invention, the photonic structure, in particular formed as a one-dimensional photonic crystal, can be configured in such a way that a main radiation direction of the electromagnetic radiation runs at an angle to the normal of the light-emitting surface, the angle being not equal to zero degrees. The main radiation direction can thus be inclined to the normal of the light-emitting surface. A beam collimated in at least one direction can thus, for example, emerge from the light-emitting surface at an angle.

The photonic structure formed as a one-dimensional photonic crystal can be arranged in a layer below the light-emitting surface, in particular directly below. The one-dimensional photonic crystal can thereby have a periodically repeating sequence of two materials with different optical refractive indexes extending in one direction. The materials can each have a rectangular or parallelogram-shaped cross-section. The abutting interfaces of the materials can be inclined to the light-emitting surface.

Such a structure can be formed, for example, by etching trenches running parallel to each other at an angle to the light-emitting surface into the substrate having the light-emitting surface. The trenches can be filled with a material having a different optical refractive index than the substrate material etched away. The angle may depend on the inclination of the trenches to the light-emitting surface, and the width of the trenches or the width of the substrate material remaining between the trenches influences the wavelengths at which the photonic structure is effective. Typically, the width of the trenches and the width of the substrate material remaining between the trenches are adapted to the wavelength of the electromagnetic radiation.

In some aspects, the photonic structure can also be a two-dimensional photonic structure, in particular a two-dimensional photonic crystal. One end face of the two-dimensional photonic structure may form the light-emitting surface of the illumination unit, or the two-dimensional photonic structure may be arranged in a layer below the light-emitting surface.

The two-dimensional structure, in particular a two-dimensional photonic crystal, can be designed in such a way that it influences the electromagnetic radiation in such a way that the electromagnetic radiation in the far field forms a defined, in particular a discrete, pattern. The illumination unit can thus be used in surface topography systems, for example for face recognition.

As mentioned above, the photonic structure may be located in a layer below the light-emitting surface, or an end face of the photonic structure may form the light-emitting surface so that the photonic structure is located directly below the light-emitting surface and encloses it.

The photonic structure can also be formed in a semiconductor layer of the optoelectronic emitter unit.

The optoelectronic emitter unit may comprise a layer of converter material and the photonic structure may be formed in the layer of converter material or in a layer between the layer of converter material and the light-emitting surface.

The optoelectronic emitter unit can have at least one optoelectronic laser, such as a VCSEL (vertical-cavity surface-emitting laser). A field of several lasers is also conceivable.

Another aspect relates to the lighting design by suitable projection units after the light has left the emitter or μ-LED, i.e. the distance from a light source to the eye of a user. In some solutions, the display is in the line of vision of a user. These solutions are mainly relevant for automotive and other applications. Alternatively, the virtual elements can be created outside the direct line of sight and their light must then be directed to the user's eyes. In all cases, it should be ensured that the projection of the image to the user is sufficiently sharp and contrasty. This means that the pixels should be separated from each other, so that different raven between two adjacent pixels will create the same impression on the user.

In some aspects, a μ-display arrangement or display array will have optics to direct light emitted by the μ-LED array in certain spatial directions or to reduce its divergence, for example, or to allow shaping of a light beam emitted by the μ-LED array. For this purpose, the optics may include optical lenses and/or reflectors. The optics may also include, for example, optical filters to change the color of the emitted light. Furthermore, the optics may include, for example, light scattering agents to enable a better homogenization of the emitted light.

An arrangement with a μ-display may have optics for individual μ-LEDs or common optics for some or all μ-LEDs of the μ-LED array, for example to direct light emitted by these μ-LEDs in certain spatial directions or to reduce its divergence or to allow shaping of a light beam emitted by the μ-LEDs. For this purpose, the optics may comprise optical lenses or reflectors, for example. Furthermore, the optics may include, for example, optical filters or/and light scattering means to change the light color or the homogeneity of the emitted light for some or all μ-LEDs of the μ-Display. For example, the optics may be arranged on a common carrier for the μ-LEDs of the μ-LED array.

In another embodiment, an aspect of light guidance is considered when the light-emitting display is not in direct line of sight. For this purpose a light guide arrangement downstream of the light-emitting device and having at least two light-emitting devices emitting light of different colors.

The arrangement also comprises a first and a second elongated light guide arranged so that light generated by the light emitting devices is coupled into the light guide. For this purpose, the light guide arrangement further comprises a first coupling element disposed adjacent to the first elongated light guide and configured to couple light of the first color into the first elongated light guide. A second coupling element is disposed adjacent to the elongate second light guide and configured to launch the light of the second color into the elongate second light guide. Corresponding outcouplings are located at the respective end portions of each of the first and second elongated light guides. These guide the light to the user's eye. The light guide elements can be made of a transparent material so that they can be arranged in the direct line of sight of the user without impairing the user's vision. The coupling and decoupling elements can be implemented as separate elements or, for example, as a coating on the corresponding light guides.

The light emitting device may have a μ-LED display or a μ-LED display matrix and the like. These devices can be monolithically integrated. The sub-pixels of different colors can be integrated on a single device. As an alternative, a variety of μ-LED displays can be provided, each of the μ-LED displays being adapted to produce light of a specific color. The generated light can then be combined by different optics placed in front of the μ-LED display. Using different μ-LED displays can reduce the technical requirements regarding the size of individual pixels compared to a solution where sub-pixels of different colors are arranged on the same substrate. The above solution uses different coupling elements to couple selectively the light from the light emitting device into the corresponding light guide. In one aspect, another third coupling element is provided and positioned opposite the second coupling element. The third coupling element is adapted to couple light of a third color into the elongated second light guide. The different launching element allows a separate launching of light of a different color into the corresponding light guide. The separation allows addressing aspects when light of different colors or wavelengths is handled. In this respect, light of the third color may have a longer wavelength than the second color.

Depending on the design, light can be generated at a point that is displaced or offset in relation to the light guides. Accordingly, light generated by the light-emitting device may have an angle of incidence between 30° and 90°, in particular between 45° and 90° and in particular between 60° and 90°, with respect to the surface of the light guide. In other words, the light is not parallel to the elongated light guide when it is launched into the guide through the launching element. In some aspects, at least one of the first and second launching elements may be located on the sidewall of the corresponding elongated light guide. The dimension of the corresponding launching elements is selected so that all light from the different pixels of the light-emitting array is launched.

The first and second elongated light guides can be arranged essentially parallel to each other. They may be separated from each other using spacers between them to provide space for the input and outcouplings. Apart from the input couplers, the end sections of the corresponding light guides may have an outcoupling. The outcoupling element arranged on the output section of the elongated first light guide is adapted to couple out light of the first color. The outcoupling element arranged on the output part of the elongated second light guide is adapted to couple out light of the second color. Furthermore, a third outcoupling element is provided in some variants. The third outcoupling element is located on the output part of the elongated second light guide opposite the second outcoupling element to couple out light of the third color. The corresponding outcoupling elements are arranged in such a way that the light coupled out by the corresponding outcoupling elements is directed towards an eye of the user. It is appropriate if some of the outcoupling elements are transparent to light of a different color. For example, the first outcoupling element is transparent to light of the second and/or third color. The second outcoupling element can at least be transparent to light of the third color.

Due to the small size of μ-LEDs, one difficulty for optoelectronic components is to achieve efficient beam extraction. Likewise, the beam should already be collimated when leaving the device in order to couple it into an optical device in a suitable way. Due to the small size of the individual components on a μ-display, classical lenses placed in front of the individual components are difficult to realize. Therefore, in the following a concept is presented that is based on a curved emission surface, a foveated display is based on. In addition, a small imaging error should be achieved.

Starting point of the concept is an illumination arrangement comprising a light-emitting optoelectronic element and an optical device for beam conversion of the electromagnetic radiation generated by the light-emitting optoelectronic element, wherein the optoelectronic element comprises several emission regions arranged in matrix form and each emission region is assigned a main beam direction.

It was found that the optical device following the light-emitting optoelectronic element in the beam path can be of simplified design if at least some and preferably all emission regions of the light-emitting optoelectronic element are arranged in such a way that their centres lie on a curved surface. In one aspect, this can be achieved with a concavely curved surface. The center of an emission area is understood to be the intersection of the main beam direction with the surface of the emission area emitting electromagnetic radiation.

In one aspect, the curved surface forms a spherical segment whose associated spherical center lies on the optical axis of the optical device. For the preferred concave curved surface for the arrangement of the centres of the emission regions, the centre of the sphere is at a distance from the light-emitting optoelectronic element in the direction of the beam path. Alternatively, the curved surface is a rotating conical section, for example an ellipsoid, paraboloid or hyperboloid.

For a first embodiment, adjacent emission areas are tilted against each other so that the main radiation directions of the emission areas are at an angle to each other. For a second, alternative embodiment, there are emission areas with a coinciding main beam direction, which are arranged on different planes with a different distance in the main beam direction to the optical device.

For a further embodiment, it is proposed that the optical device forms a system optic, in particular an imaging projection optic. By the arrangement of the emission regions an improved compensation of the field curvature of the system optics is achieved. Additionally, the imaging in the projection optics can be simplified. For a further design of these concepts, several non-planar collimating optical elements are provided between the emission areas and the system optics.

In one aspect, each individual emission area forms a separate Lambertian radiator. Furthermore, the emission areas are very small in area and have maximum edge lengths of less than 70 μm, in particular less than 25 μm. For an embodiment of the illumination arrangement, at least one of the emission regions is formed by the aperture of a primary optical element assigned to a μ-LED or a converter element assigned to a μ-LED. Alternatively, the emission regions can comprise readily collimating elements, for example in the form of a photonic structure In this case, the emission regions whose centres lie on a curved surface can be part of a monolithic pixelated optochip or they are arranged in several separate optochips arranged on a non-planar IC substrate.

A plurality of different projection units are known in the art, with which images can be displayed in specifically defined image planes according to requirements. Such projection units are used in so-called augmented reality or virtual reality glasses or in head-up displays, for example in motor vehicles. In the aforementioned special applications of projection units, augmented reality applications and head-up displays regularly display enlarged images at a distance from the viewer. In contrast, in virtual reality glasses, the projection optics usually take over the function of a magnifying glass that enlarges the display.

In this context, display units for motor vehicles are known from EP 1 544 660 and DE 197 51 649 A1. The latter uses an intermediate image on a ground glass screen in order to display the image on the windscreen to the correct side for the driver by means of additional optics. In this way, it is possible to display instruments, warning displays or other information important to the driver directly in the field of vision, so that he can see the information without having to look away from the road ahead.

An alternative embodiment to transfer images to or into the eye of a user is achieved by so-called light field displays, also known as virtual retinal display (VNA). In contrast to normal displays, which create an image on a plane directly in front of the user's eye, light field displays create an image inside the eye by direct retinal projection.

The requirement for a light field display of small size and light weight to achieve a comfortably portable system is contrary to the desire to achieve a large field of view with high resolution. Up to now, arrangements with μ-displays as image generators and these imaging multi-channel optics have been proposed, which split the beam path for reshaping and reunite it on the retina. A suitable system with hybrid diffractive-refractive optics and free-form lenses is described by Marina Buljan, et al., “Ultra-compact multichannel freeform optics for 4×WUXGA OLED microdisplays”, Proc. SPIE 10676, Digital Optics for Immersive Displays, 1067607 (21 May 2018).

Other projection units are also known whose pixels emit light that is mixed from light of different colors. In these solutions, light is generated spatially separated and then mixed by suitable optical elements, such as an achromatic lens, and combined into a beam. In the case of displays that generate color by means of pixels arranged in a matrix on a surface, the light must be sufficiently collimated to be able to resolve adjacent pixels of different colors, especially at high fill factors.

In contrast, other solutions suggest using μ-LEDs with a low packing density. However, this leads to significant differences between punctually illuminated and dark areas when viewing a single pixel area. This so-called fly screen effect (screen door effect) is particularly noticeable at a short viewing distance and thus especially in applications such as AR or VR glasses.

Other solutions with adaptive optics for phase modulation and beam shaping are mentioned by Jonathan D. Waldern, “DigiLens switchable Bragg grating waveguide optics for augmented reality applications”, Proc. SPIE 10676, Digital Optics for Immersive Displays, 106760G (21 May 2018). Waveguides are proposed for HMDs with integrated diffractive optical elements (DOE) formed by switchable Bragg gratings (SBG). To produce the SBGs, liquid crystals are embedded in a polymer. Prior to polymerization, pattern-forming cavities are created by holographic processes to accommodate the liquid crystal phase in the monomer starting material. After solidification of the matrix, the liquid crystals can be aligned by means of an electric field so that a variation of the refractive index results in a switchable beam deflection.

An alternative adjustment optics for VR HMDs is described by R. E. Stevens, et al., “Varifocal technologies providing Prescription and VAC mitigation in HMDs using Alvarez Lenses”, Proc. SPIE 10676, Digital Optics for Immersive Displays, 106760J (21 May 2018). The disclosure concerns the use of Alvarez lens pairs to adjust the beam path of video glasses.

Based on the known problems, further solutions will be proposed. It is considered to be not insignificant that the optics used for beam guidance and beam shaping are as efficient as possible so that optical losses are considerably minimized.

One aspect thus concerns a projection unit comprising an optoelectronic lighting device and projection optics, the optoelectronic lighting device comprising a matrix of pixels for the emission of visible light. Each pixel comprises several μ-LEDs with spectrally different light emission so that sub-pixels of different colors are formed. Each μ-LED is separately controllable and may be connected to the driver circuits disclosed in this application. The matrix of pixels comprises in some aspects one or more μ-LED modules having the structures disclosed in this application. For example, the matrix may comprise an antenna structure or a bar shape as disclosed herein. Various measures such as a transparent cover electrode, photonic structure or similar may be provided to improve outcoupling and directionality. In one configuration, the matrix can be formed by pixel modules (each with three subpixels) attached to a carrier substrate. The carrier substrate may contain leads and drive circuits and may be made of a different material system than the matrix.

In addition, each pixel is assigned a separate collimation optics, which is connected upstream of the projection optics to increase the fill factor. According to the invention, the collimation optics are configured in such a way that enlarged and overlapping intermediate images of the μ-LEDs of the respective pixel are generated in the beam path in front of the projection optics. Accordingly, the collimation optics assigned to each individual pixel not only increases the degree of illumination of a pixel, but additionally enables a spatial correction of the radiation of the μ-LEDs forming subpixels by means of the most accurate possible superimposition of the subpixel intermediate images, which enables efficient light coupling into the projection optics following in the beam path. It should be mentioned at this point that such an optic would be suitable for the concepts presented here, which provide partly redundant subpixel elements.

It is advisable to adapt the collimation optics in such a way that the degree of overlap of the intermediate images of the μ-LEDs belonging to the same pixel is as high as possible. An overlapping of the intermediate images of the Hμ-LEDs of a pixel of at least 85% and further of at least 95% of their intermediate image area has proven to be suitable.

Furthermore, an embodiment is preferred for which the intermediate images of the μ-LEDs are virtual intermediate images. In an aspect, the collimation optics generate a virtual image of the subpixels, so that the size of the virtual image of a subpixel corresponds to the size of the pixel. Furthermore, the collimation optics is preferably arranged between the μ-LEDs of a pixel and the projection optics.

The light emitted by μ-LEDs with different colors can occupy areas of the pixel of equal size or the areas occupied by the subpixels are adapted to the light emission and are of different sizes. For an embodiment, it is intended that the subpixel emitting green light occupies the largest surface area of the pixel compared to the other two subpixels or at least that green light is emitted over a larger area. This is due to the fact that the eye is most sensitive to the green color. Furthermore, it is useful if the surface area of an RGB pixel occupied by subpixels for red light is larger than the surface area occupied by subpixels emitting blue light. According to this embodiment, green light is emitted over a larger surface area of the pixel than red light, and red light is emitted over a larger surface area of the pixel than blue light. By means of the proposed collimation optics of the pixel, intermediate images are generated by the differently sized and differently located μ-LEDs of the subpixels in the beam path in front of the projection optics, which have a high degree of overlap.

According to another aspect, small μ-LEDs are used so that there are large surface areas in the individual pixels that do not emit light. Preferably, the semiconductor lighting devices of a pixel occupy no more than 30% and moor preferably no more than 15%, most preferably no more than 10% of the pixel area. This ensures that optical and electrical crosstalk between the individual pixels is prevented. Preferably, the sub-pixels are arranged in such a way that they are not directly on the edge of a pixel and do not adjoin each other. In addition to μ-LEDs, the term μ-LEDs also includes color converted μ-LEDs or VCSELs with such edge length or μ-LEDs illuminated optical fiber end pieces. The slotted antenna structures that would be regarded as such μ-LEDs should also be mentioned at this point.

The collimation optics assigned to each pixel offers the advantage that the light emitted by the subpixels is converted into a pre-collimated beam, which is then available in an advantageous way for the generation of an image by at least one further optical element. By using at least one suitable collimating optical element, pre-collimated light beams can thus be generated, so that in turn optical crosstalk between the individual light beams emitted by the subpixels is prevented or at least reduced.

An aspect provides that the collimation optics comprises at least one holographic optical element (HOE) that compensates for the different positions of the three semiconductor lighting devices on the surface of the pixel. Alternatively or in addition, it is conceivable that this function is achieved by a refractive optical element (ROE), which is a component of the collimation optics. It is also conceivable that a diffractive optical element (DOE) is used as a supplement or alternative to achieve appropriate compensation of the different positions of the semiconductor luminous devices on the illuminated area in the intermediate image of the pixel.

In further aspects, the projection unit will be adapted further. In one design it comprises a projection optic which is arranged downstream of the collimation optic in the beam path. With the help of the projection optics, an image or another intermediate image is generated from the individual intermediate images generated by the collimation optics. This image or intermediate image is used directly or in further processed form to display the desired information to the viewer. For this purpose, the projection optics has suitable optical elements, such as deflection mirrors, beam splitters and/or lenses, which are preferably controlled by a control unit and can be moved in such a way as to effect beam steering and/or beam deformation as required, so that information is presented in an easily understandable and perceptible form on a display, on a matt screen and/or as a virtual image, for example in front of the windscreen of a motor vehicle.

A proposed projection unit, according to at least one of the previously described aspects, can be used to generate an image for an augmented reality application, for a virtual reality application, and/or in a head-up display. In particular, the proposed one can be installed in an augmented reality spectacle and/or in a virtual reality spectacle worn on the head by the viewer.

In addition to directing light to a display and creating a virtual image, there is another way of transmitting information to the user. It is based on the knowledge that the eye does not have a uniform resolution over its range of perception. Rather, the eye has a very high spatial and also color vision in the area of its fovea centralis. However, this decreases at larger angles, so that in the area of peripheral vision, i.e. at approx. 20° to 30°, both spatial resolution and color vision decrease. In conventional displays, this is not taken into account further, i.e. the number and size of the individual pixels is substantially constant over the entire row or all columns.

The fovea centralis, also known as the visual fossa, is a sunken area in the centre of the yellow spot on the retina with a diameter of about 1.5 mm in an adult person. It is characterised by a high surface density of light receptors, which also have a direct neural connection. The fovea centralis has only cones for daylight vision, with predominantly M cones for the green spectrum and L cones for red light.

This application discloses novel concepts with which the different resolution capabilities of the eye is considered. This includes the generation of different resolutions by suitable optics as well as a solution with variable pixel density.

In the following concept, an approach is to be pursued in which a light guiding arrangement is provided that takes into account the resolution capability on the retina of the eye, thus reducing the requirements for a μ-display with respect to pixel density and size.

The proposed light guiding arrangement here comprises at least one optoelectronic imaging device, in particular a μ-display for generating at least a first image and a second image. Furthermore, at least one imaging optic is provided which is configured to project a first image of the first image with a first resolution onto a first region of the retina of an eye of the user and to project a second image of the second image with a second resolution onto another, second region of the retina, the first resolution being different from the second resolution.

The first image and the second image can be a respective image of a sequence or sequence of images. In particular, the images may be at least two successive images of a sequence or succession of images, which are perceived by the user as a scene or frame, the individual images normally being displayed so quickly that the eye does not perceive them as individual images but only as a scene or frame in their entirety. In this case, the first image can have a first partial image with the first resolution and the second image can have a second partial image with the second resolution. Thus, in the eye of the user, the first and the second image each have different resolutions.

With the proposed light guiding arrangement, the first image with the first resolution can be projected onto the first area of the retina and the second image of the second image with the second resolution onto the second area of the retina. Different areas of the retina can thus be illuminated with images whose resolutions are adapted to the physiological possibilities of the retina. For example, an image can be projected onto an outer area of the retina with a relatively low resolution, while another image is projected onto a central area of the retina with a higher resolution.

The proposed light guiding arrangement therefore allows different resolutions of the projected images to be provided for different areas of the retina, so that resolutions can be achieved that lead to pixels that are no longer resolvable for the eye. On the other hand, so-called oversampling can be avoided, since, for example, the resolution at any point of the retina can be adapted to the actual receptor density of the retina. Thus, it is possible to execute an optoelectronic imager more easily, since it does not have to deliver high resolution images everywhere.

In particular, an image of an image cannot be generated with constant resolution over the entire surface of the retina. Rather, it is taken into account that the resolving power of the eye is lower in the peripheral areas of the retina than in the centre. This is particularly advantageous compared to a system that produces an image with constant resolution over the entire surface of the retina. In this case, a constant pixel density is provided, so that either the resolution in the peripheral areas of the field of view is higher than the eye can perceive, or the resolution in the centre of the retina is too low to enable good image perception.

With regard to the areas into which a respective image is projected, in particular for a respective frame, a so-called scanning method can be used, in which, in particular to generate a respective overall image or frame, the entire retina is gradually scanned. The areas, such as in particular the first and second area, are therefore smaller than the total area of the retina.

It may also be intended that at least one image for a frame, especially the first or second image, fills the entire surface of the retina. At least one region, such as the first area or the second area, may therefore correspond to the total area of the retina.

The imaging optics or components thereof and the imaging device may be synchronized in such a way as to produce at least one frame comprising the first and second images, which the eye perceives as a complete image. It is understood that the retina, the eye and the user are not part of the optoelectronic device.

The first and second images generated by the at least one imaging device or μ-display may have a total number of pixels projected onto the first and second areas of the retina where they appear as first and second images, respectively. The resolution of the first and second image is therefore determined by the ratio of the number of pixels and the area of the area into which the respective image is projected on the retina. Each image can be assigned a resolution with which the image is projected onto the respective area of the retina.

The images generated by the at least one imaging device have the same resolution according to the number of pixels of the respective imaging device when leaving the imaging device and only when the image is enlarged or reduced by the imaging optics does the resolution of the respective projected images on the retina differ.

Compared to a conventional projection of an image generated by an imaging device such as DLP or LCD over the entire retina, the light-guiding device based on this concept can enable a frame of several non-resolvable images with different resolutions according to the sensitivity of the eye to be projected onto the retina using a more compact component than an imaging device or with fewer pixels or a smaller imaging device diagonal, without limiting the visual experience.

Such a frame, which is composed of images, can also be called a scene, where the images can be projected onto the retina of the eye simultaneously or sequentially. A scene with sequentially displayed images is usually so fast that the eye perceives them as a single overall image. Typical refresh rates are 60 or 120 Hz and the display duration per image is a fraction of a frame, with 2 to 100 images, preferably 5 to 50 images, being displayed per frame.

The imaging device, for example in the form of a μ-display, can be configured to comprise a pixel size with dimensions in the range of a few μm, in the range of 100 μm×100 μm or less. Such pixel sizes can be realized with displays that include μ-LEDs. Distances between two pixels can be in the range of about 1 μm to 5 μm, the pixel size itself is smaller than 70 μm and can for example be smaller than 20 μm or in the range of 3 μm to 10 μm.

Alternatively, such pixel sizes can be realized with displays based on a monolithic, pixelated array. Therefore, the imaging device can be adapted as a monolithic component, but the individual pixels can be individually controlled. The array can be an RGB array. Separate arrays for each color, especially RGB color, can also be provided. The pixels can, for example, have sizes in the range of a few μm to a maximum of 50 μm and be almost seamlessly adjacent to each other. With such imaging devices, the number of pixels can be in the range 1000 to 50000, whereby the pixels are preferably directly adjacent. The use of monolithic picture generator allows compact components to be realized.

The at least one optoelectronic imager may be formed by an array of μ-LEDs with m×n pixels. m and n may have values between 50 and 5000 inclusive, preferably between 100 and 1000 inclusive. The size of the pixels and the distance between adjacent pixels (pitch) may be constant. Typical values for the pitch can be in the range between 1 μm and 70 μm inclusive, preferably between 2 μm and 30 μm inclusive, and particularly preferably between 2 μm and 10 μm inclusive.

The at least one optoelectronic imager may have subpixels with at least one primary color, but preferably subpixels with the three primary colors red, green and blue (R,G,B). Subpixels of all three primary colors form one pixel. The number or the density per area of the subpixels can be different. For example, several green subpixels may be provided because the eye is sensitive especially in the green area.

The antenna structure proposed in this application is also conceivable. Likewise, μ-rods as disclosed herein or optoelectronic elements with dyes in between would also be possible. With μ-LEDS the distances between pixels could also be greater. For example, arrangements are possible in which the distance between adjacent pixels is between 1 and 5 times the pixel size. Such shapes and designs are disclosed in this application.

With the help of such a display it is possible to project an image with a high resolution onto the entire image area of the retina. However, this places high demands on the production and integration of such displays, especially if resolutions in the HD range (1920×1080 pixels) are to be achieved. The light guiding arrangement according to the invention allows the use of such high-resolution displays as image generators. However, lower resolution image generators can also be used, since—as already explained—a higher resolution can be achieved on the retina.

The first area in which the first, especially higher resolution is achieved may be located in the center or closer to the center of the retina than the second area in which the second, especially lower resolution is achieved. The higher first resolution takes into account the higher receptor density in the center of the retina.

The first and second areas can be arranged on the retina so that the second area concentrically surrounds the first area. Accordingly, the first area in the center of the retina has the shape of a circle, for example. This can be surrounded concentrically by at least one second area, for example in the shape of a ring. The individual images can thus enclose themselves on the retina like concentric circles, whereby a partial overlap is also possible.

The imaging optics may include a beam steering device, which directs light rays of the first image onto the first region of the retina to produce the first image and light rays of the second image onto the second region of the retina to produce the second image. By means of the beam steering device, images produced by an imager can be projected onto the respective intended retinal regions. A control system may be provided which controls the beam steering device in dependence on an image displayed by the imager.

The beam steering device may have at least one movable and/or fixed mirror or other equivalent reflecting element to direct the beam. The movable mirror may, for example, be configured to tilt about one, two, three or more axes, preferably about one or two axes. The control system can control the positioning of the mirror in dependence on an image displayed by the imager.

The beam steering device may have at least one, and preferably at least two, optical fibres for beam steering. The glass fibres may be fixed. Depending on the image, the light beams emitted by an imaging device can be coupled into different glass fibres. Each glass fibre can illuminate a specific, assigned area of the retina. The image of an image therefore appears on the area of the retina that is assigned to the glass fiber into which the light rays are coupled to form the image.

The imaging optics may have at least one beam-shaping device, which focuses the light rays of the first and second images on the respective area of the retina. The light rays of the first image can be focused more strongly than the light rays of the second image. The first image resulting from the first image on the retina thus appears on a smaller area than the less strongly focused second image. The first image therefore has a higher resolution than the second image.

The beam shaping device may have at least one focusing or magnifying optic, at least two different magnifications may be provided, preferably between three and ten different magnifications. The highest and lowest magnifications of the beam shaping device may differ, for example, by a factor between 1.1 and 10, preferably between 1.5 and 5, particularly preferably between 1.8 and 3. The imaging optics may have at least a first beam-shaping element and a second beam-shaping element. The first beam shaping element can focus the light beams of the first image and the second beam shaping element can focus the light beams of the second image.

The at least one first and one second beam-shaping element can be formed, for example, from a lens, in particular a converging lens and/or a diverging lens. It is also possible for the at least one first and second beam-shaping element to be formed from a segmented lens which may have a plurality of smaller converging lenses and/or diverging lenses. In addition to lenses of classical design, other suitable optical elements, for example flat optical elements, can also be used as beam-shaping elements, for example metal lenses.

The at least one first and one second image can be displayed one after the other, especially on the same image generator. A composite overall image resulting therefrom for the eye can be produced on the retina by a scanning process, since different areas of the retina can be illuminated at different times. In doing so, the retina can be at least substantially completely illuminated within a scene comprising at least the first and the second image or image.

The first and the second image can be displayed at least substantially simultaneously, in particular on at least two different imaging devices. Thus, a simultaneous projection of the first image and the second image onto the corresponding areas of the retina can be performed. For this purpose, the first and the second image are generated at least substantially simultaneously on different imaging devices and a projection can be made on the intended retinal areas by means of a respective, assigned beam steering device. The advantage of this is that the beam steering devices can be easily designed, as there are no moving parts, for example. In addition, by mapping the images from several imaging devices onto assigned retinal areas, an adapted resolution can be easily achieved on each area of the retina.

The optoelectronic device may have at least one controller designed to control the imaging optics in dependence on a respective image provided by the imager.

An alternative way of transferring images to or into the eye of a user is achieved by so-called light field displays, also known as virtual retinal displays (VNA). In contrast to normal displays, which create an image on a plane directly in front of the user's eye, light field displays create an image inside the eye by direct retinal projection.

Rather, the concepts presented here propose a light field display comprising an optoelectronic device for generating a raster image and an optics module for direct retinal projection of the raster image into a user's eye. In order to improve the image resolution while maintaining a compact size, the proposed operating method is based on the realization that in addition to a first raster image projected flat onto the retina of a user, a second raster image, which has a higher resolution and a smaller spatial extent than the first raster image, is imaged onto the fovea centralis in the user's eye.

The projection covers at least the fovea centralis and can draw a picture on a further area around the fovea centralis, which is assigned to the parafovea. This ensures that a certain centering error of the second raster image relative to the position of the fovea centralis is not perceived in the user's eye. A maximum diameter of the second partial raster image projected onto the retina of 5 mm, preferably of 4 mm and especially preferably of 3 mm is advisable.

In some aspects of the proposed concept, the light field display comprises a first imaging unit generating a first raster field and a second imaging unit generating a second raster field. The raster image projected onto the retina comprises the first raster sub-image and the second raster sub-image. Thus, there may be additional raster sub-images that are projected onto different areas of the retina with an adapted resolution. It is possible to create configurations for which the retinal projections of the raster images overlap.

For an embodiment, the retina-projected raster image is composed of the first raster partial image and the second raster partial image, whereby the first raster partial image has a dark area in the area of the fovea centralis, into which the second raster partial image is faded in with higher resolution by an adjustment optic. The adjustment optic is configured in such a way that the relative position of the retinal projection of the second raster partial image can be adjusted in relation to the retinal projection of the first raster partial image. For this purpose, an advantageous embodiment of the adjustment optics has a switchable Bragg grating. For a further embodiment according to some aspects, the adjustment optic includes an Alvarez lens arrangement, in particular a rotatable version with a Moire lens arrangement. Here, the beam deflection is determined by the first derivative of the respective phase plate relief, which is approximated, for example, by z=ax2+by2+cx+dy+e for the transmission direction z and the transverse directions x and y, and by the offset of the two phase plates arranged in pairs in the transverse directions x and y. For further design alternatives, swivelling prisms or other elements with the same functionality are provided in the adjustment optics.

For a further embodiment, the optical module of the light field display has collimation optics for the first imaging unit and/or the second imaging unit. Preferably, the adjustment optics are at least partially arranged in the collimation optics and especially preferably completely in the collimation optics. In some aspects, an adjustment optics can be at least partially located between the collimation optics and a waveguide. Particularly, flat embodiments use an adjustment optic, which is at least partially arranged, in a waveguide or completely in the waveguide.

For the light field display according to the proposed principle, the first imaging unit and/or the second imaging unit are formed by a light emitting diode microarray. This has the advantage that a space-saving arrangement results, since the μ-LED module and/or a μ-display for the particularly high resolution and its control components can be designed in a small construction due to the limited projection area. For an embodiment, the μ-LED module for the second imaging unit can be simplified in terms of design by the fact that at least the central areas have pixels that generate light only in the green and red spectral range, which can be detected by the cones of the fovea centralis.

For an embodiment, the light field display is assigned in some further aspects to a measuring device for determining the position of the fovea centralis in the user's eye. This may include an IR illumination device for measuring the retina. In particular, a device may be provided which determines the position of the fovea centralis by an imaging procedure. It is also possible to determine the position indirectly by measuring the optical axis of the eye on the basis of the pupil position or by detecting the location of the more visible optic nerve papilla on the retina. From the centre of the optic nerve papilla, the centre of the fovea centralis in the average adult is at a transverse distance of 4.5 mm (15°) laterally (on the temporal side) and a vertical offset of 0.65 mm (2° 10′) proximally.

For a further configuration of the light field display, the projection of the first raster partial image onto the fovea centralis is dynamically tracked and thus follows the direction of the user's gaze. For this purpose, an eye movement detection device and a control device for the adjustment optics are provided. For possible designs, the eye movement detection device has an imaging measuring device for the fovea centralis or another reference point in the eye, such as the pupil axis or the optic nerve papilla. In addition, the control device may also have a prediction device which has a model of the eye movement stored in it and which additionally processes the superimposed image data. In doing so, moving objects in the image to which the user most probably directs the direction of gaze can be detected and this information can be fed into the motion model.

Another concept is based on the fact that the human eye does not see equally well everywhere in its full range of vision, both in terms of color perception and spatial resolution. In particular, eye sensitivity varies across the visual range, so that good spatial resolution and good color resolution are only necessary in the area around the center of a μ-display. Thus, power consumption can be reduced compared to conventional displays or pixel arrays. In addition, a more compact component can be implemented without restricting the visual experience.

Thus, an imaging element only needs to have as good a resolution as is required for the respective areas in the eye.

The application now suggests to create a imaging element with a variable pixel density and to generate the image by scanning with a suitable optical system. For example, the imaging element comprises a linear imaging element with variable pixel density and suitable optics so that the actual image is generated by scanning the polar angle. Optics are used to “rotate” an image strip represented by a line array, resulting in a circular two-dimensional image with a variable pixel resolution for an user. This resolution decreases with increasing distance from the centre according to the sensitivity of the eye. The linear imaging element can be, for example, an array of μ-LEDs or a monolithic pixelated RGB array. The latter is a monolithic component in which individual areas can be individually controlled. The versions of μ-LEDs or modules disclosed in this application are particularly suitable for such an arrangement. The size of the μ-LEDs or pixels should be as small as possible in the centre of the visual range of the eye to achieve high resolution. In the peripheral areas, a much coarser resolution is then sufficient, since the sensitivity of the eye is also lower here. Here, the color reproduction can also be greatly reduced and in extreme cases can be limited to green light only, since the color perception of the eye is also greatly restricted in the peripheral areas.

In some aspects, a pixel array is proposed, especially for a display in polar coordinates. This comprises a plurality of pixel elements arranged in at least one line from a starting point on an axis through the starting point. The plurality of pixel elements each have a height and a width. At least the width of the pixels, defined as the distance between the centers of two adjacent pixels, is variable in such a way that the width of the pixel elements increases along the line from the starting point. In other words, the individual pixel elements become wider the further away they are from the defined starting point. This line, in a configuration also two or more lines on top of each other, can be used to display a display. In this context, the term “pixel” refers to an addressable picture element of a predefined size, which includes at least one light source. The light source can be of the same size as the pixel, but can also be smaller. Thus, the increase in width can be achieved by different active areas of the light source in the pixel or by increasing dilution. In other words, with increasing distance, the predefined size becomes larger while the light area remains the same, or the light-emitting area becomes smaller while the predefined size remains the same.

In one aspect, not only the width but also the height can be variable. For example, the pixels can also have a variable height, which increases with increasing distance from the starting point.

It may be intended to rotate the light coming from the line array (which forms a light strip) so that a light strip rotating around the starting point results. If this rotation is sufficiently fast, the result is a substantially circular display. The focal point of the eye is substantially in the starting point, which is also the point of rotation. In a design, the variable height is chosen so that the position of the pixel elements from one position to the next are adjacent to each other due to the rotation of the light strip.

In an aspect, the starting point forms a central midpoint and the many pixel elements are arranged symmetrically around the midpoint along the axis in one line. This configuration is similar to the design mentioned above. The only difference is that the rotation is no longer 360°, but only 180° to create a complete image. This allows higher frame rates to be achieved at the same rotation frequency. Alternatively, the optical system can be simplified, since it only has to rotate in a reduced angular range.

In another aspect, the array contains pixels of several basic colors, so that a multi-colored display can be realized. This is done either by an alternating arrangement of the colors within the same one line or the array comprises further lines or- and/or below the primary line, which contain pixels of other primary colors. A colored pixel can also be formed by one subpixel, in which case three subpixels of different color are combined to one pixel. This is the conventional approach for μ-displays. In the present case, however, due to the different light generation and guidance concept, for the sake of simplicity, pixels and subpixels are used synonymously.

Another aspect concerns the different color perception of the eye, which changes depending on the position as well as the spatial resolution. In general, this aspect can be realized in different ways. In an embodiment, for example, two adjacent pixels in a line have a different color. Thus, the plurality of pixel elements can include at least three different colors, with the number of pixels (or subpixels) of the respective color being different. For example, these can be the colors green, red, blue, and yellow. To take into account the decreasing color sensitivity of the eye, the number of pixels of different color can also vary with increasing distance. For example, pixels of the color green may occur more frequently with increasing distance from the starting point than corresponding pixels of other colors.

This generally varies the color distribution of the large number of pixels along the axis. For example, the colors in the central area, i.e. near the starting point, are evenly distributed, and further outwards the color to which the eye is still sensitive dominates.

In an alternative configuration, a first number of the plurality of pixel elements is arranged in a first line, a second number of pixel elements is arranged in at least one second line. The pixels in the first line differ in color from pixels in the second line. There may be three or four lines of pixel elements, with the pixels in each line being of a different color.

It may also be provided that each of the at least two lines contains pixel elements of all colors. However, these are arranged differently from line to line, so that the nth pixel of each line differs in color. This can be useful when creating an overall image by rotating the lines.

In an embodiment, the rows are arranged essentially parallel to an axis. In an aspect, a first row of the at least two rows is arranged centrally on the axis, a second row then follows below the centrally arranged row, a further row eventually above. However, it is also possible to place all rows in a common starting point and at a defined angle to each other. In this way, each row is arranged along an axis, but not parallel. For example, three lines can have a common starting point and include an angle of 60°.

Some other aspects concern a distribution of pixels of different colors. The first and at least one second line need not have the same number of pixels. For example, the first number of the plurality of pixel elements in the first line is different from the second number of the plurality of pixel elements in the at least one second line. For example, the active area of the light source may be different in the pixels of the first line and the pixels of the second line. This aspect can be realized mainly in a range of the lines, i.e. from a predefined distance from the starting point depending on the sensitivity of the eye.

In particular, one aspect requires that at least some pixels of the first and second line have the same width and from an n-th pixel of the first line on the width is different from the width of the n-th pixel of the second line. In an embodiment, the one line or the several lines is designed as a pixelated array, in which each pixel of the array can be controlled individually. Such an array can be configured as a monolithic component. Alternatively, the individual pixel elements can be implemented by μ-LED.

Another aspect concerns a pixel matrix. As described above, to form a display and an image, it is sufficient to use a pixel array and to rotate the light strip generated by this array. In aspects, a pixel array with at least two pixel arrays is now also proposed, especially for a display in polar coordinates. The at least two pixel arrays have a common center, i.e. their respective starting point is the same. Furthermore, the two pixel arrays form a defined angle to each other. For example, the angle between the pixel arrays is 90° for two pixel arrays, for three pixel arrays the angle can be 60°.

Another aspect concerns a display arrangement in polar coordinates. Such an arrangement comprises a pixel array or matrix and an optical system for light deflection and rotation of the light strip generated by the pixel array during operation. The optical system comprises a mirror, which is movable about at least two axes, which is arranged in a main radiation direction of the pixel array or the pixel matrix and is adapted to make radiated light from the pixels arranged in line rotate about a point corresponding to the starting point.

Finally, a last aspect concerns a method for operating a pixel array or a pixel matrix. For this purpose, a first light strip with a plurality of pixel elements arranged in a line is generated and this light strip is guided to a target location. Then a second light strip is generated. The second light strip is rotated by a certain angle and a rotation point, whereby the rotation point corresponds to the starting point of the pixel elements arranged in a line. The second light strip thus rotated is then guided to the target location. In an embodiment, the rotation of the light strip takes place via one or more mirrors. The line can be a single or several lines. A monolithically integrated pixelated component can also be used as such a line.

Another aspect relates to the control of light emitting elements in a μ-LED display. The limited space available among the current matrix element pixels requires further consideration of how to address and control the individual pixels. Conventional approaches and techniques may not be usable due to the limited space. This may also apply to concepts where the current is controlled by each pixel. Since the required space for a μ-LED as subpixel is much smaller than for normal pixels, newer concepts are necessary.

In addition, driver circuits should be capable of providing the current frame rates of 60 Hz to 240 Hz. In this context it is also necessary or at least expedient to achieve a wide dynamic brightness range (1:100,000) or 100 dB per individual pixel. This range is necessary to achieve sufficient contrast and brightness of the image even under different external light influences in automotive or augmented reality applications.

Due to the already mentioned size of the individual μ-LEDs in both pixelated displays and monolithic arrays, a digitally generated pulse width modulation, PWM, seems to be appropriate. Accordingly, the technology should be scalable in terms of both pixel array size and CMOS technology process nodes. A digitally generated PWM also allows calibration for non-uniformity of both pixel array and pixel current.

A digital nonlinear PWM can process digital codes so that the pulse width can be generated by a nonlinear transfer function of the codes to pulse width. In the following different concepts are presented, which are suitable for implementation in monolithic displays or pixelated arrays with μ-LEDs due to their special size or scalability.

Typically, in a pulse width modulation (PWM) implementation, a standard pixel cell circuit is very quickly switched alternately to “off” and “rated current”. For this purpose, a so-called 2T1C circuit is used in conventional circuits. However, especially in displays with a high number of lines and columns, the programming frequency is very high in order to achieve a sufficient “refresh rate” of the display. In the past, this problem was solved by a second transistor, which, however, consumes additional space. Especially with the μ-displays shown here, or even the space “under” the μ-LEDs, the space may no longer be sufficient. In addition, depending on the wiring (i.e. position of the μ-LED within the current path), a higher inaccuracy and thus intensity fluctuations can occur. Accordingly, a current driver for μ-LEDs with backgate, which reduces these problems. According to an aspect described here, a device for electronic control and power supply of a μ-LED is proposed, which has a data signal line, a threshold line and a selection signal line. Furthermore, a μ-LED is proposed, which is electrically connected in series to a dual-gate transistor and together with it between a first and second potential connection. A first control gate of the dual-gate transistor is connected to the threshold line. The device also comprises a select-hold circuit with a charge accumulator connected to a second control gate of the dual-gate transistor and to a current conduction contact of the dual-gate transistor, and with a control transistor whose control terminal is connected to the selection signal line.

Instead of an additional transistor for pulse width modulation (PWM), the additional control gate of a dual-gate transistor can now be modulated with a PWM signal as an existing driver transistor. In some aspects, the dual-gate transistor also acts as a current driver transistor.

According to a second aspect, a device is also proposed, where a μ-LED and a dual-gate transistor are arranged in series in a current path. An analogue data drive signal is applied to one side of the dual-gate transistor via a selection hold circuit to control the color of the μ-LED by means of the selection signal. A pulse width modulation signal coupled to the other side of the dual-gate transistor controls the brightness of the μ-LED.

Advantageously, a backgate transistor is used as a dual-gate transistor.

The modulation of the backgate of the driver transistor can also be used as an actuator for the current control loop in order to feed back a feedback signal, for example the forward voltage of the LED, thus achieving a current feedback to a LED temperature drift. By modulating the voltage at the backgate of the driver transistor, a light emitting diode current can be easily and, above all, space-savingly pulse-width modulated, especially in the TFT (Thin Film Transistor) pixel cell. With RGB cells, this results in a saving of three power transistors.

A weak modulation of the voltage at the backgate can be used to make the current in the μ-LED substantially independent of the μ-LED temperature. This is especially useful when using an NMOS cell with the μ-LED on the low side of the driver transistor, because of the common cathode. Such cells have intrinsically poor current accuracy, so that the idea of the present invention can be used to improve such cells significantly.

On the one hand, this allows pulse width modulation via the backgate of the main transistor instead of via an additional transistor, in addition to the main transistor. On the other hand, the use of a backgate transistor in displays allows temperature stabilization by “not digitally” operating the back-gate with pulse width modulation, but with an analogue voltage. This is derived from the forward voltage Vf of the LED, which is used as a feedback loop of a control system. Such temperature stabilization improves the color accuracy and stability of the μ-LED.

In some aspects, the dual-gate transistor may include a back-gate transistor where the backgate is the first control gate. This is a compact design. The dual-gate transistor can be designed as a thin-film transistor with two opposite control gates. This allows a reliable and compact manufacturing. The first control gate of the dual-gate transistor can be configured to set a threshold voltage. In this way, a modulation can be carried out. Alternatively, a switching signal (PWM signal) can be applied to the first control gate during operation. This allows a simple brightness control to be carried out.

In further aspects, the μ-LED can be connected with its first terminal to the first potential connection, the dual-gate transistor can be arranged with its current line contacts between a second terminal of the μ-LED and the second potential connection. The selector hold circuit may have the charge storage connected to the second control gate of the dual-gate transistor and to the second terminal of the μ-LED. This version can be easily manufactured in NMOS technology.

In further aspects, the μ-LED can be connected with its first connection to a second current line contact of the dual-gate transistor and with its second connection to the second potential connection. The Dual-Gate Transistor is connected with its current conducting contacts between a first terminal of the μ-LED and the first potential connection. The charge memory of the selector holding circuit is connected to the second control gate of the dual-gate transistor and to the first potential connection. Thus, the forward voltage of the LED does not affect a gate-source voltage of the dual-gate transistor.

Another aspect deals with the realization in μ-MOS technology. There the μ-LED is connected with its first terminal to the first potential terminal and the dual-gate transistor with its current line contacts is connected between a second terminal of the μ-LED and the second potential terminal. The selector hold circuit can be connected with the charge storage to the second control gate of the dual-gate transistor as well as to the second potential connection.

In a further aspect, the selection hold circuit comprises a further control transistor, which is connected in parallel to the μ-LED and whose control terminal can be connected to the selection signal line.

According to a further configuration, the charge accumulator can be connected to the second control gate of the dual-gate transistor as well as to the first potential terminal, and further comprises a temperature compensation circuit with a negative feedback based on the detection of a forward voltage by the μ-LED, whereby the temperature compensation circuit can form the threshold line on the output side. This allows additional weak modulation to be impressed on the backgate transistor.

In some aspects, the temperature compensation circuit may include a control path, which may be in parallel with the dual-gate transistor, and may have two paths connected in series. This is a simple design. In another embodiment, from a node between the two controlled paths provided by a third control transistor and a fourth control transistor, the threshold line may be connected to the first control gate of the dual-gate transistor. By means of the node the back gate can be effectively controlled. According to a further embodiment, the control terminal of the fourth control transistor can be connected to the second potential terminal. In this way, the gate of the transistor is set stable to the high potential of the second potential connection.

Another aspect is that the temperature compensation circuit may include a second charge storage device, which may be connected to a control terminal of a control transistor providing one of the two paths and to the first potential terminal. This allows the gate voltage of the third transistor to be buffered.

A second data signal line is coupled to the second charge storage and the third control transistor. A signal on this line is used to program a negative feedback factor. The second data signal line can also be used for fine adjustment of the temperature compensation. Depending on the application, this fine adjustment can be switched on or off by means of a further control transistor According to another advantageous embodiment, in the temperature compensation circuit the control terminal of the third control transistor can be connected to the second potential terminal. In this way, the gate voltage of the third control transistor is advantageously fixed in a clear and stable manner.

In accordance with another advantageous embodiment, a fifth control transistor can be connected in parallel to the μ-LED. A switching signal (PWM signal) is applied to its control terminal during operation. In this way, the LED can be switched on and off directly and without charge storage, in particular by means of pulse width modulation. The dual-gate transistor can then operate as a temperature-stabilized current source.

Also a control for a brightness adjustment or a dimming of pixels of importance. Such dimming is not only required in the automotive sector, for example to switch between day and night vision, but also in AR applications. Basically, such dimming can be useful and advantageous when contrasts have to be adjusted or when external light makes it necessary to control the brightness of a display in order to avoid dazzling a user or to show information reliably.

For the reasons mentioned above, different technical solutions are known for the control of lighting units with LEDs, in particular to operate displays at different brightness levels. For example, control circuits for controlling matrix displays are known, with which the individual pixels of the rows formed by several rows and columns are specifically controlled. Likewise, control circuits are known with which the LED current can be reduced or dimmed. This so-called current dimming is used, for example, in displays with liquid crystal displays or OLEDs.

Due to the limited space available, solutions with a large number of components are difficult to implement. This can sometimes make the circuits very complex. Based on this, the following aspects should further develop the control of a lighting unit with LEDs to vary the brightness in such a way that a comparatively simple, accurate and reliable variation of the brightness of the light emitted by the LEDs is achieved. In particular, the above-mentioned dimming and operation in different brightness and contrast levels should be made possible.

Thus, a control circuit for changing the brightness of a lighting unit is proposed, which has a voltage source for supplying the lighting unit with electrical energy and at least one energy storage device. The latter sets a current for the illuminants of the lighting unit. Furthermore, a control element is provided which temporarily changes a voltage of a voltage signal generated by the voltage source, on the basis of which a LED current flowing through the at least one LED can be adjusted. According to the proposed principle, the control circuit has been developed further in such a way that the control element is set up to operate the lighting unit at at least two different brightness levels by transmitting a first and a second voltage signal having different voltages to the lighting unit during a period, i.e. in a repeating time period, and the brightness level can be adjusted as a function of the voltage of the first voltage signal.

Essential for this concept is therefore that a pulsed voltage signal is applied to the lighting unit, whereby a current flows through the at least one μ-LED of the lighting unit as a function of the voltage signal, which causes the LED to light up. During a period, a first voltage signal, in particular a switch-on voltage signal, and a second voltage signal, in particular a switch-off voltage signal, are advantageously provided, wherein the at least one LED provided in the lighting unit is supplied with a current proportional to the voltage during the application of the first voltage signal or a current proportional to the voltage flows through it. It is basically irrelevant here whether the lighting unit has one or a plurality of LEDs. One aspect of the switching element has a transistor, via which the at least one LED of the lighting unit is supplied with electrical energy depending on the respective voltage signal and an LED current flows through it so that it preferably emits visible light.

According to the proposed concept, the lighting unit is controlled in such a way that within a period, firstly a first voltage signal is transmitted to the lighting unit in a first phase of the period and subsequently a second voltage signal is transmitted to the lighting unit in a second phase of the period, whereby a current flow through the at least one LED of the lighting unit is effected depending on the voltage of the respective voltage signal. It is important here that the voltage or the voltage value of the second voltage signal is significantly lower than the voltage of the first voltage signal. Preferably, the voltage of the second voltage signal is at least nearly zero.

In the first phase of the period, in which the first voltage signal is transmitted to the lighting unit, the energy storage of the lighting unit is charged. At the same time, a current proportional to the voltage of the voltage signal flows through the LED, which emits visible light. While in the second phase of the period the second voltage signal is transmitted to the lighting unit, the potential in the energy storage, preferably a capacitor, is maintained so that until the beginning of the following period a current caused by this flows through the LED, which thus continues to emit light. Although the intensity of the current flowing through the LED during the first phase of the period should theoretically be equal to the intensity of the current flowing through the LED during the second phase of the period, this is not the case in practice. This is due to the fact that the control circuit usually has a second capacitance in addition to the capacitance of the energy storage device, in particular a capacitor, thus creating a capacitive voltage divider so that the voltage at the energy storage device is lower during the second phase of the period compared to the voltage during the first phase of the period. Such a second capacitance is provided, for example, by the capacitance of the transistor, in particular the so-called gate-source capacitance.

In this context, it is significant that the intensity of the current flowing through the LED during the first phase of the period in which the first voltage signal is transmitted to the lighting unit is different from the intensity of the current flowing through the LED during the second phase of the period in which the second voltage signal is transmitted to the lighting unit, namely smaller. However, an observer will not recognize this difference, which leads to a difference in the maximum brightness of the LED during a period, but will only perceive the light output averaged over the period.

In order to use this effect in a suitable way for the control of lighting units used in displays, for example, it is advantageous if the first and second voltage signals are repeated at a frequency of 60 Hz, which corresponds to the usual refresh rate of displays. This means that within one second, a first and a second voltage signal are transmitted to the lighting unit sixty times each, whereby a LED current flows through at least one LED of the lighting unit depending on the voltage of the respective voltage signal.

In further aspects, it is planned that the μ-LED, while the second voltage signal is transmitted to the lighting unit, is supplied with the electrical energy required to excite light emission from an energy storage device designed as a capacitor. Since the voltage of the capacitor is lower than that of the first phase of the period, the LED is passed through by a current of lower intensity in this operating state compared to the first phase of the period, so that the μ-LED shines less brightly.

Furthermore, it is conceivable in this way that the control element is set up to generate the first voltage signal with a duty cycle of 0.0025 to 0.003, the duty cycle corresponding to the ratio of the duration of the first voltage signal to the duration of the period. The duty cycle thus indicates the ratio of the duration of the first voltage signal to the duration of the period. At a repetition frequency for the first and second voltage signals of 60 Hz, this means that the control element is arranged according to this embodiment of the invention such that a period within which the first and second voltage signals are transmitted to the lighting unit is 0.0166 s or 16.6 ms long. In a preferred embodiment, the first voltage signal is transmitted to the lighting unit for a period not exceeding 0.050 ms, which corresponds to a duty cycle of about 0.003 or 1:333. In this case, the second voltage signal is transmitted to the lighting unit for a period of 16.6 ms. The duty cycle in relation to this signal is therefore approximately 1.

Since the brightness of an LED perceived by an observer depends on the average brightness or light output emitted during a period, a current flow in the LED during the second phase of a period and thus the proportion of light emitted by the at least one LED in the second, comparatively long phase of the period has a considerable, disproportionately strong influence on the average light output of an LED of the lighting unit.

In some aspects it is conceivable that the control circuit is arranged to operate the lighting unit at a first, darker brightness level by setting the voltage of the first voltage signal to a voltage value within a first voltage interval and to operate the lighting unit at at least a second, brighter brightness level by setting the voltage of the first voltage signal to a voltage value within at least a second voltage interval whose voltages are higher than those of the first voltage interval. In accordance with this embodiment, two voltage intervals or voltage ranges are thus provided for the control of a lighting unit, which each have different voltages with which the first voltage signal is generated and which are at different voltage levels. Depending on the voltage level of the first voltage signal, the lighting unit is thus operated either at a first, darker brightness level or at a second, brighter brightness level. If the lighting unit is to be operated at the brighter brightness level, the lighting unit is controlled on the basis of a first voltage signal whose voltage lies in the second voltage interval and thus in the voltage interval which has the higher value.

In another aspect, the control element is set up to operate the lighting unit at the same brightness level by selectively varying the voltage of the first voltage signal within one of at least two defined voltage intervals. This means that in a beneficial manner the first voltage signal, in particular its voltage, is only varied between two successive periods to such an extent that the corresponding voltage is still within the same voltage interval and it is ensured that the lighting unit is still operated at the same brightness level despite a slight change in brightness. It is thus possible to dim the lighting unit, in particular the at least one LED provided within the lighting unit, to at least two different brightness levels, i.e. to provide an at least largely stepless range at least at two different brightness levels in each case, in which the brightness of the at least one LED of a lighting unit is deliberately changed.

According to a further embodiment, it is intended that the first voltage interval or the first voltage range should have voltage values at least in the range of 1.3 V to 3.0 V. Furthermore, it is preferably provided that the second voltage interval or the second voltage range has voltage values at least in the range from 4.0 V to 10.0 V. In this way, two ranges are realized at different brightness levels, within which the brightness of the lighting unit can again be specifically and continuously changed or dimmed.

With regard to the embodiment described above, the idea can again be considered that—as soon as a comparatively small first voltage signal is applied to the lighting unit—the total current flowing through the LED during a period is significantly determined by the current flowing through the LED during the first phase of the period in which the first voltage signal is applied to the lighting unit. In this case, the lighting unit is operated at a comparatively low brightness and the emission of light due to a current flow through the LED caused by the second voltage signal applied to the lighting unit during the second phase of the period can be neglected in this operating state.

If, on the other hand, a first voltage signal with a comparatively high voltage is transmitted to the lighting unit, the total current flowing through the LED during a period is determined to a large extent by the current flowing through the LED during the second phase, i.e. while the second voltage signal is applied to the lighting unit. In this case, the lighting unit is operated at a high brightness level and can be dimmed in this range by selective variation of the first voltage signal. The presented control circuit can be used in a display or monitor for image generation. These can be part of a larger screen or display device, for example in a motor vehicle. Also a realization in AR or VR glasses or any other device is conceivable. Again, it is essential that a control circuit is used which allows a display or monitor to be operated at at least two different brightness levels.

In addition to a specially designed control circuit, some aspects also relate to a method for selectively changing the brightness of a lighting unit, in which a voltage source supplies the lighting unit with electrical energy and at least one LED as the illuminant of the lighting unit is supplied with electrical energy at least temporarily from an energy storage device of the lighting unit. Furthermore, in this method a voltage signal is transmitted to the lighting unit at least intermittently and the current flowing through the at least one LED is adjusted on the basis of the voltage signal.

The method is characterized in that the lighting unit is operated at at least two different brightness levels by transmitting a first and a second voltage signal having different voltages to the lighting unit during one period and adjusting the brightness level depending on the voltage of the first voltage signal. It is again substantial to the invention that the brightness of an LED, which is decisively determined by the total current flowing through at least one LED during a period, can be selectively changed by transmitting a first voltage signal which is transmitted to the lighting unit in a first phase of the period. To drive the lighting unit, a first voltage signal is applied to the lighting unit in a first phase of the period, so that initially, while the first voltage signal is applied to the lighting unit, the energy storage device of the lighting unit is charged and a current proportional to the voltage of the voltage signal flows through the at least one LED of the lighting unit. In a second phase of the period, a second voltage signal is transmitted to the lighting unit with a voltage, which is significantly lower than the voltage of the first voltage signal, preferably close to zero. This initially lowers the potential of the energy storage device, in particular a capacitor, which also reduces the strength of the current flowing through the LED accordingly.

Compared to the first phase of the period, the LED therefore shines less brightly in the second phase, but this over a comparatively long period. Depending on the level of the voltage value of the first voltage signal, the lighting unit can be operated at a high brightness level with comparatively high average light output or at a low brightness level with comparatively low average light output. In this context, it should be noted that for a first voltage signal with a comparatively low voltage, the influence of the first phase of the period on the average light output of the LED is comparatively high, whereas for a first voltage signal with a high voltage value, the second phase of the period in which the second voltage signal is applied to the lighting unit is of decisive importance for the average light output of the LED.

In this way, it is intended that the LED of the lighting unit, while the second voltage signal is applied to the lighting unit, is supplied with electrical energy from an energy storage device designed as a capacitor. Furthermore, it is advantageous if the lighting unit is at least temporarily operated at a first, darker brightness level by setting the voltage of the first voltage signal to a voltage value lying within a first voltage interval and the lighting unit is at least temporarily operated at at least a second, brighter brightness level by setting the voltage of the first voltage signal to a voltage value lying within at least a second voltage interval, the voltages of which are higher than those of the first voltage interval.

In one embodiment it is provided that between two consecutive periods the voltage of the first voltage signal is varied without changing the brightness level at which the lighting unit is operated. This means that the average light output of an LED is varied while it is operated at a constant brightness level. The voltage of the first voltage signal is thus varied between two successive periods within the voltage interval or voltage range provided for the corresponding brightness level.

In addition to the question of temperature stability and drift of an input voltage or current through the diode due to process fluctuations, the pulse modulation used is also an aspect to be considered. In current displays, light emitting diodes are usually operated in pulse width modulation, i.e. they are switched on and off in rapid succession for contrast and brightness adjustment. The frequency is several 100 kHz up to the MHz range. The switching operations act back on the current source. This can affect the precision and stability of the power source. In the case of control loops within the power source, the switching processes lead to spikes or other behaviour, which can bring the control loop out of its control range.

Following these considerations, a regulated current source for μ-LEDs which controls a current source in such a way that its output current remains in its control state and follows a setpoint value even during PWM modulation and in particular during switching operations. The current source and in particular the feedback loop is suitable

For this purpose the output current or a signal derived from it is fed to the control loop, which compares it with the setpoint. If the current source is now switched off or operated in an on/off mode (intermittent operation), a substitute signal is fed to the control loop while the output current is switched off. The substitute signal keeps the control loop in its control range. The substitute signal corresponds or is similar to an expected output current or the signal derived from it. All in all, continuous control in the output range is achieved in this way, independent of the switching state of a current source. The precision and stability of the supply circuit is maintained.

In an embodiment, a supply circuit is proposed which comprises an error correction detector with a reference signal input, an error signal input and a correction signal output. Furthermore, a controllable current source with current output and a control signal connection is provided. The control signal terminal is connected to the correction signal output to form a control loop for the controllable current source. In other words, the error correction detector controls the output current of the current source within certain limits. The current source is thus configured to provide a current at the current output depending on a signal at the control signal terminal.

According to the proposed principle, the supply circuit comprises a substitute source with one output, which is configured to provide a substitute signal. Finally, a switching device is arranged in operative connection with the controllable current source and the error correction detector, so that the switching device, depending on a switching signal, supplies the error signal input with either a signal derived from the current at the current output or the substitute signal with additional separation of the current output of the current source. In other words, the switching device is coupled to the controllable current source and the error correction detector and is configured to supply either a signal derived from the current at the current output or the substitute signal to the error signal input. In addition, the switching device is configured to disconnect the current output in the latter case.

This creates an arrangement that keeps the control loop in a control range independent of the operating state of the power source. The current source can thus be operated in a PWM or other intermittent mode in addition to being controlled by the control loop and the error correction detector.

It is useful if the substitute signal correspond substantially to the signal derived from the current signal. In this way, the control loop, and especially the error correction detector, will provide a signal that is hardly different from that of the current source, so that the control and the modulation remain intact.

In one aspect, the adjustable current source has a current mirror with a switchable output branch. This is connected to the current output or forms it. The output branch may comprise one or more output transistors whose control terminals or gates are connected to a control terminal of a current mirror transistor arranged on the input side.

In another aspect, the output transistor of the output branch is connected with its control terminal to the switching device. The switching device is configured, depending on the switching signal of the output transistor, to connect to a fixed potential for opening the output transistor or to connect the control terminal to the control terminal of the current mirror transistor arranged on the input side. When the control terminal is at the fixed potential, the output transistor opens or closes, i.e. it no longer conducts current and the load and the output of the supply circuit are disconnected.

In another aspect, the switching device is located in the output branch and is configured to disconnect the current output or output transistors from the load. The tap for the error signal input of the error correction detector is located between the switching device and the load.

In another aspect, the adjustable current source has an input branch. A reference current signal can be fed to the input branch so that the current source supplies an output current dependent on it. The input branch of the adjustable current source also includes a node, which is connected to the reference signal input of the error correction detector. Thus, for example, the reference current, which is fed to the current source to derive the output current, can also serve as a reference signal for the error correction detector.

The adjustable current source may also include a current mirror, with the control signal terminal connected to the control terminal of an output transistor of the current mirror. This allows a current through the output transistor to be changed with a control signal, thus providing regulation. The control terminal of the output transistor of the current mirror is coupled to the current mirror transistor of the current mirror via a capacitor in positive feedback. The capacitor is used for frequency compensation and thus improves the stability of the control.

Another aspect concerns the differential amplifier. This can include a differential amplifier whose two branches are connected to a supply potential via a current mirror. Optionally, the two branches of the differential amplifier can each include an input transistor, which have different geometrical parameters. Together with the current mirror, different fixed factors between reference and error signal can be taken into account. In a further aspect, the substitute source comprises an element coupled to the output for voltage generation, so that the substitute signal essentially corresponds to the signal derived from the current signal. This allows the substitute signal to simulate the current flowing through the load during regular operation, thus keeping the control loop in the control range.

The replacement source may comprise a series connection of a current-generating element and a voltage-generating element, with the output located between the two elements. Similarly, in a further aspect, the replacement source may comprise a transistor whose control terminal is connected to the control terminal of the current mirror transistor of the current source.

Another aspect concerns the switching device, which comprises one or more transmission gates. The supply circuit may comprise a reference current mirror configured to supply a current defined on the input side to the error correction detector and to the current source on the output side.

Another aspect concerns the use of a supply circuit for a power supply of a μ-LED. This is powered by the power supply circuit, which is an on/off operation. This means that the μ-LED is driven by a pulse-width modulating signal from the power supply. This operation is not unusual for optoelectronic devices, but the supply circuit generates a stable and precise output current during this pulse-width modulated operation.

Another aspect relates to a method for supplying a μ-LED. Here, a supply current through the load is detected. This can be done by detecting the current through the μ-LED. Alternatively, a signal can be derived from the current, which has a known relationship to the current through the load. The supply current or the signal derived from it is compared with a reference signal and a correction signal is generated from this comparison. With the help of the correction signal, the supply current through the consumer is controlled to a reference value, if necessary.

It is now intended that the consumer is switched off at certain intervals, i.e. disconnected from the supply current. In such a case, a substitute signal is generated instead of the signal derived from the supply current and used for the comparison step. In other words, instead of the supply current or a signal derived from it, the substitute signal is compared with the reference signal and a correction signal is generated from this comparison. This makes the control independent of whether the load is supplied with power or not. The substitute signal can substantially correspond to a supply current through the consumer or a signal derived from it.

Another aspect lies in the realisation of a driver circuit with low own power consumption, which can nevertheless drive a large number of optoelectronic elements and especially μ-LEDs.

In a first aspect of the present application, a driver circuit is intended to drive or control a large number of optoelectronic elements. The optoelectronic elements are configured as μ-LEDs and are arranged in an array of rows and columns. Each μ-LED can represent one pixel. Alternatively, if each pixel includes several, for example three, sub-pixels, each μ-LED can form one of the sub-pixels.

The driver circuit comprises a plurality of first memory cells, each of the first memory cells being associated with a respective one of the μ-LEDs. In addition, each memory cell includes two inputs, referred to as a set input and reset input, and an output. The first memory cells may be latches and may be configured as 1-bit memories. Each first memory cell can have two different states at the output, a first state and a second state, where the first state can be a high state and the second state can be a low state.

A set signal received from one of the first memory cells at the set input triggers the first memory cell at the output to the first state. The first memory cell holds the first state until it is reset to the second state by a reset signal received at the reset input. The output, especially the output signal provided at the output, of each first memory cell is configured to control or drive a respective one of the μ-LEDs. In particular, the output signal determines whether the μ-LED is switched on and emits light or is switched off and does not emit light.

CMOS technology would be particularly suitable for the production of the driver circuit and also the first memory cells and their associated circuits. The driver circuit according to the first aspect is a digital driver circuit and requires less power and space compared to conventional driver circuits. Furthermore, the driver circuit according to the first aspect provides better linearity. Each first memory cell can provide a pulse width modulation signal, PWM signal, at its output.

In an embodiment, each first memory cell comprises two cross-coupled NOR gates or two cross-coupled NAND gates. Each of the NOR or NAND gates has two inputs and one output. The output of each of the NOR or NAND gates is coupled to one of the inputs of the other NOR or NAND gate. The other input of one of the NOR or NAND gates receives the set signal, and the other input of the other of the NOR or NAND gates receives the reset signal.

In an alternative embodiment, each first memory cell comprises an N-type metal oxide semiconductor transistor, NMOS transistor, and a P-type metal oxide semiconductor transistor, PMOS transistor, which are connected in series, meaning that the channels of the two transistors are connected in series. Furthermore, an input of an inverter is connected between the NMOS transistor and the PMOS transistor, and an output of the inverter is connected to the gates of the NMOS and PMOS transistors. The driver circuit may include a plurality of loadable counters, each configured to activate a set signal to turn on a current through the respective μ-LED when data, such as a pulse width value, is loaded into the respective counter. The counter counts until the current value reaches the loaded data value. Then the counter activates a reset signal to turn off the current through the respective μ-LED.

When an array of μ-LEDs arranges them in N columns of pixels, the driver circuit can include N counters that generate PWM signals for N columns of pixels simultaneously per selected row. The driver circuit may also include a single common counter configured to generate a common or global dimming signal for the plurality of μ-LEDs.

To disconnect dark pixels, the driver circuit can include a large number of second memory cells. Each second memory cell may be coupled to a respective one of the first memory cells and may be configured to override an output signal of the respective first memory cell when required so that the respective μ-LED remains off. In other words, the second memory cells prevent the respective first memory cells from turning on the respective μ-LED when these optoelectronic elements represent dark pixels during a frame.

An optoelectronic device or μ-display according to a second aspect of the present application comprises a plurality of μ-LEDs and a driver circuit for driving the plurality of μ-LEDs according to the first aspect as described above. The μ-LEDs may be arranged in an array and may form a display or a portion of a display. Each of the μ-LEDs can form one pixel of the array. Alternatively, each μ-LED can also form a sub-pixel. For example, in an RGB pixel array, a pixel can contain three optoelectronic elements or μ-LEDs that emit red, green and blue light respectively. Alternatively, converter materials may be provided so that at least two of the three μ-LEDs emit light of the same color, which is converted by the converter material.

The μ-LED can be arranged above an integrated circuit, IC, which is located below the μ-LED. The circuit can be formed in a different material system.

In a third aspect, a method for operating an optoelectronic device or μ-display according to the second aspect is provided. At the beginning of a frame, a global reset is performed and the pixel current is switched off so that all optoelectronic elements are switched off. Next, dark pixels are loaded line by line. Thus, the optoelectronic elements that are dark during the frame are controlled by the second memory cells. Afterwards, a line by line content-dependent PWM, for example grayscale PWM, is performed. Thus, the current through the optoelectronic elements is controlled by means of the first memory cells.

In addition, after a global reset at the beginning of a frame, the pixel stream can remain switched off until a common or global dimming starts. The common dimming of the optoelectronic elements can be performed before the current through the optoelectronic elements is controlled by the first memory cells. The global dimming data can be combined with the grayscale data in the video/image signal processor IC or by the μ-LED driver IC so that no separate global dimming pulse is required and then only the grayscale data is updated line by line. The optoelectronic device according to the second aspect and the method according to the third aspect may include the embodiments disclosed above in connection with the driver circuit according to the first aspect.

A novel concept for the control of μ-LEDs, which are intended as pixels, is based on a analogue ramp for lighting control. For a control circuit for a display matrix comprising a plurality of optoelectronic devices arranged in rows and columns, pulse width modulation can be used to adjust the on/off behavior of each pixel. Although the principle seems to be similar to conventional pulse width modulation schemes, the implementation is different and takes into account the small space available.

A control circuit for a matrix display, in particular a μ-LED matrix display comprises a row selection input for a row selection signal, a column data input for a data signal, a ramp signal input for a ramp signal and a trigger input for a trigger signal. For the purpose of explanation, a ramp signal is a signal that varies over time from a first value to a second value. Usually, a ramp signal is periodic. The circuit includes a column data buffer configured to buffer the data signal in response to the row select signal. In some variants, the level of the column data signal may correspond to the brightness of the light-emitting device. A pulse generator is coupled to the column data buffer and the ramp signal input and configured to provide a buffered output signal to control the on/off ratio of at least one of the plurality of light emitting devices in response to the trigger signal, the data signal and the ramp signal.

The proposed principle implements an analogue pulse generator that requires only a small space. Since the ramp signal can be multiplexed in space and time, artefacts caused by activation of different pixels can be suppressed. Furthermore, time multiplexing when using the ramp signal leads to different switching behavior of the pixels. This means that the μ-LED associated with the pixels is switched at different times, which causes a more even power distribution and prevents current peaks.

In some variants, the pulse generator has a comparator device to compare the buffered data signal with the ramp signal. The result is delivered to an output buffer, which is coupled to an output of the comparator and the trigger input, the column data buffer can act as an input buffer in such embodiment. Together with the output buffer of the pulse generator a double buffering is realized, which allows to implement the circuit in displays using a longer duty cycle, thus reducing update rates and the like. In general, this concept will further reduce power consumption, which is preferred in advanced reality applications.

The output buffer can have a single memory stage, such as a flip-flop. In some variants, the buffer may contain an RS flip-flop, whose inputs are coupled to the output of the comparator device and, accordingly, to the trigger input. In this respect it should be noted that depending on the current implementation and the sign of the corresponding data and trigger signals (positive or negative), inverted inputs of the corresponding flip-flops can also be used. The column data buffer in some variants includes a capacitor to store the data signal and a switch located between the capacitor and the column data input. The capacitor may comprise a small capacitance, just as the input buffer can only apply a voltage signal of the order of a few volts and the comparator device has a very high input impedance. The comparator can be implemented using a differential amplifier. For example, an inverting input of the comparator can be coupled to the data column buffer and its non-inverting input can be coupled to the ramp signal input.

Depending on the implementation, the μ-LED coupled to the control circuit can only be active for a short period of time. In some variants, the μ-LED can only be active for about 50% of a normal cycle. In such cases, it is useful to be able to disable unneeded parts of the control circuit. For this purpose, the comparator device may have a power control input coupled to the trigger input for adjusting its power consumption based on the trigger signal. Alternatively, the comparator device may be coupled to the output buffer to control its power consumption based on an output state of the output buffer. In this respect, the output buffer may be configured to maintain its output state independently of its input coupled to the comparator device until it is reset or triggered by the trigger signal.

Another aspect concerns the generation of the ramp signal. In some variations, the control circuitry includes a ramp generator to provide the ramp signal to the ramp signal input, the ramp generator being configured to generate a varying signal between a start value and an end value in response to a trigger signal. The ramp generator can be implemented as a global ramp generator that sends a common ramp signal to various other control circuits. Alternatively, some ramp generators can be provided, where each individual ramp generator drives a number of lines and their respective pixels. Such an implementation allows to multiplex the ramp signals temporarily and thus reduce the artefact. Furthermore, a ramp signal supplied by a ramp generator can also be multiplexed before being applied to the ramp signal input.

Another aspect relates to a method of controlling the illumination of a light emitting device in a matrix display having a plurality of light emitting devices arranged in addressable rows and columns. In accordance with the proposed principle, the method comprises providing a trigger signal and a data signal for a selected row and at least one light emitting device. A level of the data signal is then converted to a pulse with respect to the trigger signal. More precisely, in some variants the level of the data signal is converted to a pulse width with respect to a trigger signal. The pulse is used to control the on/off ratio of the light emitting device with a pulse.

In some aspects, converting a level of the data signal involves generating a ramp signal between a first value and a second value. The data signal is compared with the ramp signal to generate a state signal. The state signal can be a digital signal. The pulse signal is then based on the trigger signal and a change in the state signal. Essentially, the pulse signal is set from LOW to HIGH or reset from HIGH to LOW in response to the change in the state signal. Of course, this principle of setting the value and resetting the value can be changed.

The ramp signal can be generated or initiated in response to the trigger signal. In some variants, both signals can be derived from a common signal. Delivering a data signal can also include pre-buffering of the data signal in some variants. For example, the data signal could be pre-buffered in a storage device such as a capacitor or the like.

Another aspect deals with the correction of errors in μ-LEDs of a μ-Display or μ-Display module that occur during their production by means of redundant μ-LED branches with selection fuse. Several concepts are presented in this application to create redundant μ-LEDs in production.

With μ-displays a μ-LED can fail during production. This can be caused, for example, by faulty assembly or, in the case of monolithic display modules, by a fault in one of the layers. There are two main variants of such an error. One is an open contact, known as “Open”, or a short circuit between the anode and cathode, known as “Short”. Both lead to the failure of the cell's LED.

Redundant μ-LEDs are provided for each subpixel to reduce the failure probability of a subpixel or a pixel. In the event of a defect, appropriate circuitry measures are taken to ensure that the cell does not fail, i.e. the defective LED can be decoupled from the current source. In some variants, however, this means that in a fault-free case both μ-LEDs are supplied by the same current source, namely the typical and the redundant one. This in turn leads to a color shift resulting from a dependency between cross current and dominant wavelength. In addition, due to the process technology of μ-displays or modules, often only one common cathode can be used for all LEDs. Depending on the further construction of the backplane (e.g. TFT backplanes), this can lead to the fact that only NMOS transistors (N-type metal oxide semiconductor transistors) can be used to construct the pixel cell. In a conventional 2T1C (2 transistors, 1 capacitor) cell, this leads to a clear dependence between the cross-current of the LED and its forward voltage.

There are various approaches to solving these difficulties, most of which, however, require additional work or space. According to the principle proposed here, a solution is given in which, on the one hand, redundancy is provided, but halving an electric current flowing through a light emitting diode is avoided. In addition, PMOS transistors can be used, which increases flexibility. The space consumption does not increase significantly, so that the solutions are just suitable for μ-displays with low space per pixel or subpixel.

This involves the creation of a device for electronically driving a plurality of μ-LEDs of a pixel cell or sub-pixel, in particular as a 2T1C cell. By means of a first transistor and an electronic imprinting component associated with the μ-LED, a current flow is generated which triggers the fuse connected in series to this μ-LED.

A device for electronically driving a plurality of μ-LEDs of a pixel cell or subpixel thus comprises a first and at least one second path each having a μ-LED connected therein and an electronic fuse arranged in series with the μ-LED. The first and the at least one second path are connected to one side with a potential terminal. Furthermore, a driver circuit with a data signal input, a selection signal input and a driver output is provided. The driver output is connected to the other side of the first and the at least one second path. Finally, the device comprises an imprinting component associated with the at least one second path, which is configured to generate a current flow triggering the electronic fuse arranged in series.

A characterising feature thus consists in the introduction of an additional imprint signal line in combination with an additional electronic imprint component, which can be adapted in particular as a transistor or as a diode. This ensures that after an end-of-line (EOL) test, only one LED per color and pixel is active, even in the case of an error-free pixel. In other words, in the event of an error, the μ-LED that is still functioning is selected. If, on the other hand, there is no error, i.e. both μ-LEDs of a path are working, one of the two will still be switched off permanently.

In a method for the electronic configuration of a plurality of μ-LEDs, a test of a function of the μ-LED of the first path and the second path is thus carried out first. If both μ-LEDs of the first and second path are functioning, an imprinting signal is applied to the electronic imprinting component. A current flow is then impressed into the second path of a fuse, which triggers the fuse connected in series with the μ-LED of the second path. For this purpose, the fuse is usually configured as a fuse link.

Depending on its embodiment, the imprinting component may comprise an imprinting transistor whose current line contacts are electrically parallel to the μ-LED to which the imprinting component is assigned and whose control contact is connected to an imprinting signal line. Alternatively, the imprinting component can also comprise an imprinting diode, which is connected with one terminal to the second terminal of the μ-LED to which the imprinting component is assigned. The other terminal of the impress-in diode is connected to the impress-in signal line.

The proposed arrangement makes it possible to design the μ-LED as a so-called common anode or common cathode. This means that, depending on the embodiment, the μ-LED of each path is either switched between supply potential and current source or between current source and reference potential connection. Thus, in one case the μ-LED is connected to the supply potential connection and the electronic fuse. In the other case, the μ-LED is connected between the fuse and the reference potential connection. The current source is always connected to the electronic fuse of the respective path. The charge storage of the 2T1C cell is connected to the gate of the current source transistor and the fixed potential, i.e. to the potential terminal to which the current source transistor is also connected.

In a further aspect, a μ-display or μ-display module with a variety of the devices described above is presented, in which pixel cells of the μ-display are electrically connected along a line and/or along a column to a common imprint signal line. Each pixel cell of a column is electrically connected to the supply potential terminal by means of a common supply line to a switching transistor arranged on a common carrier outside the μ-display.

Small-scale display arrangements with a high resolution are particularly desirable for AR systems, such as head-up displays or glasses with a light field display that projects a raster image directly onto the retina.

Micro OLEDs have been proposed for μ-displays with active pixel-sized light sources. Their disadvantage is their insufficient luminance and limited lifetime. An alternative for self-luminous light sources, which promises a long lifetime and a high efficiency as well as additionally a fast reaction time, is the use of μ-LEDs arranged in matrix form, for example based on GaN or InGaN. These are particularly suitable for display arrangements with a high packing density to form a high-resolution μ-display.

The starting point for the consideration is a display device comprising an IC substrate component and a monolithic pixelated optochip mounted thereon. In the present case, a monolithic pixelated optochip is understood to be a matrix-shaped arrangement of light-emitting optoelectronic light sources, which are created on a continuous chip substrate by a common manufacturing process. Some of the structures presented here can be produced in a matrix. These include, for example, the antenna structure, vertical or horizontal μ-rods, the paired bar-shaped configuration with converter material between the μ-LEDs or the μ-LEDs along special crystal directions, to name a few non-limiting examples. These light sources are adapted as μ-LEDs.

The IC substrate component features monolithic integrated circuits, which in turn result from a common manufacturing process. In addition, IC substrate contacts are arranged as a matrix on a top side of the IC substrate component facing the monolithic pixelated optochip.

The monolithic pixelated optochip comprises a semiconductor layer sequence with a first semiconductor layer having a first doping and a second semiconductor layer having a second doping, wherein the polarity of the charge carriers in the first semiconductor layer differs from that of the second semiconductor layer. Preferably, the first semiconductor layer and the second semiconductor layer extend laterally over the entire monolithic pixelated optochip. For an embodiment, the first semiconductor layer may have a μ-type doping and the second semiconductor layer may have an n-type doping. A reverse doping is possible as well as the use of several sublayers of the same doping for at least one of the semiconductor layers, which differ in the doping strength and/or with respect to the semiconductor material. In particular, the semiconductor layer sequence can form a double heterostructure. Between the first semiconductor layer and the second semiconductor layer there is a region with a transition in which light-emitting active zones are formed during operation of the display. For a possible embodiment, the active zone is located in a doped or undoped active layer, which is placed between the first and the second semiconductor layer and has, for example, one or more quantum well structures.

The individual light-emitting, optoelectronic light sources of the pixelated optochip each represent μ-LEDs arranged as a matrix, each μ-LED having a μ-LED rear side facing the IC substrate component and a first light source contact which adjoins the first semiconductor layer in a contacting manner and is electrically conductively connected to one of the IC substrate contacts in each case. In other words, each μ-LED in the pixelated optochip is formed so as to include a region of one of the above-mentioned active layers. Between adjacent μ-LEDs, the active layer or another of the above-mentioned layers may be interrupted, so that crosstalk is avoided.

The inventors recognized that a display arrangement with high packing density, which is simplified in terms of production technology, can be realized if the projection area of the first light source contact on the μ-LED rear side corresponds to at most half the area of the μ-LED rear side and the first light source contact is surrounded in lateral direction by an absorber on the rear side. In the present case, the lateral direction is understood to be a direction perpendicular to a stacking direction determined by averaging the surface normals of the semiconductor layer sequence.

Due to a small area first light source contact, which is significantly smaller than the pixel area of the assigned μ-LED, a lateral narrowing of the current path in the semiconductor layer stack results. Consequently, the lateral extension of an active zone is limited to [μm] dimensions, so that individually controllable μ-LEDs are separated from each other due to the localized recombination zone within the semiconductor layer stack. The pixel size of each μ-LED, which is defined as the maximum diagonal of the μ-LED backside, is <70 μm and preferably <20 μm and especially preferred <7 μm. Again, the preferred first light source contact is significantly smaller, whereby for advantageous embodiments the projection area of the first light source contact on the μ-LED backside occupies at most 25% and preferably at most 10% of the area of the μ-LED backside.

To limit the lateral expansion of the active zone, the first semiconductor layer and the second semiconductor layer are preferably configured with a p or n conductivity of less than 10⁴ Sm-1, preferably less than 3*10³ Sm-1, more preferably less than 103 Sm-1, so that the lateral expansion of the current path is limited. In addition, it is advantageous if the layer thickness of the first semiconductor layer in the stacking direction is at most ten times and preferably at most five times the maximum diagonal of the first light source contact in the lateral direction.

For further embodiment, a first light source contact on the monolithic pixelated optochip does not directly abut the associated IC substrate contact. Instead, the actual optochip contact element, whose cross-sectional area is larger than that of the first light source contact, lies below the first light source contact in relation to the stacking direction. This measure simplifies the positioning of the monolithic pixelated optochip on the IC substrate component and the mutual contacting without worsening the lateral limitation of the current path.

According to the invention, the area around the small first light source contact is used for the arrangement of a rear absorber, which reduces the optical crosstalk between adjacent μ-LEDs. In particular, the downwardly directed electromagnetic radiation emanating from the active zone at an angle is absorbed as long as a limit angle to the stacking direction is exceeded. Preferred materials for the rear absorber are structured layers with silicon, germanium and gallium arsenide. It is also possible to incorporate graphene or soot particles into the rear absorber.

The rear absorber laterally surrounds the first light source contact and extends laterally from it. Rear absorbers of adjacent μ-LEDs are adjacent to each other and are preferably made in one piece. For an embodiment, the rear absorber extends in stacking direction at least up to the first semiconductor layer. For a further embodiment, a partial section of the rear absorber runs within the correspondingly structured first semiconductor layer and shields the border region between adjacent μ-LEDs. For this purpose, additionally or alternatively reflective radiation blockers can be used, such as structured elements made of reflector materials, such as aluminum, gold or silver, or of dielectric materials whose refractive index is lower than that of the first semiconductor layer. For further embodiment, the rear absorber not only fulfils an optical function, but also serves as an electrical insulator to limit the current path laterally.

The display arrangement has a second light source contact for each μ-LED in the stacking direction above the second semiconductor layer. This contact is made of a transparent material such as indium tin oxide (ITO) and is electrically connected to a transparent, flat contact layer on the front side of the pixelated optochip. For an advantageous embodiment, the second light source contact is formed by the large-area contact layer itself, so that the entirety of the second light source contacts of the μ-LEDs arranged in matrix form can be applied as one common area contact. For an alternative embodiment which further reduces optical crosstalk, the second light source contact adjoins the contact layer in each case in a contacting manner, second light source contacts of adjacent μ-LEDs being separated from one another by an absorber on the front side in a lateral direction perpendicular to the stacking direction. The front absorber may consist of a material absorbing the electromagnetic radiation emitted by the active zone or of a material reflecting this radiation. In addition or alternatively, the front absorber can act as an electrical insulator and contribute to the lateral restriction of the current path for the localization of the recombination zone to an area with [μm] dimensions.

For a possible further embodiment, the front absorber extends against the stacking direction at least in a part of the second semiconductor layer. Furthermore, the lower and/or the upper sides of the second light source contact and/or the contact layer and/or the upper side of the second semiconductor layer may have an optically effective structuring to improve light extraction.

For a proposed method of manufacturing a display arrangement, an IC substrate component with monolithic integrated circuits and with IC substrate contacts arranged as a matrix is electrically conductively connected to a monolithic pixelated optochip.

For the preceding manufacturing of the monolithic pixelated optochip, a semiconductor layer sequence with a first semiconductor layer having a first doping and a second semiconductor layer having a second doping is grown preferably epitaxially, the polarity of the charge carriers in the first semiconductor layer differing from that of the second semiconductor layer and the semiconductor layer sequence defining a stacking direction. Furthermore, μ-LEDs arranged in the pixelated optochip as a matrix are applied, each μ-LED having a rear side facing the IC substrate component and a first light source contact which adjoins the first semiconductor layer in a contacting manner and is electrically conductively connected to a respective one of the IC substrate contacts. In accordance with the invention, the first light source contact is formed with such a size that its projection surface with a surface normal perpendicular to the stacking direction occupies at most half the surface of the rear side of the μ-LED. In addition, the first light source contact is surrounded by an absorber on the rear side in a lateral direction perpendicular to the stacking direction.

Besides the different concepts for driving and providing a redundancy circuit, another aspect is to connect the carrier with the μ-LEDs or the monolithic array with a carrier that contains the driving. There are concepts that try to realize both μ-LEDs and the IC circuits in the same material system. This is to be advocated per se and can be realized at least in parts. However, the material systems for μ-LEDs have disadvantages, so that they are only partially suitable for IC circuits.

Another aspect is to create different material systems for the generation of the driving circuits on one side and the μ-LEDs in a matrix arrangement on the other side. There are substantially two possibilities for this. Firstly, one material system can be started with and the components can be manufactured, then a transition to the other material system is created and in this the further components are provided. Supply lines through the material systems and connect the components. One difficulty with this approach is to select and set the different process parameters in such a way that it is possible to manufacture one “side” without damaging the other “side”. For example, the process temperature (e.g. for diffusion or implantation processes) is very different, so that depending on the temperature, no or undesired diffusion occurs. In this way, components can be damaged. In some aspects it is proposed to manufacture the control in one technology, for example on silicon basis, and then to grow different material systems as μ-rods or similar.

Another approach proposes to manufacture the control and pixel array separately and then connect them electrically and mechanically. In this way, the needs and requirements of the respective situation can be adapted and production can be optimized. Due to the small size of μ-LEDs, precise orientation for contacting is essential. The above example already illustrates this problem and suggests a solution. On the other hand, the use of digital control techniques allows reducing the number of necessary contact pads between the carriers without limiting the functionality. For the production of μ-displays or even display devices and matrices, novel digital and analogue concepts developed and jointly implemented.

One aspect of the design of a μ-LED display concerns the control of the light emission elements or μ-LEDs in a μ-display. The μ-Display thus has a plurality of μ-LEDs arranged in rows and columns. In some aspects, the μ-LEDs can be combined into subunits. This makes them easier to manufacture, test and process.

The limited space available under the actual matrix elements and pixels requires further considerations regarding addressing and control of the individual pixels. Conventional approaches and techniques may not be applicable due to the limited space. This may also apply to concepts where the current is controlled by each pixel.

In one embodiment a μ-display is provided, which has a plurality of pixel structure arranged in rows and columns. A first substrate structure is manufactured in a first material system and has a plurality of μ-LEDs whose edge length is 70 μm or less, in particular less than 20 μm. The μ-LEDs are individually addressable by lines in and/or on the first substrate structure. A large number of contacts are arranged on a surface of the first substrate structure facing away from the main radiation direction.

Furthermore, the μ-display has a second substrate structure, which comprises a plurality of digital circuits for addressing the μ-LEDs. The second substrate structure is manufactured in a different material system than the first substrate structure. The second substrate structure comprises on one surface a plurality of contacts corresponding to the contacts of the first substrate structure. According to the proposed principle, the first and second substrate structures are now mechanically and electrically connected to each other so that the contact areas correspond to each other. In accordance with this concept, it is proposed to manufacture digital and analogue elements of a display separately in different material systems and then to connect them with each other. This allows the optimal technology to be used in each case.

In this context, the first substrate structure with μ-LEDs can be configured as a monolithic module. In addition, the modular design revealed here can be used. Thus, the first substrate structure itself would be a carrier for the modules comprising the different μ-LEDs. The first substrate structure includes in some aspects the analogue circuits, for example a current source for each pixel. The redundancy circuits and driver circuits provided here are also conceivable. A design of these circuits in thin-film technology is possible, as long as the requirements for a current carrying capacity are not too high. If possible, it may be appropriate in some aspects to provide multiplexers or other circuits in the first substrate structure. This can reduce the number of contact areas between the first and second substrate structure. Simple switches, each selecting one of two μ-LEDs, reduce the number of necessary contact areas by about half. In other aspects, contacts may be grouped together, for example when using a common cathode layer for the μ-LEDs.

The μ-LEDs have an edge length of 20 μm or less. For particularly small μ-displays the edge length can be 2 μm to 5 μm. Depending on the embodiment, the contacts can be the same size as the μ-LEDs, but also smaller.

As far as material systems are concerned, the choice is flexible, with each technology and material system bringing its own advantages and challenges. The second substrate structure is based, among others, on monocrystalline, polycrystalline or amorphous silicon. To realize digital circuits in these material systems is well understood and can be scaled to small sizes. Likewise, indium-gallium-zinc-oxide, GaN or GaAs are suitable as material systems for the second substrate structure. As material system for the first substrate structure, at least one of the following compounds can be used: GaN, GaP, GaInP, InAlP, GaAlP, GaAlInP, GaAs or AlGaAs. One aspect can be the different thermal expansions and crystallographic parameters depending on the material systems used. Therefore, both substrate structures are often not bonded together directly, but via several intermediate layers.

The second substrate structure with the digital circuits, in addition to the supply lines, can also contain a variety of digital circuits to generate a PWM-like signal from a clock signal and a data word for each pixel. Furthermore, it is possible to implement series-connected shift registers whose respective length corresponds to the data word for one pixel, each shift register being connected to a buffer for intermediate storage.

For the already mentioned reduction of contact areas, the second substrate structure can comprise one or more multiplexers, which are electrically coupled to a demultiplexer in the first substrate structure for driving several μ-LEDs.

Besides display applications in the automotive and augmented reality sector, other Fields of application be developed.

For mechanical stabilization and/or electrical contacting, a μ-display should have a carrier on which the μ-LEDs of the μ-LED array are arranged. The carrier may include transparent material, for example in order not to impair the transparency of a transparent component equipped with the μ-LED or the μ-LED array. The carrier can be part of a display or can also be used for example in a vehicle component be integrated. A carrier surface can also form a surface of a component. In some aspects, a component of a vehicle itself can be designed as a carrier for the μ-LEDs or for the μ-LED array. The carrier can be of any shape, e.g. with a flat or curved carrier surface. For example, the shape of the carrier can be predetermined by the manufacturing process. For example, a carrier can be produced by a deep-drawing process in which the shape is predefined by a tool. The beam can be flexible or bendable. The carrier can also include a membrane, in particular a vibrating membrane, for example for generating acoustic effects. This allows the μ-LED array to be integrated into the surface of a component, even if this surface is not flat.

According to another aspect, for example, two non-monolithic μ-LED arrays of a μ-display can be arranged on top of each other or one behind the other. Here the upper or front μ-LED array can have a transparent carrier so that light from the lower or rear μ-LED array can pass through the transparent carrier. In this way, the μ-displays can create a three-dimensional visual effect (3D effect).

One aspect in this respect concerns the implementation with sensors in a μ-LED array or in a μ-display to provide further functionality. The sensor(s) is/are arranged, for example, on the carrier of the μ-display or μ-LED array in a space between the μ-LEDs. This disclosure shows several examples of such an implementation. Similar to the μ-LEDs, the sensors can be supplied with electrical energy via conductor tracks and electrical contacts arranged on the carrier. The information or data detected by the sensors can, for example, be transmitted to a receiver wirelessly or via data lines arranged on the carrier. Sensors can be brightness sensors, proximity sensors, distance sensors or/and touch sensors integrated in the μ-LED array. By means of brightness sensors arranged on the μ-displays, for example, the brightness or the switching on and off of the μ-LEDs of the μ-LED array can be automatically controlled or regulated depending on the ambient light or an ambient brightness.

By means of proximity sensors arranged on the μ-display, it is possible, for example, to detect the approach of a person or the hand of a person to the μ-LED array or to a device containing the μ-LED array, and to automatically switch the μ-LED array or said device containing the μ-LED array on or off again when the person or the hand of the person moves away. In this way, for example, a display device equipped with the μ-LED array can be automatically activated or deactivated or controls equipped with at least one μ-LED array containing a proximity sensor can be automatically illuminated and activated or deactivated.

In addition, the sensors allow eye tracking, for example by measuring the reflection of the back of the eye or a light beam reflected from parts of the eye. Eye tracking makes focusing possible, i.e. an optical system can place information displayed by the μ-display on the central visual area of the eye. On the other hand, the distance between the displays and the eye can be measured and the image sharpness adjusted accordingly.

By means of touch sensors, which are arranged on the μ-LED array, a display device or operating elements, which have the aforementioned μ-LED array, can be operated or controlled by a user in the manner of a touch screen.

By means of distance sensors arranged on the μ-LED array it is possible, for example, to detect and monitor the distance of an object or a person to the aforementioned μ-LED array or to a device comprising the aforementioned μ-LED array, in order to display information or warnings, for example, as a function of a detected distance.

The μ-LED array can also be equipped with any combination of one or more proximity sensors, brightness sensors and touch sensors as well as distance sensors to enable a desired function or application according to customer requirements.

One aspect concerns a surface topography recognition system with an optoelectronic component comprising at least one μ-LED, which emits electromagnetic radiation via a light exit surface. A photonic structure is also provided for beam shaping of the electromagnetic radiation before it emerges via the light exit surface, wherein the photonic structure shapes the electromagnetic radiation in such a way that the electromagnetic radiation has a specific far field. The photonic structure is a two-dimensional photonic structure, in particular a two-dimensional photonic crystal, which is designed such that the electromagnetic radiation produces a defined, in particular a discrete, pattern in the far field. The surface topography detection system now further comprises a detection unit, in particular with a camera, which is configured to detect the pattern in the far field.

The surface topography detection system may include analysis equipment configured to detect pattern distortion with respect to a predetermined reference pattern.

The analyser may be configured to determine a shape and/or structure of an object illuminated by the pattern depending on the distortion detected.

A further application also concerns a scanner for scanning an object, the scanner having at least one optoelectronic component with a μ-LED and a photonic structure determining the far field, which can preferably be used for line-by-line detection of the object.

According to another point of view, one μ-LED array or a plurality thereof may be configured as part of a rear lamp of a motor vehicle. The combination rear lamp may include at least one array of light-emitting μ-LEDs forming a pixel density of at least 50 PPI and having a pixel pitch of at most 0.5 mm. The combination rear lamp may be configured as a combined tail and stop lamp and may have a tail light area and a stop light area.

According to another aspect, the stop light area and the tail light area may each have at least one array of μ-LEDs, wherein the pixel density of the array of μ-LEDs in the stop light area is higher than the pixel density of the array of light emitting diodes in the tail light area. According to an aspect, the device can be configured as a raised brake light of a motor vehicle. The raised brake light can be embedded in a rear window pane of a motor vehicle or also be arranged in the roof area of the body of a motor vehicle. It may be transparent.

The pixel density of such a stop lamp with an array of μ-LEDs may be at least 10 PPI and the pixel pitch may be at most 2.5 mm. It is possible to regard one μ-LED array of the lamps described here as a single light emitting diode and thus to design the lamp from several such μ-LED arrays. Each μ-LED array can be controlled individually.

According to an aspect, the device may include a μ-display located on the outside of a motor vehicle. This allows information to be transmitted to people outside the vehicle, thus increasing safety for all road users. According to an aspect of the invention, the pixel density of the array of light emitting diodes of the display may be at least 100 PPI and the pixel pitch may be at most 0.25 mm and additionally be integrated into the vehicle body. According to an aspect, the shape of the display may be adapted to a contour of the vehicle body.

According to another aspect, a control device for the display may be provided, which allows the display operation to be controlled by a user or a computer program. In addition, at least one sensor or detector may be provided in such a way that the display of the display is controlled by the control device in dependence on measurement signals of the at least one sensor or detector. In addition or optionally, the control device for the display may include a communication interface so that information or control signals can be transmitted to the display. Similarly, for example, statuses or operating parameters may be transmitted from the display to external devices via the communication interface. In the case of a motor vehicle, the control device may be configured to receive information outside the motor vehicle.

In another aspect, the control device has a recording device or can receive information and data from such a recording device. The recording device may be designed as a unit for detecting the vehicle environment. The recording device may be configured to detect moving and/or non-moving obstacles. In particular, the recording device may be configured to detect persons, roadways, traffic signs or other road users. The detection system may comprise a radiation emitter with a radiation receiver. The recording equipment may include a camera to record visible or invisible light. According to an aspect, the camera system or recording equipment may be located outside and/or inside the vehicle.

According to an aspect, the camera system located outside can be directed both outwards and inwards. Outward facing means that the camera system can pick up light (electromagnetic radiation in the visible or non-visible range) that radiates into the camera system from outside the vehicle. Inward facing may mean that the camera system receives light radiating from inside the vehicle. Alternatively, the camera system may be located inside the vehicle. The camera system so positioned must be directed both outwards and inwards. Outward facing means that the camera system can receive light (electromagnetic radiation in the visible or non-visible range) radiating into the camera system from outside the vehicle. Inward facing may mean that the camera system receives light radiating from inside the vehicle.

According to an aspect, the recording equipment, in particular the camera system, can reproduce the function of mirrors on the vehicle. According to an aspect, the mirrors may be exterior mirrors and/or rear-view mirrors of the vehicle. According to an aspect, the camera system may be located inside and/or outside the vehicle. The recording device may be configured to cover the whole of the vehicle's environment or only a predefined part of the vehicle's environment. For example, the recording device may be designed to record a front area and/or a rear area of the vehicle. In particular, the recording equipment may be designed to cover an area of the vehicle, which is not visible to the driver. For example, an area not visible to the driver from his point of view may be located behind the A, B, C or D pillars of the vehicle.

A frontal area, in the sense of the present disclosure, is the area of the vehicle, which is ahead of the typical main direction of travel. The frontal area of the vehicle is substantially the area that appears to the driver when looking through the windscreen of the vehicle. A rear area, for the purposes of this disclosure, is the area of the vehicle, which lies behind the typical main direction of travel. The rear area of the vehicle is substantially in the area, which appears to the driver when looking through the rear window of the vehicle.

According to an aspect, the recording device may include a touch-sensitive panel. The touch-sensitive panel may preferably be located inside the vehicle. The touch-sensitive panel may also be located outside the vehicle. According to an aspect, the receiving device may be integrated and/or combined with an output device. Similarly, the receiving device and an output device may be integrated and/or combined on one panel.

Another aspect concerns the control device. The control unit is set up for the transmission and processing of signals or information. According to an aspect, the control device receives signals or information from the receiving device, processes them and passes the processed signals or information to an output device. The signals or information can, for example, include general information on the vehicle status. The signals or information can, for example, comprise information from the vehicle environment, from the vehicle interior, information about the driver or persons inside the vehicle, persons outside the vehicle or information about possible obstacles or indications from the vehicle environment.

According to an aspect, the control device comprises one or more computing units. The arithmetic units can be set up in such a way that they collect, evaluate and process the signals received from the recording device. The control device may be part of an on-board computer of the vehicle. The on-board computer may be set up to process information from the vehicle, which is read in/fed in outside the recording device. According to an aspect, the control device or at least part of it is located outside the vehicle. For example, part of the control equipment may be arranged in a cloud. The part of the control device remaining in the vehicle may be connected to the cloud by a wireless connection. The cloud can be set up to collect information, evaluate and process it and then send it back to the vehicle, in particular to an output device inside or outside the vehicle concerned. According to an aspect, the control device may be located in or on the recording device. According to an aspect, parts of the control device may be arranged in or on the recording device and/or in or on the output device and/or inside and/or outside the vehicle.

Another aspect concerns an output device. The output device is set up to output information in a predetermined way. For this purpose, the output device can comprise one or more display units (in the following referred to as screen, display and/or display or display unit and/or display board). The display unit may have different predefined characteristics. In particular, the display unit may have a predefined size, shape, resolution (pixel density or pixel pitch) and/or contrast ratio (also called “dynamic ratio” or “dynamic range”).

According to an aspect, the display unit can be arranged directly or indirectly on components. This means that the display unit can include components, in particular vehicle components. According to an aspect, the display unit can be configured as a part of this component. According to an aspect, the display unit can form a component, in particular a vehicle component. For examples of the properties, please refer to the explanations in this disclosure for the various applications in the table.

According to an aspect, the display unit may comprise one or more displays (also called screen, display or scoreboard). The displays can have different predetermined characteristics. The characteristics of the displays may include size, shape, resolution and/or contrast ratio. The displays may be arranged directly/indirectly on components. This means that the displays may include components, in particular vehicle components, and may thereby form part of those components. According to an aspect, the display unit may be designed, for example, as a headliner, centre console, display in a pillar, as a pillar itself and/or as a vehicle status display.

The application examples shown here, especially in a motor vehicle, require partially curved or at least non-planar and straight surfaces. Therefore, it seems appropriate to use the manufacturing techniques and components or structures disclosed in this application to manufacture curved displays.

According to at least embodiment, the display device comprises a carrier with a front side and a backside. The carrier is preferably continuous and/or in one piece. The support may comprise or consist of glass or plastic or metal. In particular, the support is self-supporting. The support is preferably stiff, i.e. it cannot be bent or can only be bent slightly.

The front and back are opposite sides of the carrier. For example, an average thickness of the support, measured from the front side to the backside, is at least 1 mm or at least 5 mm or at least 10 mm. For example, an area of the front side is at least 1 cm² or at least 10 cm² or at least 100 cm² or at least 500 cm². Alternatively or in addition, the area of the front face may be no more than 5 m² or no more than 1 m² or no more than 3000 cm².

In some aspects, the display device comprises a self-supporting display segment applied to the front of the carrier. The display segment is preferably mounted on the carrier. For example, the display segment is glued or plugged onto the front of the carrier. The display segment is especially but not exclusively manufactured on the carrier. Rather, the display segment is a component that is manufactured separately from the carrier and is only attached to the carrier after the carrier and the display segment have been completed.

The term ‘self-supporting’ means in the present case that an element is mechanically stable even without being supported by the support or by any other support, which is not part of the element. The element is therefore self-supporting and self-stabilising. For this purpose, the materials of the element and/or the thickness to expansion ratio can be chosen accordingly. For example, the self-supporting element can be gripped by a gripping tool at a corner or edge of the element and transported without any other stabilizing component by the gripping tool alone. The element is not broken or destroyed in the process. However, it can bend or bend itself. For example, a self-supporting element is transported vertically in order to avoid very severe bending during transport.

According to at least one embodiment, the display segment comprises a substrate with an electrically conductive connection layer and an electrically insulating layer as well as at least one optoelectronic component.

The substrate is preferably the stabilizing component of the display segment. The substrate has a top side and a bottom side. For example, a maximum lateral expansion of the substrate, measured along the top surface, is at least 1 cm or at least 5 cm or at least 10 cm. Alternatively or additionally, the maximum lateral expansion of the substrate may be at most 50 cm or at most 30 cm or at most 15 cm. For example, an average thickness of the substrate measured between the top surface and the bottom surface is at least 30 μm or at least 100 μm or at least 500 μm or at least 1 mm.

The electrically conductive connection layer comprises, for example, a dielectric layer, for example of SiO₂, in which metal structures, for example of Al, Au, Cu or Mo, are embedded. The connection layer comprises for example a switching structure, for example with a thin-film circuit. The connection layer can comprise one or more thin-film transistors. In particular, the junction layer can be produced or manufactured by means of a TFT manufacturing process. For example, the connection layer has a thickness between 50 nm and 1 μm.

The electrically insulating layer comprises or consists, for example, of an organic material, such as a polyimide or polyester or polyurethane or glass. The electrically insulating layer can be formed in one piece. The electrically insulating layer can be a foil. The connection layer can be produced on the electrically insulating layer, for example in a TFT process. For example, the thickness of the electrically insulating layer is at least 10 μm or at least 50 μm or at least 100 μm. In particular, the electrically insulating layer forms a component that stabilizes the display segment. Preferably, the electrically insulating layer extends over the entire lateral extent of the display segment. A side of the electrically insulating layer facing the connection layer can be completely covered by the connection layer.

The optoelectronic component is especially configured to emit or absorb electromagnetic radiation, preferably visible light. In particular, the optoelectronic component includes a μ-LED. The semiconductor chip is based, for example, on a nitride compound semiconductor material. The optoelectronic component is arranged and fixed on the upper side of the substrate. A maximum lateral expansion of the optoelectronic device is smaller, for example by a factor of at least 10 or at least 100, than the maximum lateral expansion of the substrate.

According to one possible aspect, the optoelectronic component is arranged on the connection layer and electrically conductively connected to the connection layer. The optoelectronic component can be energized and controlled via the connection layer.

According to at least one embodiment, the electrically insulating layer is arranged on a side of the connecting layer facing away from the optoelectronic component and between the substrate and the connecting layer. For example, the electrically insulating layer forms the underside of the substrate. In particular, the side of the electrically insulating layer facing away from the connection layer forms an outer side of the display segment when unmounted. The electrically insulating layer can be in direct contact with the front side of the carrier.

In a further aspect, the electrically insulating layer is simply cohesive. This means that the electrically insulating layer is free of holes or vias extending through the electrically insulating layer within the manufacturing tolerance. The electrically insulating layer preferably extends continuously and without interruptions over the entire lateral extent of the display segment. Preferably, a side of the electrically insulating layer facing away from the connection layer is free of electrical wires. In particular, there are no electrical leads between the support and the electrically insulating layer.

According to some aspects, the carrier includes at least one opening that extends from the front to the back. The opening is a hole in the carrier that passes completely through the carrier. In plan view of the front side, the opening is completely surrounded by a continuous web of the carrier. For example, the display segment is arranged on the front side in such a way that it does not cover the opening or only partially or completely covers it.

According to another aspect, the display segment can be electrically contacted from the back of the carrier via an electrical lead that extends through the opening. This means that an electrical lead extends through the opening from the front to the back and is electrically connected to the display segment. When the display device is operated as intended, a current flows from the rear through the opening to the optoelectronic component. In particular, the electrical lead is electrically connected to the terminal layer of the display segment.

In one aspect, the display device comprises a carrier with a front and a back and a self-supporting display segment applied to the front of the carrier. The display segment comprises a substrate with an electrically conductive connection layer and an electrically insulating layer and at least one optoelectronic component. The optoelectronic component is arranged on the connecting layer and is electrically conductively connected to the connecting layer. The electrically insulating layer is arranged on a side of the connecting layer remote from the optoelectronic component and between the substrate and the connecting layer. The electrically insulating layer is formed as a single continuous layer. The carrier comprises an opening extending from the front to the back. The display segment can be electrically contacted from the rear side of the carrier via an electrical lead conductor that extends through the opening.

The present concept is based, among other things, on the idea of providing a display device in which the display segment itself has no vias that pass through the substrate of the display segment. This means that the substrate of the display segment has conductive structures on only one side, namely only in the area of the connection layer. Such display segments can be manufactured at low cost and can be configured to be flexible or bendable. This is advantageous if the substrate has a curved front side or a free form, as is desired in some display applications, for example.

Such display segments without vias must be electrically contacted on the carrier, especially from the back of the carrier. In the present invention, this is solved by the fact that the carrier has an opening through which an electrical lead extends by means of which the display segment can be electrically contacted. In this case, through-connections in the display segment are not necessary.

According to some aspects and embodiments, the display segment, especially the substrate of the display segment, is configured to be flexible or bendable. This preferably refers to reversible pliability. For example, the display segment can be reversibly bent back and forth between a state with a substantially flat top surface of the substrate and a state with a curved top surface of the substrate, in which case a radius of curvature of the top surface is, for example, less than 1 m or less than 10 cm or less than 1 cm.

According to at least one embodiment, the front of the carrier has a concave and/or convex curvature where the display segment is applied. For example, a radius of curvature of the front side in this area is less than 5 m or less than 1 m or less than 50 cm.

In another aspect, the electrical conduction is formed by a tab of the substrate, with the tab being inserted through the opening. The tab is preferably a part of the substrate, which is reversibly bendable with respect to the rest of the substrate. For example, a radius of curvature in the region between the tab and the rest of the substrate can be set to a value of less than 5 cm or less than 1 cm or less than 1 mm or less than 0.1 mm without the substrate breaking or cracking between the tab and the rest of the substrate. For example, the tab includes a portion of the terminal layer, thereby forming an electrical conductor.

The average thickness of the substrate in the area of the tab preferably deviates by less than 10% from the average thickness of the rest of the substrate. In particular, the tab includes a portion of the electrically insulating layer. The tab preferably protrudes completely through the opening of the substrate. Part of the tab may protrude out of the opening at the rear. For example, this part protrudes at least 0.5 cm or at least 1 cm from the opening.

In accordance with other aspects, an active or passive electronic component is arranged on the part of the tab that protrudes on the back and is electrically connected to the substrate. In particular, the active or passive electronic component is electrically conductively connected to the optoelectronic component via the connection layer. The component serves, for example, as a driver for the display segment. The electronic component can be a semiconductor chip, for example an IC chip, or a control element for the optoelectronic component. Like the optoelectronic component, the electronic component is preferably located on the top side of the substrate. Alternatively or additionally, such an electronic component may also be located on the substrate and on the same side of the carrier as the optoelectronic component.

The substrate of the display segment can at least partially cover the opening in the carrier. The electrically insulating layer is partially or completely removed in the area of the opening and the electrical lead is led to the connecting layer in the area of the opening and electrically connected to the connecting layer. In particular, in the area of the opening, the electrically insulating layer is removed from the substrate to such an extent that the connection layer is accessible on a side facing away from the upper side of the substrate.

The electrical conduction can then be formed, for example, by an electrically conductive layer, such as a metal layer or a sintering/conducting paste, for example of Ag, which is in electrical contact with the connecting layer. Starting from the connecting layer, the electrically conductive layer can be guided in a form-fit manner over sidewalls of the opening to the back of the carrier. An insulating layer may be placed between the electrically conductive layer and the carrier. In this case, preferably no part of the substrate is inserted through the opening.

According to another aspect, the display segment comprises a plurality of μ-LEDs, each μ-LED or triple of μ-LEDs being associated, in particular uniquely associated, with a pixel or pixels of the display segment. For example, the optoelectronic components are arranged on the substrate in a regular pattern, for example a rectangular pattern. Each of the optoelectronic components may be controlled individually and independently of the other optoelectronic components. Each component can thus be used to realize a pixel or pixels of a display or a subpixel. All features previously disclosed in connection with an optoelectronic component can also apply to all other optoelectronic components of a display segment.

According to at least one embodiment, the display device comprises a plurality of display segments applied to the front of the carrier. The display segments can be arranged almost seamlessly side by side. Each display segment can be assigned to an opening of the carrier, in particular, it can be assigned uniquely. All features described so far for one display segment can also apply to all other display segments. In particular, the display segments are adjoined to each other on the front of the carrier. The distance between two adjacent optoelectronic components of a common display segment preferably deviates imperceptibly, for example by a maximum of 10%, from the distance between two optoelectronic components of two adjacent display segments.

A display device with a single support and with one or more display segments mounted thereon may be used as a display, for example in a vehicle. However, it is also conceivable that the display device comprises a plurality of carriers, each comprising one or more display segments mounted thereon. The individual carriers may be arranged next to each other and may be mechanically connected, for example by a frame. In this way, for example, a large video screen with dimensions of more than 1 m and up to 10 m can be realized.

In addition, a method for manufacturing a display device is proposed. The method is particularly suitable for manufacturing a display device as described above. All features disclosed in connection with the display device are therefore also disclosed for the process and vice versa.

According to at least one embodiment, the method comprises a step A) in which a carrier is provided with a front side, a back side and at least one opening extending from the front side to the back side. In a step B) a self-supporting display segment is provided. The display segment comprises a substrate with an electrically conductive connection layer and a single cohesive, electrically insulating layer and at least one optoelectronic component. The optoelectronic component is arranged on the connection layer and is electrically conductively connected to the connection layer. The electrically insulating layer is arranged on a side of the connection layer facing away from the component. In step C) the display segment is applied to the front of the carrier. In a step D), an electrical lead is formed which extends through the opening so that the display segment can be electrically contacted from the back of the carrier via the electrical lead.

Steps A) to D) are preferably carried out in the specified order and one after the other.

According to at least one embodiment, the substrate comprises a tab which is inserted through the opening in step D) and which forms the electrical lead.

According to at least one embodiment, the display segment is arranged in step C) so that the electrically insulating layer at least partially covers the opening. In step D), the electrically insulating layer is removed in the area of the opening, for example by laser ablation, and then the electrical lead in the area of the opening is led to the connecting layer and electrically connected to the connecting layer. For example, an electrically conductive layer in the area of the opening is formed as an electrical lead, for example by jetting. Prior to this, an insulating layer can be applied to the carrier in the area of the opening as electrical insulation between the carrier and the electrical lead.

### BRIEF DESCRIPTION OF THE DRAWINGS

In the following section, some of the above-mentioned and summarized aspects are explained in more detail using various explanations and examples.

FIG. 1A shows a diagram illustrating some requirements for so-called μ-displays or micro-displays of different sizes with respect to the field of view and pixel pitch of the μ-display;

FIG. 1B shows a diagram of the spatial distribution of rods and cones in the human eye;

FIG. 1C shows a diagram of the perceptual capacity of the human eye with assigned projection areas;

FIG. 1D is a figure showing the sensitivity of the rods and cones over the wavelength;

FIG. 2A is a diagram illustrating some requirements for micro-displays of different sizes in terms of the field of view and the angle of collimation of a pixel of the μ-display;

FIG. 2B illustrates an exemplary execution of a pixel arrangement to illustrate the parameters used in FIGS. 1A and 2A;

FIG. 3A shows a diagram illustrating the number of pixels required depending on the field of view for a specific resolution;

FIG. 3B is a table of preferred applications for μ-LED arrays;

FIG. 4A shows a principle representation of a μ-LED display with essential elements for light generation and light guidance;

FIG. 4B shows a schematic representation of a μ-LED array with similar μ-LEDs;

FIG. 4C is a schematic representation of a μ-LED array with μ-LEDs of different light colors;

FIG. 5A and FIG. 5B show two examples of a structure or beamline and collimation;

FIG. 6 illustrates an example of a slotted antenna according to the proposed principle;

FIGS. 7A to 7C illustrate an example of light-emitting devices based on the proposed principle that are capable of producing light of different colors;

FIGS. 8A to 8F show various examples of a slotted antenna realized in a semiconductor material for light emission;

FIG. 9 illustrates the radiation pattern for a simple example of a slotted antenna according to FIG. 8A;

FIG. 10 shows two exemplary versions of a slotted antenna with additional optics arranged on the emission surface;

FIG. 11 shows another example of a slotted antenna to produce light of a defined color;

FIGS. 12 to 19 show a step in the production of a pixel from pairs of μ-LEDs in bar form with a converter layer between the pairs in representation of a cross section;

FIG. 20 illustrates a step of a first contacting of a proposed pixel with pairs of μ-LEDs in a top view;

FIG. 21 shows the step of first contacting a proposed pixel in a longitudinal section according to some aspects of the proposed concept;

FIG. 22 represents a step of a second contacting of a proposed pixel in a cross-sectional view according to some aspects of the proposed concept;

FIG. 23 shows the step of the second contacting of a proposed electronic component in a longitudinal section;

FIG. 24 shows the step to create a pixel after the previous figure in a cross-sectional view;

FIG. 25A is an embodiment of a pixel with an arranged light-shaping structure and different control options according to some aspects of this disclosure;

FIG. 25B shows a top view of the photonic structure.

FIG. 25C shows another top view of different ways to position subpixels of different pixels, according to some aspects of FIG. 25A;

FIG. 26 is an embodiment example of a μ-rod as starting material for the production of an optoelectronic device, in particular a μ-LED;

FIG. 27A shows an example of a μ-LED with a μ-rod structure aligned horizontally to the carrier;

FIG. 27B shows another embodiment example where the contacting is done on a bottom side of the μ-rod;

FIGS. 28 to 37 illustrate an embodiment example of a proposed process for manufacturing a group of three μ-LEDs aligned and contacted horizontally to the carrier according to the proposed principle;

FIG. 38 shows another embodiment example of a horizontally oriented μ-rod according to some aspects in a longitudinal section;

FIG. 39 illustrates a further embodiment example of a proposed group of three μ-LEDs with a converter layer on top of it according to some aspects explained;

FIG. 40 shows another example of a group with three horizontally aligned μ-rods and a reflective layer on the carrier;

FIG. 41A shows a top view of a pixel array with three horizontally aligned μ-rods that are suitable for emitting light at different wavelengths;

FIG. 41B is the side view of the embodiment of the previous figure;

FIG. 42 illustrates another embodiment example based on some suggested aspects of a group of three aligned μ-rods, each forming a μ-LED in a top view;

FIG. 43 shows a further embodiment example of a proposed group with three μ-rods in cross-section, which are configured to emit light of different wavelengths due to their different geometry;

FIG. 44 illustrates the embodiment example of a group of three proposed μ-rods as an electron microscope image in a perspective view;

FIG. 45 shows a representation of emitted wavelengths of an embodiment example of a group of three proposed μ-rods;

FIG. 46 illustrates another example of an embodiment example of a group of three proposed μ-rods in a cross-section, which together form a pixel;

FIGS. 47A to 47D show an embodiment of a manufacturing process for a μ-LED, which is grown on a predefined molded layer of the carrier substrate;

FIG. 48 illustrates a completed version of a μ-LED according to the proposed principle;

FIG. 49 shows a second version of a μ-LED grown on a predefined molded layer of the carrier substrate and shows some more aspects;

FIG. 50 is a first contour of the molded layer for the production of a μ-LED according to some aspects of the proposed concept;

FIG. 51 shows an embodiment of a second contour of the mold layer for the production of a μ-LED;

FIG. 52 shows a third embodiment of a μ-LED grown on a molded layer with some of the proposed aspects;

FIG. 53 is a fourth embodiment of a μ-LED epitaxially generated on a molded layer with a defined orientation of the carrier;

FIGS. 54A to 54B show a fifth embodiment of a μ-LED with some of the proposed aspects and an intermediate manufacturing step;

FIG. 54C shows a fourth embodiment of a μ-LED with an additionally attached photonic crystal structure and a contact for electrical contact to a control circuit;

FIG. 54D shows an alternative embodiment, in which the photonic structure is arranged on the back;

FIG. 54E shows another embodiment with photonic structure and converter material;

FIGS. 55A to 55E illustrate a embodiment with different process steps for producing quantum well intermixing in an active layer of a semiconductor body outside a region intended for light emission according to some aspects of the proposed concept;

FIG. 56 shows the progression of various process parameters during a procedure according to the proposed principle;

FIG. 57 is a diagram showing the course of a relative luminous intensity over time to illustrate a reduction in luminous intensity in optoelectronic components;

FIGS. 58A to 58F show an embodiment with different process steps for fabricating a semiconductor structure using quantum well intermixing according to some aspects of the concept presented;

FIG. 59 shows an exemplary course of various process parameters during a procedure according to the proposed principle;

FIG. 60 shows a section of a semiconductor structure to explain various aspects of the concept presented;

FIG. 61 is a diagram illustrating the barrier height as a function of the operating current at different doping levels to explain the concept presented;

FIG. 62 is another diagram illustrating the quantum efficiency at different barrier heights to explain the concept presented;

FIG. 63 shows a square μ-LED structure and corresponding cross-sectional profile of the dopant concentration to derive the proposed concept;

FIG. 64 shows a top view of an optoelectronic component semiconductor structure with a corresponding cross-sectional profile of the dopant concentration according to some aspects of the proposed principle;

FIG. 65A to 65C shows different steps of a layered structure and thus a manufacturing process of the optoelectronic component under consideration of the proposed concept;

FIG. 66 is a representation of the band gap of the optoelectronic component according to the proposed concept;

FIGS. 67A and 67B each illustrate a top view of a first version of a semiconductor structure suitable for light emission and associated cross-sectional profiles of the band gap of the semiconductor structure according to some aspects of the concept presented;

FIGS. 68A and 68B show a top view of a further embodiment of a semiconductor structure suitable for light emission with associated cross-sectional profiles of the band gap according to some aspects of the proposed concept;

FIGS. 69A and 69B are a top view of a third embodiment based on some aspects of the proposed concept with associated cross-sectional profiles of the band gap;

FIGS. 70A and 70B show a top view of a fourth embodiment of the semiconductor structure and associated cross-sectional profiles of the band gap of the semiconductor structures as realized in various aspects;

FIGS. 71A to 71C illustrate a layered structure and a process for the manufacture of one or more optoelectronic components, in particular μ-LEDs, according to some aspects of the concept presented;

FIG. 72 is a representation of the band gap of the semiconductor structure according to the proposed concept;

FIG. 73 illustrates an embodiment of a conventional optoelectronic component, for example an LED;

FIG. 74 is a longitudinal section of a first embodiment of an optoelectronic device or μ-LED with a current constriction according to some aspects of the presented concept;

FIG. 75 shows a top view cross-section of the first embodiment of the μ-LED;

FIG. 76 shows a representation of the mode of operation of the first embodiment;

FIG. 77 illustrates a longitudinal section of a second embodiment of a μ-LED with magnetic elements for current constriction;

FIG. 78 shows a top view cross-section of the second embodiment of the μ-LED;

FIG. 79 shows a longitudinal section of a third embodiment of a μ-LED with further aspects of current constriction;

FIG. 80 shows a cross-sectional view of the third embodiment of the μ-LED;

FIG. 81 illustrates a longitudinal section of a fourth embodiment of an optoelectronic device or μ-LED according to some aspects of the proposed concept;

FIG. 82 shows an embodiment of a proposed process for manufacturing a μ-LED with current constriction;

FIG. 83 shows different steps of an execution example of a proposed process for the production of a μ-LED with a circumferential reflector structure;

FIG. 84 shows a first embodiment of an array of two μ-LEDs with an intermediate reflector structure in cross-section according to some aspects of the proposed concept;

FIG. 85 illustrates a part of the first embodiment of the μ-LED according to the proposed principle as top view;

FIG. 86 shows a second embodiment of a proposed array in cross-section with a reflector structure in between;

FIG. 87 is a cross-sectional view of the first embodiment of the proposed electrically contacted μ-LED;

FIG. 88 illustrates further aspects of the proposed concept in a third embodiment of a proposed array in cross-section;

FIG. 89 shows a fourth embodiment of a proposed array in cross-section;

FIG. 90 is an embodiment with several suggested arrays in a top view to illustrate further aspects;

FIG. 91 shows another embodiment of a proposed array in a top view;

FIGS. 92 to 94 show various embodiments of a μ-LED in cross-section, arranged in a proposed array;

FIG. 95 shows the embodiments of FIGS. 93 and 94 as top view;

FIG. 96 shows a section of a μ-display with several μ-LEDs and a transparent contact layer formed as a common cathode in top view to explain some aspects;

FIGS. 97A and 97B illustrate some pixel elements with μ-LEDs and contact layer and two tracks according to some aspects of the proposed concept;

FIG. 98A shows a section with several pixel elements with μ-LEDs, conductor structures for anode and cathode, and μ-LEDs with beam-shaping elements in top view;

FIG. 98B shows a further complementary arrangement of the embodiment of the previous figure;

FIG. 99 is a plan view of a section of a μ-display with pixel elements with a contact layer and recesses in the area of the μ-LEDs according to some aspects of the proposed concept;

FIG. 100A shows a vertical sectional view through a pixel element with a μ-LED, traces and radiation areas as shown in FIG. 99 to illustrate further aspects;

FIG. 100B is an alternative embodiment for limiting the radiation area of a μ-LED;

FIG. 101A shows a vertical sectional view through a pixel element with three μ-LEDs and transparent cover electrode according to some aspects;

FIG. 101B shows a 90 degree rotated vertical sectional view of a pixel element with a trace according to some aspects of the presented concept;

FIG. 101C is an embodiment of a pixel in vertical sectional view with a conductor lead below a stepped contact layer;

FIG. 101D shows a pixel in vertical sectional view with a conductor lead below a plane contact layer;

FIG. 101E shows an embodiment with two pixel elements in vertical sectional view with a conductor lead on the carrier substrate;

FIG. 101F shows a pixel element in vertical sectional view with three μ-LEDs, arranged in cavities of the carrier substrate in a planar arrangement according to some aspects;

FIG. 101G is a pixel in vertical sectional view with three μ-LEDs arranged in cavities of the carrier substrate with raised interstitial walls;

FIG. 101H represents a complementary execution of a pixel to the previous figure, in which a remaining space within the cavity is filled with converter material.

FIGS. 102A to 102C show different arrangements of μ-LEDs on a carrier substrate and reflection behaviour of emitted light on sidewalls of cavities according to some aspects of the presented principle;

FIG. 103A illustrates a representation of a pixel of three vertical μ-LEDs with a circumferential structure and a cover electrode according to some aspects of the proposed concept;

FIG. 103B shows another embodiment similar to FIG. 103A with additional converters and light extraction structures, thus realizing further aspects of this disclosure;

FIG. 104 shows a top view of the device of the previous figure;

FIG. 105 shows a cross-section of a section of an array with several pixels and a cover electrode;

FIG. 106 is a second embodiment of a pixel with several μ-LEDs and a transparent cover electrode according to further aspects of the proposed principle;

FIG. 107 shows a top view of the embodiment of the previous figure;

FIG. 108 illustrates a third embodiment of a pixel in cross-sectional view;

FIG. 109 shows a top view of the embodiment of the previous figure;

FIG. 110 shows another illustration of an embodiment of a pixel according to the proposed concept;

FIG. 111 is a top view of the embodiment of the previous figure;

FIG. 112 is a process sequence with various steps for producing a pixel according to the proposed principle;

FIG. 113 shows a first embodiment of a μ-LED arrangement with nanocolumns according to some proposed aspects in a lateral sectional view;

FIG. 114 shows the first embodiment of the arrangement of the previous figure in plan view;

FIGS. 115A to 115H show various aspects of making the first embodiment of the arrangement according to some suggested aspects;

FIGS. 116A to 116D illustrate various aspects of a process for producing a second embodiment of the arrangement according to some suggested aspects;

FIGS. 117A to 117D show different steps for a process according to some further aspects to produce a third embodiment of the arrangement;

FIG. 118 is a fourth embodiment of the nano light emitting diode array with some of the proposed aspects;

FIGS. 119A and 119B illustrate supplementary versions of the embodiment of FIG. 116D, where additional supplementary measures are arranged.

FIG. 120 shows a cross-sectional view of an optoelectronic device, such as a display array, with a plurality of optoelectronic devices of the invention according to some aspects;

FIG. 121 is a cross-sectional view of another optoelectronic device with a large number of optoelectronic devices configured as μ-LEDs according to the proposed concept;

FIG. 122 shows a cross-sectional view for another proposal of a monolithic array with a variety of optoelectronic devices;

FIG. 123 shows a cross-sectional view of another monolithic array with a plurality of optoelectronic devices configured as μ-LEDs; and

FIG. 124 illustrates, based on the example of the previous structure, a monolithic array with a light-shaping structure;

FIG. 125 is a cross-sectional view of a dielectric reflector;

FIG. 126 shows an example of an optoelectronic device with an LED semiconductor element and a dielectric filter according to some aspects of the proposed principle;

FIGS. 127A and 127B are representations of an embodiment of an optoelectronic device having an array of a plurality of semiconductor elements; and

FIGS. 128A to 128C are illustrations of another embodiment of an optoelectronic device with several μ-LEDs according to some aspects;

FIGS. 129A and 129B each show a respective embodiment with aspects of magnetic current confinement in a cross-section and in plan view;

FIG. 130 illustrates a further embodiment, in which quantum well intermixing was additionally performed to constrict the current.

FIG. 131 shows a simplified structure of a display with pixel elements arranged in rows and columns;

FIG. 132 shows an enlarged section of a display according to the previous figure with one pixel element and subpixels;

FIG. 133 shows a schematic vertical sectional view through a section of a display according to the proposed concept with a pixel element separation layer and subpixel separation elements;

FIG. 134 illustrates a schematic vertical sectional view through pixel elements applied in a layer on a backplane;

FIG. 135 is an embodiment where various converters are embedded in a light-shaping structure;

FIG. 136 illustrates another aspect where quantum well intermixing is used to create an optical separation;

FIG. 137 shows steps of a method for calibrating a pixel element with a pixel element separation layer and sub-pixel separation elements;

FIG. 138 shows a first embodiment of a pixel array according to some aspects of the proposed principle, where adjacent pixels are connected by a thin material bridge;

FIG. 139 shows a second embodiment of a pixel array with two μ-LEDs connected by a material bridge;

FIG. 140A is a third embodiment of a pixel array with some aspects according to the proposed principle;

FIG. 140B is a diagram for the embodiment of the previous figure, which illustrates the energy flow with regard to the material bridge;

FIG. 141 shows a fourth embodiment of a pixel array with some aspects according to the proposed principle;

FIG. 142A is a fifth embodiment of a pixel array;

FIG. 142B shows an embodiment of a pixel array with adjacent μ-LEDs, a material bridge, with an additional output structure according to some of the aspects revealed here.

FIG. 143 shows a sixth embodiment of a pixel array;

FIG. 144 is a seventh embodiment of a pixel array with further aspects;

FIG. 145 shows an eighth embodiment of a pixel array;

FIG. 146 shows a ninth embodiment of a pixel array;

FIG. 147 shows an embodiment with different steps for a method of manufacturing a pixel array according to the proposed concept;

FIGS. 148A to 148J show a first embodiment of a process for manufacturing a μ-LED with a holding structure according to some aspects of the presented concept;

FIGS. 149A to 149J show a second embodiment of a process for manufacturing a μ-LED with a holding structure according to some aspects of the presented concept;

FIGS. 150A to 150I represent a third embodiment of a process for manufacturing a μ-LED with a holding structure according to some aspects of the concept presented;

FIGS. 151A to 151J show a fourth embodiment of a process for manufacturing a μ-LED with a holding structure according to some aspects of the presented concept;

FIGS. 152A and 152B represent two additional steps that can be used in the various embodiment;

FIGS. 153A to 153D show the schematic sequence of a mass transfer printing process for a large number of μ-LEDs on a wafer;

FIG. 154 shows a support structure according to the proposed principle in a top view with 3 mounting elements;

FIGS. 155A to 155E show a total of four vertical sectional views through a carrier structure for holding flat μ-LEDs suitable for the proposed transfer;

FIG. 156 shows a layout of a carrier structure according to some aspects of the proposed concept with flat μ-LEDs and a variety of mounting elements in different arrangements;

FIG. 157 shows another layout of a support structure, prepared and suitable for the proposed transfer process;

FIG. 158A shows another embodiment of a support structure;

FIG. 158B is an alternative to the previous embodiment;

FIGS. 159A to 159D are illustrations of a process and a device for picking up and placing μ-LEDs or optoelectronic semiconductor chips to explain various aspects of the concept presented;

FIG. 160 shows a representation of another device for picking up and placing μ-LEDs or optoelectronic semiconductor chips;

FIGS. 161A and 161B show illustrations of an embodiment of a process for picking up and placing μ-LEDs or optoelectronic semiconductor chips using a cylindrical pick-up tool;

FIG. 162 illustrates an illustration of a pick-up tool with elevations for picking up μ-LEDs or optoelectronic semiconductor chips;

FIG. 163 shows a version of a pick-up tool that is suitable for selective irradiation of μ-LEDs or optoelectronic semiconductor chips;

FIG. 164 illustrates a representation of a pick-up tool with a flat surface for picking up μ-LEDs or optoelectronic semiconductor chips;

FIGS. 165A through 165C show illustrations of a method for depositing μ-LEDs; and

FIGS. 166A to 166C are different representations of some of the ways in which an electric field is generated by the pick-up tool;

FIGS. 167A and 167B show illustrations showing transfer steps of a conventional method and the proposed method;

FIG. 168 is a first embodiment of a start structure for a procedure according to some suggested aspects in a top view;

FIG. 169 shows the first embodiment according to FIG. 168 of the start structure for the procedure in an enlarged view;

FIG. 170 shows a further illustration for a manufacture of a first start structure according to some of the proposed aspects;

FIG. 171 is an embodiment of the inventive step with some aspects of the proposed principle;

FIG. 172 shows the first embodiment of the start structure for a procedure in a cross-section;

FIGS. 173A to 173E show a further embodiment of an invention-related procedure using a first start structure;

FIG. 174 is a first illustration of the mode of action of anchor elements and release elements according to some aspects presented;

FIG. 175 is a second illustration of how anchor elements and release elements work;

FIG. 176 shows a second embodiment of a starting structure for a transfer procedure according to some suggested aspects;

FIGS. 177A to 177E show another embodiment of a proposed procedure using the second start structure;

FIG. 178A is a first illustration of the selectivity of release elements according to some aspects of the proposed concept for a transfer;

FIG. 178B shows a second illustration of the selectivity of release elements;

FIGS. 179A to 179F show examples of the use of anchor elements and release elements between microchips and module areas;

FIG. 180 shows an illustration of an embodiment of a proposed base module for the provision of light emitting diode modules according to some aspects of the proposed concept;

FIG. 181 shows the embodiment according to FIG. 180 on a replacement carrier according to further aspects;

FIG. 182 illustrates the embodiment according to FIG. 181 with a further basic module;

FIG. 183 shows the embodiment according to FIG. 182 with separate contacting of the contacts;

FIG. 184 illustrates the embodiment according to FIG. 183 with common contacting of the first contacts;

FIG. 185 shows a further illustration of an embodiment of a proposed base module to provide a two row and two column light emitting diode module according to some aspects of the concept presented;

FIGS. 186A to 186D show four cross sections of two oppositely oriented base modules of two adjacent rows;

FIG. 187 shows a further illustration of an embodiment of a proposed base module to provide a two row and three column light emitting diode module;

FIG. 188A to 188D illustrate four cross sections of two oppositely oriented base modules of two adjacent rows;

FIG. 189 shows a top view of a matrix containing basic modules with groupings to explain further aspects;

FIG. 190 illustrates a top view of a matrix with basic modules and further groupings;

FIG. 191 shows a top view of a matrix with basic modules and another possible grouping;

FIG. 192 is a top view of a matrix with basic modules and another possible grouping;

FIG. 193A illustrates a cross-sectional view of another embodiment of a μ-LED module with an additional photonic structure;

FIG. 193B shows an example of how the proposed μ-LED module can be lifted off by a transfer stamp described in this application;

FIG. 194 shows several steps of an embodiment of a proposed process for manufacturing μ-LED modules;

FIG. 195 illustrates a schematic representation of another method for the production of μ-LED modules according to some aspects of the proposed principle;

FIG. 196A are illustrations of some steps of the method presented in FIG. 195;

FIG. 196B shows an illustration of further steps of the method presented in FIG. 195 for an explanation of various aspects;

FIG. 196C shows a representation of an arrangement of a large number of full-surface target matrices;

FIG. 196D illustrates schematically various contact surfaces that are suitable for contacting the proposed μ-LED modules;

FIG. 196E shows a section of a display with contact areas and some μ-LED modules;

FIG. 197 shows an embodiment for a double transfer process with proposed μ-LED modules;

FIG. 198 shows a first embodiment of a μ-LED module for vertical and horizontal mounting with some aspects according to the proposed principle;

FIG. 199 shows the bottom of the first embodiment;

FIG. 200 shows a sectional view of the first embodiment along the X-X axis in FIG. 199;

FIG. 201 shows another embodiment of a μ-LED module for vertical and horizontal mounting with some aspects according to the proposed principle;

FIG. 202 shows a schematic side view of FIG. 201;

FIGS. 203A to 203C show various embodiments in which a module is placed on a carrier and electrically contacted;

FIGS. 204A and 204B show a second embodiment with some aspects according to the proposed principle;

FIGS. 205A and 205B shows a third embodiment with some aspects according to the proposed principle;

FIG. 206 shows an embodiment with different process steps;

FIG. 207 shows a first embodiment of a contacting in perspective;

FIGS. 208A and 208B shows two top views with a schematic wiring diagram for a module based on the proposed principle;

FIG. 209 shows a view of a bottom side of the above embodiments;

FIG. 210 shows an example of a structured membrane wafer during the manufacturing process of a module according to the proposed principle;

FIG. 211A is a top view of the contacts of a substrate in an unpopulated state provided for a pixel according to an aspect of the proposed concept;

FIG. 211B shows a top view of the contacts of the substrate of FIG. 206A provided for the pixel after an initial assembly of μ-LEDs;

FIG. 211C shows a top view of the contacts of the substrate of FIG. 206A provided for the pixel after a second assembly of μ-LEDs;

FIG. 212A illustrates a top view of the contacts of another substrate in an unpopulated state, provided for one pixel;

FIG. 212B is a top view of the contacts of the substrate of FIG. 207A provided for the pixel after an initial placement;

FIG. 212C shows a top view of the contacts of the substrate of FIG. 207A provided for the pixel after a second placement;

FIG. 213A shows a top view of the contacts provided for one pixel of yet another substrate in an unpopulated state to illustrate further aspects of the proposed concept;

FIG. 213B shows a top view of the contacts of the substrate of FIG. 208A provided for the pixel after an initial placement; and

FIG. 213C is a top view of the contacts of the substrate of FIG. 208A provided for the pixel after a second placement;

FIG. 214 shows a μ-LED pixel where the light emission is already directed by a specially formed reflector material

FIG. 215 shows an optical pixel element with a spherical reflector element and control electronics according to some aspects of the proposed concept;

FIG. 216 shows a second embodiment of a pixel element with a reflector element designed as a layer and a passivation layer according to some aspects of the proposed concept;

FIG. 217 shows a third embodiment of a pixel element with light-absorbing coatings on a display side and an assembly side of the carrier substrate according to some aspects of the proposed concept;

FIG. 218 forms a pixel element with a roughened display side of the carrier substrate;

FIGS. 219A and 219B are embodiments based on some of the aspects revealed here, with light absorbing layers to minimize crosstalk and a color filter element on the display side of the carrier substrate;

FIGS. 220A and 220B show embodiments of a pixel element with IGZO- or LTPS-based drive electronics on the assembly side of the carrier substrate and optional diffuser layer according to some aspects of the proposed concept;

FIG. 221 shows a cross-section and top view of a pixel cell with three μ-LEDs of different colors and a reflector element;

FIG. 222 shows a method for manufacturing an optical pixel element as described above;

FIG. 223A shows on the left side a cross-sectional view of an exemplary μ-LED and on the right side a perspective view of the optoelectronic device with a photonic structure;

FIG. 223B shows a cross-sectional view of another μ-LED with photonic structure according to some suggested aspects;

FIG. 223C shows on the left side a more detailed cross-sectional view of another optoelectronic device and on the right side a more schematic cross-sectional view of the optoelectronic device;

FIG. 223D is a cross-sectional view of a μ-LED with planar surface and photonic structure;

FIG. 223E shows another embodiment of a μ-LED with photonic structure in cross-sectional view;

FIG. 223F illustrates another embodiment of a μ-LED with photonic structure in cross-sectional view according to some aspects of the proposed concept;

FIG. 224 shows an embodiment of a method for producing one of the structures shown in FIGS. 223D to 223E;

FIG. 225 illustrates a top view and sectional view of an optoelectronic device with a μ-LED and a converter element according to some aspects of simultaneous light shaping and light conversion;

FIG. 226 shows a cross-section through an optoelectronic component in a further version according to some aspects of the proposed concept;

FIG. 227 is a top view and sectional view of another component;

FIG. 228 shows a cross-section through a component with a μ-LED and a converter element according to some aspects of light shaping and light conversion;

FIGS. 229A and 229B show a μ-display with several light-emitting units and a photonic structure in a top view and cross section according to some aspects of the concept presented;

FIGS. 230A and 230B represent a second embodiment of a μ-display with a photonic structure in a top view and cross-section according to some aspects of the presented concept;

FIGS. 231A and 231B show a third embodiment of a μ-display with several μ-LEDs of a photonic structure in a top view and as a cross-section according to some aspects of the presented concept;

FIGS. 232A and 232B are part of a fourth embodiment of a μ-display with a photonic structure in a top view and as a cross-section according to some aspects of the concept presented;

FIGS. 233A and 233B show a fifth embodiment of a μ-display with a photonic structure in a top view and as a cross-section according to some aspects of the presented concept;

FIGS. 234A and 234B illustrate a sixth embodiment of a μ-display with a photonic structure in a top view and as a cross-section according to some aspects of the concept presented;

FIGS. 235A and 235B show a seventh embodiment of a μ-display with a photonic structure in a top view and as a cross section according to some aspects of the presented concept;

FIGS. 236A and 236B illustrate an eighth embodiment of a μ-display of a photonic structure in a top view and as a cross-section;

FIGS. 237A and 237B show a ninth embodiment of a μ-display of a photonic structure in a top view and as a cross-section according to some aspects of the presented concept;

FIG. 238 shows a cross-sectional view of another variant of a device according to the invention;

FIG. 239 shows an arrangement of an optoelectronic component with an emitter unit having a light-emitting surface to which a polarizing element with a three-dimensional photonic structure is applied;

FIG. 240 illustrates a representation of a three-dimensional photonic structure with a large number of spiral-shaped structural elements;

FIG. 241 shows another embodiment of an optoelectronic device with an emitter unit and a polarization element with a three-dimensional photonic structure;

FIG. 242 shows an optoelectronic device with an emitter unit and a three-dimensional photonic structure into which converter material is filled;

FIG. 243 illustrates a perspective view of a first variant of an arrangement with an emitter unit, which has a photonic structure for generating a specific far field;

FIG. 244 shows a sectional view of a second variant of an arrangement with an emitter unit to illustrate further aspects of the proposed principle;

FIG. 245 shows an arrangement of a plurality of arrangements according to the two preceding figures;

FIG. 246 shows a perspective view of a third variant of an arrangement with an emitter unit, which has a photonic structure to generate a defined far field;

FIG. 247 illustrates a block diagram of a surface topography detection system with an arrangement according to one of the preceding figures;

FIG. 248 is an example of a pair of glasses for advanced reality functionality that uses a μ-display to illustrate various aspects and basic principles;

FIG. 249 shows a first embodiment of a light guiding concept of a curved light surface according to some aspects of the proposed concept;

FIG. 250 shows an enlarged partial view for the embodiment of the light guide concept with separate μ-LEDs on a non-planar IC substrate;

FIG. 251 represents a third embodiment of a light guide with a monolithic pixelated chip according to further aspects;

FIG. 252 shows a fourth embodiment of a lighting system with some aspects;

FIG. 253 is a further development of one of the above embodiment according to some aspects of the concept presented;

FIG. 254 is another embodiment of the example of FIG. 250, with additional light-shaping structures;

FIG. 255 is a supplement to the embodiment of FIG. 253, where a photonic structure is arranged in the beam path;

FIG. 256 shows a further embodiment based on the example in FIG. 252;

FIG. 257A shows a further embodiment based on the example in FIG. 252;

FIG. 257B shows a top view of an embodiment of a step-shaped substrate;

FIG. 258 is an embodiment with a reflective circumferential structure around the optochip;

FIG. 259 combines nanorods arranged on its curved surface of a substrate with control;

FIG. 260A shows a matrix with RGB pixels, which has a high fill factor;

FIG. 260B is a schematic representation of the beam guidance in a conventional projection unit;

FIG. 261 shows an embodiment of an implemented matrix with RGB pixels, which has a small fill factor according to some aspects of the proposed concept;

FIGS. 262A and 262B show a top view and a cross-sectional view of a combined embodiment with features of the embodiment examples of FIGS. 261 and 103A;

FIGS. 263A and 263B show top views of further versions of a matrix with RGB pixels, realized by μ-LED arrangements according to some of the concepts presented here;

FIG. 264 shows another embodiment of an executed matrix with RGB pixels, which has a small fill factor according to some aspects;

FIG. 265 illustrates a top view of an embodiment of a matrix with a light-shaping structure arranged on it;

FIG. 266 shows a schematic representation of a projection unit according to some aspects of the proposed principle;

FIG. 267 shows a schematic representation of the generation of an intermediate image by the projection unit of the previous figure;

FIG. 268 shows the chromatic phase function of the collimation optics of FIG. 266;

FIG. 269 shows a metal lens of collimating optics according to some embodiments of the proposed concept;

FIG. 270 shows a schematic side view of a monolithic array with several integrated μ-LEDs to illustrate some aspects of the proposed concept;

FIG. 271 shows an example of an arrangement for beam guidance according to some aspects of the presented concept, which takes into account the different spatial resolution of the eye;

FIG. 272 are schematic illustrations for a beamline device in the arrangement of the previous figure;

FIG. 273 shows another embodiment of a beamline arrangement to explain further aspects of the concept presented;

FIG. 274 is a further embodiment of an arrangement for beam guidance that takes into account the different resolving power of the human eye;

FIG. 275 shows a representation of a μ-display for the application illustrated in FIG. 273;

FIG. 276A illustrates different possibilities of a μ-display for generating light in a beam guiding device according to the proposed concept FIG. 276B is another possibility to combine a beam delivery device with a μ-display embodiment;

FIG. 276C shows a chromatic cube as it can be used in some applications and in which the light-emitting surfaces can be formed with the versions of μ-displays disclosed here;

FIGS. 277A and 277B show various embodiments of beam systems which can be placed upstream, downstream or integrated into the imaging optics of the device of FIG. 272, 273 or 274;

FIG. 278 shows a schematic diagram for a first embodiment of a light field display according to some aspects of the proposed principle;

FIG. 279 illustrates the assembly of the first halftone image and the second halftone image to form a halftone image projected onto the retina;

FIG. 280 shows second pixel images with hexagonal outline;

FIGS. 281A to 281B show an adjustment optic with a switchable Bragg grating according to some aspects of the proposed concept;

FIG. 282 is a view of an adjustment optic with an Alvarez lens arrangement suitable for a light field display according to the proposed principle;

FIG. 283 shows an adjustment optic with a Moire lens arrangement suitable for a light field display according to the proposed principle;

FIG. 284 shows an embodiment of a dynamic eye movement detection device and a control device for the adjustment optics of a light field display according to the proposed concept;

FIG. 285 shows several examples of a one-dimensional pixel array according to some aspects of another concept;

FIG. 286 is an example to illustrate the rotation of the pixel line according to some aspects of the proposed concept;

FIG. 287 shows another embodiment of a pixel array to illustrate a new light generation and guidance concept;

FIG. 288 illustrates an embodiment of a pixel matrix with two pixel arrays according to the proposed principle;

FIG. 289 shows a third embodiment of a pixel array with several lines of different colors to illustrate a new light generation and guidance concept;

FIG. 290 shows another embodiment of a pixel array with lines for the different colors according to the proposed principle;

FIGS. 291A and 291B show a cross-section of the pixel row of FIG. 290 with a photonic structure on a substrate and a top view of it;

FIGS. 291C and 291D show another embodiment of a pixel line, which is configured with redundant μ-LEDs;

FIGS. 292A and 292B show examples of embodiments of a pixel array with several subpixels of different size and frequency according to the proposed principle;

FIG. 293 shows another embodiment of a pixel matrix in which three rows of pixels of different colors are offset from each other;

FIG. 294 is an embodiment of an optical system for generating an image according to some aspects of the proposed concept of a one-dimensional pixel array;

FIG. 295A illustrates an embodiment of a dual-gate transistor in a cross-section;

FIG. 295B shows two top views of the dual-gate transistor;

FIG. 295C illustrates a plot of the dependence of a threshold voltage on a top-gate voltage;

FIG. 296 shows a first embodiment of a control circuit for a μ-LED with some aspects according to the presented concept;

FIG. 297 shows a second embodiment of a control circuit for a μ-LED with further aspects;

FIG. 298 is a third embodiment of a control circuit for a μ-LED according to some aspects of the proposed concept;

FIG. 299 shows embodiment of a control circuit for a μ-LED with further aspects;

FIG. 300 illustrates a further embodiment of a control circuit for a μ-LED according to some aspects of the proposed concept;

FIG. 301 shows a further embodiment in addition to the previous figure;

FIG. 302 shows a fifth embodiment of a control circuit for a μ-LED according to some aspects;

FIG. 303 shows a circuit diagram of an SRAM-6-T cell to illustrate one aspect;

FIG. 304 shows a circuit diagram of a driver circuit to illustrate some aspects;

FIG. 305 is a schematic representation of a display with digital elements and the pixel array according to some of the proposed aspects;

FIG. 306 shows a circuit to illustrate the clock for dark pixels;

FIG. 307 is a representation of a global bias for the pixel stream according to some aspects;

FIG. 308 shows a signal-time diagram with some signals according to the embodiment of FIG. 305;

FIG. 309 shows another embodiment of a driver circuit with reduced space consumption;

FIG. 310 shows embodiments of another driver circuit that also has a reduced space consumption;

FIG. 311A shows a schematic diagram of a driver circuit for two μ-LEDs to explain some aspects of dimmable control according to some aspects;

FIG. 311B shows an embodiment of the dimmable control with a μ-LED module as shown in FIG. 184;

FIG. 312 is a diagram of the LED current flowing through the LED as a function of different capacitor voltages;

FIG. 313 shows a schematic representation of the brightness of a lighting unit with LED when driven with a comparatively high first voltage signal;

FIG. 314 is another schematic representation of the brightness of a lighting unit with LED when driven with a comparatively low first voltage signal;

FIG. 315 is a diagram showing the average light output of a lighting unit with LED as a function of the voltage selected for the capacitor voltage according to some aspects of the concept presented here;

FIG. 316 shows a block diagram of the main components of a PWM supply circuit for μ-LEDs;

FIG. 317 is an embodiment of a PWM supply circuit for μ-LED according to the proposed principle;

FIG. 318 shows the embodiment of FIG. 317 in an operating state with additional information on the signal flow;

FIG. 319 shows two principle illustrations of two simple switch devices;

FIG. 320 illustrates a signal-time diagram of the proposed embodiment with the signal points shown in FIG. 317;

FIG. 321 shows an illustrative version of an analogue ramp-based control circuit suitable for controlling the on/off ratio for light-emitting devices in a μ-LED display;

FIG. 322 illustrates a signal-time diagram with different signals of the concept according to FIG. 321;

FIG. 323 shows a circuit diagram of a pixel cell with redundant μ-LEDs and fuses to separate a μ-LED;

FIG. 324 shows a further embodiment of a circuit with redundant μ-LEDs, in which a defect of a μ-LED can be compensated;

FIG. 325 illustrates a third embodiment of a circuit with redundant μ-LEDs according to some aspects of the presented concept;

FIG. 326 shows a fourth embodiment of a circuit with redundant μ-LEDs in which a defective μ-LED can be replaced;

FIG. 327 shows a fifth embodiment of a circuit with redundant μ-LEDs;

FIG. 328 is a sixth embodiment of a circuit with redundant μ-LEDs, in which a defect of a μ-LED is compensated;

FIG. 329 shows an outline of a procedure for testing and configuring a pixel cell that is driven by one of the circuits presented above;

FIG. 330 illustrates a circuit for driving and testing μ-LEDs according to aspects of the proposed concept of a slot antenna based on the principle disclosed in this application;

FIG. 331 is an embodiment of a controller with a different μ-LED concept according to some aspects;

FIG. 332 shows a further embodiment of a control with a μ-LED concept presented here;

FIG. 333 shows an embodiment of a display device consisting of a monolithic pixel array with a monolithic IC in cross-sectional view according to some aspects of the proposed concept;

FIG. 334 shows the previous embodiment of the proposed display device in cross-sectional view with a sketched possible light path;

FIG. 335 illustrates a second embodiment of the proposed display device with monolithic pixel array and IC in cross-sectional view;

FIG. 336 is a third embodiment of the proposed display device in cross-sectional view according to further aspects of the proposed principle;

FIG. 337 shows a fourth embodiment of the proposed display device in cross-sectional view with additional measures for light guidance;

FIGS. 338A and 338B show two alternative embodiment to improve the localization of charge carriers in one of the proposed display devices with further aspects from this disclosure;

FIG. 339A illustrates a circuit diagram for a control circuit of one or more LEDs, taking into account the requirements for geometry and size;

FIG. 339B shows an alternative embodiment of a schematic diagram of a driver circuit for several μ-LEDs, taking into account the requirements for geometry and size;

FIG. 339C shows a version of a comparator circuit, as it can be used in a comparator instead of an OR gate as used in FIG. 339A;

FIG. 339D shows a time diagram for the various counter words 1D to 3D and the memory registers as they are used to generate the output signal;

FIG. 340A shows a sectional view of a μ-LED display arrangement;

FIG. 340B shows various examples of how the different sections are connected after the execution of FIGS. 339A and 340A;

FIG. 341 shows an example of an inverted transistor of offset type using amorphous silicon for use in the analogue part of a μ-LED driver;

FIG. 342 illustrates some examples of polysilicon transistors suitable for a μ-LED driver circuit;

FIG. 343 shows a circuit diagram of a μ-LED or LED display;

FIG. 344 shows a circuit diagram of a μ-LED display segmented into different sub-matrices;

FIG. 345 illustrates a conventional approach for a driver circuit for an LED in one pixel of a display;

FIG. 346 illustrates a version of a conventional gap driver suitable for use in a display;

FIG. 347 shows a version of a conventional line driver suitable for use in a display;

FIG. 348 is an embodiment of a semiconductor layer stack with quantum well structure;

FIG. 349 is a schematic representation of the rear of a motor vehicle with two rear lamps and a high-positioned stop lamp;

FIG. 350 shows a schematic top view of different areas of the left-hand combination rear lamp shown in FIG. 319;

FIG. 351 shows a schematic cross-section of the left rear lamp and the vehicle body;

FIG. 352 shows a schematic top view of a μ-LED array of the raised brake light;

FIG. 353 shows a cross-section through the rear window of the motor vehicle and the raised stop lamp in schematic form with a vertical cross-sectional plane;

FIG. 354 is a cross-sectional view of the rear window of the motor vehicle and the raised stop lamp, schematically shown with a horizontal cross-sectional plane;

FIG. 355 is a side view of a motor vehicle with a display on the outside of the vehicle body in schematic form;

FIG. 356 shows a top view of a μ-LED array of the display shown in FIG. 325 in schematic form;

FIG. 357 is a cross-section of the vehicle body and display as shown in FIGS. 325 and 326 in a schematic diagram with a vertical cross-sectional plane;

FIG. 358 shows an interior view of a vehicle with a headlining;

FIG. 359 shows an interior view of a vehicle with a centre console;

FIG. 360 is an interior view of a vehicle from the perspective of a driver with a display in the A-pillar of the vehicle;

FIG. 361 shows an interior view of a vehicle from the perspective of a driver with an A-pillar on which the output device is integrated;

FIG. 362 shows an interior view of a vehicle with a status display located inside a vehicle door;

FIG. 363 shows an embodiment of a display device in cross-sectional view, for example for use in a larger display or on a curved surface according to some suggested aspects;

FIGS. 364A and 364B are embodiments of a display segment in different views;

FIGS. 365 to 370 show different embodiments of a display device according to different aspects of the proposed concept in cross-sectional view;

FIGS. 371A to 371K show embodiments of a display segment in different views as they can be realized in embodiments of the proposed display device;

FIGS. 372A and 372B illustrate embodiments of a beam in top view;

FIGS. 373A through 373D are different positions in an embodiment for making a display device.

### DETAILED DESCRIPTION

Augmented reality is usually generated by a dedicated display whose image is superimposed on reality. Such device can be positioned directly in the user's line of sight, i.e. directly in front of it. Alternatively, optical beam guidance elements can be used to guide the light from a display to the user's eye. In both cases, the display may be implemented and be part of the glasses or other visually enhancing devices worn by the user. Google's™ Glasses is an example of such a visually augmenting device that allows the user to overlay certain information about real world objects. For the Google™ glasses, the information was displayed on a small screen placed in front of one of the lenses. In this respect, the appearance of such an additional device is a key characteristic of eyeglasses, combining technical functionality with a design aspect when wearing glasses. In the meantime, users require glasses without such bulky or easily damaged devices to provide advanced reality functionality. One idea, therefore, is that the glasses themselves become a display or at least a screen on or into which the information is projected.

In such cases, the field of vision for the user is limited to the dimension of the glasses. Accordingly, the area onto which extended reality functionality can be projected is approximately the size of a pair of spectacles. Here, the same, but also different information can be projected on, into or onto the two lenses of a pair of spectacles.

In addition, the image that the user experiences when wearing glasses with augmented reality functionality should have a resolution that creates a seamless impression to the user, so that the user does not perceive the augmented reality as a pixelated object or as a low-resolution element. Straight bevelled edges, arrows or similar elements show a staircase shape that is disturbing for the user at low resolutions.

In order to achieve the desired impression, two display parameters are considered important, which have an influence on the visual impression for a given or known human sight. One is the pixel size itself, i.e. the geometric shape and dimension of a single pixel or the area of 3 subpixels representing the pixel. The second parameter is the pixel pitch, i.e. the distance between two adjacent pixels or, if necessary, subpixels. Sometimes the pixel pitch is also called pixel gap. A larger pixel pitch can be detected by a user and is perceived as a gap between the pixels and in some cases causes the so-called fly screen effect. The gap should therefore not exceed a certain limit.

The maximum angular resolution of the human eye is typically between 0.02 and 0.03 angular degrees, which roughly corresponds to 1.2 to 1.8 arc minutes per line pair. This results in a pixel gap of 0.6-0.9 arc minutes. Some current mobile phone displays have about 400 pixels/inch, resulting in a viewing angle of approximately 2.9° at a distance of 25 cm from a user's eye or approximately 70 pixels/° viewing angle and cm. The distance between two pixels in such displays is therefore in the range of the maximum angular resolution. Furthermore, the pixel size itself is about 56 μm.

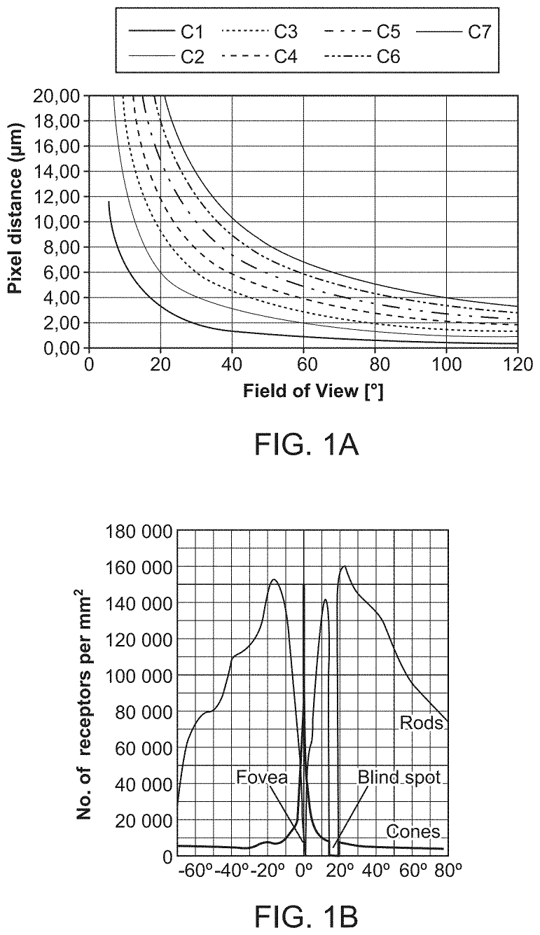

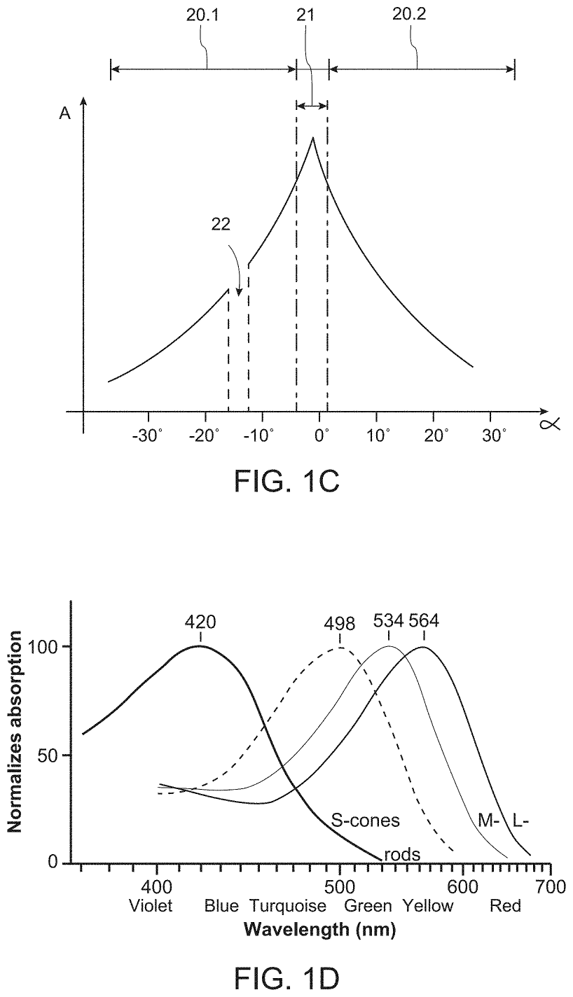

FIG. 1A illustrates the pixel pitch, i.e. the distance between two adjacent pixels as a function of the field of view in angular degrees. In this respect, the field of view is the extension of the observable world seen at a given moment. This is because human vision is defined as the number of degrees of the angle of view during stable fixation of the eye.

In particular, humans have a forward horizontal arc of their field of vision for both eyes of slightly more than 210°, while the vertical arc of their field of vision for humans is around 135°. However, the range of visual abilities is not uniform across the field of vision and can vary from person to person.

The binocular vision of humans covers approximately 114° horizontally (peripheral vision), and about 90° vertically. The remaining degrees on both sides have no binocular area but can be considered part of the field of vision.

Furthermore, color vision and the ability to perceive shapes and movement can further limit the horizontal and vertical field of vision. The rods and cones responsible for color vision are not evenly distributed.

This point of view is shown in more detail in FIGS. 1B to 1D. In the area of central vision, i.e. directly in front of the eye, as required for Augmented Reality applications and partly also in the automotive sector, the sensitivity of the eye is very high both in terms of spatial resolution and in terms of color perception.

FIG. 1B shows the spatial density of rods and cones per mm² as a function of the fovea angle. FIG. 1C describes the color sensitivity of cones and rods as a function of wavelength. In the central area of the fovea, the increased density of cones (L, S and M) means that better color vision predominates. At a distance of about 25° around the fovea, the sensitivity begins to decrease and the density of the visual cells decreases. Towards the edge, the sensitivity of color vision decreases, but at the same time contrast vision by means of the rods remains over a larger angular range. Overall, the eye develops a radially symmetrical visual pattern rather than a Cartesian visual pattern. A high resolution for all primary colors is therefore required, especially in the center. At the edge it may be sufficient to work with an emitter adapted to the spectral sensitivity of the rods (max. sensitivity at 498 nm, see FIG. 1D and the sensitivity of the eye).

FIG. 1C shows the different perceptual capacity of the human eye by means of a graph of the angular resolution A relative to the angular deviation α from the optical axis of the eye. It can be seen that the highest angular resolution A is in an interval of the angular deviation α of +/−2.5°, in which the fovea centralis 7 with a diameter of 1.5 mm is located on the retina 19. In addition, the position of the blind spot 22 on the retina 19 is sketched, which is located in the area of the optic nerve papilla 23, which has a position with an angular deviation α of about 15°.

The eye compensates this non-constant density and also the so-called blind spot by small movements of the eye. Such changes in the direction of vision or focus can be counteracted by suitable optics and tracking of the eye.

Furthermore, even with glasses, the field of vision is further restricted and, for example, can be approximately in the range of 80° for each lens.

The pixel pitch in FIG. 1A on the Y-axis is given in μm and defines the distance between two adjacent pixels. The various curves C1 to C7 define the diagonal dimension of a corresponding display from 5 mm to approximately 35 mm. For example, curve C1 corresponds to a display with the diagonal size of 5 mm, i.e. a side length of approximately 2.25 mm. For a field of view of approximately 80°, the pixel pitch of a display with a diagonal size of 5 mm is in the range of 1 μm. For larger displays like curve C7 and 35 mm diagonal size, the same field of view can be implemented with a pixel pitch of approximately 5 μm.

Nevertheless, the curves in FIG. 1A illustrate that for larger fields of view, which are preferred for extended reality applications, very high pixel densities with small pixel pitch are required if the well-known fly screen effect is to be avoided. One can now calculate the size of the pixel for a given number of pixels, a given field of view and a given diagonal size of a μ-display.

Equation 1 shows the relationship between dimension D of a pixel, pixel pitch pp, number N of pixels and the edge length d of the display. The distance r between two adjacent pixels calculated from their respective centers is given by

r=d/2+pp+d/2.

D=d/N−pp

N=d/(D+pp) (1)

Assuming that the display (e.g. glasses) is at a distance of 2.54 cm (1 inch) from the eye, the distance r between two adjacent pixels for an angular resolution of 1 arcminute as roughly estimated above is given by

r=tan(1/60°)*30 mm

r=8.7 μm

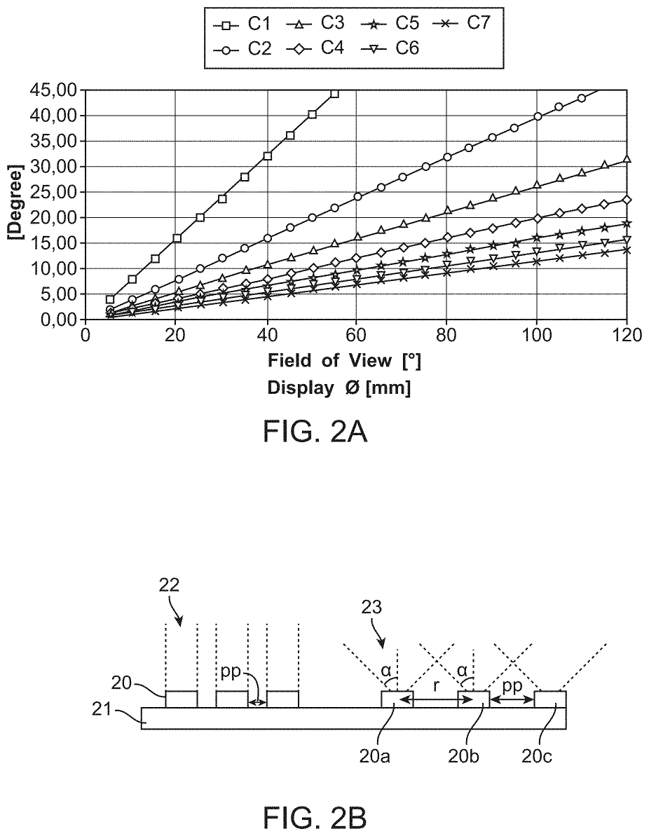

The size of a pixel is therefore smaller than 10 μm, especially if some space is required between two different pixels. With a distance, r between two pixels and a display with the size of 15 mm×10 mm, 1720×1150 pixels can be arranged on the surface. FIG. 2B shows an arrangement, which has a carrier 21 on which a large number of pixels, 20 and 20a to 20c are arranged. Pixels 20 arranged side by side have the pixel pitch pp, while pixels 20a to 20c are placed on carrier 21 with a larger pixel pitch pp. The distance between two pixels is given by the sum of the pixel pitch and half the size for each adjacent pixel. Each of the pixels 20 is configured so that its illumination characteristic or its emission vector 22 is substantially perpendicular to the emission surface of the corresponding LED.

The angle between the perpendicular axes to the emission surface of the LED and the beam vector is defined as the collimation angle. In the example of emission vector 22, the collimation angle of LEDs 20 is approximately zero. LED 20 emits light that is collinear and does not widen significantly.

In contrast, the collimation angle of the emission vector 23 of the LED pixels 20a to 20c is quite large and in the range of approximately 45°. As a result, part of the light emitted by LED 20a overlaps with the emission of an adjacent LED 20b.

The emission of the LEDs 20a to 20c is partially overlapping, so that its superposition of the corresponding light emission occurs. In case the LEDs emit light of different colors, the result will be a color mixture or a combined color. A similar effect occurs between areas of high contrast, i.e. when LED 20a is dark while LED 20b emits a certain light. Because of the overlap, the contrast is reduced and information about each individual position corresponding to a pixel position is reduced.

In displays where the distance to the user's eye is only small, as in the applications mentioned above, a larger collimation angle is rather annoying due to the effects mentioned above and other disadvantages. A user is able to see a wide collimation angle and may perceive displayed objects in slightly different colors blurred or with reduced contrast.

FIG. 2A illustrates in this respect the requirement for the collimation angle in degrees against the field of view in degrees, independent of specific display sizes. For smaller display sizes such as the one in curve C1 (approx. 5 mm diagonal), the collimation angle increases significantly depending on the field of view.

As the size of the display increases, the collimation angle requirements change drastically, so that even for large display geometries such as those illustrated in curve C7, the collimation angle reaches about 10° for a field of view of 100°. In other words, the collimation angle requirements for larger displays and larger fields of view are increasing. In such displays, light emitted by a pixel must be highly collimated to avoid or reduce the effects mentioned above. Consequently, strong collimation is required when displays with a large field of view are to be made available to a user, even if the display geometry is relatively large.

As a result of the above diagrams and equations, one can deduce that the requirements regarding pixel pitch and collimation angle become increasingly challenging as the display geometry and field of view grow. As already indicated by equation 1, the dimension of the display increases strongly with a larger number of pixels. Conversely, a large number of pixels is required for large fields of view if sufficient resolution is to be achieved and fly screens or other disturbing effects are to be avoided.

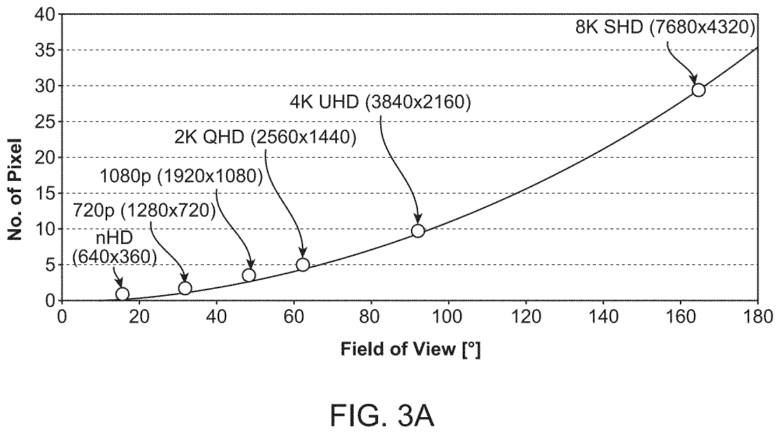

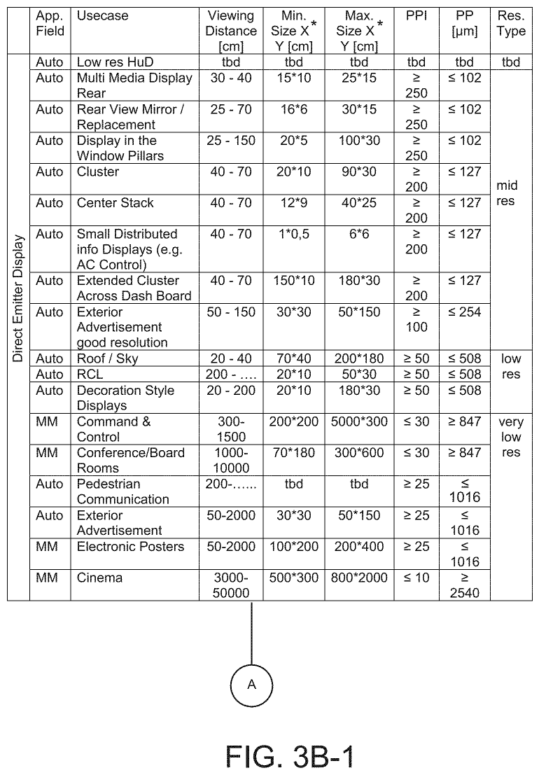

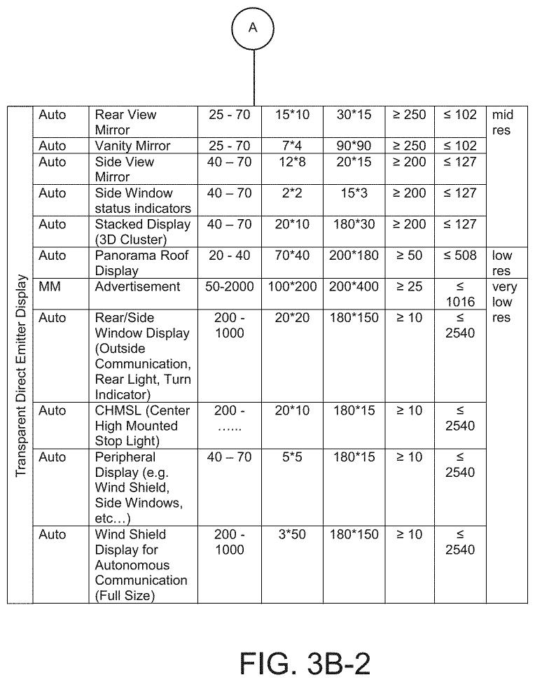

FIG. 3A shows a diagram of the number of pixels required to achieve an angular resolution of 1.3 arc minutes. For a field of view of approximately 80°, the number of pixels exceeds 5 million. It is easy to estimate that the size of the pixels for a QHD resolution is well below 10 μm, even if the display is 15 mm×10 mm. In summary, advanced reality displays with resolutions in the HD range, i.e. 1080p, require a total of 2.0736 million pixels. This allows a field of view of approximately 50° to be covered. Such a quantity of pixels arranged on a display size of 10×10 mm with a distance between the pixels of 1 μm results in a pixel size of about 4 μm.

In contrast, the table in FIG. 3B shows several application areas in which μ-LED arrays can be used. The table shows applications (use case) of μ-LED arrays in vehicles (Auto) or for multimedia (MM), such as automotive displays and exemplary values regarding the minimum and maximum display size (min. and max. size X Y [cm]), the pixel density (PPI) and the pixel pitch (PP [μm]) as well as the resolution (Res.-Type) and the distance of the viewer (Viewing Distance [cm]) to the lighting device or display. In this context, the abbreviations “very low res”, “low res”, “mid res” and “high res” have the following meaning:

| | |
|---|---|
| very low res | pixel pitch approx. 0.8-3 mm |
| low res | Pixel pitch approx. 0.5-0.8 mm |
| mid res | Pixel pitch approx. 0.1-0.5 mm |
| high res | Pixel pitch less than 0.1 mm |

The upper part of the table, entitled “Direct Emitter Displays”, shows inventive applications of μ-LED arrays in displays and lighting devices in vehicles and for the multimedia sector. The lower part of the table, titled “Transparent Direct Emitter Displays”, names various applications of μ-LED arrays in transparent displays and transparent lighting devices. Some of the applications of μ-displays listed in the table are explained in more detail below in the form of embodiments.

The above considerations make it clear that challenges are considerable in terms of resolution, collimation and field of view suitable for extended reality applications. Accordingly, very high demands are placed on the technical implementation of such displays.

Conventional techniques are configured for the production of displays that have LEDs with edge lengths in the range of 100 μm or even more. However, they cannot be automatically scaled to the sizes of 70 μm and below required here. Pixel sizes of a few μm as well as distances of a few μm or even less come closer to the order of magnitude of the wavelength of the generated light and make novel technologies in processing necessary.

In addition, new challenges in light collimation and light direction are emerging. Optical lenses, for example, which can be easily structured for larger LEDs and can also be calculated using classical optics, cannot be reduced to such a small size without the Maxwell equations. Apart from this, the production of such small lenses is hardly possible without large errors or deviations. In some variants, quantum effects can influence the behaviour of pixels of the above-mentioned size and have to be considered. Tolerances in manufacturing or transfer techniques from pixels to sub mounts or matrix structures are becoming increasingly demanding. Likewise, the pixels must be contacted and individually controllable. Conventional circuits have a space requirement, which in some cases exceeds the pixel area, resulting in an arrangement and space problem.

Accordingly, new concepts for the control and accessibility of pixels of this size can be quite different from conventional technologies. Finally, a focus is on the power consumption of such displays and controllers. Especially for mobile applications, a low power consumption is desirable.

In summary, for many concepts that work for larger pixel sizes, extensive changes must be made before a reduction can be successful. While concepts that can be easily up scaled to LEDs at 2000 μm for the production of LEDs in the 200 μm range, downscaling to 20 μm is much more difficult. Many documents and literature that disclose such concepts have not taken into account the various effects and increased demands on the very small dimensions and are therefore not directly suitable or limited to pixel sizes well above 70 μm.

In the following, various aspects of the structure and design of μ-LED semiconductors, aspects of processing, light extraction and light guidance, display and control are presented. These are suitable and designed to realize displays with pixel sizes in the range of 70 μm and below. Some concepts are specifically designed for the production, light extraction and control of μ-LEDs with an edge length of less than 20 μm and especially less than 10 μm. It goes without saying, and is even desired, that the concepts presented here can and should be combined with each other for the different aspects. This concerns for example a concept for the production of a μ-LED with a concept for light extraction. In concrete terms, a μ-LED implemented by means of methods to avoid defects at edges or methods for current conduction or current constriction can be provided with light extraction structures based on photonic crystal structures. Likewise, a special drive can also be realized for displays whose pixel size is variable. Light guidance with piezoelectric mirrors can be realized for μ-LEDs displays based on the slot antenna aspect or on conventional monolithic pixel matrices.

In some of the following embodiments and described aspects, additional examples of a combination of the different embodiments or individual aspects thereof are suggested. These are intended to illustrate that the various aspects, embodiments or parts thereof can be combined with each other by the skilled person. Some applications require specially adapted concepts; in other applications, the requirements for the technology are somewhat lower. Automotive applications and displays, for example, may have a longer pixel edge length due to the generally somewhat greater distance to a user. Especially there, besides applications of extended reality, classical pixel applications or virtual reality applications exist. This is in the context of this disclosure for the realization of μ-LED displays, whose pixel edge length is in the range of 70 μm and below, also explicitly desired.

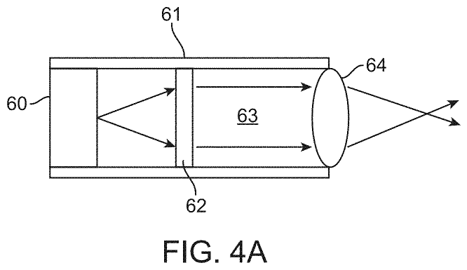

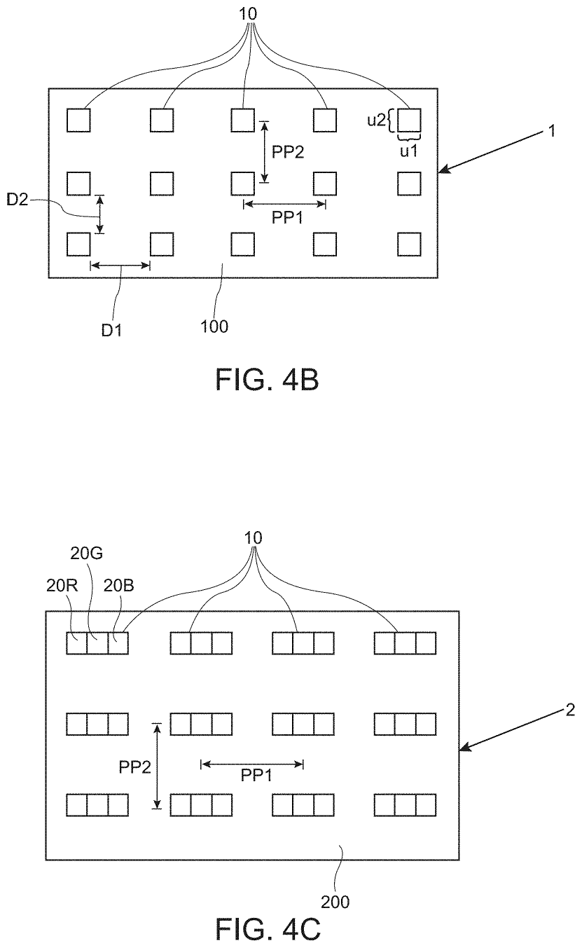

A general illustration of the main components of a pixel in a μ-display is shown schematically in FIG. 4A. It shows an element 60 as a light generating and light emitting device. Various aspects of this are described in more detail below in the section on light generation and processing. Element 60 also includes basic circuits, interconnects, and such to control the illumination, intensity, and, when applicable, color of the pixel. Aspects of this are described in more detail in the section on light control. Apart from light generation, the emitted light must be collimated. For this purpose, many pixels in microdisplays have such collimation functionality in element 60. The parallel light in element 63 is then fed for light guidance into some optics 64, for further shaping and the like. Light collimation and optics suitable for implementing pixels for microdisplays are described in the section on light extraction and light guidance.

The pixel device of FIG. 4A illustrates the different components and aspects as separate elements. An expert will recognize that many components can be integrated into a single device. In practice, the height of a μ-display is also limited, resulting in a desired flat arrangement.

This section describes in general terms aspects on μ-LED semiconductor structures and method for their manufacture. The active layer of the structures emit light of one wavelength or a wavelength range during operation. Some aspects relate to current conduction or other measures to reduce a defect density in order to achieve higher quantum efficiency.

As explained above, the structuring of micropixels for collinear light emission is a major requirement for extended realitys functionality with μ-displays. While collinearity can be achieved by beam-shaping using lenses and other optical devices to shape the light emitted from a pixel, collinear emission can also be achieved by controlling the way the light is generated in the active zone or by directing the light before it leaves the pixel material. The latter can be achieved by shaping the pixel in a certain way to increase collinearity.

Apart from the above mentioned problem of generating collinear light or preventing light from being emitted with a large emission angle, the small distance between the pixels of 2 to 1 μm or even smaller places high demands on the photomask, dopant implementation and other process steps. Small variations in the mask lead to variations in pixel size and/or geometry, which changes the properties. Besides the small pixel size, the ratio of the circumference of each pixel to the area will change significantly. Assuming a square pixel, shortening the length of a side edge by half will also change the ratio by half. Side edges and variations along the edges of pixels, along with defects within the active layer, are the main causes of non-radiative recombination (NRR), the ratio between radiative recombination and non-radiative recombination also changes to the disadvantage of the former.

FIG. 4B schematically shows a μ-display with similar μ-LEDs 10 is shown. The μ-LEDs 10 of the μ-display 1 are arranged in rows and columns on a carrier 100 with distances D1, D2 to adjacent μ-LEDs 10. Each μ-LED 10 forms a pixel. The pixel pitch PP1 or PP2 is measured from the center of a pixel to the center of an adjacent pixel. It thus corresponds to the sum of the distance D1 or D2 and the corresponding edge length K1 or K2 of a μ-LED 10. If the values for PP1 and PP2 are different, the larger value is defined as pixel pitch PP.

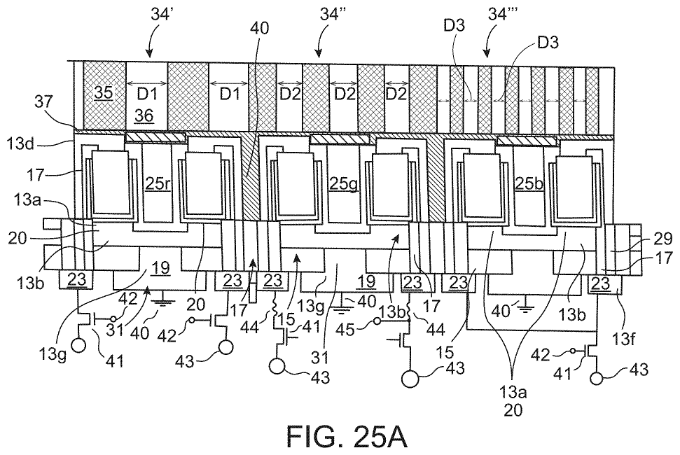

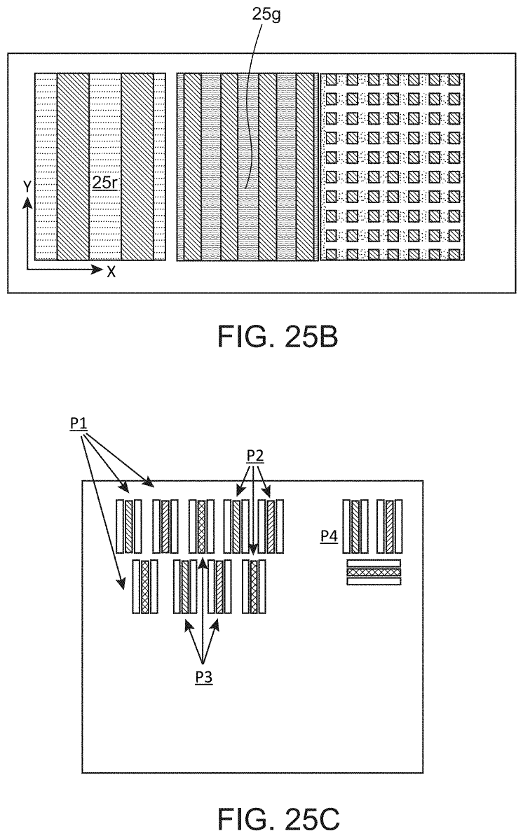

FIG. 4C schematically shows a μ-display 2 with three different types R, G, B of μ-LEDs 20R, 20G, 20B. The μ-LEDs 20R emit red light during operation, the μ-LEDs 20G emit green light during operation and the μ-LEDs 20B emit blue light during operation. A red light emitting μ-LED 20R, a green light emitting μ-LED 20G and a blue light emitting μ-LED 20B are each grouped on the carrier 200 to form a triple 20. The triple 20 of μ-LEDs 20R, 20G, 20B are arranged in rows and columns on the carrier 200. The individual μ-LEDs each form a subpixel of each Triple 20 and thus represent one pixel. The pixel pitch PP1 or PP2 is measured from the center of one pixel to the center of an adjacent pixel. If the values for PP1 and PP2 are different, the larger value is defined as pixel pitch PP. In addition to this representation, in which the three μ-LEDs are arranged in a row as subpixels, there is also another representation, for example in the form of a triangle or offset as shown in FIG. 25C.

One aspect for light generation proposes an adaptation of the emission characteristics of an LED based on the principle of induced emission by means of a slotted antenna structure. In concrete terms slotted antenna structure are used. Such slotted antennas are normally used to generate highly directional radiation from electromagnetic waves.

In contrast to a normal antenna, in which a metallic structure in space is surrounded by air (as a non-conductor) and thus radiates the electromagnetic wave, this is the opposite with the slotted antenna. The slotted antenna has an interruption, the slot, through which the electromagnetic radiation is emitted. The geometry of the slits determines the wavelength and radiation pattern. In the simplest case, the length of the interruption or slot is a multiple of the wavelength, with the radiated wave being strongly directed in the plane of the antenna. The radiated power can become very high.

Light is a type of electromagnetic radiation in the range of approximately 300 nm to 700 nm. While this requires structures of the same order of magnitude, the highly directional emission can simplify the use of other optics.

The following embodiments provide some suggestions for such slotted antennas, implemented and realized in different semiconductor material systems. The idea is based on the discovery that the wavelength emitted by electromagnetic radiation is mainly independent of the material used but depends mainly on the dimension of the slot of the waveguide. Therefore, a single material system can be used to produce light of different colors. This is because LEDs do not produce monochromatic light, but usually a broader spectrum. Thus, the emission can be easily adjusted over a range by the geometry of the slot antenna.

Slotted antennas also force an increase in spontaneous radiative recombination, which makes light generation faster than in conventional LEDs without such an antenna structure. At the same time, radiative recombination is preferred to non-radiative recombination, which improves the ratio even for very small structures. This characteristic also allows using GaN based material systems to generate red light. Because of their lower dependence on the material system, light emission induced by slotted antennas can also be less dependent on parameter changes such as temperature, carrier density and the like.

However, the light emission is dependent on the current, which allows some kind of current modulation to control the intensity of the emitted light. Driver circuits can be simplified without losing speed when switching the light on or off. For example, PWM modulation can have less steep rising and falling edges. The small structure also makes it possible to use more than a single emitter per pixel, which provides redundancy against failure or process variations that lead to a broadening of the light spectrum. Using more than one emitter of the same color not only provides redundancy but also a higher resolution in light intensity and therefore more brightness gradations.

FIG. 6 shows the main elements of a version of a light-emitting device using the principle of antenna-induced emission. A light emitting device 1001 is placed on a carrier 1007. The carrier may contain driver circuitry, current and voltage sources and the like to provide power to the light emitting device. The light-emitting device comprises a semiconductor stack 1003 or a LED nanopillar extending substantially perpendicular to the main surface of the carrier 1007. The LED nanopillar comprises a plurality of semiconductor layers including an active layer. In some variants, the active layer of the LED nanopillar 1003 comprises a quantum well or a multi-quantum well structure. Quantum wells are also conceivable. The end sections of the stack 1003 are formed with highly doped μ- or n-contacts. The carrier 1007 has an electrical second contact 1005, which is connected to the corresponding contact of the LED nanopillar to supply energy to the light emitting device.

The light emitting device is located in a cavity 1010 of an electrically conductive structure 1004. Structure 1004 has an upper major surface 10042 and a lower major surface 10041, the latter being located adjacent to the substrate. To prevent an electrical short circuit between the electrically conductive structure 1004 and the carrier, an insulating layer is provided between carrier 1007 and the structure. The cavity in the electrical structure 1010 comprises a width w and a length l (not shown). Width w is approximately the size of the LED nanopillar. The LED nanopillar 1003 is also insulated so that the conductive structure does not cause a short circuit with the column. The electrically conductive structure 1004 is made of or contains metal. In some variants, copper, aluminum, gold, silver or other suitable metals are used. Together with the cavity, the electrically conductive structure forms a slotted antenna structure in which the radiation source (the light-emitting device) is placed. The length l of the cavity is adapted to the desired length of the emitted radiation.

The electrically conductive structure and the LED nanopillar are covered with an insulating but optically transparent material 1006. Material 1006 optionally extends to the sidewalls of the electrically conductive structure 1004. Contact layer 1002 is applied to the insulating material and in contact with the corresponding contact of the LED nanopillar. At this point, the contact layer 1002 can also be omitted and the electrically conductive structure itself can form a contact. In particular, in this embodiment, the electrically conductive layer would be conductively connected to the electrical contact facing away from the carrier, so that they are at the same electrical potential. The insulating layer can then, as described below, include converters or structures to convert the light in its color or to shape the radiation further.

During operation, charge carriers are injected into the active layer of the light-emitting device, for example into the quantum well structure. The antenna structure now forces an increase in spontaneous emission. The recombination leading to light emission increases strongly compared to non-radiative recombination. Because of the specific length of the cavity, an electrical dipole is formed and directed emission of light at a wavelength based on the length of the cavity is preferred. Different cavity lengths will therefore lead to the emission of light at the corresponding wavelength.

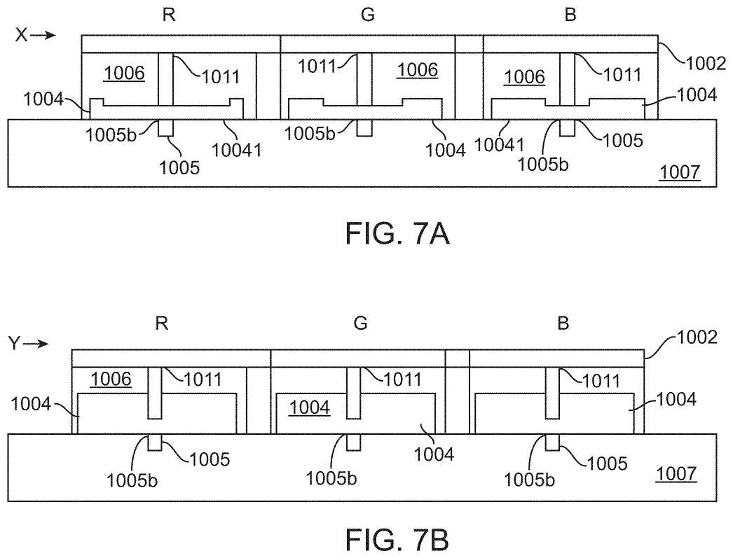

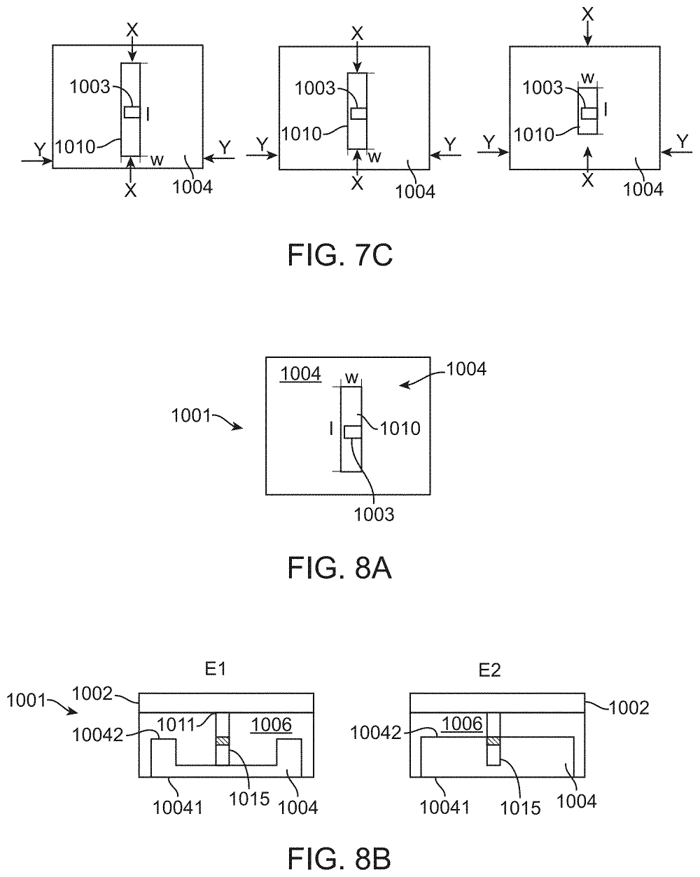

FIG. 7A to FIG. 7C illustrate an example of light-emitting devices based on the proposed principle, which are capable of producing light of different colors. FIG. 7C shows the top view of the three light-emitting devices. FIG. 7A illustrates the same devices in sectional view along the X-X-axis as shown in FIG. 7C. FIG. 7B also illustrates the three fixtures along the Y-Y-axis.

As shown in FIG. 7A, the light-emitting devices R, G, B are arranged on a carrier 1007 and electrically contacted with its n-contact surface 1005b to corresponding second contacts 1005 on the carrier 1007. Each light emitting device comprises a LED nanopillar 1003 formed as a semiconductor stack. The semiconductor stack has an n-contact 1005b and a corresponding p-contact, which is contacted by a common p-doped layer 1002. It should be mentioned that p- and n-contacts could be exchanged without deviation from the proposed principle. Each light emitting device also comprises an active region (not shown here) where recombination takes place. Layer 1006 is electrically insulating. Thus, the LED nanopillars or semiconductor layer stack extends beyond the level of the electrically conductive layer.

As shown in FIG. 7C, the LED nanocolumns 1003 are arranged in a cavity 1010 of an electrically conductive structure 1004. More specifically, the LED nanopillars, or semiconductor layer stacks 1003 are placed as an insulated wire in the center of the cavity 1010.

The electrically conductive structure has a rectangular shape but can also have a different shape suitable for induced emission. However, the semiconductor layer stack must be arranged in the cavity. In the disclosed embodiment, the electrically conductive structure of the light emitting devices R, G and B comprise the same dimension and this is in the range of 1 μm² to 2 μm². Each cavity 1010 comprise a width w and a length l and has a rectangular shape. The width of the cavity approximately corresponds to the width of the LED nanopillar or is slightly larger so that the LED nanopillar does not cause a short circuit. Between the column and the carrier is either air or other gas or an insulating solid. A spontaneous emission is induced by the length l of the cavity, the wavelength of which depends on the length l. Very simplified; the structure resembles a dipole slot antenna, where the length of the cavity corresponds to half the wavelength to be transmitted. For a wavelength of 400 nm, a cavity of approximately 200 nm is used. The actual cavity can be shorter by a shortening factor that takes into account a physical parameter.

Referring to FIG. 7A, an electrically conductive structure in sectional view along the X-X-axis forms a “U” cross-sectional contour, in which the cavity forms the inner part limited by the outer flanks. The individual electrically conductive structures 1004 of the different elements are connected to each other (not shown here). The semiconductor layer stack extends through the cavity and thus the electrically conductive structure. The electrically conductive structure is surrounded by an optically transparent insulating material 1006 and thus completely covered. The material 1006 also fills the cavity and extends up to the first contact 1011. A common contact layer 1002 is applied to the insulating material 1006. The common contact layer 1002 electrically contacts each of the LED nanopillars. FIG. 7B illustrates the light emitting devices along the Y-Y sectional view of FIG. 7C.

Now referring to FIG. 9 to illustrate the effect that the electrically conductive structure or metal plate has on the emission characteristics of a light emitting device. The figure shows a comparison of a simulated far-field radiation pattern of a slotted antenna with the dipole radiation pattern of a bonded charge oscillator. Both result in almost the same radiation pattern, indicating that the light-emitting device may behave similarly to a bound charge oscillator.

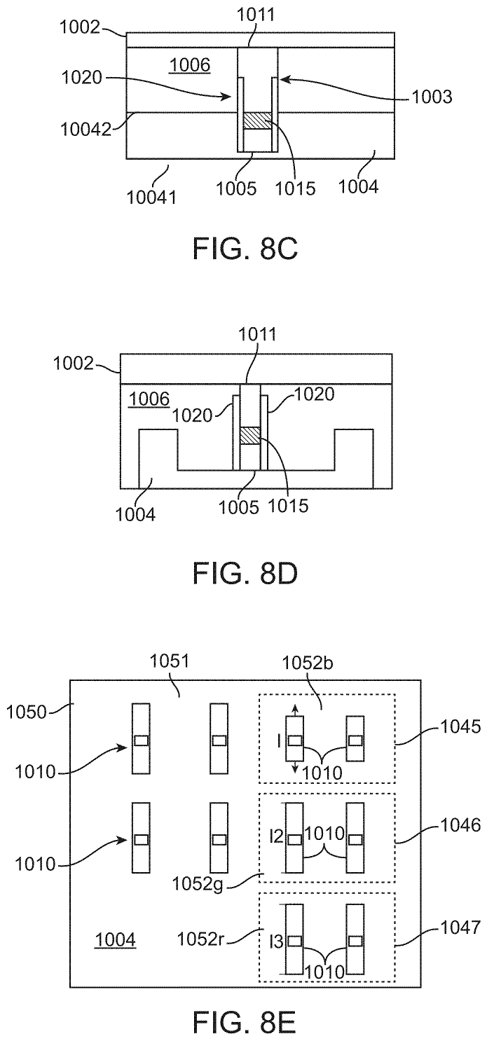

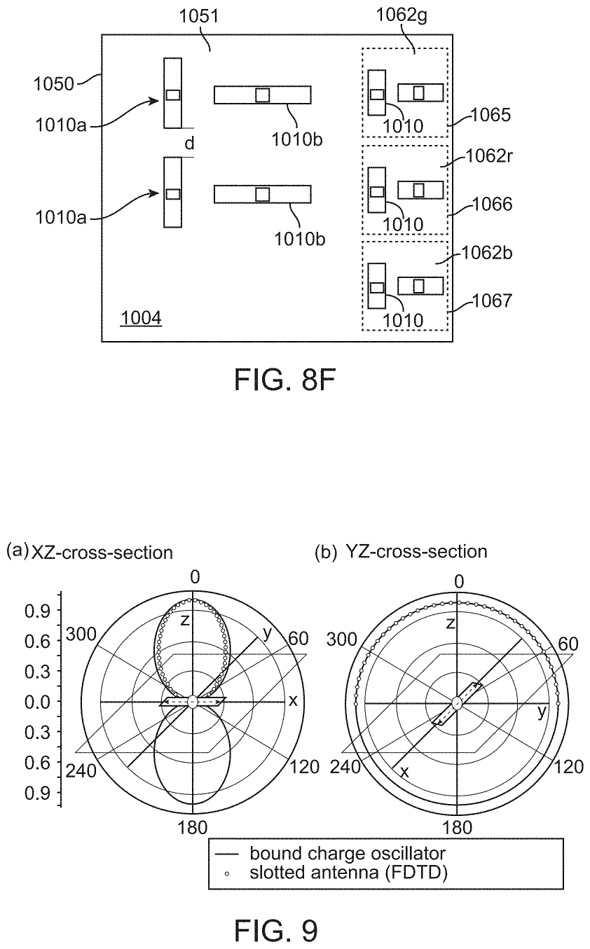

Now referring to FIG. 8A and FIGS. 8E and 8F. FIG. 8C shows a light-emitting device similar to those previously explained in detail.

Now referring to FIG. 8E and FIG. 8F, which show the top view of a μ-LED array comprising two or more light-emitting devices with substantially the same cavities. The small dimension for each light emitting device allows the implementation of densely packed μ-display arrays. Since, for example, a light emitting device according to the proposed principle comprise an area of approximately 1 μm², several such devices can be arranged side by side without exceeding an edge length of 4 μm. This creates a redundancy by which damaged devices can be replaced. On the other hand, it allows a better resolution, which allows finer intensity gradations. The small size is particularly suitable for monolithic integration with a large number of such light-emitting devices.

FIG. 8E illustrates an example of monolithic integration of a pixel comprising four light-emitting devices arranged as a group 1051. The μ-LED array shares several common structures, in this case the electrically conductive structure 1050 formed as a metal plate, the insulating layer on the metal plate, and a common contact layer. The metal plate comprises four cavities 1010 arranged in a 2×2 μ-LED matrix 1051. Adjacent cavities 1010 are arranged parallel to each other. The cavities are covered by a transparent insulating material (not shown in this top view) together with the LED semiconductor layer stacks or nanopillars placed in them. A common electrical contact layer (not shown) is applied to the insulating material. The contact layer contacts the LED nanopillar from one side. On the bottom side (not shown) underneath the metal plate, similar contacts are formed for the LED nanopillars.

During operation, the cavities can be controlled separately in pairs or all at once. In some variants, all cavities are switched at the same time. This allows a high resolution in terms of intensity to be achieved. Due to process variations, temperature effects and other physical properties, the spectrum of each cavity is broadened, resulting in a slightly increased spectrum. By selecting a slightly different length of the cavity, a so-called white light spectrum can be achieved for the light emitted by the four cavities. By placing a color filter on the arrangement with the four cavities, the desired color can be selected.

The larger area occupied by the four cavities compared to a single light-emitting device also simplifies the placement of an optical element or color filter on the array. In an alternative solution, six such illuminators can be arranged using shared structures to create three sub-pixels by placing a corresponding color filter over a pair of light emitting devices. Alternatively, the semiconductor layer stack can be configured with different material systems and cavity lengths so that different colors can be produced. Such an embodiment is illustrated in FIG. 8E, in the right part of the metal plate structure. Six light-emitting devices are arranged in pairs, with pairs of 1052b, 1052g, 1052r of identical devices arranged in parallel. The first pair is adapted to emit light that has the shortest wavelength, e.g. blue light, so their cavity has the shorter length l1. A blue filter 1045, illustrated by the dotted line, is placed on the two cavities 1010, which shapes the light or, if necessary, filters out the unwanted parts of the blue spectrum. The filter can also be omitted due to its directionality. The second pair of light emitting devices 1052g also includes a pair of cavities arranged parallel to each other with a corresponding LED nanocolumn structure arranged in the center of the cavity. The length l2 is greater than the length l1 and corresponds for example to a green color. An optional forming or filter element 1046 is also provided. Finally, the third pair of light-emitting devices has cavities with the greatest length l3. An optional forming or filtered element 1047 is also provided here, which blocks unwanted parts of the emitted spectrum and shapes the radiation pattern.

The distance between the cavities of each pair is set so that their crosstalk is either minimized or adjusted to a distance that may be beneficial for other parameters such as emission characteristics, process control, and the like. The distance between two different pairs of the same color is adjusted to minimize crosstalk. If necessary, the metal plate implementing the slotted antenna can be separated to reduce the influence of the metal structure. In some variants, the μ-LED array then comprises only one common contact layer structure.

FIG. 8F shows a different arrangement of light-emitting devices using a common structure. The slotted antenna structure comprises not only a directional emission, but can also influence the polarization of the emitted light. For a dipole antenna structure such as a slotted antenna, the electric field vector E is in the same direction as the dipole.

In FIG. 8F, the group of four light-emitting devices is arranged in such a way that two light-emitting devices are arranged in parallel, but the pairs are offset from each other by 90°. In other words, the cavities 1010a are parallel to each other but rotated 90° to the cavities 1010b. This means that two light-emitting devices are arranged in such a way that their cavities are perpendicular to each other in the shared metal plate. During operation of the devices, the dipole emission of the two devices will also be rotated, resulting in a common rotating electric field vector. Cavities 1010a are arranged in a row separated by a distance d of the common metal plate. Thus, the radiation pattern of the versions of the arrangement of FIGS. 8E and 8F is different due to the orientation of the cavities (parallel and 90° offset).

Each cavity 1010b of the light emitting devices is arranged perpendicular to the corresponding cavity 1010a of the devices so that its extension of the cavity 1010b of the device passes through the center and the LED nanopillar of the corresponding other device. The length of each cavity 1010a and 1010b of light-emitting devices is the same in the illustrated example. However, similar to the above, the length may be slightly different, thus spreading the spectrum. This can be useful when an adjustable polarizing filter is placed over the devices, as such filters can be used to change color selectively.

The right side of the illustrated example of FIG. 8F shows a structure to obtain different colors red, green and blue using converters. For this purpose, each subpixel 1062r, 1062 and 1062b comprise two light-emitting devices with their corresponding cavities 1010, arranged perpendicular to each other as described above. In some variants, they may also be arranged parallel or in any other configuration. The length of the cavities 1010 of each subpixel is selected with a value that causes the light-emitting device to emit a wavelength suitable for color conversion. A shared converter is arranged above the light emitting devices in subpixels 1062g to convert the light (e.g. blue light) emitted from the cavities to a green color.

Also a 1066 converter is used to convert the light from the light emitting devices from subpixel 1062r to red. Finally, in this example a color filter 1067 is used to filter unwanted parts of the spectrum for subpixel 1062b. In the example presented, the cavity lengths are set to a value that causes the light-emitting devices to emit blue light. If the cavity for subpixel 1062b already emits with the desired color, filter 1067 can be omitted.

In some variants, it may be appropriate to select a different length for the cavities depending on the available converter or process requirements. For example, a converter can be used to convert blue light to red or green light to red for red light generation. In the latter case, the cavity length requirements can be reduced, making it easier to process the device.

FIG. 8A illustrates another aspect. The figure shows the top view of a light-emitting device 1001 according to the proposed principle. The cavity 1010 in the electrically conductive structure, for example a metallic plate has a length l and a width w. The width w is set to be slightly larger than a width of the LED nanopillar 1003.

Furthermore, the LED nanopillar 1003 is slightly shifted and not completely centered. This means that the LED Nanopillar 1003 is positioned with one side adjacent to one sidewall of the cavity 1010, which creates a small gap between the other sidewall of the cavity and the opposite side of the LED nanopillar. In order to avoid unwanted leakage current between the LED nanopillar and the sidewall, the LED nanopillar is covered with an insulating layer at least on the longer sidewalls of the cavity opposite sides. In the current example, the LED nanopillar is covered with insulating material on each side. In an alternative version of FIG. 8A, the semiconductor layer stack or nanopillar 1003 is centered in the cavity. An area of the cavity between the semiconductor layer stack 1003 and the electrically conductive layer is filled with a transparent electrically insulating material.

FIG. 8B shows yet another aspect. The LED nanopillar comprises an active region, i.e. one or more quantum well layers in which radiative recombination takes place. In FIG. 8B, the first contact 1011 forms a p-contact, which is connected to the conductive layer 1002. The semiconductor layer stack or LED nanopillar is mainly surrounded by an insulating material 1006. The metal layer forming the slotted antenna forms a U-shaped structure with an upper major surface 10042 and a lower major surface 10041, but this shape is not necessary. In particular, the metal structure can also be completely planar and have only the cavities. The LED nanopillar is placed in the recess or cavity. The active area is formed at the level of the upper main surface, so the end of the active layer facing contact 1011 corresponds approximately to the level of the upper main surface of the cavity. In other words, the active area of the LED nanopillar is placed in cavity 1003 so that one end of the active area is located at approximately the upper major surface 10042 of the cavity.

FIG. 8B, which illustrates the rough view along the Y-Y-axis, shows the arrangement of the active area in the cavity. One end, for example the end of the active area closer to the first contact 1011 is placed at a level of the upper main surface 10042 of the cavity. The active area itself is thus placed closer to the upper opening of the capacity. Such an arrangement and especially the position of the active area within the cavity has an influence on the emission characteristics. In addition to this example, the active layer can also extend further into the metallic cavity.

FIG. 8C and FIG. 8D show some other aspects of light emitting devices to reduce crosstalk further or to improve emission and optical properties. The light emitting device in FIG. 8C along the Y-Y-axis comprises a coating layer 1002, which can be structured and transparent to allow emission in that direction.

Cover layer 1002 is electrically contacted with first contact 1011, the width of which is greater than that of the remaining LED nanopillar 1003, which is placed in a cavity 1004 with a lower main surface 10041 that can be placed on a chip driver circuit or other device. The LED Nanopillar 1003 also comprises a lower second contact 1005 and an active area 1015. Active region 1015 is formed by a large number of quantum wells or quantum dots, but in some other variants it may also have a single quantum well or a multi-quantum well.

The active region 1015 is arranged in the cavity in such a way that its cover layer, which is opposite the first contact 1011, is placed at a level corresponding to the upper main surface 10042 of the metallic slotted antenna structure forming the cavity. The LED nanopillar is covered with a transparent insulating layer 1020 or passivation layer 1020 within the area of the cavity at its sidewalls. The layer prevents unwanted electrical contact between the LED nanopillar and the surrounding cavity structure. The passivation layer 1020 runs from the second contact 1005 towards the area of the first contact 1011.

FIG. 8D shows the execution along the X-X view. The active area 1015 is located in the cavity recess, the passivation layer 1020 formed on the sidewalls of the LED nanopillar runs from the bottom of the cavity to the upper part of the LED nanopillar adjacent to the first contact. It should be noted that although the active area is arranged with one side at the level corresponding to the upper major surface, other arrangements can be formed. For example, the active area can be formed slightly below the upper major surface. Alternatively, the active region may be formed so that it crosses the level of the upper major surface.

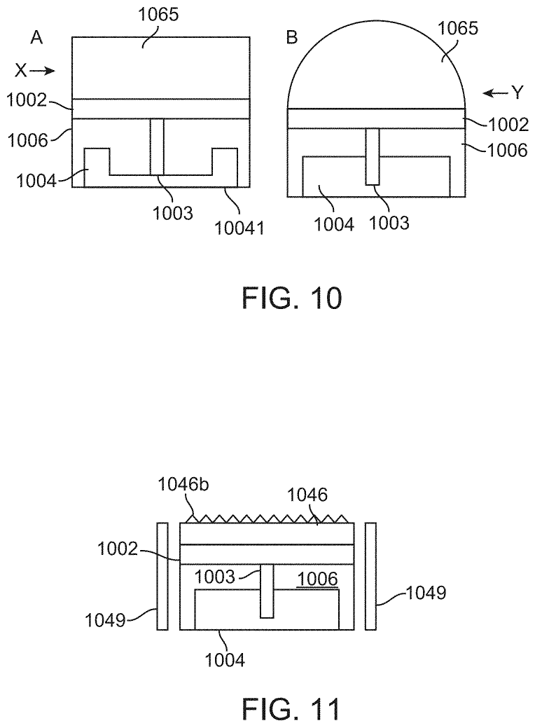

FIG. 10 shows some examples of the geometry for a coating, mesa structure, converter, color filter or any other structure placed on the light emitting device. Due to the emission characteristics of the device, a structure need not have a symmetrical structure, but its geometry may vary as shown in the figures. In the illustrated example, structure 1065 (for example a color filter) comprises the shape of a half cylinder in subfigure A. In figure B, structure 1065 may have the shape of a hemisphere. This is due to the narrow emission characteristic of the device.

FIG. 11 shows another example that uses color filters and separators to reduce crosstalk. The light emitting device has a color filter 1046 on contact layer 1002. The color filter 1046 comprises a top layer structure 1046b to improve coupling of emitted light into another material. The structure can be periodic, i.e. a photonic crystal or a similar structure. Also non-periodic structures such as simple roughening can be used to increase the coupling of light. The light emitting device also comprises transparent separators 1049 on almost every side of the pixel and the light emitting device. The separators 1049 comprises a height roughly corresponding to the height of the light emitting device.

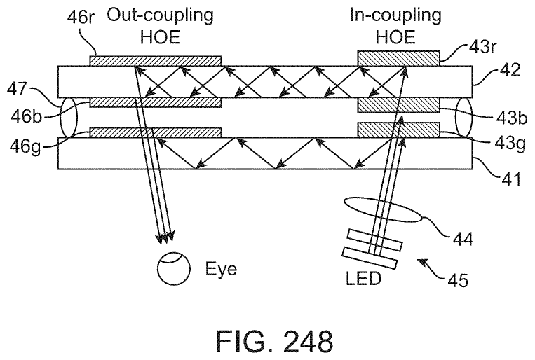

The device shown is manufactured in a monolithic display version with cavities of the same length. This display is used as a light-emitting element for the example of a light guide according to FIG. 248 described below.

FIG. 12 shows a growth carrier 1, especially a sapphire substrate. This substrate is particularly suitable for the GaN material system. In a first step, matching layers or other measures are taken to obtain a surface that is as planar as possible. Then a growth layer 3 is deposited, on which an insulating masking layer, e.g. of SiO is deposited. This is then structured so that elongated rectangular areas are exposed. The areas are parallel to each other and essentially the same size. A number of, for example six, material volumes 7 in the form of polyhedra, in particular cuboids, are epitaxially grown onto these free areas. This core can be doped so that it can conduct current well. An active layer 9 is then applied to the surface and sidewalls. This in turn is followed by an additional layer 11. The latter is of a different doping type than the core and can, for example, also include a current-expanding layer in order to distribute charge carriers evenly over the entire area, i.e. surface and sidewalls. In this way μ-LEDs are produced in cuboid or Ingot shape.

In FIG. 12 the growth, layer 3 shows n-doping and especially GaN. Masking 5 comprises silicon dioxide or silicon nitrogen. The material volumes 7 show a material identical to the growth layer 3. The active layer 9 contains In- or Al-GaN-MQW (multi quantum wells). The additional layer 11 is p-doped and also based on GaN. Other material systems are also possible. The structures thus formed are substantially parallel to each other with longitudinal axes and have the same size or geometry. Variations result from process fluctuations.

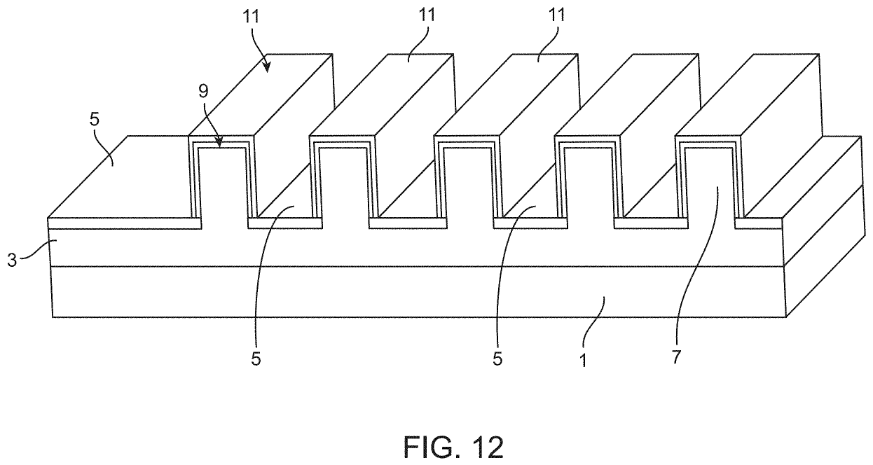

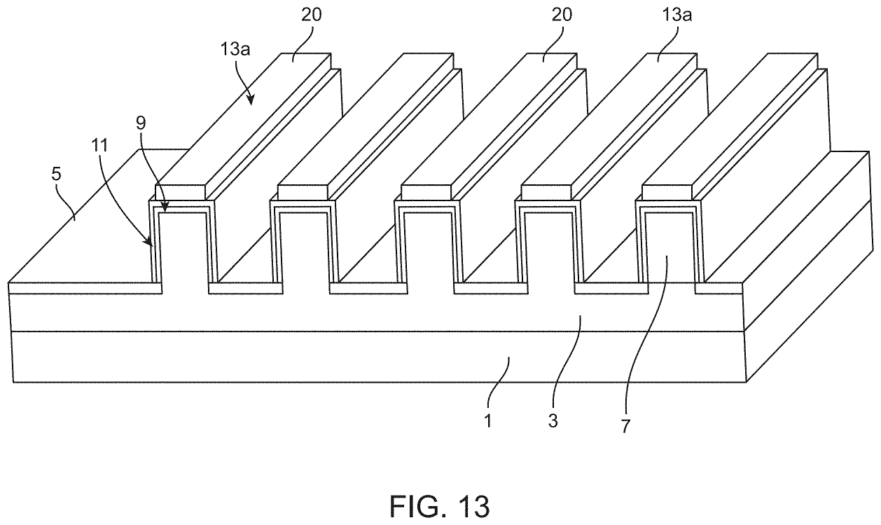

FIG. 13 shows a further step in the production of a proposed electronic component in the same cross-sectional view. In FIG. 13, a mirror metallization 13 or a mirror first metallization 13a providing a solder is created on the surface of the material volume 7 covered with the active layer 9 and the other layers 11 on the surface opposite to the growth layer 3. These thus form the p-contacts. The mirror metallization 13 is thus located on the upper side of the cuboids and contacts the p-doped layer underneath over the entire length. This creates a large-area contact that promotes an even current distribution into the p-doped layer.

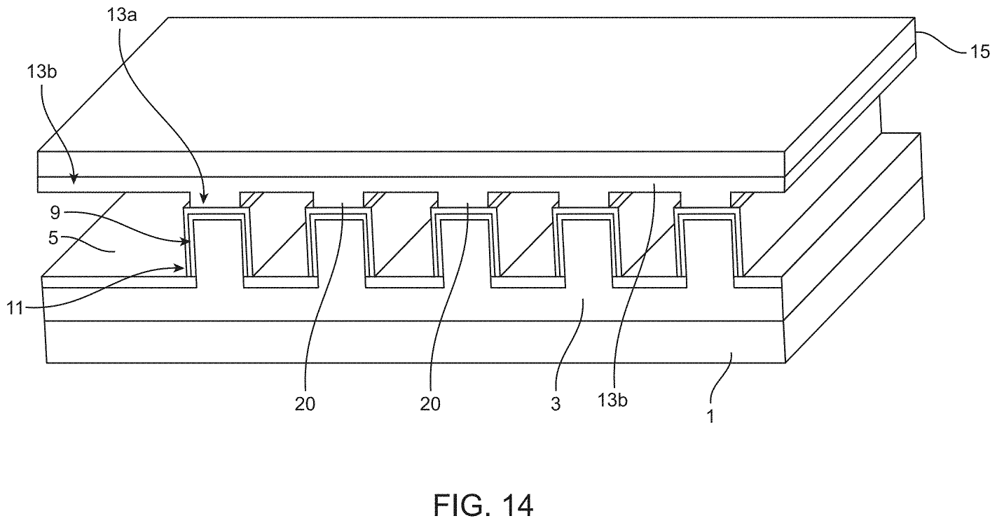

FIG. 14 shows a further step in the production of a proposed electronic component in a cross-sectional view. In this, a solder metallization layer 13b is first bonded to a main surface of a flat carrier 15 and then this is provided. The solder metallization layer 13b contains a number of contact strips whose length corresponds to the length of the cuboids or bars and the contacts 13a. In addition, the distance between the contact strips is chosen to correspond to the distance between the bars on substrate 1. The carrier with the metallization is placed and aligned over the cuboids and then bonded or otherwise fixed to them. This ensures a contact and the metallization 13b forms a common connection for all cuboids. The first metallization 13a can have the same material as the solder metallization layer 13b.

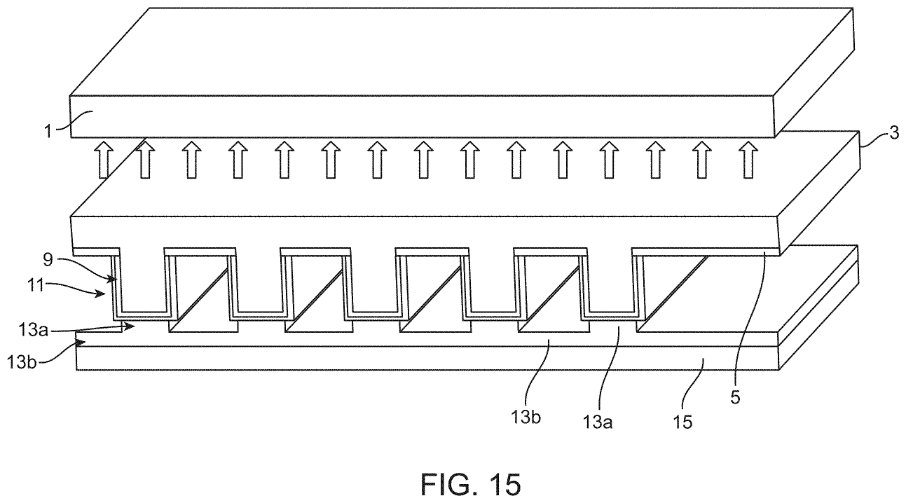

Then, as shown in FIG. 15, the carrier is flipped and the growth carrier or sapphire substrate 1 is removed from the growth layer 3. This process includes a laser lift-off process (LLO (Laser Lift-Off)).

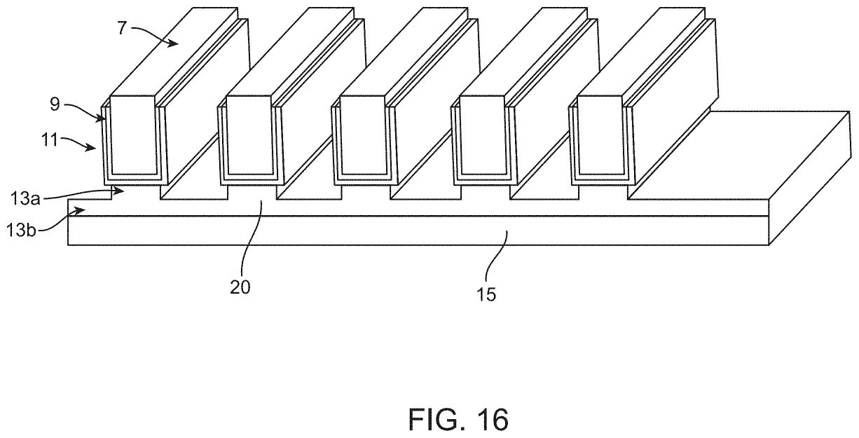

FIG. 16 shows a further step in which the growth layer 3 and parts of the mask were removed. This removal is carried out in two steps, in which the growth layer is first removed to a large extent. Then the element is processed in such a way that an area 7 protruding is left over, in this area it is left out of the further etching process, especially an etching process for the masking layer 5. As shown, a structure results in which the active layer 9 and the further layer 11 are slightly recessed with respect to the surface of the area 7. The etching process can be done by reactive ion etching or plasma etching.

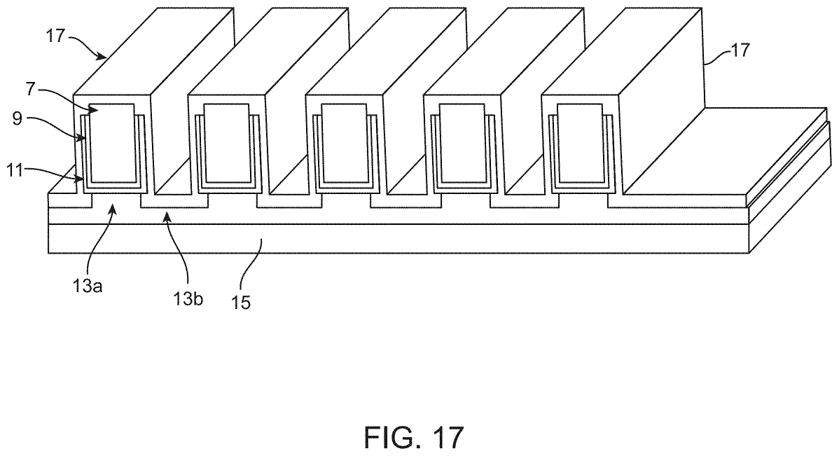

The areas now exposed at the surfaces are completely surrounded by a passivation layer in a subsequent step in FIG. 17. This contains SiO and grows over the entire surface along the long side of the cuboids. Likewise, the surface of metallization 13b is covered by a passivation layer, which also extends into the undercut between trench and metallization 13a, 13b. Although the front side is exposed in the illustration shown, it goes without saying that passivation is also carried out here to protect the underlying layers from oxidation or damage.

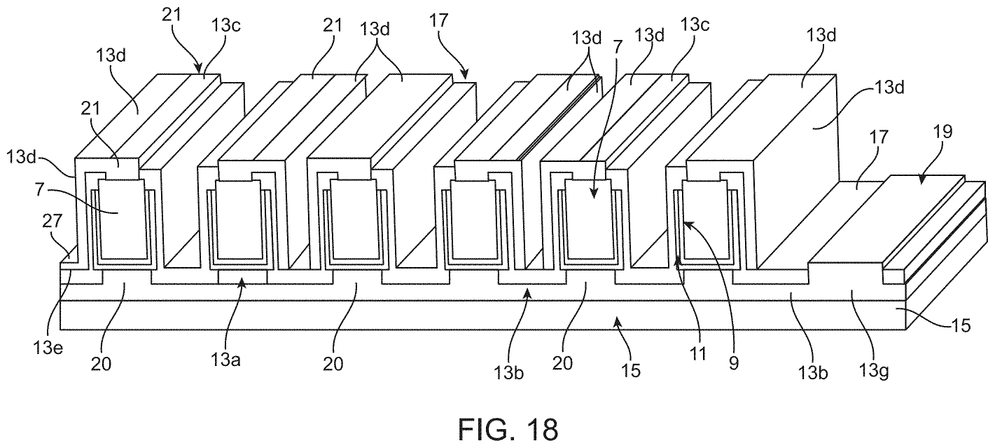

According to FIG. 18, a photo mask is now applied (not shown) and the passivation along the surface of the cuboid is opened again in a strip by an etching process and the underlying core is exposed. The width of the strip is slightly smaller than the width of the surface of the core. This means that a passivation remains even along the longitudinal edge of the core. Then, in a further step, a further metallization 13c is applied to the strip. This forms the n-contact 21 for the μ-LED elements. In addition to the n-contact formed by a strip, the strip is also contacted by a metallization 13d on one side. The metallization 13d extends in this embodiment over the whole long side of the μ-LED element and also runs along the sidewall down to the passivation 17. Metallization 13d is reflective. The course of the metallization 13d is chosen in such a way that two metallizations 13d are applied to the sidewalls of the μ-LED elements opposite each other. In three adjacent μ-LED elements at least two metallization of the elements are opposite each other.

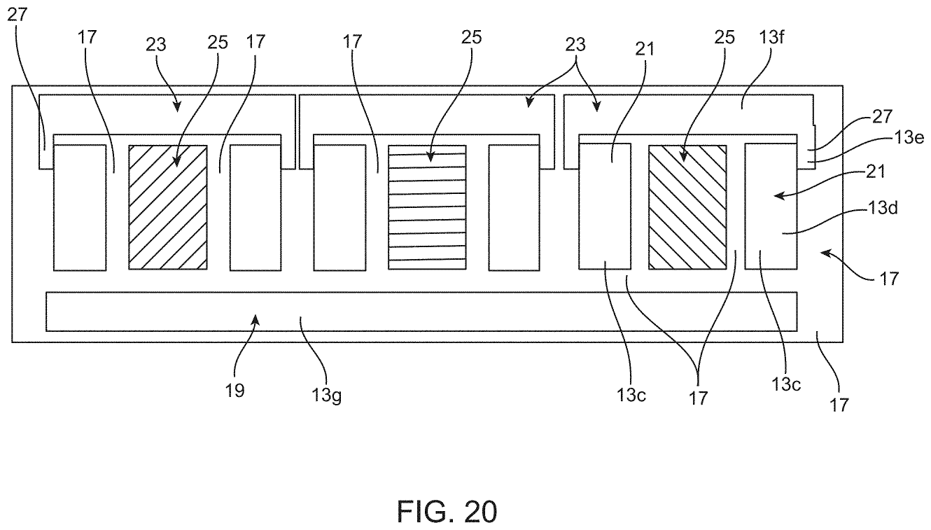

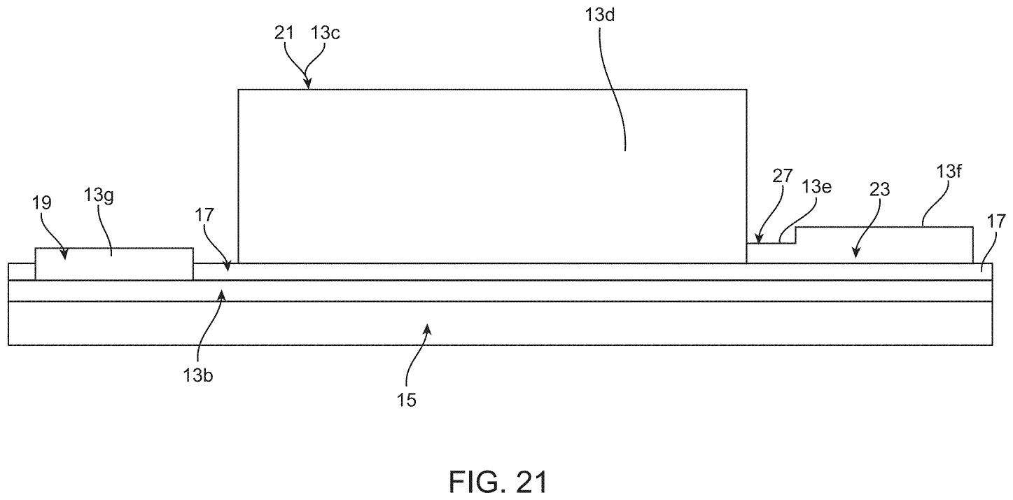

On one side, shown in FIG. 18 on the far left, another third metallization 13e is also deposited. This forms a metallic n-interconnection 27 to n-contact areas 23 attached to this surface of the passivation layer 17, which can be formed by means of fourth metallization 13f. The n-contact areas 23 can be created as contact strips and are shown in FIGS. 20 and 21.

In contrast, on the far right side of the pixel element shown in FIG. 18, the passivation has been removed in one area to expose the metallization 13b. This is then filled with the electrically conductive material 13g and forms a planar p-contact area 19, which is electrically connected to the p-contacts 20 by means of the solder metallization layer 13b. The p-contact area 19 has a large surface area and is thus suitable for bonding.

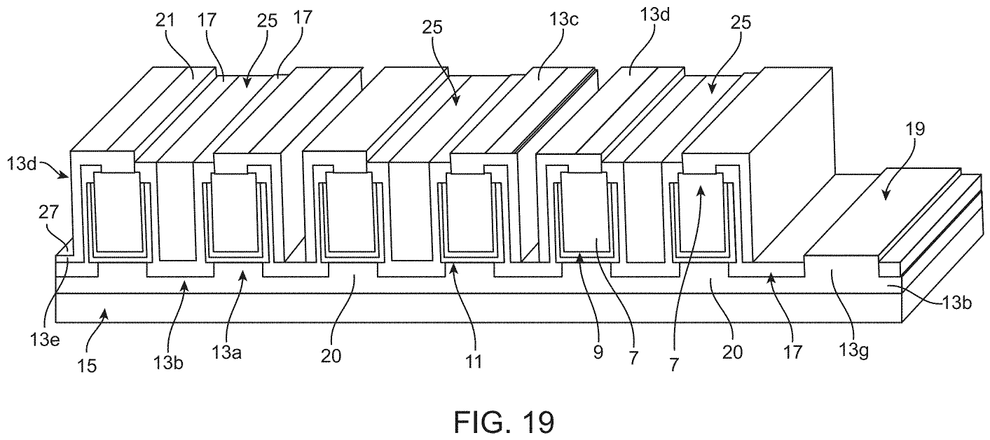

In the last step, as shown in FIG. 19, a part of the spaces between the two materials is filled with a converter material. In detail, however, only the space between the two materials is filled in where no reflective metallization is present. The area with opposite metallization 13d is left out. In other words, only the space(s) in between is/are filled with converter material where sidewall mirror metallization 13d facing away from each other were produced. The reason for this is that light generated in the active layer by the reflective metal layer is directed back towards the converter material. The converter material is filled up to approximately the height of the n-contacts 21. Thus, even slightly obliquely emitted photons can be converted in the converter.

The converter material 25 can, for example, be produced differently for each color in epitaxially generated micro light-emitting diodes of identical construction, which emit in the ultraviolet range, for example, so that the light is converted into red, green and blue light. With a number of six electrical μ-LEDs, a converter material 25 matched to one color can be used for every two adjacent μ-LEDs. Since two μ-LEDs are thus assigned to each color, there is redundancy for each color. In this way, a redundant RGB pixel is created.

FIG. 20 shows such a pixel arranged in a row with three subpixels each consisting of two μ-LEDs with converter material in between in top view. FIG. 21 shows a longitudinal section of the same pixel element. In this version, there is a common p-contact 19, which extends over the entire length of the pixel. The n-contacts 23 each contact a pair of μ-LEDs, with converter material arranged between them for converting light into different wavelengths. FIG. 20 shows in particular that n-contacts 21 are electrically connected to n-contact areas 23 by means of sidewall mirror metallization 13d and third metallization 13e deposited on the side of the passivation layer 17 facing away from the carrier 15, forming n-interconnections 27. N contacts 21 are formed as second metallization 13c. N-contact areas 23 are formed as fourth metallization 13f.

The n-contact areas 23 and p-contact areas 19 are configured in the form of connection strips or bus bars and can be arranged both on the front side for bonding contact wires and on the back of the carrier for connection as a “flip chip”. FIG. 21 also shows that p-contact areas 19 created by means of fifth metallization 13g are electrically connected by means of solder metallization layer 13b. This is electrically connected to p-contacts 20 created from first metallization 13a, which are not shown here.

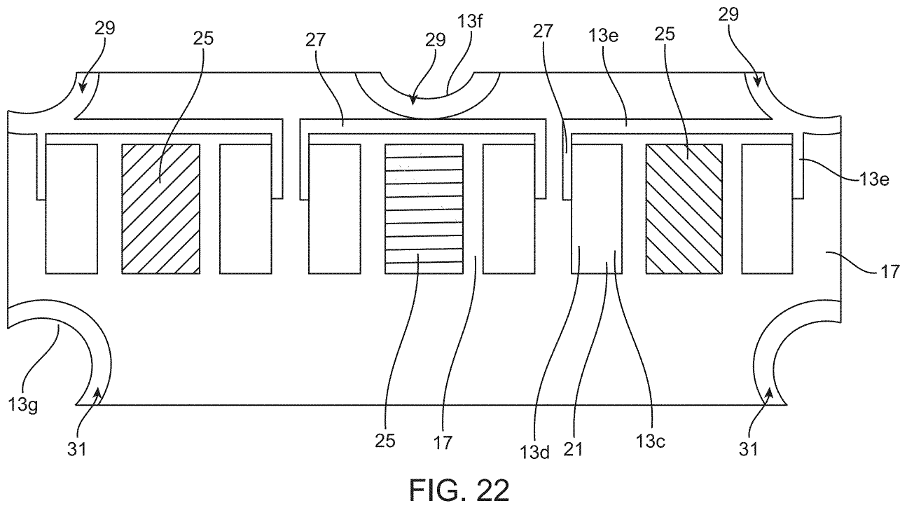

A further contact possibility of such a pixel is shown in FIG. 22. Here the pixel is configured as a surface-mountable module. In contrast to the previous version, the n-contacts 21 are electrically connected to n-contact vias or vias via intermediate line 27. The n-contacts 13d are connected to the intermediate lines through the metallization running along the sidewalls. For each n-contact, there is a through hole. The via 29 and the intermediate layers are electrically isolated from the metallization 13b (not shown here) and the carrier 15.

FIG. 23 shows the longitudinal section of the pixel element. Line 27 contacts the n-contact 13d and then leads to a via 29, which is connected to the n-contact 23 on the bottom of the carrier 15. Passivation layer 17 separates the p-contact 31 also on the bottom side and the metallization connected to it from the n-contact. The two contacts on the underside allow the pixel to be applied directly to a matrix.

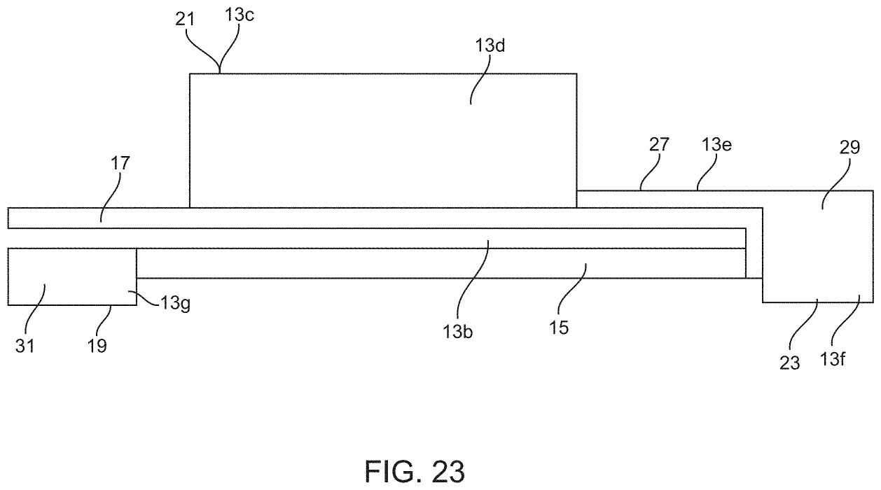

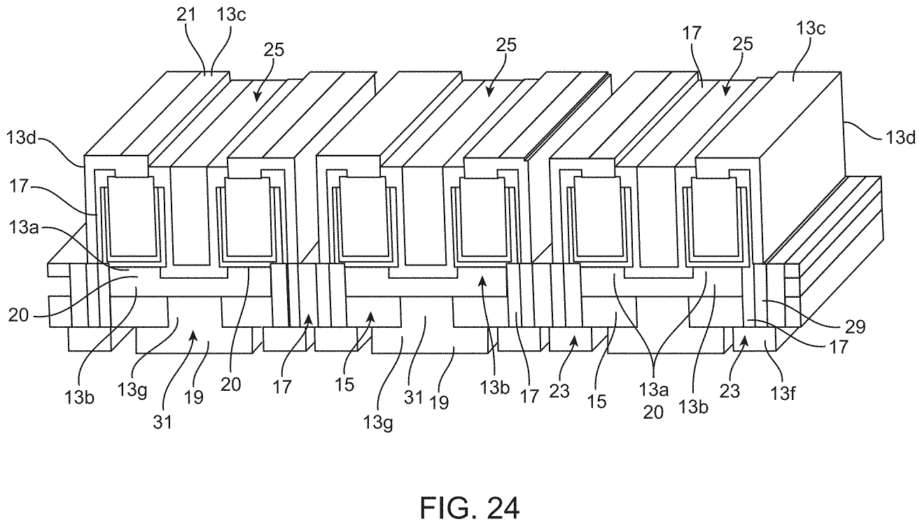

FIG. 24 shows a pixel redundant for red-green-blue light where the n-contact vias 29 have been formed where the sidewall mirror metallization 13d end. These run from the second metallization 13c, along the surfaces of the passivation layer 17 perpendicular to the substrate 15 to the surface of the passivation layer 17 facing away from and parallel to the substrate 15, from where via 29 are provided to contact the n-contact with areas 23 on the other side of the substrate. A via 31 is also provided, which is located at a point on the substrate opposite the center of the converter material and contacts the μ-layers. In this way, a redundant RGB pixel is created, since even if one μ-LED fails, the second one can still be controlled.

Three converter materials are provided in this embodiment. However, blue light does not need to be converted. Therefore, a diffusion or another material can be used instead of a blue light conversion material. In addition, individual pixel elements are shown here. It goes without saying, however, that a large number of pixels can be produced in this way. Thus, a large number of pixel elements can be produced monolithically in rows and columns. These form a μ-display or a module, which in turn can be placed and contacted on a carrier or a board with appropriate control electronics.

FIG. 25A is an addition to the embodiment of FIG. 24 with some more of the measures described in this revelation. The redundant pixel is covered with a dielectric and transparent top layer 37, which was subsequently planarized. The top layer also extends into the recesses between the pixels so that they are filled with a material. A light-shaping structure in the form of a photonic crystal 34 matched to the respective color is incorporated in the top layer 37. The crystal is made by one of the techniques described in this revelation. It can be formed by other structures shown in this disclosure in addition to the structure specifically shown here. The photonic structure comprises sections 35 and 36 of materials with different refractive indices, with material 35 corresponding to the top layer. The first structure 341 has sections of thickness D1, which is matched to the wavelength of the light emitted by the converter 25r. In the case of red light, thickness D1, and therefore the distance between sections of the same refractive index is the greatest.

Above the second subpixel with the 25g converter material, a photonic structure is arranged whose sections have the smaller distance D2 to each other. Above the subpixel with the converter material 25b, the distance D3 between materials with the same refractive index is smallest, the periodicity as the reciprocal of the distance is correspondingly largest. In this form of representation, the photonic structure is designed so that its periodicity is adapted to the frequency of the emitted light. This results in the different distances. In another embodiment, it may be intended to select common divisors or multiples of this periodicity, or to specify superlattices, in order to provide, if necessary, a photonic structure with equal distances between materials having the same refractive index. Alternatively, such a superlattice may be intended to provide frequency-selective selection, i.e. to deflect, scatter or reduce unconverted light as shown in some of the embodiments herein. In this way, the photonic structure can also act as a filter for unconverted light emerging from converters 25r and 25b. FIG. 25B shows a top view of this structure. In the left subregion the subpixel 25r, in the middle subregion the subpixel 25g and in the right subregion the subpixel 25b are each represented with a photonic structure. The photonic structure of the first and second portion is formed as a so-called one-dimensional photonic structure. Due to the bar, shape of the photonic structure, where the material of different refractive index is substantially parallel to the μ-LEDs and the converter material, a virtual band gap along the periodicity results. Light propagating along direction x is reduced by the photonic structure. In the right section for the subpixel 25b a two-dimensional photonic structure is shown whose periodicity is the same in both spatial directions x and y. This results in a suppression of light propagation of emitted light in both spatial directions and light is emitted in a narrow cone.

At this point, it should be mentioned that instead of the photonic structure shown, a microlens or other light-shaping structure can also be arranged above the individual subpixels. The same applies to other μ-LED arrangements. A microlens is produced photolithographically and seems to be possible even with smaller structures by inherent selective etching.

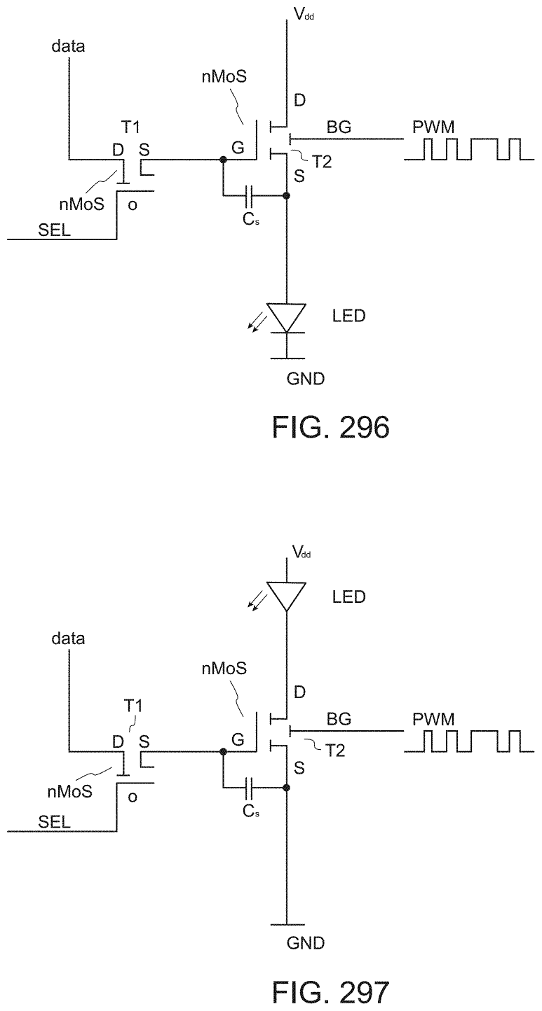

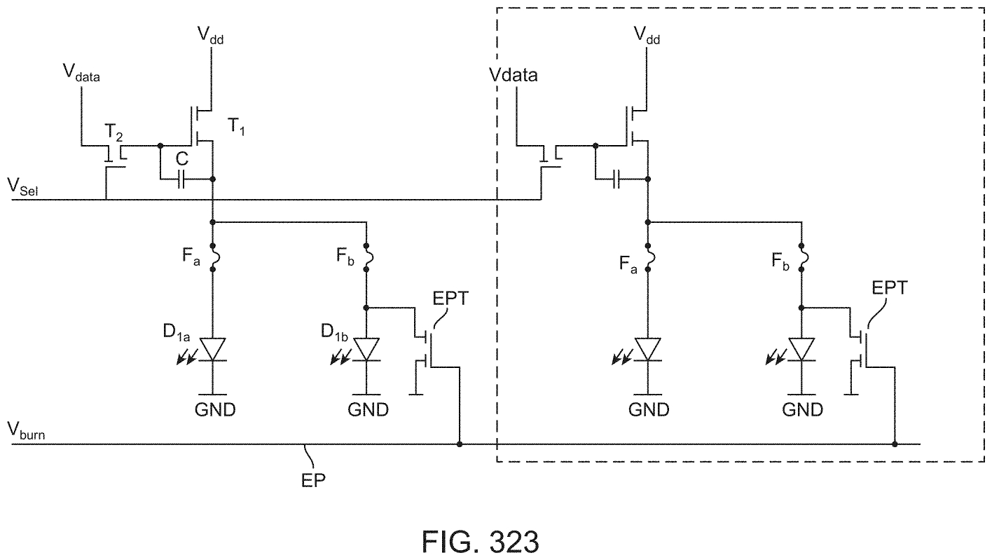

Referring again to FIG. 25A, the figure also shows examples of how to control the different subpixels. Of course, the skilled person knows that in an implementation it makes sense to use only one of the possible controls. The illustration is therefore schematic in nature. For all subpixels 25r, the connecting contacts 19 are connected to a common ground potential 40 each. Contacts 23 for the first subpixel with the μ-LED pair and converter 25r each lead to a voltage source 43 via a current driver transistor 41. Thus, both μ-LEDs can be supplied with current independently of each other in the embodiment for subpixel 25r. Thus, each μ-LED can be operated with lower current intensities for the same total intensity. For the middle pixel, a fuse 44 is connected between the current driver transistor and the μ-LED. This design is similar to one of the embodiments in FIGS. 323 to 327 in that one of the fuses is connected to an element that triggers the fuse, which is represented in the figure by reference sign 45. In the right subpixel 25b, both pins 23 are connected to a common current driver 41. The current driver transistor 41 may, inter alia, be configured as the driver transistors disclosed in this application. This includes, for example, the backgate transistor disclosed in this application (see FIG. 296ff).

Furthermore, the individual subpixels do not have to be arranged in parallel. Thus, there is the option of arranging one pair of μ-LEDs offset to the other two or even offset by 90°. FIG. 25C shows an example of such a pixel structure in top view. The left view shows two rows of sub-pixels of pixels P1, P2 and P3. These are arranged alternately, i.e. pixel 1 has the green and blue subpixels in the first row, while the red subpixel is centered in the second lower row. Pixel P2 is again arranged exactly the other way round, i.e. pixel 1 has the blue and green subpixel in the second row, while the red subpixel is centered in the first row. This results in a structure similar to the above, but the control is slightly different because the three subpixels arranged in a row belong to at least two different pixels. In the right part of FIG. 25C, the red subpixel with its cuboids is arranged perpendicular to the other two subpixel pairs. This results in a very small space consumption.

FIG. 26 shows an embodiment of a μ-rod M as it is manufactured separately. It serves as a basis for the production of the proposed electronic component with a variety of horizontally aligned μ-rods.

The μ-rod comprises a core 1, which is partially enveloped by a layer sequence 3. The layer sequence 3 is formed from inside to outside by a first layer 5, an active layer 7 and a second layer 9. The core 1 comprises n-doped GaN. The first layer 5 can also contain n-doped GaN, but with a different doping concentration. The active layer 7 comprises one or more quantum wells or quantum wells with InGaN. In the active layer 7, the charge carriers recombine and emit light. The second layer 9 is deposited on the active layer 7 and has p-doped GaN.

The μ-rod is generated on a sapphire substrate S on which an optional growth layer 2 of n-doped GaN is grown. A structured mask 4b of SiO₂ is deposited on this layer.

The μ-rod M is a regular hexagon in cross-section. At its tip, the diameter decreases and ends in the shape of a pyramid tip. Active layer 7 thus extends around the core and runs substantially from mask layer 4b to the tip. Likewise, the p-doped GaS layer completely encompasses the core and the active layer 7.

An emission wavelength is set by the shape and geometry, in particular the diameter of the μ-rods together with the material system used for the active layer and/or doping. The size of the μ-rods, especially the height, is in the range of a few μm, for example less than 20 μm or in the range of 5 μm. The diameter is also in the range of a few μm, for example 2 μm. In some aspects, a ratio of height to diameter is in the range of 1 to 1 to 4 to 1. After production, the μ-rod is removed from growth substrate 2 and further processed.

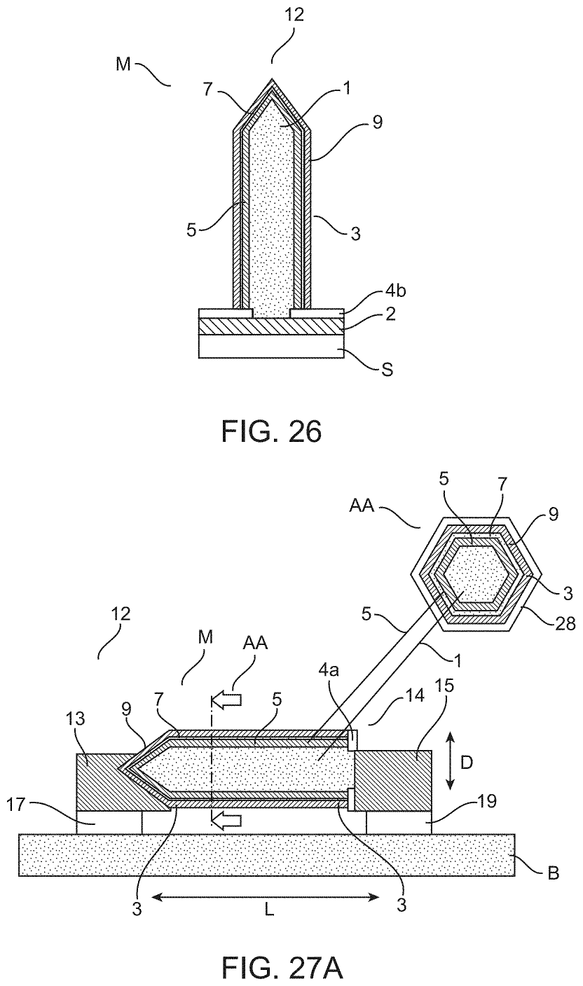

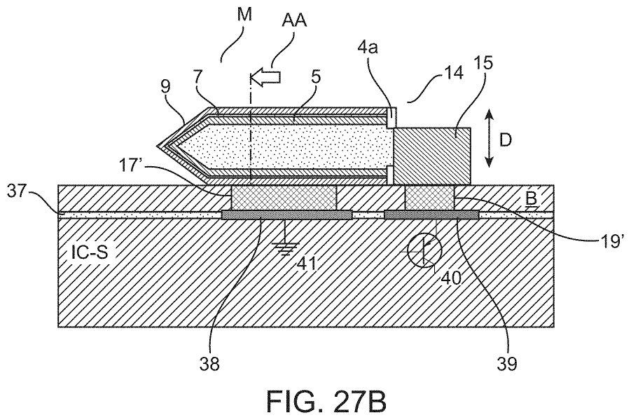

FIG. 27A shows an embodiment of a μ-rods M fixed on a carrier and electrically connected, thus forming a pixel or subpixel. The cross-section of the μ-rod is shown again in FIG. 27A along the sectional area AA in the upper right corner. The μ-rod has a cross-section in the shape of a hexagon with equal angles and edges. The layer sequence 3 from inside to outside is shown, with an additional current expansion layer 28 surrounding it on the outside. The current expansion layer is appropriately transparent and extends from the tip of the μ-rod to the insulating layer 4b.

The μ-rod M is now arranged lengthwise and substantially parallel to carrier B. At its first longitudinal end 12 the current expansion layer 28, or the p-doped layer 9, is connected to a first contact 13. The first contact extends along the lower half side of the pyramid or tip, and runs from tip 12 to the longitudinally extending area. Part of the contact is also attached to the top of the tip, so that the contact forms a kind of cap and partially encapsulates the tip of the μ-rod. The contact 13 is in turn applied to a contact area 17, which is connected to the carrier B and any electrical structures present in it. The contact area 17 extends beyond the surface of carrier B, which means that the μ-rod is slightly spaced from the surface of the carrier.

At its other rear end 14 core 1 is connected to contact 15. Due to the remains of the insulating masking layer 4a, contact 15 does not create a short circuit and is electrically insulated from layer 19 or even 28. The height of contact 15 reaches approximately to the upper part of the insulating layer 4a. This contact is also electrically and mechanically connected to a contact area 19. Contact areas 17 and 19 are substantially the same height, so that the μ-rod is aligned parallel to the surface of the carrier. The space between carrier B and the μ-rod is empty in this example, i.e. not filled with a reflective material. However, as explained further below, it is advisable to place a reflector structure below and around the μ-rod thus arranged.

FIG. 27B represents an alternative embodiment and supplement to FIG. 27A. In this embodiment, the μ-rod is directly in contact with the surface of carrier B. A contact area 17′ is provided for contacting, which is relatively large in area, making positioning easier. In another version, this contact area 17′ can also slightly protrude over the surface of carrier B, so that the μ-rod is positioned slightly above it. Contact 15 is connected to contact element 19′. In addition, the figure shows another substrate IC-S, in which several driver circuits, lines and other components are accommodated. Contacts 38 and 39, which also have a large surface area, are connected to the lines and circuits. For example, the contact area 38 leads to a ground potential 41, the contact area 39 leads to a driver circuit 40, shown here schematically. An adhesive 37 connects both carriers with each other. Due to the large surface area of the contacts, positioning the carriers on each other is simplified.

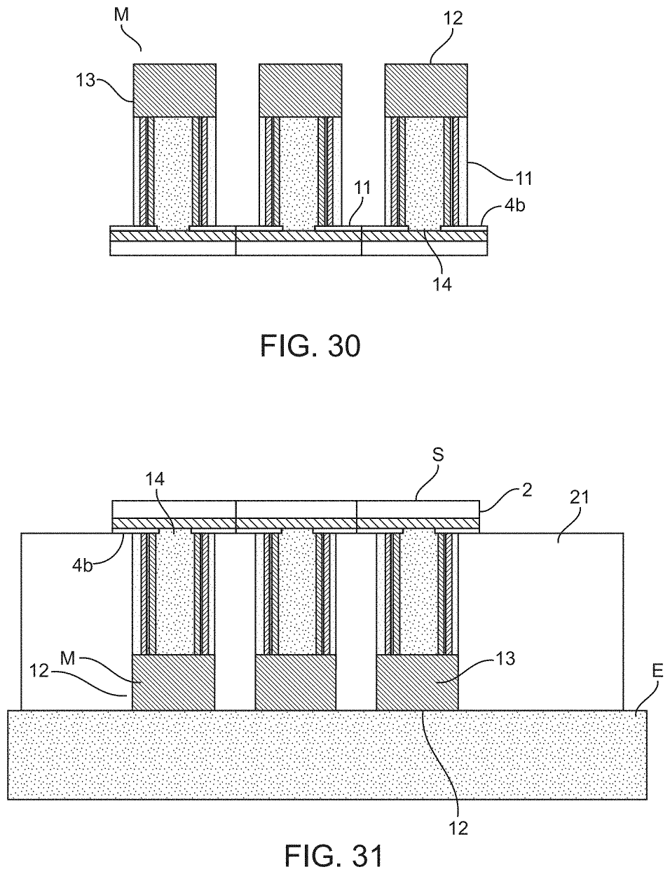

In another version according to FIG. 27B, the μ-rod can also be placed directly on the base carrier B. In this embodiment, the p-doped layer 9 or the current expansion layer along one long side is directly connected to a first contact area 17′ on the surface of carrier B. A second contact area 19′ is provided in carrier B, isolated from this and electrically and mechanically connected to contact 15. In addition to a simpler production, the steps in FIGS. 30 and 31 can be omitted; a larger contact area 17′ is possible here. This simplifies alignment and placement. Contact area 17′ includes a reflective conductive layer. A reflective structure around the μ-LED can also be provided here. This forms a box around the μ-LED, whereby the surface or the space in between can be filled with converter material.

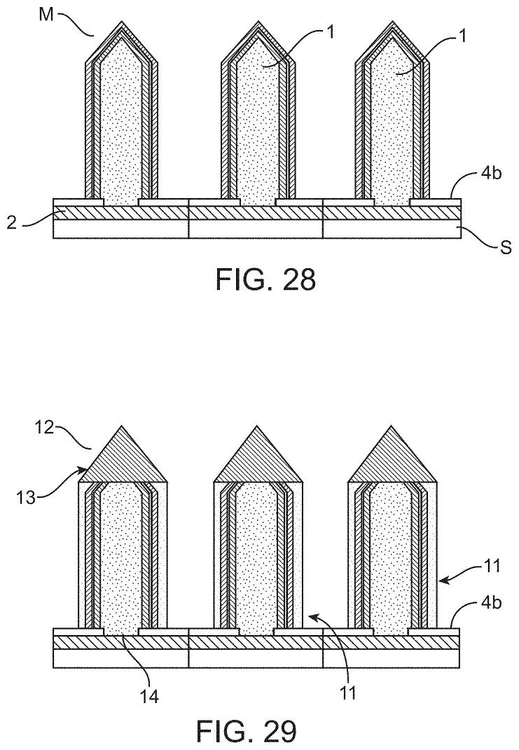

FIGS. 28 to 38 show an example of a proposed process for manufacturing a group of optoelectronic components from three μ-rods. FIG. 28 shows three μ-rods M arranged side by side and extending vertically from a growth substrate S, which are produced by means of an optional growth layer 2 having a first doping. A patterned mask 4b is deposited on the surface of the growth substrate 2. In the exposed areas, an elongated core 1 is formed perpendicularly from the growth layer 2, a core 1 having a material identical to the growth layer 2. The growth process produces the tapered tip shown in FIGS. 26 to 28. Then the layer sequence 3 is deposited on the core in several steps. First, layer 5 with the same doping type is deposited on the core. An active layer 7 is grown on this. This comprises several quantum wells. A p-doped layer 9 follows on the active layer 7. In addition, a current-expanding layer is deposited on the p-doped layer to distribute the injected charge carriers over the entire area of the p-doped layer 9. Of course, p- and n-doping can also be interchanged. In these examples, layer sequence 3 is produced epitaxially as far as possible.

FIG. 28 shows a further process step for the manufacture of a proposed optoelectronic component. First contacts 13 are formed for the group of three μ-rods. For this purpose, a photoresist 11 is applied to the surface of the μ-rod and the current expansion layer. The longitudinal end 12 with the tip is then exposed by means of O plasma etching and a conductive transparent contact is deposited flat on the tip. ITO is suitable for this contact 13. As shown in FIG. 28, the contact does not extend over the entire tip, but only over the upper area.

FIG. 29 shows an alternative embodiment. This can be produced by using the first contact 13 as shown in FIG. 28 as a seed layer and then electroplating or sputtering contact material onto it. This means that contact 13 comprises at least one contact layer to which a first contact area 17 of a carrier B can be easily connected mechanically and electrically. The contact planes for contacting with the first and second contact areas 17 and 19 run parallel along the longitudinal axis of a μ-rod M. The formation of the first contact 13 as a cube or cuboid is useful, because the resulting component does not show a strong change of its diameter, but substantially forms a twill with a hexagonal base or another polyhedron.

FIGS. 30 to 32 show further process steps of a proposed process for the manufacture of a proposed optoelectronic component. In these, the μ-rods as a group of, in particular, three μ-rods M are transferred from a growth substrate S to a foil 23, in particular by means of a flip-chip technique. FIG. 30 forms the starting point for the process. Although only three μ-rods are shown, a large number of such μ-rods can be provided in columns and rows.

In a first step, according to FIG. 31, the μ-rods are surrounded by a bonding layer 21, in particular a thermoplastic bonding layer 21. This extends from the contact 12 to the masking layer 4b. If necessary, and not shown here, the bonding layer 21 is removed except for the first contacts, so that a planar surface is obtained. The first longitudinal ends 12 and the contacts 13 are temporarily resting on a replacement carrier E. In this step, the group of μ-rods M is transferred to the replacement carrier together with the growth layer 2 and the sapphire substrate.

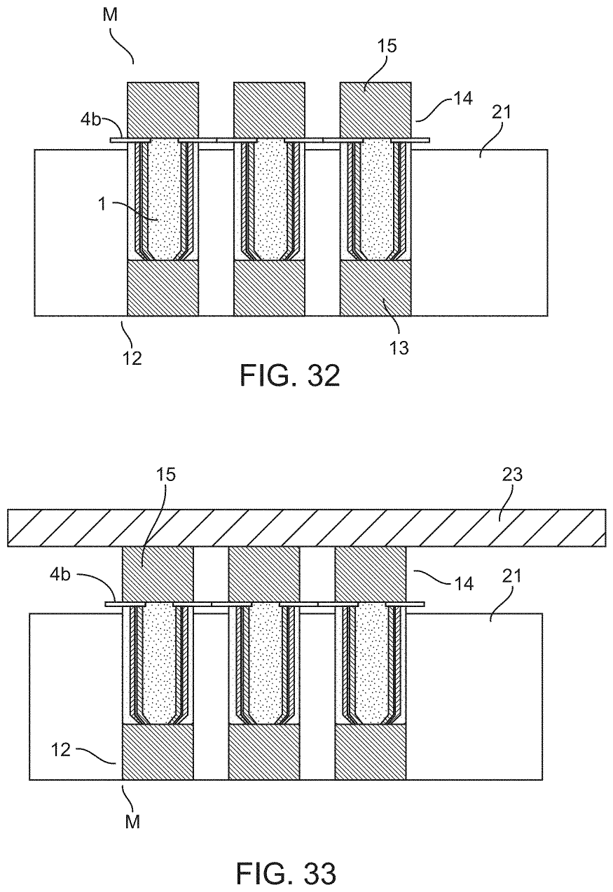

In FIG. 32 the replacement substrate E is removed, so that the μ-rods M are now held together by the bonding layer 21. Only a part of the masking layer remains as an insulating layer on the μ-rods. A contact 15 is applied to the surface of the now exposed core. This contacts the core electrically and extends over part of the insulation layer. The second contact 15 may have been created by electroplating or sputtering.

Contact 15 has at least two contact planes substantially parallel to the long side of the μ-rod, to which, on the one hand, a second contact area 19 of a carrier B can be easily connected mechanically and electrically and, on the other hand, a μ-rod M can be attached to the foil 23 shown in FIG. 33. Like the contact 13, the second contact 15 can also be cubic or cuboid.

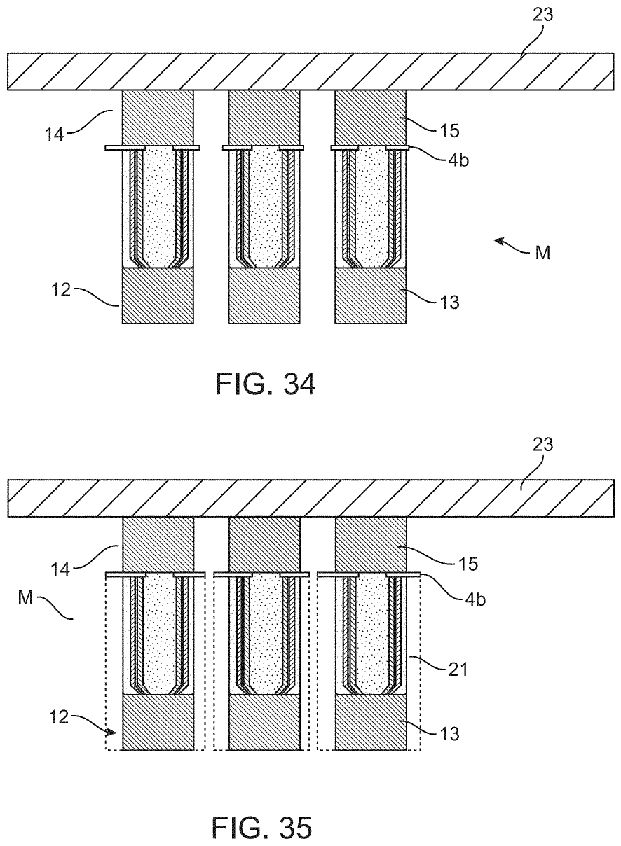

After applying a foil 23 to which the contacts 15 are mechanically attached, the μ-rods can be transferred, stored or further processed. Contacting to the foil 23 can be done by adhesive forces but also by glue or similar. The first longitudinal ends 12 remain unchanged. In the next step, shown in FIG. 34, the bonding layer 21 is completely removed. As a result, the μ-rods now “hang” individually on foil 23 and can thus be easily transferred to a carrier or processed further in some other way. In an alternative embodiment, shown in FIG. 35, the bonding layer 21 is only partially removed, leaving the μ-rods slightly wrapped around it.

According to FIG. 35, the three contacted μ-rods fixed to the foil 23 have been separated in such a way that the bonding layer 21 has only been partially removed. The rods themselves are still wrapped in this layer and no longer touch each other. This means that the μ-rods are also separated here. The end of a respective first contact 13 that is turned away from the masking 4b is still uncovered.

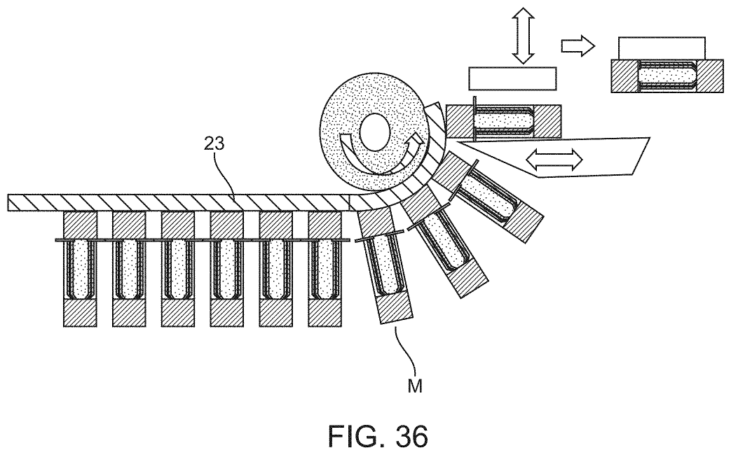

FIG. 36 shows a subsequent process step of a proposed process for manufacturing a proposed optoelectronic device in a cross-section. Groups of the separated μ-rods (M) are separated from the foil 23 and then lifted off by means of a mounting bar. For this purpose, the foil 23 is placed against a rotating roller and guided past it, whereby a deflection of a respective group facilitates detachment. The mounting beam can remove several e.g. several hundred μ-rods at once. In this example, different μ-rods are placed one after the other, i.e. into the drawing plane. The foil in FIG. 35 also extends into or out of the drawing plane, so that FIG. 85 shows a side view of this foil.

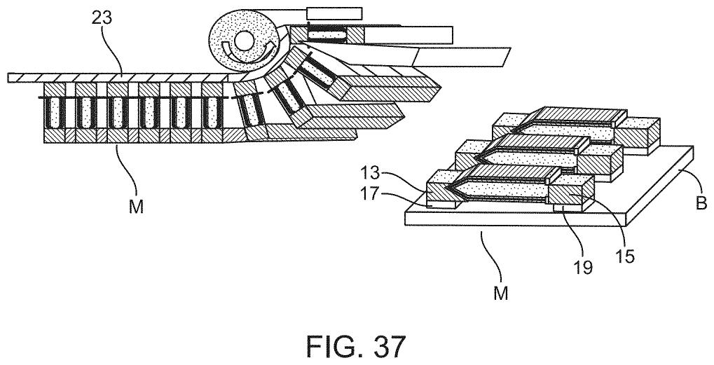

FIG. 37 shows the process step in which three μ-rods arranged side by side are transferred and attached to a carrier M. The μ-rods lifted from the folio 23 are placed in parallel on contact areas 17 and 19. In particular, contact 13 is bonded to area 17, contact 15 to area 19, thus creating an electrical and mechanical connection. Instead of a bonding process, a soldering or other fixing process can also be used. The bearing surface of contacts 13 and 15 is designed by the respective contact level in such a way that the contact rests flat on contact level 17 or 19. This reduces or prevents tilting. Depending on the process technology used and the effort involved, groups of several μ-rods up to several hundred can be transferred simultaneously.

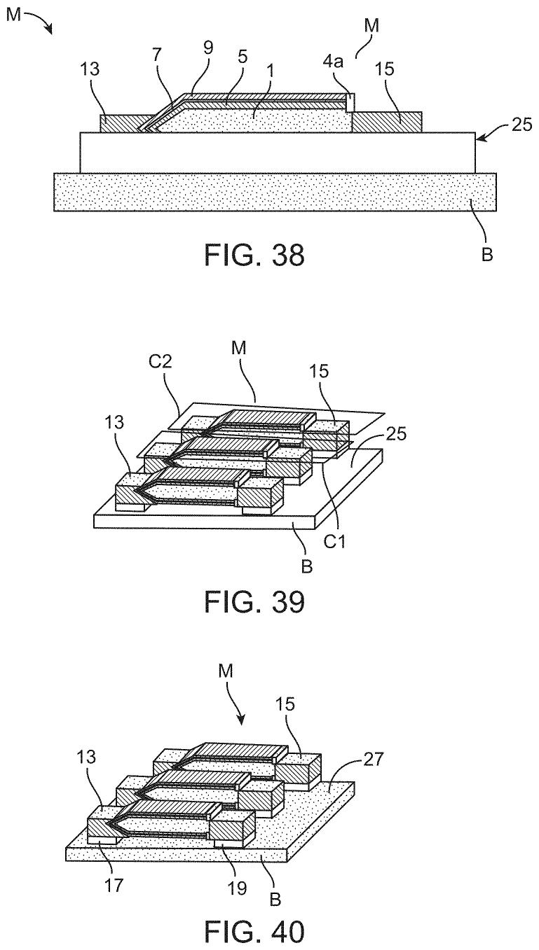

FIG. 38 shows another example of a component arranged in this way from a side view. The horizontal μ-rod M connected parallel to a carrier B with a first contact 13 and a second contact 15 is shown with its core 1, its first layer 5, active layer 7 and second layer 9 as well as an insulation layer 4a. Below the μ-rod and now not visible, a reflective layer is also applied on or in the surface of carrier B. In addition, a reflective structure 25 is formed around the μ-rod. This has a bevelled wall similar to the structures shown in FIG. 85, 90 or 91. This allows light emitted from the side to be deflected upwards. As described in disclosure herein, the sidewalls may be metallic. Alternatively, the reflector structure can be designed with TiO₂ in a silicone matrix that reflects the light generated by active layer 7 away from carrier B.

FIGS. 39 and 40 show further embodiments with three optoelectronic components arranged side by side in perspective. As explained above, the μ-rods can be configured to generate light of the same wavelength or different wavelengths.

FIG. 39 shows three μ-rods of the same design, connected in parallel to a carrier B, each with a first contact 13 and a second contact 15 on carrier B. All μ-rods M are also oriented parallel to each other. Two of the rods are additionally coated with a converter layer C1 or C2. This layer converts the blue light into red or green light. The surface of the carrier B is covered by a reflecting material. By means of the reflecting layer 25, additional light can be emitted away from carrier B and thus a light yield can be improved.

By contrast, in the version according to FIG. 40, support B is completely covered by a dark, absorbent layer 27. This improves the contrast.

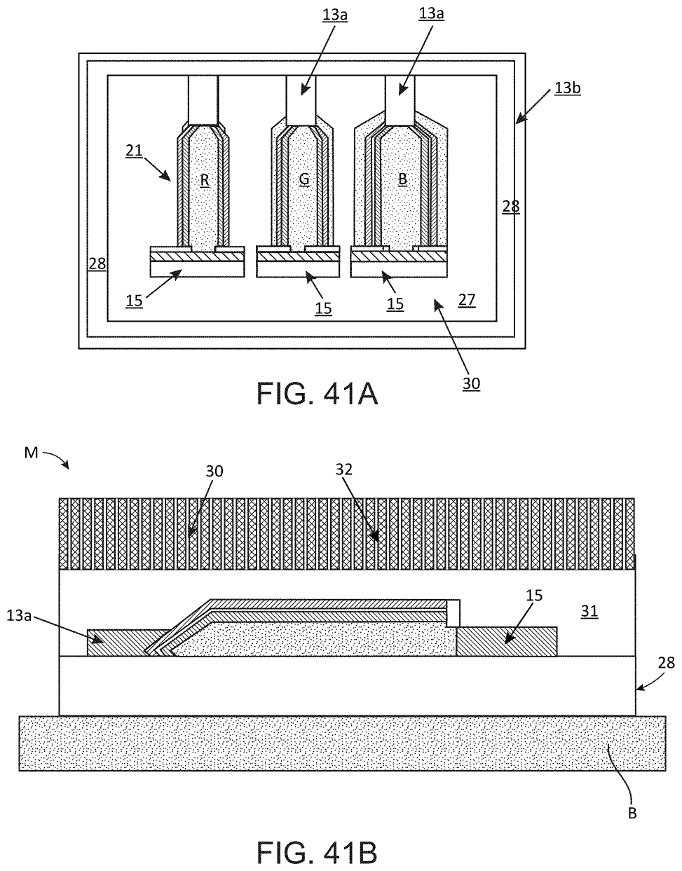

FIG. 41A shows a top view of a pixel array with three horizontally aligned μ-rods that are suitable for emitting light at different wavelengths. The three μ-rods R, G, and B each have a different geometry with the length being the same and only the width changing. The length of the μ-rods can also be different to produce a uniform light intensity for a user. The three μ-rods R, G and B are connected to a respective connector on a carrier 27 via a first contact 15. A second contact is attached to a tip of each μ-rod. These contact a common metallic structure 28. The metallic structure is circumferential and has a reflective sloping surface similar to the design in FIG. 85. This causes light to be reflected away from the top. Furthermore, a photonic structure 30 is applied to the surface, which extends over the entire cavity formed by the circumferential metallic structure. It ends on the upper side of the circumferential structure 28, but can extend beyond it depending on the application.

In this context, FIG. 41B is the side view of the embodiment of the previous figure. The photonic structure 30 does not rest on the individual surfaces of the μ-rods, but is slightly spaced by a transparent dielectric layer. The dielectric layer extends at least over the surface of the μ-rods facing the main emission direction, but it can also fill the cavity and thus form a planar surface for the photonic structure 30. The latter can be placed on the surface, or applied to it epitaxially or otherwise. The height of the photonic structure is chosen appropriately.

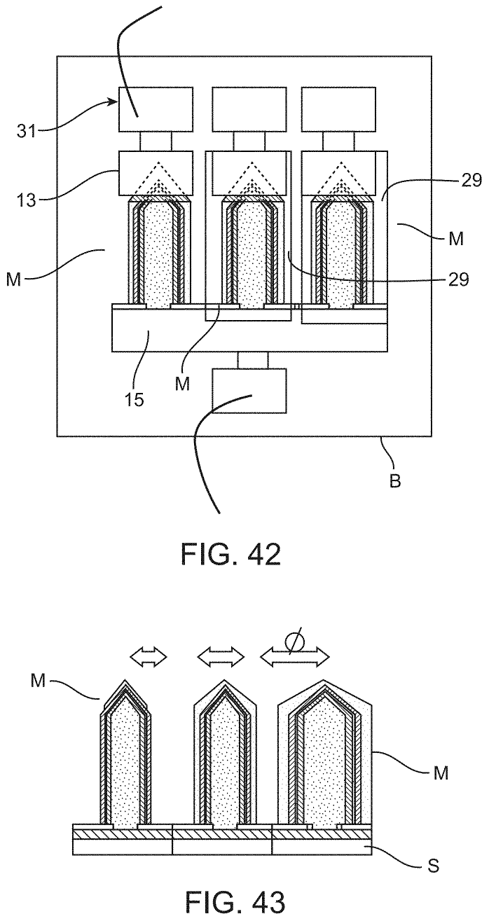

FIG. 42 shows the embodiment similar to that of FIG. 39 in a top view. A respective μ-rod M is electrically and mechanically connected to its first contact 13 and the second contact 15 with contact areas on a carrier B. A red-green-blue light source is shown here, for example for a display or indicator. The three μ-rods M are identical in construction and emit blue light, for example. Using converter material 29, the blue light can be converted into red light or green light. In FIG. 42 the left μ-rod M, which is free of converter material, emits blue light, the middle μ-rod M, which is covered with a first converter material 29, emits red light, and the right μ-rod M, which is covered with a second converter material, emits green light. First and second contact areas 17 and 19 of carrier B are also connected to contact further areas for bonding. FIG. 42 shows two bonding wires at the top and bottom.

FIG. 43 shows a further example of a proposed group with three μ-rods in cross-section. In these, the diameter of the grown structures is varied. This variation changes the color of the μ-rods. Thus, it is possible to produce several μ-rods M on one wafer in one epitaxial step, which emit different colors. The diameter of μ-rods M is varied in one-step during selective epitaxy, i.e. without changing a global growth parameter.

On a growth substrate S, three μ-rods M are generated for one emission of light of a certain wavelength with a spatial extension adapted to it. The length is substantially the same, but the diameter varies due to epitaxial growth. This results in a change in diameter and structure, which may result in a different color.

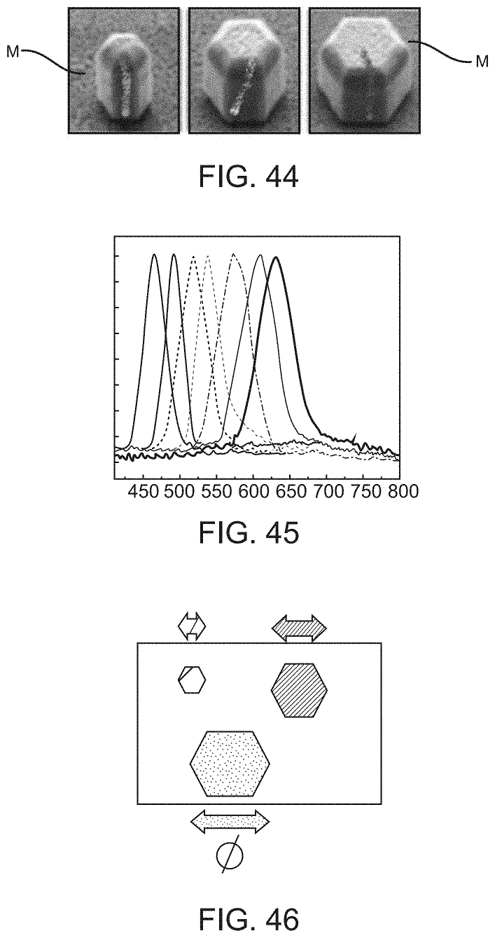

FIG. 44 shows an image of an electron microscope of such prods of different sizes. The μ-rods are regular hexagons with a slightly tapered upper edge. This corresponds to the tip in the designs shown above. Depending on the embodiment, the length of the μ-rods corresponds to a diameter. Only in the left picture, the length is about twice the diameter of the μ-rods. The μ-rods are grown on a planar but insulating surface, where an area has been left out as a nucleus. The change of the geometry results in a different color, whereby the μ-rod with the smallest diameter has light with the largest wavelength. FIG. 44 shows a red emitter on the left, a green emitter in the middle and a blue emitter on the right.

From the geometries shown, there is thus a relationship between diameter and wavelength for a given length. As the diameter decreases, the wavelength of the light increases. FIG. 45 shows a representation of emitted wavelengths from 450 nm to approx. 650 nm at different diameters. This relationship is also shown again in FIG. 46. The diameter of the red light emitting ones is about half the diameter. There is a linear relationship between the diameter of the μ-rod and the wavelength of the emitted light in a small wavelength range. Besides the hexagon shown here as a surface geometry, another geometry can be grown. At small diameters, this hexagon is in practice a little less distinct due to the processes.

With this approach, μ-rods can be created for a larger area radiation and a higher light yield. For this purpose, the prods are arranged along their longitudinal axis on a carrier. The longitudinal axis of the μ-rods thus runs essentially parallel to the longitudinal axis. In the designs shown here, the μ-rods are slightly spaced from the surface of the carrier by the slightly protruding contact areas.

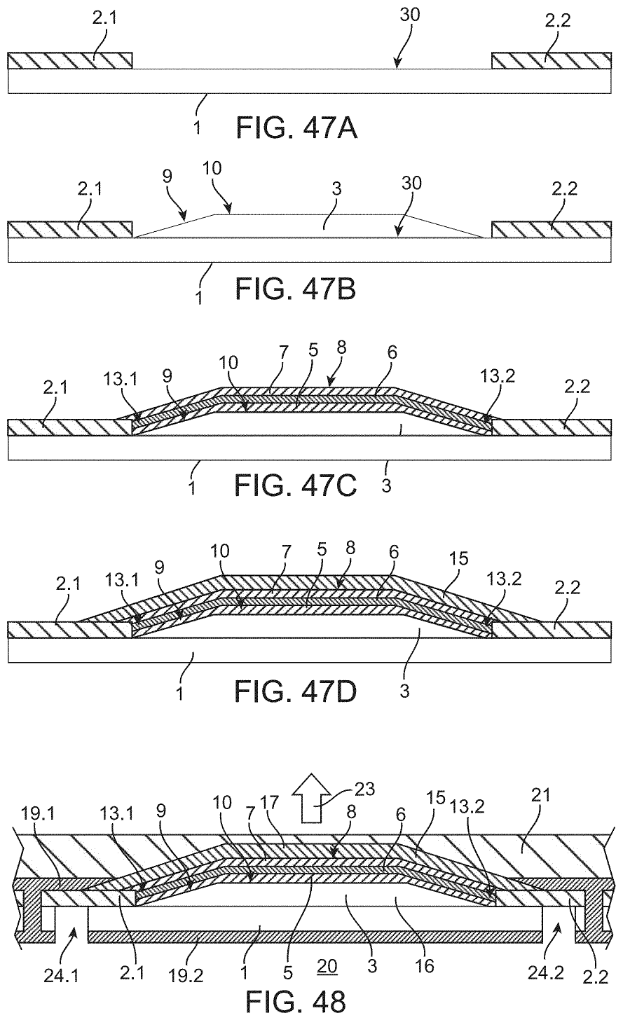

FIGS. 47A to 47D show, in a schematically simplified manner, the production of an embodiment of an optoelectronic semiconductor device with a growth surface for red μ-LED, among other things. The growth base is a tellurium n-doped gallium arsenide (111)B epitaxial substrate 1, which, as shown in FIG. 47A, carries a lithographically structured dielectric mask 2.1, 2.2, for example made of SiOx and/or SiNx and/or SiOxNy. The opening 30 in the dielectric mask 2.1, 2.2 preferably comprises edge lengths of 50 nm to 100 μm.

FIG. 47B shows a form layer 3 selectively epitaxially produced in the region of the original opening 30 in dielectric mask 2.1, 2.2 on the gallium arsenide (111)B epitaxial substrate 1, which comprises n-doped gallium arsenide. Alternatively, the form layer 3 is formed from n-doped aluminium gallium arsenide or n-doped aluminium gallium indium phosphide.

The form layer 3 has at least one {110} oriented side surface 9 extending to the opening edge of the dielectric mask 2.1, 2.2 and, for the design shown, additionally a (111) oriented cover surface 10. Due to the arsenic termination of the gallium arsenide (111)B epitaxial substrate 1, a contour-precise form layer 3 can also be grown selectively epitaxially for the small opening 30 in the dielectric mask 2.1, 2.2 with low stress and a small number of lattice defects.

The contours for the form layer are the form layer contours shown in FIGS. 50 and 51. FIG. 50 shows a form layer 3 with the contour of a three-sided hexagonal pyramid, whose side faces 9.1, 9.2, 9.3 are oriented with (−1-10), (−10-1) and (0-1-1). FIG. 51 shows a three-sided truncated pyramid as a further preferred contour of form layer 3 in plan view. The side faces 9.1, 9.2, 9.3 with the orientation (−1-10), (−10-1) and (0-1-1) and a top face 10 with the orientation (−1-1-1) are shown. To form the contours of the form layer according to FIGS. 50 and 51, the opening 30 in the dielectric mask 2.1, 2.2 is arranged in a corresponding triangular shape and aligned with an angular error <5° relative to the orientation of the gallium arsenide (111)B epitaxial substrate 1. The final contour of the form layer 3 is achieved in this configuration exclusively by selective epitaxial growth. For a further embodiment, a wet-chemical after-treatment for contour adaptation of the form layer 3 can follow the epitaxy step.

FIG. 47C shows the formation of a light-emitting Hetero structure 8 based on aluminium gallium arsenide (AlxGa1-xAs) and/or aluminium indium gallium phosphide (AlInGaP) by epitaxial growth on the three-dimensional form layer 3. This comprises a first conductive semiconductor layer 5 with n-doping, an active layer 6, in particular with quantum wells, and a second conductive semiconductor layer 7 with μ-doping, which can be produced on the form layer 3 according to the invention with a low internal crystal strain and a reduced number of lattice defects. In addition to an increase in the fill factor due to the three-dimensionality and an improved light extraction for photons emitted parallel to the active layer 6, the edge enclosure of the light-emitting heterostructure 8 leads to a further increase in efficiency. It can be seen that the active layer 6 with the angular position at the edge region 13.1, 13.2, which is predetermined by the {110}, extends to the dielectric mask 2.1, 2.2. Non-radiative recombination is suppressed by the light-emitting heterostructure 8 closed at the edge regions 13.1, 13.2. This is especially the case for the preferably selected materials SiOx, SiNx or SiOxNy of the dielectric mask 2.1, 2.2.

The further process steps to produce a μ-LED, which includes the proposed optoelectronic semiconductor structure, are adapted to the chosen design. Subsequently, the same reference signs are used for matching components.

For the embodiment shown in FIG. 47D, a transparent contact layer 15, e.g. of indium tin oxide (ITO), is deposited flat on the light-emitting heterostructure 8. The further setup for a first design of a μ-LED 20, which generates light with a main emission direction 23 in the growth direction of the layer structure and is intended for placement on an optochip not shown in detail without separate wire bonding, is shown in FIG. 48.

FIG. 48 shows a μ-LED 20 with the three-dimensional light-emitting heterostructure 8 described above, based on aluminium gallium arsenide (AlxGa1-xAs) and/or aluminium indium gallium phosphide (AlInGaP) for wavelengths in the range of 560 nm to 1080 nm. The light is emitted with the main radiation direction 23 through the transparent contact layer 15 made of indium tin oxide (ITO) and the areas above it of a carrier 21, which is formed of Al₂O₃, for example. The p-contact is made through the transparent contact layer 15 and the metallization 19.1, which is guided to the back of the gallium arsenide (111) B epitaxial substrate 1. The n-contact 16 is realized by the n-doped form layer 3, the n-doped gallium arsenide (111) B epitaxial substrate 1 and the metallization 19.1. To separate the contacts, a trench 24.1, 24.2 is provided between the rear areas of the metallization 19.1 and the metallization 19.2, cutting through the gallium arsenide (111) B epitaxial substrate 1 to the dielectric mask 2.1, 2.2, for the present embodiment made of SiOx, SiNx or SiOxNy.

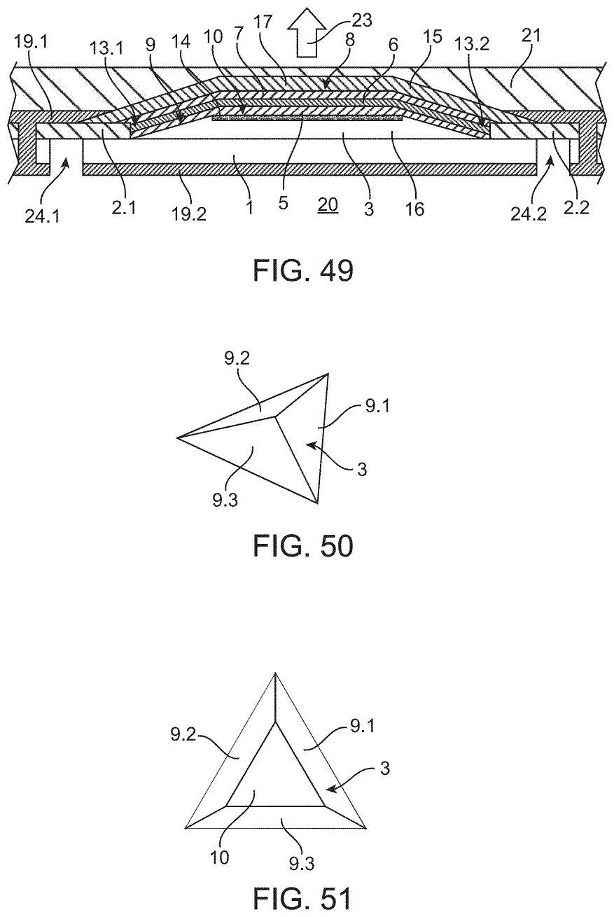

FIG. 49 shows a second variant of a μ-LED 20, which differs from the embodiment of the previous figure by a Bragg mirror stack 14 incorporated in the form layer 3. The Bragg mirror stack 14 is configured with a sequence of SiOx and SiNx layers and can be deposited during selective epitaxial growth of the form layer 3 and form an integral part of the form layer 3. The Bragg mirror stack 14 improves the light extraction for the main radiation direction 23 selected in the growth direction, for the embodiment the μ-side.

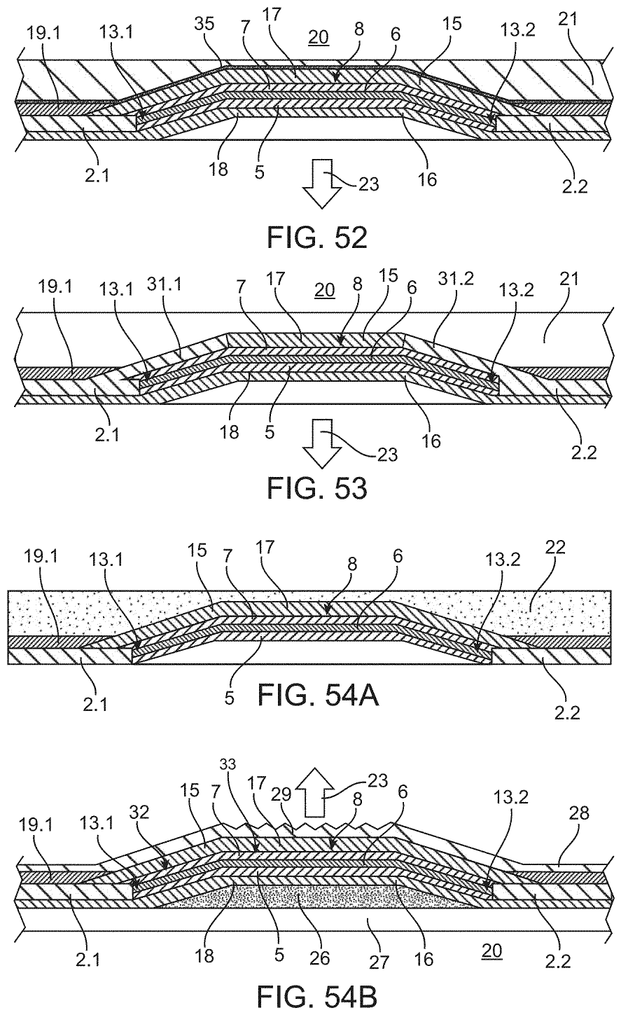

A third version of a μ-LED 20 with the three-dimensional light-emitting heterostructure 8 for single bonding is shown in FIG. 52. In contrast to the above-mentioned versions, the main radiation direction 23 is opposite to the growth direction of the layer system, in this case the n-side. For this purpose, the production of the light-emitting heterostructure 8 shown in FIGS. 47A to 47C can be carried out with undoped gallium arsenide (111) B epitaxial substrate 1. In this case, the selectively grown form layer 3 is also applied undoped. After the light-emitting heterostructure 8 has been grown epitaxially, a contact layer 15, for example of ITO, is deposited on it to produce a p-contact 17 and a metallization 19.1 is applied to contact it. In addition, a mirror layer 35, in particular a metal or Bragg mirror layer, is arranged in the area above the cover surface of the light-emitting heterostructure 8 and in particular below the carrier 21. The mirror layer 35 is thus preferably arranged directly above layer 15, 17. Alternatively, the contact layer 15 can also be reflective. For example, the carrier 21 can be made of Al₂O₃ and the carrier 21 is usually not transparent. After the layer system above the light-emitting heterostructure 8 is realized, the gallium arsenide (111) B epitaxial substrate 1 and the form layer 3 are removed. To complete the light source 20 shown in FIG. 52, a further transparent contact layer 18 made of ITO is applied to the underside of the layer structure as n-contact 16.

The fourth version of a μ-LED 20 shown in FIG. 53 is configured in the same way as the version in FIG. 52 with regard to the main radiation direction 23 against the growth direction of the layer system. In contrast to the latter, the carrier 21 is made of a material that is opaque for the wavelength range from 560 nm to 1080 nm of light emission of the light-emitting heterostructure 8 on the basis of aluminium gallium arsenide (AlxGa1-xAs) and/or aluminium indium gallium phosphide (AlInGaP), whereby the latter may consist of silicon or germanium, for example. Furthermore, 8 passivation layers 31.1, 31.2, for example of SiOx and SiNx, are present on the lateral surfaces of the light-emitting heterostructure.

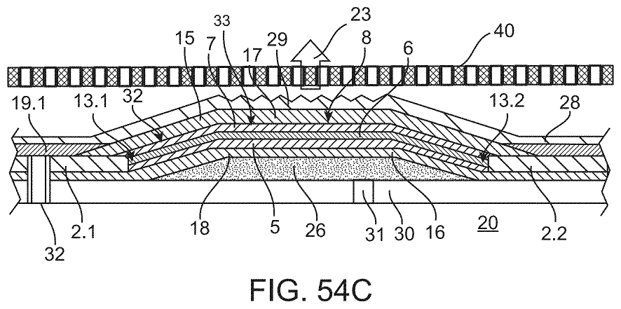

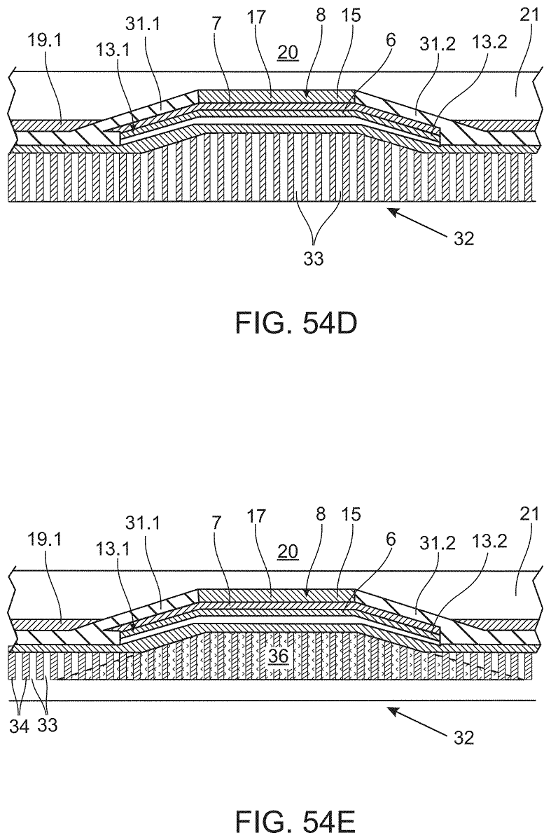

The fifth version of the μ-LED 20 shown in FIG. 54B comprises a main radiation direction 23 against the growth direction of the layer system and is adapted for double bonding. An intermediate step for its manufacture is shown in FIG. 54A, where a temporary carrier 22 is used and the removal of the gallium arsenide (111) B epitaxial substrate 1 and the selectively grown form layer 3 has already been performed. Starting from this, below the light-emitting heterostructure 8, a transparent contact layer 18, for example of ITO, and a carrier or carrier substrate 26, in particular in the form of a metallization 26, as planarization, and an n-contact 16 are applied, which are covered by a carrier or carrier substrate 27, for example of silicon, germanium or Al₂O₃. After these process steps have been carried out, the temporary carrier 22 can be removed, as shown in FIG. 54B, and replaced by a transparent protective layer 28 with a light conducting structure 29.

Furthermore, the embodiment shown in FIG. 54B includes optional Bragg mirror stacks in the area above the side surface 32 of the light-emitting heterostructure 8, so that light emission is central in the area of the top surface 33. Quantum wells or a quantum well structure in the active layer 6 can be located below the side faces 32 and the top face 33 for a possible embodiment or exclusively below the top face 33. For an alternative embodiment not shown in detail, the quantum wells or a quantum well structure are located exclusively below the side faces 32, whereby light is accordingly emitted laterally with a larger beam angle.

The versions shown here can also be arranged monolithically, i.e. in rows and columns. The μ-LEDs in FIG. 53 can also be planarized with a transparent material. Photonic crystal structures, converters or a combination of these are then applied to this material.

FIG. 54C shows an embodiment in which the roughened surface 29 has been completely planarized with another layer. A photonic crystal structure 40 is arranged on this layer, whose shape and formation corresponds to the embodiments disclosed here. The μ-LED is also removed from the carrier substrate and placed on a further substrate 30, which covers the contact areas 31 and 32 shown here. In particular, contact area 31 is arranged underneath the metallization 26 and contacts the n-doped layer electrically. A second contact area 32 is created by means of a generated via electrically insulated by layers 16 and 2.1 and contacts the metallization 19.1 and thus the p-doped layer. Both contact areas are connected to electrical structures in carrier 30, which are not shown further. These structures supply the μ-LED with power and control it.

The FIG. 54D is an alternative embodiment to FIG. 53. It comprises a rear light emission, so that the light generated in the active layer 6 is coupled out through the transparent layer 18 on the rear side. A light-shaping structure in the form of a photonic crystal 30 is applied to the surface of the rear layer 18. This comprises areas 33 and 34 with different refractive indices. In particular, the periodically arranged regions 33 and 34 are configured in such a way that they run along the surface of the rear light extraction layer 18 and thus also have a different thickness. Areas inside the central recess are thus deeper than areas outside. The thickness is selected so that sufficient light shaping can take place. The areas 33 and 34 with different refractive indexes are transparent. The light generated and shaped in this way is coupled out along surface 32. It should be mentioned at this point that at least some areas could also extend into layer 6. Thus, layer 6 can be much thicker than shown here. In some other configurations, first and/or second areas can also extend into the active layer. Providing and forming the photonic structure in the p- or n-semiconductor material enables a better optical coupling to the photonic structure, since otherwise a refractive index difference is too high and light is not or only slightly coupled into the photonic structure.

FIG. 54E shows another embodiment with a light-shaping structure. In this case, a converter layer 36 is inserted within the recess, i.e. along the transparent output coupler structure 16. The converter layer extends beyond the recess and thus also forms areas 33 of the photonic structure arranged above the recess with periodically alternating areas 33 and 34. The periodicity of the photonic structure is chosen so that it collimates converted light and radiates it downwards. In contrast, unconverted light is emitted at a different angle so that it can be filtered in a suitable manner. On the photonic structure is again a decoupling structure 32. In both embodiments, a microlens or other element can also be used as a light-shaping structure.

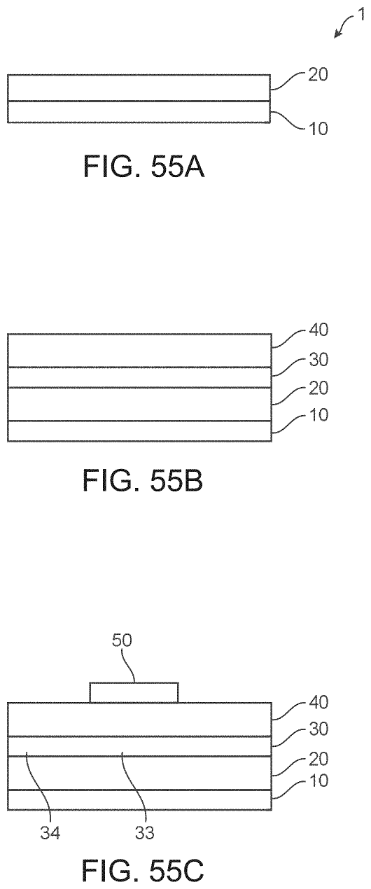

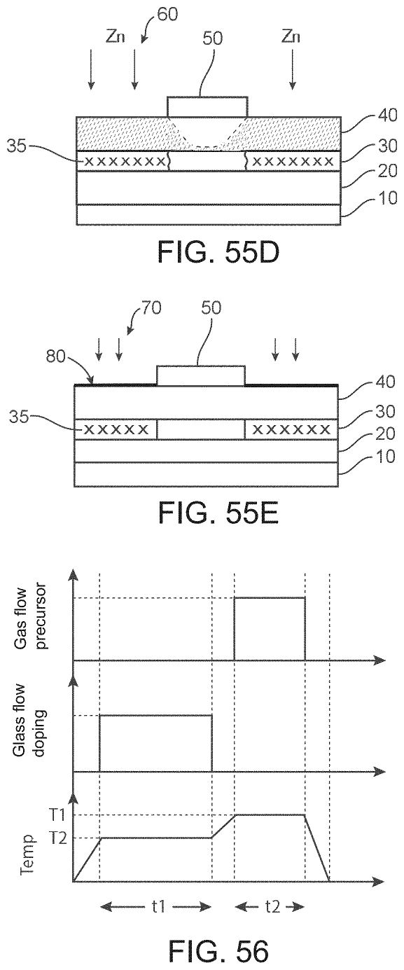

One measure to improve the low current behaviour is the Quantum Well Intermixing. FIGS. 55A to 55E show individual steps in a manufacturing process of an optoelectronic device, in particular a μ-LED, in which measures taken during or for quantum well intermixing prevent degradation in both the high-current and low-current ranges. As shown in FIGS. 55A to 55C, a semiconductor structure 1 is formed which is subjected to further process steps. In FIG. 55A, a growth substrate 10 is provided, such as a GaAs substrate, which is prepared for further growth steps. An n-doped layer 20 based on a III-V material system is then deposited on this substrate. Specifically, this can be In, Ga, Al, or a combination of these together with phosphorus P. The exemplary InGaAlP layer is n-doped and can also be provided with further layers and/or dopants (not shown here) to ensure a good electrically conductive contact and a low sheet resistance in the n-doped layer 20.

In FIG. 55B, an active layer 30 is subsequently applied. This comprises at least one quantum well in which radiative recombination takes place in one operation of the finished device, thus generating light. The at least one quantum well in the active layer 30 may also comprise a layer combination from the III-V semiconductor system, for example consisting of InGaAlP layers with different Al contents. Subsequently, a p-doped layer 40 is generated on the active layer. For this purpose, a first dopant is used, for example Mg or Zn. As with the n-doped layer 20, doping can be carried out during the manufacturing process by adding the dopant in the desired concentration. This has the advantage that doping profiles can already be created in the layers during growth, whereby the desired electrical properties can be better adjusted and impurities are reduced by more uniform crystal growth.

After providing the semiconductor structure 1 in the previous steps, a mask 50 is now applied to the p-doped layer in FIG. 55C and patterned accordingly. As shown, the patterned mask 50 covers a partial area on the surface of the p-doped layer and thus also overlies a first partial area 33 of the active layer. An adjacent subregion 34 of the active layer is not covered by mask 50. After patterning, a diffusion step is performed in FIG. 55D with first process parameters and a second dopant. This is for example Zn or an organic Zn compound.

The process parameters include temperature, pressure and concentration of the second dopant and can also vary during a given time period. They are chosen so that the second dopant is deposited on the surface not covered by mask 50 and diffuses into the p-doped layer 40. The diffusion process is now controlled by the first process parameters so that the second dopant diffuses through the layer 40 into the active layer and the quantum well. In some cases, it can also diffuse easily into the boundary region of the n-doped layer. However, the first subregion 33 of the active layer under the mask is not interspersed with dopant.

The first process parameters are chosen in such a way that diffusion creates an intermixing in the quantum well of the second subregion in the active layer, in which the energy gap of the quantum well is increased. In this example, the production of the individual layers, as well as the doping steps, is carried out by MOCVD processes. However, other manufacturing processes such as PVD, ion implantation or, much less frequently, MBE processes are also conceivable in subregions.

After completion of this procedure, an additional annealing step is now continued. Here, second process parameters are set, which in the embodiment include a higher temperature and the addition of a precursor 70. The latter can be provided by the above-mentioned procedures. This produces the structure shown in FIG. 55E. As a result of the previous diffusion process, the diffused Zn has displaced other atoms of the crystal lattice from their places and taken their place. The displaced atoms (mainly Ga) could be located in interstitial sites. It appears that these remain mobile and thus possibly form recombination centers for non-radiative recombination. By their movement, they could thus migrate to the first subregion 33 and there drastically reduce the efficiency of the device. This is supported by the observation that the efficiency drops early on even at low current densities.

Due to the additional annealing step at higher temperature these atoms become mobile. The addition of a precursor such as As now enables the displaced atoms (mainly Ga) to be bound on the surface, so that a thin layer 80 of GaAs is formed there. The atoms displaced to interstitial sites diffuse to the surface and are saturated by the precursor. This results in a concentration gradient towards the surface, since the concentration of free atoms is reduced there. Accordingly, the number of free atoms is reduced and thus the efficiency is kept stable even at low current densities. In addition, in the boundary region between the first and second subregion, quantum well intermixing decreases sharply over a short distance, resulting in a relatively steep energy barrier. This results in the structure shown in FIG. 55E, where a boundary is formed in a substantially direct line under photomask 50. Quantum well intermixing occurs only in the second subregion 34 of the active layer.

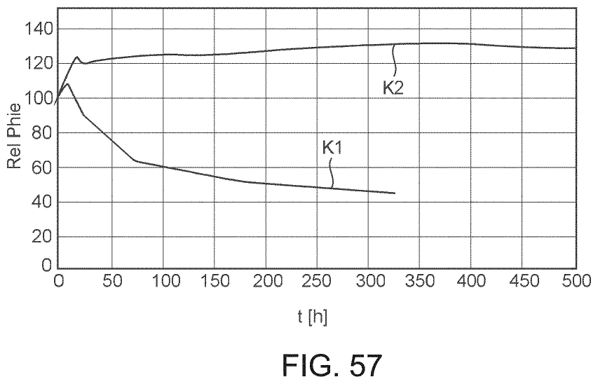

FIG. 57 shows a curve showing the relative luminous efficacy in relation to the service life of the component in operating hours. Curve K1 shows the characteristics of a component that has been processed in the conventional way without an additional annealing step. After only 200 hours, the initial value of curve K1 has already fallen to half.

Due to the temperature increase and the appropriate choice of precursor, the lattice atoms displaced by the diffusion step seem to be bound on the surface. Thus, the surface acts as a sink for the interstitial atoms. In simplified terms, it is possible that the displaced atoms diffuse preferentially from the active layer through the p-doped layer to the surface due to the changed process parameters, so that the concentration of potential non-radiative impurities in the active layer is reduced.

FIG. 57 shows in curve K2 the light yield of a component manufactured according to the process according to the invention over several hundred hours of operating time. The component was “cured” with a precursor containing a material of the V main Group such as phosphorus P or arsenic As and at an elevated temperature. The initial light output increases by approx. 20% after a short time and then remains constant for several hundred hours. The initial increase can be explained by healing of the crystal lattice caused by the current and local heating. Thus, the proposed process achieves a significant improvement, especially for components with small to very small dimensions.

FIG. 56 shows qualitatively the time course of a selection of the first and second process parameters, in detail the temperature T, the gas flow of the second dopant and the gas flow of the precursor during the annealing phase. During the time t1 the process chamber is kept at the temperature T1 and the second dopant, for example an organic Zn compound, is added. The temperature T1 is chosen so high that during this time t1 Zn diffuses through the p-doped layer into the active layer, where it leads to quantum well intermixing as described above. After the time t1 the addition of the dopant is stopped and the temperature is increased to the value T2. Depending on the profile, this increase can take place in a very short time window. Then the temperature T2 is kept constant during the time t2 and a precursor is added, which for example contains an element of the V main group. Period t2 is selected shorter than period t1 in this embodiment.

According to the inventors' findings so far, the period t1 and the period t2 can be considered as decoupled. The time period t1 substantially determines the strength of the quantum well intermixing and the time period t2 substantially determines a reduction of the degradation behaviour of the component. Accordingly, the time period t2 should be long enough to achieve the desired effect. The temperature T2 also plays a role in the strength of the suppression of degradation. It is advantageous to select T2> T1, but the temperature T2 should not be too high, since the basic brightness of the components decreases from a limit temperature. The example shown in FIG. 56 serves to illustrate the proposed principle. In embodiments, different concentration or temperature and (not shown) pressure profiles can be used to first bring the dopant into the quantum well of the active layer and then to perform the annealing process.

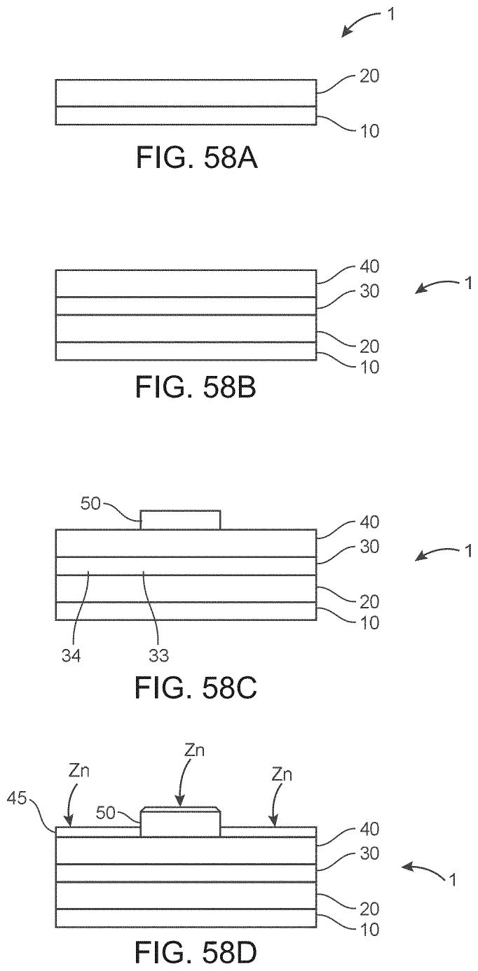

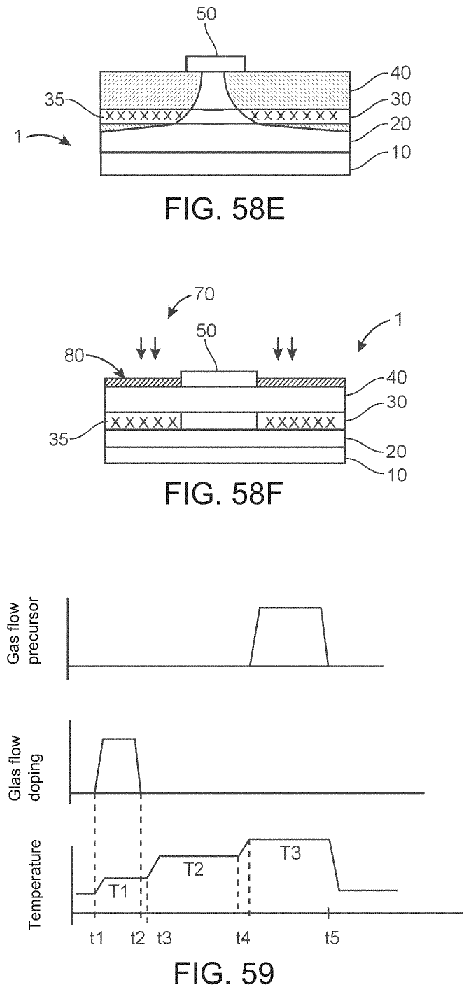

FIGS. 58A to 58E show individual steps in a manufacturing process in which, by appropriate selection of the process parameters, a further Improvement of quantum well intermixing can be generated. It was found that by an application with simultaneous diffusion dopant diffuses into the active layer under a mask, but does not cause quantum well intermixing there. Thus, an increased density of impurities remains in the active layer under a mask, which is intended for light emission and leads to an accelerated aging process and a deterioration of the properties.

FIGS. 58A to 58C show a semiconductor structure 1, which is subjected to further process steps. In FIG. 58A a growth substrate 10 is provided, for example a GaAs substrate, which is prepared for further growth steps. These further steps can include the deposition of sacrificial layers, passivation layers or matching layers to different crystal structures. The substrate can also already contain or be prepared for line contacts or circuits.

An n-doped layer 20 based on a III-V material system is then deposited on the prepared substrate 10. The deposition is carried out in a MOCVD reactor, but other processes disclosed in this application may also be used for this purpose. For example, In, Ga, Al, or a combination of these together with phosphorus P is used as material. The exemplary InGaAlP layer 20 is n-doped and may be provided with additional layers and/or doping (not further shown here) to ensure good electrical contact and low sheet resistance in the n-doped layer 20.

In FIG. 58B, an active layer 30 is subsequently applied. This comprises at least one quantum well in which radiative recombination takes place in one operation of the finished device, thereby generating light. The at least one quantum well in the active layer 30 can also comprise a layer combination from the III-V semiconductor system, for example consisting of InGaAlP layers with different Al contents. Subsequently, a p-doped layer 40 is generated on the active layer 30. For this purpose, a first dopant is used, for example Mg or Zn. As with the n-doped layer 20, doping can be carried out during the manufacturing process by adding the dopant in the desired concentration. This has the advantage that doping profiles can be created in the layers already during growth, whereby the desired electrical properties can be better adjusted on the one hand and on the other hand, impurities are reduced by a more uniform crystal growth.

After providing the semiconductor structure 1 in the previous steps, a mask 50 is now applied to the p-doped layer in FIG. 58C and patterned accordingly. As shown, the patterned mask 50 covers a partial area on the surface of the p-doped layer and thus also overlies a first partial region 33 of the active layer. An adjacent subregion 34 of the active layer is not covered by mask 50. After patterning mask 50, the p-doped layer is doped with a second dopant by gas phase diffusion using a precursor with first and second process parameters. The second dopant is formed from Zn, e.g. an organic Zn compound.

The process parameters for this second step include temperature, pressure and concentration of the second dopant and can also change during a given time period. They are chosen in such a way that after decomposition of the precursor the second dopant is deposited as layer 45 on the surface of the semiconductor structure and forms a thin layer there, but does not or hardly diffuse into the p-doped layer. For this purpose, for example, the temperature is chosen lower than in a later diffusion process. To provide the second dopant, the dopant is obtained from a decomposition of a precursor in the gas phase. This is done in a MOCVD or MOPVD reactor. The advantage of such a step is that the wafer remains in the reactor between the individual process steps and does not need to be transported. The resulting structure with a thin layer of Zn or another material as second dopant is shown in FIG. 58D.

According to FIG. 58E, a separate diffusion process takes place after the dopant has been applied to the surface. The diffusion process is controlled by the process parameters so that the second dopant diffuses through layer 40 into the active layer and the quantum well. In some cases, it can also diffuse easily into the boundary region of the n-doped layer. During this process, the second dopant reaches the region under the mask by diffusion in layer 40 (stochastically distributed). However, the first subregion 33 of the active layer under the mask is not interspersed with dopant. Instead, a sharp edge is formed there, which surprisingly coincides substantially with the projection of mask 50 into the active layer.

The process parameters are chosen in such a way that diffusion creates an intermixing in the quantum well of the second subregion in the active layer, in which the energy gap of the quantum well is increased. In the boundary region between the first and second subregion the quantum well intermixing decreases sharply over a short distance, so that a relatively steep energy barrier is created.

By separating the application of the dopant from the subsequent diffusion step, a better control of the individual processes is achieved. In most cases, the deposition of the dopant takes place at a lower temperature than the subsequent diffusion. Thus, on the one hand, the amount of the dopant provided can be better adjusted and on the other hand, diffusion is independent of the gas phase reaction. In the later separate diffusion step, a suitable temperature profile is set so that a doping profile is obtained in which the diffusion barrier for charge carriers generated by the dopant is close to the energy barrier generated by quantum well intermixing.

Once this procedure has been completed, an optional annealing step is now continued as shown in FIG. 58F. This involves setting third process parameters, including a higher temperature and the addition of an additional precursor 70 in the embodiment. This aspect is also described in detail in this application. As a result, of the previous diffusion process, the diffused Zn has displaced other atoms of the crystal lattice from their places and taken their place. The displaced atoms may be located in interstitial sites. It appears that these remain mobile and thus possibly form recombination centers for non-radiative recombination. Through their movement, they could thus migrate to the first subregion 33 and drastically reduce the efficiency of the device there. This is supported by the observation that the efficiency drops early on even at low current densities.

The lattice atoms displaced by the diffusion step are bound on the surface by the temperature increase and by the possibly optional, suitable choice of precursor. Thus, the surface acts as a sink for the interstitial atoms. In simplified terms, it is possible that, due to the changed process parameters, the displaced atoms diffuse preferentially from the active layer through the p-doped layer to the surface, so that the concentration of potential non-radiative impurities in the active layer is reduced. It was found that a precursor with a material of the V main group such as phosphorus P or arsenic As results in a significant increase in lifetime.

FIG. 59 shows qualitatively the time course of a selection of the process parameters, in detail the temperature T, the gas flow of the second dopant and the gas flow of the further precursor during the annealing phase. Between the time period t1 and t2, on the one hand, the temperature is kept at a first temperature T1 and, in addition, the dopant is added so that it can settle on the surface of the semiconductor structure. The temperature T1 is chosen in such a way that diffusion of the dopant into the semiconductor body does not take place or only to a very small extent. During this time, the further precursor is not added. At time t2, the dopant is switched off, while temperature T1 is maintained until time t3, which is a little later.

After time t3, the temperature is increased to the value T2. The temperature increase starts the diffusion process, i.e. the dopant deposited on the surface diffuses into the p-doped layer. The temperature profile in this embodiment is substantially kept constant, but non-constant temperature profiles are also conceivable. Depending on the temperature profile, a dopant profile is set. In a next annealing step, the dopant is removed from the p-doped layer or the active layer and the quantum well by a third temperature T3 over a period of time. For this purpose, in addition to an increase in temperature, the further precursor is added, whose decomposition product combines with the displaced atoms on the surface. Due to the resulting concentration gradient of mobile, displaced atoms, these are removed from the quantum well of the active layer and bound at the surface.

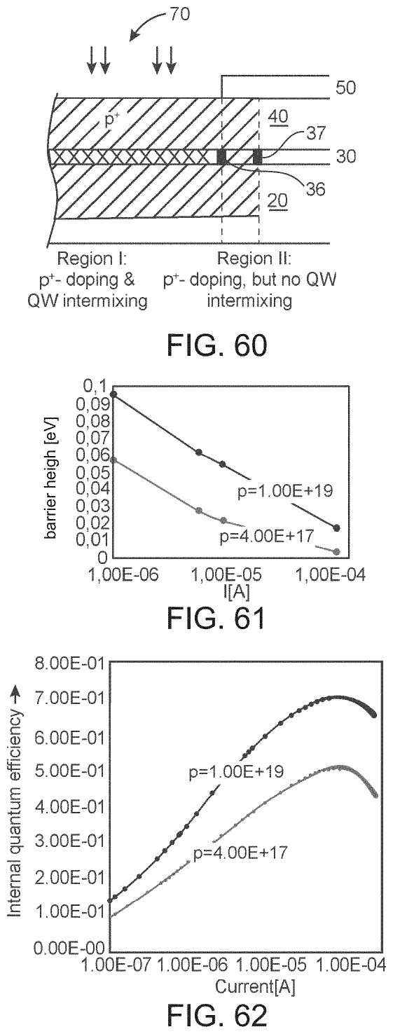

FIG. 60 shows an overview of substantially aspects for a possible explanation of the proposed principle. During the diffusion of the dopant, an additional concentration of dopant material is formed in the p-doped layer. When incorporated into the crystal lattice, this dopant displaces atoms of the original semiconductor (e.g. the trivalent component) to interstitial sites. These interstitial atoms cause quantum well intermixing in the active layer, which increases the band gap. The local area of the quantum well intermixing is given by the mask, i.e. in the area below the mask no quantum well intermixing takes place in the quantum well as shown in FIG. 60. However, the diffusion of the dopant also causes increased doping in the region marked “Region II”, thus forming a barrier to the lateral diffusion of charge carriers in the quantum well. This barrier is already partially below the mask and is thus locally offset from the boundary of quantum well intermixing. Thus, there are two barriers that reduce the lateral diffusion of charge carriers, one caused by the increased doping and the other by quantum well intermixing.

As shown in FIG. 60, boundary 36 of the quantum well intermixing and boundary 37 of the additional μ-doping are locally offset, i.e. they do not coincide. From the point of view of carrier diffusion, this means that an increase in the barriers is also gradual. The separation between deposition of the dopant and diffusion now allows a change of the diffusion profile by a free choice of a suitable temperature profile during the diffusion process. Thus, for example, the barrier 37 can be shifted towards the barrier 36. This makes the barrier for carrier diffusion steeper at the boundary 50. Likewise, the density of impurities caused by the diffused material or the displaced atoms in the active layer is reduced by the specification of the process parameters. Additionally or alternatively, the electrical activation of the second dopant and thus the barrier caused by the additional μ-doping can be increased by optimized process parameters during the diffusion process, which leads to a stronger reduction of the lateral charge carrier diffusion.

FIG. 61 shows a simulation of the height of the doping barrier for LEDs with small dimensions (<10 μm) as a function of the doping concentration at low currents. The increased doping shows a significant increase of the doping barrier by a factor of almost two. Thus, charge carriers are effectively kept away from the edge region, but also from regions with an increased number of impurities due to the introduced second dopant.

This results in a higher internal quantum efficiency. FIG. 62 shows a diagram showing the internal quantum efficiency versus the current at different dopant concentrations. Clearly visible is the improved maximum at higher concentrations for a current in the range of about 0.1 mA.

With the proposed principle and the various measures, an improvement of an optoelectronic device is achieved in both low and high current efficiency. Imperfections in the optically active region of an active layer are reduced. At the same time charge carriers can be kept away from the edge of the device (or around the active layer) due to the higher diffusion barriers at the edge of the device, thus reducing the amount of non-radiative surface recombination. This is especially important for μ-LEDs with an edge length of 70 μm or less.

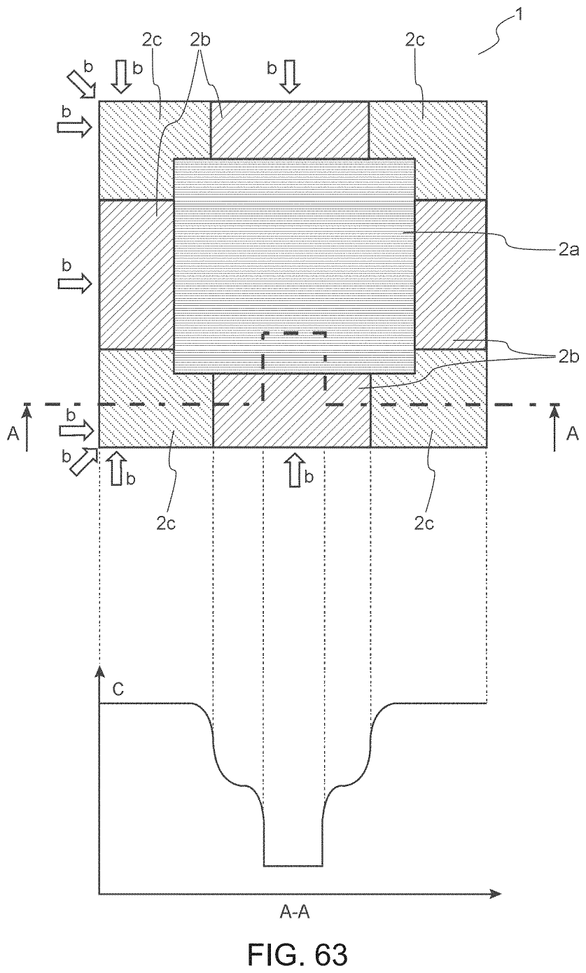

To explain the different aspects of a concentric arrangement of a quantum well intermixing FIG. 63 shows in contrast thereto a square LED which, contrary to the present invention, has several areas 2b and 2c in which quantum well intermixing takes place, but none of the second and third areas concentrically encloses the first area.

The first area 2a can be formed, for example, by applying a diffusion mask, possibly with the same or similar shape and size. For this purpose, a second dopant b is applied to the open areas 2b and 2c around the diffusion mask so that quantum well intermixing can take place in these areas. According to the above description, the edge of the square LED contains a higher impurity concentration in the corner areas 2c or shows a higher quantum well intermixing than, for example, in the middle of the side lengths 2b, since at the corners the impurities b can diffuse from more than one side. This results in the diffusion process in the regions 2b and 2c, which each have a different impurity concentration in the quantum well in the active layer 2. This effect leads to different quantum well intermixing in the regions 2b and 2c at the edge of the μ-LED and thus to different band gaps in the quantum well of the active layer 2, which reduces the power of the μ-LED.

This effect is illustrated by the cross-section of the μ-LED shown in FIG. 63 and the concentration of the second dopant b derived from it along the cross-sectional axis A-A. From this, it can be seen that the concentration of the second dopant b is higher in the corners, i.e. in the third areas 2c, than in the first and second areas 2a, 2b. A further drop in concentration occurs from the second region 2b towards the first region 2a. In a mirrored manner, a concentration increase from the first region 2a via the second region 2b to the third region 2c results corresponding to this concentration decrease.

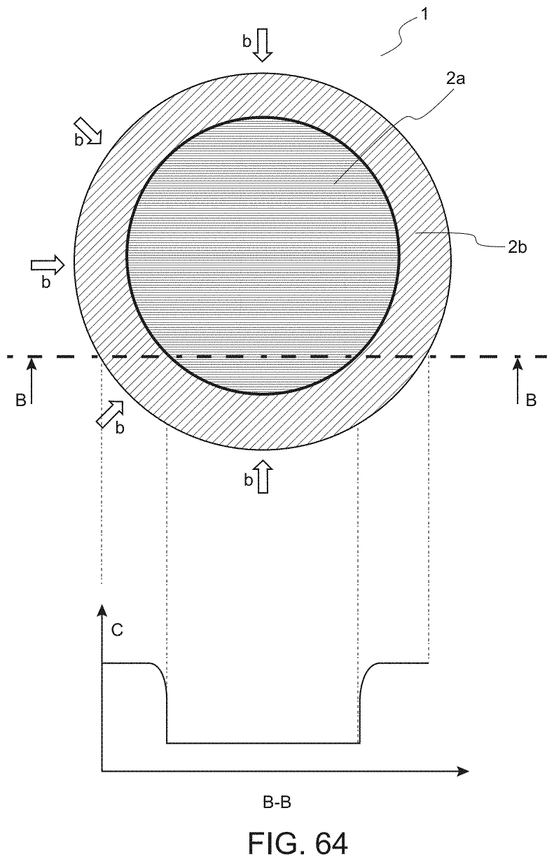

However, this concentration course is only to be regarded as a qualitative course and does not represent absolute values or ratios between the dopant concentrations in the first, second and third ranges 2a, 2b, 2c. The negative effect of a different band gap due to the different quantum well intermixing in the regions 2b and 2c is solved by a modified geometry of the optoelectronic device 1, shown in FIG. 64. The two regions 2a and 2b of the optoelectronic device 1 are concentrically arranged and the second region 2b completely encloses the first region 2a.

The first area 2a is formed by applying an at least approximately circular diffusion mask, possibly of the same or similar shape and size. Subsequently, a second dopant b is applied to the exposed region 2b around the diffusion mask so that quantum well intermixing can take place in these regions. This shape allows a second dopant b introduced into the second region 2b to diffuse uniformly along the circumference of the two regions 2a, 2b into the second region 2b as homogeneously as possible and, unlike the angular shape of a μ-LED described above, there is not a higher impurity concentration or quantum well intermixing in the corners than, for example, in the middle of the side lengths of the μ-LED.

This effect becomes clear when comparing FIG. 63 and FIG. 64, since in FIG. 63 the impurities/the second dopant b can diffuse in from more than one side at the four corners of the third region 2c, whereas in FIG. 64 the dopant b can diffuse vertically and equally distributed at any point of the outer circumference of the second region 2b.

Furthermore, FIG. 64 shows the corresponding cross-section of the optoelectronic device 1 and the concentration of the second dopant b derived from it along the intersection axis B-B. The concentration of the second dopant b is largely constant in the region of the second region 2b and decreases in a defined transition region from the second region 2b to the first region 2a. In the first region, in turn, the concentration of the second dopant b is largely constant and increases in a defined transition region from the first region 2a to the second region 2b. However, the concentration of the second dopant b can vary and does not represent any absolute values or ratios between the dopant concentrations in the first and second range 2a, 2b. Likewise, the defined transition region between the second and the first region can also vary and be both somewhat flatter and steeper.

The only decisive factor is that a largely sharp edge is formed in the transition region from the first region 2a to the second region 2b and that the dopant concentration in the first region 2a is largely zero or in a ratio of less than or equal to 2, for example less than or equal to 5 or even less than 10 to the dopant concentration in the second region 2b. In other words, the dopant concentration in the second region 2b is, for example, greater than or equal to 2, for example greater than or equal to 5 or also greater than 10 in relation to the dopant concentration in the first region 2a.

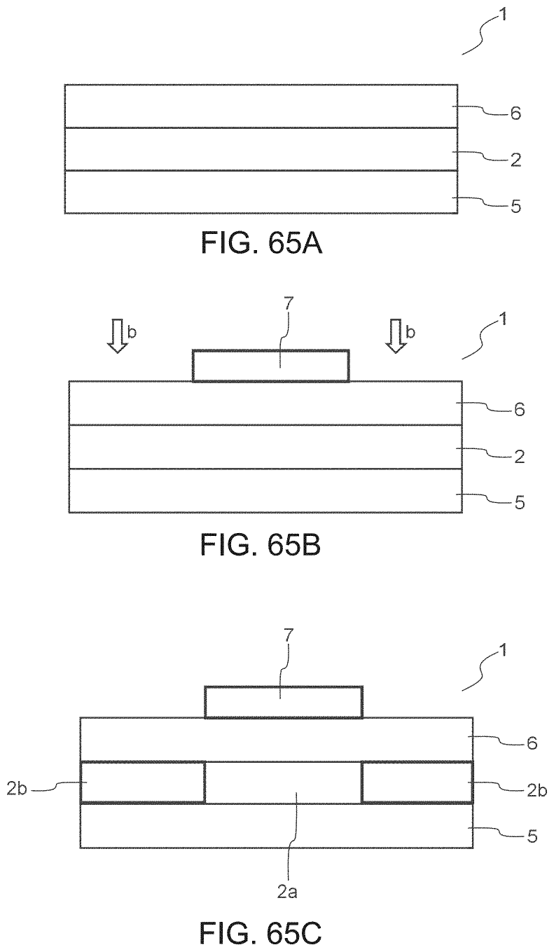

FIGS. 65A, 65B and 65C show the layer structure and the production of an optoelectronic device 1 as shown in FIG. 64. The optoelectronic device 1 comprises an n-doped first layer 5, a p-doped second layer 6, and an active layer 2 which is located between the n-doped first layer 5 and the p-doped second layer 6 and which comprises at least one quantum well.

By applying a diffusion mask 7, for example a dielectric such as silicon dioxide, silicon nitride, silicon oxynitride, aluminium oxide or for example a photomask, a corresponding mask with the circular shape substantially identical to the first region 2a is created on the surface of the p-doped second layer 6.

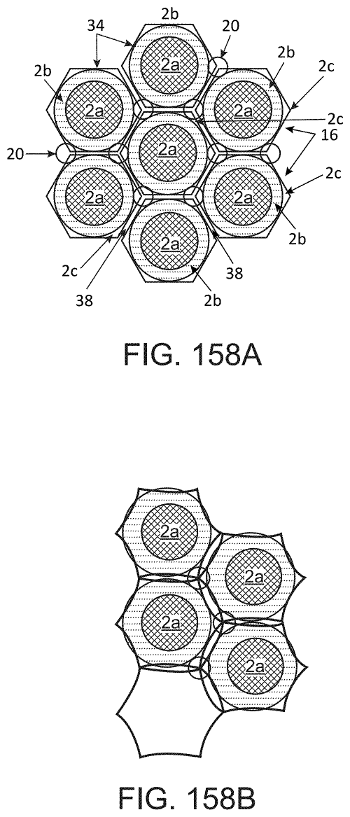

In another aspect, the surface can be covered with a thin layer before applying the photomask, which also serves as a photomask and can thus be used for processing. This can be done in some more complex arrangements to save process steps including especially new deposition or structuring of masks. Such a more complex structure would be the designs of FIGS. 158A and 158B. The thin additional layer is for example chrome. This is underetched, i.e. an etching process also removes part of the chromium layer, so that the mask and the thin chromium layer underneath can be used for two or more etching processes. In the same way, chromium can serve as a diffusion barrier for the second dopant.

Subsequently, the second dopant is applied and diffused. By applying and diffusing the second dopant b onto the remaining surface of the p-doped second layer 6, the second dopant b diffuses into the active layer 2 and forms the at least two regions 2a, 2b therein. Correspondingly, the two regions 2a, 2b in the active layer 2 result in the form of a projection of the diffusion mask 7, which is applied to the surface of the p-doped second layer 6, in the active layer 2.

Under suitable process conditions, the diffusion of the second dopant b into the active layer 2 causes the quantum well intermixing described above. The first region 2a, in particular the optically active region, results as the region which is located in direct projection below the diffusion mask 7 and into which substantially no second dopant b diffuses due to the diffusion mask 7.

The second region 2b is accordingly the region, which is located in direct projection below the region that is exposed as a free surface to the second dopant b around the diffusion mask 7.

Consequently, the second dopant b diffuses into the second p-doped layer 6, into the active layer 2, into the second region 2b and, depending on the doping profile and process parameters, partially also into a region of the n-doped layer 5 adjacent to the active layer 2.

From this it follows that the second region 2b contains the second dopant b and thus quantum well intermixing.

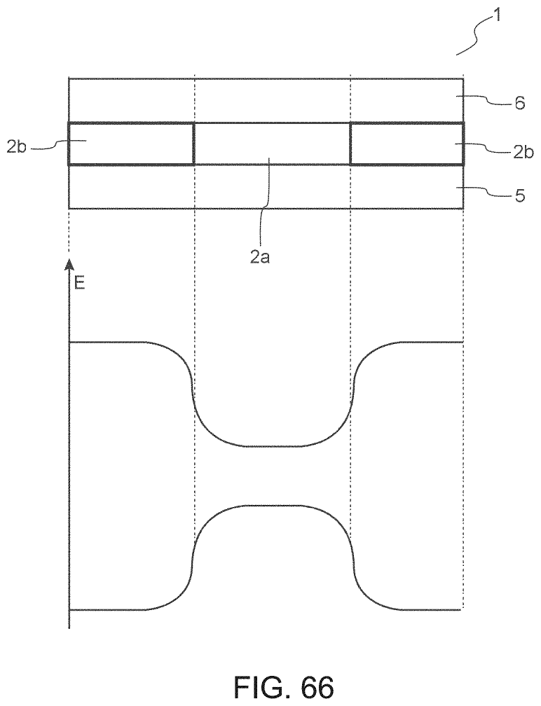

FIG. 66 shows the layer structure of the optoelectronic device 1 after application of the diffusion mask 7 and diffusion of the second dopant b, and the band gap of the at least one quantum well in the active layer 2.

The energy of the band gap E is constant in the second area 2b viewed from left to right and drops in a defined transition area from the second area 2b to the first area 2a. In the first region 2a, the energy of the band gap E again comprises a constant value and rises in a defined transition region from the first region 2a to the second region 2b, wherein the energy of the band gap E of the second region 2b again assumes a constant value.

However, the band gap E energy curve shown may vary and does not represent absolute values or ratios between the band gap E energy in the first and second range 2a, 2b. Likewise, the defined transition region between the second and the first region can also vary and be both somewhat flatter and steeper. The only decisive factor is that the energy of the band gap E of the first range 2a is smaller than that of the second range 2b, and that the energy of the band gap E in the first and second ranges 2a, 2b is substantially constant.

In addition to a geometrical consideration of how to improve the performance in the area of a single LED, the following provide examples on how to improve a quantum well intermixing at wafer level. μ-LED structures are produced independently of their later use as individual components or in monolithic form on wafer level. By means of the above-mentioned Zn diffusion and other measures, improvements in low and high current efficiency can be achieved by lowering the impurity density in the area of the later active layer and permanently binding or saturating impurity atoms.

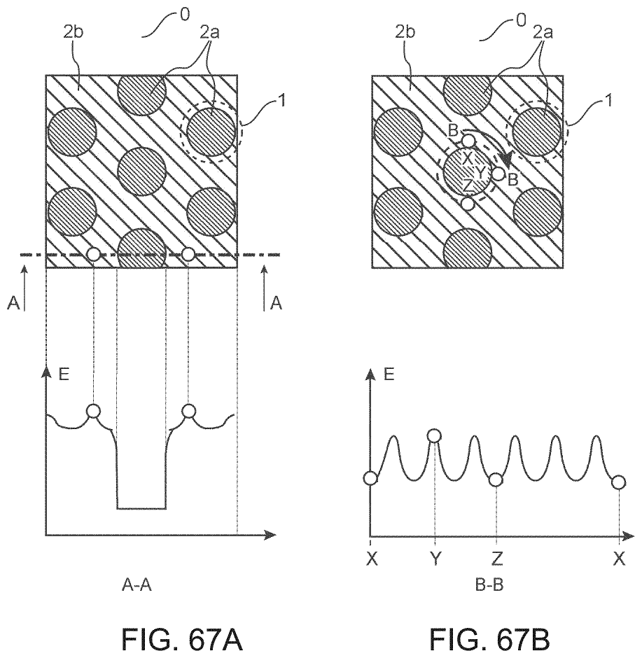

FIG. 67A shows the top view of a section of a first type of semiconductor structure 0, and the corresponding cross-sectional profile of the energy of the bandgap of the semiconductor structure along the intersection axis A-A. In semiconductor structure 0, a large number of first optically active regions 2a and a second region 2b are formed. The plurality of first optically active regions 2a are arranged spaced apart from one another in a hexagonal pattern and the one second region 2b encloses the plurality of first optically active regions 2a and is arranged in their interstices.

Furthermore, one optically active region 2a of each of the plurality of first optically active regions 2a of the semiconductor structure 0 forms part of each of a plurality of optoelectronic components 1. In this context, the optoelectronic components can be regarded as μ-LEDs due to their overall dimensions. The plurality of first optically active regions 2a can be formed, for example, by applying a mask or, for example, by applying mask segments possibly having the same or similar shape and size. Subsequently, a second dopant b is applied to the exposed second area 2b around the mask or around the mask segments so that a QWI can take place in this area. Due to the diffusion of the second dopant and the associated QWI in the second region, the energy of the band gap changes in this region compared to the regions in which no quantum well intermixing takes place.

The section of the semiconductor structure 0 shown in FIG. 67A and the band gap energy curve derived from it along the intersection axis A-A shows the band gap energy curve in the areas 2a and 2b. It can be seen that the band gap energy is greater in the second region 2b than in the first optically active regions 2a. A reduction in the energy of the band gap results from the second region 2b towards the first optically active region 2a and in a mirrored manner, corresponding to this reduction, an increase in the energy of the band gap results from the first optically active region 2a towards the second region 2b.

This and similar courses in the following, however, are to be regarded as qualitative courses only and do not represent absolute values or ratios of the energy of the band gap in the plurality of first optically active areas 2a and the second area 2b. Likewise, the transition region between the second and the first optically active region can also vary and be both somewhat flatter and steeper. The only decisive factor is that a largely sharp edge is formed in the transition region of the plurality of first optically active regions 2a towards the second region 2b and that the energy of the band gap in the plurality of first optically active regions 2a is smaller than the energy of the band gap in the second region 2b.

In other words, this means that a dopant concentration of the second dopant b in the second region 2b is greater than the dopant concentration of the second dopant b in the plurality of first optically active regions 2a.

Furthermore, FIG. 67A shows that the energy of the band gap in the second region 2b does not have a constant value, but has local maxima of the energy of the band gap in the regions where the largest possible distance between the plurality of first regions 2a occurs. This is due to the fact that the diffusion process and thus the quantum well intermixing takes place more efficiently in the region of larger areas exposed to the second dopant b than in smaller gaps between two first optically active regions 2a covered by, for example, a mask.

The section of the semiconductor structure 0 shown in FIG. 67B and the band gap energy curve along the intersection axis (B-B) derived from it shows the band gap energy curve along the circumference of an optoelectronic device 1. The intersection axis runs through the second region 2b. According to the above explanation, the energy of the band gap in the second region 2b does not have a constant value, but has maxima in the regions where the largest possible distance between the plurality of first regions 2a occurs and minima in the regions where the smallest possible distance between the plurality of first regions 2a occurs. In FIG. 67B, the regions of local maxima of the bandgap energy of the semiconductor structure are designated Y as an example, and the regions of local minima of the bandgap energy of the semiconductor structure are designated X and Z as examples.

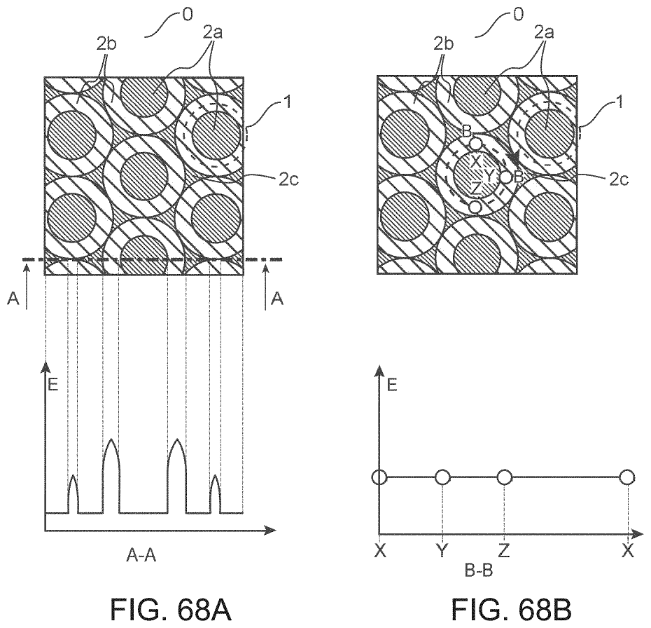

In practice, however, it is desirable to achieve a band gap energy as homogeneous and constant as possible in the second region 2b of the semiconductor structure 0 and correspondingly along the circumference of an optoelectronic device 1. In the following, therefore, the three designs (FIGS. 68A and 68B, 69A and 69B and 70A and 70B) are presented, among others, to counteract the effect of local maxima of the bandgap energy in semiconductor structure 0. FIGS. 68A and 68B, 69A and 69B and 70A and 70B each show a plan view of a design form of semiconductor structure 0 of the invention and an associated cross-sectional profile of the energy of the bandgap of the semiconductor structure along the intersection axes A-A and B-B.

In addition to the example of a structure in FIGS. 67A and 67B, at least one third area 2c is formed in addition to the large number of first optically active areas 2a and the at least one second area 2b. This at least one third area 2c is in turn arranged in the spaces between the plurality of first optically active areas 2a.

More precisely, FIG. 68A shows a section of a semiconductor structure 0 with a plurality of first optically active regions 2a, a second region 2b and a plurality of third regions 2c. The plurality of first optically active regions 2a are spaced apart in a hexagonal pattern as described above. The second region 2b encloses the plurality of first optically active regions 2a in such a way that one each of the plurality of first optically active regions 2a is enclosed annularly and/or concentrically by the second region 2b. The second region 2b is divided, for example, into ring segments and is connected, for example, only point-wise to the next adjacent ring segment of the second region 2b. The plurality of the third area 2c is formed as a deltoid curve of three of the ring segments of the second area 2b.

The large number of first optically active areas 2a and third areas 2c can be formed, for example, by applying a mask or, for example, by applying mask segments possibly with the same or similar shape and size. Subsequently, a second dopant b is applied to the exposed second region 2b around the mask or around the mask segments, respectively, so that a QWI can take place in this region.

The section of the semiconductor structure 0 shown in FIG. 67A and the energy of the band gap along the intersection axis A-A shows the energy of the band gap in the areas 2a, 2b and 2c. This indicates that the band gap in the second region 2b is larger than in the first optically active regions 2a and third regions 2c. In the areas where the axis A-A intersects the second area 2b, a local increase of the band gap can be seen. The energy of the band gap is higher or lower depending on the area of the second region 2b intersected by the A-A axis.

However, this curve is to be regarded as a qualitative curve only and does not represent absolute values or ratios of the energy of the band gap of the plurality of first optically active regions 2a, the second region 2b and the plurality of third regions 2c. Likewise, the transition regions between the first optically active region, the second region 2b and the third regions 2c can also vary and be both somewhat flatter and steeper.

The decisive factor is that a largely sharp edge is formed in the transition region of the plurality of first optically active regions 2a towards the second region 2b and in the transition region from the third regions 2c towards the second region 2b and that the energy of the band gap in the plurality of first optically active regions 2a and third regions 2c is smaller than the energy of the band gap in the second region 2b. This means in other words that the dopant concentration of the second dopant b in the second region 2b is greater than the dopant concentration of the second dopant b in the plurality of first optically active regions 2a and third regions 2c.

The section of the semiconductor structure 0 shown in FIG. 68B and the band gap energy curve derived from it along the intersection axis B-B shows the band gap energy curve along the circumference of an optoelectronic device 1. The intersection axis runs through the second region 2b. Contrary to the illustration in FIG. 67B, the energy of the band gap in the second region 2b shows less variation. By introducing the plurality of third regions 2c, it is achieved that in the region of the interstices of three of the plurality of first optically active regions 2a, the local maxima of the bandgap energy in the semiconductor structure 0 are less pronounced. Thus, a more uniform band gap energy can be achieved in the second region 2b. This in turn leads to an increase in performance of the optoelectronic components 1.

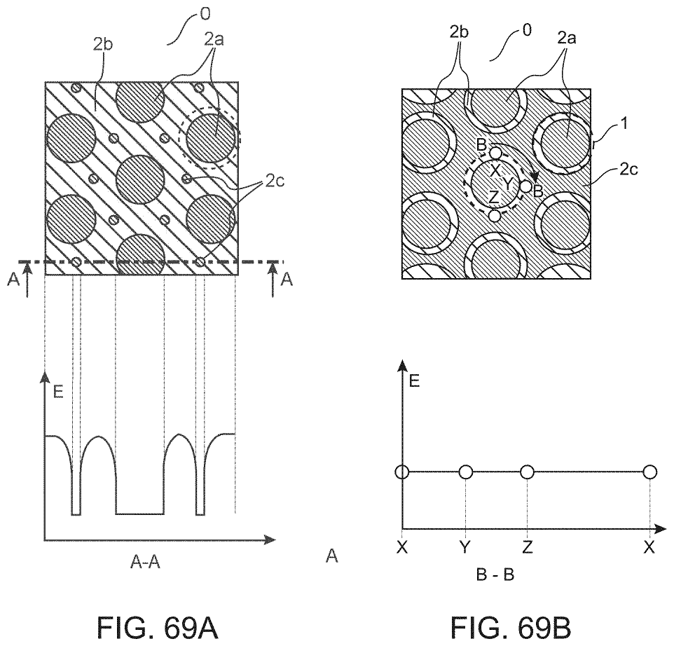

A further version of the semiconductor structure 0 according to the invention and the course of the energy of the band gap in the semiconductor structure 0 along the intersection axes A-A and B-B derived from it is shown in FIGS. 69A and 69B.

The plurality of the third areas 2c are formed circular in it and arranged in the middle of three of the plurality of first optically active areas 2a. Likewise, the term circular can also include elliptical, as well as oval and other rounded convex shapes. This arrangement of the plurality of third regions 2c serves, in analoguey to FIGS. 68A and 68B, to reduce local maxima of the applied second dopant b to the semiconductor structure 0 in order to achieve a substantially uniform dopant concentration in the second region 2b. The circularly formed third regions 2c shown in FIG. 69A and arranged in the middle of three of the plurality of first optically active regions 2a in each case already show an increase in performance of the optoelectronic components 1. Accordingly, the second region 2b does not result as continuous ring segments but fills the space between the plurality of first optically active regions 2a and third regions 2c.

The large number of first optically active areas 2a and third areas 2c can be formed, for example, by applying a mask or, for example, by applying mask segments possibly with the same or similar shape and size. For this purpose, a second dopant b is applied to the exposed second region 2b around the mask or around the mask segments, so that a QWI can take place in this region.

The section of the semiconductor structure 0 shown in FIG. 69A and the energy of the band gap along the intersection axis A-A derived from it shows the energy of the band gap in the areas 2a, 2b and 2c. From this, it can be seen that the energy of the band gap is greater in the second region 2b than in the first optically active regions 2a and third regions 2c. In the areas where the axis A-A intersects the second area 2b, a local increase of the band gap can be seen. Likewise, the transition regions between the first region, the second region 2b and the third regions 2c may vary and be both slightly flatter and steeper.

A decisive factor is that a largely sharp edge is formed in the transition region of the plurality of first optically active regions 2a towards the second region 2b and in the transition region from the third regions 2c towards the second region 2b and that the energy of the band gap in the plurality of first optically active regions 2a and third regions 2c is smaller than the energy of the band gap in the second region 2b. This means, in other words, that the dopant concentration of the second dopant b in the second region 2b is greater than the dopant concentration of the second dopant b in the plurality of first optically active regions 2a and third regions 2c.

The section of the semiconductor structure 0 shown in FIG. 69B and the band gap energy curve derived from it along the intersection axis indicated by the arrow shows the band gap energy curve along the circumference of an optoelectronic device 1. The intersection axis runs through the second region 2b. As shown in FIG. 68B, the energy of the band gap in the second region 2b again does not have a constant value.

Since the plurality of third areas 2c each cover a smaller area than the plurality of third areas 2c of the design in FIG. 68A, there are more pronounced local maxima in those areas where there is the greatest possible distance from the plurality of first areas 2a and third areas 2c. Similarly, local minima also occur in those areas where the smallest possible distance between the plurality of first areas 2a and third areas occurs. In FIG. 69B, the regions of local maxima of the bandgap energy of the semiconductor structure are designated X and Z as examples, and the regions of local minima of the bandgap energy of the semiconductor structure are designated Y as examples.

The decisive factor is that, compared to the embodiment in FIG. 67A, by the introduction of the large number of third regions 3c, the local maxima of the bandgap energy in the semiconductor structure 0 are smaller in magnitude, so that a comparatively homogeneous and constant energy of the bandgap along the circumference of an optoelectronic device 1 or within the second region 2b prevails in the semiconductor structure 0. This in turn already leads to an increase in performance of the optoelectronic components 1.

Furthermore, FIG. 69B shows that one optically active region 2a of each of the numerous first optically active regions 2a of the semiconductor structure 0 forms a part of each optoelectronic device 1.

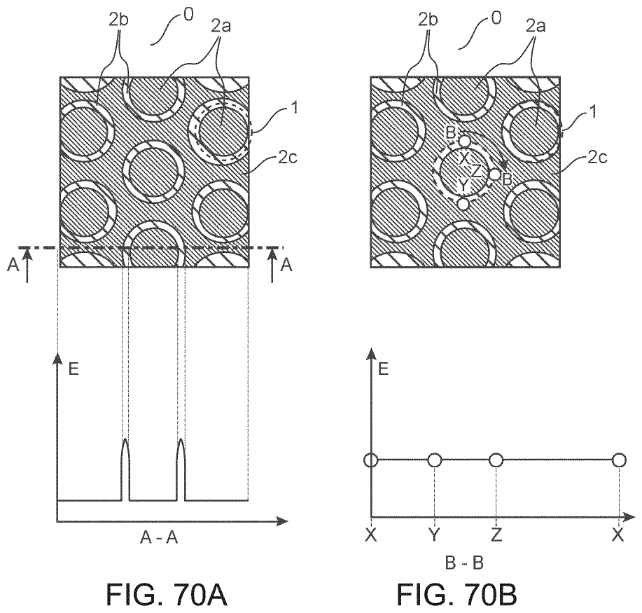

A further version of the semiconductor structure 0 according to the invention and the course of the energy of the band gap in the semiconductor structure 0 along the intersection axes A-A and B-B derived from it is shown in FIGS. 70A and 70B.

The plurality of first optically active areas 2a are each concentrically enclosed by a second area 2b. Correspondingly, a plurality of second areas 2b results, which are each arranged in a ring or circle around one of the plurality of first optically active areas 2a. Likewise, the term ring-shaped or circular can also include elliptical, as well as oval and other rounded convex shapes.

Furthermore, the semiconductor structure 0 has a third region 2c, which is located in the gaps between the plurality of first optically active regions 2a and second regions 2b. The plurality of first optically active regions 2a and the third region 2c can be formed, for example, by the application of a mask or, for example, by the application of mask segments possibly having the same or similar shape and size. For this purpose, the exposed second areas 2b around the mask or around the mask segments are exposed to a second dopant b so that a QWI can take place in this area.

This ring-shaped arrangement of the plurality of second regions 2b around one of the plurality of first optically active regions 2a and the third region 2c in each case avoids the formation of local maxima of the applied second dopant b in the region of the interstices of three first optically active regions 2a in each case. In this way, a substantially uniform dopant concentration can be achieved in the plurality of second regions 2b. This in turn leads to a substantially uniform QWI in the plurality of second regions 2b, which leads to an increase in the performance of the optoelectronic components 1.

The band gap energy curve along the intersection axis A-A shown in FIG. 70A shows that the band gap energy is greater in the second region 2b than in the first optically active regions 2a and the third region 2c. In the areas where the axis A-A intersects the second area 2b, a local increase in the band gap is visible.

However, this progression is to be regarded as a qualitative progression only and does not represent absolute values or ratios between the energy of the band gap of the plurality of first optically active regions 2a, the second region 2b and the third region 2c. Likewise, the transition regions between the first optically active region, the second region 2b and the third region 2c can also vary and be both somewhat flatter and steeper.

A decisive factor is that a largely sharp edge is formed in the transition region of the plurality of first optically active regions 2a towards the second regions 2b and in the transition region from the third region 2c towards the second regions 2b and that the energy of the band gap in the plurality of first optically active regions 2a and in the third region 2c is smaller than the energy of the band gap in the second regions 2b.

This means in other words that the dopant concentration of the second dopant b in the second region 2b is higher than the dopant concentration of the second dopant b in the plurality of first optically active regions 2a and the third region 2c.

The section of the semiconductor structure 0 shown in FIG. 70B and the band gap energy curve derived from it along the intersection axis B-B shows the band gap energy curve along the circumference of an optoelectronic device 1. The intersection axis runs through the second region 2b. In contrast to the illustration in FIGS. 67B, 68B and 69B, the energy of the band gap in the second region 2b comprises a largely constant value. By introducing the third region 2c, it is avoided that local maxima of the applied second dopant b are formed in the area of the interstices of each of the three first optically active regions 2a, and thus no local maxima of the bandgap energy in the semiconductor structure 0 arise. Thus, a substantially uniform band gap energy can be achieved in the second region 2b.

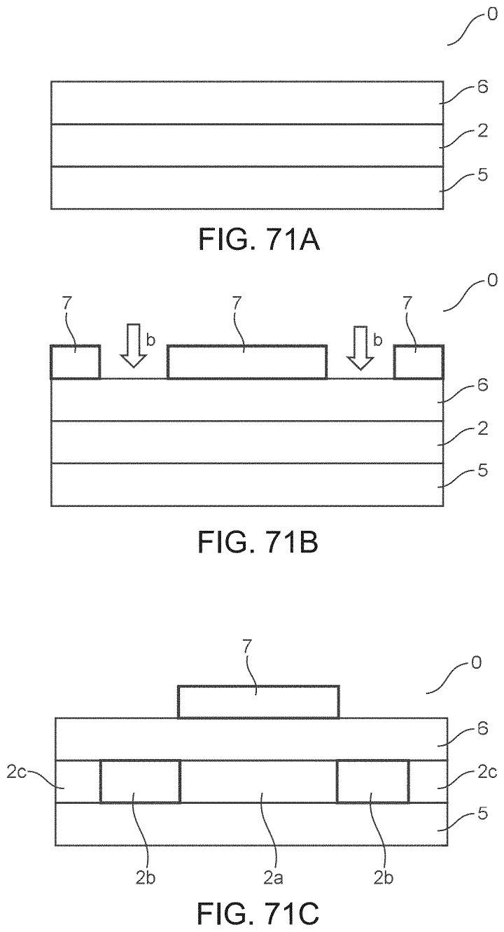

FIGS. 71A, 71B and 71C show the layered structure and correspondingly the production of a semiconductor structure 0 as shown in FIGS. 68A, 69A and 70A. The semiconductor structure 0 comprises an n-doped first layer 5, a p-doped second layer 6 containing a first dopant and an active layer 2, which is arranged between the n-doped first layer 5 and the p-doped second layer 6 and which has at least one quantum well. The layers are deposited, for example, epitaxially on a carrier substrate not shown here. In addition to the layers shown here, further layers, contact layers, sacrificial layers and the like can be provided.

FIG. 71B shows the next step in which a structured mask 7 is applied. The mask is pierced in some places so that dopant b is introduced there. Diffusion of the second dopant b into the active layer 2 causes the QWI described above.

By applying a mask, or rather, by applying mask segments 7, for example a dielectric or a photoresist mask, to the surface of the p-doped second layer 6 and the subsequent diffusion process, the structure shown in FIG. 71C is created. It shows a number of optically active regions below mask 7 with surrounding second regions 2b and the at least one third region 2c. As mentioned above, the structure and the build-up result from the structuring of the applied mask 7. The second dopant b diffuses through the p-doped second layer 6 and into the active layer 2, forming the regions 2a, 2b and 2c therein. Correspondingly, the regions 2a, 2b and 2c in the active layer 2 are formed in the active layer 2 in the form of a projection of the mask or the mask segments 7, respectively, which is deposited on the surface of the p-doped second layer 6.

The plurality of the first optically active regions 2a and the at least one third region 2c result as the regions which are located in direct projection below the mask or the mask segments 7 and into which essentially no second dopant b diffuses due to the mask or the mask segments 7.

The at least one second region 2b results accordingly as the region which is located in direct projection below the region which is exposed to the second dopant b as a free surface around the mask or the mask segments 7. Consequently, in the at least one second region 2b, the second dopant b diffuses into the second p-doped layer 6, into the active layer 2 and, depending on the doping profile and process parameters, partially also into a region of the n-doped layer 5 adjacent to the active layer 2.

It follows that the at least one second region 2b has the second dopant b and thus a QWI.

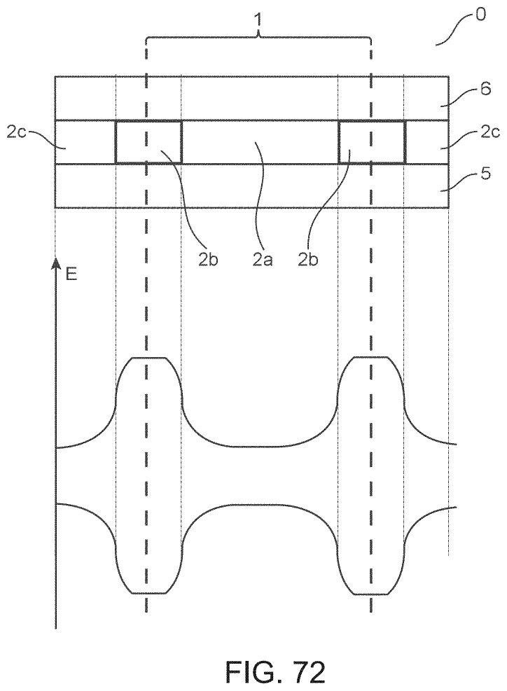

In addition to the layer structure of the semiconductor structure 0 after application of the mask or the mask segments 7 and diffusion of the second dopant b, FIG. 72 shows the band gap of the at least one quantum well in the active layer 2. Shown is the energy of the band gap E in vertical direction of the diagram over the cross-section of the semiconductor structure 0 in horizontal direction of the diagram.

The energy of the band gap E is constant in the third region 2c viewed from left to right and increases in a defined transition region from the third region 2c to the second region 2b. In the second region 2b, the energy of the band gap E comprises a constant value and then decreases in a defined transition region from the second region 2b to the first optically active region 2b, wherein the energy of the band gap E of the first optically active region 2a assumes a constant value. In a mirrored manner, corresponding to this course, there is an increase in the energy of the band gap E in a defined transition region from the first optically active region 2a to the second region 2b and a decrease in the energy of the band gap E in a defined transition region from the second region 2b to the third region 2c.

However, the represented course of the energy of the band gap E may vary and does not represent absolute values or ratios between the energy of the band gap E in the first optically active regions 2a, the at least one second region 2b and the at least one third region 2c. Likewise, the transition region between the at least one second region 2b and the first optically active regions 2a and the transition region between the at least one second region 2b and the at least one third region 2c can also vary and be both somewhat flatter and steeper.

A decisive factor is that the energy of the band gap E of the first optically active regions 2a and of the at least one third region 2c is smaller than that of the at least one second region 2b, and that the energy of the band gap E is substantially constant in the respective first optically active regions 2a and the at least one second region 2b along the circumference of region 2a.

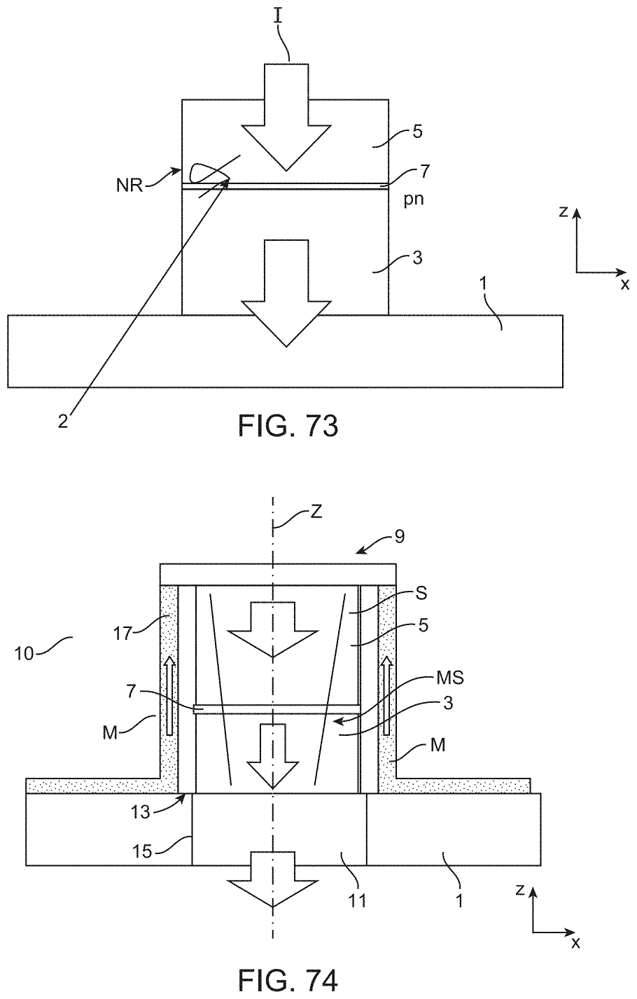

Before aspects of the magnetic constriction is explained, reference is made to FIG. 73. The figure shows an embodiment of a conventional light-emitting diode. The light emitting diode is supplied with power, whereby an electric current flows from the top of the light emitting diode, represented here by thick arrows, to an active layer with a so-called pn junction. In addition to radiative recombination, undesirable non-radiative recombination NR takes place there, which should be avoided or reduced in intensity. The non-radiative recombination result from the diffusion of charge carriers to the edge, whereby the defect density at the edge is increased or other effects occur. This diffusion of charge carriers to the edge is indicated by the reference sign 2. NR reduces the quantum efficiency and is essentially converted into heat. Especially, with small chips the ratio of radiative recombination to non-radiative recombination becomes worse. It is therefore desirable to develop methods to constrict the charge carriers and limit them to the center.

FIG. 74 shows a longitudinal section along an X-Z plane of a first embodiment of an optoelectronic device 10 of the invention. The device is formed as a layer stack S, which has a first layer 3 on a carrier 1, on which an active layer 7 is deposited and on which a second layer 5 has been deposited. A first contact 9 is formed on a surface area of the second layer 5 facing away from the carrier 1 and a second contact 11 is formed on the first layer 3 by means of the carrier 1. The first layer 3 is n-doped and the second layer 5 is p-doped, so that in particular the first contact 9 forms the anode and the second contact 11 the cathode. Here, the layer stack S comprises an electrically insulating coating 13 and a passivating coating 15 along its lateral surface and on the side facing the carrier 1. The first contact can, for example, have ITO (indium tin oxide), so that light generated in the active layer is emitted upwards.

Furthermore, the device comprises a magnetizing element M, which provides magnetic field lines along the X-Y plane when current flows along the Z-axis of the (entire) stack of layers S. The magnetizing element M comprises a number of strip-shaped current lines 17 running along the Z-axis and along the lateral surface of the layer stack S. Depending on the direction of the current (i.e. depending on the function of contact 9 as anode or cathode) a current flow runs along the current lines and antiparallel through the stack of layers. In this way, the charge carriers, especially electrons, repel each other. The resulting magnetic current constriction MS, a kind of “electron lens”, is illustrated by two lines running towards each other.

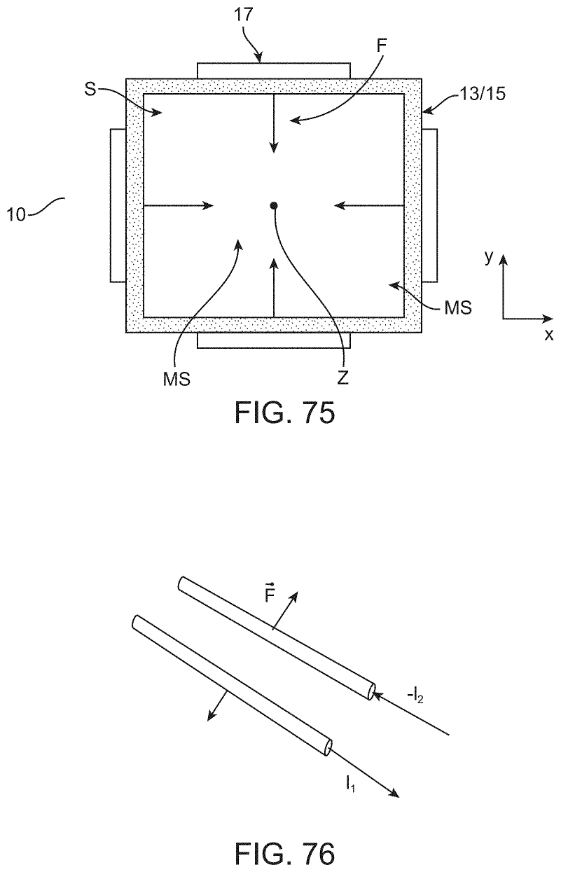

FIG. 75 shows a cross-section along an X-Y plane of the first embodiment of the optoelectronic device 10 of the invention. In the center of the X-Y cross-sectional plane extends the Z-axis along which a current flows along an optoelectronic device 10. In the form of conductor strips or conductor bands, current lines 17 are generated along the lateral surfaces of the layer stack S. Here, a total of four current lines 17 are formed on the cuboidal layer stack S, whose currents flow antiparallel to the current through a light-emitting diode, for example. These current lines 17 form a magnetizing element M, whereby the charge carriers, for example electrons, flowing in the optoelectronic component 10 move in the direction of a carrier 1 and are deflected in the direction of the Z-axis as a result of the magnetic fields generated along an X-Y plane by the current lines 17. In this way, forces F act on the charge carriers, in particular electrons, which are displaced from the edge of the device 10. This results in a constriction of the current distribution (a magnetic current constriction MS) and a kind of “electron lens” is created in such a way that non-radiative recombination at chip edges or mesa edges of the optoelectronic device 10 is reduced. The outer surface of the optoelectronic component also comprises an electrically insulating coating 13 and a passivating coating 15.

FIG. 76 shows an illustration of the mode of operation of the first embodiment. The antiparallel current I1 to -I2 in the two lines produces a force F that moves the two lines away from each other. The magnetic fields that arise around the two lines due to the currents act. The same is true for the embodiment shown in FIG. 74 and FIG. 75.

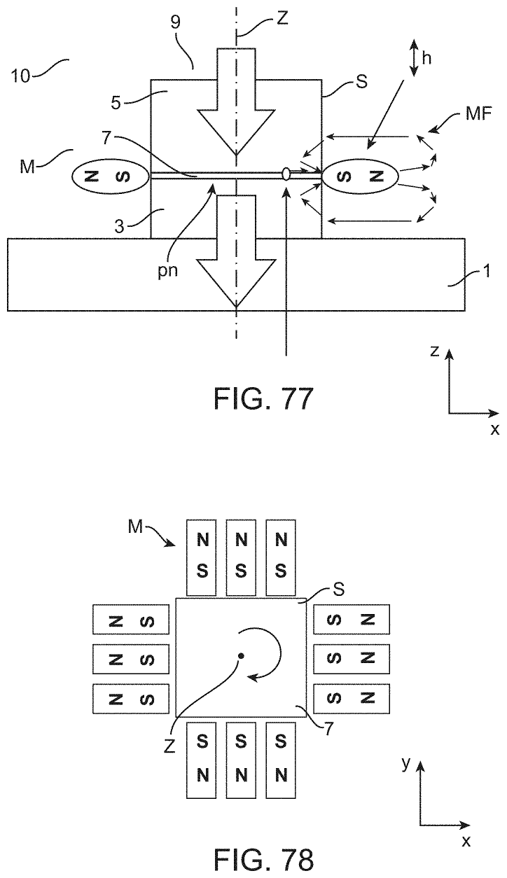

FIG. 77 shows a longitudinal section of a second embodiment of an optoelectronic component that is in accordance with the invention. A magnetizing element M is here formed in the region of an active layer 7 in the form of four permanent magnetic dipoles. This position can be varied in height h to provide magnetic forces specifically within the active layer 7 with the quantum wells. In this way, magnetic field lines MF, especially along the Z-axis, can be specifically impressed against the main direction of motion of the charge carriers and thus in a region in front of the active layer 7. The south poles of the magnetic field lines are facing the active layer 7 and the north poles are facing away from the active layer 7. The poles can also be reversed. The course of the generated magnetic fields MF causes the preferred direction of movement of an electron along a Y-axis to run out of the drawing plane or the X-Z plane. Thus, a random movement of an electron without the respective magnetic field due to diffusion to the edge of the active layer 7 of the layer stack S is deflected into a lateral direction of movement by means of the targeted force of the magnetic field. This results in a preferential direction of random diffusion to the opposite other edge of the active layer 7 of the layer stack S, where the electron is diverted away from the edge there again, since the force there then acts again in a different lateral direction. In this way, an electron in the active layer 7 can be deflected along a spiral line in the direction of the Z-axis, especially if a large number of permanent magnet dipoles along the edge region of the active layer 7 in the X-Y plane frame or circumferences the active layer 7. A layer stack S can be created as a cuboid or alternatively as a cylinder, for example. In principle, alternative geometric shapes of the layer stack S such as cones, truncated cones or pyramids are also possible. According to this embodiment, the first contact 9 provides an anode.

The positioning of the permanent magnet dipoles along the Z-axis is selected to increase the reduction of non-radiative recombination. In principle, the magnetic dipoles used can be horizontal along an X-Y plane or vertical along a Z-axis.

FIG. 78 shows a cross-section of the second embodiment of the optoelectronic device 10 according to FIG. 77. FIG. 78 shows the arrangement of a large number of permanent magnet dipoles along the edge region of the active layer 7 in the X-Y plane. The layer stack S is here framed or enclosed by twelve permanent magnet dipoles NS in the area of the active layer 7, for example. Z represents the vertical Z-axis arranged in the center of the X-Y cross-sectional area, around which electrons can move along a spiral line in the direction of the Z-axis due to diffusion and the force effect of the magnetic fields of the permanent magnet dipoles NS. The magnetic fields of the permanent magnet dipoles NS run from the respective north pole N to the south pole S, with the magnetic fields in the region of the south poles S acting into the edge region of the X-Y cross-sectional area of the active layer 7 of the layer stack S. Accordingly, a magnetizing element M is created here by means of the permanent magnetic dipoles described above.

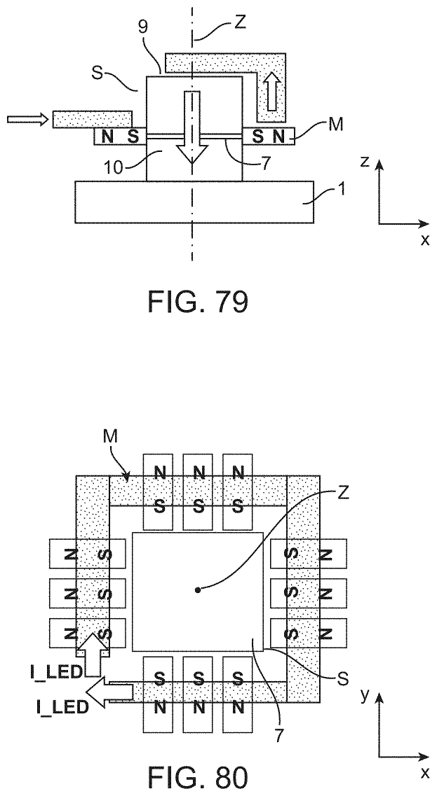

FIG. 79 shows a longitudinal section along an X-Z plane of a third embodiment of an optoelectronic component 10 according to the invention. In contrast to the second embodiment, electromagnetic dipoles are used here instead of permanent magnet dipoles, whereby their current flow is provided in particular by means of the current flow through the optoelectronic component 10. The first contact 9 is designed here as an anode. The technical current flow runs at the level of the active layer 7 into the electromagnets and flows around the layer stack S in order to flow then antiparallel to the current through the optoelectronic component 10 or through the exemplary μ-LED along the Z-axis to the anode. In this way, the concept of an “electron lens” according to the first embodiment can be combined with the magnetic effect in the active layer 7 according to the second embodiment. Manganese can be used as an example of a magnetic material, which is magnetized by means of a current flow.

FIG. 80 shows a cross-section along an X-Y plane of the third embodiment of the optoelectronic device 10 according to the invention. The electromagnetic dipoles SN are arranged along the X-Y plane around the layer stack S along the Z-axis at the level of the active layer 7 of the optoelectronic device 10, which may be a μ-LED chip LED. Twelve electromagnets are also proposed here. The electric current is fed in at the bottom left of FIG. 80, in particular the current that also flows through the optoelectronic component 10. This current I_{LED} can also be fed in FIG. 80 bottom left after at least one circulation of the layer stack S and at least one circulation of the electromagnet dipoles NS or alternatively one circulation of magnetic, especially ferromagnetic, material, to the anode or the first contact 9.

FIG. 79 and FIG. 80 show the magnetizing element M in the region of an active layer 7, with magnetic field lines running towards one pole, in this case the south pole, of a magnetic dipole being provided in its edge region. The effect of the magnetic fields on charge carriers here is similar to that of the second embodiment according to FIG. 77 and FIG. 78. The magnetizing element M provides magnetic field lines by means of which the moving charge carriers, in particular electrons, are kept away from edge regions of X-Y cross-sectional areas of the layer stack.

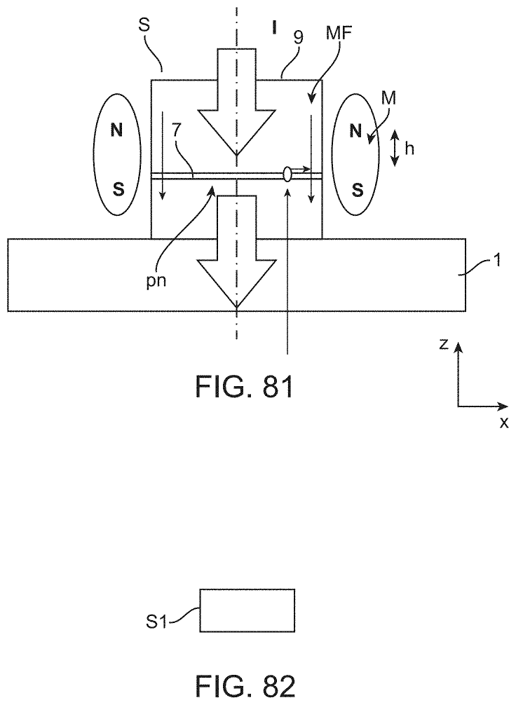

FIG. 81 shows a longitudinal section along an X-Z plane of a fourth embodiment of an optoelectronic device of the invention 10. The magnetization element M provides magnetic field lines by which the moving charge carriers are kept away from edge areas of X-Y cross-sectional surfaces of the layer stack S. The magnetizing element M is arranged in the Z-direction at the level of an active layer 7. The magnetic field lines MF are provided in the edge region of the active layer 7 running along the Z-axis. The position of the magnetizing element M can be varied in height along the Z-axis in order to define and generate the forces on the charge carriers, in particular electrons, specifically within the quantum well of the active layer 7. For example, the magnetizing element M may have been displaced against the main direction of motion of the charge carriers in a region in front of the active layer 7.

The magnetizing element M is created as a magnetic material, especially manganese, surrounding the layer stack S along an X-Y plane in the region of an active layer 7. The magnetic material is deposited on a lateral surface of the layer stack S and may have been magnetized by an external magnetic field. A deposition of the magnetic material can be carried out, for example, by MOVPE (metal organic gas phase epitaxy), MBE (molecular beam epitaxy) or similar methods.

The course of the generated magnetic fields MF causes the preferred direction of movement of an electron along a Y-axis to run in particular out of the drawing plane or the X-Z plane. Thus, a random movement of an electron without the respective magnetic field MF due to diffusion to the edge of the active layer 7 of the layer stack S is deflected into a lateral direction of movement by the targeted force of the magnetic field MF. This results in a preferential direction of random diffusion to the opposite other edge of the active layer 7 of the layer stack S, where the electron is diverted away from the edge there again, since the force there then acts again in a different lateral direction. In this way, an electron in the active layer 7 can be deflected in particular along a spiral line in the direction of the Z-axis, especially if magnetic material along the edge region of the active layer 7 frames or circumferences the active layer 7 in the X-Y plane. In this case, a layer stack S can be created as a cuboid or alternatively as a cylinder, for example. In principle, alternative geometric shapes of the layer stack S such as cones, truncated cones or pyramids are also possible. According to this embodiment, the first contact 9 provides an anode. The magnetic material acts as a dipole, with magnetic field lines running from an upper north pole along the Z-axis towards a lower south pole along the layer stack S. The magnetic field lines MF penetrate the edge region of the layer stack S and the active layer 7, which is created as a pn junction region.

FIG. 82 shows an example of a proposed method. In the method, a main direction of movement of charge carriers along an axis runs perpendicularly through the active layer of a μ-LED. Diffusion of carriers to the edge of the active layer is counteracted by a magnetic field, which keeps the carriers away from edge areas of X-Y cross-sectional surfaces of the active layer.

Among other aspects, the crosstalk of light into adjacent pixels is also important. Sometimes light is emitted from the side of the μ-LED, so that crosstalk reduces the contrast of a μ-display. Likewise, light emitted or radiated from the side often cannot leave the structure due to refractive index jumps. In addition, many applications require a Lambertian radiation characteristic of the display so that the display appears equally bright when viewed from all sides. Therefore, it is suggested to improve the radiation pattern by adding the active layer or the μ-LED surrounding reflective layers or mirrors can be reached. In other words, μ-LED structures can be provided with a circumferential mirror to improve the radiation characteristics.

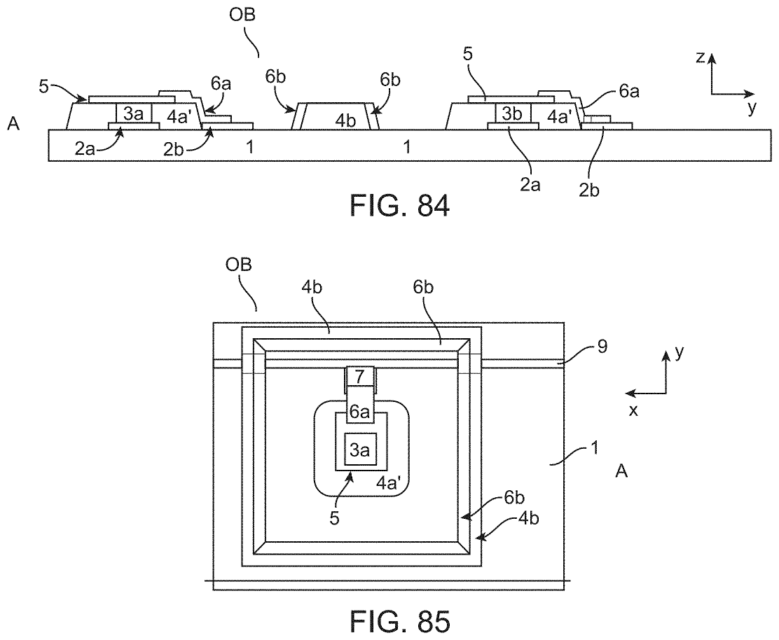

FIG. 84 shows a first embodiment of a proposed array in a Y-Z cross section. This can, for example, be produced using the processes described in this application. The μ-LEDs which are disclosed in this application may be used instead. In a Y-Z cross section, two electrically contacted μ-LEDs 3a and 3b are manufactured on a substrate 1, whereby a μ-reflector structure 4b is formed on the substrate 1 in a central area between the two processed μ-LEDs 3a and 3b. The edge angle of the μ-reflector structure 4b is adapted to a required optical output. For example, the edge angle can depend on the distance between the μ-LED and the μ-reflector structure 4b. The two electrically contacted μ-LEDs 3b together with the central coated μ-reflector structure 4b each form an optoelectronic component OB. In contrast to μ-LED 3a, p-LED 3b can emit light of other wavelengths. Reference mark 4a′ denotes an enclosure. It goes without saying that further μ-LED components can also be arranged in this embodiment, for example three, so that they then form the subpixels of a pixel of a μ-display.

During the manufacturing process, the flanks of the μ-reflector structure 4b have been coated with a second metal mirror layer 6b together with the first metal mirror layers 6a of the μ-LEDs, resulting in the shown structure.

The μ-reflector structure 4b, was generated from a planarization layer 4. The component also comprises the first metal mirror layer 6a, which as respective metal bridges lead from a second contact area 2b to a contact layer 5 of a second contact of the μ-LEDs. The second metal mirror layers 6b only cover the edges of the μ-reflector structure 4b. In addition, an area close to the substrate 1 can be omitted in the second metal mirror layers 6b to avoid short circuits with conductor paths on the substrate 1. Substrate 1 can also include electrical structures for driving the μ-LEDs, as described here in this application. If substrate is made of or includes Si or another material that is generally not compatible with the μ-LEDs, matching layers are also provided. This means that the μ-LEDs either have been directly generated on carrier 1 or have been transferred to it. The transfer processes and anchor structures shown here, for example, would be suitable for this.

FIG. 85 shows a first embodiment of a proposed optoelectronic device OB as a top view of an X-Y plane. This top view can represent the left optoelectronic device OB according to FIG. 84. The optoelectronic device is a subpixel and together with others it forms one pixel each. The latter are arranged with further pixels in several rows and columns. These thus form an array or μ-display.

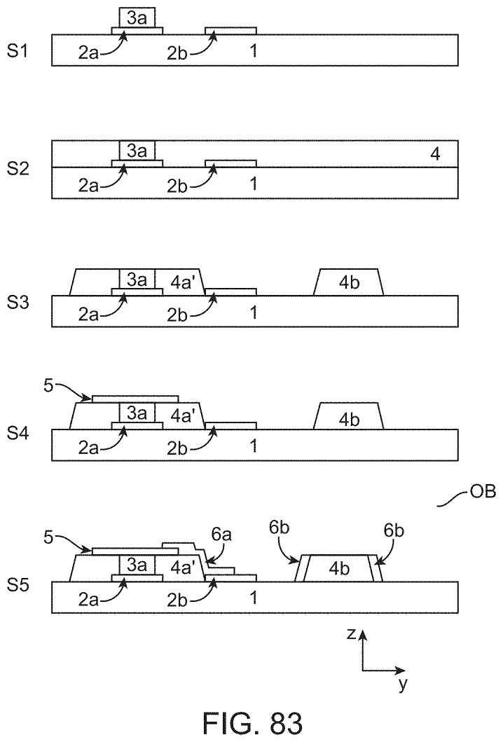

Each pixel comprises identically constructed μ-LEDs, which can be electrically connected to control them individually. According to FIG. 83 and FIG. 84, an optoelectronic device OB with second metal mirror layers 6b coated μ-reflector structure 4b surrounding a μ-LED. The μ-LED is arranged centrally for this purpose. Other geometric shapes such as rectangles, circles or triangles or polygons are also possible.

The edge of the μ-reflector structure 4b facing the μ-LED 3a is here covered by a second metal mirror layer 6b. In the plan view, a border 4a′ appears along the X-Y plane around the μ-LED 3a. Like the μ-reflector structure 4b, this border 4a′ was formed from the material of a planarization layer 4. Starting from a contact layer 5, a first metal mirror layer 6a, in particular in the form of a strip, extends to a second contact region 2b formed on a substrate 1, which may be covered by a coating 7 for sealing or encapsulation. As an example, an electrical conductor track 9 is shown to which the second contact area 2b can be electrically connected. The metal mirror layers 6a and 6b can have the same material or stack of layers.

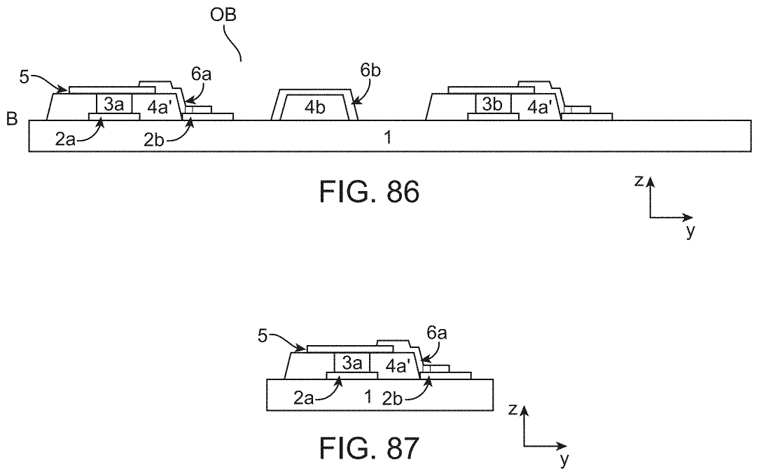

FIG. 86 shows a second embodiment of a proposed array in a cross-section of a Y-Z plane. In contrast to FIG. 84, here a μ-reflector structure 4b is covered with a second metal mirror layer 6b along its entire originally free surface. This means that not only the flanks, but also the main surface facing away from substrate 1, are covered by a continuous second metal mirror layer 6b. The μ-LEDs in FIG. 86 are constructed in the same way as in FIG. 84.

FIG. 87 shows again the essential aspects of the μ-LED in a cross-section along the Y-Z plane. On one side of a substrate 1 extending along an X-Y plane, a first contact 2a is connected to a semiconductor layer 3a of the μ-LED. The active zone is also located in layer 3a. A second contact is formed by the transparent layer 5, which is electrically connected to the first metal mirror layer 6a. Along the X-Y plane, around the body 3a, mechanically contacting it, the electrically insulating enclosure 4a′ is formed, along which the contact layer 5 and the first metal mirror layer 6a, in particular in the form of strips, run.

Substrate 1 can itself be a semiconductor and contain electrical structures for control. Alternatively, it can also be produced as a passive matrix or active matrix backplane and contain glass, a polyimide or PCBs (Printed Circuit Boards). The first contact area 2a for the contact near the substrate can contain Mo, Cr, Al, ITO, Au, Ag, Cu and alloys of these. The second contact area 2b for the second contact of the μ-LED 3a facing away from the substrate 1 can also comprise Mo, Cr, Al, ITO, Au, Ag, Cu and alloys thereof.

The μ-LEDs shown here are either identical or realized with different material systems, so that they emit different colors during operation. For example, red, green and blue (RGB), red, green, blue and white (RGBW) can be arranged on substrate 1. By using converter materials, the same light emitting diodes can be used, which nevertheless produce different light. Reference mark 4a′ denotes the remainder of a planarization layer 4 to provide a surround 4a′ to which a contact layer 5 can be applied for a top contact. The enclosure 4a′ can also optionally passivate mesa edges of the semiconductor layers of body 3a, for example by means of spin-on dielectrics or by means of a photoresist.

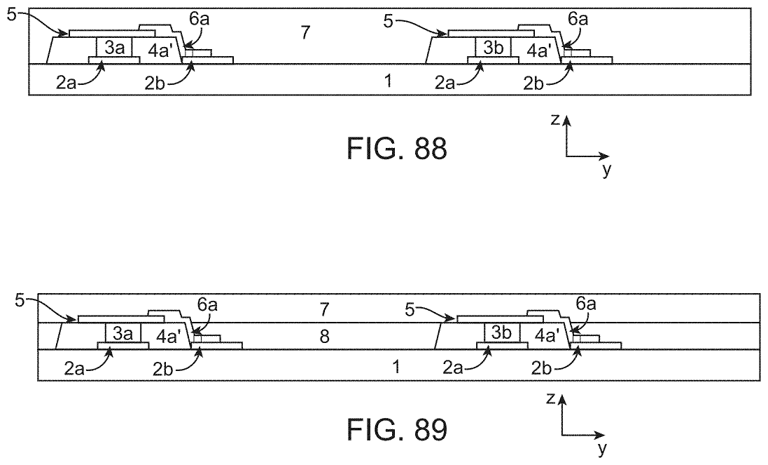

FIG. 88 shows a third embodiment of a proposed array in cross-section along a Y-Z plane. In contrast to the first embodiment shown in FIG. 84 and the second embodiment shown in FIG. 86, no μ-reflector structures 4b are formed here. On the other hand, a coating 7 is formed for sealing/encapsulation of the contacted μ-LEDs 3a, 3b and/or for optical out-coupling. The element is structured here (not shown) and has a photonic crystal structure from the top side, so that the radiation characteristic is improved. Layer 7 is electrically insulated from the other structures. The coating 7 can contain scattering particles or converter materials. It is usually applied after the μ-LEDS has been manufactured and then planarized.

FIG. 89 shows a fourth embodiment of a proposed array in cross-section along a Y-Z plane. In addition to this, a black encapsulation 8 is formed between the μ-LEDs 3a, 3b under a coating 7, which was applied to seal/encapsulate the contacted light-emitting body 3a, 3b and/or for optical output. No coated μ-reflector structures 4b are shown here. These μ-reflector structures 4b may be formed on other areas of the array not shown here.

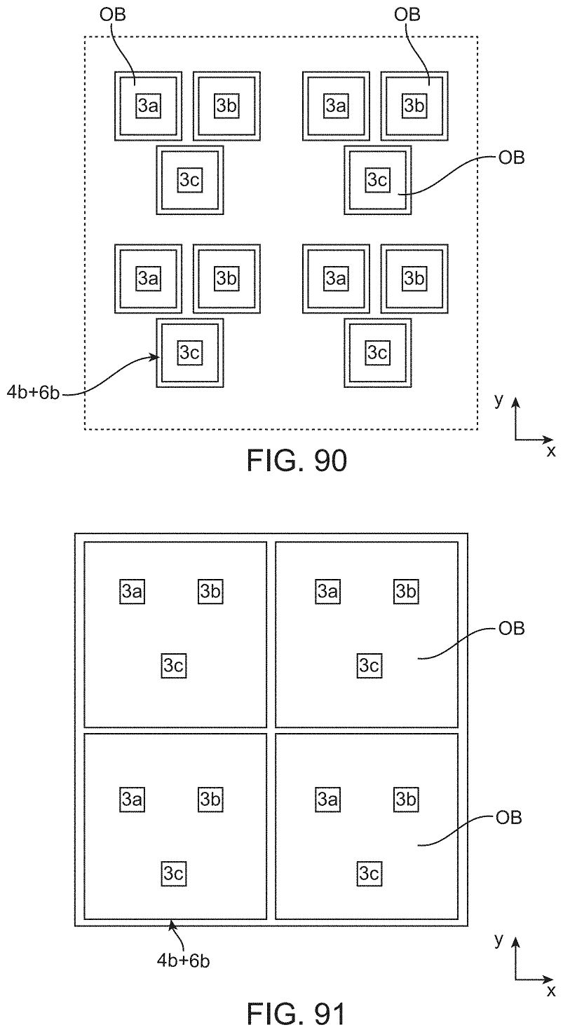

FIG. 90 shows an example of an array in a top view with a plurality of such μ-LEDs, each forming 4 pixels. This embodiment concerns in particular the shape and arrangement of the μ-reflector structures 4b. According to FIG. 90, each subpixel is framed individually by a μ-LED with a μ-reflector structure 4b having a second metal mirror coating 6b. The distance between μ-reflector structure 4b and the respective μ-LED in this example is 5 times the chip edge length. However, other distances are also possible; in particular, the subpixel can be surrounded by the μ-reflector structure with a distance of only one μm.

Each pixel comprises three subpixels 3a, 3b and 3c for the emission of red, blue and green light. The pixels have the same shape and are arranged in columns and rows. They thus form a μ-display or a module of such a display. In order to avoid visible artefacts during light emission, which can occur due to periodic subpixel arrangement, the subpixels 3a, 3b and 3c can be arranged differently or permuted contrary to the representation shown here. In addition, the shape of the μ-reflector structures 4b is not based on square footprints.

FIG. 91 shows a sixth embodiment of a proposed array in a top view. Here, the μ-reflector structures 4b are configured to enclose an entire pixel, for example with the μ-LEDs 3a, 3b, 3c.

Because of the now different distance, the flank angles of the coated μ-reflector structures 4b are different compared to the embodiment of FIG. 90. Depending on requirements, the flank angle of the centrally arranged μ-reflector structures may also be different from the surrounding frame. It should be noted, however, that in both versions, considerably more such structures are combined and formed as pixels.

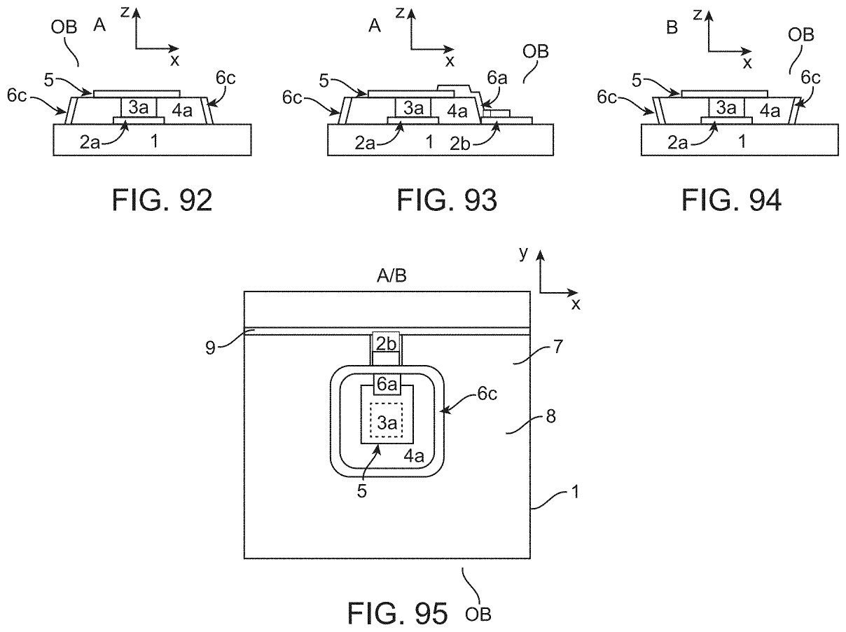

FIGS. 92 to 93 show further embodiments of an optoelectronic component OB, how they can be configured and combined as subpixels.

In FIG. 92 the μ-LED is formed with an additional metal mirror layer 6c on the side flank of the bezel 4a. The side flank forms a truncated pyramid and tapers towards the top. The metal mirror layer can also serve as a contact for contact 5. FIG. 93 shows the second embodiment already described. FIG. 94 shows a third embodiment. In this example, the flanks of the reflector structure 4a are also bevelled, but in such a way that the circumference increases with increasing distance from carrier 1. The shape of the flanks and their steepness adjust the extraction of light from the body.

FIG. 95 shows an advanced embodiment based on the third embodiment according to FIG. 94 in a top view. In this example, the second metal mirror layer 6c applied to the reflector structure 4a are surrounded and framed by a black layer 8, in particular a black casting. This may, for example, extend in particular near the substrate 1 at the foot of a reflector structure 4a. In addition, a coating 7 is deposited on the surface for sealing and optical out-coupling. The edge of the μ-reflector structure 4a is covered by a second metal mirror layer 6c. Starting from a contact layer 5, a first metal mirror layer 6a extends in particular in the form of a strip to a second contact region 2b formed on a substrate 1, which may be covered by an optically transparent coating 7 for sealing or encapsulation. As an example, an electrical conductor track 9 is shown to which the second contact area 2b is electrically connected. The metal mirror layers 6a and 6c can have the same material or layer stack.

FIG. 83 shows an embodiment of a proposed process for manufacturing an optoelectronic device OB and a μ-LED. The steps shown can be applied to a large number of individual μ-LEDS so that they can be manufactured together in larger numbers.

In a first step S1, a first contact area 2a and a second contact area 2b is made on one side of a substrate or carrier. The carrier may in turn have circuits or other internal structures. The contact areas can be created by, among other things, patterning a photoresist layer and removing the areas that are not exposed afterwards, so that parts of the substrate are exposed. The contact areas 2a and 2b are then deposited as a metallic layer. A body 3a is also deposited on one of the contact areas. The body 3a comprises two oppositely doped semiconductor layers with an active layer for generating light arranged in between. In some aspects, this body can be manufactured separately and then be transferred onto this area by means of a transfer process. In another aspect, the layers are applied to the surface of substrate 1, structured and thus the bodies are formed.

In a second step S2, a planarization layer 4 is applied to form a μ-reflector structure 4b which completely surrounds the body 3. If necessary, the layer 4 is planarized to be planar with the surface of body 3a. The layer 4 is then structured to create a surround 4′ around the body 3. This border essentially extends to the second contact area 2b. In addition, a more distant border 4b is created. The side flanks of the border are bevelled. The slope of the edges can be used to control light extraction or the direction of reflection. In step S4, a contact surface 5 is applied to the surface of the body 3a and adjacent areas. This comprises a transparent but conductive material

Finally, in a fifth step S5, an electrically connecting metal mirror layer 6a is applied to the contact layer 5. The metal mirror layer extends over the edging 4a′ to the second contact area 2b and contacts it. In addition, a second metal mirror layer 6b is simultaneously applied to the side flanks of the preflector structure 4b. Through structuring and processing, the surface of the surrounding ridge 4 remains free of the metal. In other embodiments, this can also be done differently in order to obtain an electrical connection between the metal mirror layer on both side flanks.

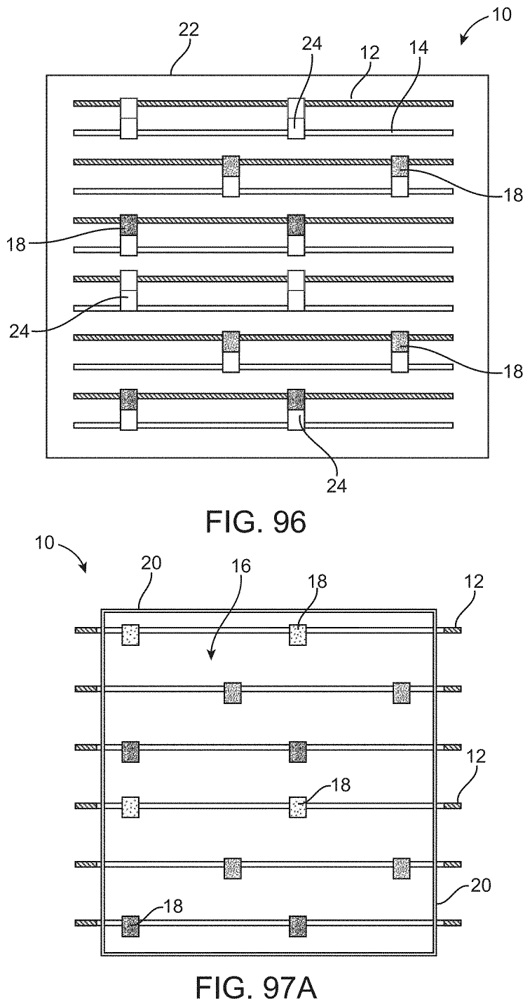

FIG. 96 shows a section of a μ-display with several μ-LEDs and a transparent contacting layer formed as a common cathode in top view.

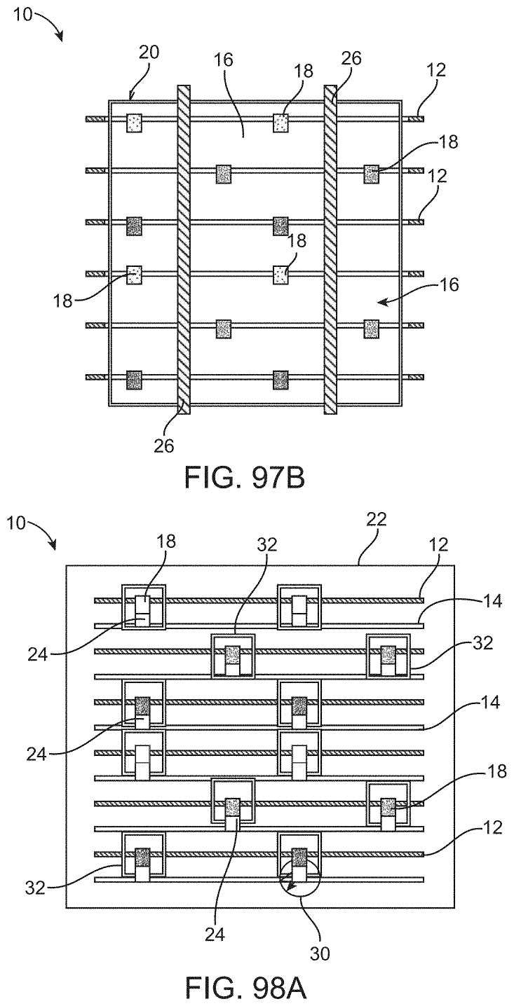

In FIG. 97A, the large number of individual contacts is combined in a common contact layer 16. This contacting layer 16 is flat, at least partially electrically conductive and, as a common cathode, contacts the top sides and the electrical contacts 20 of the μ-LEDs 18 on their top side. Due to the partially transparent embodiment of the contacting layer 16, light emitted by the μ-LED 18 can at least partially pass through the contacting layer 16. Accordingly, in one aspect an arrangement or contacting of vertical μ-LEDs with a transparent and electrical cover layer is provided.

It can be seen that due to the possibility of contacting the μ-LEDs 18 by means of contact 20 on their respective top side, the previously necessary conductor structures 14 for the cathode can be omitted and thus more space is available. In the example shown here, a connecting conductor 20 for contacting layer 16 is provided for the electrical contacting of contacting layer 16. With the common contacting layer 16, the processing of individual single contacts for each individual μ-LED 18 can be omitted and instead be realized with a common contacting layer 16, which is easier to manufacture.

FIG. 97B shows a variant of the optical pixel element 10, which has been further developed according to the invention. The basic structure corresponds to the pixel element according to FIG. 97A, whereby a common contact layer 16 together with a connecting conductor 20 forms the common cathode for the μ-LEDs 18 below. In the example shown here, two parallel conductor tracks 26 are provided at the contacting layer 16.

These conductive tracks 26 have a higher electrical conductivity than the material of the contacting layer 16, so that a total resistance of the total arrangement of contacting layer 16 and conductive track 26 is reduced compared to contacting layer 16. In other words, the conductor tracks 26 bridge areas of the electrically less conductive contacting layer 16. In principle, the conductor tracks 26 can be configured in a wide variety of shapes, for example straight, curved, meandering and similar, and also vary in width and thickness.

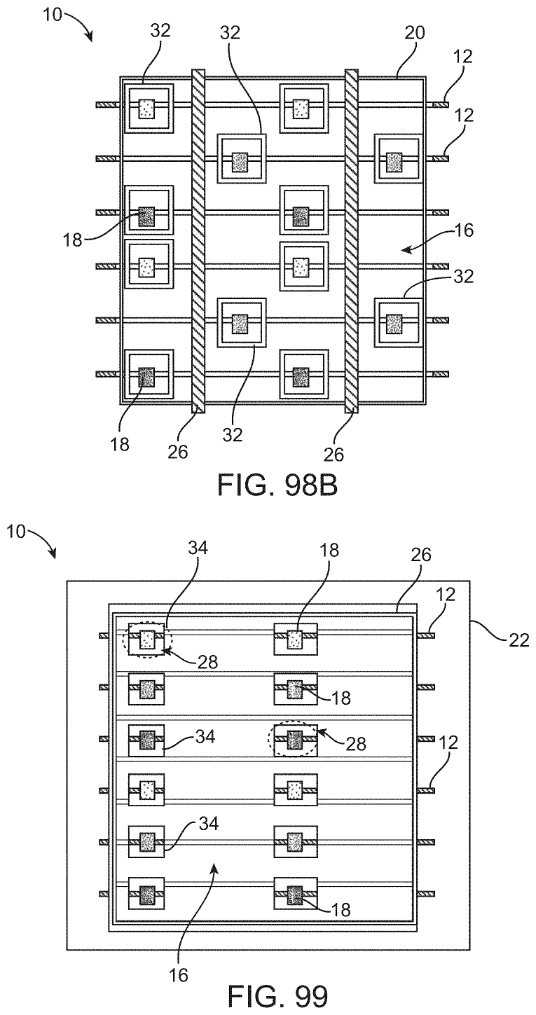

Trace 26 can also be configured as a combination of a number of individual thin conductors analogueous to the stranded wire. It can be seen that the conductors 26 are arranged outside a primary radiation area 28 (see FIG. 98A and FIG. 98B), so that they do not shadow or hinder the emission of light from pixel element 10 or μ-LEDs 18.

FIG. 98A shows a structure of a pixel element 10 in which conductor structures 12 for the anode are arranged parallel to conductor structures 14 for the cathode on a carrier substrate 22. In contrast to the construction of the well-known pixel element 10 in FIG. 96 with horizontal μ-LEDs (whose contacts on the underside directly contact the leads 14 and 12), here the upper contact, i.e. the contact of the respective μ-LED 18 facing away from the carrier substrate, is connected to the lead structure 14 of the cathode via a partially transparent contact. In addition, a beam-shaping element 32 is provided here for each μ-LED 18. This beam-shaping element 32 can also be understood as a so-called decoupling structure. In this respect, this representation is similar to the embodiments in FIG. 90 or 95 and others. The contacting can also be realized in a similar way.

Due to the geometric design of the beam-shaping element, for example as a structure surrounding the μ-LED 18, a certain size of opening is necessary for a desirable shape of the emitted light. This size can in turn cause undesired spatial overlaps between the conductor structure 14 of the cathode and the beam-shaping element 32 in an overlap area 30. This is particularly possible because both conductor structures 12 for the anode and conductor structures 14 for the cathode must be simultaneously provided on the carrier substrate 22.

It should be mentioned that the conductor structures 12 for the anode and conductor structures 14 for the cathode could also be assigned in reverse order. This means that the electrical contact 20 of the μ-LEDs 18 on the upper side can be configured as cathode or anode. Accordingly, the conductor structures 12, 14 must be configured as anode conductor structure or as cathode conductor structure.

FIG. 98B shows the basic structure of a pixel element 10 from FIG. 97B with two parallel tracks 26. The vertical μ-LEDs contact the contact tracks 12 and the conductive transparent layer (not shown here). By omitting the conductive structures 14, more space is available for beam forming elements 32, so that no undesired overlapping or electrical contacting occurs.

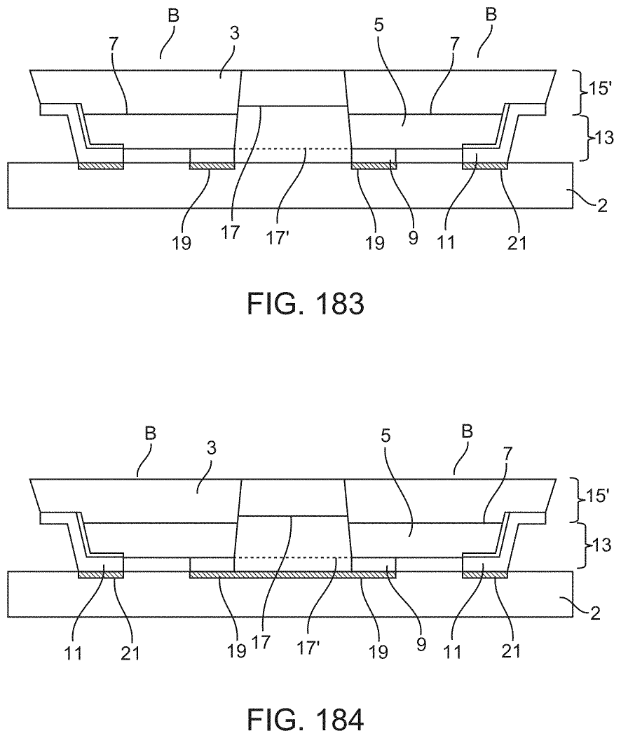

FIG. 99 shows another version of the optical pixel element 10. While the basic design of the pixel element with μ-LEDs 18, conductor structures 12 for the anode and a carrier substrate 22 corresponds to the example shown in FIG. 97A, here conductor track 26 is configured as a continuous surface over a large number of μ-LEDs 18. In the area of the respective primary beam areas 28, recesses 34 are provided for beam-shaping. In other words, these recesses 34 are intended to pass the light emitted by the respective μ-LED 18. In this way, separate beam-shaping elements 32 (see, for example, FIG. 183) can be omitted, since this function can now be performed by the recesses 34.

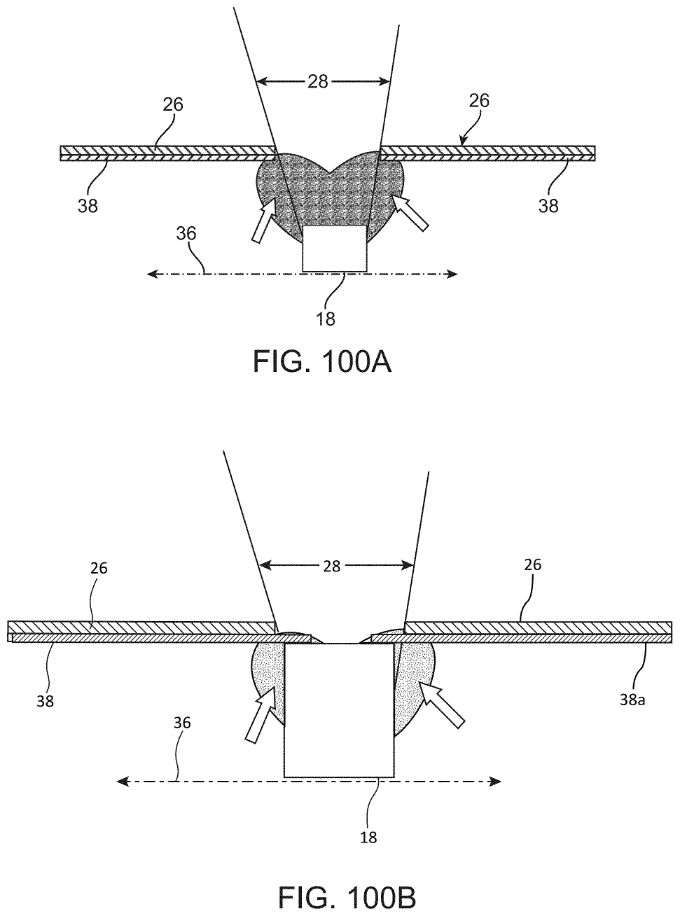

In FIG. 100A the aspect of beam-shaping for light emitted by a μ-LED 18 is explained in more detail. A vertical sectional view shows a μ-LED 18 arranged on a carrier substrate 22 (not shown). This emits light transverse to a carrier substrate plane 36 in a direction away from the carrier substrate 22. In the example shown here, the μ-LED has a heart-shaped propagation characteristic. However, it is desirable that the light is only emitted in a primary emission range 28 of the μ-LED 18. One or more conductor paths 26 are used here to shade unwanted light components. These can be reflective or absorptive on the lower side. In another aspect, the conductor path comprises a light-absorbing layer 38 on its underside. This layer can prevent or reduce further unwanted reflections or crosstalk between adjacent μ-LEDs 18.

An alternative embodiment is shown in FIG. 100B. In this context, it is intended that a transparent conductive layer 38a as shown in FIG. 100B partially overlaps the μ-LED and thus securely connects the upper contact. At the same time a beam-shaping is achieved by the reflective conductive layer.

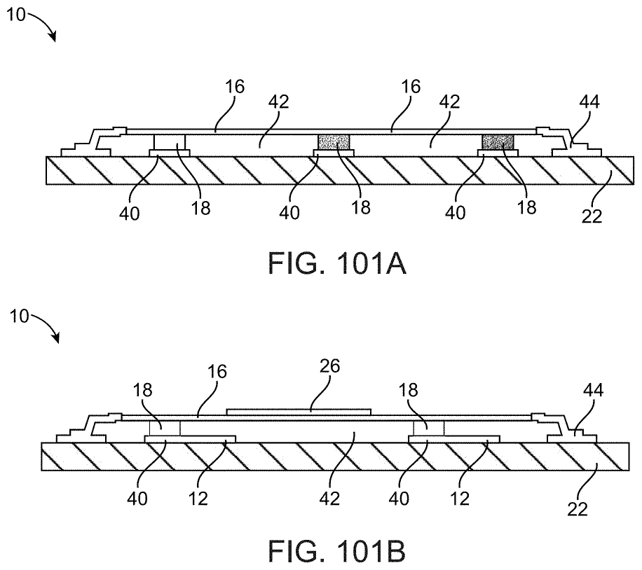

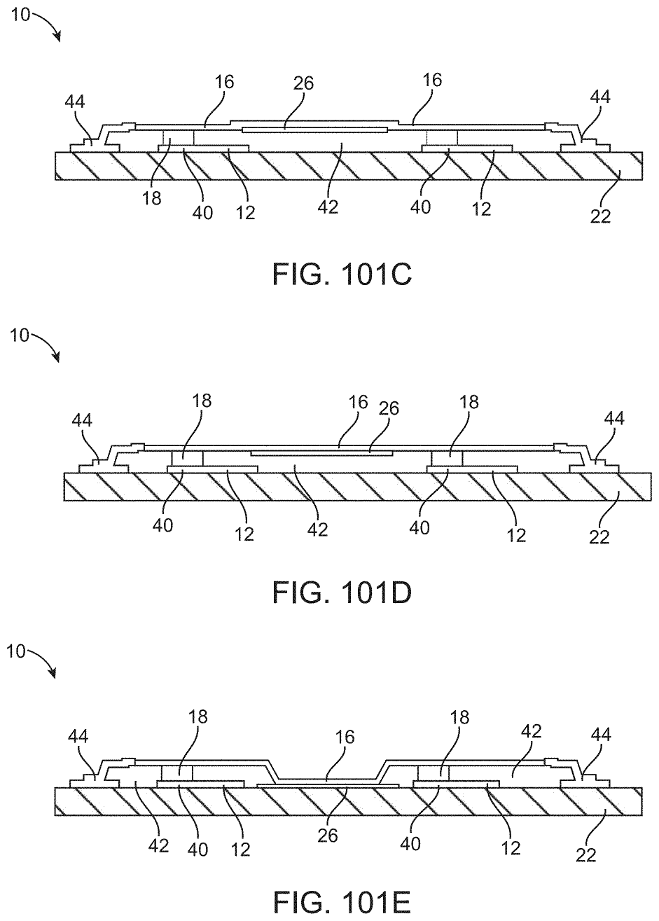

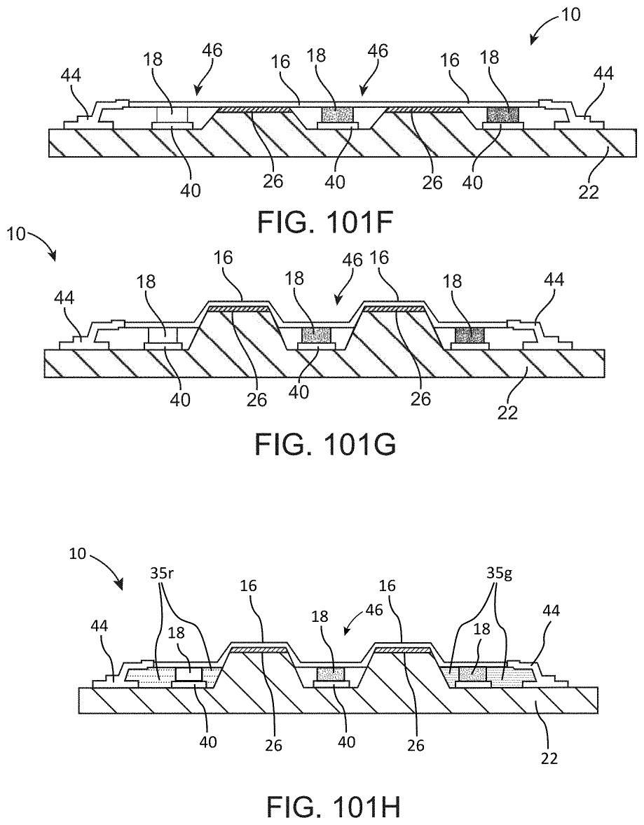

FIG. 101A shows a vertical section through a pixel element 10 in longitudinal direction. Three μ-LEDs 18 can be seen, which are connected to a carrier substrate and the corresponding conductor structure 12 for the anode via anode contacts 40. A planarization layer 42 has a height of 2-4 μm, for example. Due to the overall planar structure, the height of the μ-LEDs including anode contact 40 can also be in this size range. A flat electrically at least partially conductive and at least partially light-transparent contact layer 16 is provided on one top side.

Since contact layer 16 represents a common cathode connection or anode connection, it must be electrically connected to the external connection elements accordingly. For this purpose, a connecting element 44 is to create an electrical connection between the contacting layer 16 and a connecting element of the carrier substrate 22. In this example, the element is arranged at the edge of the pixel element 10. A connection element of the carrier substrate 22 can be, for example, a suitable conductive surface or also conductor structures, which allow, for example, the connection of external components or supply lines for the pixel element 10.

FIG. 101B shows pixel element 10 of FIG. 101A, with the view rotated by 90°. In addition, a trace 26 can be seen here, which is located in a gap between two emitter chips 18, so that it is outside a primary emission area 28 (see for example FIG. 100A) of the respective μ-LED 18. Here and in the following FIGS. 101C to 101G, connecting elements 44 are provided at the edge of pixel element 10.

FIG. 101C and FIG. 101D show examples of how the conductor track 26 can be arranged at the contact layer 16. In FIG. 101C, track 26 is partly embedded in planarization layer 42 and partly on the underside of contact layer 16. Here the contacting layer 16 is processed with a stepped elevation above the conductor track 26.

The embodiment of the pixel element 10 in FIG. 101D basically corresponds to the embodiment of the pixel element 10 in FIG. 101C, whereby here the contacting layer 16 is configured to be completely flat and the conductor track 26 is provided on a lower side of the contacting layer 16. In this case, the conductor track 26 is embedded in an area of the planarization layer 42.

In FIG. 101E the planarization layer 42 is interrupted in an area between two adjacent emitter chips 18. This provides the option of placing the trace 26 directly on the carrier substrate 22. The contacting layer 16 is therefore intended as the layer above. This design variant can, for example, make it easier to provide the conductor path 26 already during the production of the carrier substrate 22.

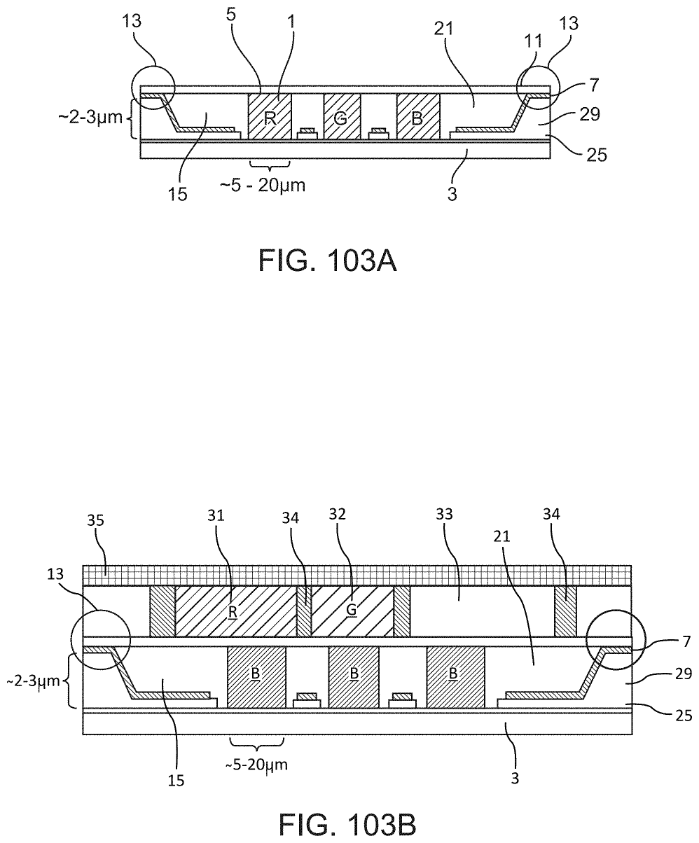

FIG. 101F and FIG. 101G each show an example for the arrangement of μ-LEDs 18 in cavities 46 of the pixel element 10 or the carrier substrate 22. Instead of a cavity, an elevation can also be provided. The latter is similar to the shape in FIGS. 103A to 105.

FIG. 101H represents a complementary version of a pixel to the previous figure, in which a remaining space within the cavity is filled with a converter material 35r and 35 each. The converter material extends to the ceiling electrode, but can also be provided above the ceiling electrode to convert light radiating upwards. In this way, a planar surface can be created with the converter material. In one embodiment, the converter material is realized with quantum dots, which are filled into the cavity as powder or emulsion. Quantum dots can be formed in powder form, sometimes much smaller than some conventional inorganic dyes, making them suitable for μ-LEDs.

Optionally, tracks 26 can be provided in the elevations 48 between two cavities 46. The arrangement of the μ-LEDs 18 in cavities 46 can have particular advantages with regard to the radiation characteristics, since light emitted in a lateral direction can be reflected on the side surfaces of the elevations 48 of the cavities.

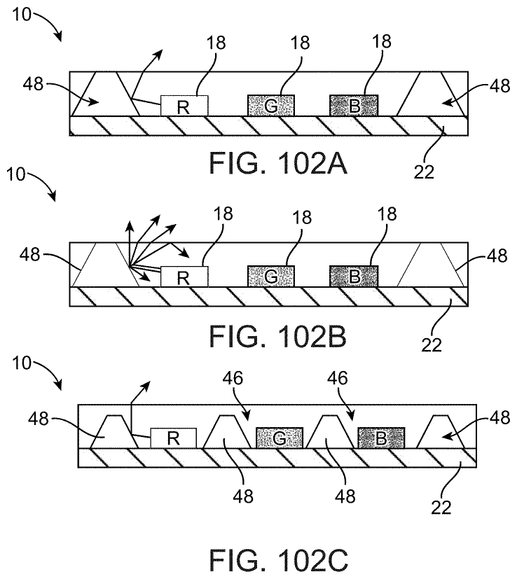

In FIG. 102A, the side surface of the elevation 48 is smooth, so that light emerging from the side of a μ-LED 18, for example, is reflected once and is deflected advantageously in the direction away from the carrier substrate 22. In FIG. 102B, a material of the side surface of the elevation 48 is configured to cause multiple reflections of the incident light in different directions. In FIGS. 102A and 102B, the bumps 48 are placed at the edge of a pixel element 10 or at the edge of an array of several μ-LEDs 18.

FIG. 102C shows an example in which elevations 48 are provided between two adjacent μ-LEDs 18 each. By optically separating the respective μ-LED 18 within a pixel element 10 by the shading effect of the elevation 48, crosstalk, for example, can be achieved, thus improving the contrast of a display. These versions of FIG. 101 are also similar to the examples of FIGS. 103A to 105, so the various aspects of the designs shown there can be combined with one another.

The aspects presented above for a reflecting mirror can also be applied to other designs of μ-LED realizations, for example to the vertical μ-LEDs with circumferential structure.

FIG. 103A shows a version of a pixel cell with a common cover electrode and a circumferential structure, which on the one hand allows fast switching times by a suitable current conduction and on the other hand radiates the generated light in a main radiation direction by a mirror coating. The arrangement according to FIG. 103A shows three so-called μ-LED dies, whereby a first die provides 1 red light, a second die green light and a third die blue light. They thus form subpixels of a pixel cell. For simplicity, the individual dies are shown in series, but other arrangements are also possible, for example in a triangular shape. Furthermore, the dies are the same size. A single die 1, especially a cubic die 1, can have an edge length of about 3 to 70 μm, 5 to 30 μm and 5 to 20 μm respectively. The height of a die 1, for example, can preferably be between 0.5 μm-5 μm, 1-3 μm or approx. 2 to 3 μm. This is also due to the simplicity of the embodiment, as the size can also vary depending on the design. However, they should have the same height so that further process steps do not require additional measures. The μ-LED dies have a vertical design, i.e. they have their two contacts on different sides, as shown in the figure on the top and bottom side.

The μ-LED dies are arranged on a common substrate 3. For this purpose, the μ-LED dies are electrically connected with their first contact to a contact not shown here on or in the substrate. The substrate can be a semiconductor substrate or a backplane or similar. In the substrate are the leads, which lead to the contacts for the μ-LED dies. In addition to supply lines, power sources and/or control electronics can also be formed in the substrate. It is useful to have such current sources for each μ-LED die directly underneath it. This results in a certain amount of space. Accordingly, the circuits may only have a small size. Examples and concepts for this are disclosed in this application and can be provided in substrate 3. Part of the structures and supply lines are configured in TFT technology.

The pixel cell with its three μ-LED dies is embedded in a cavity or surrounded by a border. Such borders can also be seen in FIGS. 90 and 91.

On the left and right sides of FIG. 103A, 3 bumps 29 are formed on the substrate. Such protrusions 29, which provide a cavity or recesses, may be made of polyimide or other non-conductive material. They surround the dies on all sides and thus form the border of the pixel. The sidewalls are slightly bevelled and thus run at an angle to the normal of the surface. In addition to the linear course of the side surface shown here, they can also show a parabolic course.

In addition, an additional electrical insulation layer 25 is provided between the generated elevations 29 and the substrate 3 for better mechanical strength. A conductive reflective layer 7 is applied to the insulation layer or the elevation 29. This extends not only over the lateral surface of the elevation 29, but also along a region of the substrate surface and between the μ-LED dies. However, the reflective layer is spaced apart here so that a short circuit or unintentional contact with the tube chips is avoided. In addition, the mirror coating is also provided on an upper side of the elevation in area 13. Mirroring 7 is configured as a metal mirror, which can have Al, Ag and AgPdCu and the same in particular. Other materials can be metals or alloys of Al, Ag, Nd, Nb, La, Au, Cu, Pd, Pt, Mg, Mo, Cr, Ni, Os, Sn, Zn or alloys or combinations thereof.

The space 15 between the elevation or in the cavity and between the μ-LED die is now filled with a transparent, non-conductive material 21 and reaches up to the height of the contacts 5 of the μ-LED die. Material 21 forms an insulating layer. The insulation layer can be applied by spin-on glass or similar techniques. Depending on the requirements, the insulating material can then be removed up to the height of the contacts 5 and the reflective layer so that these are exposed and a planar surface is formed. Finally, a transparent, electrically conductive layer is created on the second contact 5 of the μ-LED dies and the insulating layer 21, which provides a cover electrode 11. The transparent layer can have ITO and/or IGZO and the like, for example. Other examples of cover electrode materials are transparent conductive oxides such as metal oxides, zinc oxide, tin oxide, cadmium oxide, indium doped tin oxide (ITO), aluminum doped tin oxide (AZO), Zn₂SnO₄, CdSnO₃, ZnSnO₃, In₄Sn₃O₁₂ or mixtures of different transparent conductive oxides.

The cover electrode 11 extends over the entire insulation layer 21 and overlaps with the reflective layer in the areas 13. The large-area direct contact with the underlying metal mirror coating 7 creates a good current coupling, so that the distance that the current must travel through the transparent conductive layer 11 is only short. This means that the generally greater surface resistance of the transparent conductive layer 11 does not have such a great effect. Due to the planar surface to which the cover electrode 11 is applied, the material can be easily sputtered on or applied by means of a “spin-on glass (SOG)” top contact process. This enables a planar coating with the ITO cover electrode 11, so that tear-off edges are avoided, for example during a so-called thermal shock test. However, it is useful in this production process that both the mirror coating 7 and the contacts 5 are exposed and are contacted directly by the material 11.

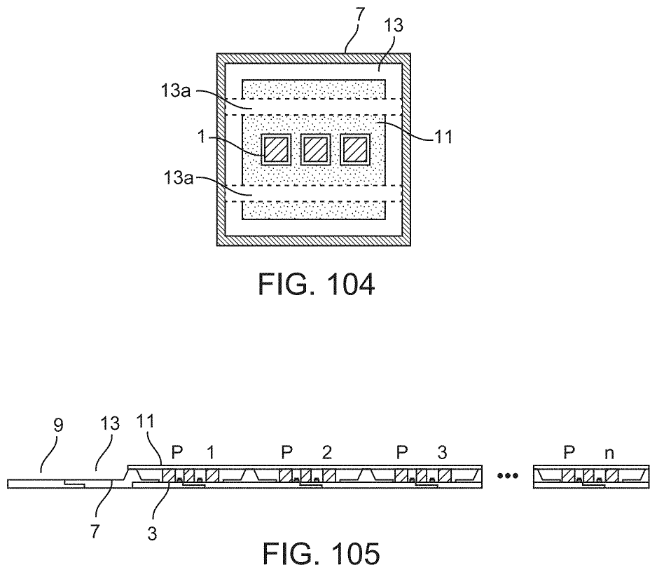

FIG. 104 shows a top view of the embodiment as shown in FIG. 103A. In the middle of the arrangement the three μ-LED are arranged in a row. These are contacted by means of a cover electrode 11, which is electrically contacted in an overlap area 13 with a mirror coating 7 or a metal mirror layer. The border through the elevation or cavity is substantially square. This results in a smaller distance between the two outer μ-LED chips and the elevation. In one embodiment, it may be more appropriate to form the border as a rectangle. This is indicated in FIG. 104 by the dashed areas 13a in which the elevation lies and in which the cover electrode is in contact with the mirror coating. This makes the distance between the μ-LED chips and the border more even.

FIG. 105 shows an arrangement of several pixels P1, P2, P3 . . . Pn arranged along a row. The pixels P are separated from each other by an elevation, so that optical crosstalk is at least reduced. In cross-section, three μ-LED dies 1 are formed for each pixel, which are designed to emit light of different wavelengths during operation. These are fixed and electrically contacted between a substrate 3 and a cover electrode 11. The direct electrical contact of the cover electrode 11 with the mirror coating 7 is formed according to the design shown in FIG. 103A.

The mirror coating 7 is electrically connected to the cover electrode 11 on each of the elevations separating the pixels. Outside the pixel cells and the row of pixels, the mirror coating is connected to a leftmost control contact 9 of the substrate 3. The control contact 9 forms a contact area at which further contacting can take place. In other examples, contact 9 is led into the substrate where further circuits and control elements are arranged. Due to the low surface resistance caused by the metallic mirror coating, the total voltage drop across the supply lines is reduced. With a suitably guided current flow, parasitic capacitances are reduced and switching times for driving the μ-LED dies can be effectively reduced. The pixel arrangement shown in FIG. 105 further minimizes optical scattering between pixels and thus so-called optical crosstalk.

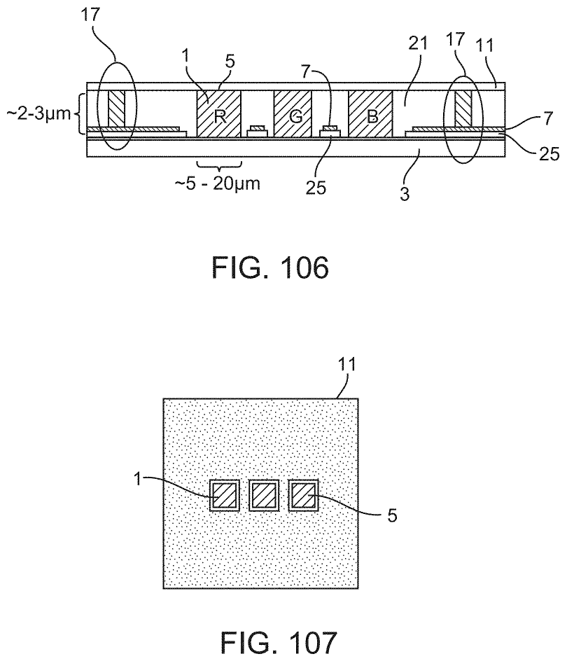

FIG. 106 shows a further embodiment of a proposed device. FIGS. 103A to 105, where the same reference signs show the same characteristics. In this embodiment, no elevation or cavity is provided on the substrate, i.e. the mirror coating and the supply line run substantially planar along the surface of substrate 3. Three μ-LED dies 1 are arranged on substrate 3 and electrically connected to contacts not shown. The mirror coating 7 surrounding the dies 1 is electrically separated from the substrate 3 by a transparent but electrically insulating layer 25. The μ-LED chips are surrounded by an insulating layer 21. The layer is transparent and extends in every direction over the substrate up to the height of the contacts 5 of the μ-LED dies. The upper contacts of the μ-LED dies 1 are electrically contacted by a cover electrode 11, which is configured as a transparent ITO cover contact and rests on the insulation layer. Furthermore, several conductive vias are created above the mirror coating 7, the mirror coating 7 is electrically contacted with the cover electrode 11. The vias are filled with a metal to keep the surface resistance low.

In some aspects, the vias are merely openings in the insulation layer. However, trenches or the like can also be provided in the insulation layer, which reach up to mirror coating layer 7. If these are formed at least partially circumferentially around the pixel and then filled with a reflective material, light guidance can be achieved in addition to good current injection. In this design, the height of the μ-LED dies plays a lesser role, provided they are of the same height, since they do not have to be adapted to a cavity or elevation.

FIG. 107 again shows the structure shown in FIG. 106 in plan view. The pixel is configured as a square so that the distance from the middle die to the edges of the pixel is approximately the same. Reference mark 5 indicates the electrical contacts 5 of the μ-LED dies 1 to the transparent cover electrode 11. Here too, a mirror coating 7 (not shown) may surround the area around the μ-LED dies.

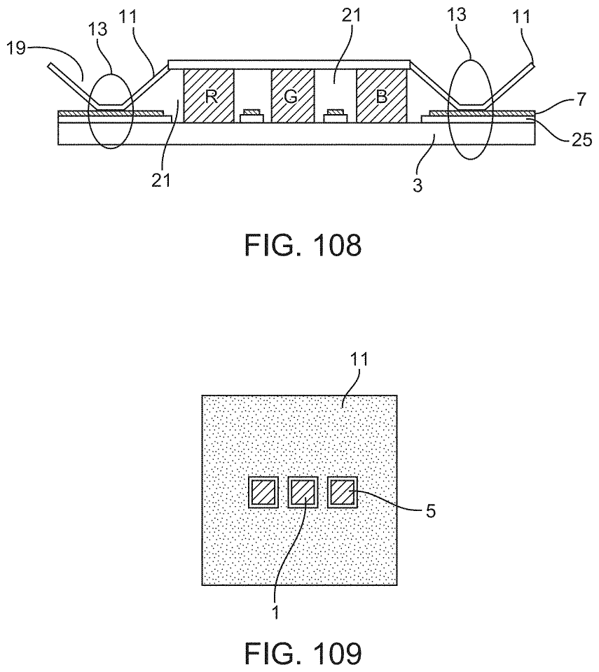

FIG. 108 shows another example of a proposed embodiment in cross-section. According to this example, the cover electrode 11 is configured as an ITO cover contact, which in turn has been applied planar over the contacts 5 of each μ-LED die. An insulation layer 21 surrounds each die. However, the insulation layer has been removed in the edge area of the pixel and has a sloping side edge. This creates an opening 19 that reaches up to the reflective layer 7 and exposes it in a larger, i.e. not only point-shaped, area. The larger this exposed area, the larger is the later contact area with the cover electrode 11.

In other words, the planar isolation layer is removed in the area between two pixels and above the reflective layer 7. This can be done by an etching process, for example with RIE. The created openings 19 have edges 23 with a flat opening angle. After opening, the cover electrode 11 is applied to the insulating layer and thus extends over the planar surface and the side surface of the insulating layer. Alternatively, a metal layer can be applied to the side surface, which contacts the cover electrode 11 at the upper edge of the insulation layer.

With a thicker insulation layer 21, the opening 19 with its side flank should be designed so that the upper angle is relatively flat, i.e. comparable to an inverted flat cone. The flat bevel angle prevents the ITO layer 11 from “tearing off” at the edge of the openings 19. The same applies to the angle between the side flank and the mirror coating layer 7.

The generated pixel element has such contacts and overlaps at several points, especially all around, so that the subpixel or pixel is also enclosed. In addition, further subsequent layer(s), for example a scattering layer, or clear lacquer layer with different refractive index can be provided in the openings, which in the embodiment, for example, lead to an improvement of the contrast, in which the lateral waveguide of light emitted from the chip side edges can be used for light extraction and does not propagate up to neighboring pixels.

FIG. 109 shows the embodiment according to FIG. 108 in top view. Three subpixels, each provided by a micro light-emitting diode die 1, have electrical contacts 5 on a side facing away from the substrate 3. These can be electrically coupled outside the pixel by means of a transparent cover electrode 11.

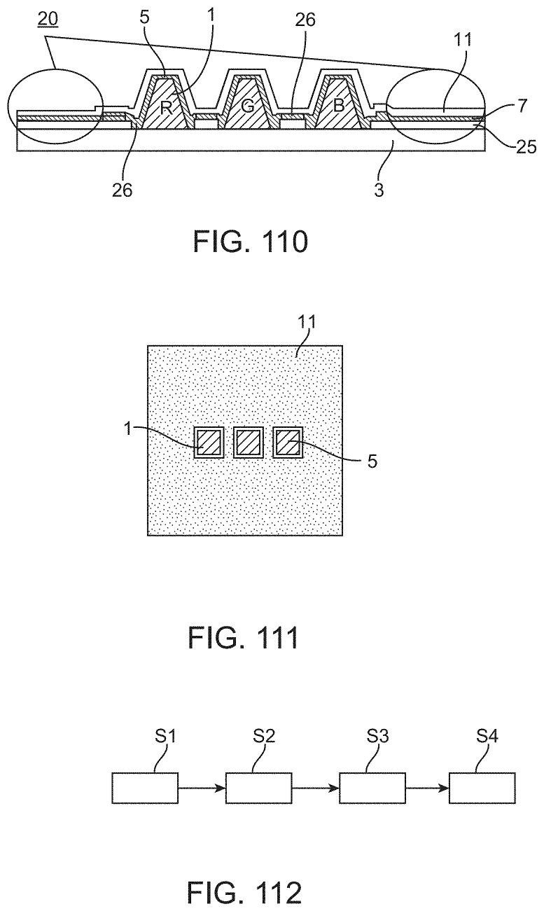

FIG. 110 shows another example of a device with three μ-LED dies 1 arranged in a row. Each of the μ-LED chips is designed as a truncated pyramid. Its base area decreases slightly with increasing height. Thus, the μ-LED dies have a slightly bevelled side edge.

The surface of the side edges of each of the μ-LED dies 1 is covered with a thin transparent and insulating layer 26. However, this does not extend to the upper second contact 5, so that it is exposed. The inorganic insulating layer 26 can be produced by chemical vapor deposition, for example. Alternatively, the layer 26 can also be produced with ALD-based (Atomic Layer Deposition) layers such as SiNx, SiOx, Al₂O₃, TiO₂, HfO₂, TaO₂ and ZrO₂. The inorganic layer can also consist of multiple layers, namely ALD-CVD-ALD or CVD-ALD or ALD-CVD. The ALD layer can also intrinsically consist of a multilayer stack (a so-called nanolaminate). Such an ALD nanolaminate would then consist of a multilayer layer stack of e.g. two different ALD layers and ALD materials, whereby, for example, the individual layers are typically only 3 nm-10 nm thick, according to AB-A-B-A or similar.

In the vicinity of the substrate 3, 25 mirror coatings 7 are applied to electrical insulation layers, which are also formed near the dies 1. In sufficient distance to the die chips, openings 20 are formed in the insulation layer 26 on the left and right side of the pixel. This exposes the mirror coating layer 7. Finally, a cover electrode made of the conductive transparent material is applied to the top side and the side edges. This also extends over the openings in the insulating layer 26, and is thus in contact with the metallic layer 7 over a large area. In this way, the direct electrical contact of the cover electrode 11 with the mirror coating 7 can be created.

FIG. 111 shows the arrangement according to FIG. 110 as top view. FIG. 111 shows three subpixels or dies 1, whose electrical contacts 5 facing away from the substrate 3 can be electrically contacted by a transparent cover electrode 11.

FIG. 103B presents a version that is provided with additional structures. The arrangement is similar to the embodiment in FIG. 103A, although no further explanation is given. In contrast to that embodiment, however, three μ-LED chips of the same type are applied to the substrate and electrically contacted. The μ-LED dies are configured to emit light of a blue wavelength during operation. A structured insulation layer 30 is applied to the cover electrode 11. This improves the light output of the μ-LED dies. Since μ-LED dies of the same type are used in this embodiment, the light must be converted into other colors to obtain an RGB pixel.

For this purpose, 30 converter materials are applied to the layer to convert the light into the appropriate wavelength. In detail, this is a first converter layer 31, which is located above the left blue μ-LED die. A green converter layer 32 is provided above the centrally arranged μ-LED die. Finally, a further transparent layer 33 is arranged above the right μ-LED die. This is not necessary in itself, but the transparent layer creates a planar surface. The converter materials contain an inorganic dye or quantum dots. To reduce optical crosstalk, the individual converter layers, or the converter layer 32 from the transparent layer, are separated by a thin reflective layer 34. Although it is possible that light from other dies than the component directly below may also enter the converter layer, this can be reduced by a low design or by raising the conductor path structures between the components. In addition, the coupling-out layer 30 can also be structured in such a way that it couples out more light that enters layer 30 at a steep angle, i.e. substantially from below. The pixels here are arranged quite close together. If the distance is slightly greater or the arrangement is different from the one in a row, the converters and reflective layers 31 to 34 can be arranged so that they are evenly distributed over the pixel. This would also place the outermost reflective layers 34 above the elevation.

Above the converter structure there are now one or more further structured layers 35, which (not shown here) also partially extend into the converter structure. The converted light can couple well into the structure 35. The structured layers 35 are used for light collimation and shaping, so that converted or unconverted light exits substantially steeply, i.e. preferably at perpendicular angles to the substrate surface. The structured layers 35 can, for example, have a photonic structure that provides a virtual bandgap for light propagating parallel to the surface. This collimates the light.

Several of the pixels shown here can be arranged in columns and rows to form an individually controllable μ-LED module.

FIG. 112 shows an example of a method for the production of a μ-pixel. In a first step S1, a substrate with a number of contacts is provided on the surface. The substrate can contain further lines, control or switching elements as described above. In one aspect, an elevation can be created on the substrate that surrounds the μ-LED die to be attached later and thus optically separates a pixel from adjacent elements.

In step S2, one or more μ-LED dies are mounted on the substrate and their first contacts are electrically connected to contacts on or in the substrate. The μ-LED dies are designed in a vertical configuration, i.e. their contacts are on opposite sides. The μ-LED dies can be arranged in series, but other arrangements are also possible. Possible examples are shown in FIGS. 103A and B and 110 and 111.

In step S3, a mirror coating layer is deposited on the substrate surface, which is electrically connected to an electrical control contact on the surface of the substrate and at least partially covers the surface. The mirror coating layer can be applied at least partially to the sidewalls of the elevation or cavity, in particular those facing the μ-LED dies. Finally, in step S3 a transparent cover electrode is placed on the further contact, which electrically contacts the mirror coating.

In order to prevent the cover electrode from being torn off, step S2 or S3 also provides for the μ-LED dies to be surrounded by an insulating layer after the mirror coating has been applied or the μ-LED dies have been attached. The height of this insulating layer corresponds to the height of the μ-LED dies, so that a planar surface is created. The generation of the insulating layer is done with the measures disclosed here to create a transparent non-conductive layer, such as spin-on glass or similar. A planar surface is created by removing the insulating layer back to the upper contacts of the μ-LED dies and the mirrored layer. This step can involve mechanical or chemical techniques. The cover electrode is then applied to the transparent insulating layer.

Contacting can take place in an overlapping contact of the cover electrode surface and a mirroring surface in the area of the elevation or at the end of the cavity facing away from the at least one μ-LED die. Alternatively, a series of vias can be provided in the insulating layer, which when filled with metal creates a connection between the cover electrode and the mirror coating. The vias can also be trenches, which expose the mirror coating.

In further steps, one or more structured layers can be deposited on the cover electrode, which comprise a photonic crystal or quasi-crystal structure and are configured to suppress or reduce light that radiates parallel to a surface of the substrate. Alternatively, the cover electrode itself can be patterned to either improve light extraction, collimate light or emit light directed away from the substrate surface. Finally, the application of converter material over the μ-LED dies is possible.

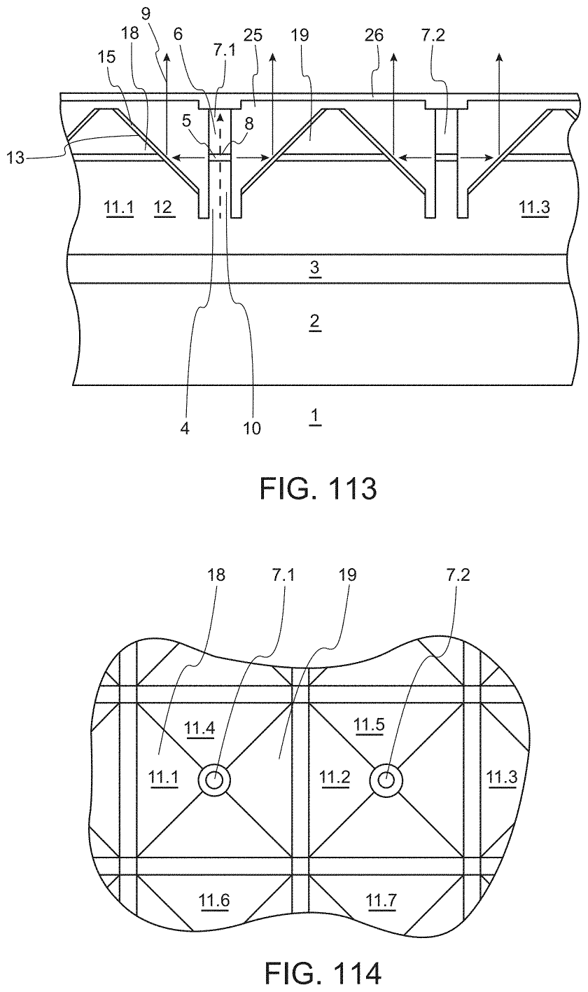

Nano light emitting diode arrays applied in a matrix arrangement and comprise vertical layered nanopillars or nano rods offer the possibility to generate an emission of light in a very small space. In these embodiments, light is emitted by the active layer essentially in any direction in space. Due to the small size and the associated low light force of a single nanopillar, it is advisable to redirect light in a suitable way in order to generate sufficient light intensity. FIG. 113 shows a first version of a μ-LED arrangement 1 as a sectional view, which realizes such a light guidance and thus on the one hand increases the light intensity and on the other hand reduces crosstalk. Shown are two nanocolumns 7.1, 7.2, which are part of a matrix array 28 on a carrier substrate 2. The carrier substrate is formed, for example, with Al₂O₃, glass, silicon, GaAs, SiC, ZnO. A III-V semiconductor system is preferably used as material of the semiconductor sequence 10 of the nanocolumns 7.1, 7.2. In particular (AlxInyGa1-x-y)N, InyGa1x-y)N, GaN, InN, AlN, InGaN, AlGaN, AlInN or AlInN can be used. An n-contact layer 3 is provided between the semiconductor sequence 10 and the carrier substrate 2. The contact layer 3 is continuous in this configuration. However, this can also be structured so that each nanopillar can be contacted individually. In this context, the carrier substrate can also be designed with additional elements and structures. Arrangements and designs are part of this disclosure and can be used for this purpose.

The nanopillars 7.1, 7.2 have a longitudinal extension in the longitudinal direction 8, which runs parallel to the surface normal of the carrier substrate 2, which clearly exceeds their transverse extension. The transverse diameter of the nanocolumns 7.1, 7.2 is 1 μm for the present embodiment, whereby even smaller structures with sub[μm] dimensions are possible. The semiconductor sequence 10 comprises an n-doped semiconductor layer 4, an active layer 5, which typically comprises a quantum well structure, and a p-doped semiconductor layer 6. For variations not shown in detail, several active layers stacked on top of each other may be present.

The active layer 5 takes the form of a quantum disk and generates electromagnetic radiation when energized, which, as indicated by arrows in FIG. 113, comprises a laterally directed component. In accordance with the invention, reflector devices 11.1, 11.2, 11.3 are provided laterally to the nanopillars 7.1, 7.2 with respect to the longitudinal direction 8, which deflect the radiation emission transversely to the longitudinal direction 8 at least partially into a main radiation direction 9 running parallel to the longitudinal direction 8, so that an angle-limited radiation through the p-contact layer 26 results. In this way, precollimation is achieved, which leads to improved coupling efficiency for projection optics not shown in detail and following in the beam path.

The reflector device 11.1, 11.2, 11.3 is formed by a shaped layer 12 with a truncated pyramid shape and a metallic reflecting layer 15, for example of gold, silver or aluminium, on a reflector surface with a 45° position relative to the main radiation direction 9. In addition, reflector devices 11.1, 11.2, 11.3 are provided for each nanopillar 7.1, 7.2 on opposite lateral sides. For the section shown in FIG. 113, a first reflective optical element 18 on the reflector device 11.1 and a second reflective optical element 19 on the reflector device 11.2 are shown. Furthermore, the top view of the matrix arrangement 28 shows that the nanopillar 7.1 is laterally surrounded by further reflector devices 11.4, 11.6. Correspondingly, the opposite reflector devices 11.5, 11.7 are also present for the nanopillar 7.2. FIG. 114 shows the top view of such a μ-LED arrangement 1.

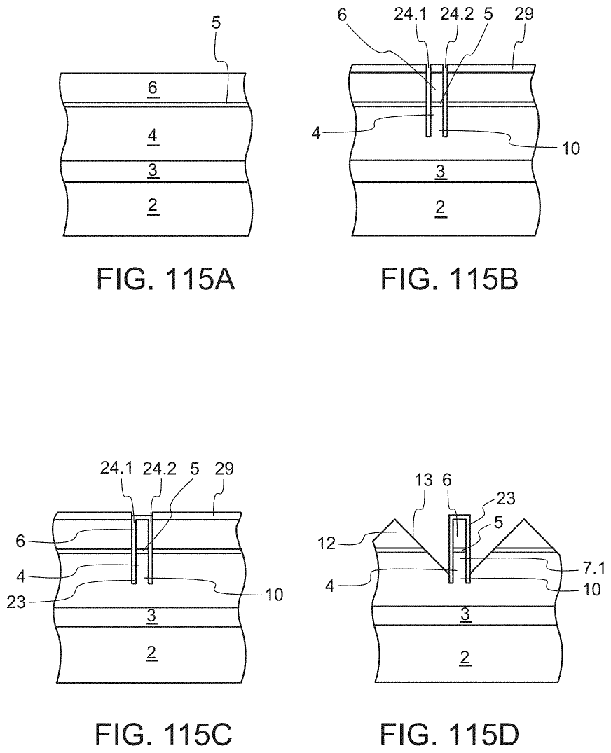

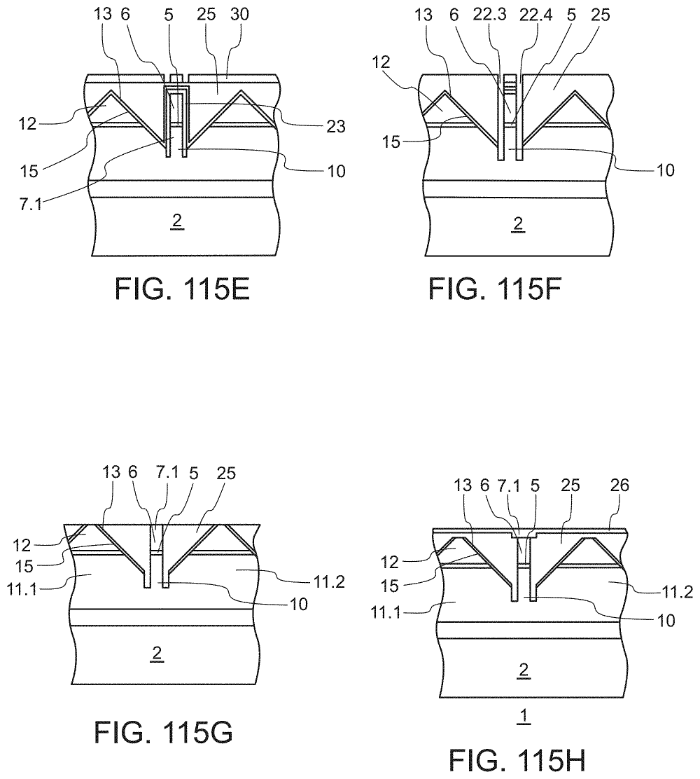

The figure sequence 115A to 115H shows the production of the first version of the μ-LED array 1 and clarifies some aspects. Starting from the extended planar stratification shown in FIG. 115A, a trench structure 24.1, 24.2 is created by dry etching and with the aid of the etch mask 29 shown in FIG. 115B. This trench structure 24.1, 24.2 extends into the n-doped semiconductor layer 4 and an etch stop layer 23, for example of SiNx, is formed in this layer (FIG. 115C). As a further step, an anisotropic wet etching process is used to structure the angular reflector surface 13 of a shaped layer 12. FIG. 115D shows the exposure of the semiconductor sequence 10 of the nanopillar 7.1 protected by the etch mask 29 with a high aspect ratio. Then, as shown in FIG. 115E, a metallic reflection layer 15 is deposited on the reflector surface 13 and planarization is carried out with a transparent electrical insulator 25, for example made of spin-on glass (SOG), SiO2 or epoxy resin. Another etch mask 30 is then applied to this to remove the etch stop layer 23 for the dry etching shown in FIG. 115F. The resulting trench structure 22.3, 22.4 is again filled in by the transparent electrical insulator 25. After removal of the etch mask 30, isotropic etching is carried out over a large area until, as shown in FIG. 115G, the p-doped semiconductor layer 6 of the semiconductor sequence 10 is exposed and can be covered by a p-contact layer 26. As shown in FIGS. 115G and 115H, these steps also produce the final contour of the reflector devices 11.1, 11.2 arranged laterally to the nanopillar 7.1.

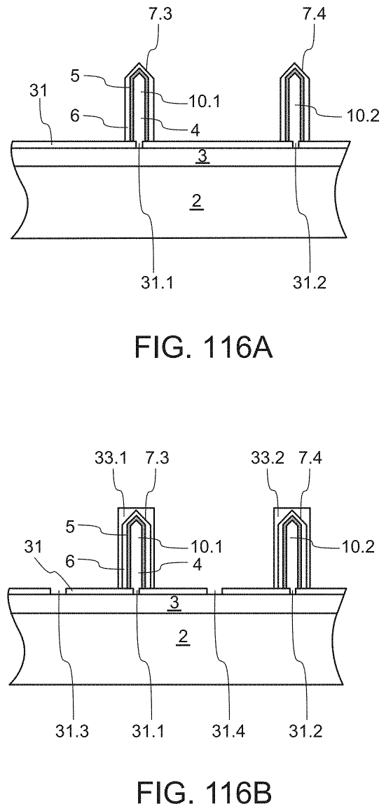

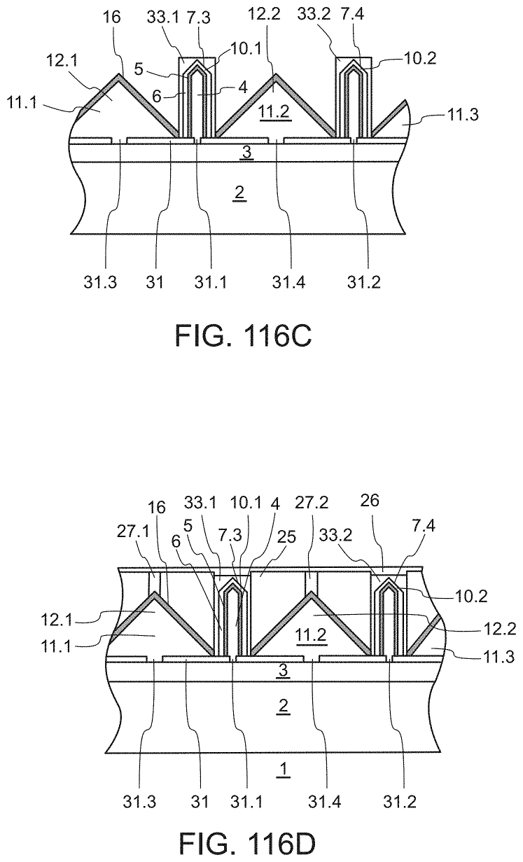

FIGS. 116A to 116D show the epitaxial production of a second version of μ-LED array 1 according to some other aspects. As shown in FIG. 116A, the n-contact layer 3 additionally serves as an epitaxial substrate, whereby an electrically insulating, structured substrate layer 31, for example of SiNx, is present, which comprise openings 32.1, 32.2 to the epitaxial substrate. From these, lateral epitaxial overgrowth takes place by means of hybrid gas phase epitaxy (HVPE), molecular beam epitaxy (MBE) or metal organic gas phase epitaxy (MOCVD) up to beyond the edges of the openings 32.1, 32.2 in the structured substrate layer 31, the process parameters being set in such a way that a semiconductor sequence 10.1, 10.2 with a high aspect ratio grows up to form the nanocolumns 7.3, 7.4. These have an n-doped semiconductor layer 4 in the form of a column core, which carries the active layer 5. This is surrounded on the outside by a p-doped semiconductor layer 6 forming a shell.

FIG. 116B shows the encapsulation of the nanopillars 7.3, 7.4 by means of passivation 33.1, 33.2 in the form of a transparent conductive layer. Additionally, further openings 32.3, 32.4 are created in the structured substrate layer 31 by dry etching. The etching masks used for this are not shown in detail. The epitaxial growth described below starts from the epitaxial substrate in the area of the openings 32.3, 32.4 and is controlled in such a way that the shaped layers 12.1, 12.2 shown in FIG. 116C and arranged as pyramids are created. In the following step, these are covered by a Bragg mirror 16 as shown in FIG. 116C to produce a reflector device 11.1, 11.2, 11.3. Then, as shown in FIG. 116D, a transparent electrical insulator 25 is deposited on the surface and structured to form the optical separating elements 27.1, 27.2 between adjacent nanopillars 7.3, 7.4. The μ-LED array 1 is completed by a p-contact layer 26, which is also transparent and electrically conductive.

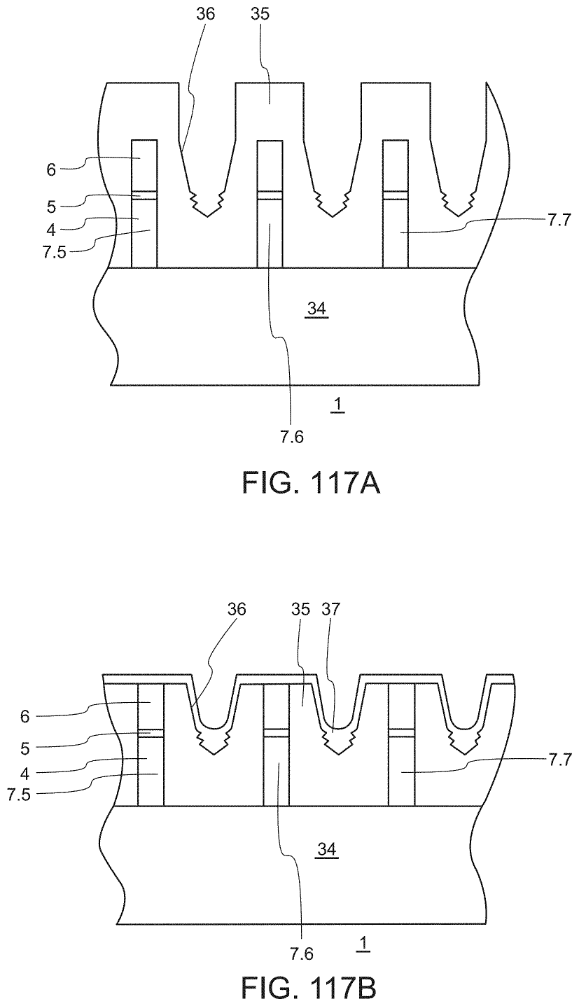

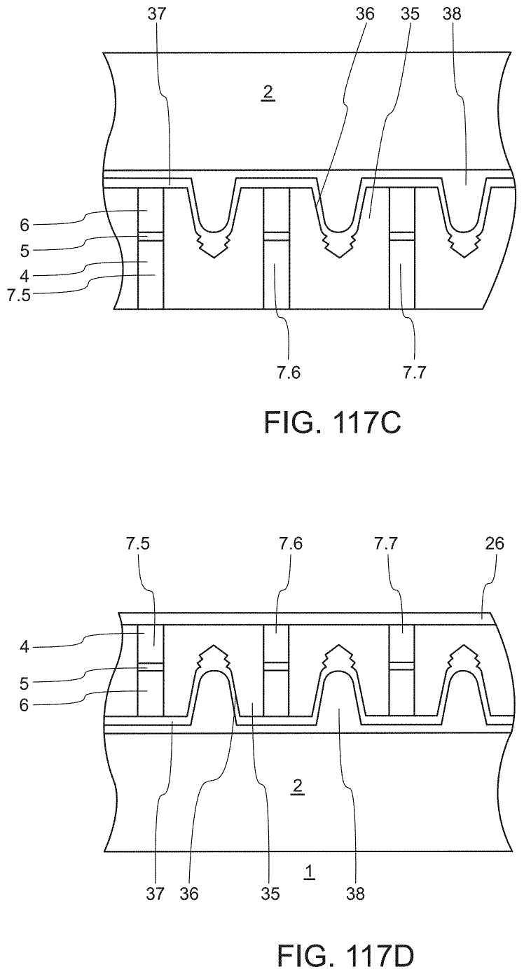

FIGS. 117A to 117B show the production of a third version of a μ-LED array 1 by nano-stamping and using a flip-chip technique. FIG. 117A shows an array with nanocolumns 7.5, 7.6, 7.7 on a transfer substrate 34. The epitaxially grown or lithographically structured nanocolumns 7.5, 7.6, 7.7 each comprise an n-doped semiconductor layer 4, an active layer 5 and a p-doped semiconductor layer 6. The array with nanocolumns 7.5, 7.6, 7.7 is covered by a nanopunch substrate 35 with imprinted structures 36. As shown in FIG. 117B, this is removed over a large area up to the p-doped semiconductor layer 6 by an etching process, whereby the impressed structures 36 are protected by structured etch stop layers, which are not shown in detail. After removal of the etch stop layers, a metallization 37 is applied for the electrical contacting and for mirroring the impressed structures 36. Then a planarization with an intermediate layer 38 is applied, on which a carrier substrate 2 is attached. The next step is to remove the transfer substrate 34, resulting in the state shown in FIG. 117C. The μ-LED array 1 is completed with a p-contact layer 26 as shown in FIG. 117D.

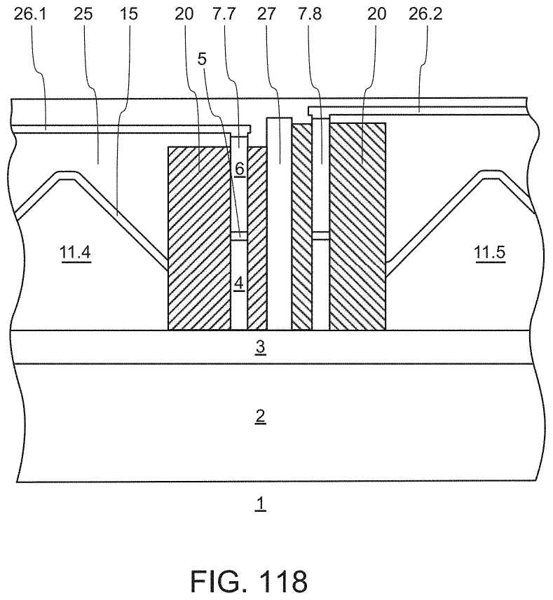

FIG. 118 shows a further development of the μ-LED arrangement 1 with nanopillars 7.7, 7.8 according to the invention, for which a reflector device 11.4, 11.5 for deflection and precollimation of the lateral radiation of the respective active layer 5 is arranged on one lateral side only. An optical separating element 27 between the nanopillars prevents crosstalk. The nanocolumns 7.7, 7.8 have electrically separated p-contact layers 26.1 and 26.2 and can be controlled separately. Furthermore, the nanopillar 7.7 is embedded in a first wavelength conversion element 20, which comprises an emission characteristic that differs from a second wavelength conversion element 21 surrounding the nanopillar 7.8.

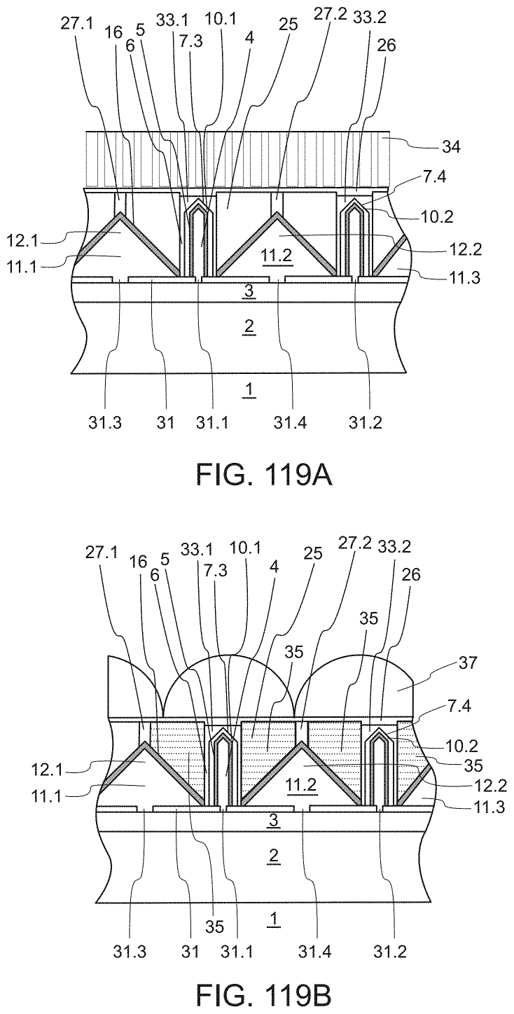

FIG. 119A illustrates a supplement with additional measures to shape light and improve directionality. The μ-LED arrangement includes a light-shaping structure on the surface or light-emitting surface. The structure includes areas 33 and 34 with different refractive indexes. Thus, light coming from column 7 or the reflective layer of structure 16 is formed. Depending on the design of the structure, light can thus be emitted in a defined direction. The structure is formed by a photonic structure. The periodicity of the areas is chosen so that it is in a defined relation to the wavelength of the emitted light. To take the refractive index jump into account, the photonic structure extends into the material of the arrangement (not shown here). Finally, FIG. 119B shows another alternative embodiment based on the example in FIG. 116D. Here, a converter material 35 is inserted into the spaces between column 7 and reflector structures. The converter material in this example is formed by quantum dots. Such quantum dots are available in powder form or as an emulsion and are of a size sufficiently small to fill the gap sufficiently. Grain size of the quantum dots is an essential size here, since conventional inorganic dyes often have a grain size at which there is a risk of misalignment or the like due to the edge structures.

Special processing of the inorganic dyes by the inventors by means of grinding and other mechanical processes, however, allow a reduction of inorganic dyes to a sufficient size. The quantum dots or the dyes can be applied by conventional methods. For example, in one process an emulsion with quantum dots is sputtered on and distributed over the surface. The quantum dots thus also deposit in the interstitial spaces and fill them. In a next step, photoresist is applied and structured. Then the quantum dots are removed outside the desired spaces. If a structured photomask from a previous process step is already in place, this can also be used and the quantum dots are deposited directly into the interstices.

The steps of photoresist structuring and quantum dot insertion can be repeated for further colors. In this way, not only RGB pixels can be produced with the three basic colors, but also 4 colors are possible to make better use of the available color space.

In a further step, microlenses are applied to the converter layer of the other. The microlenses can be structured in a similar way. In this example, the microlens covers one μ-LED array each, but it can be provided that one lens covers all subpixels of one pixel, e.g. 4 subpixels in an extended color space or with one redundant subpixel in a 2×2 matrix.

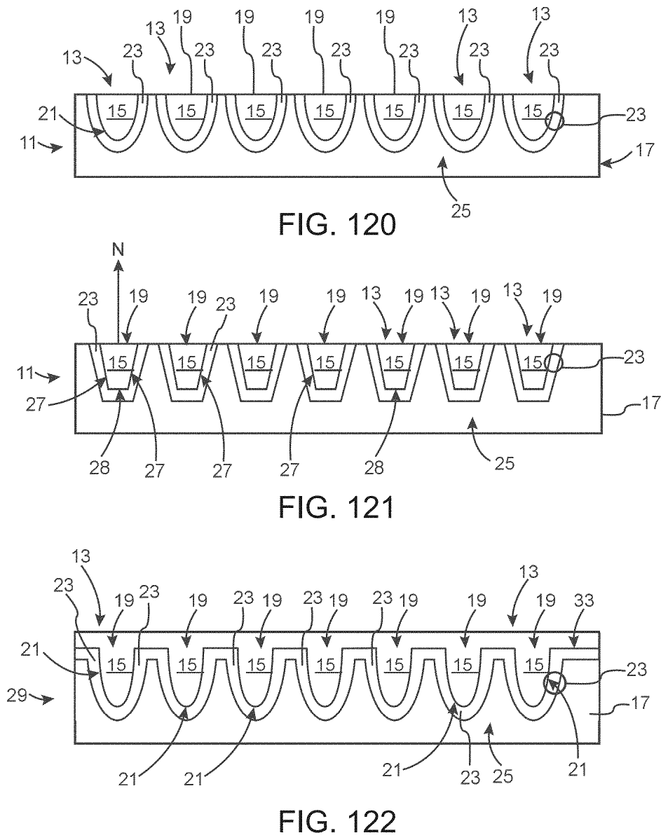

In monolithically arranged μ-LEDs, for example in a display, crosstalk can be reduced by reflective interfacen between the individual pixels or μ-LEDs. At the same time, light is emitted in the main emission direction, thus improving efficiency. The optoelectronic device shown in FIG. 120, which in the example described below is a μ-display array 11, comprises a variety of these proposed optoelectronic devices 13. The optoelectronic devices 13 are further processed μ-LEDs, each of which forms a pixel or subpixel of the μ-display. Although a μ-display arrangement 11 is referred to below, this is only an example and the optoelectronic device is not limited to this example.

Each optoelectronic device 13 has a light source 15, which is a semiconductor device consisting of several semiconductor layers. Because of its dimensions and function, the semiconductor device is also called a μ-LED. Among other things, the semiconductor layers form an active zone for generating light in a manner known per se (not shown). The light sources 15 are arranged in an array on a carrier 17. Due to the array-like arrangement, the light sources 15 form several rows or columns of light sources on the carrier 17.

It may be envisaged that each light source 15 and thus each device 13 emits light at a specific wavelength, i.e. in a specific color, from a number of possible wavelengths or colors. A device 13 that emits light in a certain color can be considered a subpixel of a pixel. The pixel may have further sub-pixels, each of which is formed by adjacent light sources or devices and emits light in the other possible colors.

For example, to create an RGB pixel (RGB for red, green, blue), three light sources 15 can form a pixel, with one of the light sources 15 emitting light in red color, one of the light sources 15 emitting light in green color and one of the light sources 15 emitting light in blue color. In this way, an RGB display arrangement can be formed.

The material 25 of the support 17 surrounds each light source 15 except for its upper surface 19; the light-emitting surface for the light produced is provided on the upper surface 19 of each light source 15 not surrounded by material 25. The light source 15 is functionally separated from the support 25 by an interface 21. The boundary surface 21, as shown in FIG. 120, limits the light source 15 to the sides and downwards and thus comprises the entire outer surface of each light source 15 with the exception of the upper surface 19. In the example shown in FIG. 120, the boundary surface comprises a shape corresponding to the surface of a partial ellipsoid. This is only an example, as other surface shapes are also possible. A parabolic shape of the interface is also conceivable. In both cases, however, light is emitted in the direction of the main emission surface 19, i.e. upwards as shown in the figure.

The material 25 of carrier 17 may have filling material. The material 25 may also include electrical equipment, such as conductive tracks in one or more planes, to supply and control light sources 15 individually with electrical current. The material 25 need not therefore be a homogeneous material, but may be an arrangement of several materials. Additional electronic circuits such as supply or control circuits can be formed in material 25.

For each light source 15, a dielectric reflector 23 is arranged at interface 21, which at least partially reflects the light generated in the active zone of the respective light source 15. The light generated in a light source 15 can therefore not or only slightly escape through the boundary surface 21 into the substrate 21. Rather, the light is, at least to a predominant extent, reflected back into the light source 15 at the interface 21 and travels around in the light source 15 until it is emitted upwards through the light exit surface. The light yield can thus be increased by using the reflector 23.

The display arrangement 11 according to FIG. 121 differs from the variant of FIG. 120 mainly in that the light sources 15 have a different, approximately pot-shaped or trapezoidal cross-section. The boundary surface 21 therefore comprises a side surface 27 running around the respective light source 15 in the circumferential direction and a bottom surface 28 opposite the top surface 19. The circumferential direction runs around a normal N, which extends perpendicularly to the upper side 19.

In the display arrangement 11 shown in FIG. 121, a dielectric reflector 23 is arranged on both the side face 27 and the underside 28. A dielectric reflector 23 thus completely surrounds each light source 15 except the top 19. In modified versions, a dielectric reflector 23 may be provided on the side face 27 only or on the bottom face 28 only.

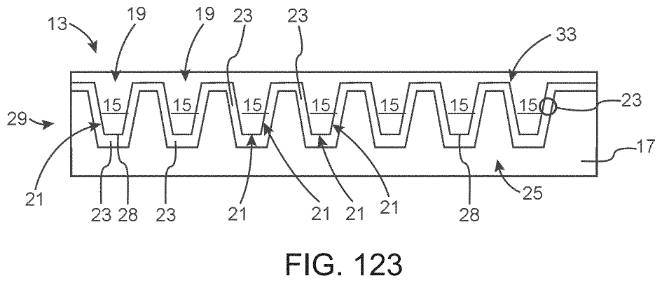

In contrast to FIGS. 120 and 121, which show exemplary variants of display arrangements 11 with a large number of arrayed optoelectronic devices 13, FIGS. 122 and 123 show monolithic arrays 29. The monolithic array 29 shown in FIG. 122 comprises optoelectronic devices 13, which are constructed in the corresponding manner as the optoelectronic devices of FIG. 120. In addition, the monolithic array 29 shown in FIG. 123 comprises optoelectronic devices 13 constructed in the same manner as the optoelectronic devices of FIG. 121. Identical reference marks are therefore used for corresponding elements.

In the variants of FIGS. 122 and 123, a continuous, at least partially transparent top layer 33 may be placed over the light sources 15 and support 17. In addition, the cover layer is conductive and thus forms a common connection for all light sources 15.

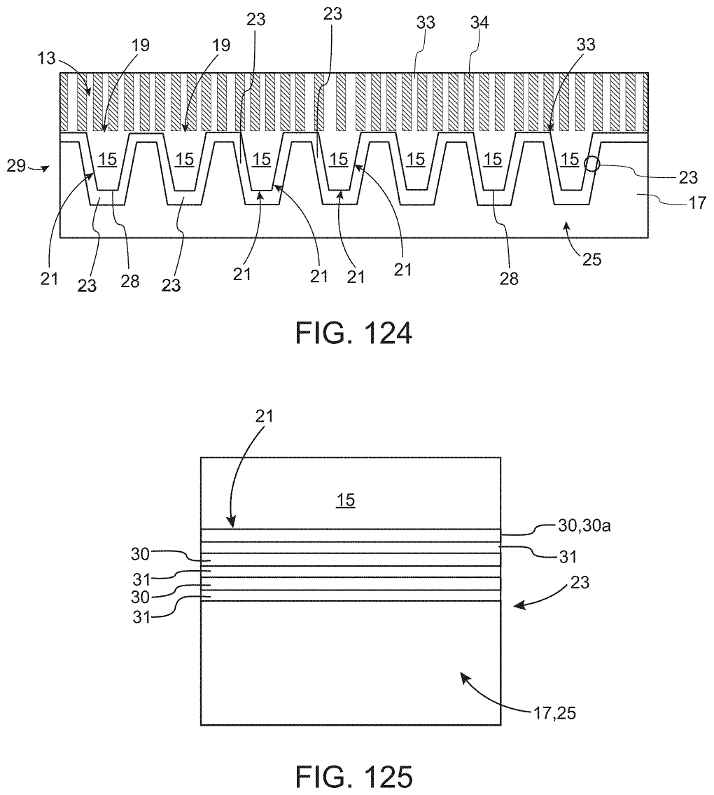

FIG. 124 is a supplement to the embodiment of FIG. 123, where a light-shaping structure is integrated in the upper side 19, and especially in the semiconductor material. The light-shaping structure comprises a periodic arrangement of areas with different refractive indices. This periodic arrangement may be one or more of the structures disclosed in this application. In the version shown, the periodic structure is integrated in the semiconductor material in the surface region. For this purpose, a structure is etched into the semiconductor material, which is then filled with a second material with a different refractive index, thus forming a photonic crystal. It is useful to form the photonic crystal in the semiconductor material itself, because in this way there is no additional refractive index jump between the semiconductor material and the photonic crystal, which would reduce the efficiency in certain cases. The height of the photonic structure is approximately the same as the wavelength, i.e. it is in the range of a few 100 nm, depending on the wavelength of the emitted light in the material. The material in the filled areas should be transparent to keep the light absorption as low as possible. In this context, also converter material, e.g. quantum dots in an emulsion, can be introduced into the etched areas so that the periodic structure has both light shaping and light converting properties.

The example of a light-shaping structure with its different aspects shown here can be transferred to further embodiments of μ-LED arrangements, pixels or even arrays with such.

FIG. 125 shows a cross-sectional view of a dielectric reflector 23, which consists of a periodic sequence of two alternately arranged layers 30, 31, located between the interface 21 of the light source 15 and the material 25 of the carrier 17. The layers 30, 31 are each formed by a dielectric, the optical refractive index of the dielectric of the layers 30 being different from the optical refractive index of the dielectric of the layers 31. In the example shown, three layers 30 and three layers 31 are provided, whereby a different number of layers, for example, 1, 2, 3, 4, 5, 6, 7, 8, 9 or 10 layers each, can also be provided. For example, only one high refractive layer can be provided between two low refractive layers. For very small pixels, there may not be enough space for more than one high refractive index layer between two low refractive index layers.

The layers 30, 31 can be arranged to form a Bragg mirror. The maximum reflectivity for the wavelength of the light emitted by the associated light source 15 is achieved when layers 30, 31 have an optical thickness of a quarter of the wavelength. The optical thickness corresponds to the product of the refractive index and layer thickness.

The production of layers 30, 31 can be carried out by means of atomic layer deposition, for example. By deposition in layers, target thicknesses of the individual layers 30, 31 can be achieved precisely. In particular, layers 30, 31 can be made correspondingly thin so that the above condition can be met, according to which layers 30, 31 should have an optical thickness of a quarter of the wavelength. Thus, very efficient reflectors can be produced. The method of atomic layer deposition also allows a uniform overmoulding of the interface 21, so that, for example, even narrow gaps can be lined with a high aspect ratio. In addition, remaining gaps to the carrier material 25 can be filled with filler material.

In a modified embodiment, the first, lowest layer 30a, which directly abuts the interface 21, can be deposited using another technology, such as CVD or PE-CVD. This allows unevenness of the interface 21, for example a rough surface resulting from an etching process, to be covered by a more conformal deposition. The remaining layers 30, 31 can then be applied over the smooth layer 30a by atomic layer deposition.

In the variants shown in FIGS. 120 to 123, a dielectric reflector 23, as shown as an example in FIG. 125, causes light to be reflected at least partially back into the interior of light source 15, in particular light that strikes the reflector 23 perpendicularly. The light generated in the light source 15 can thus not, or to a lesser extent, escape through the interface 21 to the side and/or downwards into the material 25 of the support 17. The light reflected back remains in the light source 15 and escapes to a large extent upwards through the light exit surface. The light yield can therefore be increased.

The term light is broadly understood herein and refers in particular to electromagnetic radiation produced by a particular light source. In particular, the term light may include not only visible light but also infrared and/or ultraviolet light.

A further aspect is concerned with improving the radiation characteristics of a μ-LED, which comprises a dielectric filter with additional reflecting sides.

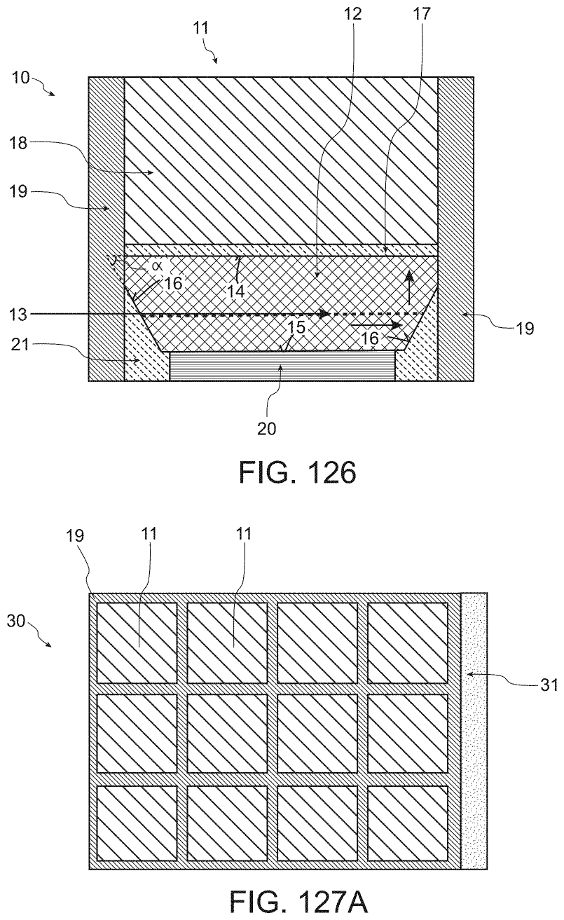

FIG. 126 schematically shows a cross-section of an optoelectronic component 10. In the following, the design, function and manufacture of the optoelectronic component 10 are described.

The optoelectronic component 10 contains a pixel 11 with an LED semiconductor element 12 in the form of a μ-LED. The LED semiconductor element 12 contains an active zone 13, which is configured to generate light, and has a height in the range of 1 to 2 μm. The LED semiconductor element 12 has a first main surface 14, a second main surface 15 opposite the first main surface 14, and for example, four side surfaces 16. The side surfaces 16 are each bevelled in the lower area so that they form an angle α of less than 90° with the first main surface 14 in the bevelled area. The active zone 13 is at the level of the bevel.

A layer 17 is arranged on the first major surface 14 of the LED semiconductor element 12, which contains a random or deterministic topology. Alternatively, a corresponding topology can be etched into the first major surface 14 of the LED Semiconductor Element 12.

Above layer 17, another layer not shown in FIG. 126 is deposited, which has a different refractive index than layer 17. Layer 17, in combination with the layer deposited above it, causes light that does not exit from the LED semiconductor element 12 perpendicular to the first main surface 14 to be deflected in other directions, for example by reflection at the interface between layer 17 and the layer above it. In addition, the layer arranged above layer 17 has the function of providing a smooth surface to which dielectric mirror layers can be applied.

Above the layer 17 and the layer above it with the smooth upper surface is a dielectric filter 18, which consists of a stack of dielectric layers and is configured in such a way that it only transmits light components within a predetermined angular cone, while flatter rays are reflected. The angle cone is aligned with its axis perpendicular to the first main surface 14 of the LED semiconductor element 12.

Furthermore, a reflective material 19 is deposited on all side surfaces 16 of the LED semiconductor element 12, which is electrically conductive and consists of a metal, for example. The reflective material 19 is in contact with the n-doped area of the LED semiconductor element 12. Below the second main surface 15 of the LED semiconductor element 12, there is a reflective layer 20, which is also electrically conductive. The reflective layer 20 is in contact with the p-doped area of the LED element 12.

The bevelled side surfaces 16 of the LED semiconductor element 12 are covered by an electrically insulating first material 21. The electrically insulating first material 21 is located between material 19 and layer 20 and provides electrical insulation between the n and p contacts of the LED semiconductor element 12. In addition, the material 21 has a low refractive index to reflect light emerging from the LED element 12 at the tapered side faces 16.

The layer formed from the reflective material 19 is configured in such a way that it completely surrounds pixel 11 in the horizontal direction and extends over the entire pixel 11 in the vertical direction. This means that the reflective material layer 19 extends from the bottom of the electrically insulating first material 21 through the LED semiconductor element 12 to the top of the dielectric filter 18. Any light that exits laterally from the pixel 11 is reflected back through the reflective material 19 so that high directionality light can only exit at the top of the optoelectronic device 10.

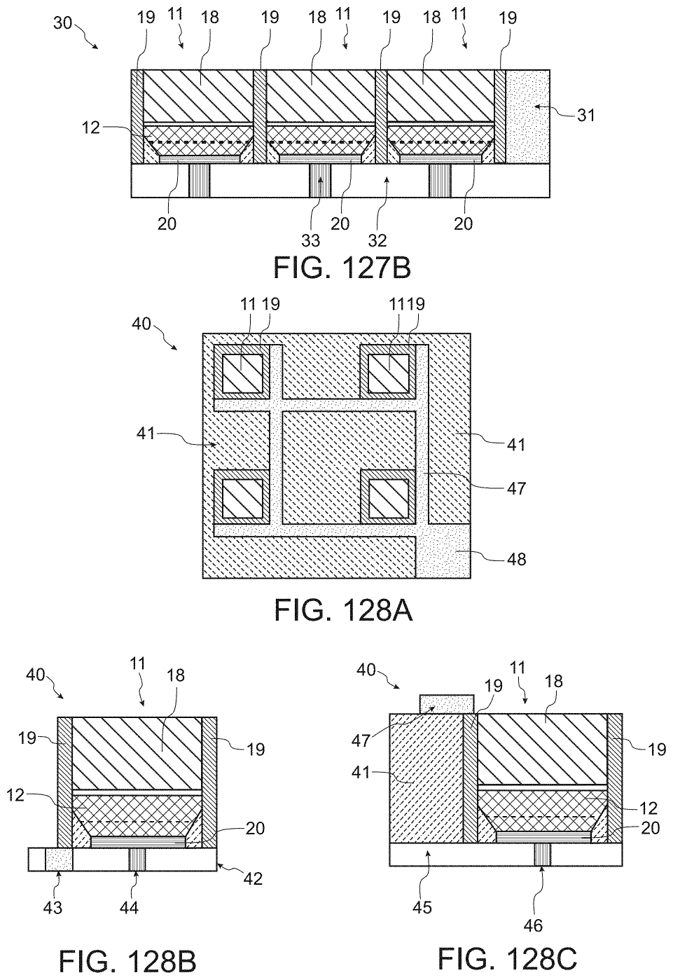

FIGS. 127A and 127B schematically show an optoelectronic component 30 in a top view from above and in cross-section. The optoelectronic device 30 contains a large number of pixels 11 as described above. The pixels 11 are arranged in an array and separated from each other by the reflective material 19, which extends through the optoelectronic device 30 in a grid-like manner. An external terminal 31 is provided on one side of the optoelectronic device 30, which allows the n areas of the LED semiconductor elements 12 to be contacted from outside the optoelectronic device 30. In the present embodiment, the anodes of the LED semiconductor elements 12 are connected to each other, which is called common anode arrangement. A common cathode arrangement in which the cathodes are connected to each other is also possible.

The array of pixels 11 is placed on a carrier 32. The carrier 32 comprises a p-contact connector 33 for each p-contact, so that the p-contacts of each of the pixels 11 can be controlled individually, for example by an IC. The optoelectronic device 30 allows a very high pixel density. FIGS. 128A, 128B and 128C show an optoelectronic device 40 in a top view from above and in a cross-sectional view respectively. Two different variants are shown in FIGS. 128B and 128C.

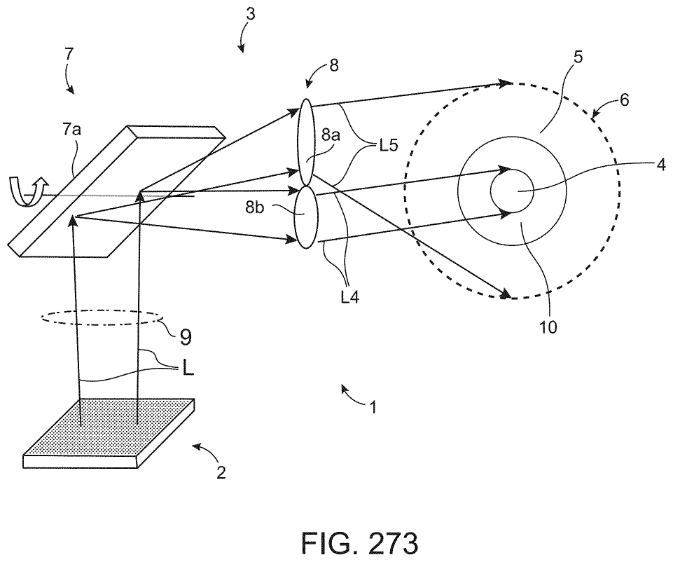

The optoelectronic device 40 contains a plurality of pixels 11, the pixels 11 not being directly adjacent to each other as in the optoelectronic device 30 shown in FIGS. 127A and 273B, but spaced apart. Each pixel 11 in the optoelectronic device 40 is completely covered on its four side surfaces by the reflective material 19. The space between the pixels 11 is filled with an electrically insulating second material 41, for example a moulding material. In the optoelectronic component 40, the LED semiconductor elements 12 are configured as μ-LEDs.

The n-contacts of the μ-LEDs in pixel 11 can be connected to the bottom or top side or between top and bottom side of the optoelectronic device 40. In FIG. 128B, pixel 11 is placed on a carrier 42, which has n-contact connectors 43 integrated into it, connecting the n-contacts of pixel 11. In addition, the carrier 42 comprises a p-contact connector 44 for each p-contact, so that the p-contacts of each pixel 11 can be controlled individually. The carrier 42 can also contain an IC. The spaced-apart arrangement of the LED semiconductor elements 12 in the optoelectronic device 40 also permits contacting in which both the n-contact and the p-contact of each pixel 11 can be individually driven.

FIG. 128C shows an alternative variant, in which a carrier 45 contains only individual p-contact connectors 46 for each pixel 11 arranged on the carrier 45. Of course, P-doped and n-doped layers can also be swapped. On the electrically insulating second material 41, traces 47 are arranged in a grid pattern, connecting the n-contacts of the pixels 11 to each other and leading to an external terminal 48, which is located on one side of the optoelectronic device 40, as shown in FIG. 128A.

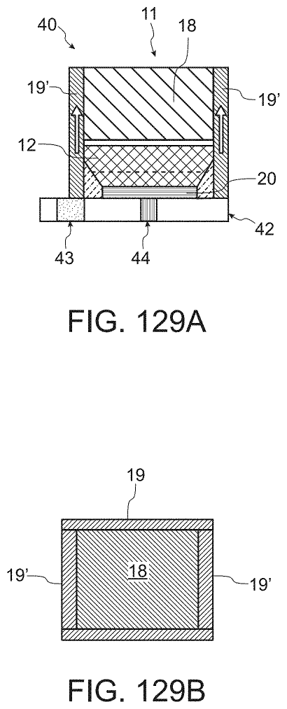

FIG. 129A shows an embodiment in which an essentially rectangular semiconductor element or μ-LEL 12 has a 19′ dielectric layer formed on two opposite sides. A plan view in FIG. 129B shows that the dielectric elements 19 and 19′ are alternately placed around the semiconductor element 12 and the dielectric filter 18. The dielectric elements 19 and 19′ are designed differently. Element 19′ comprises at least one electrically conductive partial area, for example in the form of a surface along the sidewall of the μ-LED 12 or also in the form of several strips running along the sidewall. Element 19 is not electrically connected to the μ-LED 12 and therefore does not contribute to the power supply of element 12.

The current direction is indicated by the arrow in FIG. 129A. The current flows both to the surface and from there through the dielectric filter 18 into the semiconductor layer to the active region. Alternatively, the conductive portion of the dielectric element is connected to a contact layer on the μ-LED. The contact layer could, for example, be located between the dielectric filter and the μ-LED and be designed as a cover electrode, as shown in FIG. 129A by the thin unmarked layer between elements 12 and 18. In both cases, the contact layer serves to spread the current over the entire surface.

The current flow generates a magnetic field so that charge carriers moving through the layers of μ-LED 12 feel a force towards the center of the structure.

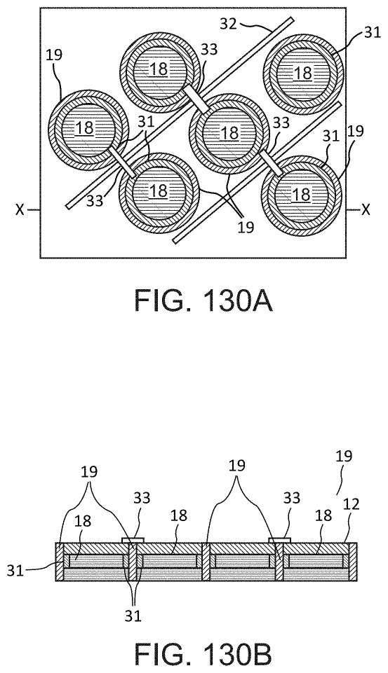

FIGS. 130A and 130B illustrate a configuration in which the dielectric layer 19 is arranged around a μ-LED, which is essentially cylindrical in shape. The μ-LEDs are monolithic at regular intervals, thus forming a μ-LED array or μ-display. The dielectric element 19 is non-conductive, i.e. the current is conducted to the μ-LEDs through leads arranged on the surface. For this purpose, the lines 32 run between the individual μ-LEDs. Supply lines 33 connect the lines 32 with a conductive dielectric filter 18, which in turn is in electrical contact with one of the semiconductor layers of the μ-LED. In order to keep the current away from the edge region and thus from the dielectric element 19 on the lateral surface of the μ-LED an additional quantum well intermixing is proposed. The design and process of such a quantum well intermixing is shown in this disclosure in several examples. Quantum well intermixing surrounds the active region (shown in FIG. 130B by the slightly wider line) and produces a change in the band gap around the active region. As a result, the charge carriers “see” an energy barrier, which pushes the charge carriers towards the center of the μ-LED 12.

The following comments concern various aspects of processing, which can be used for the semiconductor structures to improve their properties or to create new fields of application or realization possibilities.

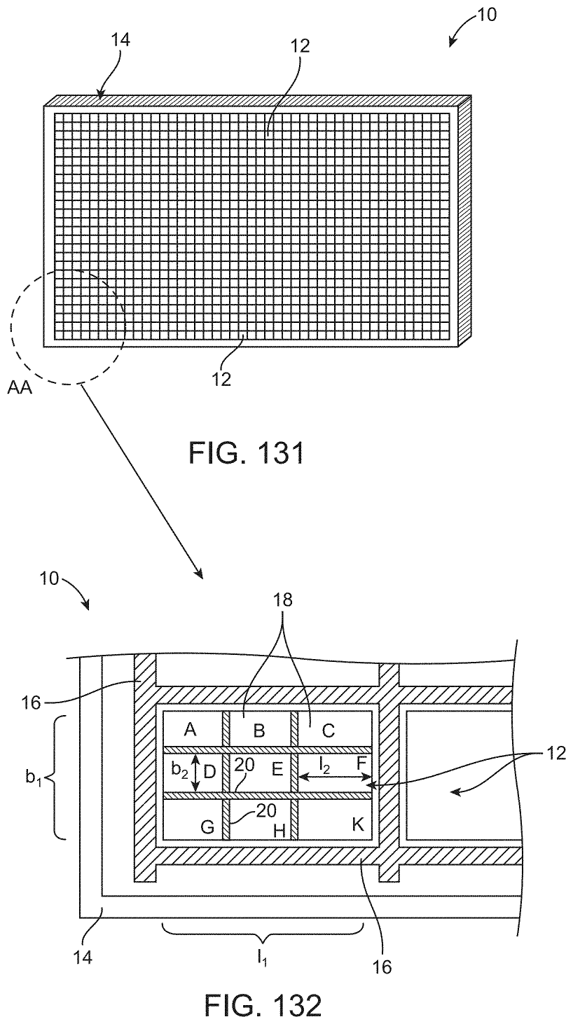

For illustrating the aspect of pixel elements with electrically separated and optically coupled subpixels a simplified schematic diagram of an electronic display 10 is shown in FIG. 131, as it is often used in, for example, monitors, televisions, scoreboards or even small devices such as smart watches or smart phones. As is generally known, the basic structure is realized by a closely adjacent arrangement of a large number of pixels or pixel elements 12 in one plane. The pixel elements 12 are organized in rows and columns and can be controlled electronically individually. They are controlled in such a way that they can be varied in their luminosity as well as in their color tone and emitted wavelength. In the latter case, each pixel often comprises three sub-pixels, which in turn are designed to emit different wavelengths. The pixel elements 12 are often mounted on a substrate or carrier structure 14, which in this aspect are primarily intended to ensure mechanical stability of the arrangement.

This illustration shows clearly that in order to generate a sufficiently high resolution, several million of such pixel elements 12 must be spatially densely arranged both mechanically and electrically. At the same time, in many cases defective pixels 12 can be detected as dark dots between the active pixels. Especially due to extremely small dimensions, e.g. for μ-LEDs, the density and resolution of such displays increases on the one hand, while on the other hand there is a need for fault-free operation and production with as few rejects as possible.

In FIG. 132, the section AA shown in FIG. 131 is enlarged in order to be able to describe the features of the solution in more detail. For example, substrate 14 is shown to simultaneously contain the control elements and serve as a support structure for the pixels. On substrate 14, individual pixel elements 12 are provided, which here are rectangular and of the same size. These identical sizes of the pixel elements 12 are often advantageous for manufacturing reasons, but can also be designed in different shapes or sizes according to an example. The pixel element 12 in the example shown here has a length l1 and a width b1. A pixel element separation layer 16 is provided between the pixel elements 12. The latter is in the range of a few μm, for example 0.5 μm to 3 μm.

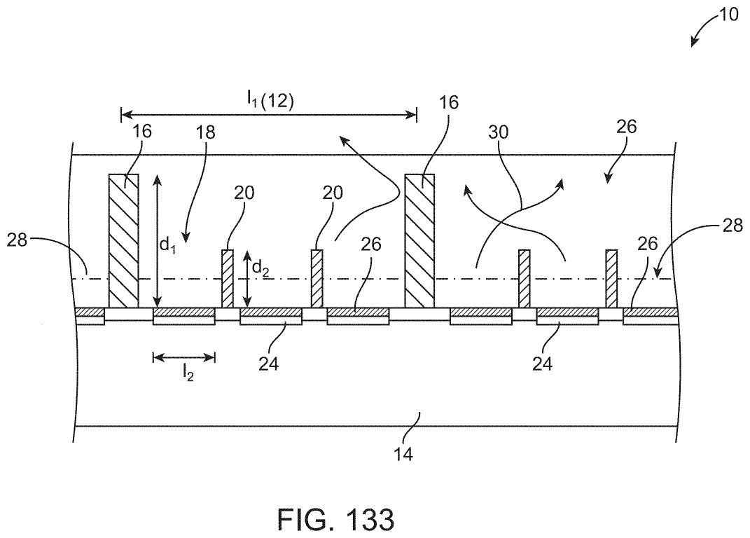

The pixel element separation layer 16 is configured in such a way that the adjacent pixel elements 12 are electrically separated with respect to the control of the respective pixel elements. FIG. 133 shows a section of a pixel element in cross-sectional view. The pixel elements 12 are separated by a pixel element separation layer 16 and each comprises sub-pixels 18. The pixel element separation layer 16 provides electrical and optical separation between the pixel elements 12. This is intended to prevent light emitted by a pixel element 12 from passing through optical crosstalk into an adjacent pixel element 12 and being emitted from there.

Within a pixel element 12, a further subdivision into subpixels 18 is shown here, as an example of a selected pixel element 12. The subpixels 18, also known as fields, have the same size and shape here. A length l2 of a subpixel 18 is defined, whereby, according to an example, the length l1 of the pixel element 12 can result from a multiple of the length l2 of the subpixels 12 of the same size including any gaps. Similarly, a width b2 of a subpixel is specified, where, according to an example, the width b1 of the pixel element can also result from an approximate multiple of the width b2 of the respective equally sized subpixels 18 including any gaps. The representation selected here shows the subdivision of pixel element 12 into subpixels 18 or so-called fields for only one pixel element 12. However, the structuring is applicable to all pixel elements 12 arranged in a display 10.

Between two adjacent subpixels 18 of the same pixel element 12 a subpixel separator element 20 is also provided. This subpixel separating element 20 is configured in such a way that electrical separation takes place with respect to the control of an assigned subpixel (of length l2) (see FIG. 133). The subpixel separating element 20 is further configured in such a way that optical coupling or optical crosstalk is possible with respect to the light emitted by the subpixels 18. In other words, this means that within a pixel element 12 photons or light can cross talk from a subpixel 18 to one or more of the subpixels 18 located in the same pixel element 12, but not between two pixel elements 12.

For example, the various possible emittable colors of a pixel element 12 can be generated by combining the basic colors red, green and blue. Consequently, a pixel element 12 can contain subpixels 18, which can emit different wavelengths of light. In FIG. 132, for example, the total of nine subpixels 18 are marked with the letters A to K. According to one example, the subpixels A, D, and G are red LEDs, the subpixels B, E, and H are green LEDs, and the subpixels C, F, and K are blue LEDs. If, for example, red light is to be emitted by pixel element 12, the subpixels A, D and G are controlled simultaneously via the control electronics. If necessary, the control electronics can be used to test whether all subpixels A, D and G are functioning correctly. By this means, a desired brightness can be adjusted.

If, for example, one of the subpixels A, D or G is defective, the remaining pixels can still be controlled correctly due to the electrical separation. However, the optical crosstalk made possible by the subpixel separation element 20 allows the missing light of the defective subpixel 18 to be compensated by the adjacent subpixel 18. Thus, as long as a subpixel 18 of the same color from a group works and the remaining subpixels 18 of this group are defective, this remaining working subpixel 18 could compensate for the malfunctions of the defective subpixels and thus ensure a function of the pixel element 12 by redundancy. In an example, an optical crosstalk can also take place over several subpixels within a pixel element 12. Other possible arrangements would be, for example, the assignment of three subpixels 18 each to one of the basic colors red, green, or blue. Examples are the following grouping A/B/C, D/E/F and G/H/K. But also a diagonal assignment is conceivable, whereby an optical crosstalk should be advantageously possible.

FIG. 133 shows a sectional view through a section of a display 10. In the lower part of the figure a substrate 14 is shown, which among other things should provide a mechanically sufficiently stable support structure to accommodate the remaining structural elements. According to one example, this can be a wafer of a silicon IC. The substrate 14 can also comprise a driver circuit or drive electronics (not shown) and various electrical connections. These can, for example, be realized via conductor structures in the integrated circuit. Furthermore, contact structures 24 are provided, which can be used to drive a subpixel area 26. In the example shown here, this is arranged directly adjacent to contact structures 24. Via contact structures 24 it is possible to control an emitter chip 26 individually and selectively via the control electronics.

An epitaxial layer 26, for example, comprises different layers, which among other things allows the functionality of light-emitting diodes. For example, a p-n junction can be implemented by correspondingly differently doped layers or can also have one or more quantum well structures. Schematically and for simplicity, a region of a p-n junction 28 is indicated here by a dotted line. In the epitaxial layer 26, the structures of the pixel elements 12 and the subpixels 18 are introduced.

In detail, the individual pixel elements 12 can be identified via pixel element separation layers 16. These each have a length l1, which corresponds to a distance between two pixel element separation layers 16. Within the pixel elements 12, three subpixels 18 can be separated in the longitudinal direction. These each have a length l2. Subpixel separation elements 20 are arranged between the individual subpixels 18.

In the example shown here, the pixel element separation layers 16 and the subpixel separation elements 20 are each designed as a trench or similar structure. This means that the pixel element separation layers 16 and the subpixel separation element 20 are each incorporated into the epitaxial layer 26 as a trench-like, slit-like or similar structure, for example by etching processes. An electrically insulating material such as SiO₂ is then deposited in the trenches. In order to determine the electrical and optical properties of these trenches, a trench depth dl of the pixel element separation layer 16 is chosen to be larger than a trench depth d2 of the subpixel separation element 20. Thus, it can be achieved that an optical crosstalk between subpixels 18 is possible due to the smaller depth d2 of the trench of the subpixel separation element 20.

In contrast, between two pixel elements 12, both optical crosstalk 30 and electrical crosstalk is prevented by the deeper trench dl of the pixel element separation layer 16. According to one example, a depth d2 of the trench of the subpixel separation element 20 is chosen such that it passes through an area of a p-n junction 28. This can be advantageously used to prevent electrical interaction between two adjacent subpixels 18 or the associated emitter chips 22 and/or electrical or electromagnetic crosstalk.

In the example above, the pixel element separation layer 16 runs through the active layer to the edge of the opposite radiation surface, but does not cut through it. This allows the area close to the surface to be formed as a common contact connecting all pixels and sub-pixels with a potential connection. In addition, the pixel element separation layer 16 can include a mirror layer so that light generated by the pixel is optically redirected. In the example of FIG. 133, it is also shown that the subpixel separation element 20 passes through the active layer but ends shortly after. This prevents electrical crosstalk, but not optical crosstalk. Depending on the design and manufacturing parameters, the subpixel separator element 20 can also reach only to the active layer or slightly into it.

While in this embodiment the pixel element separation layer 16 and the subpixel separation elements 20 are designed as trenches with substantially vertical sidewalls, the invention is not limited to this. It is also possible to choose deliberately other shapes, which also have additional functionality such as light collimation or light guidance. As an example, sloping sidewalls for pixel element separation layer 16 can be mentioned.

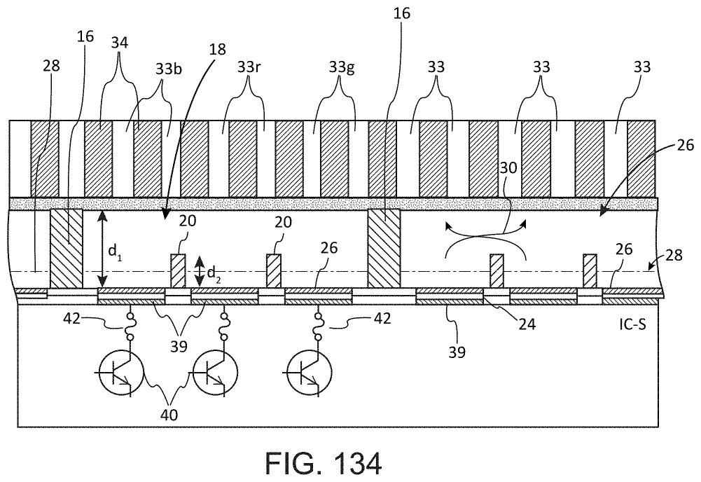

In FIG. 134, an extension of the embodiment in the previous figure is shown. The pixel elements are implemented monolithically in or on a thin film substrate. Contacts 26 are arranged on the backside, i.e. the side facing away from the main radiation direction. These are located directly below the individual sub-pixels and are formed with a conductive metal, for example a gold or silver alloy. The size of the contacts essentially corresponds to the area of the individual subpixels. In this way, a suitable material system can be used to produce the pixels. In addition, process parameters such as temperature, precursors and others can be adjusted to the pixels to be produced.

Contacts 39 of a backplane or other substrate carrier are arranged opposite the contacts 26 of the subpixels. The backplane is configured with a different material system, e.g. silicon technology. The backplane contains the control for the individual subpixels as well as their power supply. Examples of current driver and drive concepts for μ-LEDs are disclosed in this application. In this version, the backplane includes additional fuses 42 for each individual subpixel. The fuses are in turn connected to current driver 40. If a defect occurs in one of the subpixels during production or a defect occurs during the positioning of the pixels on the backplane, the defective subpixels can be separated by means of the fuses.

The backplane is positioned with its contacts and then connected to the contacts of the pixels. Depending on the application, an auxiliary carrier (not shown here) can be provided to ensure sufficient stability for the pixel elements. For contacting, for example, the two surfaces can be glued together, provided that a conductive connection between the contacts is guaranteed.

On the other side of the pixel elements, a cover electrode is provided on the one hand, which creates an electrical contact to each subpixel. The cover electrode is led down one or more sides to a contact area. The cover electrode is transparent and consists for example of ITO. Along and above the pixel separators 14 additional metallic lines can be provided on the cover electrode. This reduces the surface resistance of the cover electrode and thus improves the current carrying capacity. The additional lines at this point do not have a negative effect on light extraction and shadows do not significantly affect the structure.

A light-shaping structure is arranged next to the cover electrode. This can either be arranged on the cover electrode or extend through the cover electrode and into the semiconductor material of the pixel, in some cases down to active region 28. The light-shaping structure comprises regions with different refractive indices. Various examples of such a structure are disclosed in this application.

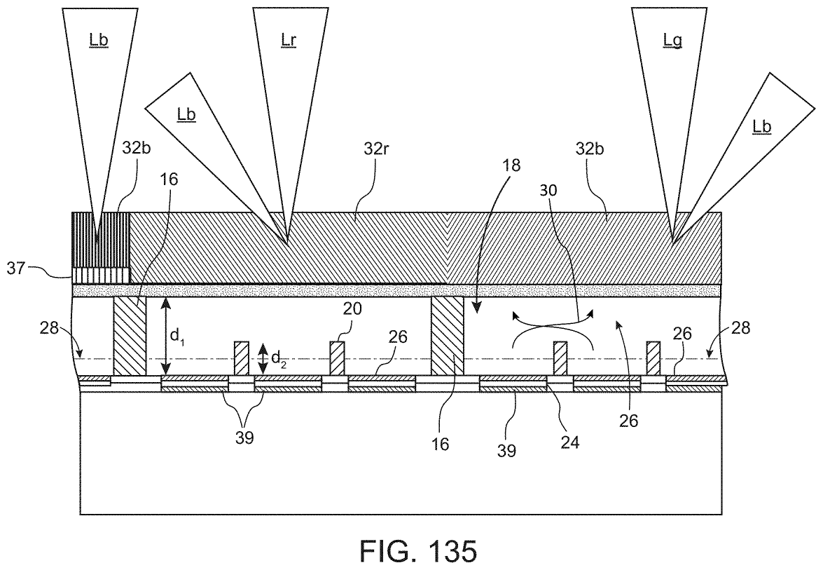

FIG. 135 shows an example. On the one hand, a converter material is incorporated into the light-shaping structure. In particular, the left side or the left pixel has a light-shaping structure 32r with converting properties. This structure converts blue light from each controlled subpixel below the structure 32r into red light. Accordingly, structure 32b converts the light emitted by the subpixels into green light.

At the same time, the light thus converted is directed through the respective structures 32r and 32b in such a way that the converted light is emitted directly upwards. In contrast, unconverted light is deflected in direction so that an exit of unconverted light directly upwards or parallel to the direction of emission of the converted light is suppressed. A directional selection can be achieved by photonic structures presented here. The directional deflection also extends the path through the converter material, so that the conversion efficiency increases. The unconverted light is deflected towards structure 32b, which collimates light from blue subpixels.

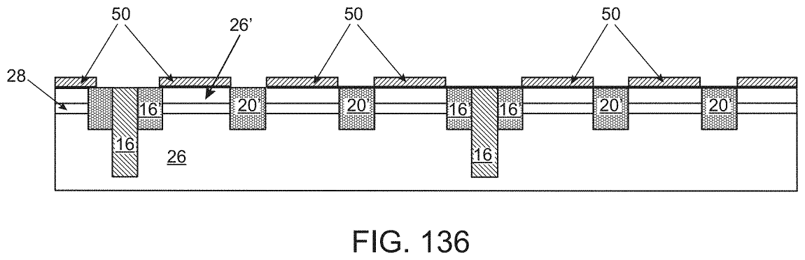

FIG. 136 shows another viewpoint that is suitable for creating the optical separation elements. In addition, this embodiment improves the relationship between radiative and non-radiative recombination. The embodiment makes use of quantum well intermixing to create the subpixels within a pixel. FIG. 136 shows a structure on a non-displayed substrate carrier on which semiconductor layer 26 has been grown. The substrate carrier 26 is removed at a later time after transfer to a backplane or an auxiliary carrier. After production of the individual semiconductor layers with an active region 28 between them, a photomask 50 is applied and patterned so that the surface on the semiconductor material is exposed, in which the optical and electrical separation elements 16 are manufactured. In a subsequent step, trenches 16 for electrical and optical separation are etched and filled with an insulating or dielectric material. Then the photomask 50 is appropriately structured again so that on the one hand the areas on the surface are exposed in which the electrical separation elements 20 are manufactured. In addition, a small additional area around the electrical and optical separating elements is freed from photoresist.

In a following step, Zn or another dopant is applied and diffused. These steps can be carried out using, among others, the methods disclosed in this application. The resulting quantum well intermixing increases the band gap in these areas so that charge carriers see an additional energy barrier. This results in a certain electrical separation between the individual subpixels. Quantum well intermixing around the optical and electrical separation elements 16 creates a barrier that keeps charge carriers away from potential recombination centers and defects created by the etching process. The photoresist is then removed and the wafer is further processed.

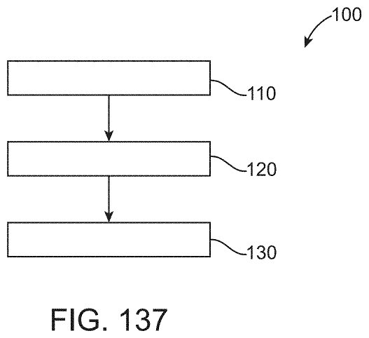

FIG. 137 shows a method 100 according to the invention for calibrating a pixel element 12. In a first step 110, a subpixel 18 of a pixel element 12 is driven as described above and below. This control of the subpixel 18 should allow a test of the function of the respective subpixel 18. This can be done, for example, by control signals from an electronic control unit, which in turn can be made possible by contacting each individual subpixel 18 separately. In a following step 120, defect information of a subpixel 18 is recorded, in other words, information is generated as to whether the subpixel 18 in question is functioning correctly.

Such defect information can be, for example, a flag or a certain value that contains information about a correct function of subpixel 18. This defect information can be stored according to a following step 130, for example in a memory unit of a control electronics. This can be used to compensate defective subpixels by appropriately adapted control signals of the associated subpixels of the same wavelength and thus to achieve a correct function of the entire pixel element 12.

In an example, the subpixel separation element 20 may be designed to allow optical crosstalk between subpixels 18 of the same color or wavelength, where the subpixel separation element 20 is designed to optically separate between subpixels 18 of different color or wavelength.

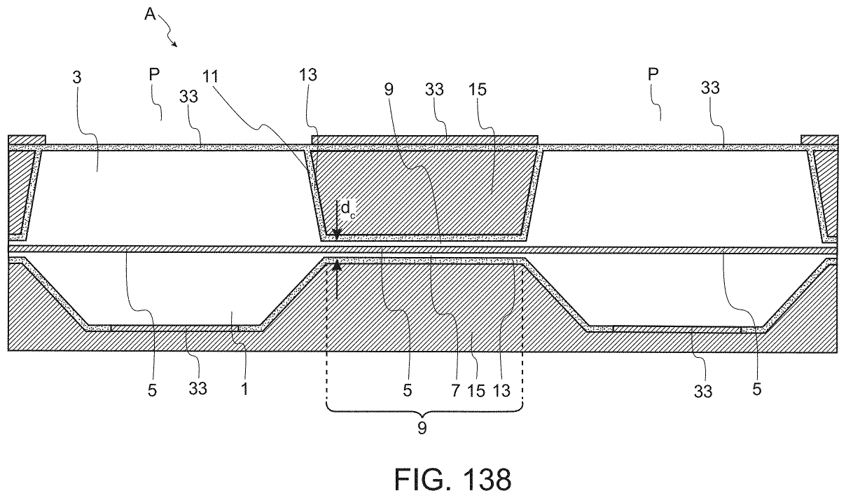

An extension of pixelated or other emitters in which optical and electrical crosstalk between pixels of an array is prevented by a pixel structure with a material bridge is shown in FIG. 138. It illustrates a section of an array A in a cross-section in which two adjacent optoelectronic pixels P are connected by a material bridge.

Array A features two optoelectronic pixels P in the form of vertical μ-LEDs, which have been manufactured over the entire surface. Each pixel P comprises an n-doped layer 1, a p-doped layer 3 as well as an active zone 5 suitable for light emission. Between the two formed pixels P material of the layer sequence was removed from the n-doped side and from the p-doped side. Only a thin material transition 9 with a maximum thickness dC remains, which comprises the active layer 5 and a thin cladding layer 7. The cladding layer can be formed from the same material as layers 3 and 5. The material transition is much longer than it is thick. The thickness dC is selected so that no electromagnetic wave can propagate in the material transition. Optical modes are thus suppressed. In other words, the electrical and/or optical conductivity of the material transition 9 in FIG. 138 is effectively reduced in the horizontal direction.

The two main surfaces of the material transitions 9 and exposed surface areas 11 of the pixels P, which are exposed as a result of the removal of the material of the layer sequence, are electrically insulated and passivated by means of a respective passivation layer 13, which in particular contains silicon dioxide. The areas of the removed material of the layer sequence are also filled with a filler material 15. Finally, the two main surfaces of the pixels P are electrically contacted by means of contact layers 33, whereby these can form end contacts. Contact layers 33 can have transparent material, for example ITO, in such a way that the light generated or received by the pixels P emits through the transparent material.

The active zone 5 comprises one or more quantum wells or other structures. Their band gap is tuned to the desired wavelength of the emitted light. The maximum thickness dC is chosen such that all fundamental modes are prevented from propagating along the active zone 5 of the material transitions 9 to the next pixel P. The maximum thickness dC of an active zone 5 of a material transition 9 for this condition depends on the refractive index difference between the active zone 5 and the cladding layers 7 of the material transition 9 corresponding to a waveguide. In general, this means that the material transition should be as thin as possible. On the one hand, this makes crosstalk of optical modes more difficult, since the wave cannot propagate in the horizontal direction. On the other hand, the low maximum thickness dC makes further electrical crosstalk more difficult. The thin cladding layers 7 of the active zone 5 surrounding the active zone generally show a high surface resistance and can only carry little current. A further reduction also reduces electrical crosstalk here due to the increasing resistance.

The maximum thickness dC also depends on the refractive index and the thickness of the active zone 5. The maximum thickness dC is greater than or equal to the thickness of the active zone 5. The maximum thickness dC also depends on the distance between adjacent pixels P. The greater the distance, the greater the maximum thickness dC can be. A suggested range of the maximum thickness dC is ≤1 μm and ≥30 nm.

The layers shown in FIG. 138 have thicknesses that depend on the materials used, including the doping materials, the doping profile of the concentration versus depth, the angles of the sidewalls, the pixel size, the pixel spacing and the total array size. A lower limit for the total thickness is about 100 nm.

Suitable material systems for the pixels P are for example In(Ga,Al)As(Sb,P), SiGe, Zn(Mg,Cd)S(Se,Te), Ga(Al)N, HgCdTe. Suitable materials for contact layers 33 are metals such as Au, Ag, Ti, Pt, Pd, Cr, Rh, Al, Ni and the like, alone or as alloys with Zn, Ge, Be. This material can also be used as the filling material 15, which then serves as a bonding material in addition to the filling function. Conductive material also has possible reflective and other properties. Transparent conductive oxides such as ZnO or ITO (InSnO) can also be used as contact layers 33 for bonding and also provide a common contact for either the μ-side or the n-side of the array.

Dielectrics such as fluorides, oxides and nitrides of Ti, Ta, Hf, Zr, Nb, Al, Si, Mg can be used as transparent insulators. This material can be used for passivation layers 13. This material can also be used as the filling material 15, which then serves as an electrical insulator in addition to the filling function. Values of the refractive indices of active zone 5 and cladding layers 7 depend entirely on the materials used.

The maximum thickness dC also depends on the refractive index of the dielectric generated by the passivation layer 13 and/or the filler material 15. The smaller the refractive index difference between active zone 5 and dielectric, the greater the maximum thickness dC can be for equal crosstalk.

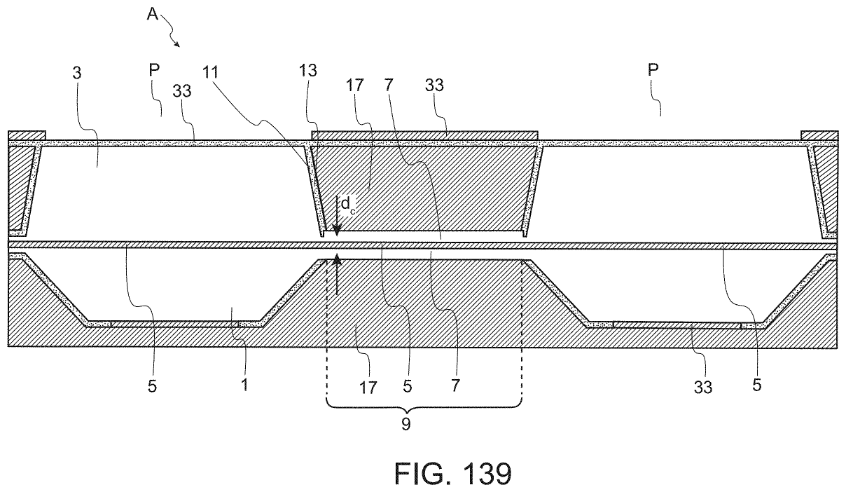

FIG. 139 shows a second embodiment of a pixel array A in a cross-section. The array A shown here in FIG. 139 differs from the array A shown in FIG. 138 in that a light-absorbing material 17 having a relatively small band gap at least partially fills the areas of the removed material of the layer sequence. Furthermore, the light-absorbing material 17 adjoins directly at the material transitions 9, since no passivation layers 13 are formed at these. Only exposed surface areas 11 of the pixels P are electrically insulated and passivated by means of a respective passivation layer 13. Their material can contain silicon dioxide, for example, so that no electrical short circuit occurs between material 3 and 17.

In FIG. 139—not shown there—alternatively only one—in FIG. 139 upper or lower—side of the material transition 9 between the two pixels P is filled by the light absorbing material 17. On the other side, for example, a filling material 15 is formed at the material transition 9, leaving the passivation layer 13 between them. By using the light-absorbing material 17, additional suppression of optical crosstalk is provided. The light-absorbing material 17 between the pixels P reduces wave guiding by absorbing the light that leaves the active zone 5 in the area of the material transitions 9. There is an attenuation of the waveguide along the material transitions 9.

Suitable light-absorbing materials 17 are metals, alloys, dielectrics or semiconductors with a smaller band gap than the band gap of the material transition 9, which initially acts as a waveguide. This means that the energy of the light is also greater, so that it is absorbed by the material 17. For example, floating eye can be used, which absorbs 50% of red wavelengths. The light-absorbing material 17 is grown at the material transitions 9, for example by CVD (chemical vapour deposition) or PVD (physical vapour deposition) by creating epitaxial layers. The light absorbing material 17 was applied or grown on the cladding layers 7.

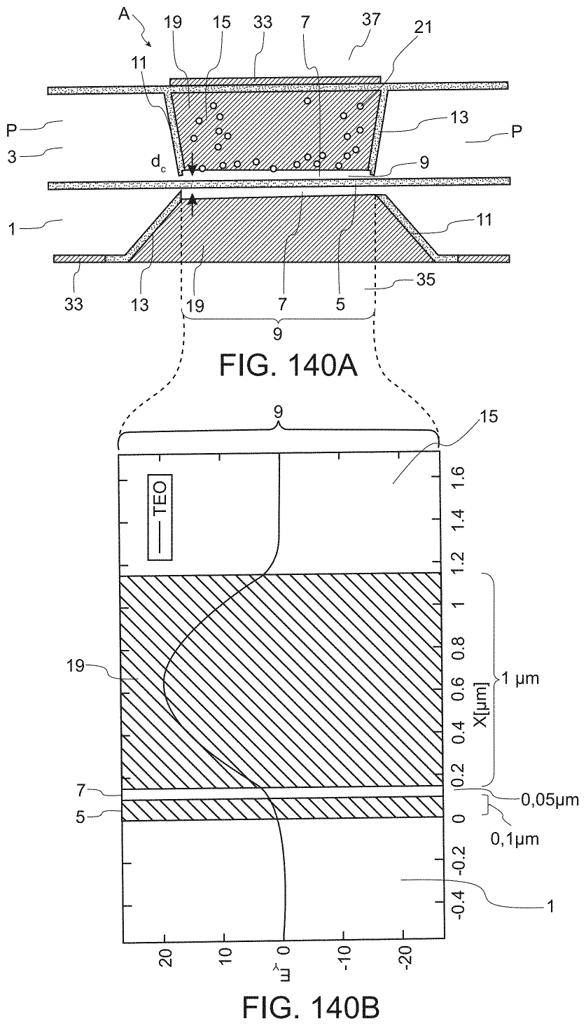

FIG. 140A shows a third embodiment of a pixel array A in a cross-section. At the locations of the material removed from the n-doped and/or from the p-doped side of the layer sequence of the pixel array, a material 19 is formed with a refractive index which is larger compared to the removed material, in particular to the doped material or a filler material 15, but which should not be greater than the refractive index of the cladding layers 7 or the active zone 5. This also attenuates the waveguide in the material transition 9. The layer sequence on the substrate 35 is finally covered by a protective top layer 37.

The material 19 with an increased refractive index is grown epitaxially at the material transitions 9, for example by means of chemical or physical vapor deposition. The application or growth takes place after the removal of the original n-doped and/or p-doped layer material between two pixels P each and after passivation of exposed surface areas 11, in particular side areas, of the pixels P by applying passivation layers 13.

The material 19 with increased refractive index was applied or grown on the cladding layers 7. No passivation layers 13 are formed at the material transitions 9. This is the area below the material transition 9. For example, GaAs as material 19 with increased refractive index can be grown on an active zone 5 of a material transition 9, which contains AlGaAs. Alternatively, the material 19 with increased refractive index is formed by diffusing or implanting a refractive index increasing material 21 into a filler material 15 up to or into the cladding layers 7. This is represented in FIG. 140A by the area above the material transition 9. Increased refractive index material 19 may be formed above the material transition 9 and/or below the material transition 9 in FIG. 140A. An area free of material 19 with a higher refractive index can be filled with a filler material 15.

FIG. 140B shows a simulation of the propagation of light in the area of the material transition of the third embodiment of a pixel array according to the proposed principle. It shows the cross section of a material transition 9 where only an upper side has been etched and filled with a material 19 with an increased refractive index. The material 19 with an increased refractive index has a refractive index equivalent to the quantum well material 5, i.e. the active zone 5 and the material 19 with increased refractive index are shown in dark grey in the diagram. The cladding layer 7 or non-etched semiconductor material of an n-doped layer 1 and a filler material 15 are shown in white.

The 0.1 μm thick layer is the active zone 5 or the area of the quantum well material. The 0.05 μm thick layer is still “residual cladding” or a remaining cladding layer 7. The 1 μm thick layer is the material 19 with the increased refractive index.

In the area of the material transition 9 between two pixels P, an active zone 5 with a refractive index of 3.5 and a layer thickness of 0.1 μm is arranged on a lower, unetched n-doped layer 1 having a refractive index of 3. On this first inner layer, a cladding layer 7 with a refractive index of 3 is formed as a second inner layer of the material transition 9 with a layer thickness of 0.05 μm. A relatively thick third inner layer of a material 19 with an increased refractive index of 3.5 and a layer thickness of 1 μm is formed thereon. The third inner layer is covered by a layer comprising a filler material 15 with a refractive index of, for example, about 3.

For a simulation on this layer structure, a vacuum light wavelength of 0.63 μm was assumed. The generated light can be TM- and/or TE-polarized. One speaks of TM-polarized light when the direction of the magnetic field is perpendicular to the plane (“plane of incidence”) defined by the vector of incidence and the surface normal (TM=transversely magnetic), and of TE-polarized light when the electric field is perpendicular to the plane of incidence (TE=transversely electric). For the simulation, FIG. 140B with the x-axis represents the value of a spatial extension x in μm. The y-axis shows the value of a y-component of an electric field strength E. FIG. 140B shows how a fundamental mode TE0 emerges from the active zone 5 and is stopped by the other optical barriers present between two pixels P above and/or below the material transition 9 acting as a waveguide. The optical barriers here are the interfaces between the layers of different refractive indices according to the layered structure of FIG. 140A described above. The fundamental mode TE0 enters the thick third inner layer of material 19 with increased refractive index and does not reach the adjacent pixel P.

In practice, a material with a higher refractive index is often also a more absorbent material, especially due to a smaller band gap.

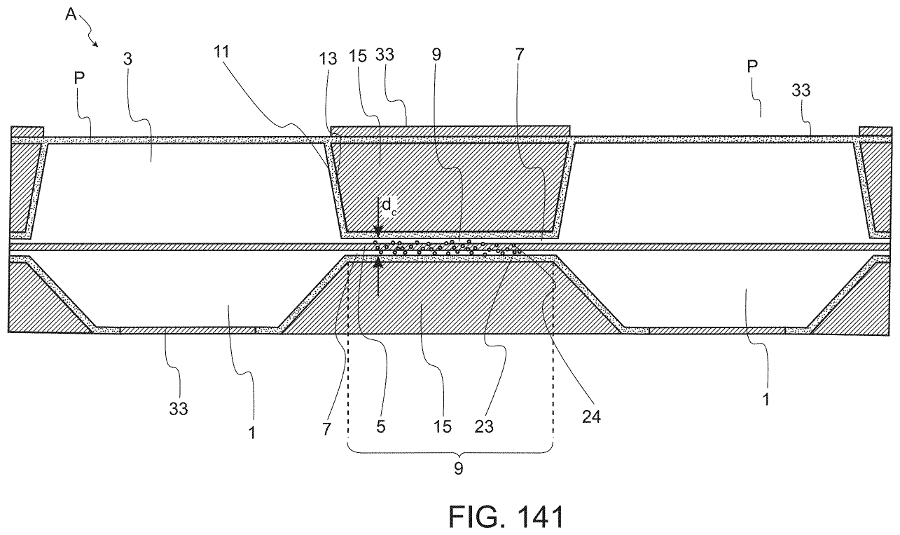

FIG. 141 shows a fourth embodiment of a pixel array A in a cross-section. Identical reference signs to the other FIGS. 141 to 140A indicate identical features in FIG. 141. In contrast to a design according to FIG. 138, here between two filler layers 15 and two passivation layers 13, additional material 23, 24 is introduced into the active zone 5 of a material transition 9, which effectively reduces electrical and/or optical conductivities of the material transition 9 acting as waveguide. The additional material is, on the one hand, a material 23, which increases light absorption in the active zone 5 of the material transition 9. Absorption in the active zone 5 between pixels P is increased by reducing the bandgap of the material of the active zone 5. For this purpose, bandgap-reducing elements are implanted or diffused into the active zone 5 of the material transition 9. In particular, dopants are diffused or implanted into the central region of the active zone 5 between pixels P. The reduction of the band gap is achieved by a so-called band gap renormalization. The greater the amount of material 23 introduced along a material transition 9, the greater the absorption of light in the active zone 5.

Alternatively or cumulatively, the additional material is, on the other hand, a material 24, which increases an electrical resistance in the active zone 5 of the material transition 9. For this purpose, elements, which increase the electrical resistance, are implanted or diffused into the active zone 5 of the material transition 9. This further increase in electrical resistance serves to reduce further electrical crosstalk from one pixel P to the adjacent pixel P. For example, to increase the electrical resistance Fe can be implanted in an active zone 5 of a material transition 9 with InGaAsP. The greater the amount of material 24 introduced along a material transition 9, the greater the increase in electrical resistance of the active zone 5 of the material transition 9 between two pixels P.

Materials 23, 24 are both diffused or implanted into the active zone 5 of a respective material transition 9 before the application of passivation layers 13.

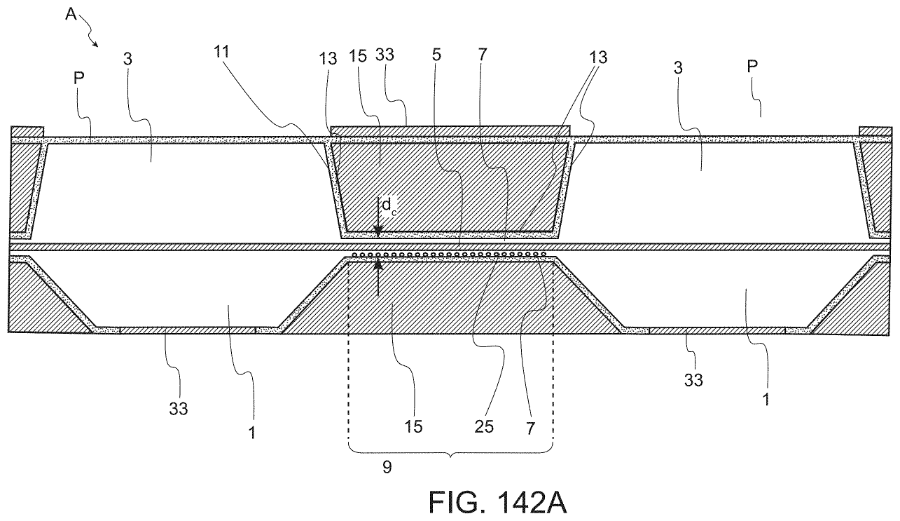

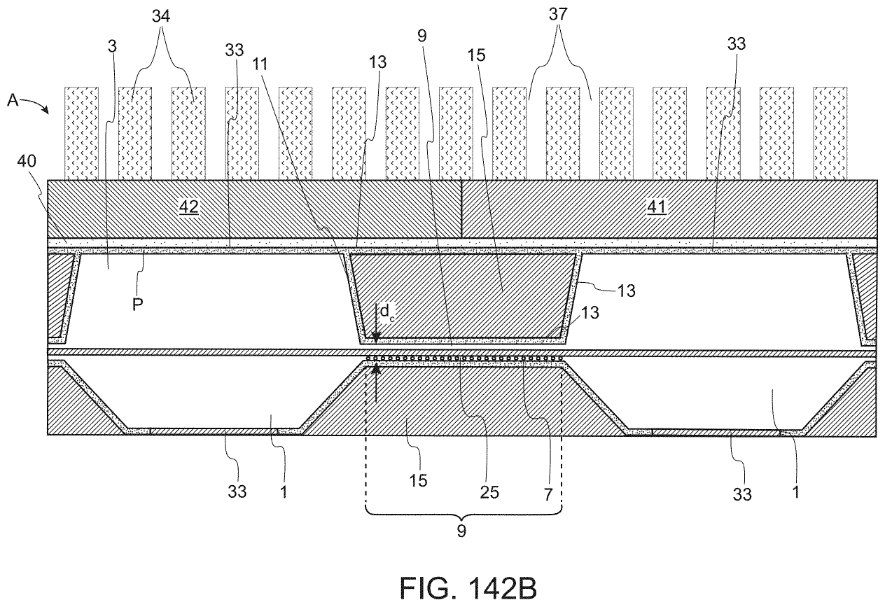

FIG. 142A shows a further example of a pixel array A in a cross-section, in which, in contrast to a structure in FIG. 138, an optical structure 25 is incorporated in the area of the material transition. The structure 25 is inserted between two filler layers 15 and two passivation layers 13 along the active zone 5 of a material transition 9. This reduces an optical conductivity of the material transition 9 acting as waveguide between two pixels P. A waveguide is reduced. Optical structures 25 can be a photonic crystal and a Bragg mirror or another dielectric structure. The structure 25 forms periodic structures of the refractive index along the material transition 9 above, below or on both sides of the active zone 5, which leads to an optical band gap and prevents the propagation of photons along the material transition.

The periodicity of the optical structures depends on the light wavelengths, the size of the optical structures, the length of the structured material transition 9 and the refractive indices of the materials used. FIG. 142A shows only one optical structure 25 on a lower side of the material transition 9, which acts as a waveguide. This optical structure 25 can also be formed on the upper side of the wave guiding material transition 9. The optical structure 25 shown in FIG. 142A is a Bragg mirror. After forming the optical structure 25, passivation layers 13 are applied.

An extension of the example in FIG. 142A is shown in FIG. 142B. A converter material 41 or 42 is applied to the surface. The converter material 41 and 42 extends to approximately the middle between two μ-LEDs. As the walls of the μ-LED are self-reflecting, the light generated in the active layer of a μ-LED is directed by the μ-LEDs towards the converter material. Light that enters the converter material from the μ-LED is converted there. Crosstalk is prevented by an optional reflective layer between the converter materials.

On the surface of the converter materials, photonic structures 34 and 37 are deposited on each pixel to direct the light. In an alternative embodiment, the photonic structure extends into the converter material or even into the semiconductor material.

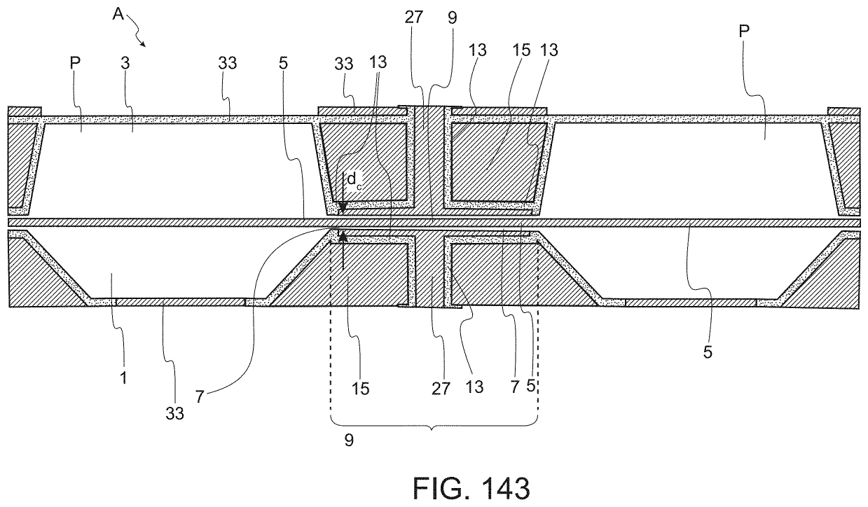

FIG. 143 shows a sixth embodiment of pixel array A in a cross-section in accordance with the invention. In contrast to an embodiment according to FIG. 139, in two filler layers 15, along the active zone 5 of a material transition 9, two additional electrical contacts 27 are introduced at both main surfaces of the material transition 9 acting as waveguide, which effectively reduces electrical and/or optical conductivities of the material transition 9 acting as waveguide between two pixels P. These opposite electrical contacts 27 apply an electrical bias to both main surfaces of a respective material transition 9 between two pixels P.

By means of the applied electrical bias voltage (Bias), a static electrical field is generated, by means of which the optical properties of the material transition 9, which initially acts as a waveguide, are changed in such a way that a waveguide along the material transition 9 is effectively reduced.

As a result of applying the electrical bias to the material transition 9 between the pixels P, which initially acts as a waveguide, an absorption of light in the waveguide is increased by means of the so-called “quantum confined Stark” effect (QCSE; limited Stark effect), as is used in an electro-absorption modulator, for example. In an electro-absorption modulator, the fundamental absorption of a semiconductor is effectively increased by applying an electric field. Accordingly, optical crosstalk between pixels P is reduced. Suitable electrical contacts 27 are conventional Schottky contacts or metal-insulator contacts. Furthermore, everything that is conventionally used for band bending without current flow is suitable.

After the two opposing electrical contacts 27 have been formed, passivation layers 13 are applied to the two opposing electrical contacts 27, in particular to their surfaces where filler material 15 is formed and which are adjacent to the pixels P. Identical reference signs to the other FIGS. 138 to 142A are shown in FIG. 143, which shows identical characteristics.

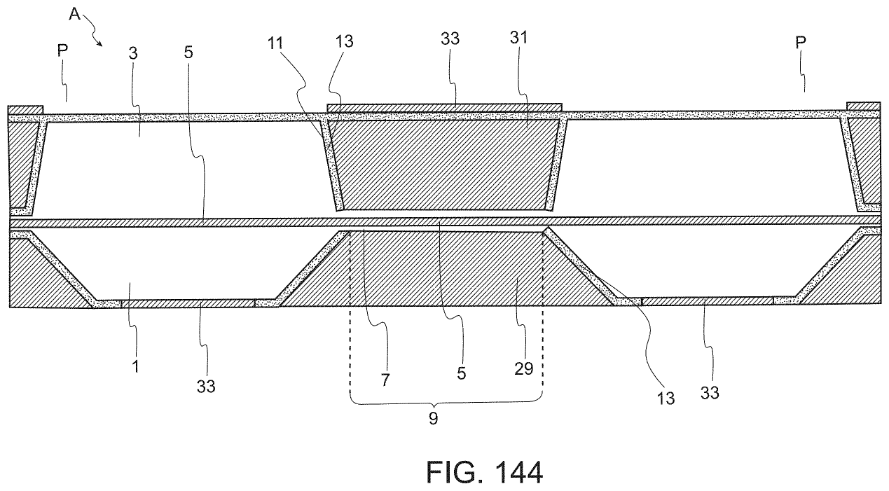

FIG. 144 shows a seventh embodiment of a pixel array A in a cross-section. In contrast to the embodiment in FIG. 143, an electric field is generated here inherently, i.e. by selecting a suitable material system. For this purpose, at least one layer of n-doped material 29 and/or p-doped material 31 is arranged on at least one of the two main surfaces of a material transition 9 in such a way that an electric field is generated by it, which is thus incorporated into the material transition 9 without further means. If only one layer of doped material is formed on one of the two main surfaces of the material transition 9 and the layer on the other main surface of the material transition 9 is undoped, a so-called depletion field is provided which is sufficient as an electric field to increase light absorption in the material transition 9. Alternatively, the electric field for increasing light absorption in the material transition 9 is generated by forming a layer of n-doped material 29 on one main surface of the material transition 9 and a layer of p-doped material 31 on the opposite main surface of the material transition 9.

The material used to provide the electric field, in particular the n-doped material 29, the p-doped material 31 and possibly the undoped material are grown epitaxially by means of CVD (chemical vapor deposition) or PVD (physical vapor deposition) in such a way that a built-in bias is provided between adjacent pixels P on the thin waveguide. For n- and μ-doping, InGaAlP can be doped with Si and Zn.

By means of the doped material 29 and/or 31, a bias is provided which has the same effect as the embodiment as shown in FIG. 143. Furthermore, the material providing the electric field is directly applied to the material transitions 9, as no passivation layers 13 are required at these. Only exposed surface areas 11 of the pixels P are electrically insulated and passivated by a respective passivation layer 13. Their material may contain silicon dioxide, for example. The pixels P are electrically connected via electrical contact layers 33.

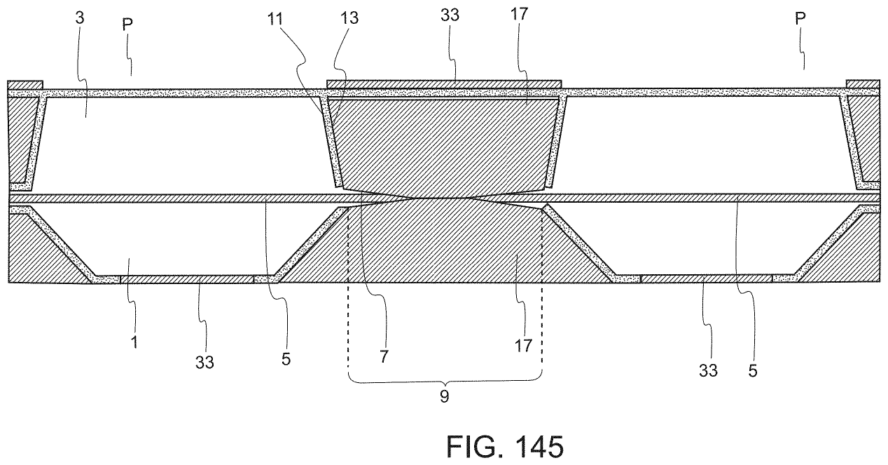

FIG. 145 shows an eighth embodiment of a pixel array A in a cross-section. In this example, the active zone 5 was etched in a controlled manner. In other words, damage to the active zone 5 or the occurrence of defects in the active zone 5 in the area of the material transition is allowed in a controlled manner. According to FIG. 145, the material transition 9 is completely interrupted in its center to the two pixels P, between which the material transition 9 is formed. At the transitions to the two pixels P, the material transition 9 is formed with a maximum thickness dC.

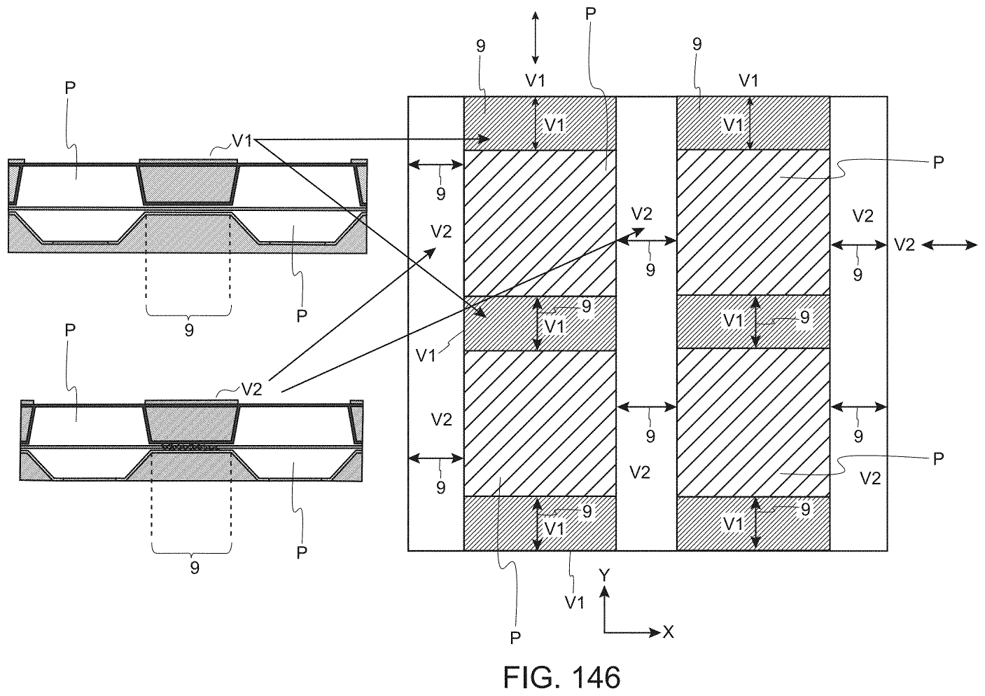

FIG. 146 shows a ninth embodiment of a pixel array A. On the left side, two different embodiments of the suppression of crosstalk between two adjacent pixels P are shown in cross section. The upper variant V1 shows the first embodiment according to FIG. 138, the lower variant V2 shows the fourth embodiment according to FIG. 142A. On the right side, a top view of four adjacent pixels P is shown.

Four adjacent pixels P are assigned to each pixel P, whereby here along an x-direction material transitions 9 are formed according to the second variant V2. Along a y-direction the material transitions 9 are formed according to the first variant V1. In principle, each material transition 9 to the other material transitions 9 can be designed differently, in accordance with the embodiments described in this application. In principle, material transitions 9 can be designed in the same way along a respective spatial direction. The material transitions 9 can be designed according to the desired patterns. The material transitions 9 along a respective spatial direction can alternate in design.

In this way, an array A according to this application includes all possible embodiments or variants as well as combinations of embodiments of material transitions 9. The plan view in FIG. 146 shows that all variants V can be combined depending on the direction, for example. This also applies to all possible shapes of pixels P, which can be round or square, especially here rectangular.

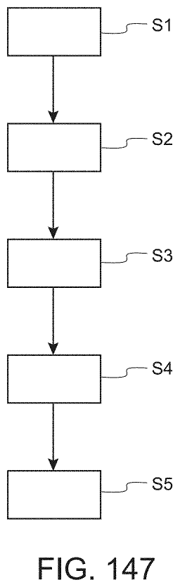

FIG. 147 shows an example of a method of manufacturing a pixel array A according to the invention. The method of manufacturing an array A of optoelectronic pixels P comprises the following steps. In a first step S1, a whole-surface layer sequence of an n-doped layer 1 and a p-doped layer 3 is generated along the array A, between which an active zone 5 is formed. Various techniques are explained and disclosed in this application.

In a second step S2, material of the layer sequence is removed between pixels P to be formed, in particular by etching, from the n-doped side and from the p-doped side. This is done in such a way that at least the active zone remains as a material transition. Likewise, thin cladding layers 7 can remain in the material transition 9 above or below or on both sides of the active zone 5. The thick dC is thus significantly reduced and optical modes cannot propagate laterally between the pixels. The higher resistance also reduces electrical crosstalk. Overall, the electrical and/or optical conductivity of the material transitions 9 is reduced.

The thickness dC is sufficiently thin, which is required according to the specifications for array A or for a desired device in terms of brightness or responsivity. The thickness in the area of the material transition depends, among other things, on the material system and the wavelength of the emitted light.

In one aspect, etching is performed from both sides up to or into the thin mantle layers 7 on each side of the active zone 5 or up to the active zone 5, in such a way that all fundamental modes are prevented from propagating along the active zone 5 to the next pixel P. The maximum thickness dc of an active zone 5 of a material transition 9 for this condition depends on the refractive index difference between the active zone 5 and the cladding layers 7 of the material transition 9 acting as a waveguide.

Reducing the maximum thickness dC results in a reduction of optical crosstalk because more light is emitted from the waveguide. A reduction of the thickness dC also means a reduction of electrical crosstalk. The thin undoped cladding layers 7 of the active zone 5, which remain between individual pixels P, can hardly carry any current. This therefore reduces electrical crosstalk.

With further steps S3 to S5, after etching, the individual pixels P and the waveguide can be covered with other materials necessary for further suppression of optical and/or electrical crosstalk outside the waveguide. In step S3, the exposed main surfaces of the material transitions 9 and exposed surface areas 11 of the pixels P are electrically insulated and passivated by means of a respective passivation layer 13, in particular comprising silicon dioxide. The electrical insulation and passivation of the exposed main surfaces of the material transitions 9 can be omitted, depending on which measure is used in the fourth step S4 to reduce crosstalk.

In a fourth step S4, from the n-doped side and/or from the p-doped side, the removed material is at least partially replaced, e.g. by a filler material 15. In step S5, contact layers 33 are applied to the main surfaces of the Pixel P and thus the structure is electrically contacted. According to one design, steps S1 to S5 are first performed for one main surface of the array and then, after a substrate change, for the other main surface of the array.

To reduce further optical and/or electrical crosstalk, further measures can be taken in the fourth step S4 cumulatively to form the material transitions 9 with the maximum thickness dC. Some of these are listed here as examples, others are described above for the various embodiment. For example, from the n-doped side and/or the p-doped side, areas of the removed material can be filled with light-absorbing material 17 and/or with more strongly refractive material or material 19 with an increased refractive index instead of filling material 15. No passivation layer 13 is formed here at the material transitions 9.

Furthermore, in the fourth step S4, the light absorption and/or the electrical resistance of the active zone 5 can be increased alternatively or cumulatively. A passivation layer 13 should also be applied to the material transitions 9.

The application of these concepts allows the manufacturing of arrays A of optoelectronic pixels P, in particular micropixel emitter and detector arrays without etching through the active zone 5, without optical and electrical crosstalk and without performance and reliability problems compared to solutions with etched active zones.

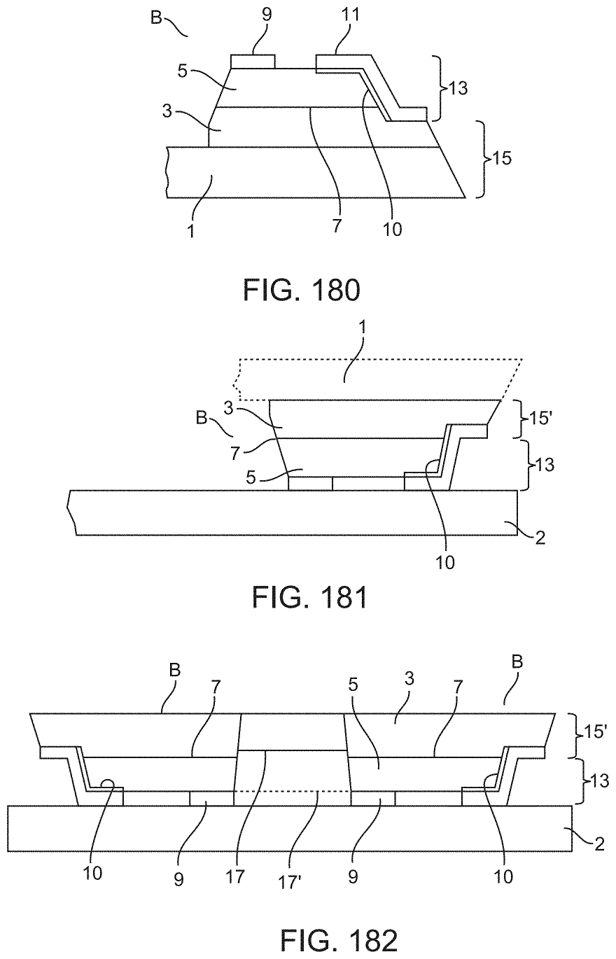

FIG. 180 shows a modular architecture of subunits of μ-LEDs. These show different horizontal μ-LEDs, which are combined in so-called base modules for the provision of μ-LED modules. The base module comprises a layer stack, which has a first layer 3 formed on a carrier or replacement carrier 1, on which an active layer 7 and on which a second layer 5 is formed. A first contact 9 is applied to a surface area of the second layer 5 facing away from the carrier 1, and a second contact 11 is connected to a surface area of the first layer 3 facing away from the carrier 1. The second contact 11 is electrically insulated from the active layer 7 and the second layer 5 by means of a dielectric 10 and is formed to and on the surface region of the second layer 5 facing away from the carrier 1.

When manufacturing the base module, a surface area of the first layer 3 facing away from the carrier 1 must be exposed after the generation of the layer stack. This means that material of the second layer 5, the active layer 7 and partly of the first layer 3 is removed at an edge area of the layer stack.

This can be carried out, for example, by means of flank structuring of the at least one stack of layers, in particular from the side of the second layer 5, a trench being created surrounding the at least one stack of layers, in particular in a flank structuring area 13. A layer stack can also be described as a mesa structure. The trench is also referred to as a mesa trench. The flanks of a stack of layers are called mesa flanks accordingly. This structuring is carried out using appropriate masks.

In the case of edge structuring, etched areas can be coated with an insulating layer or a dielectric, especially by means of inductively coupled plasma ICP or reactive ion etching RIE, using chemical vapor deposition. The dielectric used is SiO or ZnO. The second contact 11 can have ITO (indium tin oxide) and is produced by sputtering or physical vapor deposition.

A plurality of base modules can be generated as a matrix along an X-Y plane along at least one row and along at least one column on a carrier 1. For this purpose, in addition to the flat one, a further, deep flank structuring through carrier 1 and the first layer 3 is implemented on the right edge area. Area 15 corresponds to the deep flank structuring.

In this way, one module from a matrix of a plurality of base modules can be removed from a carrier 1. The deep edge structuring can be carried out by etching, in particular dry chemical etching or plasma etching.

FIG. 181 shows an example of the embodiment of a base module B as shown in FIG. 180, arranged upside down on another carrier or end carrier 2. The further carrier or end carrier 2 can be transparent to the light emitted by the optoelectronic component. In addition, the material of carrier 1 has been removed. This can be done, for example, by grinding away or by so-called laser lift-off (LLO). The base module B is thus arranged as a flip chip on the further carrier or end carrier 2 and contacted there.

FIG. 182 shows the embodiment according to FIG. 181 with a further base module B with edge area 15′ without carrier 1. Both base modules B are oriented opposite to each other, whereby identical contacts, namely first contacts 9, are arranged adjacent to each other. Both base modules B may originally have been formed on carrier 1 in two adjacent rows of a matrix. After removing carrier 1, base modules B are arranged upside down on another carrier or end carrier 2. The two adjacent base modules B, oriented opposite to each other, have been created here as a common layer stack. In this case, the dashed line 17′ in FIG. 182 would be a surface area of the second layer 5 in the middle between the two base modules. However, to prevent crosstalk, layer 5 in the middle has been removed by structuring. After such structuring, which also cuts through the active layer, the solid line 17 shows a surface area of the first layer 3.

FIG. 183 shows the embodiment according to FIG. 182 with separate contacting of the contacts. First contacts 9 and second contacts 11 are electrically isolated and connected to corresponding contacts on the end carrier 2. A first contact 19 is electrically connected to the first contact 9 of each module and a second contact 21 is electrically connected to a second contact 11. Contacts 21 and 19 have been made in previous steps in end carriage 2. The base modules are then placed on the end carrier 2, thus creating an electrical connection.

As in the previous version, the middle area is partially removed by additional structuring. Alternatively, it can also be left in place.

FIG. 184 shows the embodiment according to FIG. 182 with common contacting of the first contacts. Second contacts 11 are electrically isolated and connected to contacts of end carrier 2. A first contact 19 applied to a surface of the end carrier 2 is electrically connected to two first contacts 9. Second contacts 21 are electrically connected separately to second contacts 11.

As in the previous version, the middle area is partially removed by additional structuring. Alternatively, it can also be left in place.

In FIGS. 182 to 184, a first layer 3, a transition layer 7 and a second layer 5 can be completely removed as a result of a deep flank structure between the two base modules B. The two base modules B can be contacted to the further carrier or end carrier 2 using flip-chip technology.

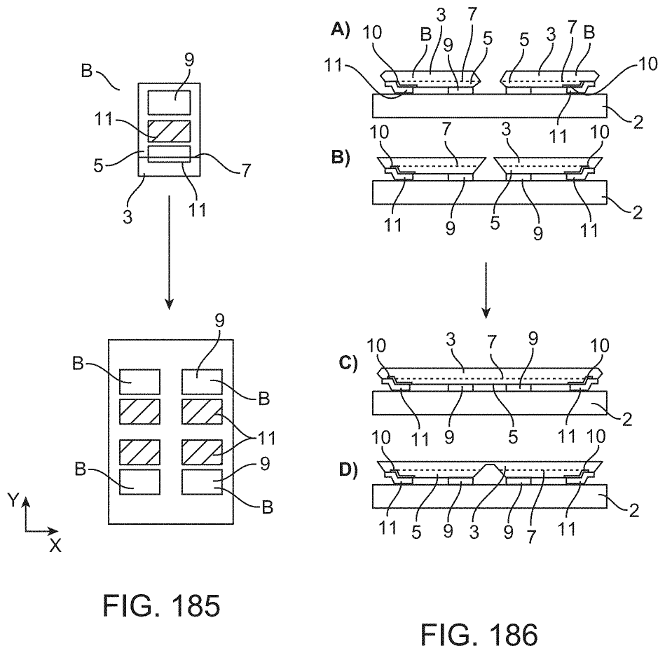

FIG. 185 above shows another example of the embodiment of a proposed base module B of a single μ-LED to provide a μ-LED module with two rows and two columns of base modules B as shown below. The base module B shown above can be provided here on a carrier 1 but also without a carrier. In this top view, a first contact 9 and a second contact 11 are visible, and in addition, the first layer 3, the transition layer 7 and the second layer 5 are shown.

As shown in FIG. 185 below, four base modules B have been grouped together to form a μ-LED module. Already on carrier 1, this matrix with two rows and two columns in an X-Y plane may have been selected. When producing adjacent rows on carrier 1, the base modules B of a row can be oriented in the same way. Here, the lower row has base modules B, which are arranged opposite to the upper base modules B. The μ-LED module shown in FIG. 185 below can still be arranged on the not shown carrier 1 after a flat edge structuring. It is grouped into the rectangular LED module by selecting a release area. This is extracted by means of a deep edge structuring along a rectangle surrounding the μ-LED module. The resulting 2×2 (two rows by two columns) μ-LED module comprises a width of approximately 20 micrometers and a length of approximately 30 micrometers.

FIGS. 186A to 186D show four cross-sections of two oppositely oriented base modules B, which are arranged upside down, i.e. as flip chips on another carrier or end carrier 2. A base module B can have a width of approximately 10 micrometers and a length of 15 micrometers. Depending on the masking during mesa etching, especially to provide a shallow edge structuring, precursors of μ-LED modules can be created, which can subsequently be removed from a carrier, especially carrier 1, to or as a light emitting diode module, especially by means of a deep edge structuring. Reference symbol 10 designates a dielectric.

According to FIG. 186A, two oppositely oriented individual base modules B are arranged adjacent to each other. Their first contacts 9 are in contact with each other, but do not touch each other. The cross section according to FIG. 186A shows that a flat flank structure was brought out from the side of the second layer 5. This creates a shallow trench that runs around a respective base module B or a respective layer stack. A deep flank structuring was led out from the side of the first layer 3 so that the individual base modules are separated. In this way, several base modules still connected to each other are first placed on the end carrier 2 and then separated from the side 3 by means of the flank structuring. The original carrier 1 was removed.

According to FIG. 186B, two oppositely oriented individual base modules B are also arranged adjacent to each other. Their first contacts 9 are in contact with each other, but do not touch each other. The cross-section according to FIG. 186B shows that a shallow flank structuring of the layer stacks was carried out from the side of the second layer 5. In contrast to FIG. 186A, a deep flank structuring of the layer stacks was carried out from the side of the second layer 5, i.e. from the same side as the shallow flank structuring. The original carrier 1 was removed.

FIG. 186C shows an intermediate step. After that, two oppositely oriented base modules B are arranged, which are created together as one piece. Their first contacts 9 are adjacent to each other. A common layer stack of two adjacent base modules oriented in opposite directions to one another is produced, with a first layer 3, a transition layer 7 and a second layer 5 each being produced as a unit along the end carrier 2. The cross section according to FIG. 186C shows that a shallow flank structuring of the layer stack was performed from the side of the second layer 5, with only the edge areas of the two second contacts 11 having a shallow flank structuring. The area between the first two contacts 9 is not flank structured, i.e. the second layer 5 there remains unprocessed. After contacting, a deep edge structuring of the layer stack is carried out here as shown in FIG. 186A from the side of the first layer 3 and the modules are separated (not shown). The original carrier 1 has been removed.

According to FIG. 186D, two oppositely oriented base modules B are also arranged, which were created as one piece. Their first contacts 9 are adjacent to each other. A common layer stack of two adjacent base modules oriented in opposite directions to each other has been produced, whereby a first layer 3 has been produced as one unit along the end carrier 2. The cross-section shown in FIG. 186D shows that a shallow flank pattern has been created on the stack of layers from the side of the second layer 5, creating a shallow trench around each base module B. In particular, the area between the two first contacts 9 is flank structured, i.e. the second layer 5 there and the transition layer 7 as well as part of the first layer 3 have been removed there as well as in the edge area of the second contacts 11. A deep flank structuring of the stack of layers was carried out here, as in FIG. 186B, from the side of the second layer 5. Only a small ridge remains in the figure, but this can still be separated if necessary.

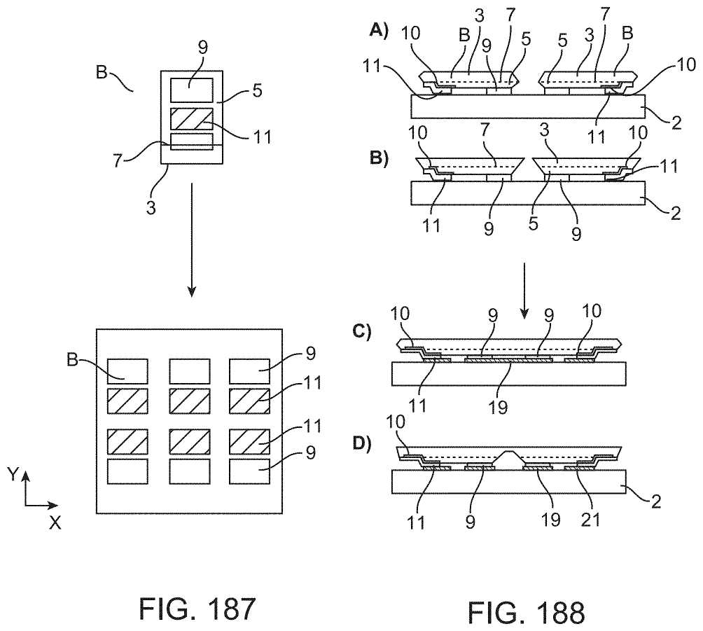

FIG. 187 shows a further illustration of an embodiment of a proposed base module B to provide a μ-LED module with two rows and three columns (2×3) of base modules B, as shown below the base module B shown above can be provided here on a carrier 1, but also without a carrier. In this plan view, a first contact 9 and a second contact 11 are shown, as well as the first layer 3, the transition layer 7 and the second layer 5 are visible.

According to FIG. 187 below, six base modules B are grouped together to form a μ-LED module. This matrix with two rows and three columns in an X-Y plane is already selected on carrier 1. In addition, when producing adjacent rows on carrier 1, the base modules B of one row are oriented in the same way. The lower row here has base modules B, which are arranged opposite to the upper base modules B. The μ-LED module shown in FIG. 187 below can still be arranged on carrier 1 after a flat edge structuring. A grouping into the rectangular LED module shown below takes place by selecting a release area. This can be detached by means of a deep edge structuring along a rectangle enclosing the μ-LED module. The generated 2×3 (two rows by three columns in an X-Y plane) μ-LED module has a width of approximately 30 micrometers and a length of approximately 30 micrometers. With this method, any combination of a matrix of base modules can be extracted and produced as a μ-LED module.

FIGS. 188A to 188D show four cross sections of two oppositely oriented base modules B of a μ-LED module as shown in the lower illustration in FIG. 187.

FIG. 188C shows, in contrast to FIG. 186C, that the first contacts 9 are electrically connected and contacted by means of a common first contact 19 created on the end carrier 2. The second contacts 11 are individually electrically connected to second contacts 21 on the end carrier.

FIG. 188D shows, in contrast to FIG. 186D, that first contacts 9 are individually connected to first contacts 19 and second contacts 11 are individually connected to second contacts 21 of the end carrier 2.

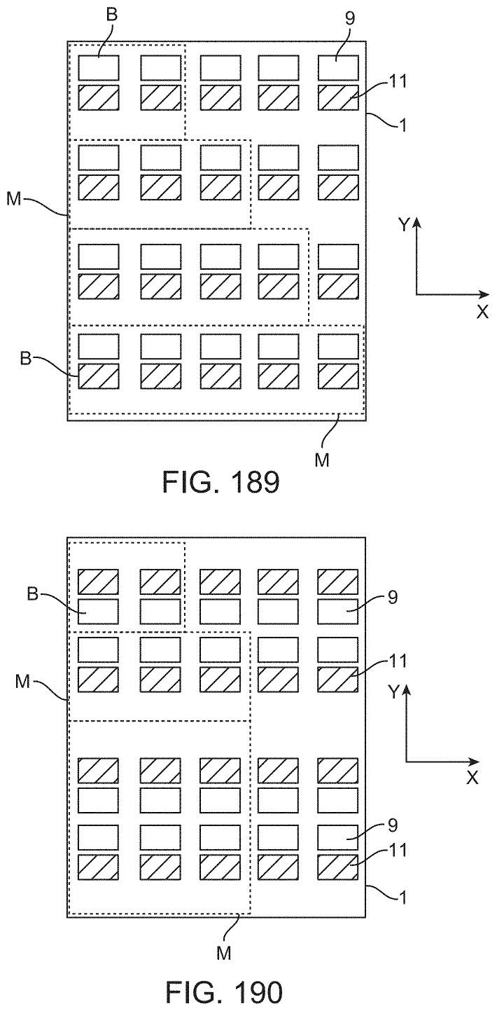

FIG. 189 shows a top view of a matrix of a carrier (wafer or carrier 1) with groupings in an X-Y plane, which has base modules B. The base modules B are all originally generated on a carrier, in particular carrier 1, in the same orientation. There was no rotation or rotation of base modules B. A generated μ-LED module only comprises one base module B in a Y-direction and is therefore single-line. Any number of base modules can be provided in an X direction. In FIG. 189 base modules B have been grouped into four μ-LED arrays or μ-LED modules M.

FIG. 190 shows a top view of a matrix of a carrier (wafer or carrier 1) with other groupings, which comprises base modules B. Here, the base modules B of two adjacent rows are oriented opposite to each other by rotating the base modules B of one of these rows. The dotted lines represent the rectangles of the μ-LED modules M still to be separated. FIG. 190 shows μ-LED modules M with one or two rows along a Y-direction, whereby the number of columns in the X-direction can be arbitrary.

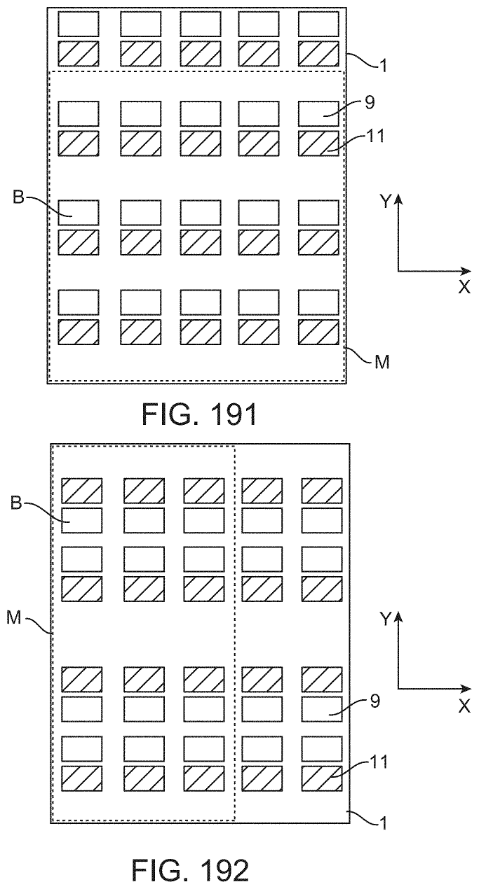

FIG. 191 shows another top view of a further matrix of a carrier, in particular a carrier 1 or wafer, with a further grouping, which comprises base modules B. This grouping creates a rectangular μ-LED module M in an X-Y plane, which comprises three rows and five columns. The μ-LED module M thus has 15 base modules B, which are evenly distributed in the rectangle. The base modules B are equally spaced along one row. The rows are also equally spaced. All base modules B have the same orientation.

FIG. 192 shows a further top view of a further matrix of a carrier, in particular a carrier 1 or wafer, with a further grouping, which comprises base modules B. This grouping creates a rectangular μ-LED module M in an X-Y plane, which has four rows and three columns. The μ-LED module M thus comprises 12 base modules B, which are evenly distributed in the rectangle. The base modules B are equally spaced along one row. The base modules B comprise two pairs of lines, whereby in one pair of lines the base modules B of both lines are oriented opposite to each other and are equally spaced apart. The distances between the pairs of lines can be different from the distances between the lines in a pair of lines. In this way, a chip cluster of μ-LEDs can be formed on a carrier 1 or wafer. The result is a modular μ-LED architecture.

The manufactured μ-LED modules M can be electrically contacted by means of flip-chip technology and integrated into μ-LED displays, for example. Base modules B can be electrically connected in series or in parallel.

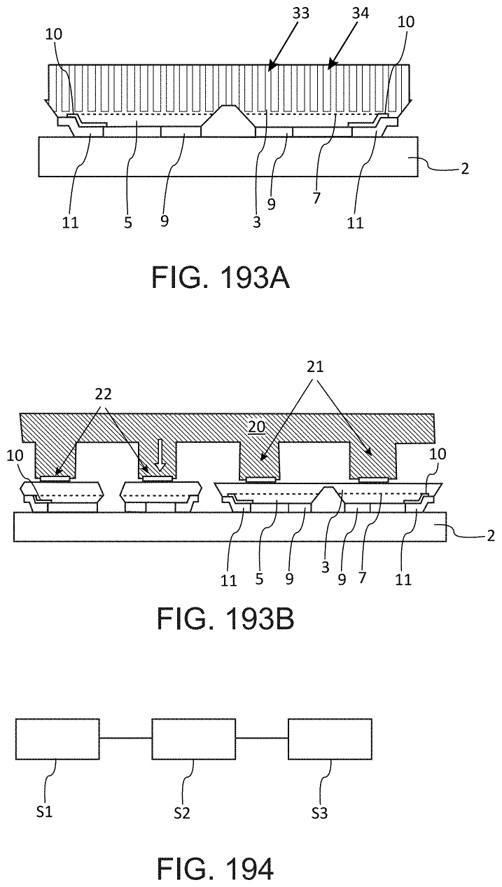

FIG. 193A shows an embodiment in which the μ-LED module was structured either after the intermediate transfer step or before on the light emission side. Several periodically arranged holes were etched into the semiconductor layer facing the light emission side, which can be described as so-called negative pillars or columns. This result in a periodic variation of the refractive index, since the surrounding semiconductor material comprises a higher refractive index than the holes filled with air. In this embodiment, the depth of the periodic structure reaches approximately to the active region, but is at least in the order of one wavelength of the light to be emitted. In this embodiment, the holes in the semiconductor material are not filled. However, it can be useful to fill them with a material with a different refractive index in order to achieve the desired optical properties on the one hand and to achieve a planar surface on the other.

The μ-LED modules can be transferred to a backplane after deep edge structuring as well as after a complete etching. The defined size of the μ-LEDs from the combined base modules is particularly suitable for this, as it defines the distances in a fixed manner. In addition, a class of stamps can possibly be used to transfer modules of different sizes. FIG. 193B illustrates an example of such a transfer process with a stamp, as described in more detail in this application. Stamp 20 has several cushions 21 and 22, spaced at fixed intervals, each of which can be charged with a surface tension or surface charge, as described in this application. The distances between the cushions correspond to the size of the individual base modules of each base module.

If a base module or μ-LED module is to be removed from the composite and transferred, the stamp generates a potential on its side facing the module so that it adheres to the cushion. The adhesive force is determined by the charge or voltage of a cushion. In this respect, larger modules can also be transferred, provided that the electrostatic force generated by the cushions is sufficient.

FIG. 194 shows an example of a proposed method for the manufacture of light emitting diode modules. In a first step S1, at least one layer stack providing the base module is created. The stack comprises a first layer formed on a carrier 1, on which an active layer and a second layer are applied. The active layer can comprise a quantum well or similar.

In a second step S2, a surface area of the first layer facing away from substrate 1 is exposed. Finally, in a third step, a first contact is applied to a surface area of the second layer facing away from carrier 1. In addition, a second contact is created on the surface area of the first layer facing away from carrier 1 and exposed. The second contact is electrically insulated from the transition layer and the second layer by means of a dielectric and runs on the surface area of the second layer facing away from carrier 1.

In this way, any number of base modules can be generated as a matrix on a wafer or carrier 1, whereby the base modules can be grouped into μ-LED modules and then separated. LED modules preferably have a rectangular or square shape in an X-Y plane of the matrix. In this plane, base modules can be arranged regularly in the rows and columns with equal spacing. The base modules are preferably generated and arranged evenly distributed along the matrix over a wafer, carrier or replacement carrier 1.

The manufacturing process shown here is greatly simplified. In fact, a large number of the techniques described here can also be used. For example, each base module can have a current constriction by doping the change in band structure accordingly. Since the base modules are separated if necessary, it is also advisable to change the band gap of the material system and the active layer at the possible predetermined breaking points by quantum well intermixing or other measures. This reduces non-radiative recombination at possible edge defects, since the charge carriers are repelled by the changed potential of the band structure. The manufactured μ-LED modules can still be structured in the surface to improve the radiation characteristics. This makes it possible to apply a photonic crystal or a converter layer to larger modules or modules of different colors. Each μ-LED module can also be equipped with its own control unit, which has already been implemented in the end carrier 2.

Another aspect deals with the question whether and to what extent such sub-units with sensor can be provided. As already mentioned, the manufactured and grouped modules are transferred to a target matrix, which comprises for example a backplane or similar.

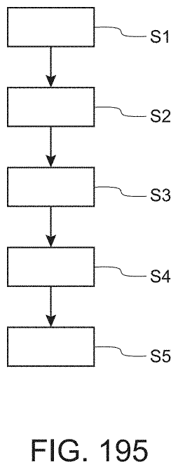

FIG. 195 shows the steps S1 to S5 of a proposed process for the production of a display with such sensors, which will be manufactured using the modules presented here.

The method is used to produce a μ-display with a full-surface target matrix of components, in particular μ-LEDs 5, arranged in rows and columns next to each other on a first carrier 3 or end carrier. The μ-LEDs in turn are part of modules.

In a first step S1, a number of μ-LEDs 5 are formed on a carrier or a replacement carrier 17 in a starting matrix 7. The spacing and size of the μ-LEDs 5 in the start matrix 7 are in a fixed, in particular integer, ratio to the spacing and size of the free spaces of the later target matrix 1 on the first carrier or end carrier 3. The μ-LEDs are formed by the methods described in this application. In particular, the wafer is prepared for deep mesa etching in order to obtain a module structure. The individual μ-LEDs later form the subpixels or also pixels on the target matrix. In this respect, the start matrix 7 can be congruent with at least part of the target matrix 1. In this way, groups of components 5 can be transferred for this part from the replacement carrier 17 to the final carrier 3. Correspondingly, the replacement carrier with the μ-LEDS formed on it can be at least partially congruent with the end carrier in terms of size and spacing.

In a second step S2, the μ-LEDs 5 are grouped to a number of modules 9 on the replacement carrier 17, especially by means of deep mesa etching.

In a subsequent step S3, the modules 9 structured in this way are lifted off the replacement carrier 17, in particular by means of laser lift-off or a mechanical or chemical process, and then transferred as modules to the final carrier 3 and thus to the target matrix 1. Contact areas of the modules contacting the μ-LEDs 5 are configured in such a way that they correspond to contact areas of the target matrix after the transfer. In other words, for at least a partial area of the final carrier 3 and thus the target matrix 1, the modules and the μ-LEDs are arranged with their contact areas on the replacement carrier 17 in rows and columns next to each other in such a way that the distances between the μ-LEDs 5 on the replacement carrier 17 are equal to the distances between the μ-LEDs 5 on the target matrix 1 of the final carrier 3.

In the fourth step S4, the modules 9 are positioned and electrically connected to the primary end carrier 3 in the target matrix 1 in such a way that a number of unoccupied positions 11 remain in this matrix. For this purpose, the modules themselves may be unevenly designed, so that, for example, one module is missing. Alternatively, the modules can also be transferred to the target matrix in such a way that some positions, for example rows or columns, remain unoccupied.

In a fifth step S5, at least one sensor element 13 is positioned and electrically connected at least partially at each of the unoccupied positions 11.

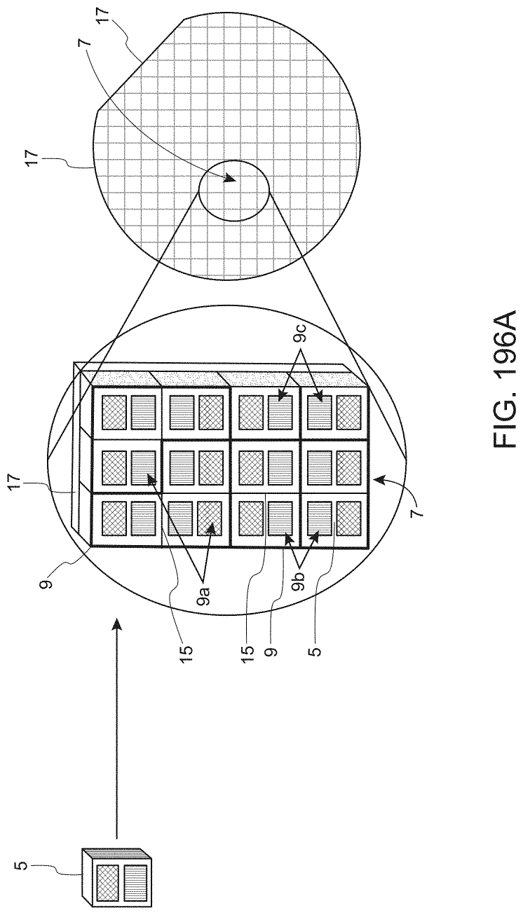

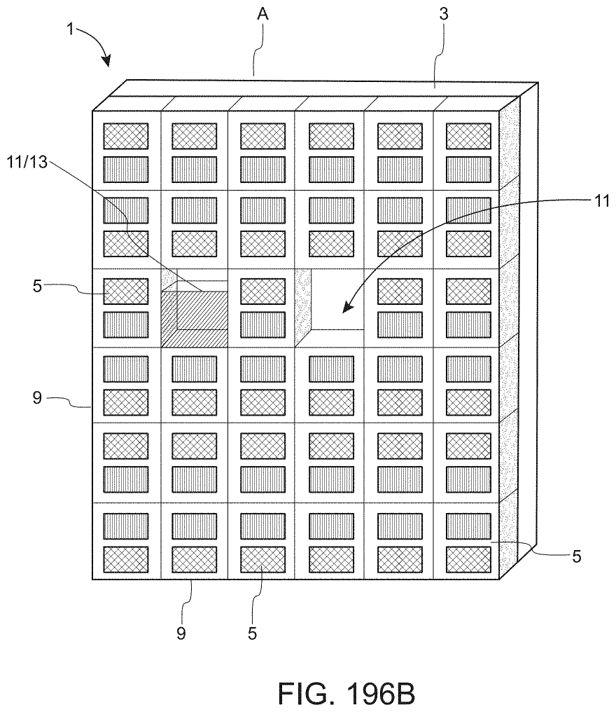

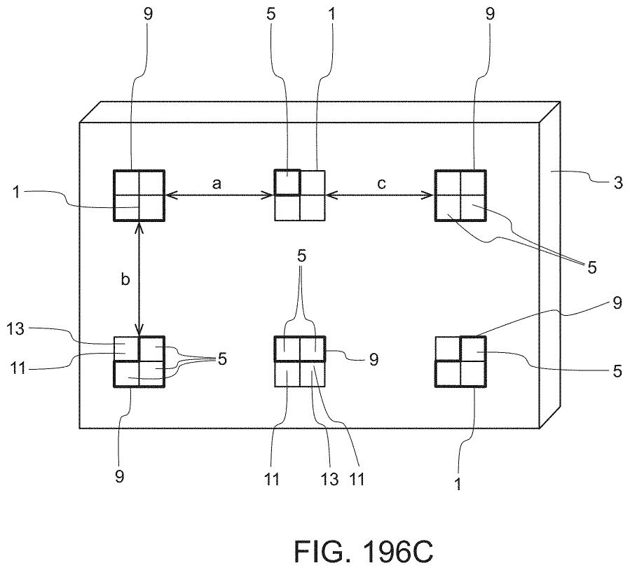

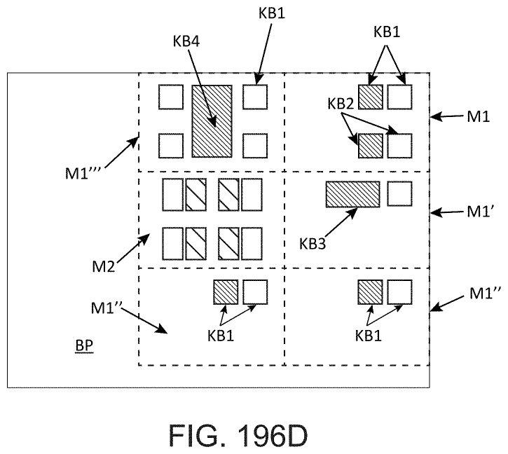

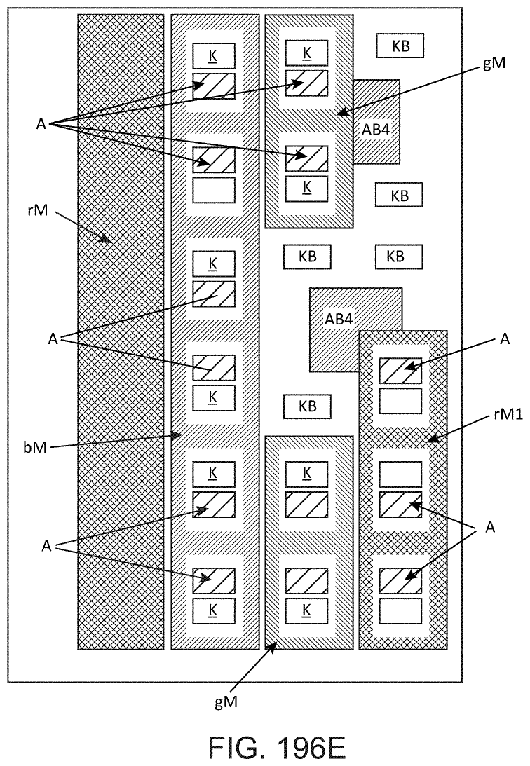

FIG. 196A shows a diagram to illustrate the different aspects and differences between μ-LED, module and the replacement carrier. Replacement carrier 17 comprises a sapphire substrate on which various semiconductor layers, including at least one active layer, have been deposited in several steps disclosed in this application. A starting matrix 7 of μ-LEDs is created on the replacement carrier 17 by means of shallow etching. The μ-LEDs 5 are still interconnected and have only electrically mutually insulating areas created by means of shallow etching, so that they can be individually addressed. Such methods are disclosed in this application. In one aspect, vertical μ-LEDs are formed in which a first contact faces the substrate and a second contact faces away from the substrate. In addition to this embodiment, μ-LEDs can also be produced which are designed as flip-chips with their contacts next to each other on the same side. In the present example, a μ-LED 5 is designed as a flip chip, with the two contacts facing away from the substrate and electrically insulated from each other. The μ-LED 5 forms a cuboid element. The μ-LED 5 represents a basic element and comprises, for example, a width of approximately 10 μm and a length of approximately 15 μm. A component 5 is shown as a base unit on the left side of FIG. 196A.

By means of an additional, this time deep mesa etching—this corresponds to the second step S2 of FIG. 195—the μ-LED 5 are grouped to modules 9. In the middle of FIG. 196A, a start matrix 7 of twelve components 5 is created on the replacement carrier 17 by means of a shallow etching, whereby the μ-LEDs 5 are arranged along common sides 15 in four rows and three columns next to each other. The thick edges in FIG. 196A center surround modules 9 grouped in this way, which can combine a plurality of components 5. In this way, two modules 9a are created, each grouping together three μ-LED 5. Furthermore, two modules 9b with two μ-LEDS each and two modules 9c with one μ-LED each are created.

FIG. 196B shows an illustration of the modules and μ-LEDs after transfer to the final carrier 3. 6 columns and rows can be seen on the final carrier 3, whereby the number of columns and rows can of course be chosen at will. The module arrangement is chosen so that there is no further distance between the modules, i.e. the components are close together. However, modules are selected which do not completely fit into this matrix. For example, 2×2 modules could completely cover the end carrier shown here. However, two modules are configured in such a way that they are not designed as a 2×2 matrix but as a 2×1 matrix, i.e. they only have three μ-LEDs, so that one position 11 remains unoccupied. When positioning in the above-mentioned way, two positions 11 thus remain free, whereby the position of these in turn depends on the positioning of the respective module. The left of the two free positions is occupied by a sensor element 13. In the version shown, only one position is already occupied. In embodiments, however, the sensor element can also consist of two individual or several elements, which are then divided between the unoccupied positions.

FIG. 196B thus shows a large number of μ-LED 5, which are grouped together in the form of modules 9 and arranged on the end carrier 3. In this way, a single full-surface target matrix 1 is equipped. For a μ-display, modules 9 are designed and combined as subpixels. Modules 9 for the three different colors red, green and blue are created and arranged next to each other in such a way that they together create a pixel (picture element) as subpixels. Then the picture elements are arranged along the target matrix 1 in rows and columns. By using redundant μ-LEDs, sensor elements can also be positioned in some places instead of redundant subpixels.

FIG. 196C shows a representation of an arrangement of a large number of full-surface target matrices 1.

In contrast to FIG. 196B, a large number of full-surface individual target matrices 1 are used, each of which can also comprise a large number of modules 9 according to FIG. 196B. For a clear description of FIG. 196C, each single full-surface target matrix 1 comprise only two rows and two columns. Here, the target matrices 1 comprise the same uniform size in the area. Alternatively, the target matrices 1 can create areas of different sizes. In this way, a display device can be flexibly adapted to a particular application.

For example, in the upper left target matrix 1, a module 9 covers all the vacant positions in target matrix 1. To the right of it, only one module 9 is formed with a component 5 in target matrix 1, leaving three positions 11 unoccupied. Below this, two components 5 form a module 9, leaving two positions 11 unoccupied. A module 9 is positioned in the target matrix 1 at the bottom left, consisting of three components 5, whereby only one position 11 remains unoccupied. For example, sensor elements 13 can be formed at least partially at the unoccupied positions 11. Three of the four above-mentioned target matrices 1 can each have components 5 for one color red, green and blue and together form a picture element. This picture element can be repeated horizontally and vertically along the first carrier or end carrier 3 so that a display function can be provided. Since a homogeneous radiation of the sub-pixels is generally desired, they are preferably equipped with the same modules 9 for each color. The fourth target matrix 1 can alternatively be completely equipped with sensor elements 13.

The distances a and c for respective distances of the target matrices 1 in a row and the distance b as an example for a distance of the target matrices 1 in a column can be selected according to the desired resolution of the display. This also applies to the distances to the edges of the first carrier or end carrier 3. The distances a and b, or a and c, or b and c or a, b and c can be the same. Likewise, the distances a and b and c can be whole multiples of the spatial extension of a component 5 or the distance of the components 5 to each other.

FIG. 196D shows examples of different contact possibilities for electrical contacting of μ-LED modules on a backplane or other substrate. In M1 a contact panel M1 with two areas KB1 and KB2 is shown, which are suitable for two single base modules. The base modules can be placed on the surface individually or also in combination. Contact panel M1′ expands the contact area KB3. This allows a μ-LED module comprising two connected base modules with shallow mesa etching to be placed and controlled together. Panels M1″ are similar to Panel M1′, but only contact areas are provided for one base module. In Panel M2 a μ-LED module is shown, which is arranged above the contact areas. Panel M1″′ illustrates an area where a common connection is provided.

FIG. 196E shows a section of a partially equipped backplane or plane to illustrate some aspects of this. As already mentioned, the μ-LEDs can be manufactured as an array in rows and columns. This allows the assembly of several μ-LED modules and modules with different colors. This is shown in FIG. 196E. The section shows a red module rM in direct top view. It is manufactured from a 6×1 module according to the proposed principle and is mounted and contacted on the plane. Adjacent to the red module is a blue module bM in a kind of sectional view to illustrate the different contacts. Contacts connected together are marked with K. In this context, the term “common” should be understood to mean that these contacts have the same potential as at least some other adjacent contacts. Accordingly, a common contact area AB4 is applied on the plane. This always contacts contacts K of several base modules as shown. Further contacts Kb are used for individual control of each base module. Consequently, a total of 5 contact areas must be formed on the plane in order to control 4 base modules individually. As shown in the illustration, the jointly used contact areas can thus also be used jointly by μ-LED modules of different colors.

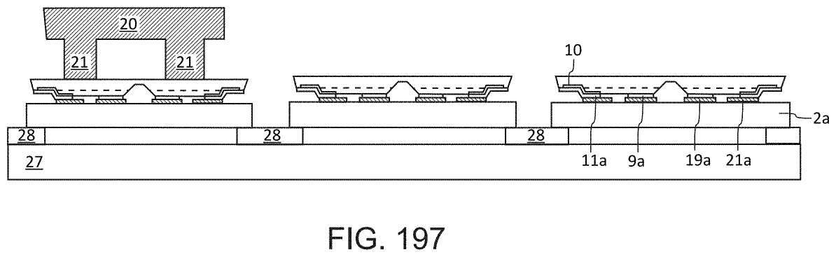

FIG. 197 finally shows another aspect of the transfer process. By periodically arranging and organizing the μ-LED modules into base modules, after a separation of μ-LED modules in the desired way, the modules can be transferred using the twofold transfer process presented in this application. FIG. 197 shows a transfer arrangement 20 with two cushions 22 whose size corresponds to the distance between the base modules.

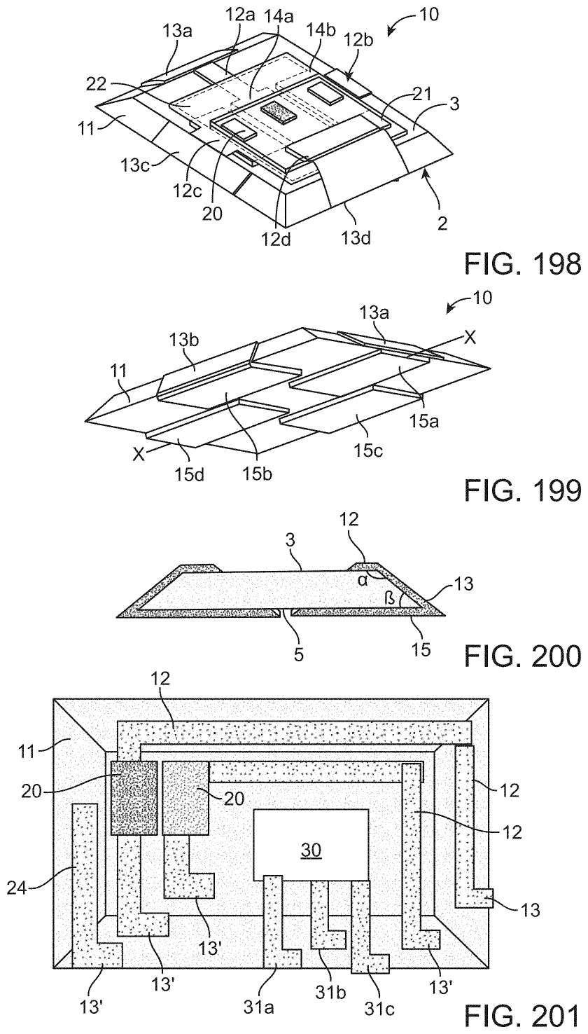

In addition to the production of monolithic pixel arrays, μ-LEDs can also be separately applied to a carrier board and subsequently contacted. FIG. 198 shows an embodiment of a pixel module for different mounts
10 with some aspects according to the proposed principle. Module 10 comprises a body 2 with a first main surface 3, a total of four side surfaces 11 and a second main surface, not shown here in this view, which forms the bottom. Body 2 is made of, for example, silicon or another semiconductor material. In some embodiments, however, the body can also be formed from another material, conductive or non-conductive. The second main surface is arranged parallel to the first main surface 3 and thus forms the underside of the module and body 2. The side surfaces are diagonal to the first main surface or upper side of the body, thus forming a truncated pyramid as shown. Thus, as shown in FIG. 200, an angle α between the first main surface and the side surfaces shows more than 90°, while the angle β between the second main surface 5 and the side surfaces is less than 90°.

Referring again to FIG. 198, the upper surface 3 comprises an insulating layer 22, which is arranged in the middle. In this example, the insulation layer does not extend completely over the first main surface, but a free area remains at the corners. Several contact pads 14a to 14c are now arranged on the insulation layer. Each contact pad 14a to 14c is connected to a contact bar 12a to 12c, the width of which is smaller than the actual contact pad as shown. The contact pads 12a to 12c are also insulated from body 2 of the module. Continuations 13a to 13c of the contact bars are now attached to the side faces 11 of the body. As contact tabs, these are in turn much wider on the side surface than the contact bars 12a to 12c. This increases the possible contact area on the side faces, allowing greater positioning tolerance and greater flexibility in contacting.

One μ-LED with vertical design is arranged on each of the contact pads 14a to 14c. These are configured to emit light in different wavelengths, for example red, green and blue light. The μ-LEDs comprise an edge length of a few μm, for example 5 μm, and are therefore slightly smaller than the contact pads 1a to 14c. The latter are also spaced apart from each other on surface 3, so that a slight offset is possible when positioning the μ-LEDs without restricting the functionality of module 10. The μ-LEDs are designed as vertical μ-LEDs, i.e. they comprise one electrical contact each on their bottom and top side. The contact on the bottom side is electrically connected to the contact pad.

On the upper side, a transparent conductive layer 21 forms a common contact pad for the three μ-LEDs and leads to a fourth contact bar 12d. This is excellent, as it forms the common connection for all three μ-LEDs. In the embodiment, it is significantly wider and thicker than the contact bars 12a to 12c. This enables visual identification, making it easier to transfer and position the μ-LED modules correctly for connection. The contact bar is electrically connected to a contact tab 13d on the last side surface.

With the contact tabs on the side surface, the module or the μ-LEDs can be electrically contacted if the module is inserted into a matrix or similar. FIG. 199 also shows another aspect, which increases the possible applications of the module. Several contact pads 15a to 15d are arranged on the underside of the module, which are electrically connected to the contact tabs 13a to 13d. The contact pads on the underside can be configured in different ways and can thus be adapted to the requirements of different applications. In the example, the contact pads 14a to 14d are substantially rectangular.

FIG. 200 shows a section through the μ-LED module along the X-X-axis in FIG. 199. The bevelled side faces are clearly visible. These include an angle α greater than 90° with the first main surface, i.e. the top of the module. For example, the angle can be between 100° and 150°, especially in the range 110° to 130°. The angle depends on the manufacturing process and the parameters used for production, as explained in detail below. Accordingly, the angle β is less than 90°. The contact tabs and bars form a continuous metallization. The thickness of the module body is in the range of 10 μm to 100 μm, the metallization has a thickness in the range of some 100 nm to approx. 10 μm. This allows the module itself to be kept quite flat, but the body itself is stable enough.

FIG. 201 shows a top view of a further embodiment of the μ-LED module according to the proposed principle, from which further aspects can be seen. In this embodiment, the module with the module body is equipped with only two μ-LEDs 20 and additionally a further semiconductor chip 30 containing integrated circuits. In this version, the μ-LEDs are configured as horizontal flip-chips, whose underside, which cannot be seen, comprises the two contacts. The μ-LEDs are mechanically and electrically connected to the contact bars 12. Each μ-LED is thus connected to two contact bars 12, some of which are guided to corresponding contact tabs on the side surfaces. In addition, some contact tabs are arranged on the top side of the module, thus forming further contact pads. The IC chip 30 is connected to contact tabs on one side of the module body via its own contact bars.

In this embodiment, the individual contact bars do not run in a straight line to the side surfaces. Instead, the embodiment shows a rewiring in which contact bars are used that run along the surface and/or the side surfaces in order to electrically connect the chip 30 as well as the components 20. The contact tabs 13′ along the side face are placed substantially parallel to the edge of the side face, i.e. they run along the side edge. This increases the effective contact area with external contacts. The module can thus also be easily offset or placed with greater placement tolerance on a matrix, display or similar.

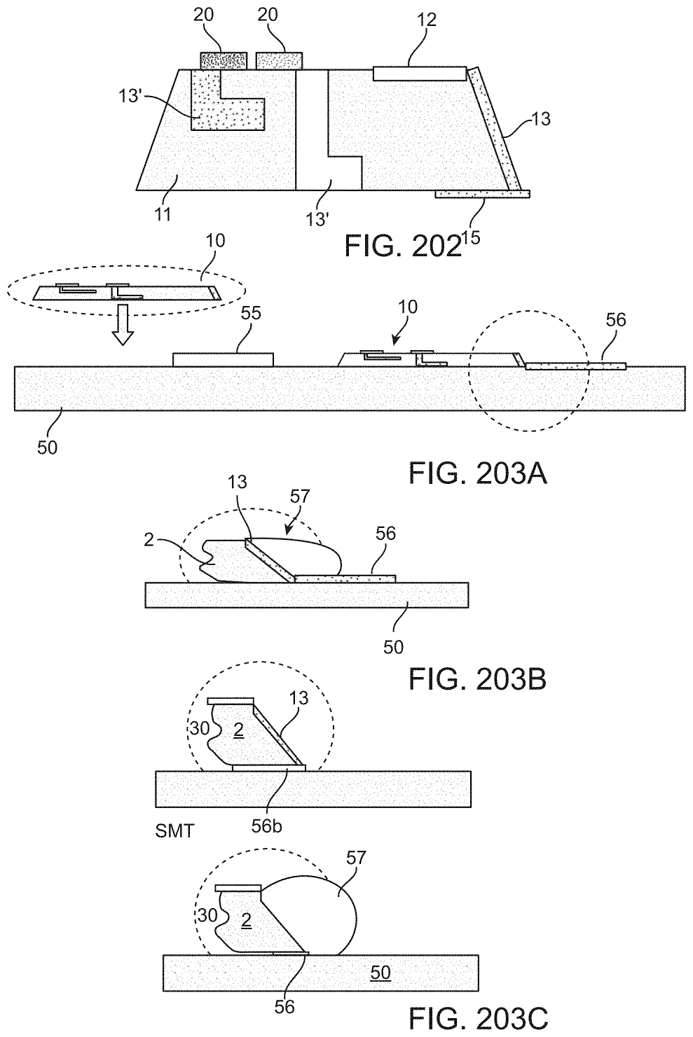

In a side view according to FIG. 202, this aspect is clarified once again. It shows a combination of contact tabs on one side surface and a contact pad 15 on the bottom of the module. The contact tabs 13′ are placed on the side face, but at different heights.

FIG. 203A shows an example of further processing of a μ-LED module according to the proposed principle. Module 10 is manufactured in a separate process and then placed on a carrier in a separate step. Carrier 50 comprises a large number of signal, control and power lines, of which line 56 is shown here as an example. In addition, carrier 50 also includes integrated circuits 55, buffers and similar. In this example, the module is placed on the carrier directly next to line 56 and fixed there. In order to achieve an electrical contact and connection between pad 56 and contact tab 13, these two are connected in a further step. This is shown in FIG. 203B. Contact pad 56 is attached to contact tab 13 by reflow or other soldering method. Material 57 is a conductive metal. This not only creates an electrically conductive connection, but also fixes the module mechanically to the carrier. In such a case, additional fastening of the module body to the carrier is not necessary.

FIG. 203C shows various contact options in this context. In the upper illustration of FIG. 203C, the module body is placed on contact pads 56b on carrier 50 in such a way that the contact pads on the underside of the module body overlap with them. A firm connection between the two pads is created by means of paste, reflow or other methods after heating. This requires an exact positioning of the module on the carrier.

In the lower illustration of FIG. 203C, a similar shape is shown as in FIG. 203B. The contact tab on the side face of module body 2 is attached to carrier 50 by soldering a wire to the carrier 50. In one case, this lead 56 on the carrier is designed so that it also partially overlaps with the contact pad on the underside of the module body. This makes the electrical connection even more reliable. At the same time, this embodiment is somewhat less sensitive to positioning fluctuations, as the lines on carrier 50 can be made larger and at the same time, a connection is improved with the additional solder. To ensure that the solder does not create a short circuit, the area 50 should be insulated apart from the contact area of line 56. However, it is advisable to configure the area around the contact of line 56 in such a way that solder also reaches the line, thus improving the electrical connection.

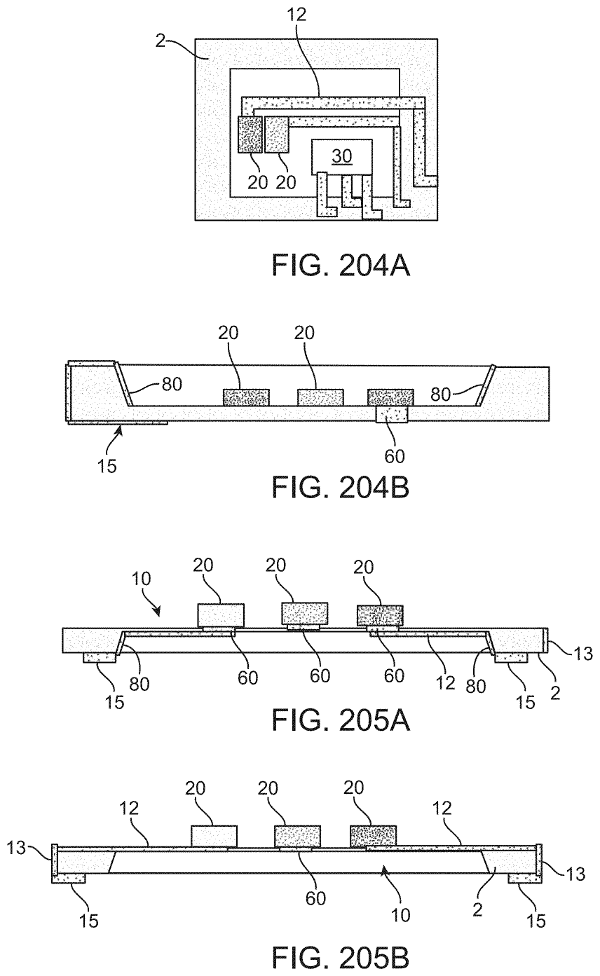

FIGS. 204A and 204B show an example of another version of a special module body. In this module, body 2 is configured with a central recess in which the components 20 and 30 are arranged. This allows the height of the module to be further reduced. In addition, the edge area of the module body can serve as a mounting for optical elements such as lenses and the like. The contact lines to the optical semiconductor components 20 and 30 run along the bottom of the recess and the side surface. As shown in FIG. 204B, the side surface of the recess is sloped. To make contact, the leads 80 are routed along the inner side face, over the main face along the outer side face, to the rear contact pad 15. In this illustration, the outer side surface is substantially vertical. However, this is not necessary, in some configurations this side surface can also be bevelled in the same way as in the previous embodiments.

The module body also has a through hole or via 60, which extends through the material of the module body in the recess. The via is filled with a metal for contacting, which is also insulated from the body. This combination of vias and contact tabs and pads creates a very flexible concept that can produce modules for a variety of technologies and connection variants in a standardized way.

FIGS. 205A and 205B continue this principle. In both FIGS. 205A and 205B, module body 2 also comprises a recess or notch, but the recess or notch is in the bottom of the module body. The μ-LEDs are located on the upper side of module body 2. In the examples, several vias 60 are provided which extend through the material of body 2 and are connected to contacts of components 20. On the side facing away from the components, i.e. in the recess, contact bars 12 are now provided which connect the via 60 in an electrically conductive manner and lead along the recess to ridges 80 on the side surfaces. The bars 80 on the inner side surface of the recess are then connected to contact pads 15 on the bottom side.

In contrast to FIG. 205A, the lower contact pads in the FIG. 205B version are contacted via the outer surfaces of the module body. Both versions can also be combined with each other, i.e. through-plated holes are provided as well as contact lines, which are electrically connected to contact tabs on the outer side surface and/or contact pads. Due to the increased surface area of the module body, a specifically adapted wiring can be carried out, the flexibility for wiring is significantly increased. The embodiment of FIGS. 205A and 205B makes it possible, when positioning the module, to provide 10 additional circuits on the carrier whose position is in the recess. This results in a higher integration density.

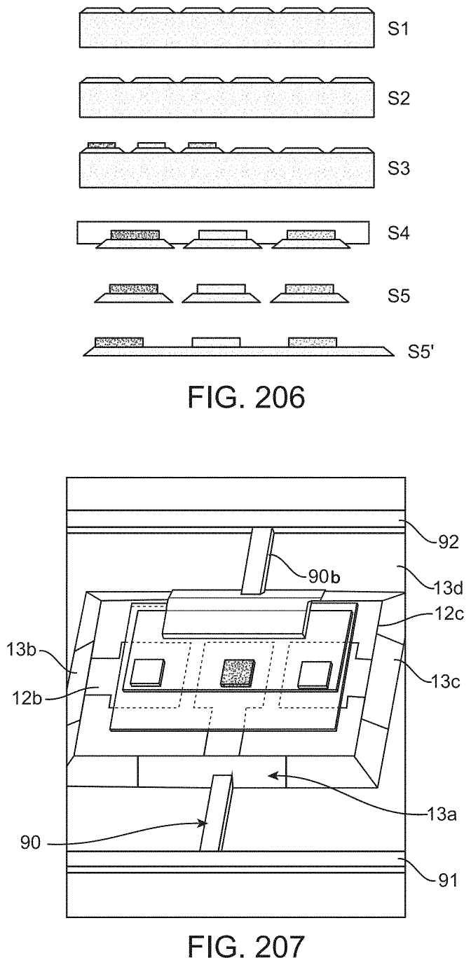

FIG. 206 shows in this context an example of a manufacturing process for a module according to the proposed principle. It should be noted in this context that various techniques disclosed in this application are used for the production. One component, however, is a structured membrane wafer as shown in step S1. This is done by providing the membrane wafer and structuring it by etching in such a way that V-shaped recesses and trenches are formed in sections. A plan view of such a structured membrane wafer is shown in FIG. 210.

In step S2, contact pads and leads or contact bars and tabs are generated on the structured membrane wafer. For this purpose, a photomask is applied and, for example, the metallic leads are formed by MOCVD. If necessary, previously formed isolated vias can also be filled with a metallization in this step. In step S3, the μ-LEDs are now placed on the contact pads and connected to them.

In step S4, the membrane wafer is rebonded onto an auxiliary carrier so that the back of the membrane wafer is exposed. Then in step S5, this is etched back to the trenches. This allows the modules to be separated so that each module now carries the intended number of μ-LEDs. In the exemplary step S5, it is a component. Alternatively, step S6 can also be carried out, in which etching is also carried out, but several μ-LEDs are now combined to provide a module, which is similar to the previous examples. There is no limit to the number of μ-LEDs and their positioning, but depends on the requirements and the later use. In a last optional step, contact pads are attached to the underside of the module body and these are electrically connected to the contact tabs on the side surface.

FIG. 207 shows a perspective view of the module of FIG. 198 after it has been placed on a carrier. The carrier includes several supply lines and control lines. A supply line 92 is connected to the common contact pad 13d via a contact bar 90b. Contact pad 13b is designed as a top contact and connects the top contacts of the respective vertical μ-LEDs to a common connector. A further supply line 91 contacts the contact pad 13a on the side surface of the module body via bar 90 and thus connects a connection of the red μ-LED. The slanted side surfaces ensure a secure electrical connection between bar 90 or 90b and the respective contact tabs. In addition, the module is attached using a soldering process, in which the bars 90 are soldered to the tabs 13a to 13d. Since the contact tabs 13a to 13d cover a relatively large part of the respective side surface, the requirements for positioning accuracy are somewhat lower.

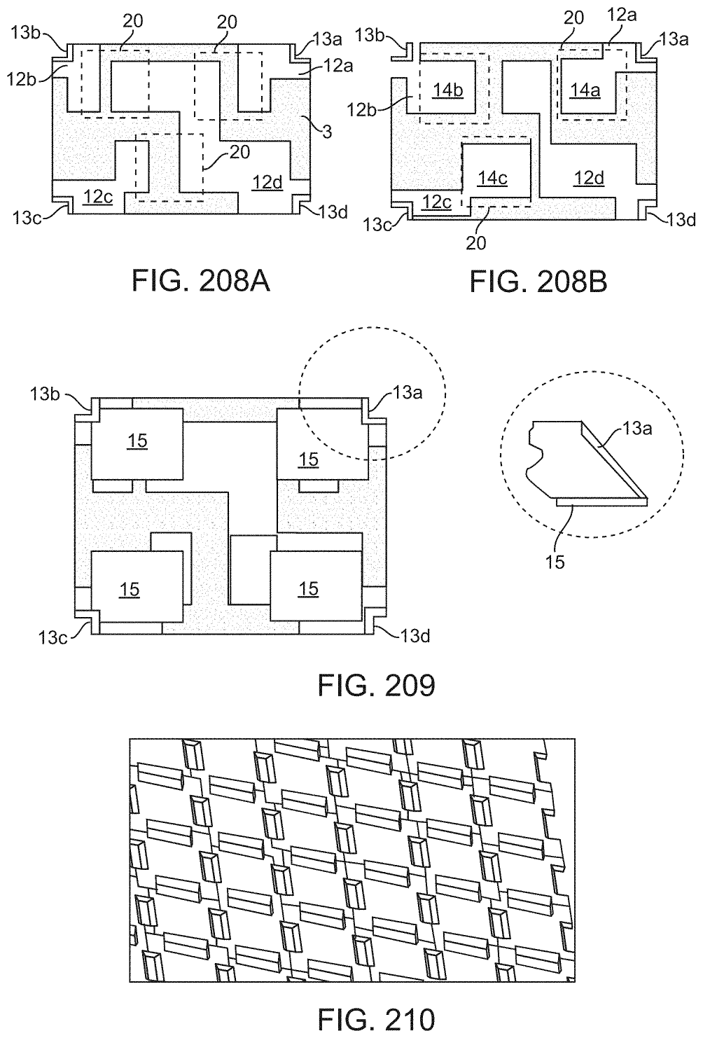

FIG. 208A shows a top view of a module with three μ-LEDs of different colors with metal bars 12a to 12d on the surface of the module body for contacting three μ-LEDs. These form a subpixel of a pixel and are designed as SMT μ-LEDs. They have a contact pad on their underside on each side and thus form horizontal LEDs. Schematically, the μ-LEDs 20 are represented by the dotted line. Their contact pads are arranged laterally. For perfect contacting they are thus connected on one side to one of the contact bar 12a to 12c. In addition, a common contact is realized with the bar 12d and the metallization there. Each of the bars 12a to 12c leads into one of the corners and to a contact tab 13a to 13c along one corner.

FIG. 208B shows an alternative embodiment in which the μ-LED components 20 are vertical μ-LEDs with one contact pad on the bottom and another on the top. In this example, the contact pads 14a to 14c are larger and have essentially the same dimensions as the μ-LED. The latter is placed on the contact pad and electrically connected to it. Contact bars 12a to 12c also connect the respective corner tabs 13a to 13c with the contact pads. The fourth common contact bar 12d is wide and serves to contact the top side of the μ-LEDs 20 via a transparent electrically conductive material.

FIG. 209 shows the underside of the version according to FIG. 208A. Contact pads 15 on the underside are contacted by the contact tabs 13a to 13d on the side surface. These are designed to have a relatively large surface area. The cut-out also shows a side view. In one design, one of the contacts is larger than the other and forms the connection for the common contact lead 12d on the top side.

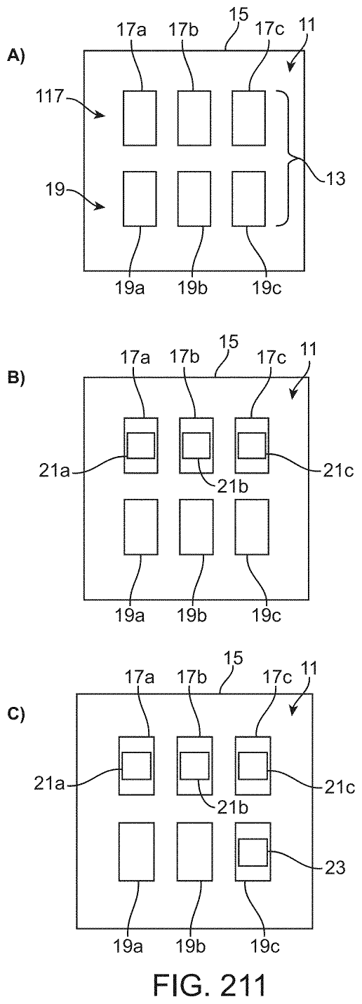

In addition to the production of a monolithic display, some applications and designs also involve the transfer and attachment of μ-LEDs to a carrier substrate and contact areas there. In order to reduce the error rate during a transfer and the following process steps, the following propose examples and designs show for a pixel array with redundant μ-LEDs positions. Those can assembled with components if needed. The FIGS. 211A to 211C show a top view of the contacts 13 provided for one pixel 11 on a substrate 15. The substrate 15 comprise several such contacts 13 for further pixels, which are arranged in field or array fashion. After an assembly with subpixels, as shown below, a pixel field or pixel array results, which can be arranged in a display, for example.

The contacts 13 can be divided into a set 17 of primary contacts 17a, 17b and 17c and a set 19 of replacement contacts 19a, 19b and 19c. Each of the contacts 13 can be equipped with a subpixel, for example a μ-LED. FIG. 211A shows the unpopulated state.

In a first assembly step the pixels 11 of the substrate 15 are assembled in such a way that for each pixel 11 the primary contacts 17a-17c are assembled with one subpixel 21a, 21b, 21c each, while the spare contacts 19a, 19b, 19c remain free. The subpixel 21a can be a μ-LED, for example, which can emit light in the red spectral range. The subpixel 21b, for example, can be a μ-LED that can emit light in the green spectral range. The subpixel 21c, for example, can be a μ-LED that can emit light in the blue spectral range. Pixel 11 thus has a set of RGB subpixels 21a-21c after the first assembly, as FIG. 211B shows.

After the first placement, the subpixels 21a-21c can be checked for errors. For example, subpixel 21c can be identified as faulty.

In a second assembly step, the replacement sub-pixel 19c can be equipped with a replacement sub-pixel 23, which can be a μ-LED emitting in the blue spectral range. The replacement subpixel 23 thus replaces the faulty subpixel 21c, which can be left on the primary contact 17c.

In the case of substrate 15 as shown in FIGS. 211A to 211C, each pixel 11 has a respective, assigned replacement contact 19a-19c for each primary contact 17a, 17b, 17c. The substrate 15 thus allows each sub-pixel 21a-21c on a primary contact 17a-17c to be replaced by a substitute sub-pixel on a substitute contact 19a-19c.

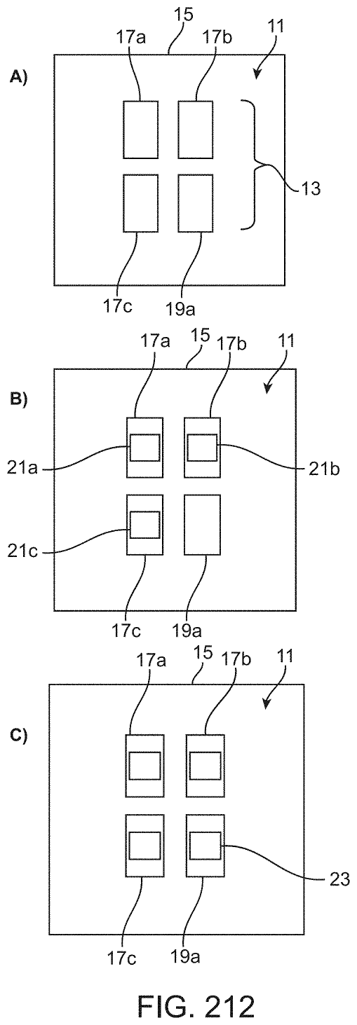

In contrast, as shown in FIGS. 212A to 207C, the substrate 15 comprises three primary contacts 17a, 17b and 17c per pixel 11 and only one replacement contact 19a, which makes it possible to replace a faulty subpixel on one of the primary contacts 207a to 207c. Additional circuitry measures shall be provided to ensure that the pixel with its subpixel on the secondary contact is addressed in the correct color.

FIG. 212A again shows a top view of the contacts 13 for a pixel 11 in unpopulated condition. As FIG. 212B shows, after a first assembly step, the primary contacts 17a-c are equipped with subpixels 21a-21c, which in turn can be μ-LEDs for the primary colors red, green and blue.

In a subsequent step, for example, subpixel 21a can be identified as faulty. As a replacement for this faulty subpixel, a replacement subpixel 23 can be placed on the replacement contact 19a as shown in FIG. 212C, which emits light of the same color as subpixel 21a if it were faultless.

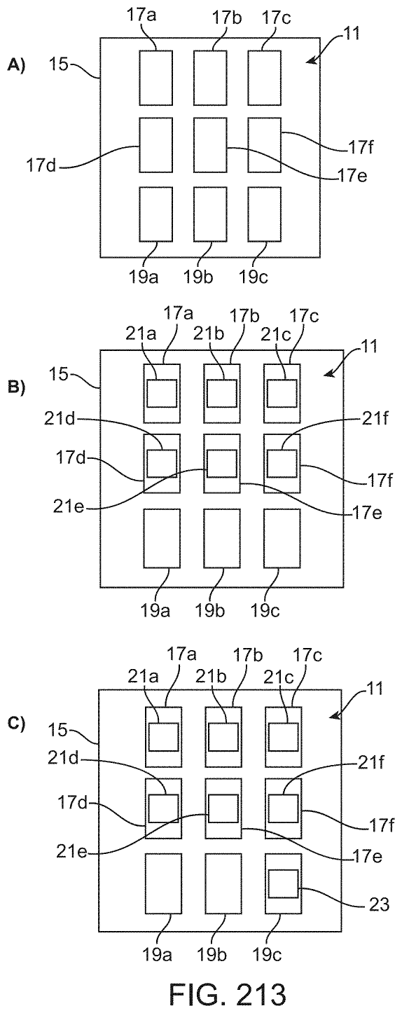

FIGS. 213A to 213C show a respective top view of a substrate 15, in which a set of primary contacts is provided for a respective pixel 11, comprising six primary contacts 17a, 17b, 17c, 17d, 17e and 17f. In addition, the substrate 15 comprise three spare contacts 19a, 19b, 19c for a respective pixel 11. FIG. 213A shows the primary and replacement contacts in an unpopulated state.

In a first assembly step as shown in FIG. 213B, the primary contacts 17a-17f are assembled with respective subpixels 21a-21f. Two subpixels of each primary color red, green and blue can be provided. This provides double redundancy for each of the primary colors red, green and blue. In addition, the provision of 2 subpixels per color allows a more precise gradation of brightness and thus an improved brightness resolution. Despite the redundancy, subpixels 21a-21f can be checked for errors. For example, if it turns out that both subpixels 21c and subpixels 21f, which emit light of the same color, are faulty, a replacement subpixel 23 can be provided on the replacement contact 19c to replace the two faulty subpixels 21c and 21f. The primary contacts 17a-17f as well as the spare contacts 19a-19c can be used for the electrical contacting of the subpixels 21a-21f, 23 arranged on them. The subpixels can be μ-LEDs in particular, as explained above.

The described manufacturing method is particularly suitable for the production of pixel fields for μ-displays, which use μ-LEDs as subpixels with horizontal flip-chip design. In this design, p- and n-contact are located on the bottom side of each μ-LED. This allows an electro-optical characterization of the individual μ-LEDs before further process steps prevent the substrate 15 from being refilled. The described manufacturing process is also advantageous for pixel arrays with vertical μ-LED chips. Depending on the test method used to find defective subpixels, the redundant replacement contacts 19a-19c can be re-equipped in different steps of the manufacturing process. Attention should be paid to a further processing option for the electrical contacting of the replenished replacement contacts 19a-19c or the replacement subpixels 23.

With regard to the electrical connection of the primary contacts 17a-17f and the replacement contacts 19a-19c there are different approaches. For example, with reference to FIG. 213, the redundant contacts 21a and 21d or 21b and 21e or 21c and 21f can be integrated into the same respective subpixel circuit. The redundancy can thus only refer to the primary contacts for the subpixels, but not necessarily to a circuit for controlling the subpixels.

The spare contacts 19a-19c can be wired in such a way that they can be controlled after an assembly instead of a subpixel identified as faulty.

The primary and replacement contacts assigned to each other can also be connected in parallel, whereby a supply line to a primary contact is disconnected if the sub-pixel arranged on it proves to be faulty and the replacement contact is equipped with a replacement sub-pixel.

As can be seen with reference to FIGS. 212A to 212C, at least one spare contact 19a may also be provided as a redundant placement facility for the sub-pixels on primary contacts 17a-17c, the spare contact 19a allowing for a placement of a spare subpixel regardless of the color of the emitted light. This redundant spare contact 19a can be connected like a fourth subpixel. A programming of the control of the replacement contact should be adapted to the population of the replacement contact 19a depending on the color of the subpixel identified as defective on one of the primary contacts 17a-17c.

In the following some concepts for measures to improve a transfer in the form of an improved mass transfer printing process are presented. Background of the process is a transport of μ-LEDs of a wafer onto a carrier surface of a display. There, the individual μ-LEDs are fixed and attached and electrically connected. On the one hand, the dimensions of the individual μ-LEDs are in the range of only a few [μm]n, on the other hand a large number of these μ-LEDs have to be transferred locally at the same time. Often several million of such microstructures have to be transferred from a large number of wafers to a common carrier surface.

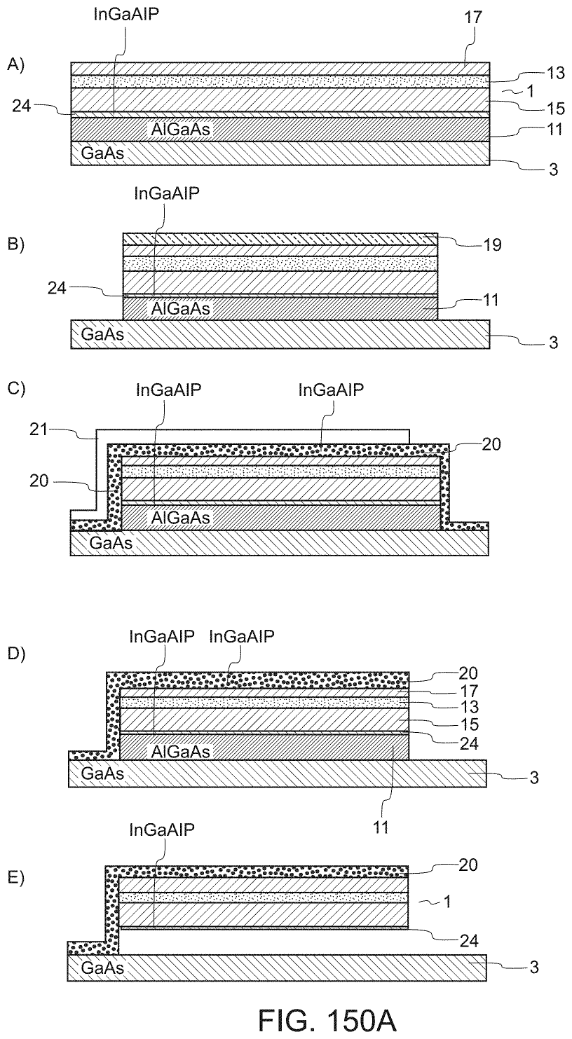

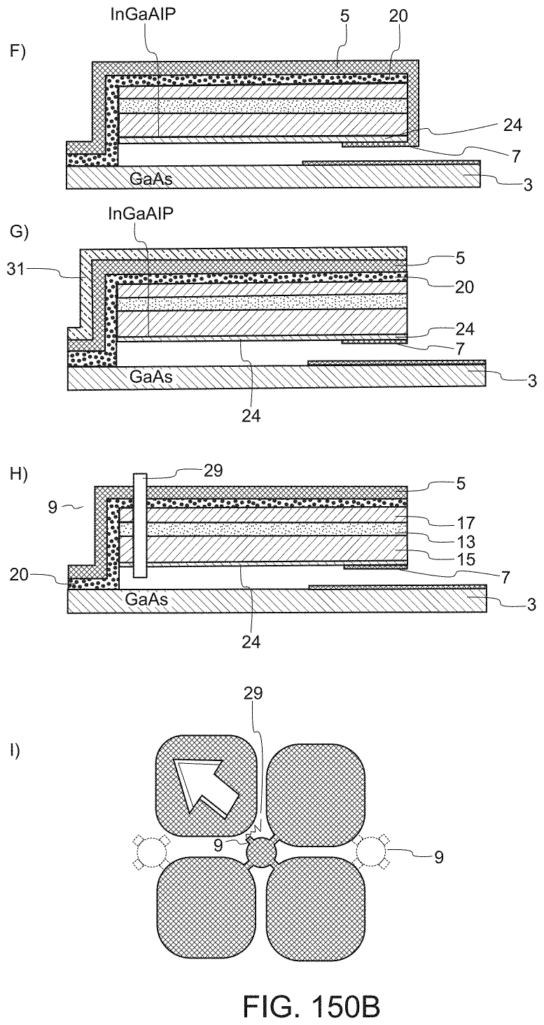

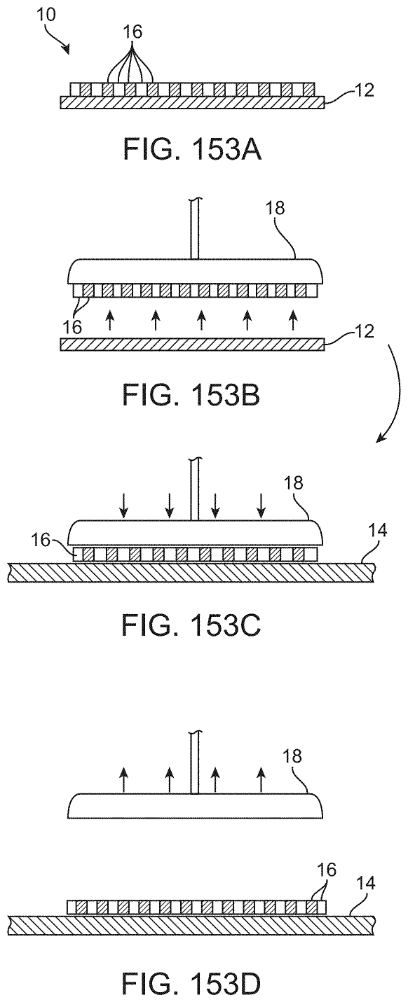

In the example shown here in FIG. 153A, a wafer 12 is initially planned on which epitaxial layers have been created by various semiconductor manufacturing processes, from which the individual μ-LEDs 16 are then formed. In some aspects, the μ-LEDs can emit different colors and wavelengths during operation. This is indicated here by the different shades. The μ-LEDs are flat at least on their underside and/or top surface to allow for easy mounting and transport, for example. As part of the manufacturing process, the μ-LEDs 16 can be mechanically separated from wafer 12. This is done by removing a so-called sacrificial layer (see for example FIGS. 150A to 150D as well as 148J, 149J and 151J), if necessary supplemented by one or more release layers.

FIG. 153B shows how an elastomer stamp 18 is moved vertically from above towards the wafer 12 and adheres to a surface of the μ-LEDs 16 by means of a suitable surface structure of the elastomer stamp 18. For example, a maximum tensile force can be proportional to a size of the surface of the μ-LED 16. Adhesion can be created by silicone materials, for example, especially by so-called PDMS elastomers. Due to the separation of the μ-LEDs 16 from wafer 12, the μ-LEDs in their plurality can be lifted off wafer 12 together, whereby they adhere to the elastomer stamp 18. This elastomer stamp 18 is now moved in a transfer movement away from wafer 12 to a carrier surface 14 of a display mounted next to it, for example. This can be done, for example, with the aid of a transfer tool, whereby the elastomer stamp 18 can be regarded as part of such a tool.

In FIG. 153C, the elastomer punch 18 is now initially located above the carrier surface 14 and is lowered onto a surface of the carrier surface 14 in a lowering movement. In this process, the underside of the μ-LEDs 16 comes into mechanical contact with the carrier surface 14. In a subsequent step, as shown in FIG. 153D, the μ-LEDs 16 are detached from the elastomer stamp 18. The elastomer stamp 18 is then moved upwards, for example to start a new transfer cycle. The μ-LEDs 16 can, for example, be permanently attached to the carrier surface 14 by an adhesive process.

The steps shown in FIGS. 153A to 153D indicate that due to the high number of μ-LEDs 16, reliable and accurate placement in the shortest possible time is desirable. Especially when the μ-LEDs 16 are picked up by the stamp 18, it may be desirable to keep the occurring forces low on the one hand and to achieve a reliable positioning and holding of the μ-LEDs 16 on wafer 12 on the other hand. In particular, avoiding fluctuations in the adhesive force or excessive adhesive forces on the wafer and/or on the stamp can bring about significant improvements here.

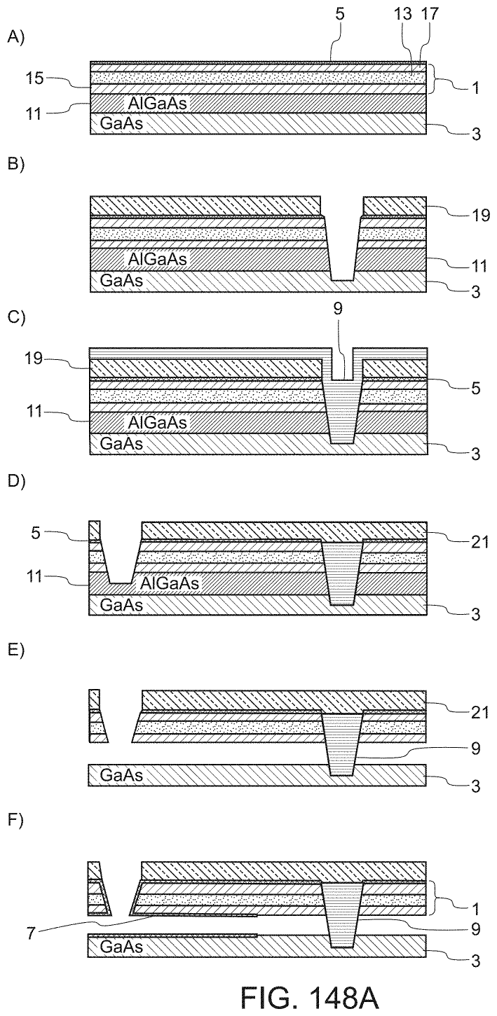

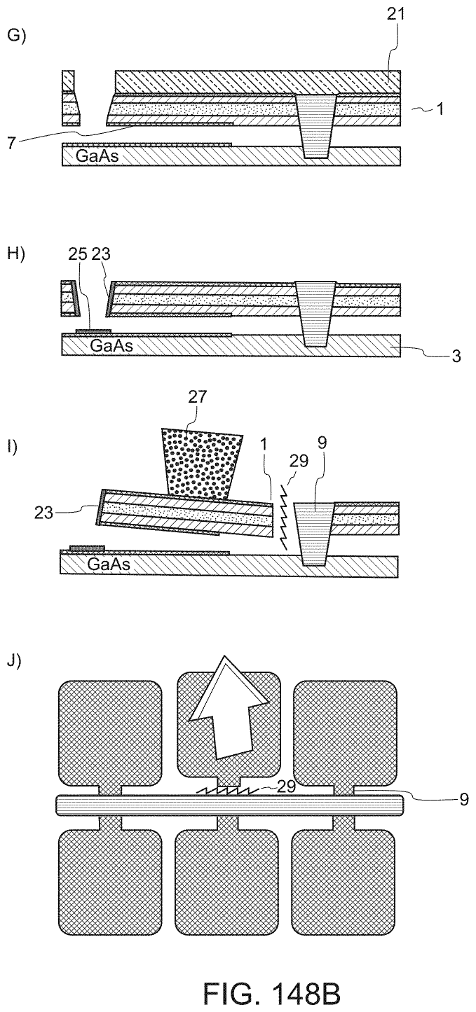

FIGS. 148A to 148J show a first example of a process for manufacturing a μ-LED with a μ-LED supporting holding structure. The manufacturing process of the μ-LED is simplified. It should be noted in this context that the process can be supplemented and extended with the measures disclosed here.

FIG. 148A shows a step in which a sacrificial AlGaAs sacrificial layer is first applied to a substrate 3, which here shows GaAs. A functional layer stack 1 is then epitaxially grown on this sacrificial layer stack, which thus has at least one quantum well or another optically active structure 13. In addition, the layer stack comprises two layers 15 and 17, which are doped differently. The n-doped semiconductor layer 15 is here attached to the sacrificial layer 11. A first electrically conductive contact layer 5 is then deposited on a side of the functional layer stack 1 facing away from the substrate 3. This may, for example, contain ITO (indium tin oxide).

FIG. 148B shows a step in which a first lithographic processing is carried out on the main surface side of the functional layer stack 1 on the first electrically conductive contact layer 5, which is turned away from the substrate 3. In particular, a first masking layer 19 is applied to the first electrically conductive contact layer 5, whereby an area of the first electrically conductive contact layer 5 remains uncovered by the first masking layer 19 in order to create a holding structure 9. From this side of the layer sequence, the first electrically conductive contact layer 5, the functional layer stack 1, the sacrificial layer 11 and a part of the substrate 3 can then be etched out in the uncovered area so that the recess shown in cross-section is formed. The sidewalls are very steep or fall down essentially vertically.

FIG. 148C shows a step in which a support structure 9 is formed in the etched out area of the layer sequence. This is done by depositing material from a gas phase, which extends over the masking 19 and fills the trench until a small recess remains in the material of the web 9 at the level of the masking layer. The recess can be production-related and optionally omitted, for example by applying material until the recess is completely filled. A too thick layer of material on masking 9 can be thinned again by CMP or other methods.

FIG. 148D shows another aspect after the material on masking layer 19 and layer 9 itself has been removed. A second photomask 21 is then applied and patterned in a second area to provide access to the sacrificial layer. The area between the holding structure and the patterning forms the μ-LED. After patterning, etching is again carried out through layers 5 and 1 to the sacrificial layer 11. This results in the structure shown in FIG. 148J. Here the etching process can form a trench or similar to define the dimensions of the μ-LED.

FIG. 148E shows the structure after the etching process, in which the sacrificial layer 11 is removed from the layer sequence, especially by wet chemical etching. The functional layer stack 1 is then supported by the holding structure 9, which is attached to the substrate 3. In a final step, a second electrically conductive contact layer 7 is attached to the functional layer stack 1 on the side of the functional layer stack 1 facing the substrate 3 in the area of the removed sacrificial layer 11. The material of the second electrically conductive contact layer 7 may contain ITO (indium tin oxide). In the area where the sacrificial material has been etched away, the second electrically conductive contact layer 7 can be applied by sputtering, see FIG. 148F. In this way, the space between the substrate 3 and the functional layer stack 1 can be accessed. In addition, when the second electrically conductive contact layer 7 is applied, flanks of the functional layer stack 1 and an area of the exposed area of substrate 3 can be covered. It is also possible to deposition from the gas phase, electroplating or other techniques.

After finishing the contacts 7 on the underside of the structure, the electrically conductive material is removed again on the flank and especially in the area of the trench. The structure thus produced is shown in FIG. 148G. FIG. 148H shows a step in which the flanks of the functional layer stack 1 that are free of electrically conductive material are covered by a passivation layer 23. This is optional. The second masking layer 21 has also been removed. A further passivation layer 25 can also be created on the substrate 3 covered with electrically conductive material of the second electrically conductive contact layer 7.

The structure shown in this way can now be broken away from the holding structure using the stamp described above or another transfer tool. The flanks of layer stack 1 are also covered by a passivation layer 23. FIG. 148J again shows the step of breaking off the μ-LED thus produced as a top view. The large arrow is intended to show the break-off from a holding structure 9 and the jagged area is intended to represent a break point 29.

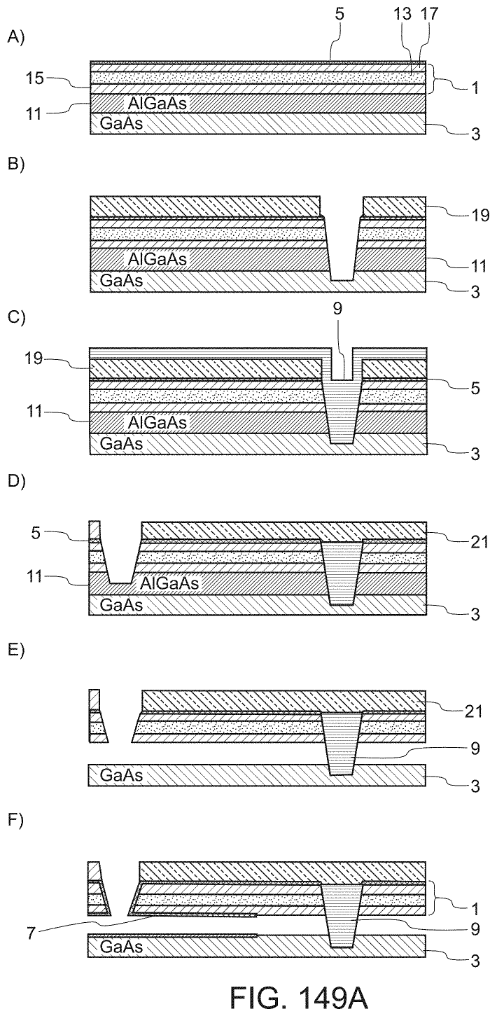

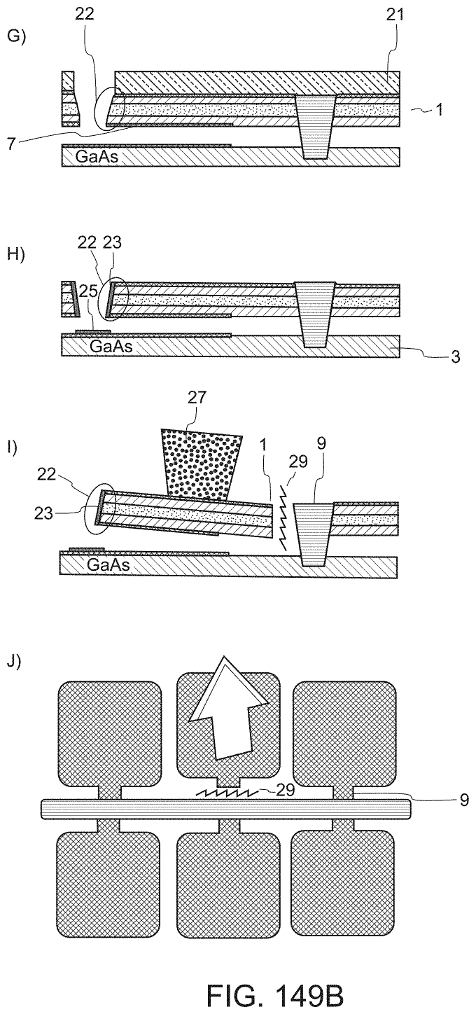

A further example is shown in FIGS. 149A to 149J. FIGS. 149A to 149F show steps identical to those in FIGS. 148A to 148F. In contrast to the steps shown in FIG. 148G, FIG. 149G involves removing the electrically conductive material deposited on the flanks of the functional layer stack 1. Then, before or instead of passivation, a metal is deposited on the flanks and diffused. This material can be Zn in particular. It diffuses into the edge area of the layer stack and produces a change in the band structure there, so that charge carriers are kept away from this area of high defect density. Accordingly, the non-radiative recombination of charge carriers in the functional layer stack is reduced in this way. This is followed by the same steps as in FIGS. 148H to 148J as shown in FIGS. 149H to 149J.

FIGS. 150A to 150I show a third embodiment of a proposed process for manufacturing a μ-LED with a holding structure. FIG. 150A shows a step in which a functional layer stack 1 was epitaxially deposited on a GaAs substrate 3 over a sacrificial layer 11 of AlGaAs. Between the functional layer stack 1 and the sacrificial layer 11, a second supporting layer 24 is also epitaxially formed, which contains, for example, InGaAlP and is relatively thin compared to the sacrificial layer 11. Similar to the previous explanations, the doped semiconductor layer of layer stack 1, which is adjacent to layer 24 and the sacrificial layer, is n-doped. The second semiconductor layer 17 is p-doped. A first electrically conductive contact layer 5 not shown here is subsequently applied to a side of the functional layer stack 1 remote from the substrate 3, especially the main surface side. This can then have ITO (indium tin oxide), for example.

FIG. 150B shows a step in which a first lithographic processing is carried out on the main surface side of a functional layer stack 1 that faces away from a substrate 3. For this purpose, a first masking layer 19 is applied to the second semiconductor layer 17 of the functional layer stack 1, whereby, for the creation of a holding structure 9, outer edge regions of the functional layer stack 1 remain uncovered by the first masking layer 19. From this side of the layer sequence, the functional layer stack 1, the second supporting layer 24 and the sacrificial layer 11 can be removed, in particular etched away by means of ICP (inductively coupled plasma etching), in these uncovered edge regions up to the substrate 3. Finally, the first masking layer 19, is removed again. The trench thus formed can extend around all sides of the body, thus forming one or more μ-LED structures separated by trenches.

FIG. 150C represents a further step in the process, in which a first support layer 20 is formed on the substrate 3, on exposed edge areas of the layer sequence and on a main surface of the μ-LED 1 facing away from the substrate 3 to provide a support structure 9. The material of the support layer 20, which is deposited from a gas phase and epitaxially grown, for example, has InGaAlP. The support layer 20 envelops the layer sequence at least on one side up to substrate 3, it thus extends from the second main surface side over at least one side flank to substrate. Finally, a second masking layer 21 is applied to the main surface of the first support layer 20 facing away from substrate 3. An outer edge region of the layer sequence remains uncovered by the second masking layer 21.

FIG. 150D shows a step in which an outer edge region uncovered by the second masking layer 21 of the layer stack 1, the second support layer 24 and the sacrificial layer 11 up to the substrate 3 has been removed, in particular by etching. In this way, an access to the sacrificial layer 11 will be formed from this side of the layer sequence. The areas covered by the second masking layer 21 remain intact even after the second masking layer 21 has been removed in FIG. 150D.

FIG. 150E shows a step in which the sacrificial layer 11 is removed from the layer sequence, in particular by wet chemical etching. The removal is performed from the outer edge of the layer sequence exposed in step 150D. The functional layer stack 1 is then supported by the first support layer 20 and the second support layer 24, the first support layer 20 being attached to the substrate 3. In this way, a support structure 9 is provided which supports the functional layer stack 1, without the sacrificial layer 11.

FIG. 150F shows the structure after which a first electrically conductive contact layer 5 and a second electrically conductive contact layer 7 are formed. An electrically conductive layer is formed, which is attached to the side facing away from the substrate 3 on the first supporting layer 20, which is attached to the functional layer stack 1 in a supporting and electrically conductive manner. The electrically conductive layer is also applied to the side of the functional layer stack 1 facing the substrate 3 in the area of the removed sacrificial layer 11 on the second supporting layer 24. The material of the electrically conductive layer may contain ITO (indium tin oxide). Especially in the area where the sacrificial layer 11 was etched away, the electrically conductive layer can be applied by sputtering. In this way, a space between the substrate 3 and the functional layer stack 1 is easily accessible. When the electrically conductive layer is applied, flanks of the functional layer stack 1 and at least part of the exposed area of substrate 3 can also be covered.

FIG. 150G shows a step in which the electrically conductive material deposited on the flanks of the functional layer stack 1 is at least partially removed, in particular etched away, in such a way that the first electrically conductive contact layer 5 on the side facing away from the substrate 3 is produced electrically separately from the second electrically conductive contact layer 7 on the side of the functional layer stack 1 facing the substrate 3. In this way, a contacted functional layer stack 1 is formed.

For this purpose, a third masking layer 31 is first applied to the first base layer 20. This third masking layer 31 leaves edges to the flanks of the functional layer stack uncovered. This third masking layer 31 covers edge areas of the first support layer 20 that are attached to the substrate 3. By means of removal, in particular by etching, firstly the first and second contact layers 5 and 7 are electrically separated from each other and the support layer 20 is mechanically reinforced by the first contact layer 5 in such a way that a retaining structure 9 is additionally mechanically reinforced.

FIG. 150H shows a step where the third masking layer 31 has been removed. The functional layer stack 1 is attached to the substrate 3 by a retaining structure 9. For attachment, the first support layer 20, reinforced by the first electrically conductive contact layer 5, interacts with the functional layer stack 1, stabilized and protected by the second support layer 24. By means of a lifting head 27, the contacted—i.e. indirectly coated with the contact layers 5 and 7—functional layer stack 1 can be lifted off and thereby broken off from the holding structure 9. Reference mark 29 denotes a predetermined breaking point at which an electronic component or a contacted functional layer stack 1 can be detached from a substrate 3.

FIG. 150I again shows a step of breaking a layer stack 1, which has electrical contacts and provides at least one function, in contrast to the cross-sections in FIGS. 150A to 150H, this time as a top view. The large arrow is intended to show the breaking off of a retaining structure 9 and the jagged point is intended to represent a break point 29. A detachable electronic component, in particular a detachable micro-light-emitting diode, may be attached to several retaining structures 9, for example, in plan view, at rounded corners of the component.

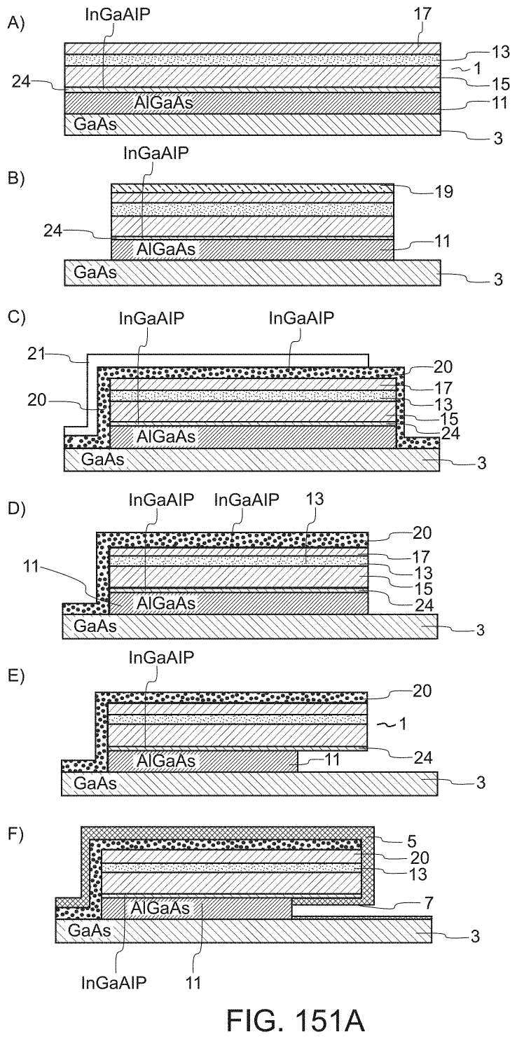

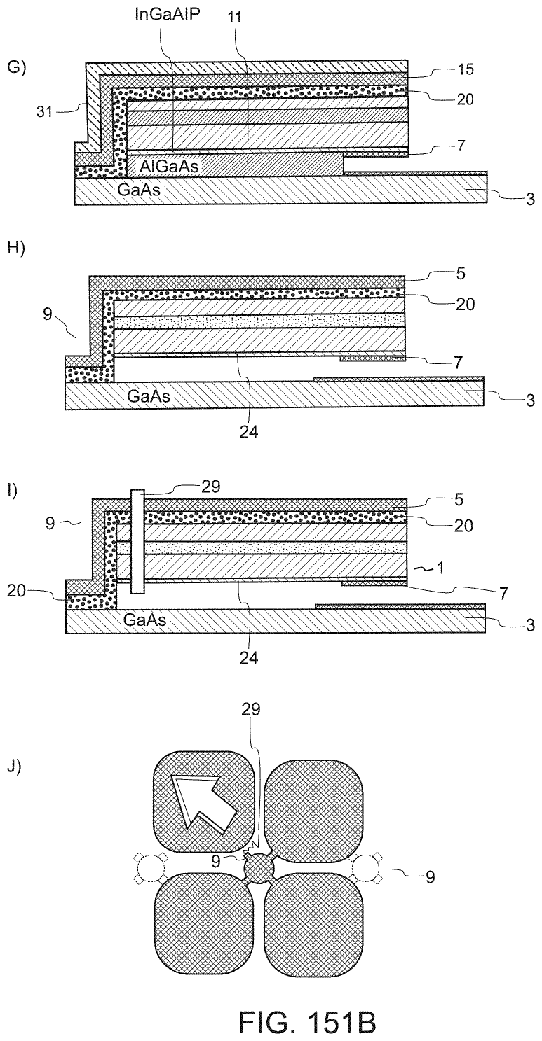

FIGS. 151A to 151J show a fourth example of a proposed method. FIGS. 151A to 151D show steps similar to those in the previous example in FIG. 150.

In contrast to FIG. 150E, FIG. 151E shows a step in which only part of the sacrificial layer 11 is removed by wet chemical means. This exposes a part of layer 24 and the contact layer 7 is then applied. The removal is performed from the outer edge of the layer sequence exposed in step 141D. The functional layer stack 1 is then supported by the first support layer 20 and the second support layer 24, with the first support layer 20 attached to the substrate 3. In this way, a support structure 9 is provided to support the functional layer stack 1 without the complete sacrificial layer 11.

FIG. 151F shows a step in which a first electrically conductive contact layer 5 and a second electrically conductive contact layer 7 are formed on a sacrificial layer 11, which is only partially removed in FIG. 151E. In this process, an electrically conductive layer 5 is formed, which is attached to the side facing away from the substrate 3 on the first support layer 20, which is attached to the functional layer stack 1 in a supporting and electrically conductive manner. The electrically conductive layer also extends to the side of the functional layer stack 1 facing the substrate 3 in the area of the removed sacrificial layer 11. Especially in the area where the sacrificial layer 11 has been etched away, the electrically conductive layer can be applied by sputtering. In this way, a space between the substrate 3 and the functional layer stack 1 is easily accessible. When applying the electrically conductive layer, flanks of the functional layer stack 1 and the exposed area of the substrate 3 can also be covered with the electrically conductive material.

FIG. 151G shows a step in which the electrically conductive material deposited on the flanks of functional layer stack 1 is at least partially removed. The first electrically conductive contact layer 5 on the side facing away from the substrate 3 is thus electrically separated from the second electrically conductive contact layer 7 on the side of the functional layer stack 1 facing the substrate 3.

For this purpose, a third masking layer 31 is applied to the first base layer 20. This third masking layer 31 leaves edges to the flanks of the functional layer stack uncovered. This third masking layer 31 covers edge areas of the first support layer 20 that are attached to the substrate 3. By means of an etching process, the first and second contact layers 5 and 7 are electrically separated from each other. Independently of this, the first contact layer 5 mechanically reinforces the support layer 20. The remaining sacrificial layer 11 is retained during this step.

FIG. 150H shows the structure after removing the third masking layer 31 and the remaining sacrificial layer 11, both of which can be removed by various etching processes. The functional layer stack 1 is attached to the substrate 3 by a retaining structure 9. For attachment, the first support layer 20, reinforced by the first electrically conductive contact layer 5, interacts with the functional layer stack 1, stabilized and protected by the second support layer 24. FIG. 1511 again shows the predetermined breaking point 29. FIG. 151J again shows a step of breaking a μ-LED 1 with electrical contacts as a top view. Depending on the design, a holding structure can hold several such μ-LEDs so that they can be lifted off together or one after the other by a transfer instrument.

In the last versions shown here, a breaking edge is formed. Although this is only very narrow, it can still lead to non-radiating recombination centers, so that the efficiency of the μ-LED is somewhat reduced. In addition, somewhat higher demands are placed on the transfer stamp or transfer technology.

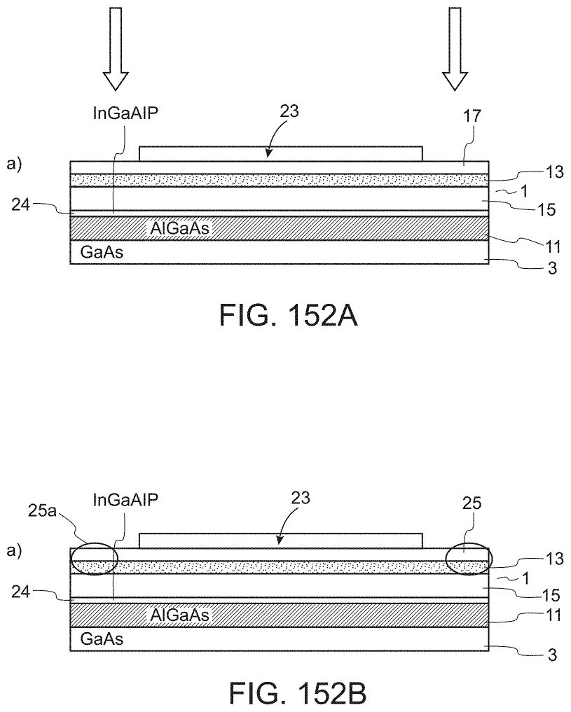

An aspect that leads to a further reduction of the influence of non-radiative recombination centers is shown in FIGS. 152A and 152B. As already mentioned, the fracture edge often generates recombination centers, which leads to an increase in non-radiative recombination in this area and thus reduces efficiency. After processing the semiconductor layer sequence, a photomask 23 is now applied and patterned so that the surface adjacent to the later edge regions is exposed. In contrast, photoresist remains over the area of the later active layer or the active region. Subsequently, a dopant, for example Zn, is deposited on the surface. In the next step, shown in FIG. 152B, a diffusion step is performed. The Zn diffuses through layer 17 and reaches the active region. With suitable process parameters, quantum well intermixing occurs, provided that the active region is formed by one or more quantum wells. Quantum well intermixing shows a strong change in the region of the mask edge as explained in this application, so that the course of the band gap is quite steep and resembles a band gap jump. The increased band gap thus occurs mainly in the edge region and also in the region 25a, where the breaking edge is later formed. The breaking edge is thus formed in an area of increased band gap, so that charge carriers are kept away from the defects caused by the edge during operation. After quantum well intermixing has been generated, the device can be further processed as described above.

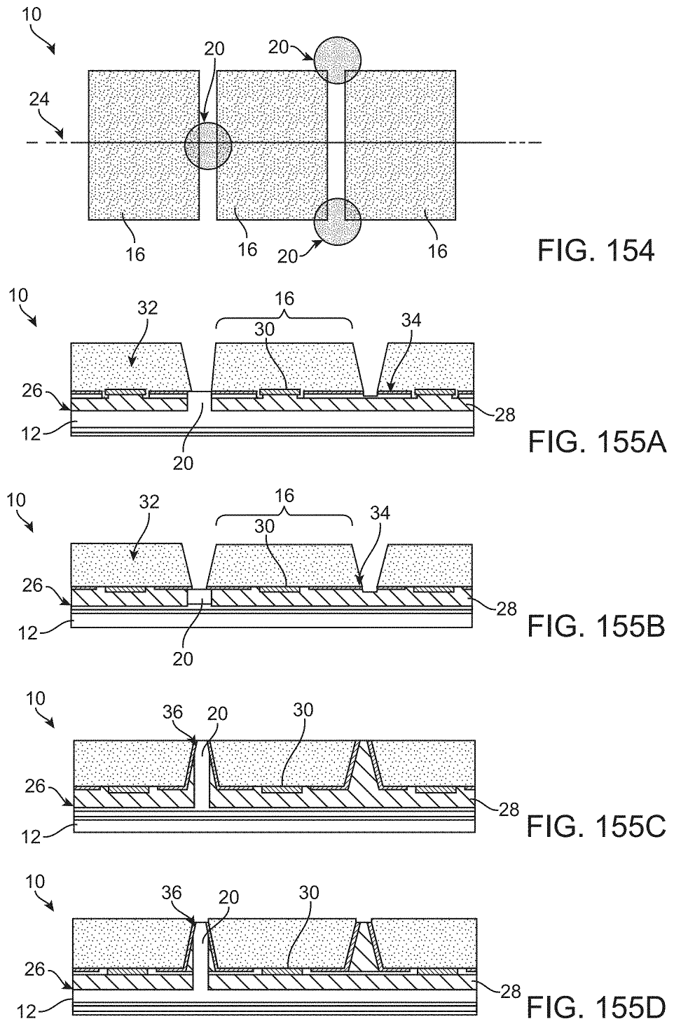

Referring back again to FIGS. 153 and 154, these show a further embodiment of a support structure 10 according to some suggested principles for avoidance of breakage edges and improved lift-off. In principle, the basic structure corresponds to the diagram in FIG. 153A. In particular, the wafer shown in FIGS. 153A and 153B comprises the wafer structure shown in the following, whereby FIG. 154 refers to a simplified top view of a wafer 12 from a top side. Three μ-LEDs 16 can be seen, which in this example are each flat rectangular and arranged next to each other. Other shapes of chips are possible for example hexagonal. On a wafer 12, a large number of such μ-LEDs 16 can be provided on a surface of 16 or 18 inches, for example, arranged side by side.

Prior to a transfer process, these μ-LEDs 16 are mechanically detachably arranged on wafer 12. This means that they can be removed by a stamping tool 18. In the example shown here, the μ-LEDs 16 are partially detached from wafer 12 on their underside (not visible) and are now held by holding elements 20. The mounting elements, which appear round here due to the top view, can be columnar or pole-like with, for example, a round, angular or elliptical cross-section, made from a carrier substrate 22 underneath. As shown, the μ-LED 16 shown here in the middle is held in position by a total of three mounting elements 20. The three support points in particular make it possible to achieve coplanarity, i.e. an arrangement that is stable from the point of view of the distribution of forces and is in the same plane as the other μ-LEDs 16. Two of the mounting elements 20 each hold two μ-LEDs 16 at their corners or edges.

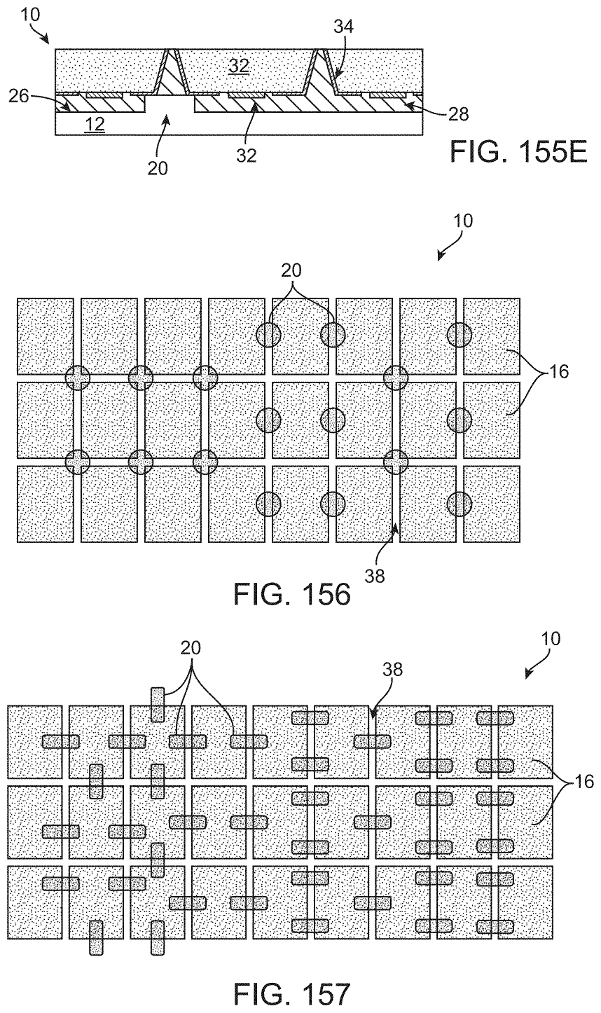

In the following FIGS. 155A to 155D, a vertical sectional view (see line 24 in FIG. 154) is shown for various possibilities of designing a support structure 10. A wafer 12 or, in general, a carrier material or bonding material serves as the basis for mechanical stabilization and for accommodating other components such as electrical connections, electronic control elements and the like. A first release layer 26 is arranged vertically above it. The release layer 26 serves to enable controlled delamination, i.e. the deliberate and controlled separation of the layers from each other by means of a defined tensile force. Furthermore, such a layer can serve as an etch stop layer to leave adjacent layers unchanged during an etching process. This can, for example, replace a breakage process, as it has been used up to now in the state of the art, with a peeling process in which no disturbing residues remain on the μ-LED.

A sacrificial Layer 28 is also provided for. The background to this is that silicon, for example, is used as the material for such layers, which can then be removed in one process step by chemical processes, for example to separate the μ-LED 16 from the wafer 12 below it. The μ-LED 16 also has a contact pad 30, which can have a semiconductor active area such as a p-n junction. FIG. 155A and FIG. 155B show the cross-section of a μ-LED 16 with an epitaxial layer 32 as an example. This epitaxial layer 32 can also be supplemented by a second release layer 34, which is formed between the sacrificial layer 28 and the epitaxial layer 32. This second release layer 34 can be arranged at different locations depending on the design variant.

FIGS. 155A and 155B each show a design variant in which a receiving element 20 as a pole-like, columnar or post-like elevation from wafer 12 extends in one piece vertically between two μ-LEDs 16 through the sacrificial layer 28 and ends before the epitaxial layer 32. Here, the epitaxial layer 32 tapers tightly towards the top, thus forming a V-shaped mesa trench 38 (see FIGS. 156 and 157). While in FIG. 155A the second release layer 34 extends to a side or partial underside of contact pad 30, the second release layer 34 ends horizontally in front of contact pad 30 with sacrificial layer 28 filling the remaining gap. A gaseous or liquid etching substance can then reach the sacrificial layer 28 via the mesa trench 38, i.e. the space between two μ-LEDs 16.

In FIG. 155B, the delamination layer on the exposed surface of the receiving element is also removed by the etching process. By controlling the etching process, the removal of the delamination layer can be selectively adjusted. For example, the delamination layer may have a significantly lower etch rate than the sacrificial layer 28 with respect to the etching process used. This ensures complete removal of the sacrificial layer without overly attacking the delamination layer or the carrier substrate by the etching process. In an alternative embodiment, which is not shown here, the etching process is also used to etch through the delamination layer and into the carrier substrate. In other words, the funnel-shaped recess between the two μ-LEDs is continued in the receiving element. This results in a V- or U-shaped recess for the receiving element, leaving two columns on which the μ-LEDs are placed. The depth of such an etch in the receiving element can also be set by the process. In general, however, not the entire receiving element is etched through. Rather, the receiving element is etched only up to half of its height or less, so that sufficient stability of the receiving elements is ensured. In particular, it is ensured that the remaining columns do not break when the μ-LEDs are removed, but that the μ-LED is lifted off by overcoming the adhesive force of the delamination layer.

FIGS. 155C and 155D show a further embodiment, particularly with regard to the design of the mounting element 20. Here, the receiving element 20 protrudes in one piece from the plane of wafer 12 through the sacrificial layer 28 to an opposite side of the support structure 10. In this case, the pick-up element 20 is tapered at its upper end or designed with slanted μ-LED retaining surfaces 36, which can allow easier lifting of the μ-LEDs 16 while at the same time ensuring a secure fit on wafer 12. In FIG. 155D, according to one example, the receiving element 20 ends vertically before the end of the epitaxial layer 32. The contact pad 30 connects the layers inside the μ-LED and especially the light emitting layer. As shown in FIGS. 155B and 155D, the contact pad 30 is the vertically lowermost element in each case and can therefore come into direct mechanical and thus electrical contact with an electrical contact element (not shown) on a support surface of the display or module, if necessary without additional bridging solder or conductive adhesive. A contact pad 30, for example, can have edge lengths in the range of 1-15 μm.

Finally, FIG. 155E shows an embodiment in which the receiving element is significantly widened and the delamination layer extends completely over the surface of the receiving element. As shown in FIGS. 155C and 155D, sacrificial layer 28 extends through the funnel-shaped region between the individual μ-LEDs with its epitaxy 32. Each μ-LED comprises an epitaxy whose lateral dimensions are larger on the light-emitting side than on the side facing the contact pad 32. In other words, the μ-LEDs widen from the side with the contact pad 32, resulting in an “inverted” V-shape in the shown sectional structure. A further layer 34 is applied to the surface of the areas of the epitaxial layer 32, especially on the sloping sides forming the funnel and on the surface containing the contact pad. This serves as an etching stop and, together with the delamination layer 26, produces a defined adhesive force. For lift-off, the sacrificial layer 28 is now removed by plasma etching, gaseous etching or another process in the V-shaped areas between the μ-LEDs and below, so that the chips only rest with their layer 34 on the delamination layer of the receiving elements.

FIG. 156 and FIG. 157 each show an example of a carrier structure 10 with exemplary 24 μ-LEDs 16 arranged in a matrix on a wafer (not shown). FIG. 156 shows a total of 17 carrier elements 20. These are partly arranged in a mesa trench 38 between two adjacent μ-LEDs 16, partly also at the corners of the respective μ-LEDs 16. This arrangement can lead to the fact that a total of fewer pick-up elements 20 are required than a total number of μ-LEDs 16. In addition, a mounting element 20 in the example shown here can support or accommodate up to four adjacent μ-LEDs 16.

In FIG. 157, the base of receptacle 20 is not round as in FIG. 156, but has a rectangular or square base. This means that the contact area 36, with which the mounting element is in contact with the μ-LED 16, may vary. This can ensure stable mounting of the μ-LED 16, even if the μ-LED 16 shifts slightly in its position in the x-direction or y-direction. In other words, a total contact area consisting of all contact surfaces 36 on the μ-LED 16 remains the same or at least approximately the same, even with small shifts in the lateral direction. Furthermore, the mounting elements 20 can also be arranged on the outer edge of a carrier structure 12 and engage on an outer lateral surface of a μ-LED 16. As an example, it can be seen here that exactly three support points for the same μ-LED can provide particularly stable spatial stabilization. Here, too, a mounting element 20 can support two or more adjacent μ-LEDs 16 and thus reduce space requirements and thus costs through multiple use. In the examples shown, the contact area is shown much larger than the chip area. In practical implementations, the contact area is significantly smaller to reduce the adhesive force so that the delamination layer remains on the carrier and does not break off.

FIG. 158A shows an embodiment in which several μ-LEDs 16 have been monolithically produced on a carrier substrate. Each μ-LED has the shape of a hexagon, i.e. 6 side faces, each facing a side face of an adjacent μ-LED. The corners of the individual μ-LEDs each rest on a mounting element 20. In addition, an edge structuring has been carried out, i.e. trenches have been etched so that the μ-LEDs are only held by the mounting elements. Each μ-LED comprises a centrally arranged and round active area 2a. This is surrounded by an area 2b, the diameter of which substantially corresponds to the distance between two opposite side surfaces of a μ-LED. In other words, the area extends to the side edge of each hexagonal structure of the μ-LEDs, while the corners of each μ-LED do not include the area 2b.

In a different embodiment, area 2b is slightly larger, so that two areas 2b of two adjacent μ-LEDs would meet virtually extended beyond the side edges. However, this part of the second area is removed during processing of the deep edge structure. The second region now comprises a larger band gap generated by quantum well intermixing than the band gap of the active region 2a. The quantum well intermixing was generated, for example, using one of the methods disclosed and presented in this application. The quantum well intermixing and the resulting increase in the band gap effectively keeps the charge carriers away from the edge regions and thus the edges of the μ-LED, since there is an increased defect density there due to the processing, which leads to non-radiative recombination.

FIG. 158B shows another version of the embodiment, which was created by an improved mask structuring. The benefit for this embodiment is to reduce the number of photomasks and transfer steps required. In this version, a photomask was chosen which leads to smaller bulges at the corners. This results in this slightly changed structure.

In the examples shown here, the μ-LEDs are manufactured using various semiconductor technologies. The techniques disclosed in this application can be used for this purpose. However, it is also possible to transfer the antenna structures in this way. The wafer onto which the transfer is made can have contact areas, so that electrical contact is possible. Likewise, control, power sources and other elements may already be present in this wafer. The μ-LEDS transferred in this way will then be further processed in several versions. For example, a converter layer or a light-shaping element will be applied to the μ-LED. In principle, individual μ-LEDs were transferred in these designs. However, the process is not limited to such. The above modules can also be formed with these carrier structures to facilitate the transfer of such modules. The columns or the carrier elements are formed after it is known what size the modules should have.

Traditionally, there are various ways of transferring chips from a carrier wafer to a corresponding target substrate.

State of the art transfer processes such as laser transfer printing or “self-assembly” of individual micro light emitting diode chips from a solution or electrostatically activated or diamagnetic transfer processes are known.

An extension of these concepts achieved with the electrostatic transfer is explained in more detail. A method is to be specified with which optoelectronic semiconductor chips with particularly small dimensions, i.e. μ-LEDs, are picked up and deposited and at the same time, those with a defect are sorted out.

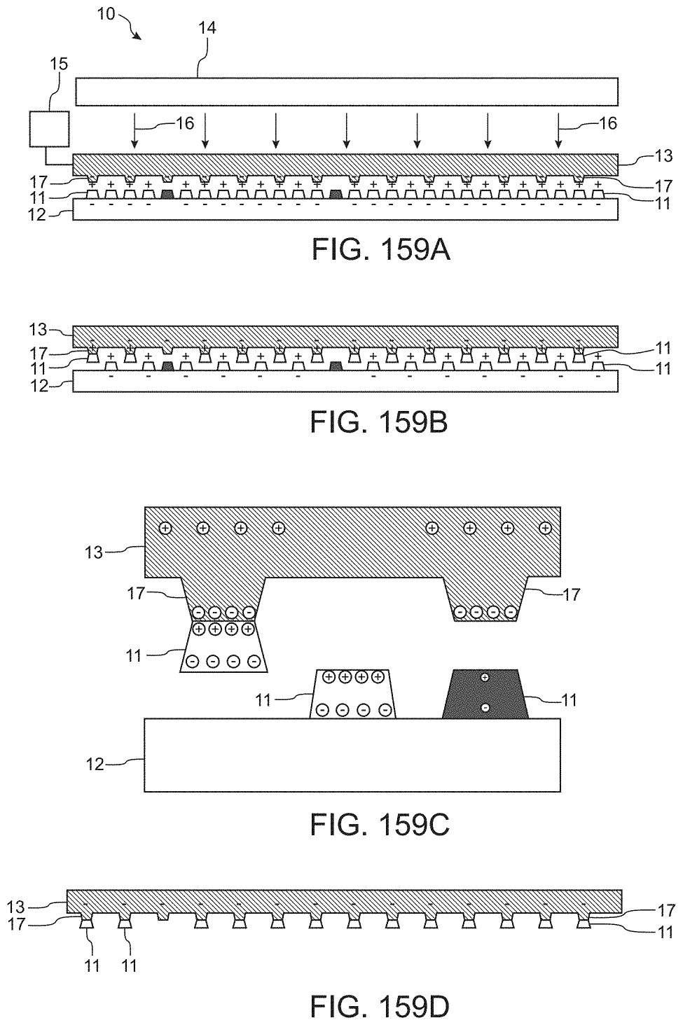

FIG. 159A schematically shows a device 10 for picking up and placing optoelectronic semiconductor chips as an example of an invention. In this example, the optoelectronic semiconductor chips are designed as μ-LEDs 11 and are arranged on a carrier 12 at a distance from each other. The device 10 comprises a pick-up tool 13, an excitation element 14 and a voltage source 15.

The excitation element 14 emits light 16 with which the μ-LEDs 11 are irradiated. The light 16 emitted by the excitation element 14 comprises wavelengths that generate electron-hole pairs in the optically active region of the μ-LEDs 11 by excitation. The electron-hole pairs cause an electrostatic polarization within the μ-LEDs 11, which generates an electric dipole field in the vicinity of the respective μ-LED 11. In the present embodiment, the pick-up tool 13 is arranged between the excitation element 14 and the μ-LEDs 11. The pick-up tool 13 is at least partially transparent for the light 16 emitted by the excitation element 14 so that the light 16 can reach the μ-LEDs 11.

The pick-up tool 13 has metal contacts embedded, for example, in polydimethylsiloxane (PDMS for short) or another suitable material. The metal contacts are connected to the voltage source 15. An electrostatic field can be generated by applying a voltage to the metal contacts. Furthermore, the pick-up tool has 13 elevations 17, which extend from a surface on the underside of the pick-up tool 13 in the direction of the μ-LEDs 11.

Based on FIGS. 159A to 159D, a procedure for picking up and placing the μ-LEDs 11 with the aid of the fixture 10 is described below as an embodiment according to the proposed concept. The light 16 emitted by the excitation element 14 causes an excitation and a resulting electrostatic polarisation in the μ-LEDs 11. At the same time, the pick-up tool 13 is charged by the voltage source 15 in such a way that an attractive interaction between the pick-up tool 13 and the μ-LEDs 11 is caused.

The recording tool 13 is shut down to the μ-LEDs 11 until the elevations 17 are in contact with the μ-LEDs 11 below. In this example, every second μ-LED 11 is in contact with one of the protrusions 17. As FIG. 159B shows, the pickup tool 13 is then raised together with the LEDs 11 adhering to the bumps 17. FIG. 159C shows an enlarged section of FIG. 159B. FIG. 159C shows the electrostatic charge of pick-up tool 13 and the polarization of the μ-LEDs 11. For simplicity, the excitation element 14 and the voltage source 15 are not shown in FIG. 159B and all subsequent figures.

The μ-LEDs 11 located between the elevations 13 are not lifted by the recording tool 13. Furthermore, μ-LEDs 11 are not lifted where the light 16 emitted by the excitation element 14 causes little or no polarization due to defects in the μ-LEDs 11. These μ-LEDs 11 are highlighted in FIG. 159A to 159C. The lower polarization compared to intact μ-LEDs 11 makes it possible to sort out μ-LEDs 11 with corresponding defects without having to test the μ-LEDs 11 beforehand. Then, as shown in FIG. 159D, the μ-LEDs 11 are transferred to a desired location using the recording tool 13 and stored there.

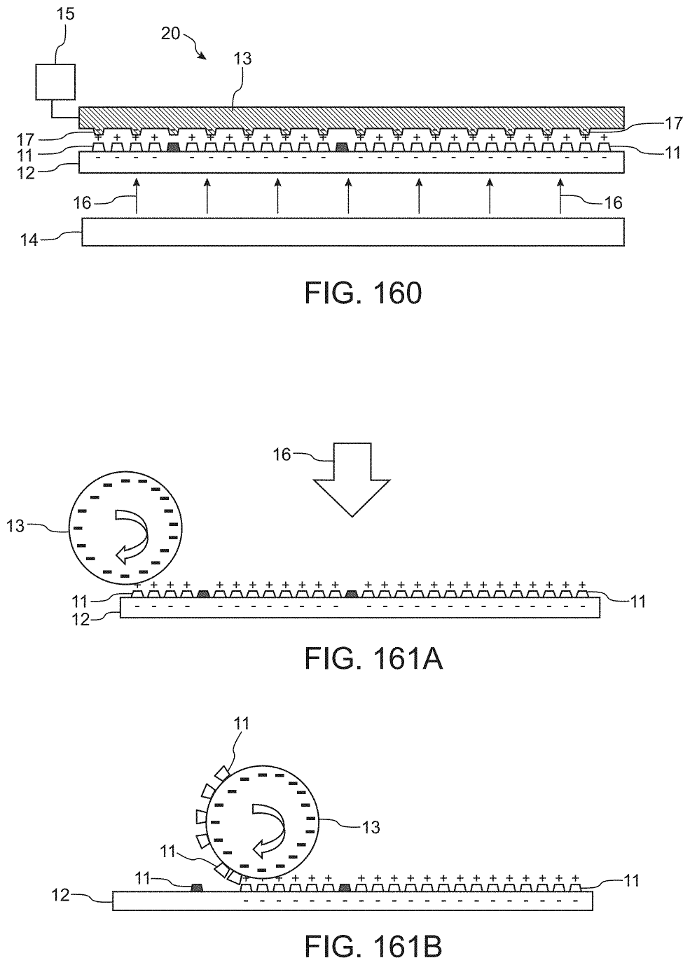

FIG. 160 schematically shows a device 20 for picking up and placing optoelectronic semiconductor chips as a further example of an invention. The device 20 shown in FIG. 160 is largely identical to the device 10 in FIG. 159A. The difference is that the excitation element 14 in FIG. 160 is located below the carrier 12 on which the μ-LEDs 11 are located. In this case, the support 14 must be at least partially transparent to the light 16 emitted by the excitation element 14 in order for photoluminescence excitation to occur in the μ-LEDs 11.

FIG. 161A schematically shows a cylindrical shaped pick-up tool 13, which can be designed like the drum of a laser printer. The pick-up tool 13 is electrostatically charged in such a way that there is an attractive interaction between the surface of the pick-up tool 13 and the μ-LEDs 11 below it due to the polarization caused by the photoluminescence excitation. As shown in FIG. 161B, the cylindrical pick-up tool 13 is rolled over the support 12 and those μ-LEDs 11 are picked up in which sufficient polarization has been produced by the incident light 16.

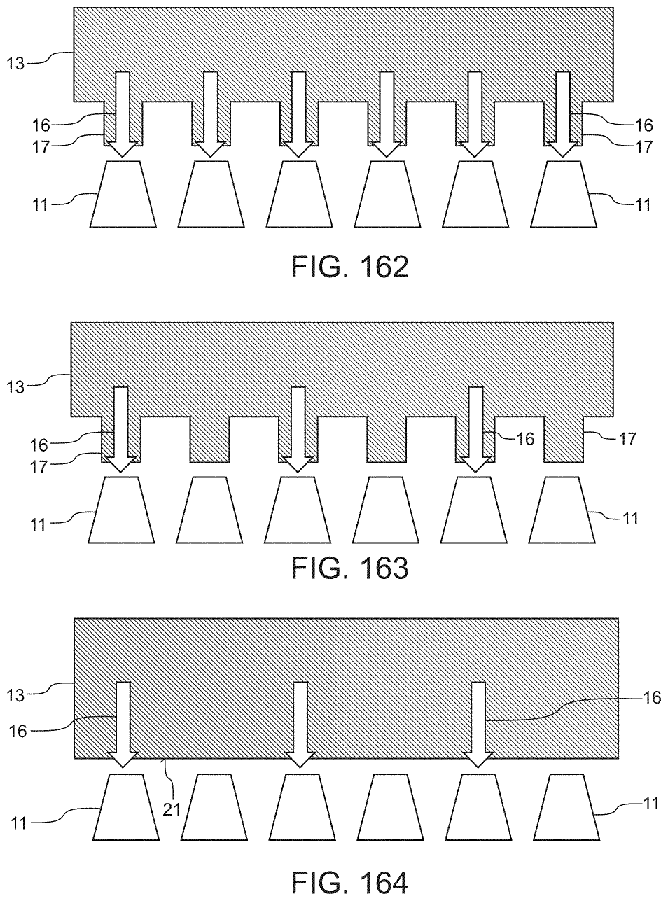

FIG. 162 schematically shows a pick-up tool 13 with elevations 17 on its underside extending in the direction of the μ-LEDs 11 located below the pick-up tool 13. The light 16 emitted by the excitation element 14 not shown in FIG. 162 passes through the pick-up tool 13 onto the μ-LEDs 11. To allow the passage of the light 16, the pick-up tool 13 is made of a material that is at least partially transparent to the light 16. Alternatively, corresponding through-holes or light guides can be integrated into the pick-up tool 13.

FIG. 163 shows the pick-up tool 13 from FIG. 162, but in FIG. 163, only certain μ-LEDs 11 are selectively irradiated with the light 16, e.g. every second μ-LED 11. To make this possible, corresponding through-holes or light guides may be integrated in the pick-up tool 13 or a corresponding shadowing mask may be provided which allows the light 16 to fall only on the specified μ-LEDs 11. As a result, only the μ-LEDs 11 irradiated with the light 16 are excited to photoluminescence and only these μ-LEDs 11 can be picked up by the pick-up tool 13, provided that they form a sufficient polarization by the photoluminescence excitation.

FIG. 164 schematically shows a pick-up tool 13, which comprises a continuous flat surface 21 on its underside. The flat surface 21 makes it possible to pick up μ-LEDs 11 arranged in different patterns and/or at different distances. Furthermore, shading elements, e.g. a mask, can be provided to excite selectively only certain μ-LEDs 11 to photoluminescence.

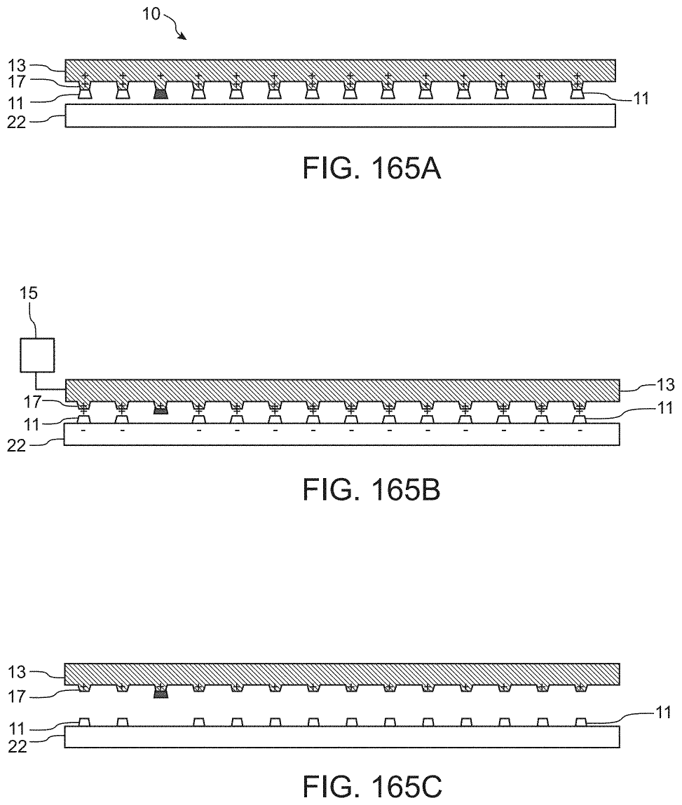

FIG. 165A to 165C shows the fixture 10 while placing the μ-LEDs 11. After picking up the μ-LEDs 11 as shown in FIG. 159A to 159D, the pickup tool 13 is transferred to a board shown in FIG. 165A on which some of the μ-LEDs 11 are to be mounted.

Using the voltage source 15 shown in FIG. 165B, the electrostatic charge of the pick-up tool 13 is changed in such a way that the attractive interaction between the pick-up tool 13 and the μ-LEDs 11 is reduced or converted into a repulsive interaction. By means of the individually controllable metal contacts in the pick-up tool, the electrical charge in certain areas of the pick-up tool can be changed in the desired way so that only a predetermined number of μ-LEDs 11 are deposited on the board 22. The pickup tool 13 is then removed from the board 22, as shown in FIG. 165C. The μ-LEDs 11 remaining on the pickup tool 13 can be removed or placed elsewhere, for example on a cleaning tape.

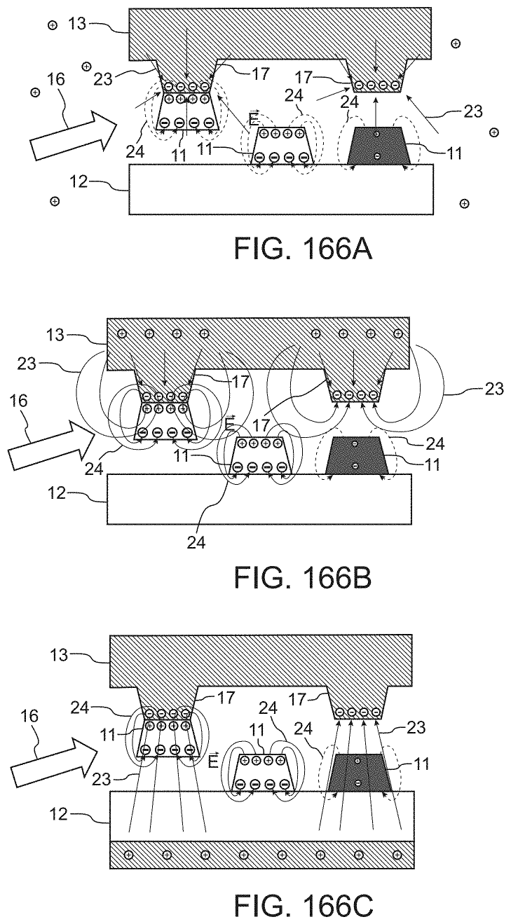

FIGS. 166A through 166C schematically illustrate various options for generating an electric field using pickup tool 13. The field lines 23 shown in FIG. 166A through 166C indicate the direction and strength of the electric field at the location.

In the configuration shown in FIG. 166A, charges are located in the elevations 17 of the pick-up tool 13, and the counter charges are located in the vicinity of the pick-up tool 13. This results in an electric field around each of the bumps 17, similar to the field of a point charge. In FIG. 166B, there are dipole charges in the pick-up tool 13, arranged in such a way that the electric field strength is particularly strong at the tips of the bumps 17. In FIG. 166C, the bumps 17 of the pick-up tool 13 are electrically charged and the countercharges are arranged below the carrier 12 so that the μ-LEDs 11 to be picked up are located between the pick-up tool 13 and the countercharges and thus within the electric field.

The electric fields generated by the recording tool 13 should not be homogeneous in order to exert an effective force on the dipoles of the μ-LEDs 11 so that they can be recorded by the carrier 12. FIGS. 166A to 166C also show electric field lines 24 of μ-LEDs 11 generated by the excitation. The interaction of the field lines 24 of the μ-LEDs 11 with the field lines 23 of the pick-up tool 13 is not shown for simplification.

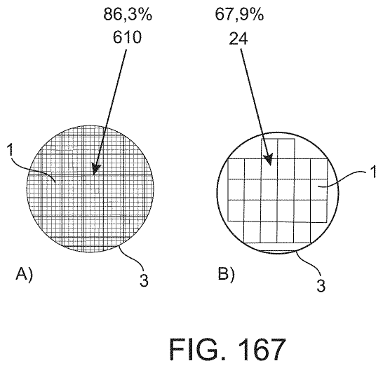

FIGS. 167A and 167B show illustrations with regard to transfer steps of a conventional method and with regard to a method according to the concept of a double transfer process. The parallel, error-free transfer of many μ-LEDs from a carrier substrate 3 to a display substrate 7 plays a decisive role in the production of μ-displays. The number of necessary transfer steps is important for the manufacturing costs. The fewer transfer steps required, the lower the corresponding process costs. Parallel to the cost consideration, the technical feasibility of reducing the number of transfer steps is also relevant.

In general, the density of μ-LEDs on a carrier substrate is 3 orders of magnitude higher than on a μ-display. The ratio depends on the μ-LED size, the chip-to-chip distance (wafer pitch) on carrier substrate 3 and the target resolution of the μ-display (pixel pitch).

The transfer from carrier substrate 3 to the target substrate 7 can be carried out according to a conventional method in such a way that the μ-LEDs are removed from carrier substrate 3 according to the pixel pitch of the display and transferred to the corresponding substrate 7. The size of the transfer stamp as well as the size of the removable area on carrier substrate 3 and the total size of the μ-display then define the number of transfer steps for a μ-display. It is advantageous if the stamp size is selected in such a way that the display size can be fully populated by means of integer multiples of the stamp size in x and y direction. In this way, individual transfer processes can be avoided. For the production of color displays, the transfer for all three colors red, green, blue of the μ-LED onto the target substrate must be carried out.

Both FIGS. 167A and 167B show a carrier substrate 3 on which μ-LEDs 1 have been formed. Accordingly, a carrier substrate 3 provides μ-LEDs of one color, for example red, green and blue. Now the number of transfer steps by means of which μ-LEDs are transferred from a carrier substrate 3 directly to a μ-display is to be determined, whereby this corresponds to a conventional method.

For example, the display has a spatial extension of 200 mm in the x-direction and 100 mm in the y-direction. The carrier substrate 3, for example, has a diameter of 300 mm. The pitch between the μ-LEDs is 10 μm. The pitch between the pixels of the display is 100 μm, ten times as large. A color display with red, green and blue μ-LEDs is to be produced. Therefore, this whole process has to be done for each color.

FIG. 167A shows maximum stamp positions per carrier substrate 3 for a small transfer stamp size. FIG. 167B shows maximum stamp positions per carrier substrate 3 for a relatively large transfer stamp size. In FIG. 167A, the size of the transfer stamp is 10 mm in the x-direction and also 10 mm in the y-direction. Accordingly, for a display area of 20,000 mm² (200 mm×100 mm) with the selected area of the transfer stamp of 100 mm², a total of s=200 transfer steps must be performed for each color. Using the three colors red, green and blue results in 600 transfer steps for one display. FIG. 167A shows that up to 610 transfer steps can be carried out with this design, allowing 86.3% of the wafer to be used. However, it should be noted that it is assumed that each transfer step does not involve a transfer error, i.e. all μ-LEDs to be transferred are also picked up.

Small transfer stamps result in a large area of use on the carrier substrate 3 In other words, a large number of μ-LEDs can be removed from a carrier substrate if the transfer stamp is small. However, the resulting high utilization factor is associated with a large number of transfer steps. FIG. 167B shows a design, in which the size of the transfer die is designed with spatial extensions of 40 mm in an x-direction and 50 mm in a y-direction.

Accordingly, for a display area of 20,000 mm² with the selected area of the transfer stamp of 2,000 mm², a number of r=10 transfer steps must be carried out for each color. Using the three colors red, green and blue results in only 30 transfer steps for one display. FIG. 167B shows, however, that up to 24 transfer steps can be carried out with this design, which means that only 67.9% of the wafer can be used. As a result, although larger transfer dies result in a smaller number of transfer steps, the usable area on carrier substrate 3 is also smaller. In other words, a larger stamp cannot easily reach some areas on the carrier substrate.

Now the number of transfer steps is to be determined by means of which μ-LEDs are transferred from a carrier substrate 3 via an intermediate carrier 5 to a target substrate for a μ-display. In contrast to the conventional method, instead of a display, an intermediate carrier 5 is now first assembled in the same way as in the conventional method. All size specifications described above still apply. Accordingly, a transfer stamp as shown in FIG. 167A requires s=200 transfer steps per color and a transfer stamp as shown in FIG. 167B requires r=10 transfer steps per color.

Since the pitch of the μ-LED on the carrier substrate 3 is 10 μm, and the pitch of the pixels of the display is ten times as large at 100 μm, the conventional transfer method can only transfer fewer μ-LEDs than possible by a factor of n=100. In other words, both stamps transfer less μ-LED per transfer in the conventional manner than it would be possible.

In the method according to the proposed principle, all μ-LEDs present on the carrier substrate 3 and accessible by the stamp are transferred to the intermediate carrier 5 during the transfer. These are so-called first transfer steps, which are carried out by means of a first transfer stamp 4. In the proposed process, the intermediate carrier 5 is the same size as the display, so that a display for one color can be completely assembled with one transfer by means of a second transfer step using a second transfer stamp 6 of the same size. Since the first density of μ-LEDs on the intermediate carrier 5 is greater by a factor of n=100 than the density of the pixels on the display, a number of n=100 displays of one color is produced from an intermediate carrier 5. For color displays, 3×100 second transfer steps are then required, which, together with the first transfer steps, result in a respective following total number of transfer steps per 100 color displays:

For the small transfer stamp 4 as shown in FIG. 167A, this results in a total number of 3×200+3×100 transfer steps for 100 color displays, i.e. 9 transfer steps per 1 color display. For the larger transfer stamp 4 as shown in FIG. 167B, the total number of transfer steps is 3×10+3×100 for 100 color displays, i.e. 3.3 transfer steps per 1 color display.

This is a significant improvement over the conventional method, which requires 600 transfer steps per 1 color display for the small transfer stamp shown in FIG. 167A and 30 transfer steps per 1 color display for the larger transfer stamp shown in FIG. 167B. The transfer steps per color display are average values from which real manufacturing processes may differ within tolerances and due to defects.

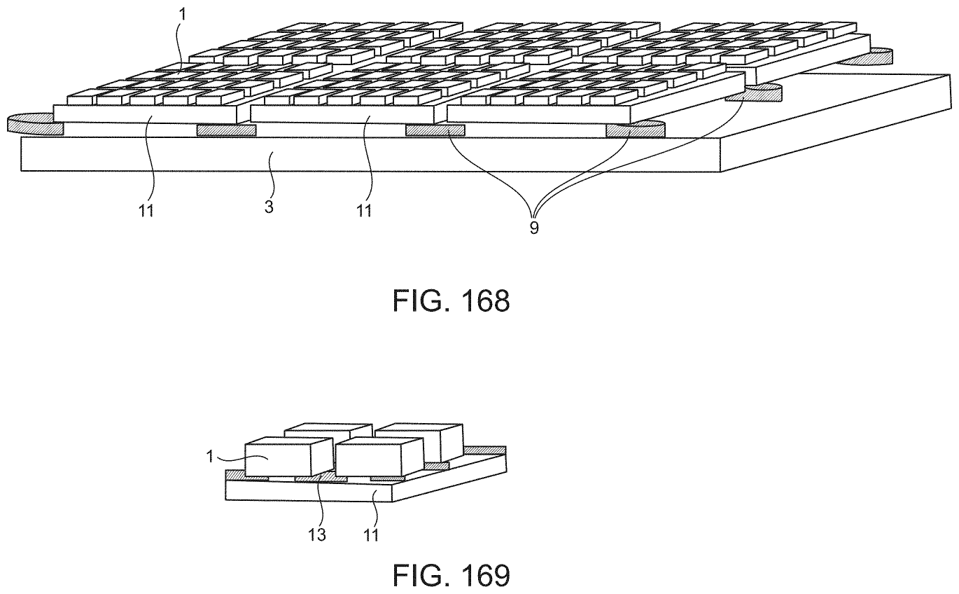

FIG. 168 shows a first embodiment of an inventive start structure for an inventive process in a top view. This start structure is used to execute the two transfer steps safely and reliably. FIG. 168 shows μ-LEDs 1 arranged at module areas 11, which adhere to a carrier substrate 3 by means of first anchor elements 9. The module areas 11 can be assembled from one or several carrier substrates 3.

The first anchor elements 9 are connected to the carrier substrate 3 and are designed to hold several module areas 11 detachably between the first anchor elements 9 in such a way that the module areas 11 can be separated from the carrier substrate 3 in first transfer steps S2 with a first defined minimum lifting force transverse to the substrate plane by means of the first transfer stamp 4, moved out and then transferred to the intermediate carrier 5. The minimum lift-off force must be applied at least to enable lift-off and must be set in a defined manner by the anchor elements 9.

The adhesive force with which the μ-LEDs 1 adhere to the first transfer stamp 4 is greater than the first defined minimum lifting force. FIG. 169 shows the first embodiment according to FIG. 168 of the starting structure in an enlarged view using the proposed concept for the procedure.

The enlarged view shows that the μ-LEDs 1 adhere to module areas 11 by means of second anchor elements 13. The module areas 11 thus carry a plurality of transferable μ-LEDs. In particular, second anchor elements 13 are formed which are connected to the module areas 11 and are configured to hold μ-LEDs 1 detachably between the second anchor elements 13 in such a way that the μ-LEDs 1 are separated from an intermediate carrier 5 by means of the second transfer stamp 6 in a respective second transfer step S3 with a second defined minimum lifting force transverse to the plane of a respective module area 11, moved out and then transferred to the target substrate 7.

The adhesive force with which the μ-LEDs 1 adhere to the second transfer stamp 6 is greater than the second defined minimum lifting force. FIG. 168 and FIG. 169 show the first starting structures that can be used to carry out the presented method. By means of first anchor elements 9 a respective first transfer step can be performed and by means of second anchor elements 13 a respective second transfer step can be performed safely and reliably. By means of the anchor structures 9, 13 defined minimum lift-off forces are set for a lift-off during the two transfer steps.

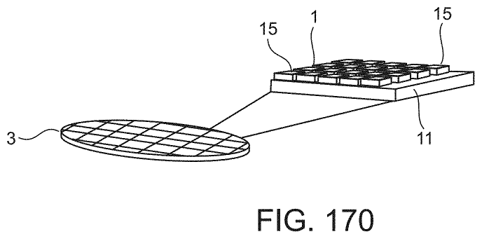

FIG. 170 shows a further illustration with regard to the production of a first launch structure in accordance with the invention. On the left, a round carrier substrate 3 is shown, in which rectangular module areas 11 are drawn. Carrier substrate 3 has the double anchor elements in the form of the first anchor elements 9 for the module areas 11 and the second anchor elements 13 for the micro light emitting diodes. On the right side, an enlarged representation of a rectangular module area 11 is shown. The module also includes lifting elements 15 at two diagonally opposite corners. These serve to ensure that the module areas 11 can be safely transferred. The lifting elements 15 can alternatively be formed in the four corners of a module area 11 or in the four corners of a module area 11 and additionally in its center. Lifting elements 15 provide working surfaces for a first transfer stamp for lifting module areas 11. Thus, module areas with μ-LEDs 1 can be assembled from different carrier substrates 3.

In some aspects, the lifting elements 15 are designed as μ-LEDs 1, which are not to be transferred and are directly attached to the module areas 11. Lifting elements 15 are thus μ-LEDs 1, which are directly connected to module areas 11 without second anchor elements 13. Without anchor elements, the lifting elements 15 have a high adhesive force on the respective wafer area 11. Lifting elements 15 create a square or round surface or structures such as crosses. The number of lifting elements 15 can be selected proportionally to the size of the module area 11. If the lifting elements 15 are only structures directly connected to module area 11, the arrangement of the structure of the lifting elements 15 is selected as an integer multiple of the display pixel pitch to generate the least loss of chip area. If μ-LEDs 1 are provided as lifting elements 15, they can no longer be used as display elements.

Alternatively or cumulatively, according to the lifting elements 15 positioning elements 17 can be designed as positioning aids for a spatially accurate transfer. Lifting elements 15 are then the positioning elements 17. The accuracy of a wafer pitch of the individual μ-LEDs on the transferred module areas 11 is not affected by the transfer process. Since the positioning accuracy of large-area module areas 11 in relation to one another is not negatively influenced by the expansion effects of a transfer stamp during the transfer, greater overall accuracy can also be achieved when “denominating” a temporary intermediate carrier 5. This also results in lower tolerances in the final assembly of displays with micro light emitting diodes.

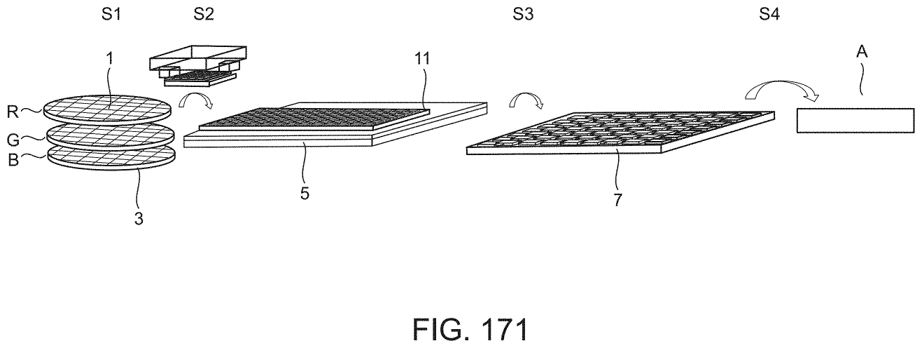

FIG. 171 shows an example of an inventive method. In a first step, an intermediate carrier 5 is produced in the target size of the display product with the same μ-LED density as the carrier substrate 3. The basic shape of the intermediate carrier 5 is rectangular. It is then thinned out during transfer to the display. For this purpose, the intermediate carrier 5 is provided on which module areas 11 of wafer 3 can be temporarily transferred completely. In a second stamping step or transfer step S3, individual μ-LEDs with the correct pixel pitch are removed again to be transferred to a final target substrate 7. An important criterion is the positional accuracy during transfer to the intermediate carrier 5 as well as the spatially accurate, preferably error-free placement during transfer to the target substrate 7.

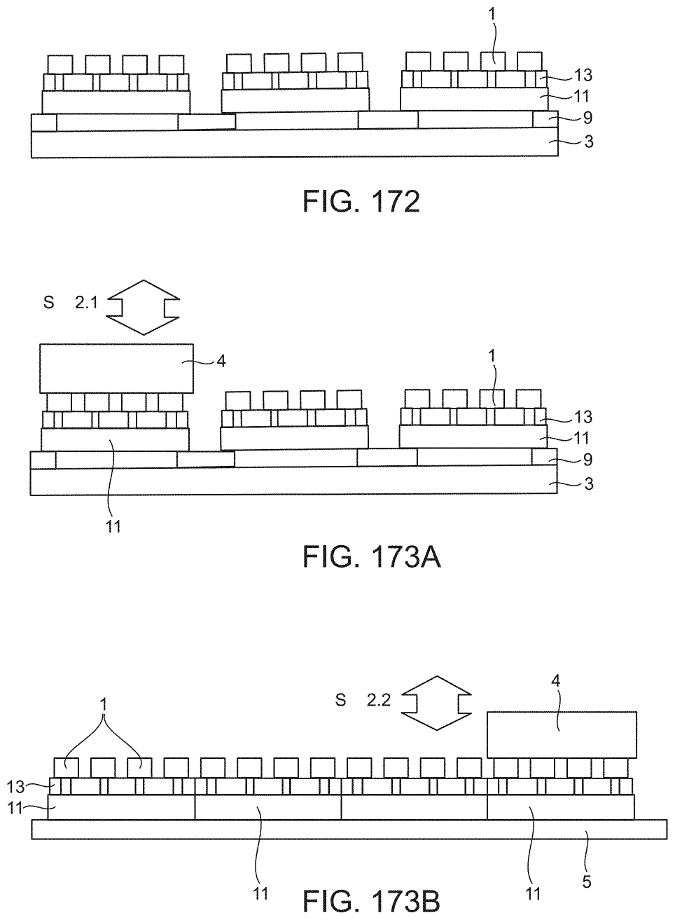

To create a color display, the following steps are carried out for each of the colors red, green and blue, in particular in the example of FIG. 172:

With a first step S1, μ-LEDs 1 are generated on a carrier substrate 3 with a first density. In this process, first anchor elements 9 and second anchor elements 13 are formed on the carrier substrate 3 for positioning module areas 11 and μ-LEDs 1. These anchor elements 9, 13 thus provide double anchor element structures or double anchor element structures as starting structures for the process. After the carrier substrate 3 has been processed, the module areas 11 located on the carrier substrate 3 are tested in such a way that, for example, functioning μ-LEDs are distinguished from defective μ-LEDs 1, a yield is determined or color locations are determined.

With a second step S2, a respective first transfer step is carried out by a first transfer stamp 4, which transfers the μ-LEDs 1 to an intermediate carrier 5 with the first density. Depending on the test results, only certain module areas 11 are arranged on an intermediate carrier 5. In this way, for example, only functioning module areas 11 or only module areas 11 with suitable color can be formed.

Depending on the design, a multiple transfer takes place until the intermediate carrier 5 is completely equipped with module areas 11. These are attached to the intermediate carrier 5 with an adhesive material or adhesive film. The adhesive force can be generated by self-hardening or cross-linking by means of ultraviolet light or exposure to high temperature. Optionally, thermal or thermocompressive treatment of the intermediate carrier 5 can be carried out, which improves the planarity and/or adhesion. An intermediate carrier 5 is used for each color, for example a 12.3 inch intermediate carrier 5. The intermediate carrier 5 can be equipped with module areas 11 of different carrier substrates 3.

With a third step S3 a respective second transfer step is executed. Here, a second transfer stamp 6 is used to transfer the μ-LEDs 1 from the intermediate carrier 5 to a target substrate 7 with a second density that is a factor n smaller than the first density. The distance between the pixels and thus also between the μ-LEDs on the target substrate 7 corresponds to a multiple of the distance between μ-LEDs of the same type on the intermediate carrier 5 and can be different in both spatial directions. In other words, μ-LEDs on the intermediate carrier are selected and transmitted based on the pitch on the target substrate 7. This result in a thinning of the μ-LEDs on subcarrier 5, but a corresponding number of color displays can be created from three assembled subcarriers.

The target substrate 7 provides a common array area for each of the n arrays, especially for all three colors. Size and shape of the intermediate substrate 5 and the second transfer stamp 6 are equal to each other and preferably equal to the array surface. In this way, a backplane of a display can be equipped with μ-LEDs of one color in a second transfer step. If intermediate carrier 5 and second transfer stamp 6 are smaller than the display by a factor k, correspondingly k second transfer steps must be carried out, which increases the manufacturing effort. The target substrate 7 can be equipped with several intermediate carriers 5, for example to produce colored screens.

The display can be further processed by means of a further processing S4. For example, the production of a respective electrical top contact in the case of vertical micro light emitting diodes or the production of both electrical contacts in the case of horizontal micro light emitting diodes. In addition, optical out-coupling structures or out-coupling layers or surface refinement layers can be formed, which can serve to improve the black impression, for example. A modulation can also be carried out.

FIG. 172 shows the first embodiment of a start structure for the proposed method in cross-section. The start structure comprises several μ-LEDs 1, which are connected to module areas 11 by means of second anchor elements 13. These in turn are connected to a carrier substrate 3 by first anchor elements 9. Between carrier substrate 3 and module areas 11 on the one hand and μ-LEDs 1 and module areas 11 on the other hand, anchor elements 9, 13 are configured in such a way that with a defined first minimum lifting force of the lifting first transfer stamp 4, the module areas 11 are separated from the module areas 11 in a first transfer step S2 and with a defined second minimum lifting force of the lifting second transfer stamp 6, the μ-LEDs 1 are separated from the module areas 11, lifted and then transferred in a second transfer step S3.

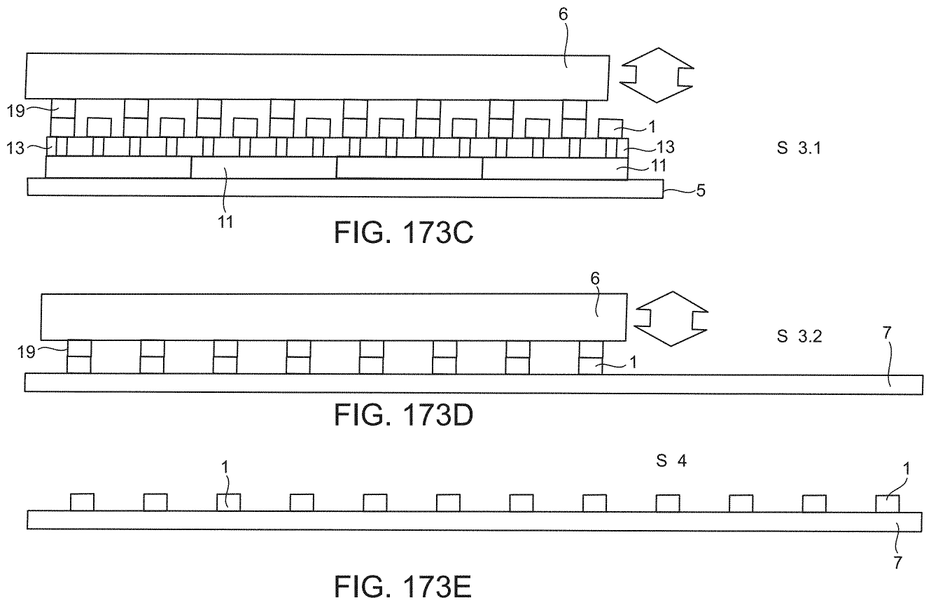

FIGS. 173A to 173E show a further example of a proposed method using the first start structure shown.

FIG. 173A shows how a large number of module areas 11 with μ-LEDs 1 are detached from the first anchor elements 9 and the wafer 3 with a step S2.1. This is done by means of a first transfer stamp 4. For lifting off the module areas 11, the adhesive force of the μ-LEDs 1 on the module areas 11 (second adhesive force) is greater than the adhesive force (first adhesive force) of the module areas 11 on the carrier substrate 3. In addition, the adhesive force of the first transfer stamp 4 on the μ-LEDs 1 is also greater than the first adhesive force of the module areas 11 on the carrier substrate 3. The first minimum lifting force applied by the first transfer stamp 4 is again greater than the first adhesive force of the module areas 11 on the carrier substrate 3 and smaller than the second adhesive force of the μ-LEDs 1 on the module areas 11 and less than the adhesive force of the μ-LEDs 1 on the first transfer stamp 4.

For successful placement of the module areas 11 carrying μ-LEDs 1 on the intermediate support 5 as described in FIG. 173B, the second adhesive force of the μ-LEDs 1 on the module areas 11 must be greater than the adhesive force of the μ-LEDs 1 on the first transfer stamp 4. The adhesive force of the module areas 11 on the intermediate support 5 must be greater than the adhesive force of the μ-LEDs 1 on the first transfer stamp 4. First anchor elements 9 and second anchor elements 13 are used to set the respective first and second adhesive forces. Thus, the first adhesive force between the module areas 11 and the wafer 3 is provided by the first anchor elements 9. The respective second adhesive force between the μ-LEDs 1 and the module areas 11 is provided by the second anchor elements 13. The release force applied by the first transfer stamp 4 must be greater than the adhesive force of the μ-LEDs 1 on the first transfer stamp 4 and smaller than the second adhesive force of the μ-LEDs 1 on the module areas 11. The release force is the minimum force that must be applied in order to carry out releasing.

FIG. 173B shows a subsequent step S2.2 of applying the module areas 11 carrying μ-LEDs 1 to the intermediate carrier 5, which is also carried out using the first transfer stamp 4.

By selecting a suitable material, a connection between the module areas 11 and the intermediate support 5 can be provided with the required adhesive force. For example, an adhesive can be used. The adhesive force of the μ-LEDs 1 on the first transfer stamp 4 can also be changed by suitable movement guidance of the first transfer stamp 4 during lifting and setting down, e.g. by movement guidance with shear component, i.e. parallel to the plane of the intermediate carrier. The adhesive force of the μ-LEDs 1 on the first transfer stamp 4 can be reduced, e.g. during setting down.

Steps S2.1 and S2.2 are carried out several times until, for example, for a color of red, green or blue, the intermediate carrier 5 is fully loaded.

FIG. 173C shows a subsequent step S3.1 of lifting the μ-LEDs 1 from the module areas 11 for transfer to the target substrate 7, which is done by a second transfer stamp 6. The μ-LEDs 1 are released from the second anchor elements 13 and the intermediate carriers 5. Here μ-LEDs 1 are released simultaneously from several intermediate carriers. The density of the μ-LEDs 1 on the module areas 11 does not correspond to the density of the μ-LEDs 1 on the target substrate 7. For example, the first density can be twice as high as the second density. Accordingly, the second stamp has 6 sensing elements 19, which correspond to the distance of the μ-LEDs 1 on the target substrate 7. FIG. 173C shows that the first density of μ-LEDs 1 on module areas 11 is twice as high as the second density of μ-LEDs 1 on target substrate 7.

The adhesion of the second transfer stamp 6 must also be stronger than the adhesion of the μ-LEDs 1 on the intermediate carrier 5. To lift off the μ-LEDs 1, the adhesive force of the μ-LEDs 1 on the second transfer stamp 6 must be greater than the second adhesive force of the μ-LEDs 1 on the module areas 11. Furthermore, the adhesive force of the module areas 11 on the intermediate carrier 5 must also be greater than the second adhesive force of the μ-LEDs 1 on the module areas 11. The defined second minimum lifting force applied by the second transfer stamp 6 must be greater than the second adhesive force of the μ-LEDs 1 on the module areas 11 and less than the adhesive force of the module areas 11 on the intermediate carrier 5 and less than the adhesive force of the μ-LEDs 1 on the second transfer stamp 6.

For successful placement of the μ-LEDs 1 from the second transfer stamp 6 onto the target substrate 7 as described in FIG. 173D, the adhesive force of the μ-LEDs 1 on the target substrate 7 must be greater than the adhesive force of the μ-LEDs 1 on the second transfer stamp 6. Conversely, the release force applied by the second transfer stamp 6 is greater than the adhesive force of the μ-LEDs 1 on the second transfer stamp 6 but less than the adhesive force of the μ-LEDs 1 on the target substrate 7. The second anchor elements 13 as well as connecting means and the movement guide of the second transfer stamp 6 are used to set the respective adhesive forces. The respective second adhesive force between the μ-LEDs 1 and the module areas 11 is provided by the second anchor elements 13.

FIG. 173D shows a subsequent step S3.2 of applying the μ-LEDs 1 to the target substrate 7, which is also done with the second transfer stamp 6. μ-LEDs 1 are applied to a target substrate 7, which is part of a display.

The adhesive force of the μ-LEDs 1 on the second transfer stamp 6 can also be changed by suitable movement guidance of the second transfer stamp 6 during lifting and setting down, e.g. by movement guidance with shear component, i.e. parallel to the target substrate plane. The adhesive force of the μ-LEDs 1 on the second transfer stamp 6 can be reduced, e.g. during setting down. By selecting a suitable material, a connection between the μ-LEDs 1 and the target substrate 7 can be provided with the required adhesive force. For example, adhesives, intervias or solder can be used.

Steps S3.1 and S3.2 are carried out several times until, for example, target substrate 7 of a display is fully populated for all colors of red, green and blue.

FIG. 173E shows further processing steps S4 on the target substrate 7, including the production of mechanical and electrical contacts on the target substrate 7 by means of conventional processes, such as deposition of an Intervia material, curing and subsequent structuring and/or back etching.

For example, a respective electrical top contact is produced in vertical μ-LEDs or both electrical contacts are produced in horizontal μ-LEDs. In addition, out-coupling structures or outcoupling layers or surface refinement layers are formed, for example to improve the black impression. Modularization can also be carried out. In this way, a large number of arrays A in μ-display design can be produced simply and cost-effectively.

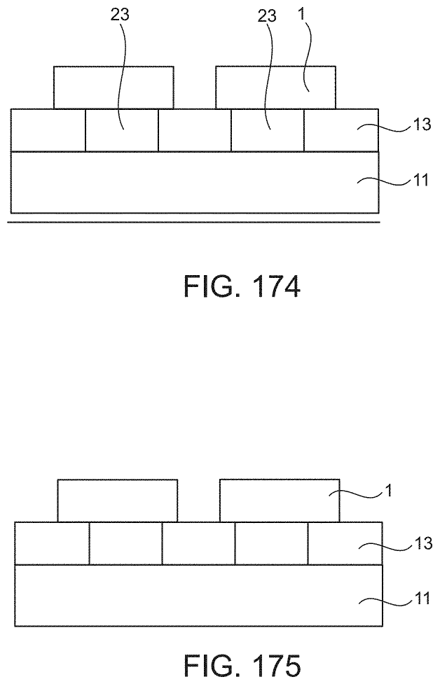

FIG. 174 shows a further example of a connection of μ-LEDs 1 at module areas 11, for which additional anchor elements 13 and second release elements 23 are provided in addition to the second anchor elements 13 and on these. Before executing a second transfer step S3 the μ-LEDs 1 are in contact with second anchor elements 13 and second enabling elements 23, each of which is connected to a module area 11. The μ-LEDs 1 are mechanically connected to the module area 11 with a large adhesive force by means of the second anchor elements 13 and the second enabling elements 23.

FIG. 175 shows the embodiment according to FIG. 174, whereby the second release elements 23 have been removed, thus effectively and purposefully reducing the adhesive force of the μ-LEDs 1 to the module area 11.

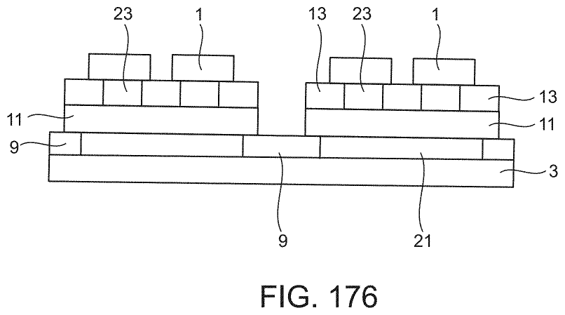

FIG. 176 shows a second start structure with μ-LEDs 1, which are connected to module areas 11 by means of second anchor elements 13 and second release elements 23, which are connected to a wafer 3 by means of first anchor elements 9 and first release elements 21. The μ-LEDs 1 are in contact with second anchor elements 13 and second enabling structures 23, which in turn are in contact with module area 11. The module areas 11 are in contact with first anchor elements 9 and first enabling elements 21. In contrast to the first start structure according to FIG. 172, enabling elements 21, 23 are used in addition to anchor elements 9, 13. In this way adhesive forces can be reduced in a targeted manner so that module areas 11 are removed first and μ-LEDs 1 afterwards by removing first release elements 21 and then second release elements 23.

The first anchor elements 9 for module areas 11 can vary in number, size and distribution. For example, they can be used to optimize a release process depending on the size of the module areas 11 in such a way that adhesive forces are selected in the correct ratio to lifting forces. A minimum lift-off force must be applied to enable lift-off. This minimum lift-off force can be set in a defined manner using anchor elements and release elements.

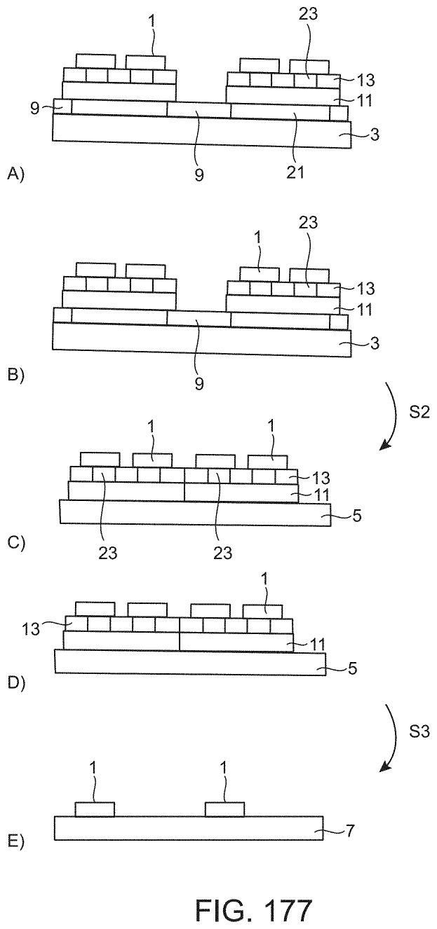

FIGS. 177A to 177E show a further example of an inventive method using the second launch structure shown in FIG. 176, which uses first release elements 21 and second release elements 23 in addition to first anchor elements 9 and second anchor elements 13. FIG. 177B shows that the first release elements 21 are removed first. FIG. 177C shows that in a first transfer step S2 module areas 11 are detached from wafer 3 and placed on the intermediate carrier 5. Then, as shown in FIG. 177D, the second release elements 23 are removed. In a second transfer step S3, the μ-LEDs 1 of module areas 11 are detached and placed on the target substrate 7. This step can be seen in FIG. 177E.

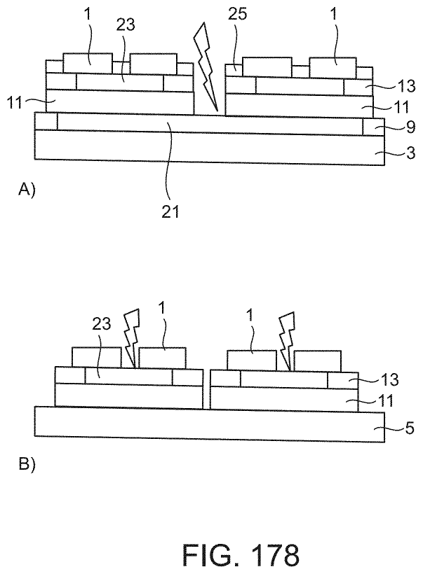

FIGS. 178A and 178B illustrate the aspect of selectivity of enabling elements. In FIG. 178A, the first share elements 21 are removed. FIG. 178B shows how two second release elements 23 are removed after the first release element 21 has been removed, the module areas 11 containing μ-LEDs 1 have been transferred to an intermediate carrier 5 and protective layers 25 have been removed.

Selectivity between first enabling elements 21 and second enabling elements 23 for successive removal can be achieved in different ways:

a) Different materials with different properties can be used, which are matched to each other. For example, SiO₂ can be etched with HF. Si can also be etched with SF6. Further possible materials are for example SiO₂, Si, Al₂O₃, SiN, SiON, AlN, HfOx, metallic layers as well as organic materials, which can be used as adhesives.
b) Different rates of material removal can be used. For example, by exposing relatively large areas of the first release element 21 to the removal process. In second release approval element 23, relatively small areas are exposed to the removal process. For example, only small openings are designed in such a way that liquids and/or gases can only penetrate slowly.
c) The second release elements 23 can be protected from the removal process by protective layers 25. After removal of the first release elements 21, the protective layers 25 can be removed, for example by dry chemical, wet chemical or gaseous etching, after which the second release elements 23 can be removed.
d) The release elements 21, 23 can be removed in different ways. For example, by means of chemical processes such as wet chemistry or by means of gas phases, by means of thermal processes, by means of mechanical processes, by means of optical processes, for example by using UV light.

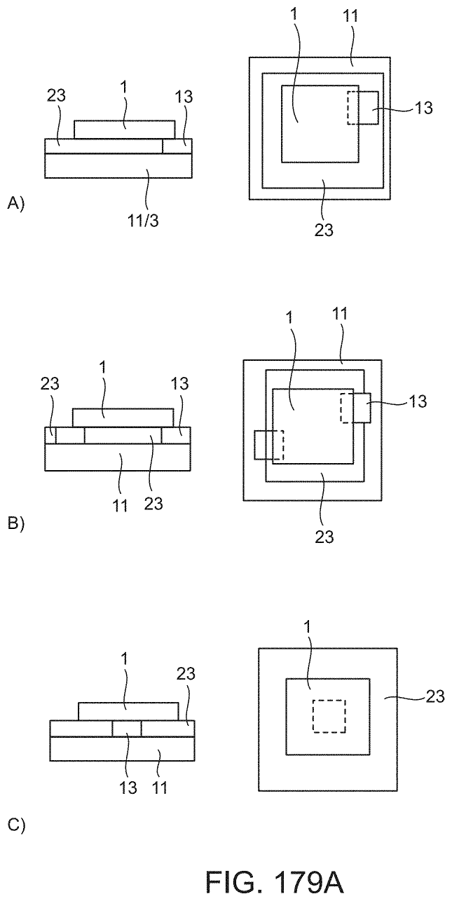

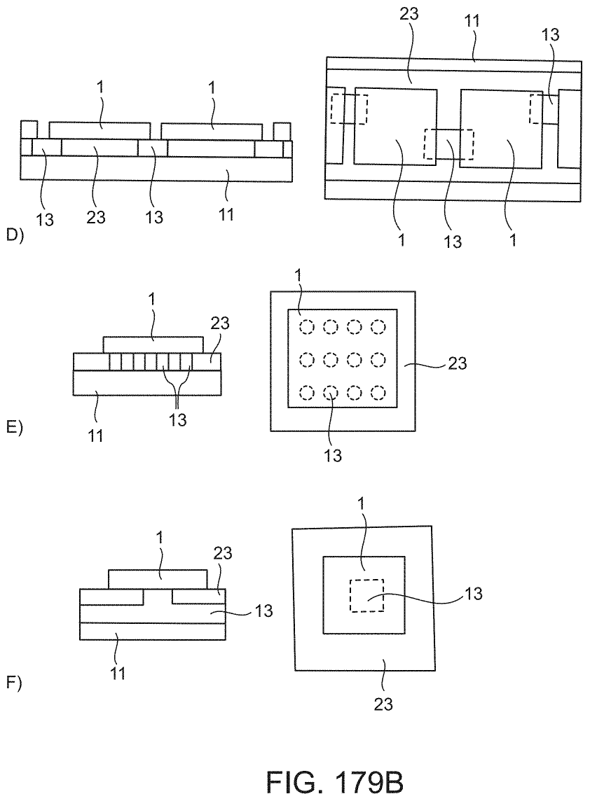

FIGS. 179A to 179F show embodiments of the arrangement of second anchor elements 13 and second release elements 23 between μ-LEDs 1 and module areas 11, which are here alternatively designed as a complete carrier substrate 3. The second anchor elements 13 for the μ-LEDs 1 can vary in number, size and distribution. For example, a release process can thus be optimized depending on the size of the μ-LEDs 1 in such a way that adhesive forces are selected in the correct ratio to lift-off forces. The second release elements 23 rest against the second anchor elements 13 accordingly. Anchor element 13 and release element 23 are also arranged on a module area 11, which is a carrier substrate 3. The main surface area of the module area 11 is greater than or equal to the main surface area of the release element 23.

FIG. 179A shows an embodiment in which a second anchor element 13 forms a smaller main surface area to μ-LED 1 and is partially connected to μ-LED 1 in an edge area at one corner of μ-LED 1. A second release element 23 comprises a larger main surface area than the μ-LED 1 and is arranged on the μ-LED 1 in such a way that the second release element 23 at least partially frames the second anchor element 13.

FIG. 179B shows a further embodiment in which two second anchor elements 13 each form a smaller main surface compared to μ-LED 1 and are arranged in the edge area at opposite corners of the μ-LEDs 1. A second release element 23 comprises a larger main surface area compared to the μ-LED and is arranged on the μ-LED 1 in such a way that the second release element 23 at least partially frames the second anchor elements 13. FIG. 179C shows a further embodiment in which a second anchor element 13 forms a smaller main surface compared to the μ-LED 1 and is arranged completely on the μ-LED 1 in a core area of the μ-LED 1. A second release element 23 completely frames the second anchor element 13.

FIG. 179D finally shows another embodiment in which a plurality of μ-LEDs 1 are arranged in a row to each other. Two second anchor elements 13 each form a smaller main surface compared to a μ-LED 1 and are each partially arranged in the edge area at opposite corners of a μ-LED 1. Each anchor element 13 is arranged on two μ-LEDs 1 arranged side by side and comprises a surface area uncovered by μ-LEDs 1. A second release element 23 comprises a larger main surface area than all μ-LEDs 1 and is arranged on the μ-LEDs 1 in such a way that the second release element 23 completely frames the second anchor elements 13.

FIG. 179E shows a further embodiment in which twelve second anchor elements 13 together form a smaller main surface than the μ-LED 1 and are arranged in the interior of the μ-LEDs 1 in the form of a matrix. A second release element 23 comprises a larger main surface area than the μ-LED 1 and completely frames the second anchor elements 13. Anchor elements 13 and release element 23 are also arranged on a module area 11, which can alternatively be a wafer 3. The main surface area of the module area 11 is greater than or equal to the main surface area of the release element 23.

FIG. 179F shows a final embodiment in which a second anchor element 13 forms a larger main surface area compared to μ-LED 1 and in its core area a protrusion which is completely arranged at μ-LED 1. A second release element 23 comprises a larger main surface area than the μ-LED 1 and is arranged on the μ-LED 1 in such a way that the second release element 23 completely frames the elevation of the second anchor element 13 and is arranged on the second anchor element 13. The main surface of the module area 11 is greater than or equal to the main surface of the second anchor element 13. The main surface of the release element 23 corresponds to the main surface of the second anchor element 13.

After light has been generated, it must be collimated and directionally coupled out as far as possible. Therefore the following explanations concern different aspects of light extraction.

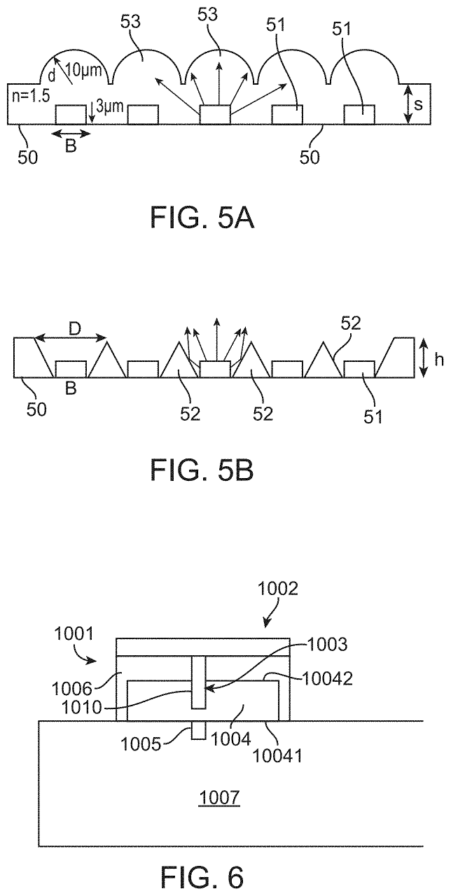

FIGS. 5A and 5B disclose some principles regarding the collimation and direction of light emitted by individual pixels. FIG. 5A shows a carrier 50, which also acts as a mirror by reflecting all light emitted by the LED 51 arranged on the carrier. Two adjacent LEDs are about 6 μm apart and about 3 μm high. Their diameter is in the range of 6 μm. Each individual pixel emits light similar to a Lambert spotlight. Consequently, they are completely covered with a transparent material with a refractive index of about n=1.5.

A hemisphere 53 of the same material with a radius of approximately 10 μm is arranged on each micropixel. Each hemisphere 53 covers the area of the underlying pixel 51 and extends to about half the distance to the next pixel. Because of the refractive index and geometry, the hemispheres are configured to collimate the light emitted by the individual pixels.

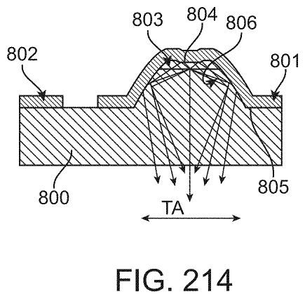

FIG. 5B shows an alternative concept for collimating the light emitted by the pixels. Similar to the above, the micropixels are arranged at equal distances from each other. Between each pixel, a pyramid 52 is placed on the support 50. The pyramids 52 are formed of highly refractive material and have distance D between their tips. The height of the apex of each pyramid is chosen so that light emitted at an angle less than 45° from the light-emitting surface is reflected on the sidewalls of the pyramid as indicated. By using the elements shown in FIG. 5B, light emitted by micropixels 51 can be parallelized to a certain extent, which improves its collimation. However, as the size decreases, it becomes increasingly difficult to shape elements 52 and 53 and to place them directly above the micropixels. FIG. 214 illustrates an example of a pixel for which, in one aspect, a rear decoupling is provided by shaping the pixel as a hemisphere and surrounding it with reflective material to shape the emitted light. The pixel is shaped as a half-dome within an n-doped first semiconductor material 800. A first contact 801 on a first side of material 800 serves as the n-contact for the corresponding pixel. A second contact 802 can be used for a variety of pixels.

Thus, it is possible to arrange the plurality of pixels next to each other to form a μ-display. Within the half-dome area of the pixel, an active layer 803 is arranged. The active layer is located in the upper third of the half-dome forming the pixel and is formed by a p-doped layer 804 deposited on the n-doped material in the half-dome. Other active layers such as quantum wells or structures mentioned in this disclosure are possible. In order to form the smallest possible region where recombination occurs, a current confinement process can be used. This keeps charge carriers away from the edge and the recombination area becomes smaller.

A reflective layer 805 is applied to the sidewalls and also to the upper surface of the material 800. The p-contact 801 is applied to the reflective layer 805. The reflective layer 805 also includes an insulating layer (not shown) to prevent a short circuit between the p-contact and the material 800. P-contact material 801 is in direct contact with the p-doped layer 804 through a gap in the reflective layer on the half-dome forming the pixel. As a result, the insulating layer on the reflective layer and the gap in the reflective layer causes carrier injection only at the tip of the half-dome. A current broadening layer can also be applied within the p-doped layer 804. Recombination of charge carriers occurs in the active region 803 Light emitted from the active region towards the side is reflected at the reflective layer towards the output surface TA. The shape of the half-dome is parabolic in some examples. The shape should be chosen to support collinearity for light generated within the active region. In some applications, other elements for guiding light, such as photonic crystal structures or similar are then arranged on the exit surface.

The following aspects deal with a different point of view in contrast to a direct improvement of the directionality of the emitted light. The following examples are intended for the creation of a Lambert radiator. However, it is known by the expert that other shapes on reflector elements influence the beam-shaping. Special designs thus create a μ-LED with rear output which can be directed at the same time.

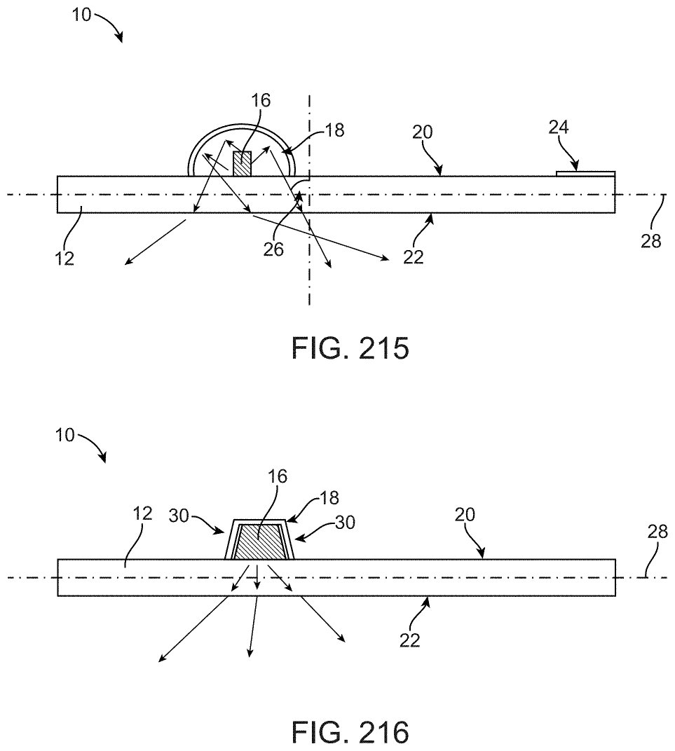

FIG. 215 shows an embodiment of a pixel element 10 with a reflector element 18 according to the invention. First of all, a carrier substrate 12 is also provided here, which often has a large number of μ-LEDs 16 arranged next to each other on an assembly side 20 of the carrier substrate 12. The carrier substrate 12 is usually provided with an electronic control unit 24, which is used to control the individual μ-LEDs 16. For this purpose, electrically conductive connections (not shown) may be provided between the control electronics 24 and the individual μ-LEDs 16. In other cases, as shown below, the carrier substrate can also be transparent or have other structures for reshaping the light.

The reflector element 18 here is designed like a dome and surrounds the μ-LED 16 at least on the side where the μ-LED 16 emits light 14. For example, if the μ-LED 16 emits light 14 in a direction away from the carrier substrate 12, this light hits a surface of the reflector element 18 directed towards the μ-LED 16, is reflected there and returned towards the assembly side 20 of the carrier substrate 12. If necessary, the light propagates with refraction at the interface of the assembly side 20 over a cross section of the carrier substrate 12 in the direction of a display side 22 of the carrier substrate 12 and is coupled out there, if necessary with repeated refraction or diffraction.

The reflector element 18 should have the advantageous shape and properties that light 14 is incident at an angle of incidence 26 as perpendicular as possible relative to a carrier substrate plane 28 on the placement side 20 of the carrier substrate 12. Among other things, this should serve to minimize losses due to total reflection within the carrier substrate 12 as well as unfavourable angles when decoupling from display side 22 of carrier substrate 12. This angle of incidence 26 should be as small as possible, also to minimize crosstalk between adjacent pixel elements 10.

FIG. 216 shows another example of a pixel element 10 according to the invention with a reflector element 18 configured as a layer on or around a μ-LED 16. This embodiment variant can be useful in that the reflector element 18 can be processed directly onto a surface of the μ-LED 16, for example as a metallic layer. Various materials can be used for the reflector element 18, such as metallic materials, metal alloys or oxides or other suitable compounds that can be applied using the available manufacturing processes. FIG. 214 shows a similar embodiment, in which the μ-LED is made directly from the same material as the carrier substrate. In addition, the reflector element has a specific shape and design. However, the various aspects of FIG. 214 can also be combined with the embodiments shown in FIGS. 215 to 216, among others, and disclosed here.

In addition, a passivation layer 32 is provided at the mesa edges 30 between the μ-LED 16 and the layer of the reflector element 18. This passivation layer 32 has light-absorbing or at least light-blocking properties so that light 14 emitted by the μ-LED in the direction of the carrier substrate plane 28 or in the direction of the mesa edges 30 is attenuated or absorbed. This is to prevent light 14 from passing over in the direction of an adjacent pixel element 10 and causing crosstalk. In addition, the passivation layers 32 can be configured to cause beam-shaping of the emitted light 14.

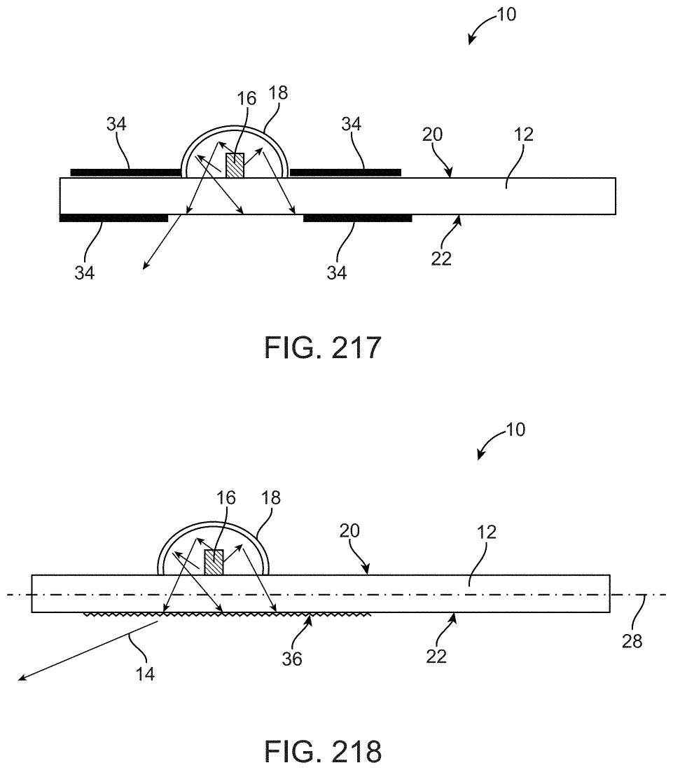

FIG. 217 shows a pixel element according to the invention with light-absorbing coatings 34 on a display side 20 and an assembly side 22 of the carrier substrate 12. This embodiment features a spherical reflector element 18 surrounding a μ-LED 16, which is arranged on the placement side 20 of the carrier substrate 12. According to this aspect, the carrier substrate 12 is adapted to be transparent or at least partially transparent so that light 14 can propagate within the carrier substrate 12.

In order to improve the dark impression and contrast of a display, light-absorbing layers 34 are provided according to this embodiment, which are applied here outside the reflector element 18 on the carrier substrate 12 on the assembly side 20 and/or on the display side 22. On the one hand, this can prevent light 14 from being coupled out outside a desired active area of the pixel element. On the other hand, an advantageous effect can be that light 14, which propagates inside the carrier substrate 12, is not coupled out outside the desired area on display side 22, but is absorbed or attenuated. For an observer, the light-absorbing layers 34 can be recognized as clearly inactive or black or dark, and due to the better optical demarcation compared to the active luminous areas, improved contrast properties of a display can be achieved.

FIG. 218 illustrates in a simplified way a further version of a pixel element 10 according to the invention. In its basic structure, pixel element 10 corresponds to the examples already shown in FIGS. 215 to 217. Here, a μ-LED 16 is provided on a carrier substrate 12, which is surrounded by a reflector element 18. By reflecting the light 14 at the reflector element 18, light 14 propagates through the carrier substrate 12 and reaches a display page 22 of the carrier substrate 12.

Here it is desirable that as much of the light 14 that has passed through carrier substrate 12 is coupled out of carrier substrate 12 via display screen 22. Here, a roughened surface 36 can cause an improved out-coupling of light 14. More generally speaking, the surface of the display side 22 comprises a structuring, which has additional microstructures at an angle to each other which deviate in their angle from the alignment parallel to a carrier substrate plane 28 and can thus cause additional out-coupling.

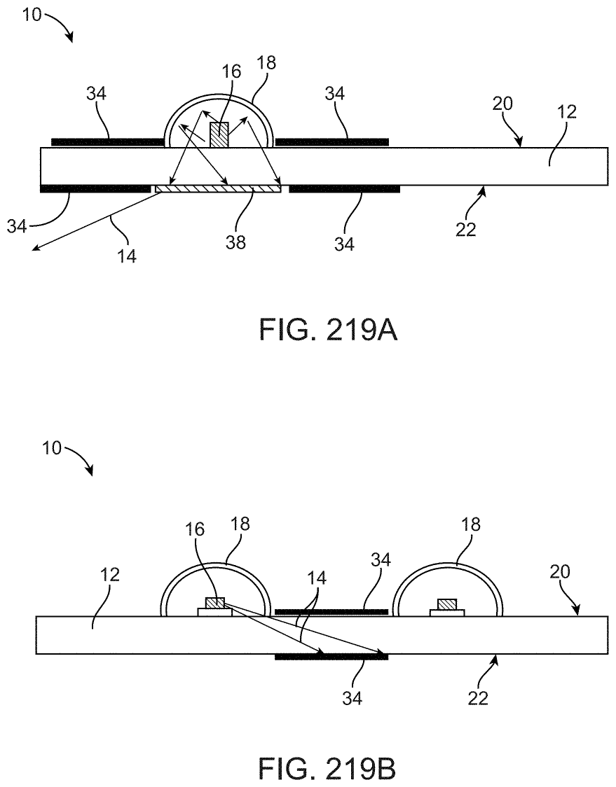

FIG. 219A shows a pixel element 10, according to the invention, with a color filter element 38 on the display side of the carrier substrate 12 and light-absorbing coatings 34. While the basic structure of the pixel element 10 corresponds to a large extent to that of the previous figures, light-absorbing coatings 34 are also provided here, which are provided both on an assembly side 20 and on a display side 22 of the carrier substrate 12 outside an area of the reflector element 18. In addition, a color filter element 38 is provided here, which is arranged on the display side 22 of the carrier substrate 12 opposite the reflector element 18. For example, a red μ-LED can be provided with a corresponding red color filter element 38. The same applies analogueously to green color filter elements 38 together with green μ-LEDs and, for example, to blue color filter elements 38 together with blue μ-LEDs and the respective emitter chips 16. The advantages here are lower reflectivity and an improved black impression. Here, too, the light-absorbing layers 34 absorb unwanted light components 14 that propagate within the carrier substrate 12.

In an alternative embodiment, again with reference to FIG. 219A, element 38 may also be a color conversion element to convert light of a first wavelength to a second wavelength. The light emitted by the μ-LED 16 and reflected by the reflector element 18 strikes the converter element and is converted there. The basic colors can be produced in this way by using different converter dyes.

FIG. 219B shows another example of a pixel element 10, where two adjacent pixel elements 10 are arranged on the carrier substrate. Between these two pixel elements, light absorbing layers 34 are provided on the different surfaces of the carrier substrate. This can be used in particular to minimize crosstalk. Depending on the arrangement and design of the μ-LED 16, there is a gap between the μ-LED 16 and the surrounding reflector element 18, which can act as an aperture or aperture edge. This can mean that light 14 emerges through this aperture at a small angle relative to the carrier substrate plane 28 and can pass through the carrier substrate 12 at an angle in the direction of the adjacent pixel element 10.

To prevent this crosstalk, light-absorbing layers 34 are provided between the two pixel elements 10 and between the two adjacent reflector elements 18, respectively. These can be arranged on an assembly side 20 of the carrier substrate 12, but also on a display side 22 of the carrier substrate 12. The light-absorbing layers 34 attenuate or eliminate the then unwanted light components 14 and can thus improve the contrast of a display.

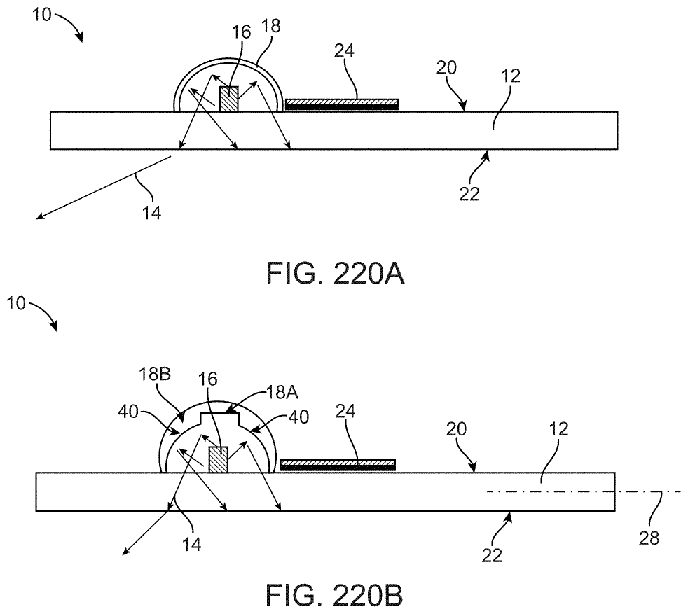

In FIG. 220A, reference is made to the aspect of the control electronics 24 of a pixel element 10 according to the invention. These may be adapted as part of the carrier substrate 12, with transistor structures, for example, being provided as part of the substrate 12. For the material of the carrier substrate 12, various materials can be considered, such as amorphous silicon, but also IGZO or LTPS. IGZO stands for indium gallium zinc oxide and has partially transparent properties for light and is comparatively inexpensive to manufacture.

If an electronic control unit 24 is designed on the basis of IGZO, it is also conceivable according to an example that the electronic control unit 24 can be arranged within an inner area of a reflector element 18 (not shown here). This possibility is based in particular on the at least partial light transmission of the IGZO material. According to another example, 24 LTPS is used as the basis for the control electronics 24 and LTPS as the material for the carrier substrate 12. LTPS stands for Low Temperature Poly Silicon and can have better electrical properties than IGZO, but with more light absorbing properties.

LTPS can be used for both μ-transistors and n-transistors, whereas IGZO is only suitable for μ-transistors. An arrangement of the control electronics 24, based on LTPS, must therefore be provided here outside a reflector element 18. A further alternative can be seen in the use of so-called μICs. These are often used together with silicon-based substrates and usually have light-absorbing properties.

A challenge here may lie in miniaturizing these ICs, whereby the electrical performance of the μICs is often higher than that of other variants. Here, too, an arrangement would, according to an example, be made outside an area of a reflector element 18 on the assembly side 20 of the carrier substrate 12. Contacting of the emitter chip 16 can be achieved, for example, via a metallic contact pad on the carrier substrate 12 or via transparent ITO (indium tin oxide).

FIG. 220B shows a pixel element 10 according to the invention with a partial coating of a diffuser layer 40 on the reflector element 18. The special feature of the pixel element 10 shown in this embodiment can be seen in a special embodiment of the reflector element 18. Here, a diffuser layer 40 is provided on the lateral inner surfaces of the reflector element 18 (here especially the area 18B). This diffuser layer 40 is intended to cause an increased deflection of the emitted light 14 and a more advantageous deflection of the light 14 in the direction of the carrier substrate 12. It can be advantageous here to provide a thinner or completely missing diffuser layer 40 in an area 18A of the reflector located vertically directly above the emitter chip.

In particular, this diffuser layer 40 can be made flat or even in this area 18A in order to focus the most direct possible back reflection of light emitted transversely to the carrier substrate plane 28 approximately vertically in the direction of the placement side 20 of the carrier substrate 12. A relatively thin diffuser layer 40 can be sufficient for this purpose, since μ-LEDs, due to their properties and construction, come closer to a Lambertian radiation pattern than previous LED technologies. Materials that can be used for this purpose include Al₂O₃ or TiO₂.

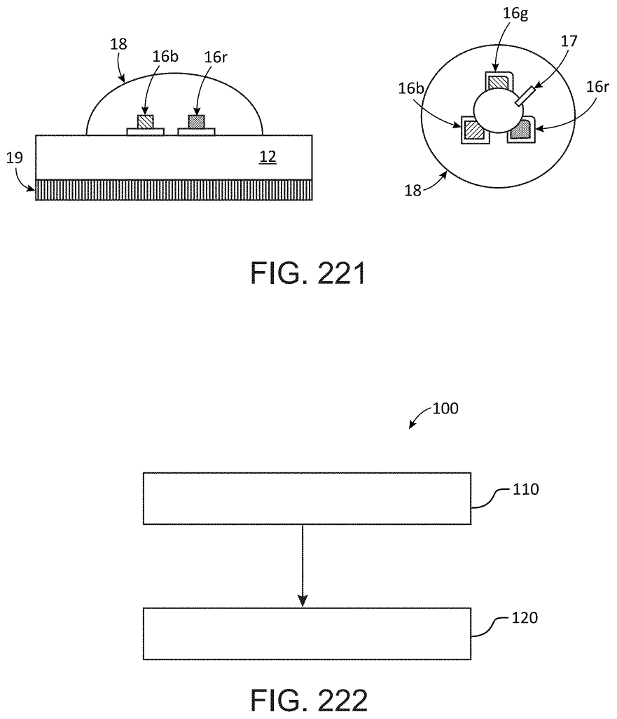

FIG. 221 shows another pixel cell in cross-section and top view. The pixel cell comprises three individual μ-LEDs 16r, 16g and 16b. These are designed to emit the respective basic colors red, green and blue during operation. In this embodiment, the three μ-LEDs are arranged in the corners of a right-angled triangle. However, other arrangements are also possible, for example in a row. Each μ-LED is adapted as a vertical μ-LED, i.e. a common contact is located on the side of the μ-LEDs facing away from the carrier substrate. The μ-LEDs can be individually controlled and can be manufactured, for example, in some versions as shown in FIGS. 49 to 54. Other designs are also conceivable, for example as individual μ-LED modules with or without redundancy. In the illustration on the right, a common transparent cover contact 17 is provided for this purpose, which either completely or at least partially covers the μ-LEDs and thus makes electrical contact. The sidewalls of the μ-LED are insulated and are not connected to the cover electrode 17. In addition, a reflector element 18 is provided which surrounds each of the three μ-LEDs and thus forms a complete pixel.

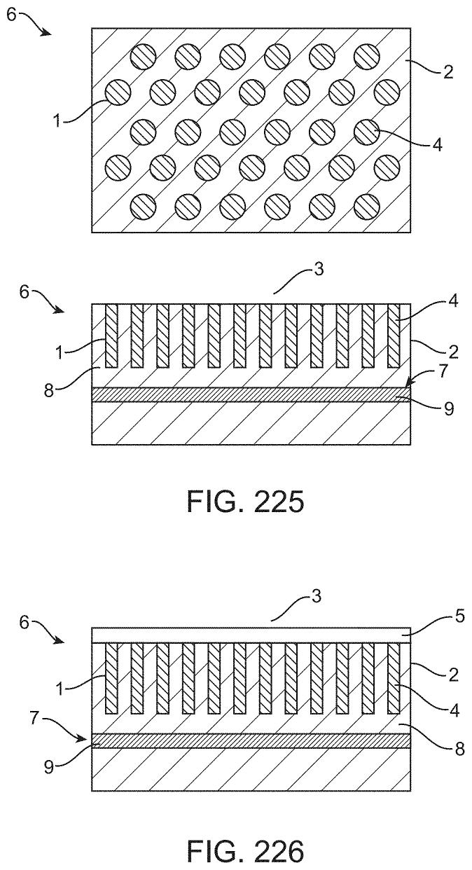

Light, which is thus emitted in the direction of the reflector element, is reflected by the carrier substrate where it hits a photonic structure 19, which is partly incorporated in the carrier substrate. The photonic structure 19 is designed to redirect the emitted light and emit it as a collimated light beam. Various embodiments of such photonic structures are disclosed in this application, for example in FIG. 225 to 228, 239 to 247 or even 223A to 223C.

The photonic structure can also be omitted depending on the application. For automotive applications, a Lampertian radiation pattern may be more desirable, in which case it is omitted. In the field of Augmented Reality a strong directionality may be desired, which is achieved by the additional photonic structure. In addition to the photonic structure, a converter material can also be provided in addition to the structure or alternatively. In the automotive sector, such directional light applications with white or other colored light are possible.

Finally, FIG. 222 shows a process 100 for the production of a pixel element 10. First, one or more μ-LEDs are attached to one side of a flat carrier substrate. The attachment is preceded by a corresponding transfer. Details are disclosed in this application.

This is followed in step 120 by creating a reflector element, for example as a reflective layer of the μ-LED. According to an example, before step 110, a display side 22 of the carrier substrate 12 is processed to produce a roughening 36 or rough microstructuring of the surface of the display side 22.

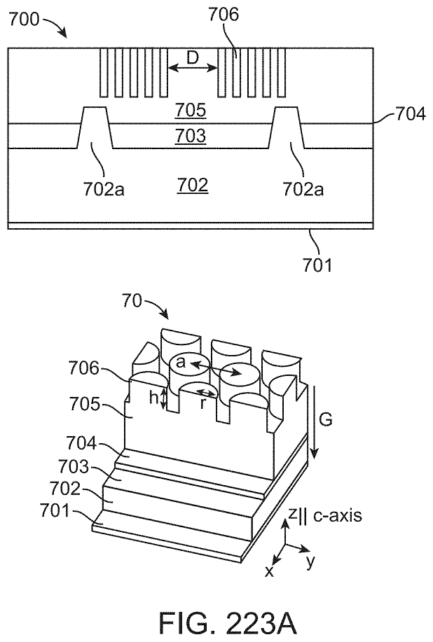

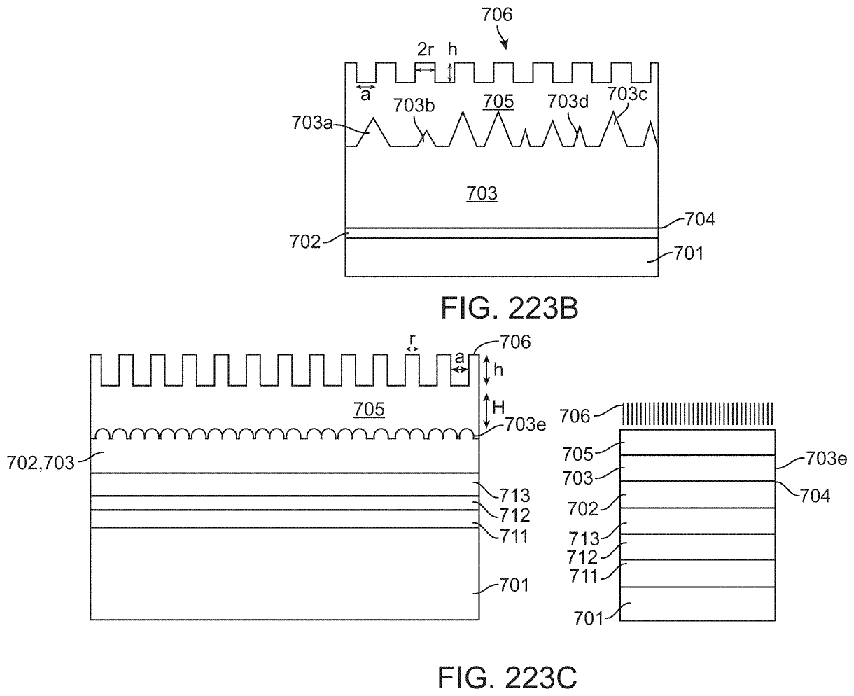

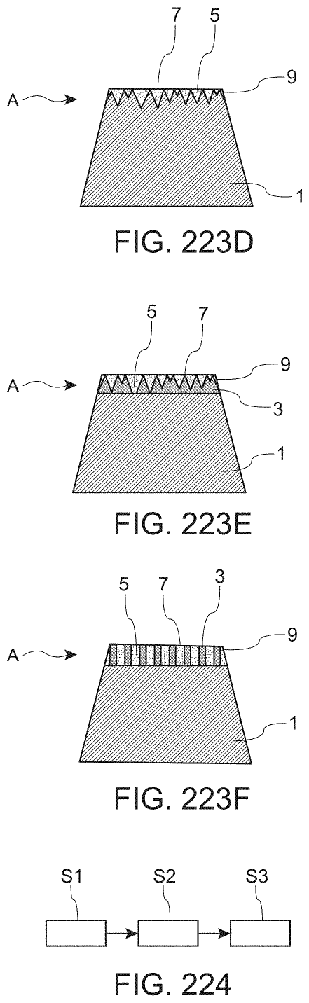

One way to reduce the emission angle of μ-LEDs is to indicate structures on the emission surface that reduce the propagation of light parallel to the emission surface. This can be achieved by photonic structures. The photonic crystal structure is basically not limited to a certain material system. The following examples and embodiments will give different ones, which are not limited to a specific design, but are suitable for all embodiments and designs disclosed herein. Furthermore, different semiconductor material systems can be used for the μ-LEDs, especially on GaN, AlInGaP, AlN or InGaAs basis. FIGS. 223A to 223C illustrate different aspects related to the principle of collimation of light by using a photonic crystal.

The exemplary optoelectronic device 700 of FIG. 223A comprises a stack of layers 702, 703 including an active zone 704 for generating electromagnetic radiation, and at least one layer 705 on the main radiation direction, which comprises a photonic crystal structure 706.

For example, layer 702 is a p-doped GaN layer and layer 703 is an n-doped GaN layer. The layer on the underside 701 can be a metallic mirror layer and/or a carrier layer. The growth direction G goes from the top side to the bottom side, or vice versa, and orthogonal to the connecting surface of the layers.

The photonic crystal structure 706 is formed by nanowires with radius r and height h. The wires form a triangular lattice with lattice constant a. However, other lattice geometries such as square lattice are possible. The periodicity and thus the lattice constant a of the photonic crystal structure are such that they are about half the wavelength of the light wavelength to be diffracted. The space between the wires may contain a material, which has a different refractive index than the material of the layer 705. For example, layer 705 may be formed of n-doped GaN. Other materials and SiO₂ are also possible.

The layer 702 can be supplied with an extension 702a, which extends through the layer 703 and reaches into the layer 705 but not into the photonic crystal structure 706 as shown in the lower view of FIG. 223A.

The photonic crystal structure 706 can have the effect of improving the concentration of light passing through it. In particular, the photonic crystal structure 706 can provide a virtual bandgap for a region of wavelengths that are perpendicular to the direction of growth. The photonic crystal structure 706 can block this light. In contrast, light that runs along the direction of growth is basically not disturbed by the photonic crystal structure 706. As shown in the upper view of FIG. 223A, the photonic crystal structure 706 in layer 705 can be generated twice or even more. The structures 706 are separated from each other by the distance D.

Alternatively, a single photonic crystal structure 706 can be fabricated to cover the complete layer 705. In this case, more unit cells of the lattice can be arranged in layer 705, which has a positive effect on the properties of the photonic crystal structure, which depend on the periodicity.

In the exemplary device shown in FIG. 223B, layer 702 is not supplied with an extension. However, layer 703, which is adjacent to layer 705 with crystal structure 706, is provided with a roughened surface, as indicated by projections 703a, 703b, 703c and 703d. The roughened surface can be filled with SiO₂, for example, to fabricate layer 705 with photonic crystal structure 706.

In the exemplary device shown in FIG. 223C, the layer 703 is formed with a wigwam surface roughening 703e. The layer 705 with the photonic crystal structure 706 may contain SiO₂. The photonic crystal structure 706 may be etched into the SiO₂ layer. Air or other material may be in the space between the photonic crystal structure.

The photonic crystal structure 706 covers the complete layer 703 and is placed at a distance H from the wigwam surface roughening 703e of the underlying layer 703.

Layer 701 is a carrier layer, layer 711 can be a compound layer, layer 712 is a mirror layer, especially a silver mirror layer, and layer 713 can be a dielectric layer. A mesa dry etch can be performed during device production and after patterning the photonic crystal structure 706.

The different photonic decoupling structures create a certain roughness and surface structures on the surface, depending on their design. Therefore, the surface should be planarized to facilitate a possibly necessary later transfer. FIGS. 223D to 223F show different aspects of surface planarization according to one of several methods of making photonic structures on a μ-LED.

Generally, a large number of μ-LEDs are first formed in or on a wafer, then their surface is structured and then, if necessary, separated. Modules of μ-LEDs and other designs are part of this application. It is clear from this that the μ-LEDs come in different designs. The following surface treatment is thus independent of the later processing and is suitable for (later isolated) μ-LEDs, μ-LED modules and also pixelated optochips with a plurality of μ-LEDs.

According to FIG. 223D, a μ-LED is epitaxially formed with an active layer in a semiconductor body. The active layer is not shown here. The μ-LED comprises in its surface area, which is covered by the likewise not shown carrier, a non-ordered, i.e. random out-coupling structure A, which is formed from the same semiconductor material as the semiconductor (or parts thereof). The structured surface region therefore adjoins the doped layers. The resulting roughness is smoothed again by applying another transparent material of SiO₂ by means of TEOS (tetraethylorthosilicate) and subsequently planarizing it. The decoupling structure improves the decoupling. It is particularly suitable for the extraction of the light emitted by the active layer. This also reduces optical crosstalk of an adjacent μ-LED with a different wavelength.

The other transparent material shows a low refractive index, especially less than 1.5, which improves the decoupling from the structured area (higher refractive index). Afterwards the other material is removed by CMP process to form the smooth surface 7 of the structured surface area 9. As shown, the removal is either carried out up to the highest areas of the structured area or a surface of the material 5 is generally left over. In this respect, a gradual transition from a high refractive index via the lower refractive index of the material 5 to air results.

In addition to SiO₂ material 5, crown glass with a refractive index of e.g. 1.46, PMMA with a refractive index of e.g. 1.49 and quartz glass with a refractive index of e.g. 1.46 can be used. These refractive indices result at the wavelength 589 nm of the sodium D-line. A refractive index of silicon dioxide, for example, is 1.458.

FIG. 223E shows a second example of a μ-LED with an output structure. To improve light out-coupling, a transparent second material 3 with a high refractive index is applied to the planar or structured surface of the μ-LED and structured in a suitable way.

For example, a suitable second material 3 with a high refractive index greater than 2 is Nb₂O₅ with a refractive index of 2.3. Other usable materials with a high refractive index are for example zinc sulphide with a refractive index of for example 2.37, diamond with a refractive index of for example 2.42, titanium dioxide with a refractive index of for example 2.52, silicon carbide with a refractive index of for example 2.65 and titanium dioxide with a refractive index of for example 3.10. These refractive indices result in particular at the wavelength 589 nm of the sodium D-line. Other materials can also be used.

The structuring of surface area 9 is done, as in FIG. 223D, by creating a random topology on surface area 9. While according to FIG. 223D the random topology is created by directly roughening the surface 7 of the surface region 9 of the semiconductor body comprising a first material 1, according to FIG. 223E the random topology is formed by first depositing the transparent second material 3 and then roughening it.

After the topology has been created, the rough surface is smoothed by applying the transparent material 5 described above to the rough surface and then planarizing it.

FIG. 223F shows a third example of a μ-LED, but this time with an ordered topology. This is explained in detail as in the examples in this application by depositing the transparent second material on the surface. A periodic photonic crystal structure is then introduced into the second transparent material. Alternatively, photonic properties can be achieved by non-periodic structures, especially quasi-periodic or deterministic aperiodic structures.

Alternatively, periodic photonic crystals or non-periodic photonic structures, in particular quasiperiodic or deterministic aperiodic photonic structures, can in principle be directly incorporated into the first material 1 of the semiconductor body without a second material 3.

After the photonic structure has been formed, the interstitial spaces are filled with a transparent material with a lower refractive index. The transparent third material 5, in particular SiO₂, is planarized, resulting in a smooth and even surface. As shown in FIG. 223F, both the surface of material 3 and the interstitial material 5 are flat. However, in an alternative embodiment, the transparent third material 5 extends beyond the structure of material 3, so that the surface is completely formed from material 5. In this way, an out-coupling efficiency can be improved compared to an unmachined surface. A transfer process using stamp technology remains possible because of the smooth and even surface.

FIG. 224 shows an example of a proposed method. In a first step S1 an output structure A is formed on a surface of a μ-LED. This is done by structuring the surface. It is possible to structure the semiconductor material directly or to provide such a structuring after the deposition of a further material. For this purpose, the surface is covered with a photomask, which is then exposed to light, thus defining the structures. The surface is structured by various other processes including various etching steps. In step S2, another transparent material is deposited in the spaces created after etching. The transparent material covers the previously created structure. Subsequently, in step S3 the surface is planarized by CMP or other suitable processes and removed to approximately the height of the structures. The structured μ-LED thus produced can be further processed, separated and transferred.

FIG. 225 shows in a top view and a sectional view a radiation source 6 in the form of a μ-LED and with a layer 2 arranged in a semiconductor substrate 8 of the μ-LED 7, which comprises a photonic structure 4 with a suitable converter material. This is based on the idea of creating a unification of light-shaping and converting structure so that a particularly space-saving arrangement of the individual elements and thus a particularly small design of an optoelectronic component is possible. The structured layer 2 with the converter material forms a converter element 1, whereby the converter material emits converted radiation into a radiation emission area 3 of the radiation source 6 when excited by the excitation radiation emitted by the LED 7.

The structure 4 provided in layer 2 with the converter material is designed in such a way that the converted radiation is emitted exclusively as a directed beam in a specific radiation area 3. According to the embodiment shown in FIG. 225, the converted radiation is emitted perpendicular to a plane in which the μ-LED chip with its semiconductor substrates is located.

The structured layer 2 shown in FIG. 225 is a two-dimensional photonic crystal etched into the LED semiconductor substrate above the active layer of the μ-LED. The individual, here rod-shaped and periodically arranged recesses of structure 4 have been filled with the converter material. The layer thickness of structure 4 is at least 500 nm, so that a band gap is created in the crystalline solid-state material, which causes a directionality of the converted radiation emitted by converter element 1. In this example, the recesses are round and arranged in a hexagonal pattern in the center of which a recess is also arranged. However, the recess itself can also take other shapes, for example hexagonal or square. Round recesses have the advantage that they are easier to produce. The recesses show the same distance and have the same size. This circumstance is also due to the application.

For example, the recesses can be of different sizes or have different spacing. This results in a different periodicity, so that a different optical band gap is formed. In a similar embodiment, the recesses can have a first periodicity in a first direction (i.e. first distance from each other and size) and a second periodicity in another, e.g. orthogonal direction. This result in a different band gap in the two spatial directions and a wavelength-dependent selection can be made. With a suitable setting, a full conversion of the incident light is possible, so that the μ-LED emits converted light substantially parallel to the recesses.

Such a photonic structure can significantly increase directionality and thus efficiency, especially of etendue-limited systems. Due to the provision of a layer 2 with a corresponding structure 4 and suitable converter material directly on the surface of the μ-LED 7, the otherwise additionally provided optical elements can be dispensed and thus a comparatively small radiation source can be realized by exploiting the invention. In addition, a particularly efficient radiation source is made available, since on the one hand, no light is emitted in an unneeded direction that is not perpendicular to the LED chip surface, and on the other hand, all the converted light can be used. Furthermore, modes of the excitation radiation emitted by the μ-LED 7, which are guided in the active zone 9 and have a low extraction efficiency from the μ-LED 7, can be efficiently converted.

In addition, FIG. 226 shows the sectional view of a radiation source 6, which is configured as explained in connection with FIG. 225, but additionally has a filter element 5 applied to the top layer of the radiation source 6 in the form of a filter layer 5, which is opaque to radiation of selected wavelength ranges. The filter layer 5 has the function of a color filter.

Such a technical design is particularly suitable for radiation sources 6, in which a μ-LED 7 and a converter element 1 are combined in such a way that the light emitted by the μ-LED 7 is fully converted. With the aid of a suitably designed filter layer 5, the radiation emitted in the emission range 3 can thus be limited to radiation with a desired wavelength. Such a filter layer 5 also ensures that the excitation radiation emitted by LED 7, which is not converted into converted radiation by converter element 1, is prevented from escaping into emission range 3 by means of filter layer 5 if necessary.

In an alternative embodiment, layer 3 of FIG. 226 assumes an out-coupling function in order to appropriately couple out the light formed by the photonic structure. However, a combination of these two functionalities is also possible. In this context, layer 3 can also be structured, for example roughened, in order to better couple out the light.

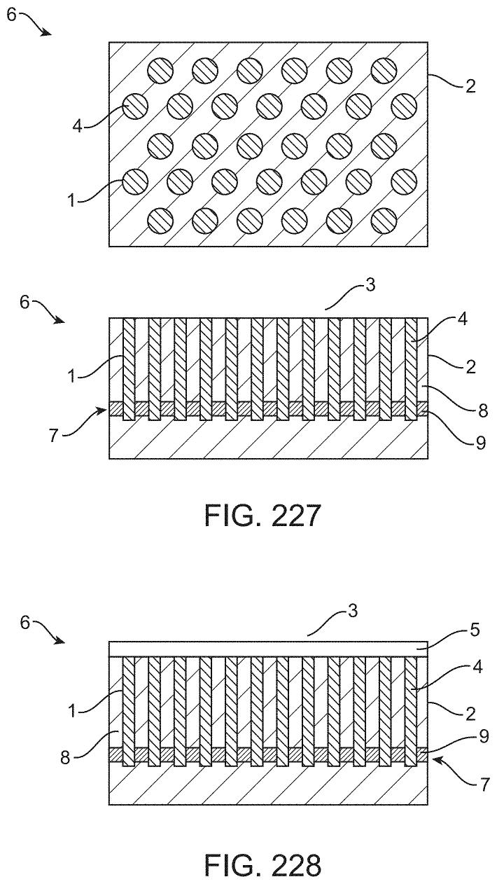

FIG. 227 again shows a radiation source 6, which has a μ-LED 7 and a converter element 1 applied to a semiconductor substrate 8 of the μ-LED 7. Converter element 1 comprises a layer 2 with converter material and a structure 4, which is applied to a semiconductor substrate 8 of LED 7. The structured layer 2 is preferably a photonic crystal, a quasi-periodic or deterministically aperiodic photonic structure. The structure 4 of layer 2 is filled with suitable converter material.

In contrast to the embodiment explained in FIG. 225, however, the structured layer 2 is not only arranged in a semiconductor substrate in the upper area of the radiation source 6, but extends into the active zone 9 of the μ-LED 7. Again, a structured layer 2 with a layer thickness greater than 500 nm is provided, thus creating an optical band gap. Also in this case, modes of the excitation radiation emitted by the μ-LED 7, which are guided in the active zone 9 and have a low extraction efficiency from the LED, can be efficiently converted.

In addition, FIG. 228 shows a configuration of a radiation source 6, which is configured as shown in FIG. 227 and additionally has a filter element 5 applied to the top layer of the radiation source 6, which is designed in the form of a filter layer serving as a color filter. Such color filters offer the possibility to limit the emission of the converted radiation into the emission range in case of a full conversion of the excitation radiation emitted by the μ-LED 7 or to selectively suppress the emission of unconverted excitation radiation in case of a not complete conversion.

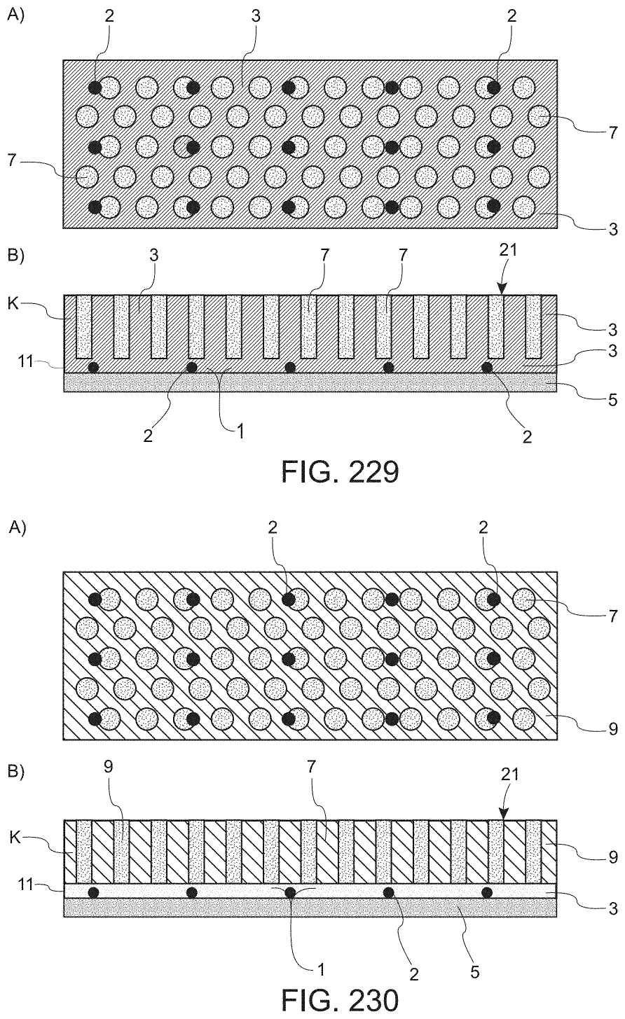

FIGS. 229A and 229B show a μ-display with a photonic structure for the emission of light that preferably emerges vertically from a light emission surface 21. The device comprises an array 11 having pixels, wherein optically acting nanostructures in the form of a photonic crystal K are formed over the entire emitting surface of the light exit surface 21. The array 11 also comprises an array-like arrangement of light sources, each of which comprises a recombination zone 2, which lies in a recombination plane 1.

The recombination zones 2 are formed in a first layer of optically active semiconductor material 3 of array 11. The zones 2 can comprise quantum dots, one or more quantum wells or even a simple pn junction. In order to obtain more localized recombination regions, it may be intended to limit recombination to predefined areas by current confinement or other structural measures.

In the layer with the semiconductor material 3, the photonic crystal or photonic crystal structures K are structured, namely in the form of a two-dimensional photonic crystal. The photonic crystal K is located between the recombination zones 2 and the light-emitting surface 21. The photonic crystal structures K can be arranged independently of the positioning of individual pixels, whereby in the example shown one pixel corresponds to one or three light sources with a recombination zone 2. Three light sources, therefore, so that any color can be produced by suitable color mixing.

The optically active photonic crystal structures K are filled free-standing in air or, as shown, with a first filling material 7, in particular electrically insulating and optically transparent, in particular SiO₂, with a refractive index which is lower than the refractive index of the semiconductor material 3. The filling material 7 preferably also comprises a low absorption coefficient.

In the array 11, both electrical poles of each light source are electrically connected by means of an optically reflective contact layer 5 for the electrical contacting of the light sources. The contacting layer 5 is located on a side of the optically active semiconductor material 3 facing away from the optically active photonic crystal structures K and is arranged below as shown in FIG. 229B. This type of contacting enables very strongly localised recombination zones 2. For this purpose, the contacting layer 5 comprises at least two electrically insulated areas in order to be able to connect the poles electrically separately.

The photonic crystal K can be structured over the entire emitting surface 21 in such a way that at least approximately only light with a propagation direction perpendicular to the surface 21 can leave the component. If the photonic crystal K is close to the recombination plane 1 and the layer thickness of the photonic crystal K is large in comparison to the distance to the recombination zone 2, the optical density of states in the area of light generation is additionally changed.

This makes it possible to generate a complete bandgap for optical modes with propagation direction parallel and at a small angle to the surface of the, in particular, planar, i.e. in particular flat and/or smooth, pixel-containing array 11. The emission of light with propagation direction parallel to the emitting surface is then completely suppressed.

In particular, light can only be generated in a limited emission cone, which is defined by the photonic crystal K. In this case, directionality is already ensured at the level of light generation, which effectively increases efficiency compared to an angle-selective optical element, since such an element only influences light extraction.

The alignment of the photonic crystal K is independent of the positioning of the individual pixels, especially in such a way that an alignment of the pixel structure to the photonic structure K is not necessary and processing of an entire wafer surface is possible. It is a reasonable embodiment if the device is homogeneous in its optical properties over the entire surface of the array 11 or varies only slightly so as not to disturb the optical environment of the photonic crystal K.

FIGS. 230A and 230B show a second proposed optoelectronic device in a plan view and in cross-section respectively. In the pixelated array 11, the photonic crystal K is arranged in a second layer of a material 9, in particular Nb₂O₅, above a first layer of the optically active semiconductor material 3, as an alternative to the embodiment shown in FIGS. 229A and 229B. The material 9 thereby has a large optical refractive index and it is arranged on the flat and/or smooth surface of the semiconductor material 3. Preferably, the material 9 also comprises a low absorption and is therefore very transparent. The contacting is similar to that shown in FIGS. 229A and 229B and allows very localized recombination zones 2.

Alternatively, some embodiments may provide that the material is also electrically conductive. This is especially useful if the different pixels are designed with vertical μ-LED packages and are to be connected to a common contact.

As shown in FIGS. 229A and 229B, columns are formed from the material 9 and the photonic crystal K is in turn formed as a free-standing two-dimensional photonic crystal. The space between the columns is filled with a different material with a lower refractive index than in FIGS. 229A and 229B. A possible filling material is for example SiO₂.

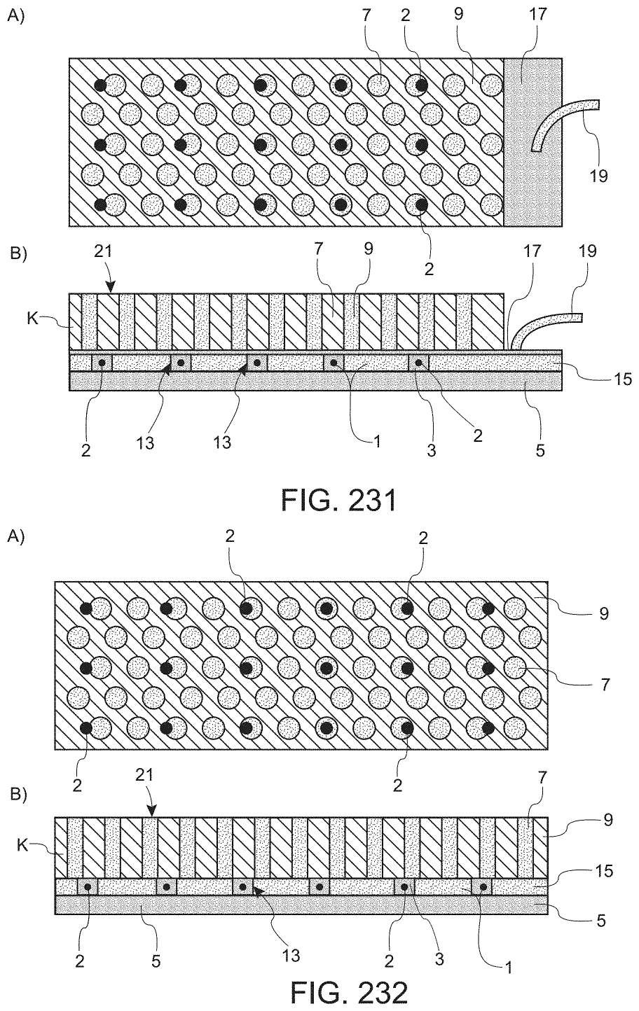

FIGS. 231A and 231B show a third proposed optoelectronic device in a top view and in a cross-section, respectively. The device shown comprises as light sources an array of vertical μ-LEDs 13 and a two-dimensional photonic crystal structure K arranged in an overlying layer, which extends over the entire emitting surface 21 and is formed from a material 9 with a high refractive index. The free space of the structure K is in turn filled with filler material 7 with a lower optical refractive index.

The vertical light-emitting diodes 13 have an upper and a lower electrical contact along a vertically oriented longitudinal axis, which is perpendicular to the light-emitting surface 21. The light-emitting diodes thus comprise an electrical contact on the front side and an electrical contact on their rear side. The rear side is the side of the μ-LEDs 13 facing away from the light emission surface 21, while the front side faces the light emission surface 21.

The device comprises an electrically conductive and the generated light reflecting contacting layer 5 for the electrical contacting of the contacts on the back of the LEDs 13 The contacting layer 5 is designed in such a way that the individual μ-LEDs can be controlled separately. For the electrical contacting of the contacts on the front of the LEDs 13, a third layer is provided, which comprises an electrically conductive and optically transparent material 17, for example ITO. An electrical connection to the corresponding pole of a power source can be established via a bonding wire 19.

In and along the recombination level 1, a further, in particular electrically insulating, filling material 15 can be arranged between the third layer and the optically reflective contacting layer 5. This electrically separates the μ-LED from each other. In addition to this structure shown here, other pixelated components disclosed in this application may also be provided with the structure K. These include, for example, the disclosed antenna structures, the μ-LED in bar form or the μ-LED modules. Likewise, in all the embodiments shown here, reflective structures may be provided in layer 5 which deflect the light in the direction of the exit surface. These include the structures surrounding the actual μ-LED, which are disclosed in this application.

FIGS. 232A and 232B show a fourth version of a μ-display in a top view and cross-section. The μ-display or module device comprises an array of horizontal μ-LEDs 13 with respective recombination zones 2 and an optically effective two-dimensional photonic crystal structure K below the total emitting surface 21. The photonic crystal structure K is located in a layer of a material 9 with a high refractive index, for example Nb₂O₅. Free spaces are in turn filled with filling material 7, for example silicon dioxide, with a lower optical refractive index.

In the case of the horizontal LEDs 13, both electrical contacts are located on the rear of the LEDs 13. Both poles of the LEDs 13 are electrically connected by means of electrically separated areas of the optically reflective contact layer 5. In the area of the recombination level 1, a filling material 15, in particular an electrically insulating one is arranged between the material layer 9 and the contacting layer 5.

The efficiency with respect to light generation is relatively high in the embodiments according to FIGS. 229A to 232B, since in these embodiments directionality or directionality of the light is already achieved during light generation, especially if a higher photonic state density can be achieved in the area of the recombination zones 2 for the emission of light in the direction perpendicular to the light exit surface by means of the band structure of the photonic crystal K. A further advantage is that the structuring of the photonic crystal K can be carried out homogeneously over an entire wafer. A certain positioning or orientation of the photonic crystal to the individual pixels or micro light emitting diodes is not necessary. This will significantly reduce manufacturing complexity, especially compared to alternative approaches where structures are placed individually over each pixel.

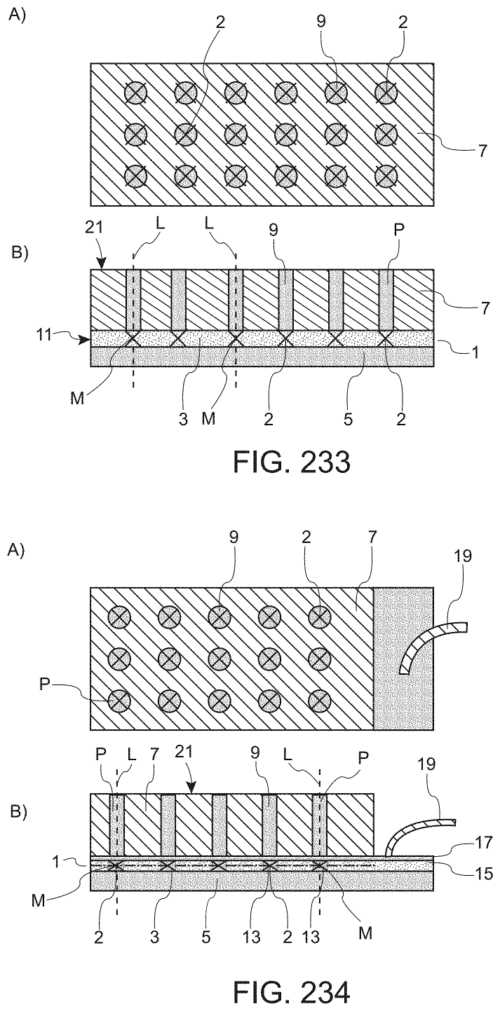

FIGS. 233A and 233B show a fifth proposed optoelectronic device in a top view and cross-section. The device comprises a pixelated array 11 and optically acting columnar or pillar structures P, in particular with pillars or columns structured over the entire emitting surface 21. The array 11 is smooth and flat on its surface.

The pixelized array 11 in this configuration comprises a large number of subpixels, each with a light source that includes a respective recombination zone 2. The recombination zones 2 of the pixels are located in a recombination plane 1 and they are arranged in a first layer with optically active semiconductor material 3.

Above this first layer the pillar structures P are formed. One pillar P is assigned to a light source, so that each Pillar P is located directly above the recombination zone 2 of the assigned light source. A longitudinal axis L of each pillar P runs in particular through the center M of the recombination zone 2 of the assigned light source 2. The pillars P consist of a material 9 with a high refractive index, for example Nb₂O₅. A filler material 7 with a lower refractive index, such as silicon dioxide, can be arranged in the spaces between the pillars P.

The pillars P can be arranged above the layer with the light sources, in particular by additionally applying the pillars P above array 11. Alternatively, the pillars can be etched into the semiconductor material 3. For this purpose, the semiconductor material layer must be appropriately high. Since the semiconductor material normally comprises a high refractive index, material can be etched away in such a way that the pillars 9 remain standing. The areas freed up by etching can be filled with material of low refractive index.

The pillars P act like waveguides which guide light upwards in the direction of the longitudinal axis L, so that the pillars P can cause an improved emission of light in a direction perpendicular to the light emission surface 21. In addition to the design shown here, the periodicity of the pillar structures can also be different, for example, the pillars can be located alternately above one μ-LED and between two adjacent μ-LEDs. This results in a double density of columns. The periodicity determines the optical band structure and thus the properties with regard to light extraction.

In the array 11, both electrical poles of a light source are electrically connected to the recombination zones 2 by means of a reflective contact layer 5. The contacting layer 5 is formed on a side of the semiconductor material 3 that is turned away from the optically active pillar structures P. The contacting layer 5 can have two separate areas in order to be able to contact electrically the two poles separately. This type of contacting allows very localized recombination zones 2.

FIGS. 234A and 234B show a sixth optoelectronic device in a top view and cross-section. The device comprises an array of vertical μ-LEDs 13. Optically active pillar structures P, in particular with pillars or columns, are arranged above the array of μ-LEDs 13. The longitudinal axis L of the pillars P runs at least essentially through the centers of the recombination zones 2 of the μ-LEDs 13.

Pillar structures P may be free-standing in air or filled with a first filling material 7, in particular electrically insulating and optically transparent, above the light-emitting diodes. The filling material 7 may comprises a lower refractive index than the refractive index of the material 9 of the pillars P and/or the semiconductor material 3 of the μ-LEDs 3. The reverse form is also possible, i.e. material 7 has a higher refractive index than the material of the pillars, but this changes the light guidance of the pillars.

As already mentioned, the μ-LEDs are vertical micro-light emitting diodes 13, which comprise one, especially positive, electrical pole on their back side facing the reflective contact layer 5 and another electrical pole on the front side facing the pillars P.

The pole at the front of the light sources is electrically connected to an appropriate power supply (not shown) by means of a layer of an electrically conductive and optically transparent material 17, in particular ITO, and by means of a contact wire 19. The layer of material 17 is placed between the light sources and the pillars 17, as shown.

A second filling material 15 can be arranged in free spaces in the layer of μ-LEDs 13 and thus between the layer with the material 17 and the contacting layer 5.

Pillar structures P can also be described as micropillar structures or micropillars, since their dimensions, in particular their cross-section, can at least approximately correspond to the dimensions of the micro light-emitting diodes 13 or the pixels of an array 11.

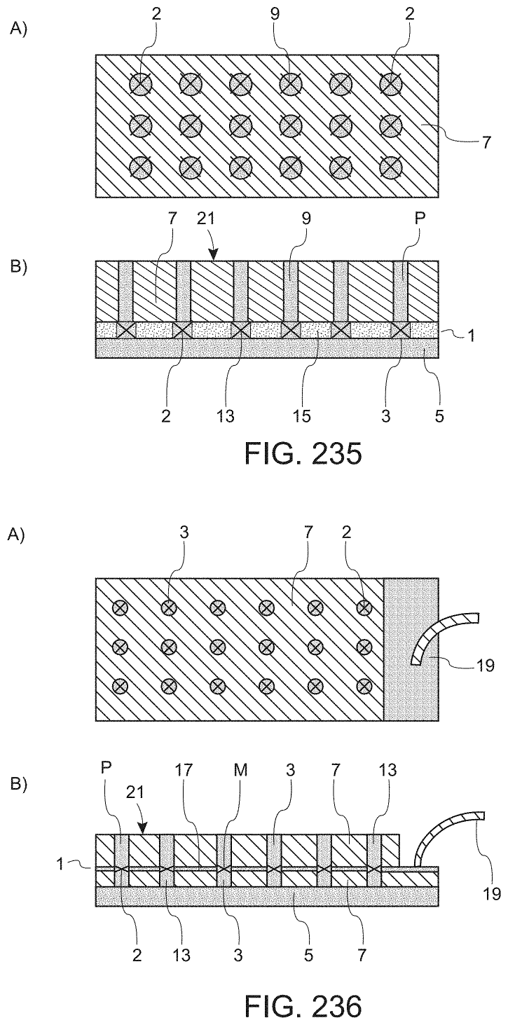

FIGS. 235A and 235B show a seventh optoelectronic device in a top view and cross-section. In contrast to the variant in FIGS. 234A and 234B, the device in FIGS. 235A and 235B comprises an array of horizontal micro-light-emitting diodes 13, the electrical poles of which are located at the rear of the micro-light-emitting diodes 13. For electrical contacting, therefore, both electrical poles of a light source can be electrically connected via two electrically separated areas of the reflective contacting layer 5. The intermediate layer with the material 17 as in the variant with vertical micro light emitting diodes described above is therefore not required.

In comparison to the arrangements with the photonic crystal structures K according to FIGS. 229A to 232B, the variants with the pillars P can be manufactured more easily with standard technologies, since the structure sizes with diameters of up to 1 μm or more are significantly larger. The process requirements are therefore lower and high-resolution lithography can be sufficient for the manufacture of the pillars.

Pillar structures, in particular pillars or columns, made of the optically active semiconductor material 3 or a material 9 with a refractive index as high as possible can be precisely structured via individual pixels of the array 11 or via vertical micro-light emitting diodes 13 (FIGS. 234A and 234B) or via horizontal micro-light emitting diodes 13 (FIGS. 235A and 235B). The individual pixels or micro-lighting diodes 13 may be smaller than 1 μm in diameter and the pillars may have an aspect ratio height:diameter of at least 3:1. Pillars are preferably etched directly into the semiconductor material 3, as is possible in FIGS. 233A and 233B and in FIGS. 235A and 235B, because there is no third layer 17 as shown in FIG. 234B, or they are made of another material 9 with a high refractive index and preferably low absorption, which is applied to the surface of the array 11. A possible material with a high refractive index is for example Nb₂O₅. Pillar structures can be free-standing or filled with a material 7 of low refractive index. A possible filling material with low refractive index is for example SiO₂. Due to the higher refractive index of the pillars compared to the surrounding material, the emission parallel to the longitudinal axis of the pillars is enhanced compared to other spatial directions. Due to a waveguide effect, light along the longitudinal axis of the pillars is additionally coupled out more efficiently than light with other propagation directions. This improves the directionality of the emitted light.

FIGS. 236A and 236B show an eighth proposed optoelectronic device in a top view and cross-section. The device comprises an array of μ-LED 13, each of which is configured with pillar P and thus in column form.

The length of the pillars P can correspond to half a wavelength of the emitted light in the semiconductor material 3 and the recombination zone 2 can preferably be located in the center M of a respective pillar and thus in a local maximum of the photonic state density. The aspect ratio height:diameter of the pillars P can be at least 3:1.

In the arrangement shown, the pillars P can be about 100 nm high and have a diameter of only about 30 nm. This requires a very finely resolved structuring technique and can be realized with current production technologies at wafer level with a lot of effort.

Alternatively, the dimensions can be upscaled to simplify manufacture, with the directionality of the emitted light decreasing as the size of the pillar structure increases. The length of the pillars P is preferably a multiple of half the wavelength of the emitted light in the semiconductor material, and the respective recombination zone 2 can be at a maximum of the photonic state density.

Due to the pillar structuring of the μ-LED 13, the emission parallel to the longitudinal axis of the pillars P is effectively amplified by the higher photonic state density. Due to a waveguide effect, light with a direction of propagation along the longitudinal axis of the pillars P is additionally coupled out more efficiently than light with other directions of propagation. The space between the pillars P is filled with a material 7, which preferably comprises a very low absorption coefficient and a lower refractive index than the semiconductor material 3. A possible filling material with a low refractive index is for example SiO₂.

In this arrangement of micro-lighting diodes 13, in particular vertical micro-lighting diodes 13 formed as pillars P or columns, a first pole, in particular a positive pole is electrically connected by means of a reflective contacting layer 5 for contacting recombination zones 2 arranged in a recombination plane 1. The contacting layer 5 is formed at the lower, first longitudinal ends of the μ-LEDs 13.

The respective other, in particular negative, second pole is electrically connected to a third layer of a conductive transparent material 17, in particular ITO, and connected by means of a bonding wire 19 for example to the corresponding pole of a power supply.

According to this arrangement, the third layer is formed in and along the recombination plane 1 in the longitudinal centers of the μ-LEDs 13, which are shaped as pillars P or columns.

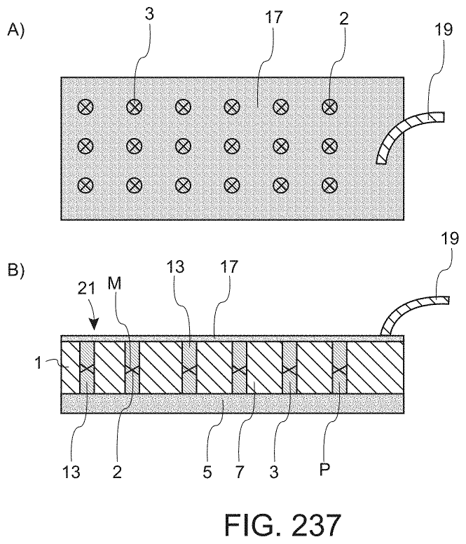

FIGS. 237A and 237B show a ninth optoelectronic device in a top view and cross-section. In contrast to the variant in FIGS. 236A and 236B, the device in FIGS. 237A and 237B comprises vertical μ-LEDs in the form of pillars P.

The electrical contact at the bottom, in particular the p-contact, is established via the bottom of the pillars P and in particular by contacting the contact layer 5. The electrical contact at the top, especially the n-contact, is on the upper side of the pillars P. The contact is established via an upper layer of optically transparent and electrically conductive material 17. The upper layer extends over the pillars P and the first filling material 7, with which the free spaces between the pillars P are filled. A possible material 17 for the upper layer is ITO (indium tin oxide), for example. A connection to a power supply can be established via the bonding wire 19.

The electrical contacting of the light-emitting diodes in the pillars P enables very strongly localized recombination zones 2, whereby the upper contact, in particular an n-contact, can be formed at the level of the recombination zones 2 or on the upper side of the pillars P. Each pillar P generates an individual pixel.

The emission of light parallel to the longitudinal axis of μ-LEDs 13 in the form of pillars as shown in FIGS. 236A to 237B is increased. This improves the directionality of the emitted light compared to conventional micro-light emitting diodes with small aspect ratio. Compared to an arrangement according to FIGS. 233A to 235B, the process of light generation can be influenced much more strongly by an arrangement according to FIGS. 236A to 237B, thus achieving high directionality and efficiency.

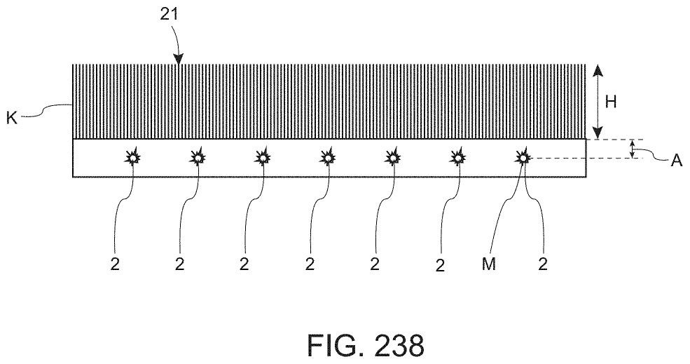

FIG. 238 shows a cross-sectional view of another optoelectronic device in which a two-dimensional photonic crystal K is arranged over a layer with an array of light sources with recombination zones 2. The photonic crystal K is thereby arranged so close to the recombination zones 2 that the photonic crystal K changes an optical state density present in the region of the recombination zones 2, in particular in such a way that a band gap is generated for at least one optical mode with a direction of propagation parallel and/or at a small angle to the light exit surface 21 and/or the state density is increased for at least one optical mode with a direction of propagation perpendicular to the light exit surface 21.

This can be achieved in particular by the fact that the height H of the photonic crystal K is at least 300 to 500 nm, preferably up to 1 μm. The height H of the photonic crystal may depend on the high refractive index material of the photonic crystal.

Furthermore, a distance A between the center M of the recombination zones 2 and the bottom of the photonic crystal K is at most 1 μm and preferably a few 10 to a few hundred nm.

All the described configurations with a photonic crystal K are two-dimensional photonic crystals, which exhibit a periodic variation of the optical refractive index in two spatial directions perpendicular to each other and parallel to the light-emitting surface. Furthermore, it is preferably a pillar structure comprising an array of pillars P or columns, the longitudinal axis L of the pillars P being perpendicular to the light-emitting surface 21.

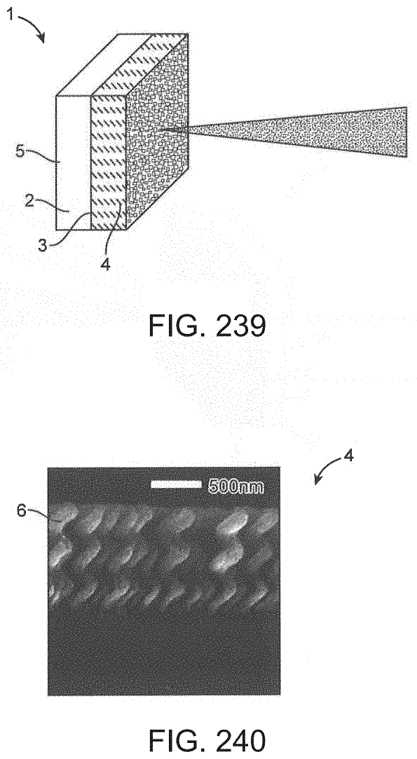

FIG. 239 shows an optoelectronic device 1 with a photonic structure for emitting polarized light. The component 1 comprises an emitter unit 2, which has a light-emitting surface 3 and on which a polarizing element 4 in the form of a polarizing layer with a three-dimensional photonic structure is applied. With the help of photonic structures for polarization of electromagnetic radiation, it is especially possible to take special pictures and show them on suitable displays. According to the embodiment shown in FIG. 239, emitter unit 2 is a μ-LED 5, which emits light in the visible or possibly also in the ultraviolet wavelength range. The light emitted by the μ-LED 5 is guided into the three-dimensional photonic structure and here it is polarized in a certain direction of oscillation depending on the design and dimensioning of the structure. Depending on the design of the three-dimensional photonic structure, either circular or linear polarization can be used. The light emitted in this way therefore comprises a specific polarization, which is predetermined by the photonic structure.

If the three-dimensional photonic structure of polarization element 4 has spiral structure elements 6 as shown in FIG. 240, a circular polarization occurs. If, on the other hand, the structural elements of the three-dimensional photonic structure are rod-shaped, in particular in the form of so-called nanorods, this causes a linear polarization of the radiation guided through the three-dimensional photonic structure.

The optoelectronic device 1 shown in FIG. 239 is manufactured by the two-photon lithography process, the glancing angle deposition process, laser interference lithography or by holographic patterning. It should be noted that the spiral-shaped features 6 shown in FIG. 240 have been fabricated using the glancing angle deposition technique.

The illustration in FIG. 239 shows only a single optoelectronic component. However, a large number of these components can be manufactured together and provided as an array or μ-LED module, as shown in FIGS. 187, 189 to 192, for example. In this way, different components can be interconnected, but with complementary properties. Thus, components 1 or also arrays or μ-LED modules are combined for imaging, which have different polarization and/or transmission properties.

The radiation generated by several illumination units, each with complementary properties, polarized in different directions of oscillation, is projected onto a display or screen by means of common optics disclosed therein.

With the three-dimensional photonic structure arranged on the surface or light-emitting surface 3 of an LED chip as shown in FIG. 239, which forms a polarization element 4, it is possible to generate light with fundamentally different properties, in particular with defined polarization, than is possible with the currently known LEDs. The advantage is that due to the provision of a three-dimensional photonic structure on the chip surface, no additional optical components, such as a classical polarization filter, are required. This is particularly useful in the area of μ-LEDs, since such photonic structures are easier to produce by means of lithographic processes than by positioning and attaching separate polarization filters. The illumination unit can therefore be made comparatively small. Due to the structuring directly on the semiconductor chip of the LED 5, such an optoelectronic component 1 is also more energy-efficient than the known components in which the polarization is subsequently selected. Any photon that does not pass through the three-dimensional photonic structure due to its properties remains in the μ-LED chip and can be re-emitted by a reabsorption process.

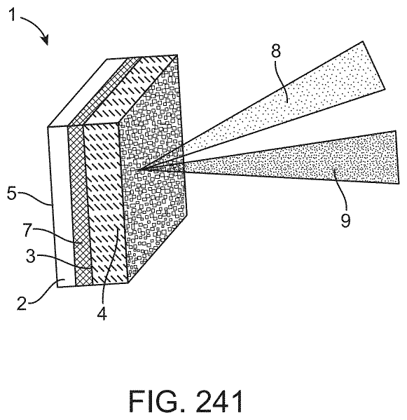

FIG. 241 shows an illumination unit or an optoelectronic component 1 with an emitter unit 2, which comprises a light-emitting surface 3 on which a polarizing element 4 with a three-dimensional photonic structure that has wavelength-selective properties is applied. The photonic structure in this case is a three-dimensional photonic crystal. Alternatively, several two-dimensional photonic crystals can be arranged in layers one above the other.

The three-dimensional photonic structure is designed to have wavelength-specific transmittance and polarization properties. This means that the transmittance and polarization properties of the three-dimensional photonic structure vary depending on the wavelength of the incident radiation.

Component 1 shown in FIG. 241 has an emitter unit, which in turn has a μ-LED 5. A converter element 7 with a layer of converter material is also provided. The converter material emits a converted radiation 9 due to excitation by the excitation radiation 8 emitted by the LED 5, which comprises a different wavelength than the excitation radiation 8.

If both unconverted excitation radiation 8 and converted radiation 9 impinge on the three-dimensional photonic structure, these radiations are influenced in different ways depending on their wavelength with respect to transmission and polarization. As shown in FIG. 241, the converted radiation 9 is coupled out perpendicular to the surface of the LED chip, while the excitation radiation 8 is deflected laterally.

Such lighting units can be used in a preferred way in components in which radiation with different wavelengths is generated, whereby different functions can be implemented with a combination of μ-LEDs and converter elements. Depending on the design of the three-dimensional photonic structure and the wavelength of the excitation radiation 8 emitted by each LED, it is possible to achieve complete suppression of the excitation radiation 8, while the converted radiation 9 passes through the three-dimensional photonic structure. It is also conceivable that the excitation radiation 8 is deflected while the converted radiation 9 is coupled out perpendicular to the chip surface, as shown in FIG. 241. Of course, the mechanism can also be reversed. Furthermore, it is also conceivable to polarize the converted radiation 9 in a special way, while the excitation radiation 8 emerges unchanged via the chip surface. Here too, the mechanism can be reversed.

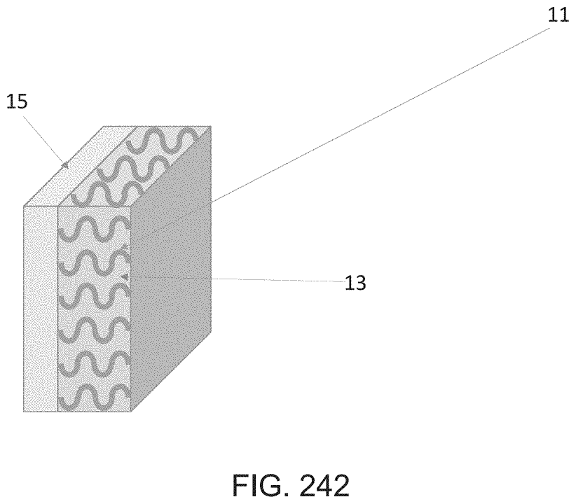

The variant of an illumination unit shown in FIG. 242 comprises an emitter unit, here again in the form of a μ-LED 15, and a three-dimensional photonic structure 11, for example a spiral-shaped photonic structure 11. Converter material 13 is filled into structure 11.

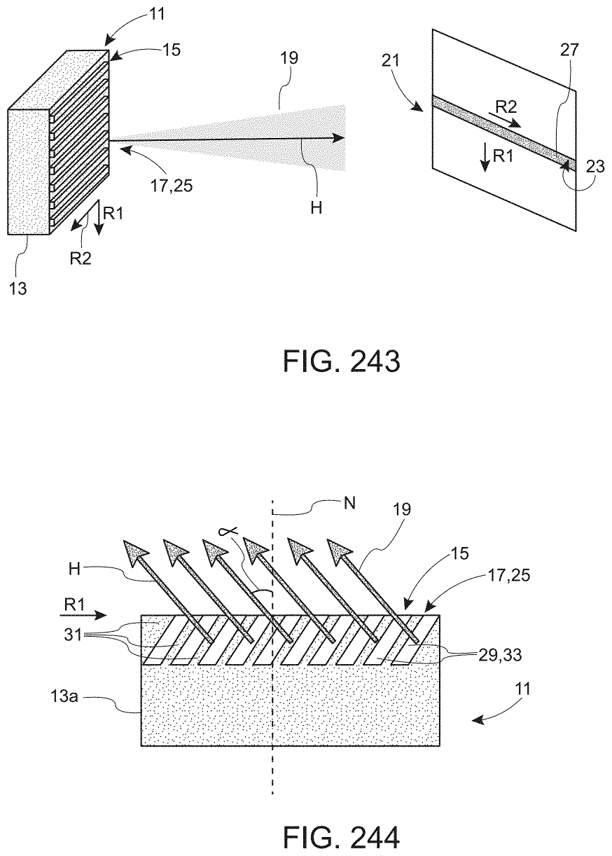

The optoelectronic component 11 shown in FIG. 243 comprises at least one μ-LED 13, which is designed to emit electromagnetic radiation 19, such as visible or infrared light of one wavelength, via a light emission surface 15. A photonic structure 17 is provided for beam-shaping of the electromagnetic radiation before it exits via the light exit surface 15. The photonic structure 17 shapes the electromagnetic radiation 19 in such a way that the electromagnetic radiation 19 comprises a defined characteristic 23 (Far-field characteristics).

In particular, the photonic structure 17 of the illumination unit 11 of FIG. 243 is a one-dimensional photonic crystal 25, which in the variant shown extends to the light-emitting surface 15. The front side of the photonic crystal 25 thus forms the light-emitting surface 15. The one-dimensional photonic crystal 25 exhibits a periodic variation of the optical refractive index along a first direction R1.

The crystal 25 or the periodic variation are adjusted to beam the electromagnetic radiation emitted by a light source (not shown) of the μ-LED. Especially a light propagation along the first direction R1 is blocked. As a result, the emitted radiation 19 in far-field 21 comprises only a slight extension along the first direction R1. A characteristic feature of electromagnetic radiation 19 in far-field 21 is therefore that it forms a narrow strip 27. The electromagnetic radiation 19 is therefore collimated with respect to the first direction 19.

The light source is a μ-LED. This is typically a Lambertian radiator. By using the photonic structure 17 and the resulting beam-shaping a directed, collimated electromagnetic radiation 19 can be generated.

As FIG. 243 schematically shows, the emitted electromagnetic radiation 19 leaves the μ-LED 13 in the form of a light cone that substantially fans out along a second direction R2. The central axis of the light cone extends along a main radiation direction H, which is perpendicular to the light exit surface 15. Not shown is a collimating, optional optical system arranged downstream of the light exit surface 15 when viewed in the main radiation direction H. By means of the optics, the electromagnetic radiation 19 can be collimated in the second spatial direction R2, which is orthogonal to the first spatial direction R1. The electromagnetic radiation 19 can thus be collimated in the far field 21 with respect to the two directions R1, R2. A luminous point is created. This luminous point is particularly favourable for displays as mentioned at the beginning, because the beam is strongly collimated in both directions in space.

An optoelectronic component 11 as shown in FIG. 243 is particularly well suited for use in an optical scanner. Here, the illumination device 11 can be used especially for line scan applications due to the stripe-like light image in far field 21.

In the optoelectronic device 11 shown in FIG. 244, a one-dimensional photonic crystal 25 is formed on the upper side of an emitter unit 13a. The front face of the crystal 25 forms the light-emitting surface 15 for electromagnetic radiation generated by an unrepresented optoelectronic light source, for example an LED or μ-LED, which is emitted through the photonic crystal 25 via the light-emitting surface 25.

In contrast to the variant shown in FIG. 243, the main direction of radiation H of the electromagnetic radiation 19 of the lighting unit of FIG. 244 is at an angle α to the normal N of the light-emitting surface 15. The angle α is not equal to zero degrees. For example, the angle α can be in the range between 30 and 60 degrees. This is achieved by the fact that the one-dimensional photonic crystal 25 comprises a periodically repeating sequence of two materials 31, 33 with different optical refractive indices extending in a first direction R1. The materials 31, 33 have a parallelogram-like cross-section and abutting interfaces of the materials 31, 33 do not run orthogonally but are inclined to the light-emitting surface 15, as shown schematically in FIG. 244.

Such a structure can be formed, for example, by etching trenches 29 running parallel to each other at an angle to the light emission surface 15 into the substrate 31 having the light emission surface 15. The trenches 29 can be filled with a material 33, which comprises a different optical refractive index than the substrate material 33, which has been etched away. The angle α may depend on the inclination of the trenches 29 to the light-emitting surface 15. The width of the trenches 29 and the width of any substrate material 31 remaining between two trenches 29 influences the wavelengths at which the photonic crystal 25 can be affected. Typically, the width of the trenches 29 and the width of the substrate material 33 remaining between two trenches, and thus also the periodicity of the photonic crystal structure 25, are adapted to the wavelength of the electromagnetic radiation provided by the light source or a converter material located between the light source and the photonic crystal.

Using the one-dimensional photonic crystal 25, component 11 of FIG. 244 can in turn generate a light strip 27 in the far field 21, as described in relation to FIG. 243. In contrast to the variant in FIG. 243, the main radiation direction H in the variant in FIG. 244 is tilted by the angle α relative to the normal N. By means of a downstream collimating optic, the strip 27 can be brought into a point-like or circular structure in the far field 21.

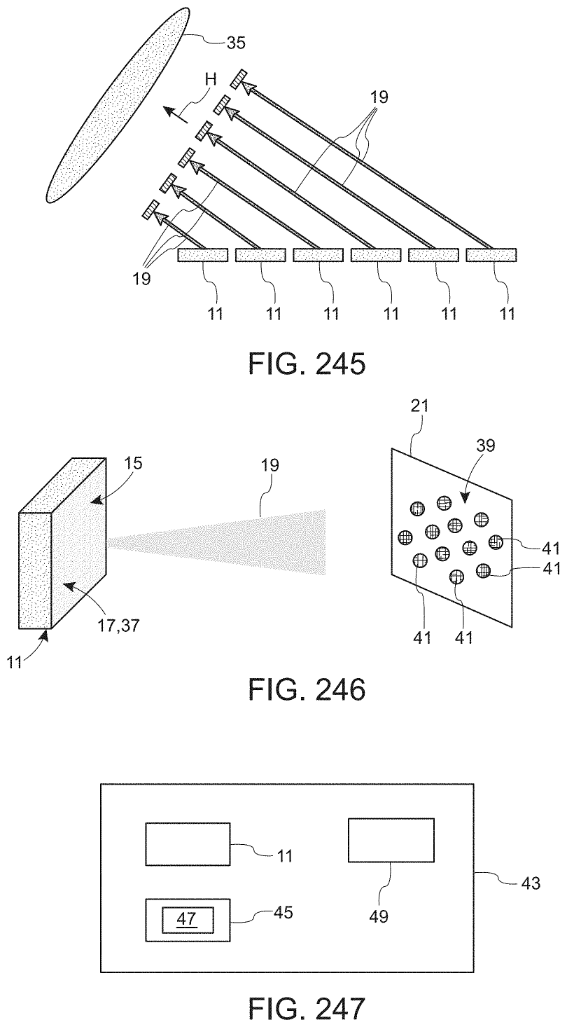

The variant shown in FIG. 245 comprises a linear or array arrangement of several optoelectronic components 11 of FIG. 244, the light beams 19 emitted by the individual components 11 having the same main radiation direction H. The light beams 19 can also be collimated by an additional collimating optic 35, in particular a lens, in a second direction, which, in the representation of FIG. 245, is perpendicular to the image plane. This results in a point or circular image of the emitted radiation 19 in the far field behind the lens 35.

The use of a photonic crystal in an illumination device 11 as shown in FIGS. 244 and 245 results in an effectively higher resolution for a line-array arrangement of illumination devices 11 as shown in FIG. 245. μ-display or modules having such features allow very directional radiation, so that the pixel sharpness is very high. This means that the contrast remains very high even with adjacent pixels and optical crosstalk is reduced. In addition, smaller beam cross-sections can be realized, especially in the far field, downstream of optics 35. Since collimation in the first direction R1 (cf. FIG. 244) is already achieved by the photonic crystals 25 integrated in the illumination devices 11, optics 35 and possibly further, subsequent optics can be made more compact.

In the variant of FIG. 246, the optoelectronic component or lighting unit 11 comprises a photonic structure 17, which is a two-dimensional photonic crystal 37, whose front side forms the light-emitting surface 15. Viewed from the light exit surface 15, at least one optoelectronic light source, optionally with converter material, is arranged behind the photonic crystal 37. The photonic crystal 37 is designed to shape the electromagnetic radiation 19 emitted via the light exit surface in such a way that it produces a defined, discrete pattern 39 in the far field 21. In the example shown, the pattern 39 consists of several distributed light spots 41, although other patterns are also possible. In particular, the photonic crystal can be formed to produce only one central pixel. This structure is particularly useful for displays.

The illumination device 11 in FIG. 246 is suitable for use in a surface topography detection system 43, for example, as shown in the block diagram in FIG. 247. In addition to the illumination device 11, the system 43 includes a detection unit 45 with a camera 47, which is designed to detect the pattern 39 when it illuminates an object (not shown).

Furthermore, an analysis device 49 is provided which is designed to detect a distortion of the pattern 39 in relation to a given reference pattern. The reference pattern can, for example, be determined from the detection of pattern 39 when it is projected onto a flat surface. The analyser 49 is also adapted to determine a shape and/or a structure of the object illuminated by the pattern 39 in the far field 39 depending on the detected distortion of the pattern 39. By means of the system 43, face recognition can thus be realized, for example. In the case of applications in the Augmented Reality area, some pixels can be formed with a crystal such as the one shown in FIG. 246 in order to detect the reflection on the eye a direction of vision or its change. This allows a user to follow and superimpose information into the field of view for sharp vision.

In the variant shown in FIG. 247, downstream optics for pattern generation can be dispensed with, since pattern 39 can already be generated using photonic crystal 37. The lighting device 11 as shown in FIG. 246 and the associated system 43 as shown in FIG. 247 can therefore be implemented in a particularly compact form.

For light extraction and light guiding there are basically two possibilities. In the first case, the eye of a user is directly in line with the direction of radiation of a display. In such a case, the light generated by the display can be radiated directly, collimated, enlarged or reduced. However, no more complex light guidance is necessary. This type of generation and guidance is often found in display applications, including the automotive sector. Also in applications to augmented reality, using glasses can make use of this principle. The display is implemented directly into the glasses and thus the glasses themselves are used as a semi-transparent screen. Of course, this also requires the implementation of control circuits and connection possibilities with transparent material.

However, in some applications a light guide arrangement necessary for light guidance, since the light-generating display is located outside a user's field of vision or at least not directly in front of it. Google's Glass™ is an example of such an application.

FIG. 248 illustrates an example where the display is not within the line of sight of the eye; that is, the light generated by the display must be directed through the glasses to the eye. In FIG. 248, a μ-display 45, which has a light-generating element LED and an optical system 44 placed in front of the light path, is placed in a position outside the field of vision of the eye. The light-generating element LED is one of the structures presented above. It is substantially one or more small displays with μ-LED pixels or subpixels thereof. A control is done by the concepts also presented here. In case of a monolithic display, the control can be implemented directly in the carrier. The μ-LED display is placed on the carrier and electrically connected to it.

In the case of spectacles, the μ-display is located on the temples close to the hinge. The μ-display in this example emits light of the primary colors red, blue and green parallel to a feed element, which is built as a sandwich structure using elements 41, 43g, 43b, 42, 43r and 43b. The feed element has a first light guide 41 made of a transparent material. A reflective input element 43g is mounted on the sidewall of the light guide and opposite incident light to reflect the green portion of the light of the μ-display and guide it through the light guide 42. In some variants, the incident light has an angle of 0° to 45° with respect to the surface of the corresponding light guide. In the illustrated example, the angle of light incidence is approximately 70° in relation to the surface of the light guide.

Another reflective coupler 43b is either on or on element 43g to couple the blue component into the second light guide 42. Finally, the last reflective element 43r is positioned on the second light guide 42 to reflect the red portion of the μ-display into the second light guide. To this extent, the reflective elements 43 are adapted to couple the corresponding light portion into the light guides 41 and 42. Reflective coupling elements allow light to be coupled into light guides even if incident light hits the light guide at a large angle, e.g. approximately 70° to 90° as in FIG. 248. The first and second light guides are spaced apart using spacers 47 at both ends of the light guides.

The light guides 41 and 42 are both elongated and arranged parallel to each other. They can be part of the glasses, for example. Total reflection in both light guides prevents the light (the green part and the red or blue part) from being coupled out of the light guide. The light is guided to an area in the light guide that is covered by the reflective out-coupling elements 46r, 46b and 46g. All these areas are arranged on the same side as the areas of the corresponding reflective elements 43g, 43b and 43r. Coupling element 46r is arranged on the second light guide 42 and is configured to couple out the red portion of the light from the second light guide and direct the portion to the eye. Elements 46b and 46g comprise the same functionality for the blue and green portions so that all three light portions are substantially parallel and directed to the eye.

The couplers 43 are implemented using, for example, mirrors and the like, which are reflective for a certain portion of the light but otherwise transparent. For the purpose of reflection, the couplers can change the refractive index so that light is reflected. In a similar way, the change of refractive index between air and the light guide leads for example to the light inside the guide. The light is coupled out in a similar way. If the light of different colors is essentially parallel and overlapping, the corresponding coupling element(s) should be stacked on top of each other. However, the stacking should occur in such a way that the coupling element absorbs or reflects undesired portions of the light. In some variants, MEMS mirrors can be used to direct the light coming from the display to the user's eye. In this example, the output coupler 46 is mounted directly on the light guide.

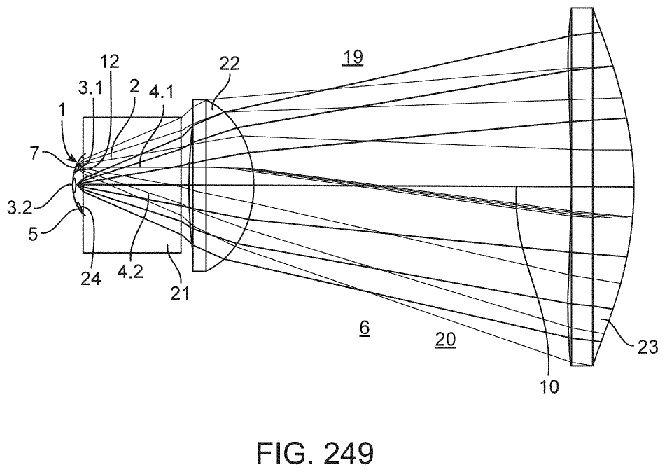

FIG. 249 shows an example of a light guide, in which a suitable beam guidance is achieved using a foveated display. FIG. 249 proposes an illumination arrangement of, for example, a μ-display, comprising a light-emitting optoelectronic element 1 and an optical device 6 for beam conversion or beam-shaping of the electromagnetic radiation generated by the light-emitting optoelectronic element 1. In this context, a light-emitting optoelectronic element 1 comprises a plurality of μ-LEDs, which emit light of one color in operation. The light-emitting optoelectronic element is designed so that the μ-LEDs emit different colors. As subpixels, three μ-LEDs form part of an entire pixel. The light-emitting optoelectronic element thus contains a large number of such pixels.

The optical device 6 represents a system optic 19 in the form of an imaging projection optic 20 and comprises in the beam path successively a plane-parallel lens 21 and a first aspherical lens 22 and a second aspherical lens 23, which realize an image of the light-emitting optoelectronic element 1.

Furthermore, FIG. 249 shows that the light-emitting optoelectronic element 1 comprises several emission regions 3.1, 3.2 arranged in matrix form. These each comprise one or more μ-LEDs (for different colors). Optionally, the μ-LEDs can already include primary optics 12. These primary optics can contain converter elements, decoupling structures or photonic crystals to achieve a certain beam-shaping already at light emission. Each of the emission areas 3.1, 3.2 is assigned a main beam direction 4.1 and 4.2. For at least partial compensation of the field curvature arising in the optical device, the centers 7 of the emission areas 3.1, 3.2 are arranged on a curved surface 5, which, for the present embodiment, forms a spherical segment 24 with an associated spherical center 30 on the optical axis 10 of the optical device 6.

For a possible dimensioning, a radius R of 10 mm is selected for a light-emitting optoelectronic element 1 with a diameter D of 3.7 mm for the curved surface 5 for the arrangement of the emission zones 3.1, 3.2 and a material with a refractive index of at least 1.6 and a thickness in the direction of the optical axis 10 of at least twice the diameter D is required for the plane-parallel lens 21 of the optical device 1 following in the beam path.

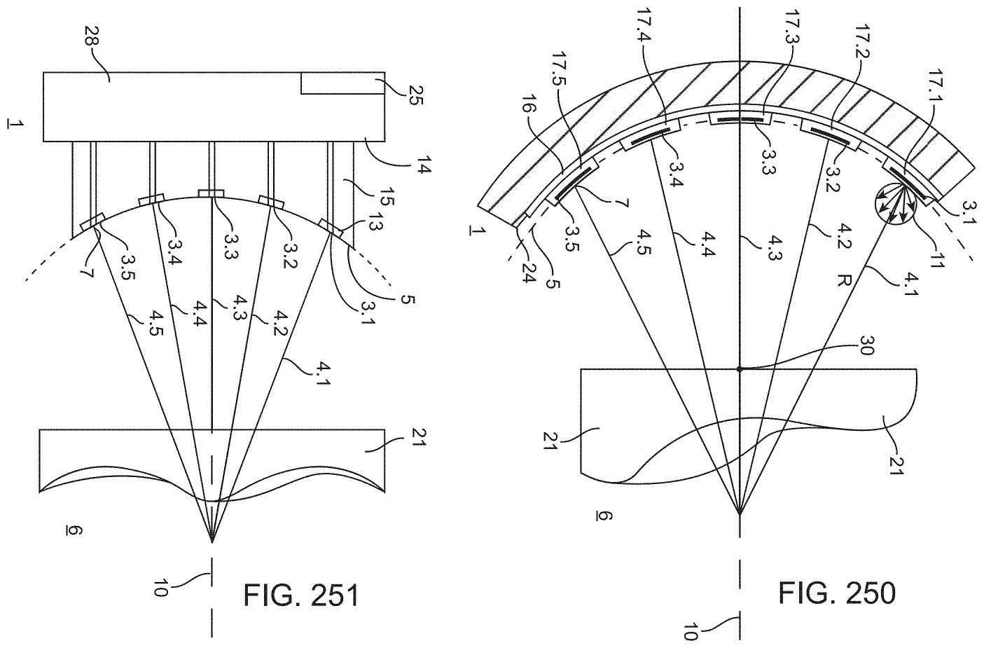

FIG. 250 shows an enlarged partial view of an example of an illumination arrangement with a light-emitting optoelectronic element 1 comprising several emission regions 3.1-3.5 formed by apertures of the primary optics of separate optochips 17.1-17.5 in the form of μ-LEDs. An arrangement of the separate optochips 17.1-17.5 on a non-planar IC substrate 16 is shown so that the centers 7 of the emission regions 3.1-3.5 are located on a concave curved surface 5. Each of the emission regions 3.1-3.5 forms a Lambert radiator 11 to which a main beam direction 4.1-4.5 is assigned, whereby due to the non-planar IC substrate in the form of a spherical segment 24 facing the optical device 6, the main beam directions 4.1-4.5 comprise a common point of intersection on the optical axis 10 of the optical device 6. By means of primary optical elements 12 (cf. FIG. 249) the Lambertian emission of the emission regions 3.1-3.5 can be transformed into a non-Lambertian emission, in particular into an emission with a narrower aperture angle.

FIG. 251 shows an enlarged partial view of a design alternative with an optical device 6, which is only shown in a sectional view, and a flat IC substrate 28 with a schematically simplified control device 25, which typically includes driver components and interface and memory elements. A monolithically pixelated optochip 14 is arranged on the flat IC substrate 28, which comprises a light-emitting optoelectronic element 1 manufactured in a common process and having several emission regions 3.1-3-5 lying on a concavely curved surface 5 of a region 15 of the chip 14, which are each formed by a converter element 13. Corresponding to the previous embodiment, the main radiation directions 4.1-4.5 of the emission regions 3.1-3.5 are at an angle to each other and intersect on the optical axis 10 of the optical device 6.

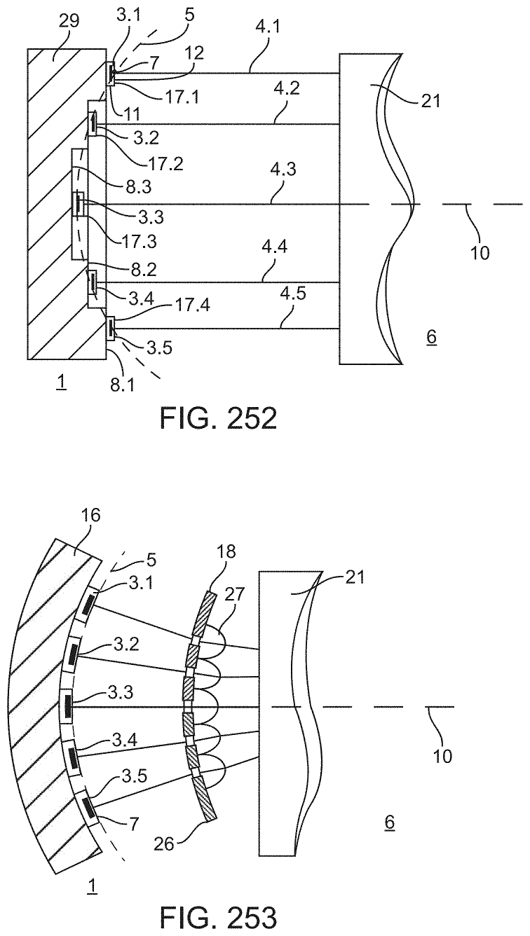

FIG. 252 shows a fourth embodiment of an illumination device with a light-emitting optical element 1, comprising a stepped IC substrate 29, separate optochips 17.1-17 being mounted on concentrically arranged ring surfaces 8.1, 8.2, 8.3 of the stepped IC substrate 29.5 formed by μ-LEDs 11 are arranged in such a way that the centers 7 of the emission regions 3.1-3.5 formed by primary optical elements 12 of the respective μ-LEDs 11 lie on a concavely curved surface 5, while the main beam directions 4.1-4.5 the emission regions 3.1-3.5 comprise a coincident orientation. Consequently, the distances of the separate optochips 17.1-17.5 to the plane-parallel lens 21 of the optical device 6 and thus the beam cross-section in the widening beam path in front of the optical device 6 differ if they are arranged on different ring planes 8.1-8.3.

FIG. 253 shows a further development of the invention based on the variant shown in FIG. 252, whereby a likewise concavely curved collimating optical element 18 is additionally arranged between the centers 7 of the emission zones 3.1-3.5 arranged on a concavely curved surface 5 and the plane-parallel lens 21 of the optical device 6. For the version shown, the collimating optical element 18 comprises a curved pinhole 26 and a curved microlens arrangement 27, which form a radiation angle filter. The functional components of the collimating optical element 18 can be assigned to one or more emission ranges 3.1-3.5. For a version not shown in detail, each functional component of the collimating optical element 18 serves to pre-collimate several emission ranges 3.1-3.5 belonging to one pixel and radiating with different colors.

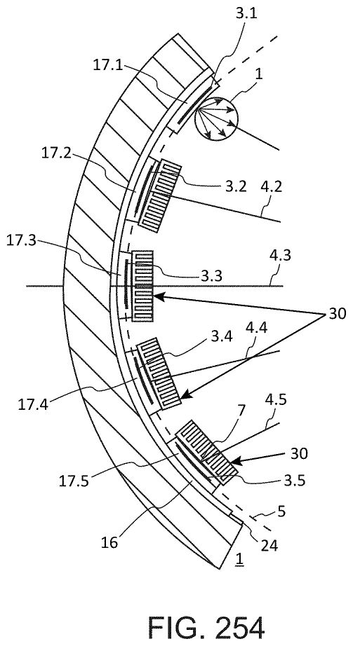

FIG. 254 shows an addition wherein the optochips 17.1 to 17.5 are designed as μ-LED arrays with an additional light-shaping structure on the upper side of the emission surface. This improves light guidance and changes the radiation characteristics of the individual optochips. The light-shaping structure, which is for example a photonic crystal in a semiconductor material of the optochip, results in a higher directionality of the emitted light. The light-forming structure can be formed in different ways.

FIG. 256 shows a further embodiment based on the example in FIG. 253, in which the light-forming structure 31 is arranged in the optical path of the optochips. It has several areas 30, 31 and 32 with a periodic change of the refractive index. In particular, the regions are formed by holes in the material of structure 31, which produces the periodic variation of the refractive index. The holes for areas 30 and 32 are not perpendicular to the surface of the structure, but are etched at an angle to it. This etching thus causes a directional dependence of the holes and thus the variation of the refractive index. Correspondingly, such an arrangement produces a shaping of the light in the area shown in the upper section of FIG. 256. Areas 30 and 32 are configured in such a way that they collimate incident light and emit it again in a directed manner at an angle defined by the direction of the holes. Only in area 33 is light collimated. This special design of the photonic structure results in an essentially parallel beam of light.

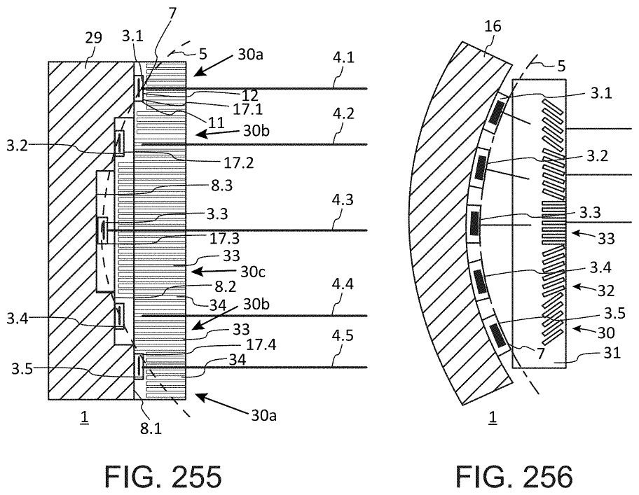

The embodiment of FIG. 255 is based on the example of FIG. 252, which also forms a light-shaping structure, but the width varies and follows the shape or surface of body 1.

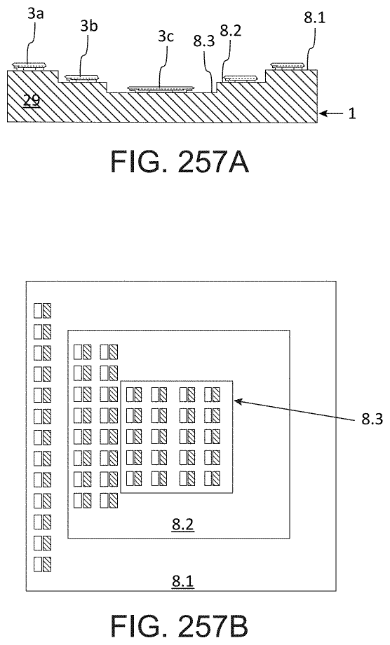

FIGS. 257A and B show another design in cross-sectional view and top view. In this case, μ-LED modules 3a, 3b and 3c are arranged as described above on the concentrically arranged surfaces 8.1, 8.2 and 8.3 of the stepped IC substrate, which are made up of several base modules. In a top view, this is shown in more detail by means of another embodiment, where the stepped substrate comprises rectangular stepped surfaces. In the central i.e. “deepest” area 8.1 a μ-LED module consisting of 4×5 base modules is arranged. In the next area 8.2 some more μ-LED modules are shown. This can be a 2×8 module, but also have a different shape. Finally, the last section is partly already equipped with a 1×13 module.

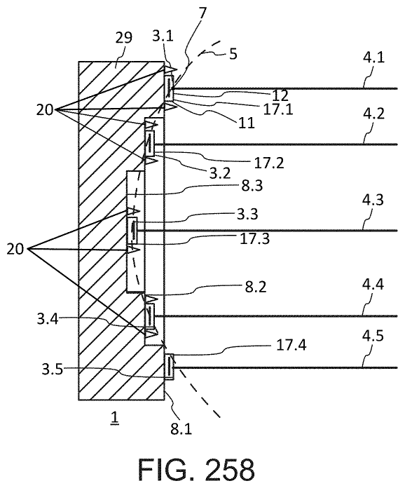

In addition to photonic structures, other light shaping measures can also be provided directly on the substrate 29. FIG. 258 shows such an example. In this case, a reflective structure 20 is arranged around each emission range 3.1 to 3.5 or around each optochip 17.1 to 17.4. The reflective structure 20 extends over the height of the emission surface so that light emitted at a flat angle is deflected laterally by the reflective structure. The reflective structure is formed with features from this application. For example, the optochips may be arranged in cavities in each annular surface, the reflective structure 20 forming part of the walls of the cavities.

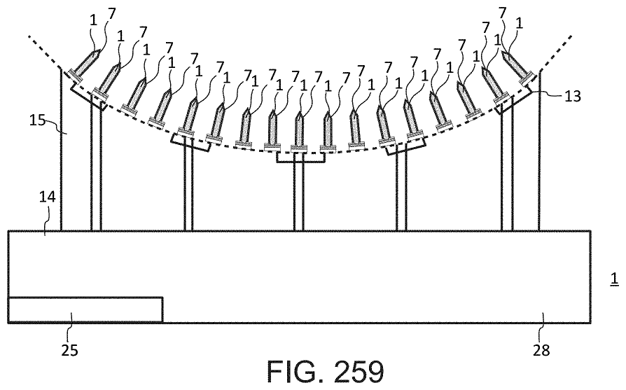

FIG. 259 shows a combination of the embodiment based on the example in FIG. 251, with a large number of nanorods arranged on the surface, for example those with a structure similar to the examples in FIGS. 26 to 29. These are individually contacted and controlled by the control circuit 28.

A plurality of different projection units are known in the art, with which images can be displayed in specifically defined image planes according to requirements.

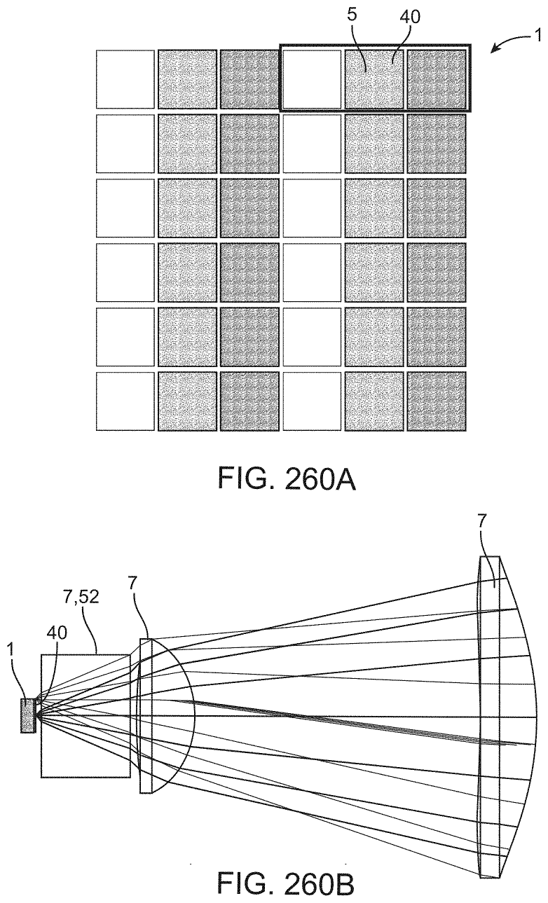

FIG. 260A shows a top view of a RGB emitter array with an optoelectronic lighting device 1 according to the state of the art, which is designed as a matrix with RGB pixels 40 emitting red, green or blue light. The RGB-Pixel 40 are characterized by a high fill factor. This means that a large part of the area 5 of the individual RGB pixel 40 is used as light-emitting area. FIG. 260B shows a schematic diagram of beam guidance in projection units with projection optics 7. Projection optics 7 comprises all 3 lenses shown in FIG. 260B, including the lens or plate 52. It can be seen that the radiation emitted by the individual RGB pixels 40 is not collimated. As shown in FIG. 260B, only the rays emitted by the RGB pixels 40 with an angle of radiation between +45° and −45° reach the elements of projection optics 7, which are arranged downstream of plate 52. Since the RGB pixels 40 emit light in accordance with Lambert's law of radiation, without collimation of the radiation, therefore, part of the radiation emitted by the RGB pixels 40 cannot be used for image generation, which ultimately means a loss of efficiency.

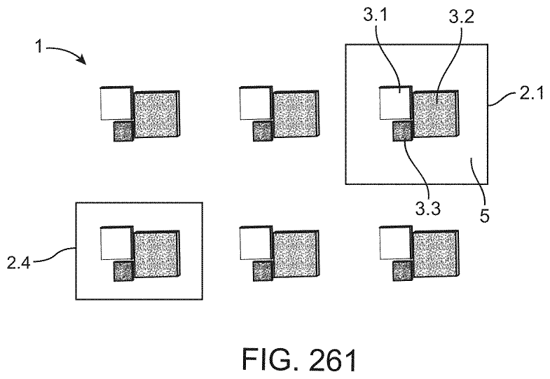

FIG. 261 shows a schematically simplified top view of an optoelectronic lighting device 1 with a proposed designed RGB emitter array according to some aspects disclosed here with six pixels, whereby the assigned pixel area 5 is shown for the exemplary pixel 2.1 provided with reference signs. Pixel 2.1 comprises separately applied μ-LEDs 3.1, 3.2, 3.3 forming subpixels, which are adapted as μ-LEDs and which emit red, green and blue light for the embodiment shown. The individual pixels 2.1 are characterized by a small fill factor so that only a comparatively small part of the pixel area 5 is occupied by the μ-LEDs 3.1, 3.2, 3.3. Otherwise, the μ-LEDs 3.1, 3.2, 3.3 are arranged in such a way that a comparatively large distance is formed between the individual light-emitting areas of the subpixels. On the one hand, the μ-LEDs 3.1, 3.2, 3.3 or the μ-LEDs are arranged at a distance from the edge of the pixels 2.1 so that optical and/or electrical crosstalk between adjacent pixels 2.1 does not occur. On the other hand, the μ-LEDs 3.1, 3.2, 3.3 are also arranged within the individual pixels 2.1 in such a way that optical and electrical crosstalk between the individual semiconductor lighting devices 3.1, 3.2, 3.3 of a pixel 2.1 can be prevented or at least minimized. The arrangement of the individual μ-LEDs 3.1, 3.2, 3.3 takes into account the radiation characteristics and the light output required to produce the desired images. In addition, a reflective elevation 2.4 can be designed, as shown here in the upper leftmost pixel. A transparent cover electrode can also be attached. Details of this are disclosed in this application.

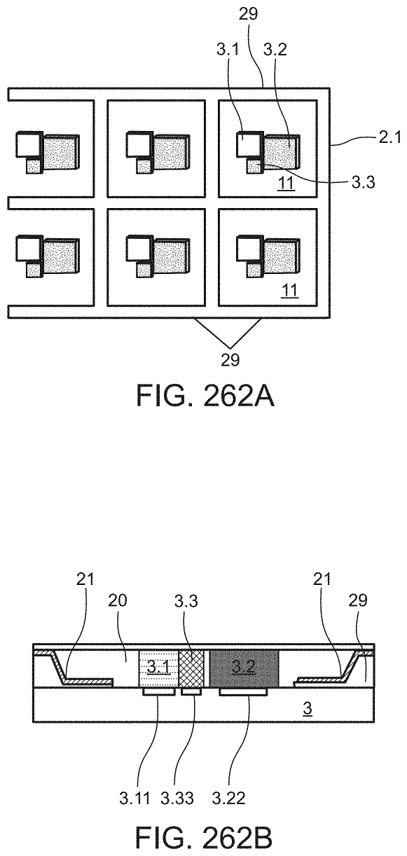

FIG. 262A shows a complementary embodiment based on the example of FIG. 261, where the pixels are arranged in rows and columns, each pixel having a total of three sub-pixels formed by respective μ-LEDs 3.1, 3.2 and 3.3. The individual μ-LEDs have different sizes depending on their emitting color. μ-LED 3.2 for the green color has the largest area, since the human eye is particularly sensitive to the color green. The μ-LED 3.1 for the red color and the μ-LED 3.3 for the blue color are arranged adjacent to the μ-LED 3.2 and have a significantly smaller size in comparison. A reflective structure 2.1 is arranged around the μ-LEDs. This has a sloping side surface on which a reflective layer 21 is deposited.

FIG. 262B shows the cross-sectional view along the XX-axis for a single pixel. The individual μ-LEDs 3.1, 3.3.2 and 3.3 are designed as vertical LEDs and each have a contact surface on their underside. Each contact surface is electrically connected to a contact area 3.11, 3.22 and 3.33 in a planar substrate 3. A further contact on the light-emitting side of each μ-LED is connected to a conductive cover electrode. The cover electrode similar to the embodiment in FIG. 103A is in turn connected to the conductive metallic and reflective structure 29 on all sides of the pixel. The reflective structure completely surrounds the μ-LEDs 3.1 to 3.3 and comprises a dielectric support 29 on the planar substrate 3, on which a reflective metal 21 is deposited. This extends over the upper side of the structure 29 and is in electrical contact with the top electrode and along the sidewalls and a partial area of the backplane substrate 3. The metal 21 is electrically insulated from the backplane substrate 3 by the electrical structure 29. Due to the large reflection range through the reflective layer 21, light emerging from the side is reflected and radiated upwards.

In the illustration shown in FIG. 262B the μ-LED 3.1 for the red light is partly behind the μ-LED 3.3 for the blue light. The contact areas 3.11 to 3.3 are designed accordingly, so that positioning the individual μ-LEDs on the surface of the backplane substrate 3 is simplified.

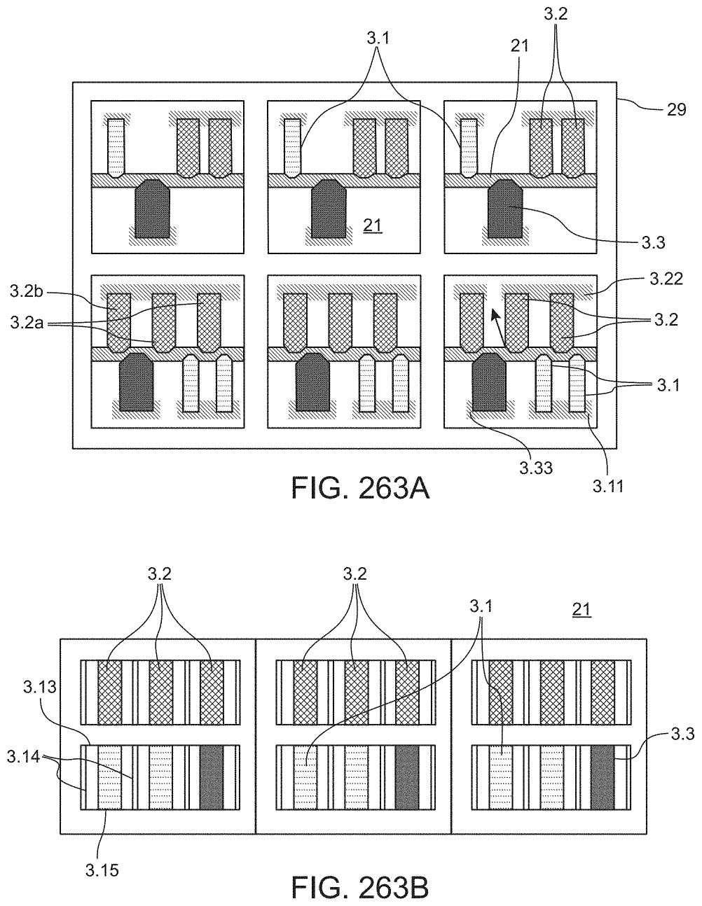

FIG. 263A shows a top view of another embodiment, in which a pixel element with several subpixels is realized by horizontally arranged μ-rods. The horizontally arranged rods correspond to the different embodiments shown in this application. For each pixel, a common contact level 21 is provided on the backplane substrate, which on the one hand contacts the reflective metallic structure and on the other hand is connected to a common terminal of each μ-LED 3.1-3.3. For individual control of each μ-LED, the respective other contact area of this μ-LED is coupled to a contact area on the surface of the backplane substrate. This contact area is designed larger than the diameter or width of the respective μ-LED, thus simplifying positioning. In the design of the top row shown in FIG. 263A, two μ-LEDs 3.2 in the form of μ-rods are provided for the color green. The μ-rods 3.1 are used to generate a red light, the μ-rods 3.3 to generate a blue light.

As already explained, the different widths of the μ-rods cause a color emission during operation. Accordingly, the μ-rod 3.3 has the largest width for the blue color, the μ-rod 3.1 the smallest width. It is planned to design the contact areas on the surface of the backplane substrate for individual control of the μ-rods with the same size in each case. This provides additional flexibility in the assembly of the individual pixels.

In the top row shown here, two rods are provided for the green color. Alternatively, however, the existing color space can be expanded, for example by configuring the μ-rods differently for the green color. Such an example is realized in the lower row in the left pixel with the two Rods 3.2a and 3.2b. Here the μ-rod 3.2b shows a slightly different green color emission compared to the two Rods 3.2a. Thus, the color space in the green area is extended. Another aspect is shown in the lower row, and concerns the different sensitivity of the human eye to different colors. In order to achieve an increased number of color gradations or to prevent failure or defects, for example, an embodiment may provide several μ-rods of one color in or for the pixel. In the right pixel of the lower line, this is represented by an additional green μ-rod and an additional red μ-rod. These redundant μ-rods can be placed on the pixel if necessary, i.e. if a defect is present. For this purpose the contact areas, 3.11 and 3.22 are configured accordingly.

Another version shows the middle pixel of FIG. 263A. In this version, the contact areas for the individual control of the rods are combined so that all green and all red rods are controlled simultaneously. In this respect, a parallel connection of the three green and two red elements shown here is achieved for both green and red μ-rods. The contact areas on the surface of the backplane substrate 3 are larger, so that a simplified and more flexible positioning can be achieved.

In addition to the rods shown here, other embodiments of such a pixel with different fill factors are also conceivable. FIG. 263B shows a version with μ-LEDs 3.1 to 3.2 in the so-called bar shape presented in this application. As already explained, a converter material 3.15 is arranged between two light-emitting bar-shaped elements 3.14 and thus forms a μ-LED. As shown, three μ-LEDs 3.2 for the green color are arranged in the top row of each pixel. Depending on the application, one of these μ-LEDs can be designed as a redundant μ-LED to replace a defective μ-LED if necessary. Alternatively, it can be designed with a different green color to extend the color space. The bottom row of pixels in FIG. 263B contains one μ-LED 3.3 for the blue color and two μ-LEDs 3.2 for the red color.

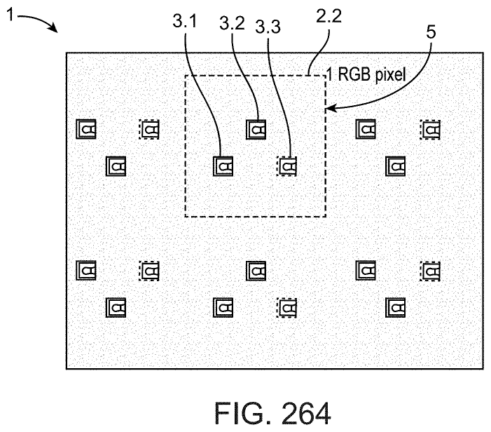

FIG. 264 shows a top view of a matrix formed by RGB pixels, which forms an optoelectronic lighting device 1 of a proposed projection unit. As an example, a pixel area 5 of pixel 2.2 is shown dashed. The pixel 2.2 comprises three sub-pixel forming semiconductor lighting devices 3.1, 3.2, 3.3, which emit red, green or blue light and which are arranged in the form of a triangle on the surface 5 of the pixel 2.2. This embodiment may also be surrounded by a reflective layer. Another aspect at this point would be an embodiment as described above, in which the pixel emits light from the back, i.e. through the substrate, as shown schematically in FIG. 221.

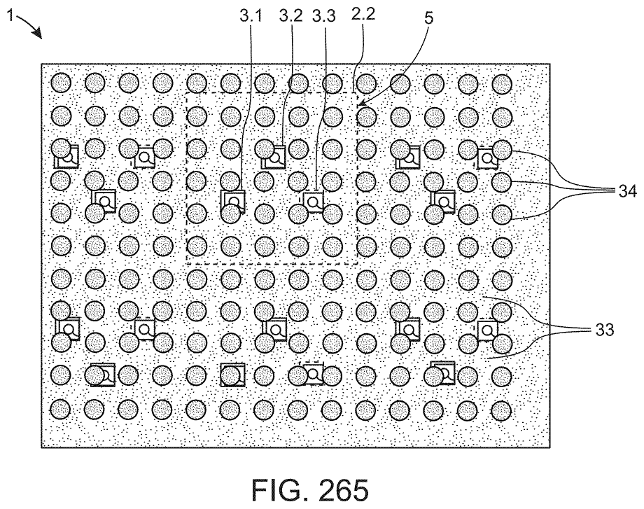

Depending on the application, the matrix of pixels with μ-LEDs of a small form factor presented here can be supplemented by a light-shaping or even light-converting structure. FIG. 265 shows a top view of such an embodiment. In this case, a light-shaping structure with areas 33 and 34 is arranged on the matrix. The areas 34 are configured as pillars or columns or holes in the transparent layer 33 covering the matrix. The refractive index of layer 33 is different from that of the columns 34 or holes 34. This results in a periodic variation of the refractive index in the two spatial directions as shown in the top view. In this way, a photonic structure or a two-dimensional photonic crystal is formed above the matrix of individual μ-LEDs and pixels. The light of at least one wavelength can thus be shaped appropriately by selecting the periodicity accordingly. In addition, the columns or holes or even the μ-LEDs forming the subpixels can be arranged above one another. In this way, the holes or columns form a light guide, which can lead to an improvement of the radiation characteristic, an increased decoupling efficiency or an improved directionality.

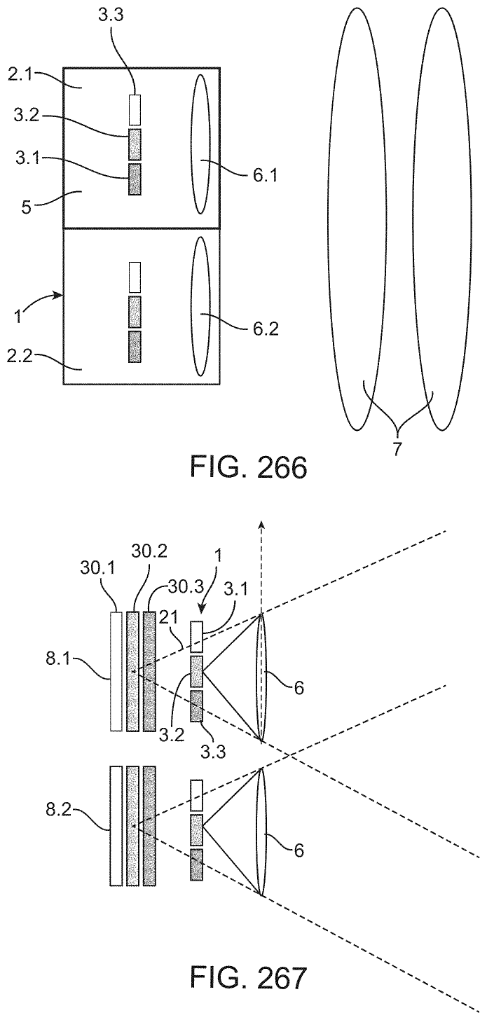

Furthermore, FIG. 266 shows a schematic view of the different components of a proposed projection unit. Such a projection unit has an optoelectronic lighting device 1, with matrix-forming pixels 2.1, 2.2, which have a low fill factor and each comprise μ-LEDs 3.1, 3.2, 3.3, which emit light of different colors, namely red, green and blue light. According to some suggested aspects, for each pixel 2.1, 2.2 a collimation optics 6.1, 6.2 is provided which collimates the light emitted by the μ-LEDs 3.1, 3.2, 3.3 and images it into a preferably virtual intermediate image 8.1, 8.2. With the aid of a projection optical system 7, the intermediate image 8.1, 8.2 of the μ-LEDs 3.1, 3.2, 3.3 is directed onto a display, screen or other display unit, which may also be the windscreen of a motor vehicle, which is not shown individually, in order to produce an image which can be perceived by the observer in the desired size, orientation and distance.

Furthermore, FIG. 267 shows the proposed location correction, which leads to an overlay of the enlarged virtual intermediate images 8.1, 8.2 of the μ-LEDs 3.1, 3.2, 3.3. Consequently, the collimation optics 6.1, 6.2 is designed in such a way that the size of the intermediate images 8.1, 8.2 of the μ-LEDs 3.1, 3.2, 3.3 essentially corresponds to the size of the respective pixel 2.1, 2.2 and additionally the different positions and sizes of the μ-LEDs 3.1, 3.2, 3.3 are largely compensated for the superimposition of the intermediate images 8.1, 8.2. Preferably the intermediate images 30.1, 30.2, 30.3 of the μ-LEDs 3.1, 3.2, 3.3 overlap over at least 85% and preferably over at least 95% of their intermediate image area. The intermediate images 30.1, 30.2, 30.3 of the μ-LEDs 3.1, 3.2, 3.3 may also overlap over at least 70%, 80% or 90% of their intermediate image area. It is also preferred that the total area of the overlapping intermediate images 30.1, 30.2, 30.3 of the μ-LEDs 3.1, 3.2, 3.3 of the respective pixel 2.1, 2.2 corresponds to at least 80% and preferably at least 90% of the pixel area 5. The total area of the overlapping intermediate images 30.1, 30.2, 30.3 of the μ-LEDs 3.1, 3.2, 3.3 of the respective pixel 2.1, 2.2 may correspond to at least 70%, 80% or 90% of the pixel area 5.

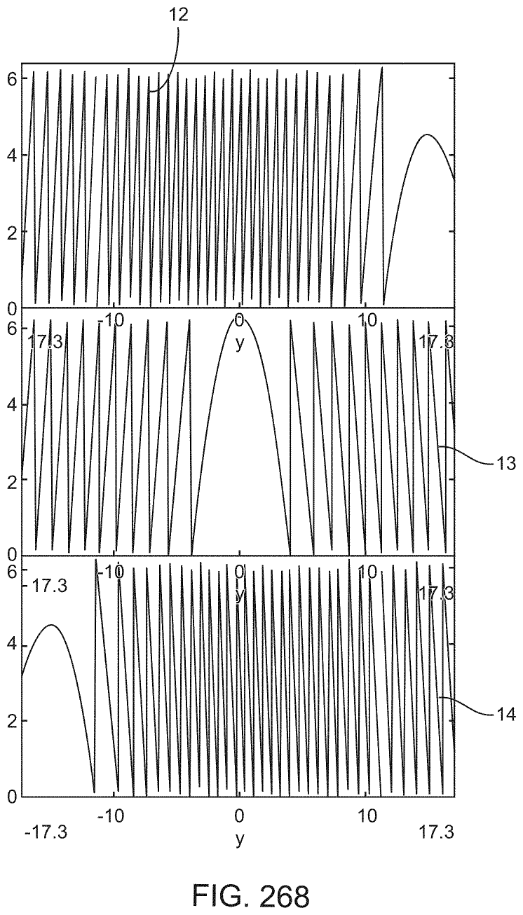

The collimation optics 6.1, 6.2 assigned to each individual pixel 2.1, 2.2 can be achieved by means of a holographic optical element (HOE), a refractive optical element (ROE) or a diffractive optical element (DOE). FIG. 268 shows the necessary chromatic phase function 12, 13, 14 of the collimation optics 6.1, 6.2, 6.3 for the three different μ-LEDs 3.1, 3.2, 3.3 of the respective pixel 2.1, 2.2. The upper graphic shows the chromatic phase function 12 for the μ-LED 3 emitting red light, the middle graphic shows the phase function 13 of the collimation optics 6.1, 6.2 for the green light emitting μ-LED 3.2 and the lower graphic shows the necessary chromatic phase function 14 of the collimation optics 6.1, 6.2 for the blue light emitting μ-LED 3.3.

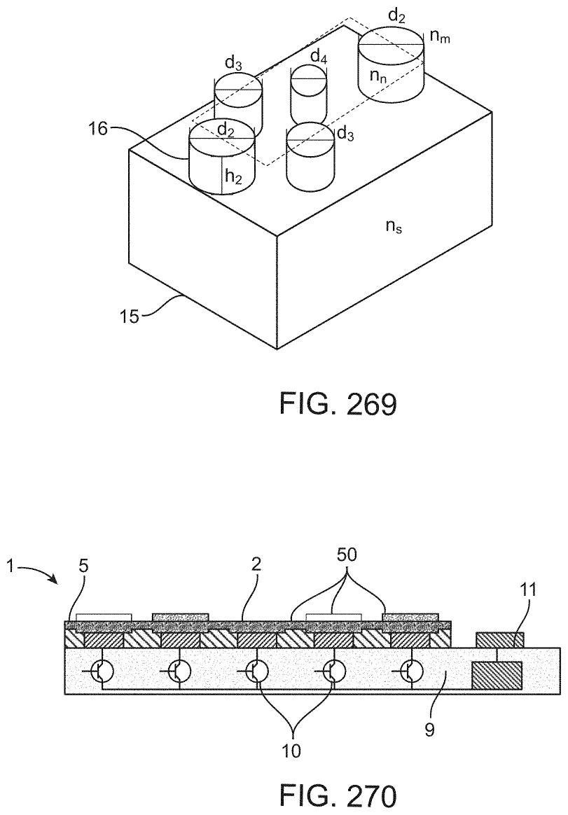

FIG. 269 shows an embodiment for which the collimation optics 6 is realized with the help of a meta-lens 15. Such a meta-lens 15 can be designed to produce either a refractive optical element or a diffractive optical element. It is advantageous for such meta-lenses 15 to have at least two spaced-apart regions, which have been structured in different ways. It is conceivable, for example, that in a first region of the meta-lenses a grid-like structure is provided, while the second region of such a meta-lens 15 comprises a circular structure. It is advantageous if the meta-lens 15 has a binary structure and/or is made of a dielectric material at least in some areas. A further aspect on FIG. 296 results when taking into account that the column structure can be arranged periodically or quasi-periodically. This results in an area with a periodic variation of the refractive index.

FIG. 270 shows the side view of a monolithic optochip containing the optoelectronic lighting device 1 for a projection display configured in accordance with the invention. The optochip has a silicon substrate 9 on which the individual pixels 2 with the sub-pixels provided therein are located. In order to supply the optochip with the necessary electrical energy, it has a power connection 11 and suitable conductor paths. The power supply and control of the individual light-emitting pixels 2 is provided by a CMOS array 10. Light generation at the subpixels is realized with LEDs, preferably μ-LEDs, which emit blue or ultraviolet light that is converted into light with the required color with the aid of suitable converter elements or suitable converter material.

On the surface of the optochip, there are pixels 2, in which subpixels 50 are arranged, each emitting red, green and blue light. The individual subpixels 50 each form a pixel 2 with a low fill factor, so that the individual light-emitting areas within a pixel 2 only occupy a part of the area of pixel 2 in comparison to the areas that do not emit any light, and are sufficiently spaced from one another in such a way that optical and electrical crosstalk between the individual subpixels 50 and between adjacent pixels 50 is reliably prevented or at least considerably minimized.

The pixels 2, each formed by three subpixels 50, are each assigned a collimation optic, not shown in detail in FIG. 270, which causes collimation of the radiation emitted by the subpixels 3 and spatial correction. According to the invention, the collimation optics produce 6 intermediate images of the subpixels 50 whose size corresponds to the size of a pixel 2. In addition, the collimation optics must be designed in such a way that the different positions and sizes of the individual sub-pixels in the intermediate image are compensated. In addition to the design with a monolithic optochip shown in FIG. 270, it is also conceivable to arrange different chips, each having one or a plurality of pixels or subpixels, on a common substrate and to contact them electrically. Preferably, the subpixels 50 of pixel 2 are formed by LEDs, which emit light with the required color, especially red, green or blue light. In principle, it is conceivable here to use LEDs that directly emit light with the desired color and/or convert the light emitted by LEDs, especially blue light, into light with the required color with the aid of suitable converter elements and converter materials. It is also conceivable to design the subpixel 50 as superluminescent diodes, VCSELs or edge-emitting lasers. It is also conceivable to implement the individual subpixel 50s by means of fiber optic cable end pieces that conduct light with the appropriate color.

In addition to the above version, the different resolution capabilities of the eye can also be taken into account by producing images of different resolution and directing them to the retina of a user.

As already mentioned, the central part of the fovea is dominated by the cones, whereas the rods are present over a larger angular range. Likewise, the increased cone density (L, S and M cones) means that better color vision predominates, as the three different types of cones (L or also red, S or also green and M or also blue cones) register different color valences. Towards the edge, the sensitivity of color vision is reduced in accordance with the lower cone density, but at the same time contrast vision is maintained over a larger angular range by means of the rods, which are still active at low light intensity and are therefore responsible for night vision. FIGS. 1B and 1D illustrate this relationship. Overall, a radially symmetrical visual pattern is thus formed for the eye. A high resolution of an image for all primary colors is required, especially in the center. At the edge it may be sufficient to generate an image resolution adapted to the spectral sensitivity of the rods (max. sensitivity at 498 nm, see FIG. 1B).

Small movements of the eye and a change in the direction of vision or focus can be counteracted by suitable optics and tracking of the eye.

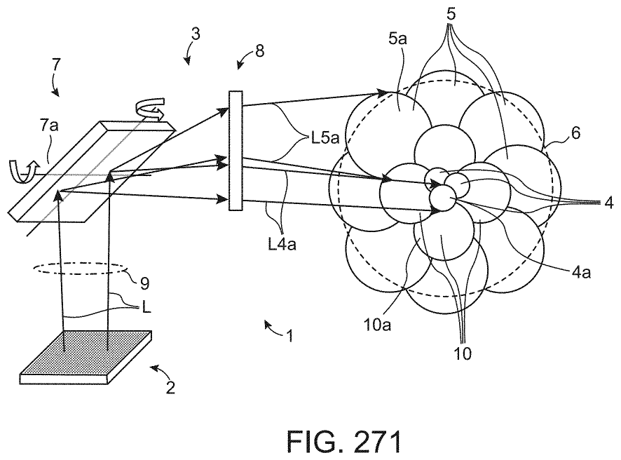

The optoelectronic device 1 of FIG. 271 comprises a μ-display or more generally an optoelectronic imager 2 for generating at least a first and a second image, and an imaging optic 3. The imaging optic 3 is adapted to project a first image of the first image with a first resolution onto a first region 4 of a retina 6 of the eye of a user and to project a second image of the second image with a second resolution onto another, second region 5 of the retina 6, the first resolution being different from the second resolution.

For this purpose, imaging optics 3 comprises a beam steering device 7, which comprises a movable mirror 7a. The mirror 7a, when appropriately positioned, directs light rays L4a of the first image, for example to the first region 4a of the retina 6, to produce the first image and, after adjustment of its position, directs the light rays L5a of the second image, for example to the second region 5a of the retina, to produce the second image. In the present case, the movable mirror 7a is tiltable about two axes, whereby the area illuminated on the retina can be adjusted in both vertical and horizontal directions.

Furthermore, the imaging optics 3 comprises a beam-shaping device 8, which focuses the light rays of the first and second image on the respective area of the retina. The light rays L4a of the first image are focused more strongly than the light rays L5a of the second image.

Since both the first and the second image are produced by only one imaging device 2, and since this imaging device 2 has a certain total number of pixels, the first and the different second resolution of the first and second image on the retina 6 is only produced by the different focusing of the light beams of the first image L4a and the light beams of the second image L5a by the beam-shaping device 8. The resolution of the first and the second image results from the ratio of the pixel number of the imaging device 2 and the area of the respective image on the first and second area 4a, 5a of the retina 6, respectively.

Since a high resolution of a projected image on the retina is only necessary in the area of center 4, the first area 4a with the first and higher resolution is closer to the center of retina 6 than the second area 5b with the second, lower resolution.

In the case of a retina 6 of an eye of a user of the optoelectronic device 1, which is to be assumed to be as round as possible, closer to the center essentially means that the center of the first region 4a, viewed in the radial direction, is closer to the center of the retina 6 than the center of the second region 5a. This means in particular that the resolution of the first and second images on the retina 6 is adapted to the higher receptor density at the center of the retina 6.

Since the optoelectronic device 1 comprises only one image generator 2 according to the embodiment of FIG. 271, the first image and second image and further images are displayed on the image generator one after the other in time. As a result, an overall image composed of the at least one first and one second image, i.e. a scene or a frame on the retina, is generated by a scanning process. The user only perceives the overall image due to the rapid sequence of the individual images. Scanning in this context means that the first and second image and possibly further, subsequent images are projected onto the areas of the retina one after the other, so that within a scene the entire surface of the retina is essentially completely illuminated by the images.

A marginal area 5 of the retina can be composed of several areas (e.g. area 5a), which are illuminated with images of the same resolution. Similarly, a central area 4 can be composed of several areas (e.g. area 4a) that are illuminated by images with the same higher resolution. Between the edge region 5 and the central region 4 it is also possible that at least one intermediate region 10 is formed, which is composed of several regions (e.g. 10a) and is illuminated with images with the same resolution. The edge region 5 and the at least one intermediate region 10 each largely form a ring which is illuminated by several images. The central area 4, on the other hand, largely forms a circle, which is also illuminated by several images. Illuminated areas of the retina may overlap. Preferably, however, the overlapping of areas is kept to a minimum. For example, less than 50% of the areas of the regions overlap, or less than 25% of the area of the regions, or less than 10% of the area of the regions.

Since the individual images are projected onto the retina so quickly one after the other, the result is, as mentioned above, a “total image” composed of the individual images within a scene on the retina, which is perceived by the eye as one image. Typical image repetition frequencies are 60 or 120 Hz and the display duration per frame is a fraction of a frame, whereby 2 to 100 partial images, preferably 5 to 50 partial images, are displayed per frame.

Optionally, an additional lens 9 can be placed between the imager 2 and the movable mirror 7a in order to focus the light beams L emitted by the imager and direct them to the movable mirror 7a.

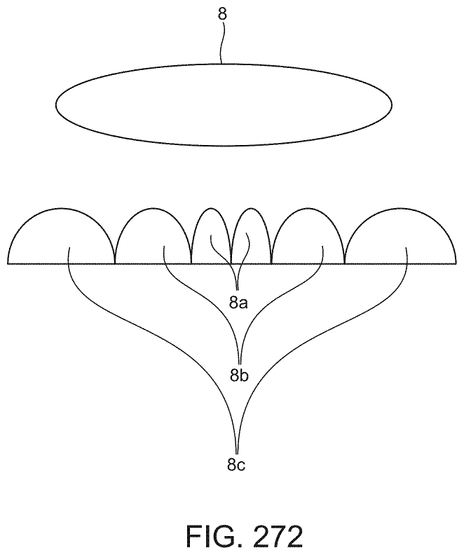

FIG. 272 shows two possible designs of the beam-shaping device 8, which can be either a classical lens with curved surfaces or a segmented lens. A different focusing of the first and second image with a classical lens is achieved in that a stronger focusing occurs under a light incidence with a small angle to the optical axis than with beams with a larger angle to the optical axis.

The segmented lens, on the other hand, consists of several smaller lenses (mini-lens array) that focus to different degrees. Lenses 8a are installed close to the optical axis of the system, which reduce the image considerably, whereas lenses 8b, 8c project the image onto a larger area of the retina 6. As an alternative to a classical lens, the beam-shaping device 8 can also be designed as a flat optical element, for example as a meta-lens. Especially in case of segmentation, this offers the advantage that individual areas can be structured directly adjacent or smooth transitions between areas of different lens properties are possible. For the overall system, the use of a flat optical element for beam-shaping can enable a compact design.

The optoelectronic device 1 of FIG. 273 differs from the optoelectronic device 1 of FIG. 271 in particular in that the movable mirror 7a is designed to tilt only about one axis. Furthermore, the beam-shaping device 8 can be formed from several optical elements, for example lenses 8a, 8b with different imaging properties. By tilting the movable mirror 7a, the at least one first and one second image generated by the imaging device 2 is sequentially projected onto the respective areas of the retina 6. The areas result as concentric circles that overlap in their center. The following two options are possible for the image formation of an “overall image”:

Each point on retina 6 is illuminated by only one projected image. In other words, for N images, the imager produces N−1 times a ring-shaped image with a dark central area, which is projected onto the retina 6.

Alternatively, at least one image generated by the imaging device can also be projected onto the entire retina, whereby, viewed in the radial direction, at least one second image in the center of the retina is projected onto the central region of the retina 6 with a higher focus and thus higher resolution than the first image, and thus the cumulative stimulation of the at least two images corresponds to a desired target value. In practice, this means that the basic stimulation that applies to a larger area of the retina is produced at low magnification and details are produced at higher magnification settings by additional stimulation. For this purpose, the image content is analysed by the electronics of a system with regard to the spatial variation and broken down into partial images corresponding to the different magnification scales.

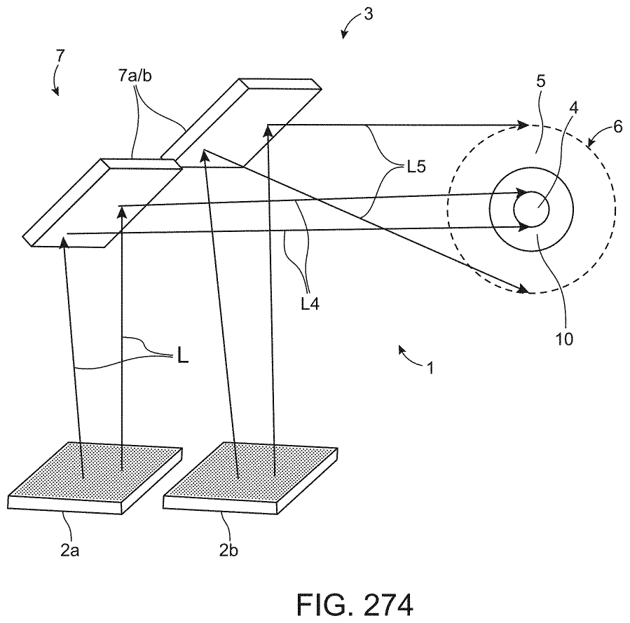

The optoelectronic device 1 of FIG. 274 differs from the optoelectronic device of FIG. 273 in that the beam steering device 7 has no movable mirrors but comprises at least two fixed beam steering elements 7a/b. In addition, the optoelectronic device 1 comprises at least two image generators 2a, 2b, which at least substantially simultaneously generate a first and a second image. The first beam steering element 7a directs the light rays L of the first image and the second beam steering element 7b directs the light rays of the second image in the direction of the retina 6. By an appropriately selected design of the beam steering elements 7a/b, the images of the at least one first and one second image are focused in a different manner on the retina 6, resulting in a different resolution of the two areas. An additional beam-shaping device is not necessary for this embodiment.

The areas on the retina 6 result, as already for the design of the optoelectronic device 1 of FIG. 273, as concentric circles overlapping in their center. The following two options, among others, are possible for the image formation of an “overall image”:

Each point on retina 6 is illuminated by only one projected image. With N imaging devices and correspondingly with N simultaneously generated images, N−1 imaging devices generate a ring-shaped image with a dark central area, which is projected onto the retina 6.

Alternatively, the image generated by at least one imaging device illuminates the entire retina, whereby, viewed in the radial direction, at least one second image generated by a second imaging device is projected in the center of the retina onto the central region of the retina 6 with a higher focus and thus higher resolution than the first image. The cumulative stimulation of the at least two images may correspond to a desired target value. In practice, this means that the basic stimulation that applies to a larger area of the retina is produced at low magnification and details are produced at higher magnification settings by additional stimulation. For this purpose, the image content is analysed by the electronics of a system with regard to spatial variation and is broken down into partial images that correspond to the different magnification scales.

The at least two beam steering elements 7a/b may, for example, be formed by fixed mirrors or have glass fibres.

With this embodiment, the imaging optics 3 can be made much simpler in comparison to the embodiments of FIGS. 271 and 273. Nevertheless, by using several imaging devices, an adapted resolution can be achieved on each area of the retina.

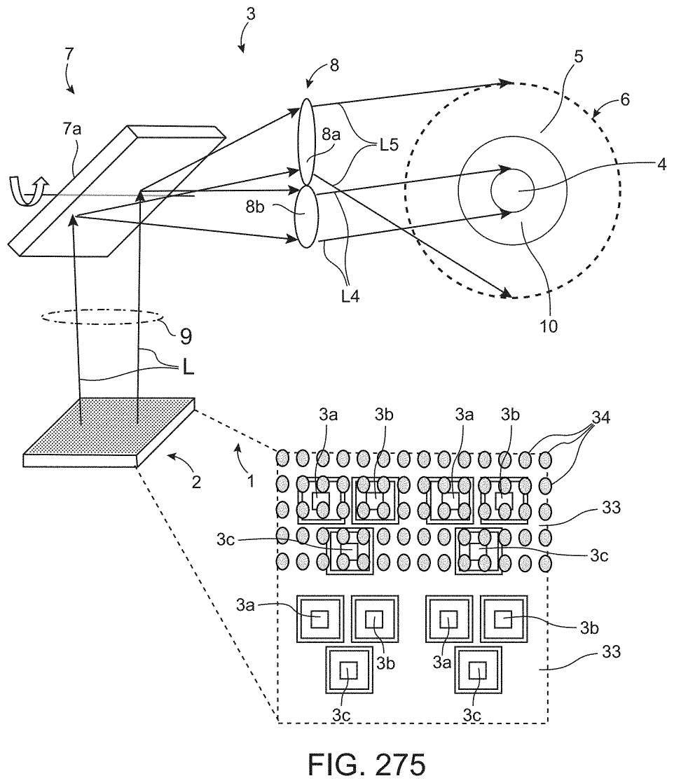

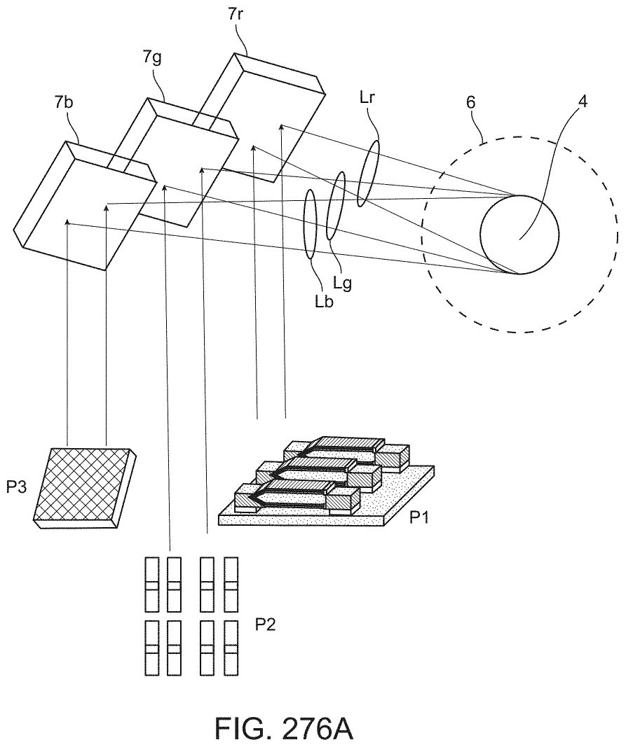

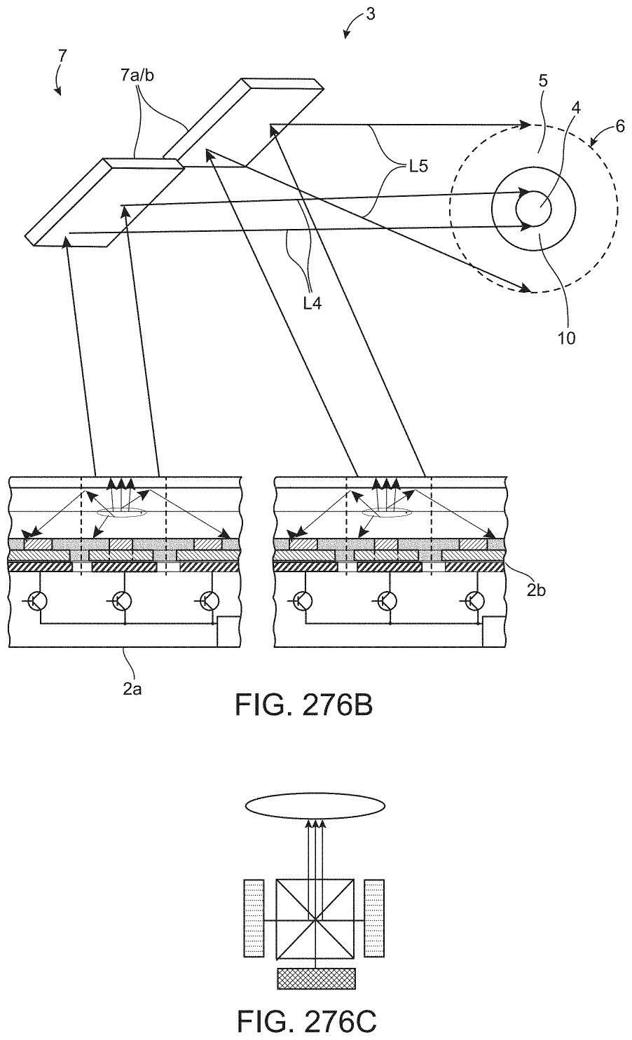

The various configurations of a beamline as shown in FIGS. 271 to 274 can be combined in any way, inter alia, with the various μ-displays and display devices disclosed in this application. FIGS. 275 to 276C show different configurations. In FIG. 275, light guide arrangement 3 is combined with a μ-display as shown in the configuration in FIG. 90. The μ-display 2 comprises a plurality of pixels arranged in rows and columns, each of which comprises a sub-pixel in the form of a μ-LED. The subpixels 3a, 3b and 3c are designed to emit and guide light of different colors. They are each surrounded by a reflective structure so that light emitted from the side is emitted upwards. To improve directionality, i.e. directional emission, a light-shaping structure is applied to the μ-display and in particular above the individual pixels. This comprises periodic areas with different refractive indices. For this purpose, a transparent material 33 is deposited on the upper side of each pixel and each μ-LED and periodic holes 34 are formed in it. The resulting structure thus forms a 2-dimensional photonic crystal, whereby the light emitted by the μ-LEDs is directed over the periodicity and radiated upwards in the form of a combined light beam L. Such collimation has the advantage that a more precise positioning on the retina of an observer is achieved by the mirror 7a and the lens system 8.

FIG. 276A shows a further embodiment in this respect. Instead of a μ-display with μ-LEDs with different color emission arranged on it, three different μ-displays are provided. Each individual μ-display P1, P2 or P3 comprises a large number of individual μ-LEDs arranged in rows and columns, each of which can be individually controlled to emit a specific color. The individual μ-displays P1, P2 and P3 thus generate a combined light beam, which falls on one of the mirrors 7r, 7g and 7b respectively. The mirrors redirect the light beam and guide it via a lens system Lr, Lg and Lb to the retina of an observer. In other words, the actual colored image is not already generated on the μ-display, but by the 3 different mirrors on the retina of the viewer. The individual color information is thus available separately for each pixel and is only assembled on the retina of the observer. Compared to a μ-display with the subpixels of each color, this embodiment has the advantage that the size requirements of each μ-LED are slightly reduced. In contrast, there is of course a larger space requirement.

The individual μ-displays P1, P2 and P3 are realized in this embodiment by 3 different designs. It goes without saying, however, that only one embodiment can be used for each individual μ-display. For example, the μ-display P1 for the red light comprises a plurality of horizontal μ-rods, which are contacted on the surface and can be individually controlled. In this design, the μ-rods are each monochrome, i.e. designed to emit red light. Accordingly, the other μ-displays P2 and P3 could also be equipped with such μ-rods to emit green and blue light respectively. Such a μ-display with horizontally aligned μ-rods of different colors is already shown in various other embodiments and can also be realized here with the shown light guide arrangement.

Furthermore, in the representation of FIG. 276A, the μ-display P2 for the green light is implemented with an antenna slot structure according to the proposed concept disclosed in this application. The antenna slot structure comprises 2 antenna slots arranged in parallel for each individual green pixel. On the one hand, the parallel arrangement allows a higher intensity and also allows compensating for possible defects by the redundant arrangement of two antenna slots per pixel. In addition, as shown in this embodiment, the emitted green light is linearly polarized due to the parallel arrangement of the antenna slots. In this respect, such an antenna slot structure as μ-display for each color would also be suitable for generating three-dimensional images on the retina of a user. In such a case, for example, the antenna slot structure for the μ-displays of the other eye could be arranged 90° offset. The lens systems Lb, Lg and Lr could possibly have switchable polarization filters.

A third version of a possible μ-display is realized by the μ-display P3. This comprises a plurality of monolithically integrated pixels of one color each, arranged in rows and columns. All μ-displays shown here can be equipped with further measures for light coordination and light shaping. For example, photonic structures of the surface or other light forms of the elements such as microlenses are conceivable.

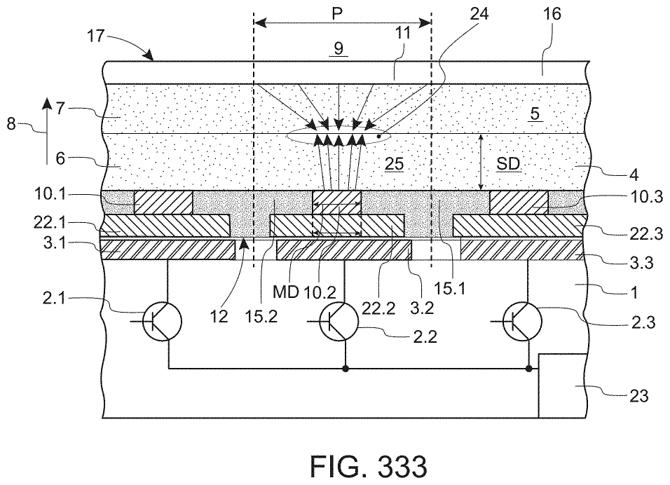

A further concept based on the embodiment of FIG. 275 and a μ-LED arrangement according to FIG. 333 shows the embodiment of FIG. 276B. The embodiment is adapted with 2 μ-displays 2a and 2b each, which contain a large number of monolithically integrated μ-LEDs. Each subpixel can be controlled individually. As explained in the embodiment for FIG. 275, the light emitted by the μ-displays 2a and 2b is deflected by the two mirror systems 7a and 7b either to the central area of the eye of the fovea or to the more decentralized area 5. Accordingly, if the μ-displays 2a and 2b are configured in the same way, the resolution in the fovea 4 area is higher than in the central area 5 due to the μ-display 2b and the mirror system 7b.

Finally, FIG. 276C shows a different embodiment in this respect with a dichroic cube. The dichroic cube comprises 2 semi-reflecting surfaces perpendicular to each other. On three sides of the dichroic cube, there is a μ-display of a plurality of μ-LEDs arranged in rows and columns. Each μ-display is designed to emit one color. In the example shown in FIG. 276C, the lower μ-display is used to emit a blue light, the right μ-display to emit a green light beam and the left μ-display to emit red light. The respective red and green light beams hit the surfaces of the dichroic cube in an angle and are deflected onto a lens system. In contrast, the two surfaces of the dichroic cube are transparent to the blue light, so that it hits the lens system directly.

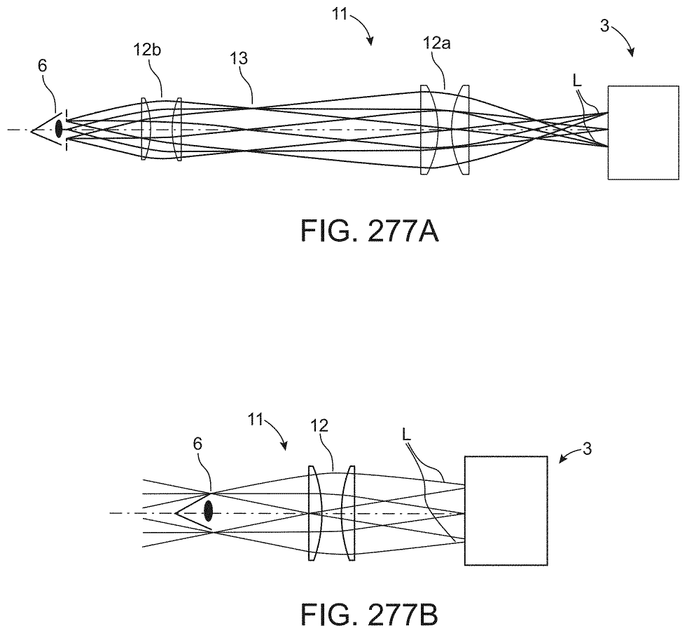

FIGS. 277A and 277B show two possible embodiments of beam systems 11, which can be arranged downstream of a respective imaging optics 3 of the device of FIG. 271, 273 or 274. The respective beam system 11 can thus be arranged between the imaging optics 3 and the eye.

The beam system 11 of FIG. 277A comprises an objective lens system 12a and an eyepiece lens system 12b, which are arranged successively in the beam path between the imaging optics 3 and the retina 6 in order to direct the light rays L to the retina 6 following the imaging optics 3. Since the light path of the light rays L crosses in the beam system 11, the objective lens system 12a produces an upside down and laterally reversed real intermediate image 13 of the projected image. By means of the eyepiece lens system 12b (principle of a magnifying glass), this intermediate image 13 of the projected image is viewed magnified.

The beam system 11 of FIG. 277B, on the other hand, comprises only one lens system 12, which is arranged in the beam path between the imaging optics 3 and the retina 6 in order to direct the light rays L to the retina 6 in the wake of the imaging optics 3. Correspondingly, no real intermediate image 13 of the projected image is produced in this lens system 11, but the projected image is merely viewed enlarged or reduced.

In a variant not shown, the respective beam system 11 could also be arranged between the imaging device 2, 2a, 2b and the imaging optics 3.

It may be intended that the imaging optics 3 are integrated in the beam system 11. With reference to FIG. 277A, the imaging optics 3 could, for example, be in the plane of the intermediate image 13. It may be provided that a pair of lenses of lens system 12b shown in FIG. 277A, which at least substantially defines the magnification, is spatially segmented (or at least one of the two lenses), and that the imaging optics 3 lies between the spatially separated segments of a lens. Alternatively, the imaging optics 3 can also lie between the two lenses of the lens pair shown.

Also in the variant according to FIG. 277B, the shown lens pair of lens system 12 could include imaging optics 3, either as an additional element in between or as a modification of one or both lenses of the lens pair.

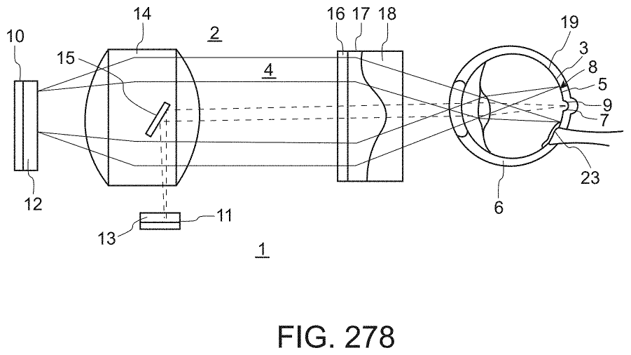

An alternative design to transfer images to or into the eye of a user is achieved by a Light field display which creates an image within the eye by direct retinal projection. FIG. 278 shows a first version of a light field display 1 according to some of the principles presented here, which is explained below for the components assigned to a user eye. Binocular optics not shown in detail accordingly show a symmetrical double arrangement of the outlined components.

Shown in FIG. 278 is an optoelectronic device 2 and an optics module 4 that create a retinal projection 5 of a raster image 3 in a user's eye 6. The optoelectronic device 2 comprises a first imaging unit 10 with a first μ-display 12 and a second imaging unit 11 with a second μ-display 13. Both μ-displays are designed as μ-LED array with a plurality of μ-LEDs in rows and columns. The μ-LEDs are organized as pixels, with each pixel having three subpixels of different color. In other words, each μ-LED is designed to emit one color and is individually addressable and controllable.

For the embodiment shown, optics module 4 has a collimation optics 14 and a projection optics 17 with a free-form lens 18, which produce a first raster partial image 8 of the first imaging unit 10 on the retina 19 of the user's eye 6. The first partial raster image 8 is created over a large area.

For the imaging of the second imaging unit 11, an adjustment optic 15 is available in optics module 4, which is arranged within the collimation optic 14 for the present embodiment. For other embodiments not shown in detail, the adjusting optics 15 can be located between the collimation optics 14 and the projection optics 17 or at least partly in a waveguide 16 of the projection optics 17.

The second raster subimage 9 of the second imaging unit 11 is projected onto a local area of the retina 19 with the fovea centralis 7, in which the most precise optical perception can be achieved due to the high surface density of the visual cells, which are exclusively designed as cones for photo-optical vision. A higher resolution is selected for the second raster subimage 9 than for the first raster subimage 8.

FIG. 1C shows the different perceptual capacity of the human eye by means of a graph of the angular resolution A relative to the angular deviation α from the optical axis of the eye. The highest angular resolution A is in a region of the fovea centralis 7 with a diameter of 1.5 mm on the retina 19, which covers an angle of about +/−2.5° around the center (0°). In addition, there is a blind spot 22 on the retina 19 at an angle of about −15°. FIG. 1C also illustrates the local limitation of the second projection area 21 of the light field display 1 for the high-resolution second raster field 9 and the larger first projection area 20.1, 20.2 for the first raster field 8 with a lower resolution.

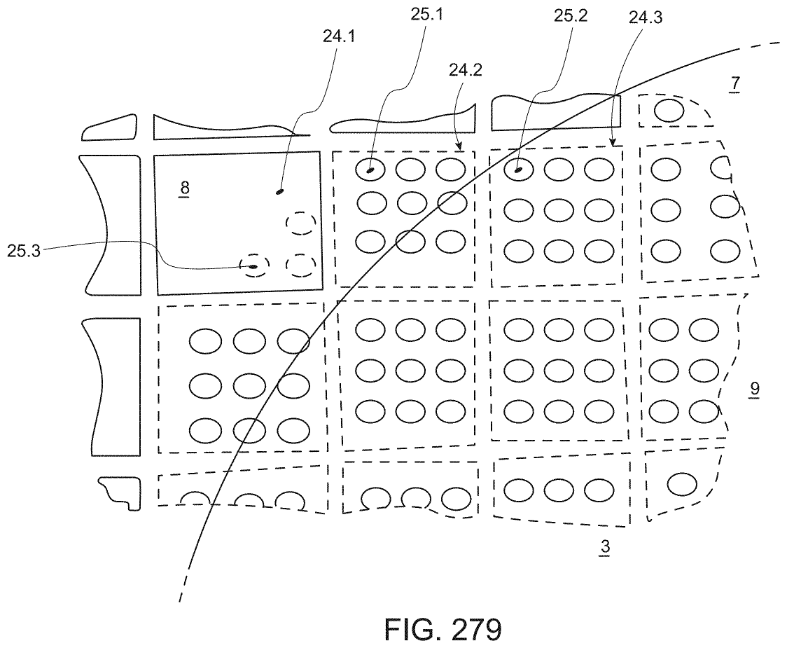

FIG. 279 illustrates the assembly of the first halftone image 8 and the second halftone image 9 to form the halftone image 3 projected onto the retina 19. For the first raster image 8, an activated first pixel image 24.1 with a relatively low resolution is sketched with a solid line. In addition, two non-activated and dashed first pixel images 24.2, 24.3 of the first raster field 8 are shown, whereby the representation in these areas assigned to the fovea centralis 7 is replaced by an arrangement of second pixel images 25.1, 25.2, which are part of the higher-resolution second raster field 9. In order to keep an overlap area of the two halftone images 8, 9 as small as possible, individual second pixel images 25.3 can also be switched off for the advantageous design shown by an appropriate control of the second imaging unit 11.

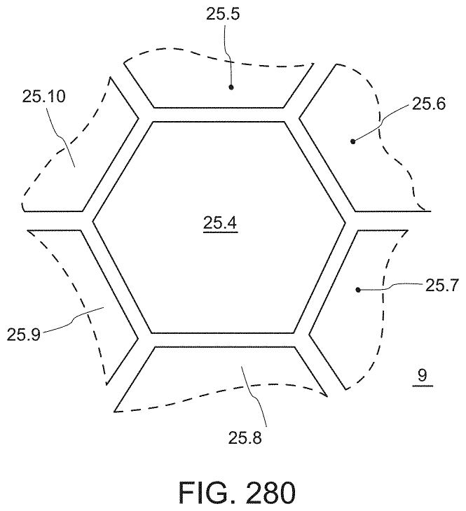

FIG. 280 shows that the contours of the pixel images may differ from the rectangular shape. Shown is a hexagonal version of the second pixel images 25.4-25.10, which allows a high surface density. Techniques to produce such μ-LEDs are disclosed in this application.

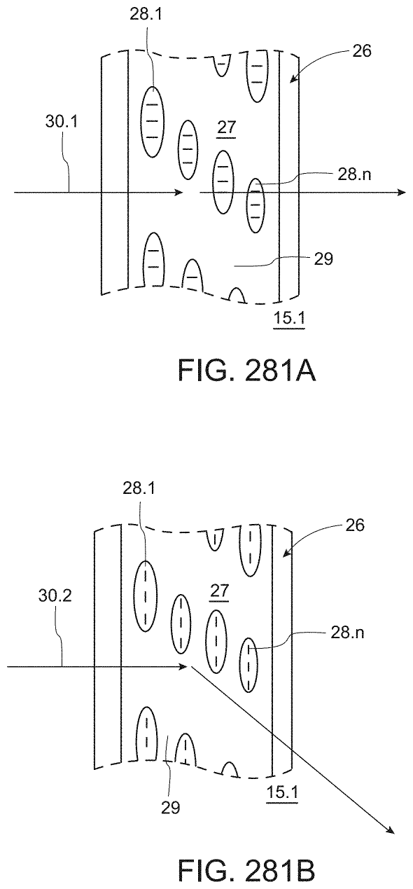

FIGS. 281A and 281B show a possible design of the adjustment optics 15.1, 15.2 with the help of which the relative position of the retinal projection 5 of the second halftone image 9 can be adjusted in relation to the retinal projection 5 of the first halftone image 8. Shown is a version with a switchable Bragg grating 26, which has a holographically produced pattern 27 with liquid crystal areas 28.1-28.n in a polymer matrix 29. FIG. 281A shows the state with an electric field oriented in a first direction and an undeflected optical path 30.1 and FIG. 281B shows the state with an electric field oriented in a second direction perpendicular to the first direction and a resulting deflected optical path 30.2.

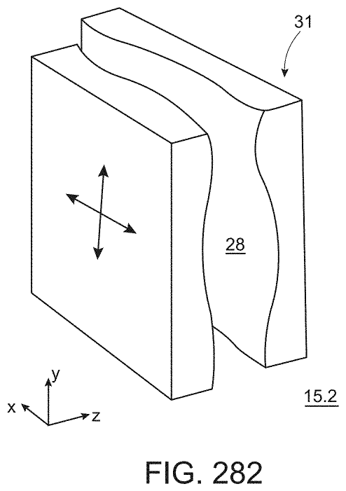

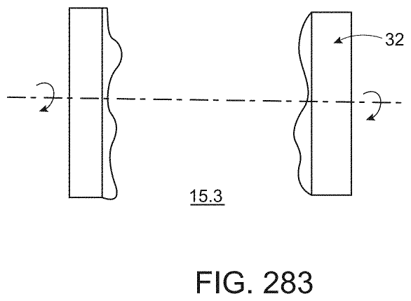

An alternative embodiment of the adjustable optics 15.2 with an adjustable Alvarez lens assembly 31 is shown in FIG. 282. This comprises a double arrangement with phase plates each having a surface relief, which can be moved relative to each other in the x and y direction for beam adjustment. A special type of adjustable optics 15.3 with rotating Alvarez lenses, called Moire lens array 32, is shown in FIG. 283.

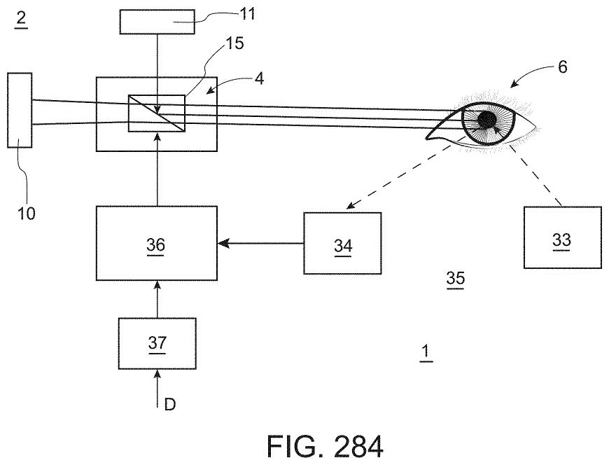

FIG. 284 shows a further embodiment of the proposed light field display 1 with a measuring device 34 to determine the position of the fovea centralis. For this purpose, a user eye 6 is illuminated by means of an IR illuminator 33 and an image of the retina 19 is taken. In the example shown, the second halftone image 9 (cf. FIG. 278) is dynamically adjusted so that the measuring device 34 is part of an eye movement detection device 35 with which the direction of vision of the user can be followed. By means of a control device 36 connected to the eye movement detection device 35, the adjusting optic 15 is controlled in such a way that the second halftone image 9 of the second imaging unit 10 is held in the area of the fovea centralis, while the first halftone image 8 of the first imaging unit 11 remains stationary in relation to the optoelectronic device 2. In addition, the control device 36 is connected to a prediction device 37 in which a model of eye movement fed by the displayed image data D is calculated.

In addition to the concepts presented here for the production and structuring of μ-LEDs and μ-Displays or modules, a special concept of such a module is introduced in the form of a imaging element with a variable pixel density.

The inventors take advantage of the fact that the human eye does not see equally well everywhere in its full range of vision, both in terms of color perception and spatial resolution. Thus, an imaging element only needs to have as good a resolution as is required for the respective areas in the eye.

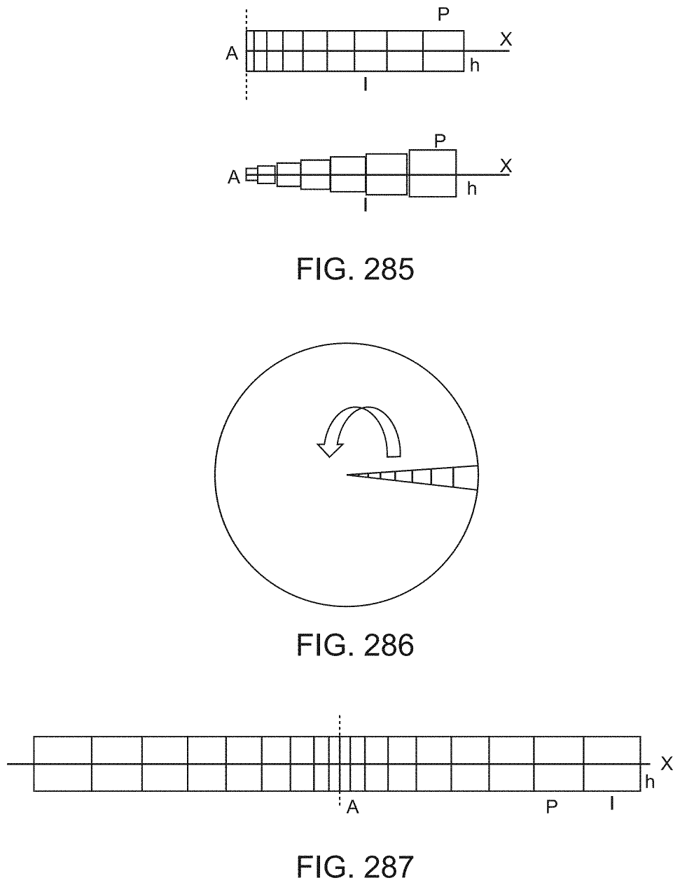

FIG. 285 shows examples of a linear pixel array comprising a single row of a plurality of μ-LEDs arranged side by side, or a monolithic LED array in which pixels in the μm range can be individually controlled. The line comprises a starting point A, to which the individual pixels P of the line are connected along the axis X. These pixels are optoelectronic components, which are set as μ-LEDs along the line or as monolithic integrated components, possibly also in segments. Each pixel has a fixed height h, but variable width 1 and comprises at least one light-emitting element, for example a μ-LED. The pixels are arranged centrally around the axis X, and the pixels with the smallest width are closest to the starting point A. In the embodiment shown, the pixels widen with a fixed predetermined function, for example a linear function. The number of pixels in the line corresponds to the resolution of the display to be shown. In other designs, the widening in width 1 can follow the course of the sensitivity of the rods and cones of the eye. Thus, some adjacent pixels have the same width, others have a different width. Another possibility is a group widening, i.e. a number of pixels along the axis comprise the same width or dimension, a second group adjacent to it has a larger width. The latter way can be implemented as a monolithic component in groups or segments.

In the second example, the pixels increase both in width 1 and height h with increasing distance from the starting point. The change is chosen in such a way that a suitable rotation through an optical system results in a visual impression in which the pixels are each located on points of circles without any gaps between them. The number of pixels in the line can be in the range of several hundred pixels, but it can be less than an HD resolution of 1980 pixel points per line.

In an example, about 150 pixels with the smallest width are arranged in one line from the starting point. The width can be 5 μm, for example. Then follows another group of 150 pixels with a pixel size of 10 μm. Two further groups with pixel sizes of 20 μm and 30 μm and a number of 100 pixels or 50 pixels follow. This results in a total length of the line of about 5750 μm. However, with approximately the same effective visual resolution for the eye, the number of pixels is significantly reduced to 500, which leads to a simpler and more cost-effective production.

In this context, it should be emphasized that the width between adjacent pixels is not always different, but can also be the same. In some cases, a pixel can also have a smaller dimension than an adjacent pixel closer to the starting point. However, the expression “width substantially increasing from the starting point” means that the width of the pixels increases with distance over a larger number of pixels. The width, and possibly also the height, therefore generally increases for pixels with a greater distance from the starting point, even though isolated pixels with neighboring pixels may comprise the same dimension. Thus, the above-mentioned execution of a segmental widening also falls under the above-mentioned expression.

Using imaging optics, an image can now be generated by rotating the pixel array around the starting point. For this purpose, the pixel array itself is not rotated, but the light stripes generated by the pixel array are shifted in fixed periods with an imaging optics, so that the impression of a rotation around the starting point is created. If this offset occurs, fast enough, the inertia of the visual processing results in the impression of an image. The number of individual steps may or may not depend on the height of the individual pixels. Depending on the image, the period can also be selected in such a way that a certain overlapping area results, especially in the high resolution area of the eye.

FIG. 286 shows a schematic representation of such a rotation. In contrast to the pixel row in FIG. 285, the height of each pixel is also varied here and the height of the pixels increases with increasing distance from the starting point. This can be done in two ways. First, the height of the pixels can actually be changed. Another way is to place an aperture above the pixel row so that the aperture widens. Thus, each pixel resembles a trapezium rather than a square or rectangle. Thus, when the pixel line is rotated around the starting point, the step size for each pixel remains essentially constant and the “rotated” pixels lie “next to each other”. The height of a pixel can be approximately determined by Hpixel>=2 d/nπ where d is the distance from the starting point to the pixel and n is the number of steps for a 360° rotation. If the height of the pixels is selected to be larger, there will be an overlap between pixels during the rotation.

FIG. 287 shows another embodiment in which the pixel array is symmetrically arranged along the X-axis around a center point that represents the starting point A. The advantage of this arrangement is that the imaging optics need only rotate the array by 180° to produce a complete image.

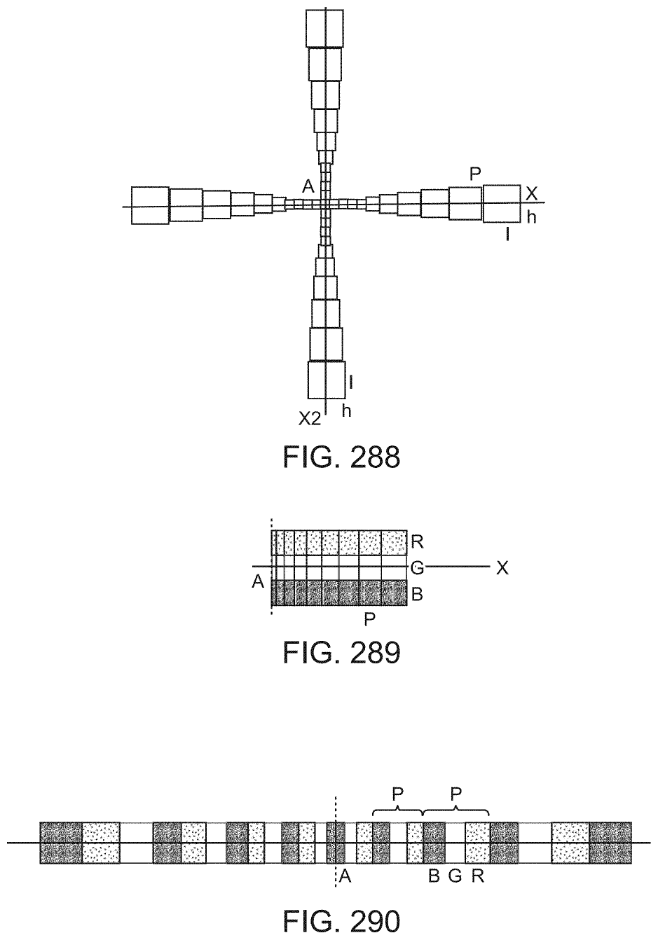

FIG. 288 shows an embodiment of a pixel matrix with two pixel arrays arranged perpendicular to each other. The two pixel arrays have a common center point around which the pixel density is greatest, i.e. the pixels have the smallest size. During operation, the two pixel arrays generate a light cross along the axes X and X2, which can be rotated by a downstream optical system to generate a complete image. The arrangement with two, or in alternative embodiments also several pixel arrays, allows a simpler design of the optics. In the example shown here, the optics is configured to rotate the generated light cross by only 90°, so the pixel array is rotationally symmetrical by 90°.

FIG. 289 shows another aspect concerning the color perception of the eye. In the embodiment shown, several lines are arranged one above the other with subpixels of different colors. A column of subpixels of the colors thus forms one pixel. The subpixels of each pixel of each line are, for example, formed in the different basic colors R(ot), G(rün) and B(lau). The lines of the different colors are arranged in a row “one above the other” along the axis. For example, the middle green line G is located centrally on the X-axis of the line, a red line R and a blue line B are adjacent to the first line with the green subpixels G on both sides of the axis. In the example, the arrangement and especially the pixel density is the same for each line.

FIG. 290 shows an alternative embodiment in which pixels P and their subpixels of different colors are arranged in a single line. The pixel line is arranged symmetrically around the starting point A. In the example, the subpixels of each pixel P have different colors but the same width. The width between the pixels increases continuously. The pixels in the line that are further out, that is, those that are further away from point A, also have a greater width. Alternatively, it can also be taken into account that the rods and cones in the eye also have different relative color sensitivity at the same angle from the center of vision. In order to compensate for this, the subpixels of different colors are also designed with different widths, i.e. with different dimensions. If the current through the pixels remains constant, there is a different brightness of the color, so that the user has the impression of equally bright colors at the respective location.

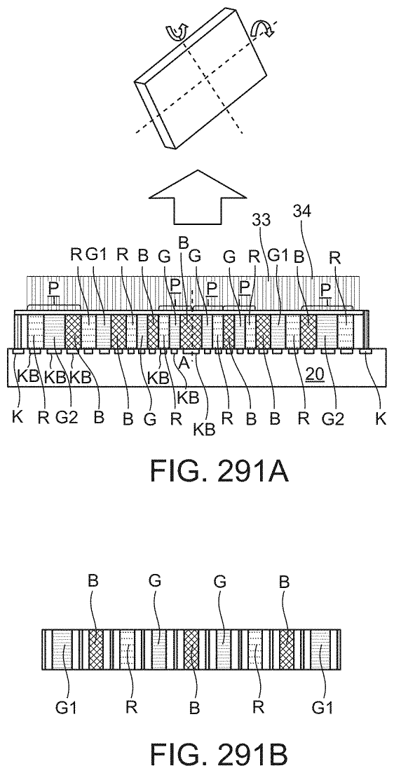

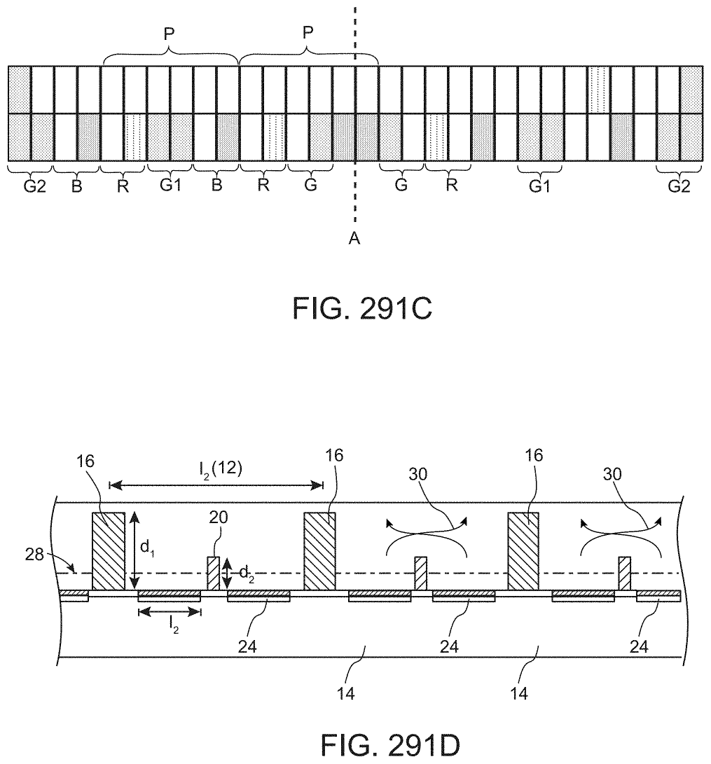

FIG. 291A shows a further embodiment in cross-sectional representation of a pixel line according to the proposed principle. The mirror device arranged above the pixel line can be rotated in 2 axes and can thus generate a circular image with different resolution for the user, as already presented in this application. The pixel line itself is arranged on a carrier substrate 20, which comprises different contact areas KB and K. In addition to the contact areas KB and K, the substrate 20 also includes drive electronics, driver circuits, and power supply for the electrical supply of the pixel array and the individual μ-LEDs. The contact areas KB are designed differently depending on the size of the pixel of the pixel row arranged above. This simplifies positioning and contacting of the respective μ-LEDs of a pixel P of the pixel row. In this embodiment, a pixel P is made up of 3 subpixels R, G and B each with one μ-LED each. A central subpixel with one of the colors blue B is arranged rotationally symmetrically around the axis A. It has twice the size of the adjacent green and red subpixels G and R.

As shown, the pixels P and the corresponding subpixels R, G and B and the μ-LEDs show an increasing size with increasing distance from the rotation axis A. For example, the μ-LEDs of the subpixels B, G2 and R of the outer pixels P are significantly larger than the μ-LEDs of the pixels adjacent around the central axis A. In addition, the μ-LEDs of the green subpixels G1 and G2 have larger dimensions compared to the other μ-LEDs of the same pixel as the distance from the rotation axis A increases. This is useful because the eye reacts more sensitively to the green color and thus the green color also dominates in peripheral vision.

The shown μ-LEDs are configured as vertical μ-LEDs. For this purpose, they have a common connection contact on the side facing away from the substrate 20, which is electrically connected to the contacts K on the outside. A light-shaping structure in the form of a photonic crystal with the areas 33 and 34 is applied to the upper side of this transparent cover electrode. The areas 33 and 34 produce a variation of the refractive index and thus cause a collimation of the light emitted by the μ-LEDs.

The pixel line proposed according to this concept can be realized with μ-LEDs of different shapes and designs. FIG. 291B shows an embodiment in which the individual sub-pixels of each pixel are implemented in the form of so-called bars using μ-LEDs. A converter material is arranged between a pair of μ-LEDs. At a greater distance from the central subpixel with the color blue B, the μ-LEDs emitting a green color are designed larger. This aspect considers the already mentioned increased sensitivity of the human eye in the green range.

FIG. 291C shows a different embodiment. For each individual subpixel of a color, a matrix of 2×2 μ-LEDs is provided, which are electrically separated from each other but optically connected. Thus, 2 essential aspects can be realized. On the one hand, this design allows defective μ-LEDs to be sorted out and replaced by working μ-LEDs. This is shown for example in the right area in the bottom line with a red subpixel, which is marked as defective as shown. The marked defective red μ-LED is replaced by another μ-LED in the red subpixel. Additionally further outside, a different intensity and radiation characteristic can be achieved by switching on additional μ-LEDs in the respective subpixel. This is indicated by the μ-LEDs of the green subpixel G1 and G2.

The structure shown in FIG. 291C comprises 4 μ-LEDs for each subpixel, some of which may be designed as redundant μ-LEDs. In a different configuration, the matrix can also be a 2×1 matrix, with only a single row of 2 μ-LEDs per pixel. The decreasing resolution capabilities of the eye outside of an area of the fovea can be taken into account by enlarging the μ-LEDs.

FIG. 291D shows the cross-sectional representation through the pixel structure of FIG. 291 shown in top view. The embodiments of these μ-LEDs with optical and electrical separating elements 16 as well as electrical separating elements 20 is already explained in this application in the embodiment of FIG. 133.

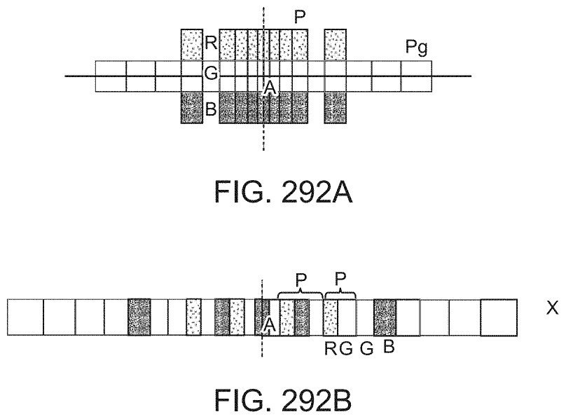

Finally, the two embodiments in FIGS. 292A and 292B take into account that the sensitivity of the eye to recognize colors also depends on the angle of vision and the distance to the center of the fovea, respectively. The dependence of sensitivity is expressed by the fact that further outside, i.e. at a greater distance from the center, the eye no longer comprises as many cones that react to the colors red and blue. Here the rods for the color green predominate. Correspondingly, a variable, i.e. different density is proposed for the respective pixels or subpixels of green color. While near the starting point A the subpixels of different color are distributed essentially equally in the three lines, the line with the pixels for the color green predominates with increasing distance.

In FIG. 292A, the greater number of pixels of green is achieved by placing the first line of green subpixels centrally along the X-axis, with essentially all pixel positions occupied. The other two lines R, B with the red and blue pixels are placed above and below the first line. Near the central starting point A, the pixel positions in all three lines are occupied. With increasing distance, however, not all positions in the second line R and the third line B are occupied, i.e. some positions for the red and blue pixels remain unoccupied. The occupancy density of the second and third lines decreases compared to the first line. This result in a lower number of red and blue pixels compared to the green pixels. In other words, the second and third lines are thus “shorter” than the first line.

In the alternative embodiment of FIG. 292B, the pixels of different colors are arranged along the X-axis similar to the embodiment of FIG. 290. Close to the starting point, the pixels of lines R, G and B are equally distributed. As the distance increases, the density of pixels in lines R and B decreases, so that the pixels of the color green predominate in line G. At greater distances from the starting point A, the pixel line G with the green basic color then predominates.

It should be explicitly mentioned at this point that the different aspects and examples can also be combined with each other to create a desired arrangement that makes sense for the respective application. This also, but not only, concerns the combination of lines and pixels in the respective lines, i.e. combinations that relate to spatial resolution and color sensitivity.

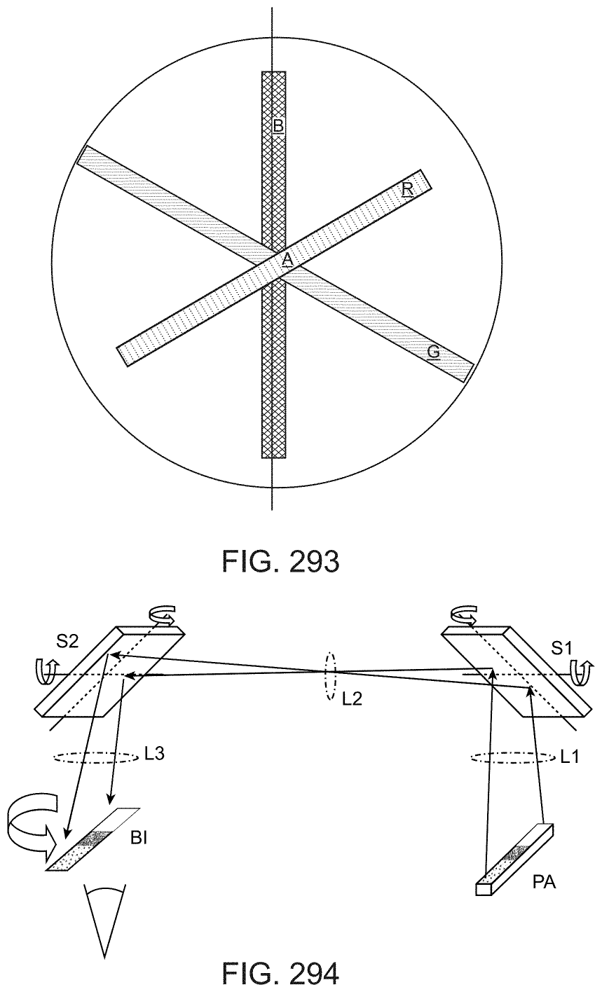

FIG. 293 shows another embodiment of a pixel matrix in which three lines R, G, and B are offset from each other with pixels of different colors. The three rows have a common center A, and the angle between individual adjacent rows is 60°. Each line R, G, and B has pixels of the same color. In addition, the widths of the individual pixels of each line are different (not shown here) to account for the different sensitivity. The staggered arrangement makes the realization easier, because the μ-LEDs of each line can be manufactured independently from the μ-LEDs of other lines. By rotating the resulting image by means of an optical system by 180°, an approximately circular colored image is generated. In addition to this arrangement, the lines have different “lengths”. Furthermore, the pixel density of the individual lines of different color is also different. The line with the green color has the highest pixel density, because the eye reacts most sensitive to this. In the outer area, the pixel width of the lines R and B is increased, i.e. the spatial resolution is reduced there. In addition, lines R and B are somewhat shorter because the color sensitivity of the eye is reduced so much near the maximum distance that red and blue colors are no longer perceived.

FIG. 294 schematically shows an implementation of an imaging optic to convert an imaging element with a variable pixel density into a virtual image. The imaging element is a single pixel row with different subpixels that are designed to deliver a color. In addition to this pixel line, other imaging elements disclosed here can also be provided. The virtual image is created by a fast rotation of the light emitted by the pixel array with several pixels in the user's eye. In particular, the pixel array generates a strip of light that corresponds to an image line in polar coordinates. The light is bundled by a first lens L1 and directed to a first mirror Si. The first mirror S1 can be tilted around two axes that are perpendicular to each other, so it can deflect the light strip around these two axes.

The light deflected by the first mirror is directed via another lens L2 to a second mirror S2. This second mirror can also be tilted around two axes arranged perpendicular to each other. This functionality is exemplified in the figure by the two arrows. A third lens L3 focuses the generated light strip onto the user's eye. The light strip is now rotated by a slight periodic tilting of the mirrors S1 and S2. The tilting can be realized with MEMS or piezoelectric elements. With each rotation, the image and color information desired at the new position is also radiated from the PA pixel array. Due to the inertia of the eye, a sufficiently fast rotation creates the impression of a circular image. The point of rotation in image Bi, for example, is placed in the focal point or direction of vision of the eye. A change in the direction of view can be detected by eye-tracking measures. The mirrors S1 and S2 can then follow the rotation point and deflect the image so that the rotation point is again in the focus of the eye.

Each of the three lenses can be optional. Likewise, measures other than lenses or mirrors, or other combinations of such optics, may be provided to produce the desired effect.

For displays a control of each pixel is done individually and separated from a second pixel to provide the appropriate flexibility to visualize any kind of information. In simple terms, it requires it requires controlling separately approximately 2 million pixels in a matrix of 1920×1080 pixels as in conventional TVs or monitors. Apart from the challenges of addressing such a number of pixels individually, in augmented reality and automotive applications, the display is quite small and the pixel size, as mentioned above, is only a few μm.

In conventional drivers for larger pixel sizes and displays, the analogueue drivers, like the digital circuits, can be easily placed under the corresponding pixels. In such conventional displays with a pixel, size of for example 200 μm² the available space “under” the pixel is of the same order of magnitude. The driver circuit could easily be implemented in the available space and the size of the pixel itself would not be the limiting factor. However, with the reduced size of the pixels, the available space is no longer sufficient for conventional circuitry. A similar problem arises when using digital circuit technology in the material systems used so far. Silicon technology offers possibilities to further reduce the size of circuits, but this material system cannot easily be combined with existing materials for generating blue or green light.

Therefore, new concepts are needed, which can roughly be divided into two areas. The first area refers to new designs of transistors, capacitors or other elements. The designs themselves may exist for completely different applications or fields of technology but not in combination with the material systems used for the μ-LED or in combination with μ-LEDs as such. The second area relates to circuit design and the principles of driving μ-LED pixels. Simply put, digital transmission paths to address the pixels in rows and columns take up space, as does the corresponding row and column decoding. The same applies to the realization of current sources or buffers to supply the individual μ-LEDs with the necessary current. The design in monolithic as well as single μ-LEDs can allow different concepts to achieve a good visual impression with new approaches in addressing the μ-LEDs in a display.

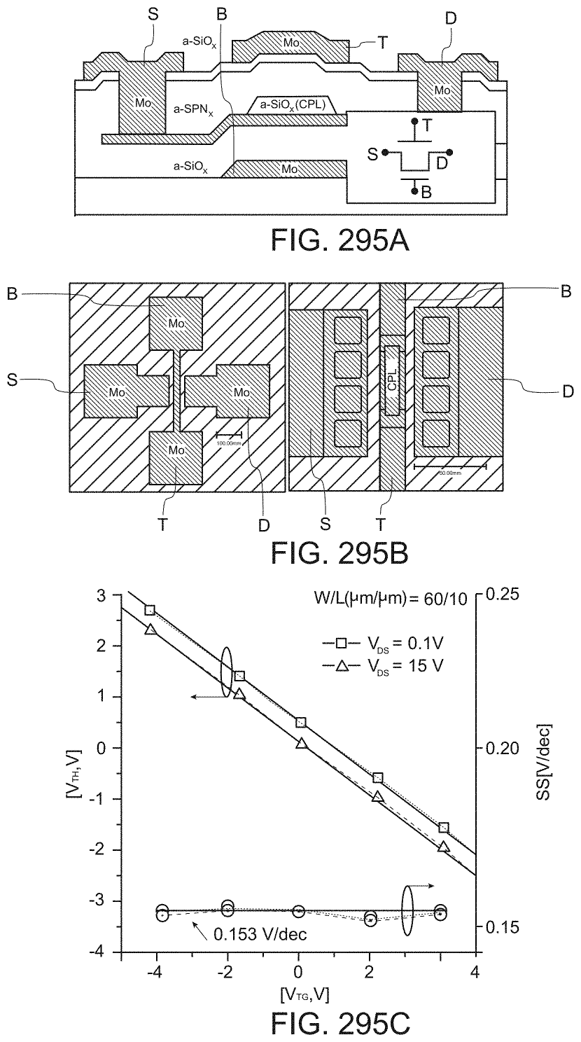

FIG. 295A shows an embodiment of a current driver for μ-LEDs with backgate and dual-gate transistor, respectively, which is formed in NMOS technology. This design can be realized in a particularly compact form with only little space consumption.

Such a back-gate transistor is often used as a current driver transistor or as a current source. It is constructed in TFT (thin-film technology), among other things, and has a second control connection, also known as a back gate, in addition to its standard control connection or gate. With the help of this additional back gate, the conductive channel of the transistor can be changed as explained below. Instead of an additional transistor for pulse width modulation (PWM), the back gate of an existing dual-gate transistor can now be modulated with a PWM signal.

FIG. 295A shows a cross-section of a backgated NMOS field-effect transistor. On the left side is a source region S, on the right side is a drain region D, with a current conducting channel between the two regions. The resistance of the channel, i.e. its ability to conduct current, is changed by a single gate in a normal field effect transistor. In a dual-gate transistor, the channel is changed by a first bottom gate B and a second top gate T. The gates are located on different sides of the channel. In the embodiment shown, the top gate (upper gate) provides the additional rear side contact or back gate contact.

FIG. 295B shows two top views of the dual-gate transistor as shown in FIG. 295A. As shown in the left-hand illustration, a power line can be controlled by a left source area S and a right drain area D via top gate T and/or bottom gate B. The right-hand illustration in FIG. 295B shows a section of the arrangement shown in FIG. 295A.

FIG. 295C shows an illustration of the dependence of a threshold voltage on a top-gate voltage V_{TG} and thus the interaction of a back contact with the threshold voltage V_{TH}. The threshold voltage VTH is in particular the gate-source voltage V_{GS}, with which the field effect transistor becomes conductive. FIG. 295C shows the x-axis, the voltage V_{TG} applied to a top gate T. As a function of this, the y-axis shows the threshold voltage VTH for changing the conductivity of the channel of the controlled NMOS field effect transistor. For example, a top gate voltage of 0 V provided a threshold voltage of 0.5 V for current conduction. By means of the additional top gate of the insulated Gate ZO NMOS transistor, the threshold voltage V_{TH} of the transistor can be shifted almost linearly over a wide range.

FIG. 296 shows a first embodiment of a device for electronic control of a μ-LED, in particular a pixel or subpixel for a display. The μ-LED can be manufactured using the various technologies shown. These include monolithic production, but also the arrangement in bar form, with current constriction or with the antenna structure disclosed in here. Decoupling structures can be provided to direct the light.

The μ-LED is connected in series with a dual-gate transistor between a first potential GND and a second potential Vdd. The arrangement comprises a threshold line PWM, which is connected to the first control gate or the back-gate BG of the dual-gate transistor T2. This has an additional control electrode. This backgate BG with a rear contact is shown in FIG. 295A and FIG. 295B. As shown in FIG. 295C, the threshold voltage can be shifted significantly via the back contact, i.e. the output current can be modulated by means of the additional gate BG while the voltage U_{GS} between gate G and source S remains constant. In principle, Gate G and Backgate BG can also be used in reverse. This means that the current setting can be carried out by means of the first control terminal BG and the pulse width modulation by means of the second gate G. By means of the wide dynamic range provided by the circuit, the threshold voltage can be shifted into ranges that lead to a safe switch-off of the second transistor T2.

This enables pulse width modulation (PWM) operation.

Another advantage is the speed of the proposed circuit using the dual-gate transistor T2. A fast switching can be carried out. Since, in contrast to modulation via the “Data” line, no memory capacity is used, modulation can be performed much faster with the same driver performance.

Furthermore, the device comprises a data signal line data and a selection signal line sel. Finally, the device also contains a selection hold circuit with a charge storage Cs and a control transistor T1. The charge accumulator is arranged between a second control gate G of the dual-gate transistor T2 and a connection of the μ-LED. The control terminal of the control transistor T1 is connected to selection signal line Sel. During operation, a date “data” is impressed on the data signal line via the selection signal line on gate G of the dual-gate transistor T2. The voltage U_{GS} is stored in capacitor Cs and is still present even after switching off selection transistor T1. The voltage is given by the data signal, whereby addressing is done by means of the selection signal Sel.

Gate G thus creates a fixed channel and thus a constant current through the current path. In this way a constant current source is provided by transistor T2, which is additionally pulse width modulated by a PWM signal at the back gate of transistor T2. The μ-LED thus switches by the PWM signal between a current given by the date in the charge storage and the state “off”. Since the μ-LED in some embodiments comprises a slight dependency of the color by the impressed current, the color can be impressed to a small extent by the data signal and the intensity by the PWM signal. If the color dependence is low, the intensity can be adjusted via the date even with a fixed PWM.

FIG. 296 shows a pulse width modulation of an adjustable constant current source with an NMOS TFT (Thin Film) transistor T2 without GND-based programming. However, this version is not temperature stabilized. The temperature instability results from the fact that the voltage across the charge storage Cs varies slightly due to the temperature dependence of the voltage drop across the LED.

FIG. 297 shows a second embodiment of a device for electronic control of a μ-LED pixel cell, provided in NMOS technology. Similar to the previous design, the current path includes a μ-LED and a dual-gate transistor T2 connected in series between the first potential terminal GND and the second terminal Vdd. The charge memory Cs of the selection signal holding circuit comprises one terminal connected to the gate G of transistor T2 and its other terminal connected between source S and first potential GND. As a result, the voltage across the charge accumulator Cs remains constant and is no longer dependent on the forward voltage of the light emitting diodes and thus no longer so dependent on temperature. The selection signal holding circuit is programmed via GND.

On the other side the μ-LED is connected between the drain connection D and the supply potential Vdd. Thus, the μ-LED is located on the side of the second potential connection Vdd, which provides the electrically higher potential. The arrangement is similar to FIG. 296, but the μ-LED is not located on the low side, i.e. not with the cathode connected to GND (ground), but on the high side or upper side of transistor T2. Thus, the cathode of the micro light emitting diode is connected to the drain of transistor T2 and its anode to the second potential connection Vdd. Correspondingly, the μ-LED shows, for example, a common anode topology instead of a previous “common cathode”.

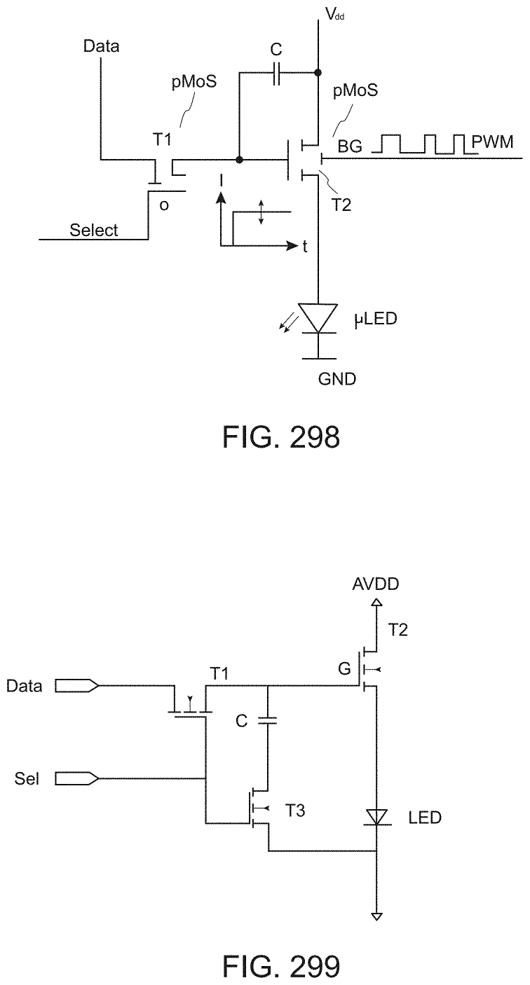

FIG. 298 shows a third embodiment of a device, an embodiment shown in FIG. 296, but now implemented using PMOS thin-film transistors instead of NMOS thin-film transistors (TFT). Only PMOS transistors are used. In this embodiment, the charge memory is connected between the source of the dual-gate transistor T2 and the first potential Vdd.

The embodiments shown in FIGS. 296 to 298 allow classic control in a pixel matrix. The “front gate” (normal) gate G of transistor T2 is described with a voltage value Data, the holding capacitor Cs stores this voltage value and controls the second transistor T2 accordingly. This is used, for example, to set a color mixture in an RGB pixel. A pulse width modulation (PWM) voltage is now applied to the second transistor T2 via the backgate BG. This voltage modulates the micro light emitting diode current in time via pulse width modulation (PWM) and is used, for example, to change the general brightness of a pixel with a previously programmed color. The color is programmed in advance via the first transistor T1 and the capacitor Cs. The same pulse width modulation signal can also be applied to all transistors of a display line, for example, to the respective backgate. Thus, a whole line is “dimmed”.

It is also possible that all back gates of a complete display, i.e. all columns and all rows, are driven by a common pulse width modulation signal PWM, so that the complete display is “dimmed” without changing its picture content. This can be used, for example, for a day-night mode for a display in a car or for glasses on Augment Reality applications. In this way, the brightness can be adjusted dynamically and continuously to an external brightness. In the automotive sector, parts of a display may also be individually controllable in this way, allowing dark areas to be brightened and lighter areas to be darkened.

FIG. 299 shows a third embodiment of a device, namely a further design of a control device. In addition to the representation and device shown in FIG. 296, a third transistor T3 is connected in parallel to the μ-LED, the control terminal of the third transistor T3 being connected to the selection signal line Sel. The transistor T2 as constant current source is here designed with only one gate. By means of such an arrangement, programming can be performed independently of the anode potential of the μ-LED. The device shown here results from a combination of NMOS-based IGZO processes and the requirement of a common cathode from process technology with regard to an assembly of μ-LEDs. On this basis an implementation of a 2T1C (two transistors and one capacitance) current source is possible.

If a high potential Vdd is applied to the selection signal line Sel, the first transistor T1 is connected to the data signal line Vdata, in addition the third transistor T3 becomes conductive, bridging the LED and connecting capacitor C to reference potential (GND). In this way, the capacitor is programmed with the voltage Vdata, referenced to the reference potential GND of the lower, first potential connection and not to the anode potential of the μ-LED. If the potential of the selection signal line Sel is at the reference potential (GND), the first transistor T1 and the third transistor T3 are blocked, so that the capacitor C maintains its previously programmed voltage, which corresponds to the gate-source voltage U_{GS} of the second transistor T2. If the anode potential shifts, the separation of Vdata also shifts the gate potential to the second transistor T2, so that the gate-source voltage U_{GS} of transistor T2 remains constant. In this way, the second transistor T2 can operate as a current source.

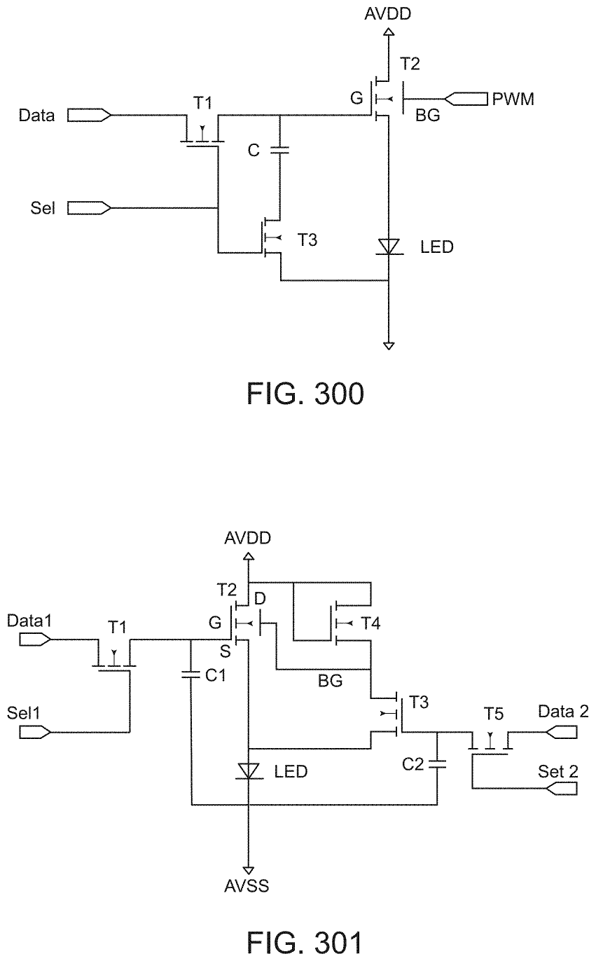

FIG. 300 shows a fourth example of a device, in the form of a subpixel cell. FIG. 300 shows an arrangement as shown in FIG. 299 with the difference that the second transistor T2 here is designed as a dual-gate transistor whose additional gate terminal BG is connected to a threshold line PWM for applying pulse width modulation. The front gate G is connected to the charge storage C, the back gate BG is fed with the pulse width modulated signal.

The transistors T1 to T3 in combination with the holding capacitor C1 form a 3T1C cell in NMOS configuration. The 2T1C cell consisting of transistor T1 and transistor T2 can also be designed as a PMOS configuration. In this case, for example, the third transistor T3 is not required. Transistor T2 is configured as a so-called “dual-gate transistor”.

FIG. 301 shows an illustration of an example of a device with additional temperature stabilization. The transistors T1 and T2 in combination with the holding capacitor C1 provide a 2T1C cell in NMOS configuration. The LED is placed on the low side of transistor T2, since a “common cathode” is provided for process-related reasons. The T2 is designed as a “dual-gate transistor” and thus comprises two control electrodes. Similar to some previous examples, the gate (corresponding to the bottom gate in FIG. 295A) of the dual-gate transistor T2 is also part of the topology of the 2T1C cell in this embodiment and provides the color and general brightness of the μ-LED via the ground-related programming of the charge storage C1 and the signal on line Data1. Via the backgate BG (front gate of FIG. 295) a PWM signal can be applied to transistor T2, which acts as a current source.

The gate-source voltage of transistor T2 is thus dependent on the forward voltage of the LED. Since the voltage drop across the LED depends on both the cross-current and the temperature, the output current is considerably different from the actual expected value of the programming. This can be described by the following equation 2:

I_{LED}=K(Udata−U_{LED}(T,I)−Uth)² (2)

Here U_{data} is the voltage across the charge storage C1. When the μ-LED heats up by itself, its forward voltage decreases, which leads to an increase of the current through transistor T2. Due to the absence of negative feedback, a change in the operating parameters of the μ-LED therefore has a significant effect on the current and thus on the brightness or color of the μ-LED.

Therefore a negative feedback is proposed, which exploits the functionality of transistor T2 as a dual-gate transistor and allows compensation of such effects. The negative feedback comprises a holding capacitor C2, which is connected between the reference potential AVSS and a control terminal of a transistor T3. The first terminal of this capacitor forms the control for the backgate BG of the dual-gate transistor T2 and the other terminal is connected to the source S of the dual-gate transistor T2. The negative feedback comprises a further transistor T4, whose control and drain terminals are connected to the supply potential AVDD. Its source terminal is connected to the backgate BG and the drain of transistor T3. Finally, a fifth transistor T5 is provided for optional programming of a compensation, which stores a compensation value on line Data 2 in the holding capacitor C2 on the basis of a selection signal Set2.

The gate-source voltage of transistor T3 corresponds to the voltage of holding capacitor C2 minus the forward voltage of the LED. If this forward voltage Vf_LED increases, the gate-source voltage U_{GS} of the third transistor T3 decreases, since the stored charge on the capacitor C2 remains the same. Thus, the current through the third transistor T3 decreases. Since this current also flows through transistor T4, the coupling of its gate to the supply potential results in a smaller voltage drop U_{DS} via the fourth transistor T4. This results in a higher voltage at the node to the back gate of transistor T2. This in turn results in a lower threshold voltage at transistor T2. By means of an appropriate design of the transistors T3 and T4 according to the following equation 3

$$β = - \sqrt{\frac{{W}_{4} \cdot {L}_{3}}{{W}_{3} \cdot {L}_{4}}} whereat \\ {U}_{th} \cdot {I}_{T 2} = {U}_{th} {U}_{th} \cdot {I}_{Nom} \cdot + β \cdot {U}_{BG - S} \cdot - S \qquad ( 3 )$$

an almost complete compensation of the described feedback effect of the forward voltage of the LEDs can be achieved. Typical values for β=−0.52 this results in W₃=3.69·W₄·with L₃=L₃=Lₘᵢₙ.

The fifth transistor T5 and the capacitance C2 can be used to fine-tune the pixel cell Data2 including the feedback. As shown in FIG. 301, a significant improvement of the current stability is achieved without complex pre-calculation. The compensation of the current instability is achieved with few components and without complex precalculation of the “Data” signal. This allows temperature fluctuations during operation to be compensated. Furthermore, a reduction of the quiescent current caused by the third transistor T3 can be achieved by the additional control input Data2 via Sel2.

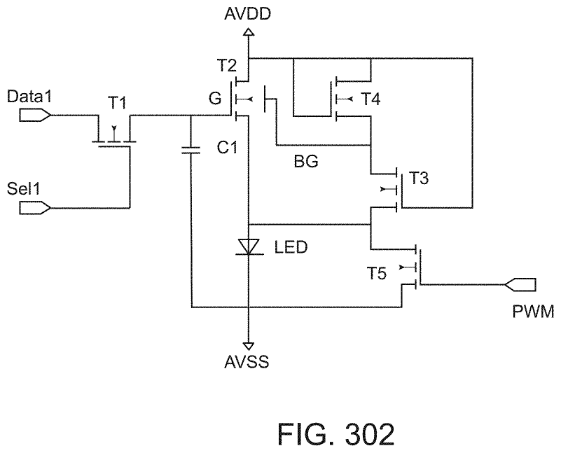

FIG. 302 shows a fifth embodiment of a μ-LED control device. As in the previous examples, the μ-LED can be part of a display or a module. In addition to the design as shown in FIG. 296, further changes have been made to the temperature compensation and influence of the forward voltage through the μ-LED.

The embodiment comprises a third electronic switch T3 with a first power line contact connected to the second terminal of the μ-LED, and a second power line contact of the third electronic switch T3 connected to the first control terminal BG of the second electronic switch T2. The device also includes a fourth electronic switch T4. A control terminal of the third electronic switch T3 is connected to a second power line contact of the fourth electronic switch T4, which are connected in common to the supply potential AVDD. A control terminal of the fourth electronic switch T4 is also connected to the supply potential AVDD. Finally, the fourth electronic switch T4 has its first power line contact connected to the second power line contact of the third electronic switch T3.

A fifth electronic switch T5 is provided to control the second electronic switch T2 via the first control connection BG. This is connected in parallel to the μ-LED. It is also connected by its second power line contact to the first power line contact of the third electronic switch T3. The control terminal of the fifth electronic switch T5 is electrically connected to a terminal for supplying a pulse width modulation signal PWM.

The behaviour and function of the device shown in FIG. 302 is similar to the device shown in FIG. 301, but unlike FIG. 301, the gate of the third transistor T3 is electrically connected to a fixed electrical potential Vdd. As an option, an additional fifth transistor T5 can be provided for safe switching off the LED without a cross current from the third transistor T3. A fifth transistor T5 is not necessary if a cross current from the third transistor T3 into the μ-LED is not a problem. According to the device presented here, the pulse width modulation PWM is controlled without a holding capacitor. In this way, a possible pulse width modulation resolution can be increased with the same cycle time. Likewise a recharging of a storage capacitor is not necessary, which increases the switching speed.

A further aspect concerns in the following a control for a brightness adjustment or a dimming of pixels, or of the assigned μ-LEDs. Such dimming is not only frequently used in the automotive sector, for example to switch between day and night vision, but also in AR applications. Basically, such dimming can be useful and advantageous when contrasts have to be adjusted or when external light makes it necessary to control the brightness of a display in order to avoid dazzling a user or to show information reliably.

Conventionally, this problem can be addressed with PWM control and current dimming, but external parameters of the LED often change, which requires complex compensation circuits. Alternatively, so-called 2T1C circuits can be used, to which the control signal for driver control is fed and stored in a capacitor. The brightness is then adjusted by the voltage applied to the capacitor. The invention now makes use of an aspect, which often occurs rather as a parasitic undesired effect, namely the gate-source capacitance of the driver transistor. This forms a capacitive voltage divider with the capacitance of the capacitor, so that the voltage at the gate of the transistor drops. If the gate-source capacitance is selected appropriately, the brightness can be adjusted over a wider range.

In one aspect, a control circuit for adjusting a brightness of at least one μ-LED comprises a current driver element with a control terminal. This is connected in series with the μ-LED and has its first terminal connected to a first potential. A charge accumulator is arranged between the control terminal and the first potential and forms a capacitive voltage divider with a defined capacity between the control terminal and the first terminal.

According to the invention, a control element is now provided which provides a control signal to the control terminal during an initial period of time, on the basis of which a current flowing through the at least one μ-LED can be adjusted during the initial, first period of time. During a second time period following the first time period, the current flowing through the μ-LED is now determined by a reduced control signal resulting from the control signal during the first time period and the capacitive voltage divider.

Thus, when the control signal is selected by the control element, the brightness of the μ-LED can be adjusted so that it depends either substantially on the current during the first time period or the current through the LED during the subsequent second time period.

In other words, the control signal determines the total current through the μ-LED during the first and second time periods and, if the control signal is appropriately selected, depends substantially on the current flowing through the μ-LED during the first time period or on the current flowing through the μ-LED during the second time period.

Thus the control element is set up to provide a first or a second control signal during the first time period in order to operate the μ-LED at at least two different brightness levels during the entire time period. For this purpose, for example, the second control signal is larger than the first control signal, so that the reduced control signal derived from the second control signal is sufficient to drive the current driver and thus provide a current sufficient to operate the μ-LED.

As mentioned, the current driver element may include a field effect transistor whose gate forms the control terminal and has a gate-source capacitance specified by design. Accordingly, during the second time period, the reduced control signal applied to the control terminal of the transistor or current driver results from the control signal during the first time period and the ratio of a charge storage capacity and the sum of the charge storage capacity and the defined capacity.

Such a circuit is operated at a certain frequency, so that first and second time periods follow each other periodically. This frequency can be 60 Hz, often also 100 Hz or 120 Hz, or can be in the range of 60 Hz to 150 Hz. In one aspect, the control element is configured to make a ratio of the second time span to the first time span adjustable, whereby the ratio can be in the range from 300:1 to 100:1, in particular in the range from 100:1. For this purpose, the control element comprises a control transistor at whose control terminal the first and second time span and thus the duty cycle can be set by means of a signal.

A brightness level can now be selected by means of various control signals during the first time period of a period. For this purpose, it is provided in one aspect to operate the μ-LED at a first, darker brightness level if a voltage of the first control signal is within a first voltage interval, and to operate the μ-LED at at least a second, brighter brightness level if a voltage of the second voltage signal is within a second voltage interval which is at least partly above the first voltage interval.

In this context, the brightness is determined by the current flowing through the μ-LED during the whole time period. With a control signal that lies within the first voltage interval, the total current is essentially determined by the current during the first time period, since due to the capacitive voltage divider and the associated drop in a voltage of the reduced control signal during the second time period, the current through the LED during this time period is very small and not sufficient or relevant for operation. The current driver is not or only very slightly driven during this time period, the LED is hardly or not at all lit.

In contrast, the total current over a period is substantially determined by the current during the second period if the control signal during the first period is within the second voltage interval. In this case, despite the capacitive voltage divider and the associated drop in a voltage of the reduced control signal during the second time interval, the current driver is still sufficiently driven so that a sufficiently high current flows through the μ-LED to operate it. Typical possible values for the first voltage interval range from 1.3 V to 4.5 V. The second voltage interval ranges from 4.0 V to 10.0 V.

A further aspect concerns a method for adjusting a brightness of at least one μ-LED connected to a current driver element with a control terminal, the first terminal of which is connected to a first potential and in which a capacitor is connected between the control terminal and the first potential so that it forms a capacitive voltage divider with a defined capacitance between the control terminal and the first terminal. In the method, a control signal is applied to the control terminal during a first time period, whereby a current flowing through the at least one μ-LED is adjusted during the first time period. During the second period following the first period, the control signal is turned off, whereby the current flowing through the μ-LED is set by a reduced control signal resulting from the control signal during the first period and the capacitive voltage divider. “Switching off the control signal” here means disconnecting the control signal from the control terminal so that only a reduced signal acts on the control terminal thereafter, resulting from the control signal during the first time period and the capacitive voltage divider.

This reduced control signal is thus smaller than the control signal by the ratio of the capacitive voltage divider. Specifically, in one aspect, the reduced signal applied to the control terminal during the second time period results from the control signal during the first time period from the ratio of a capacity of the capacitor and the sum of the capacity of the capacitor and the defined capacity.

At this point a further aspect should be mentioned, namely that a ratio of the second time period to the first time period is in the range of 300:1 to 100:1, in particular in the range of 100:1. In another aspect, it is proposed to operate the μ-LED at a first, darker brightness level if a voltage of the first control signal is within a first voltage interval, and to operate the μ-LED at at least a second, brighter brightness level if a voltage of second voltage signal is within a second voltage interval that is at least partially above the first voltage interval.

In this context, the proposed method determines the brightness by the current flowing through the μ-LED during the entire time period. For a control signal that is within the first voltage interval, the total current is essentially determined by the current during the first time period, since due to the capacitive voltage divider and the associated drop in voltage during the second time period, the current through the LED during this time period is very small. The current driver is not or only very slightly driven during this time period.

On the other hand, the total current is essentially determined by the current during the second time period if the control signal during the first time period is within the second voltage interval. In this case, despite the capacitive voltage divider and the associated drop in a voltage of the control signal during the second time interval, the current driver is still sufficiently driven so that a sufficiently high current flows through the μ-LED to operate it. Typical possible values for the first voltage interval range from 1.3 V to 4.5 V. The second voltage interval ranges from 4.0 V to 10.0 V.

The first or second control signal required for control can be obtained from a digital control word by digital/analogueue conversion. The digital control word comprises a number of n bits for this purpose. The least significant m bits (M<n, e.g. m=n−2 bits) correspond to the first control signal, i.e. the most significant bits are 0. In other words, n bits correspond to the second control signal. In another aspect, the most significant bits are used for coarse brightness adjustment, the least significant bits for more precise range adjustment.

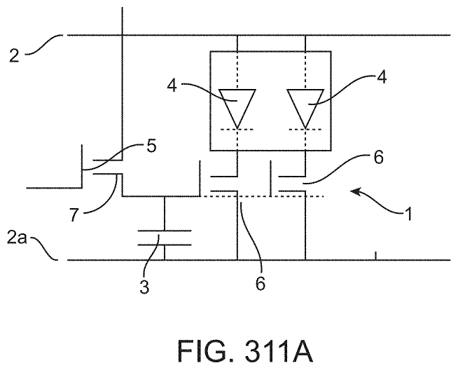

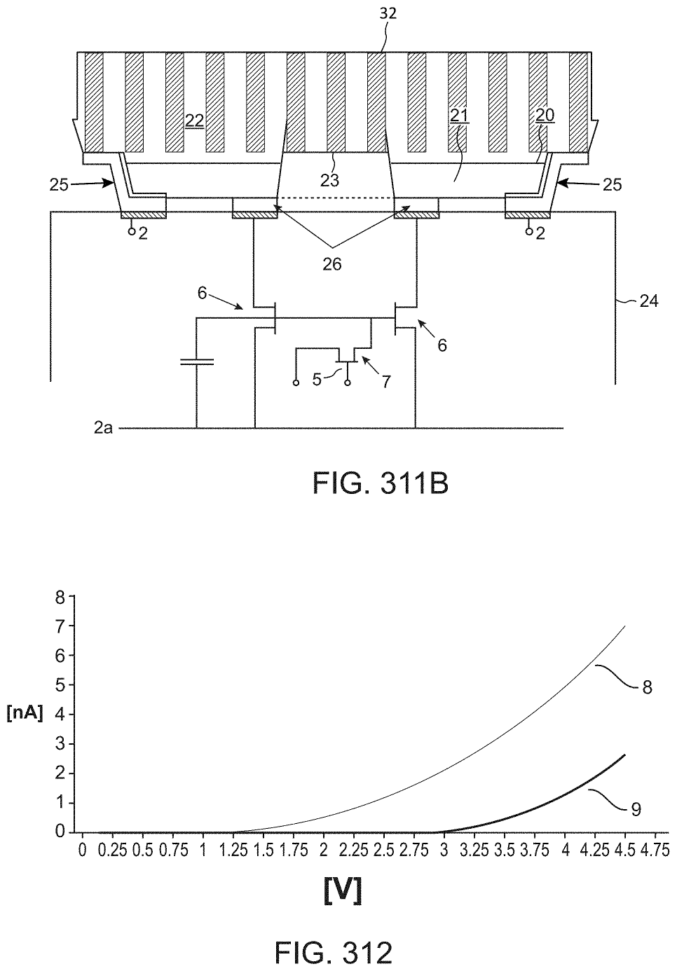

FIG. 311A shows a control circuit for a lighting unit 1, which comprises two μ-LEDs 4 as illuminates. From the basic design, the control circuit can be implemented in a 2T1C architecture as shown here. However, other architectures are also conceivable.

Even if two μ-LEDs 4 are provided according to the shown design form in order to ensure redundancy with respect to light generation, it is generally irrelevant for the realization of the invention whether one μ-LED 4 or a plurality of μ-LEDs 4 are used as illuminates. For example, the light unit 1 or the μ-LEDs 4 can be a light unit or LEDs of one color of one pixel.

In the embodiment shown in FIG. 311A, the two μ-LEDs 4 connected in parallel are each supplied with the electrical energy required to excite a light emission via a current driving transistor 6. In addition to one transistor 6 for each μ-LED, a common current source can also be provided for both μ-LEDs 4. Current driving transistor 6 is connected in series with μ-LED 4 between supply potential terminal 2 and reference potential terminal 2a. Supply potential connection 2 provides the electrical energy or voltage required for the operation of lighting unit 1.

A capacitor, which stores the brightness value, is connected between the gate of the current-driving transistors 6 and the reference potential connection 2a. Together with the control transistor 7 it forms a 2T1C cell. A pulse signal is applied to its gate, which applies a control signal 8 from the other terminal of transistor 7 to the control terminal of current driving transistor 6.

For operation according to the proposed concept in a circuit according to FIG. 311A, a pulse signal is now applied to the gate of transistor 7. For example, the duty cycle On/Off can be 200:1, i.e. at a repetition frequency of 60 Hz the ON pulse duration is approx. 50 μs while the Off pulse duration is approx. 16.6 ms.

Within a period, the control transistor is now closed via the pulse signal for a first period (ON pulse duration), and the control transistor is opened again in a second period (OFF pulse duration). During the first period, the control signal 8 is thus applied to the control terminal of the current driver transistor 6 and via the capacitor 3. The control signal controls the current driver transistor 6 and a current caused by the control signal 8 flows through the μ-LED. At the same time, a charge is applied to the capacitor until the voltage of the control signal is established across the capacitor (referred to the potential at terminal 2a).

After the first time period, control transistor 7 is opened again. The voltage of control signal 8 is now stored in the capacitor and should continue to drive the current driver transistor. In practice, however, this is not the case, since in the second time period, a capacitive voltage divider is formed, which consists of the capacitance of the storage capacitor 3 and the capacitance formed by the gate and source of transistor 7. This regularly causes the effective voltage 9 on capacitor 3 to be lowered by a discrete value. The reduced effective voltage 9 results from the voltage of the control signal multiplied by C1/C1+Cp, where C1 is the capacitor capacitance and Cp is the gate-source capacitance. Thus, compared to the first time period, a slightly smaller control signal 9 (or slightly lower voltage) is applied to the driver transistor 6, so that a current of lower intensity flows through the μ-LEDs 4. The brightness of LEDs 4 thus decreases slightly during the second period of a period. However, this is not noticed by an observer, since only the average light output available in relation to the period is decisive for the perception of brightness.

Thus, for an entire period, control signal 8 is applied to the control terminal during the first period and the reduced control signal 9 during the second period. At a frequency of 60 Hz, this would be 0.05 ms to 0.06 ms for the first time period and approximately 16.6 ms for the second time period. In terms of the average light output of the μ-LED, this means that light emitted by the μ-LED during the second time period has a comparatively high proportion of the average light output of the μ-LED during one period.

This is equivalent to the average current through the μ-LED. The current flowing through the μ-LED during the second period has a relatively high share of the average current during the whole period.

It follows from this that if a low voltage is selected for control signal 8, the total current flowing through the LEDs 4 during one period, and thus the average light output, is determined decisively by the strength of the current flowing through the LEDs 4, while control signal 8 is applied during the first period. If a low voltage value is selected for control signal 8, lighting unit 1 can therefore be operated at a low brightness level and dimmed as required within this low brightness range.

If, on the other hand, a high voltage is selected for the first voltage signal 8, for example 8V, the total current flowing through the LED during one period is largely determined by the current during the second period of the period in which the reduced control signal 9 is applied to the current driver transistor 6. If a high control signal 8 is selected, i.e. a higher voltage, the lighting unit 1 is operated at a high brightness level and can be dimmed as required at this brightness level. During the second period of the period in which the reduced control signal 9 is applied to the lighting unit, a current greater than 1 μA still flows through the LED in this operating state, so that particularly effective operation of LEDs 4 is possible.

FIG. 311B is a supplement to this embodiment where the proposed circuit is implemented in a backplane substrate. Contact areas are provided on the backplane substrate to which a μ-LED module is attached. This comprises two μ-LED base modules as disclosed in this application, for example in FIG. 184. The two contacts 26 are each connected to a current driver transistor 6. The two outer contacts 25 of the μ-LED Module are connected to the ground or reference potential connection. The current driver transistor is adequately dimensioned. In some aspects this may be the dual-gate transistor disclosed here, as described in FIGS. 295 to 302.

Furthermore, a photonic crystal 32 is incorporated in the μ-LED module. This extends to just above the active layer 20 and changes the emission properties there, for example in the area above the active layer, where it can have an emission-promoting effect.

FIG. 312 shows a graph showing the strength of the current flowing through the LEDs 4 as a function of the voltage of control signal 8 and the reduced control signal 9. It can be clearly seen that when a control signal 8 with a voltage value of about 1V to 3V is applied during the first time period, the current flowing through the μ-LEDs 4 is largely determined by the first voltage signal 8 applied during the first period. Meanwhile, in the second time period, the control signal 9, which is reduced by the capacitive voltage divider, and thus the current flowing through the μ-LEDs 4 is almost zero.

Only from a voltage of the control signal of about 3.0 V during the first time period does the voltage of the reduced control signal 9 increase and thus also the strength of the current flowing through the μ-LEDs 4 during the second phase.

It must be taken into account in each case that due to the different length of the two phases of a period, namely a short first phase in which the control signal 8 is applied to the lighting unit 1, and a long second phase in which the reduced control signal 9 is applied to the current driver transistor 6, the influence of the second time period on the average light output of the μ-LEDs 4 is significantly greater. As a result, the total current through the μ-LED increases significantly during a period when the voltages of control signal 8 exceed 3.0 V. It follows from this that in the case of a control signal with a comparatively high voltage greater than 3.0 V or 3.5 V, the proportion of the total current flowing through the μ-LEDs 4 during one period is determined to a large extent by the proportion of the current during the second time period.

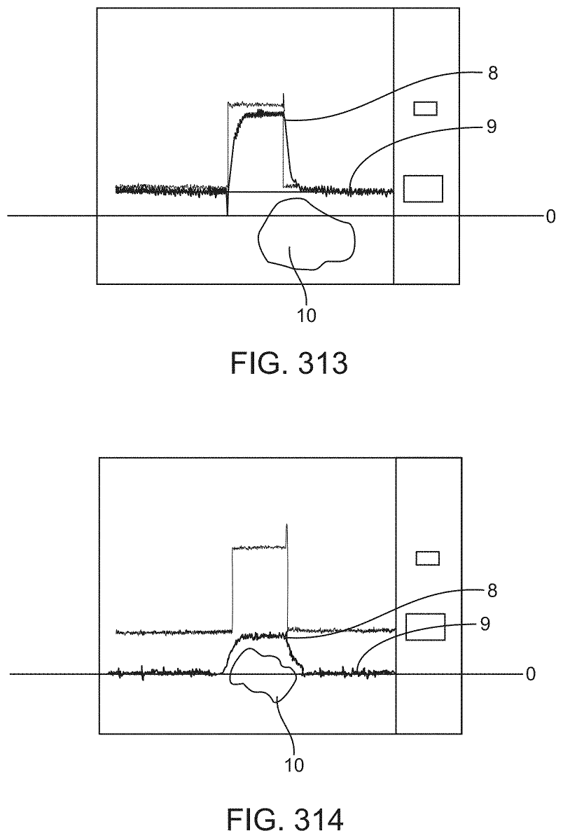

In addition, FIG. 313 shows a schematic representation of the time course of the control signals 8, 9 and the resulting light spot 10 when a control signal 8 is applied with a comparatively high voltage. The control signal 8, which is transmitted to the lighting unit, has a voltage of 10 V in the embodiment shown. Otherwise, the voltage of the reduced control signal 9, which is applied to the lighting unit during the second phase, is reduced but still has a voltage that is significantly higher than 0 V. Due to such a voltage curve of the control signals 8, 9, a bright light spot 10 is formed, the lighting unit is thus operated at a high brightness level.

FIG. 314 illustrates an operating condition in which a control signal 8 is applied to the lighting unit at a comparatively low voltage, in this case 2.0 V. The reduced control signal 9 in this case has a voltage of at least almost 0 V. The brightness of the light spot 10, which is determined by the average light output of the lighting unit 10 during a period, is significantly lower than in the operating state shown in FIG. 313. The lighting unit and the LEDs used for it are thus operated at a comparatively low brightness level at which they can be dimmed as required.

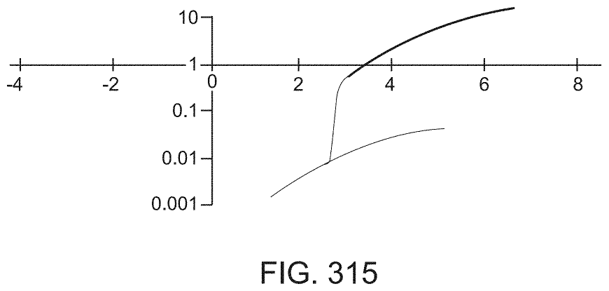

Finally, FIG. 315 shows in a graphical representation how the electrical energy conducted through the LEDs during a period, sometimes referred to as the amount of current, behaves in relation to the voltage signals applied to a lighting unit during the first and second periods of a period. The x-axis is the voltage during the first period, the y-axis the current during a period.

It can be seen that when a control signal with a comparatively low voltage is applied, especially a voltage of up to about 3V, the total current flowing through the LEDs is caused by this control signal. Only when control signals with voltages higher than 3V are applied does the voltage of the reduced control signal also increase. Above all, in this operating state, a current flows through the μ-LEDs of the lighting unit which, due to the length of the second time period, has a considerable influence on the amount of the total current flowing through the LEDs during the period and thus on the average light output or brightness of a lighting unit with at least one μ-LED.

Furthermore, FIG. 315 shows that a lighting unit controlled in this way can be operated at two different brightness levels depending on the voltage selected for the control signal. At the two brightness levels it is in turn possible to continuously vary the brightness of the lighting unit within a dimming range limited by a lower and an upper voltage value for the control signal. The course of the two characteristic curves shown in FIG. 315 can be adapted to suit requirements with the aid of a suitable circuit design, in particular by specifically defining the capacitance of the capacitor and the gate-source capacitance of the transistor used as the switching element. It is also conceivable to determine the voltage levels, the control signal and the reduced control signal by suitable selection and dimensioning of the electronic components used.

As the embodiments explained show, the control circuitry designed in accordance with the invention enables the operation of a lighting unit, which has at least one μLED, on at least two brightness levels in a comparatively simple manner. The main consideration here is that, depending on the level of the voltage of the control signal, either the current flowing through the LED during the first time period or the second time period of a period is decisive for the total current flowing through the LED as well as for the average light output and the brightness of the μ-LED perceptible by an observer.

Another aspect deals with the question of how a retroactive effect on the control of a current source can be reduced when PWM control is used. In pulse width modulation, the current source is switched on and off in rapid succession for contrast and brightness adjustment. The frequency is several 100 kHz up to the MHz range. With control loops within the current source, the switching operations lead to spikes or other behaviour, which can bring the control loop out of its control range.

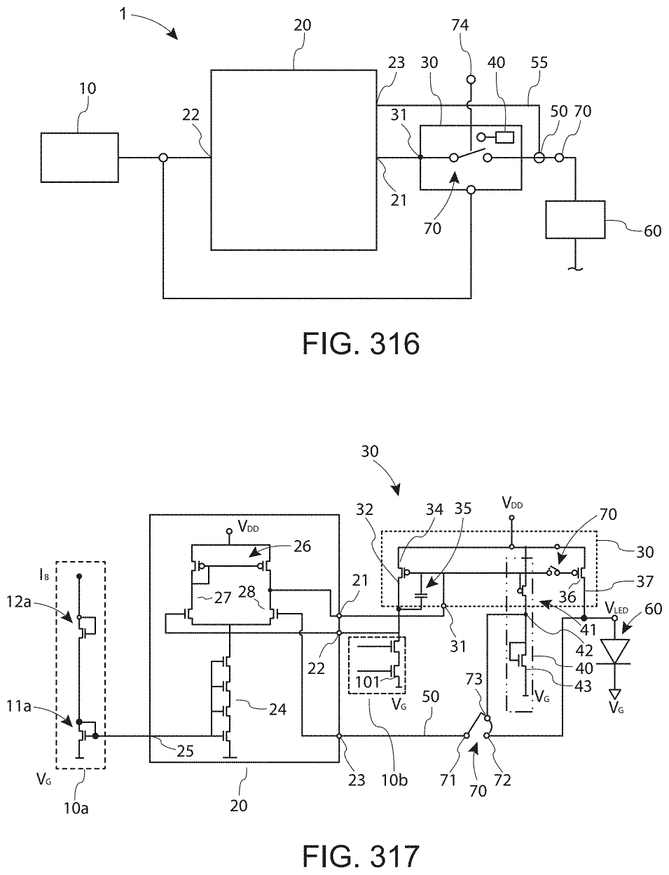

FIG. 316 shows a schematic block diagram for a regulated current source for μ-LEDs, which remains stable even during switching operations. This current source can be used in μ-displays or other display devices and is suitable for automotive and augmented reality applications.

The supply circuit includes a reference branch 10, which provides a reference signal and in particular a reference current or, if necessary, a reference voltage. In the following, all further supply currents and, if necessary, also voltages are derived from the reference signal. Further reference signals can also be generated from this signal. The reference signal, i.e. the reference current is characterized by a high temperature stability but also a stability against process fluctuations during production. If necessary, it can include one or more correction circuits, which together provide an accurate and stable reference signal, for example a reference current.

In the present case, reference branch 10 is connected to a reference input 22 of an error correction detector 20 as well as to a controllable supply source 30. In addition to the reference input, the error correction detector 20 also comprises an error signal input 23 and a correction signal output 21. The detector 20 is designed to compare an error signal at input 23 with a reference signal at input 22 or a signal derived therefrom and to generate a correction signal at its output 21.

The controllable supply source 30 has a controllable current source, which is not shown separately in this block diagram. In addition, the supply source includes a second backup source 40, which provides a feedback signal to the error detector in one operating state of the circuit. A switch device 70 is provided for this purpose, which, depending on the operating state, i.e. an operating signal at input 74, either switches the current source to the load or disconnects it from the load and switches on the substitute source 40. In this way, either a signal from the current source to the consumer or the signal from the replacement source is detected at detector 50.

A current-voltage converter or a voltage drop detector can be used for detection. A voltage or a voltage drop or a current can be detected with detector 50. The detected signal is then fed back to the error correction detector 20 and compared with the reference signal or a signal derived from it. The resulting error correction signal is used to adapt the controllable current source. If load 60 is now supplied by current source 30, error correction detector 20 adjusts the current through the load to a value defined by the reference signal. With a μ-LED, the current flowing through the diode can thus be precisely adjusted. If the voltage drop across the load or the current through the load changes due to temperature effects, the error correction detector readjusts the current accordingly. This part of the circuit and its operation corresponds to a control loop.

If the load were now disconnected from the current, for example if the LED is switched off in the case of PWM modulation, the control loop would first attempt to readjust, but then run out of the control range. For this reason, the invention provides for a substitute signal to be supplied to the error correction detector 20. This signal is essentially the same or at least very similar to the nominal signal when the load is switched on. Thus, the error correction detector 20 is operated in its optimum range regardless of the operating state of the load and the control loop is not moved out of its control range. This results in very fast control and prevents detector 20 from falling outside its control range.

The proposed supply circuit thus includes a correction circuit as part of a control loop for high-precision control of a current or voltage source as well as a substitute source. The correction circuit is now fed either a signal derived from the current or voltage source or the signal of the substitute source. The supply of the latter enables the current source to be switched off without the control loop running out of its control range.

FIG. 317 shows a specific embodiment for driving a power source for a supply of a Light Emitting Diode 60, which is part of a pixel matrix not shown here, for example a display, video wall or other application requiring a high-precision power supply. In the case of light-emitting diodes, a current through the diode also changes with changing temperatures, which can lead to a change in brightness as well as a change in color temperature. This effect is compensated by regulating the current source. Displays, pixel matrices for picture or video applications are often operated with pulse width modulation, in which the light emitting diodes are switched on and off at high frequencies. The ratio between the two states gives the brightness of the respective light emitting diode.

The power supply circuit shown in the following is essentially designed in MOS circuit technology. Some field effect transistors are of the n-type, others of the μ-type as shown. In this case the supply circuit is connected between supply potential VDD and consumer. By exchanging the channel types of the field effect transistors and an arrangement between consumer and reference or ground potential VG an alternative embodiment is created. It is also possible to replace individual transistors with bipolar transistors, or to form assemblies such as current mirrors with them. Bandgap references can be used to generate precise voltages, which then provide a current via a converter.

Supply circuit comprises a combined reference branch 10 consisting of two parts 10a and 10b, which provide a reference current. They form part of a current mirror. The reference branch 10a for a first reference current comprises two transistors connected in series, an n-field effect transistor 12a and a μ-field effect transistor 11a. The former is connected to a supply terminal, the latter to the reference potential. The gate of the transistor 12a is connected to the drain terminal and thus impresses a constant current. Transistor 11a reflects the current through the reference branch into the four series-connected transistors 24, which form the fixed current source for a differential amplifier. The differential amplifier forms a component of the error correction detector 20 and contains, in addition to the current source from the transistors 24, an inverting and a non-inverting input transistor in each branch, which is connected to the supply potential VDD via a further current mirror 26 consisting of two p transistors. The non-inverting input transistor 27 forms the reference signal input 22, the inverting transistor 28 leads to the error signal input 21. The two transistors comprise the same dimensions as the transistors of mirror 26 in this embodiment. However, different amplification factors may be provided for in versions due to geometric dimensions such as channel width or length. This may be necessary if, as described below, there is also an inherent factor between the error signal and the reference signal. Such an inherent factor results from the design of the current source 30 and the signals (error signal and reference signal) tapped for the detector 20 as described below

The controllable current source 30 comprises a current mirror with an output branch and a reference branch, which simultaneously forms the replacement source 40. The reference source 10b is connected to a reference branch input 32. This input 32 is also connected to the non-inverting transistor 27 and to the reference signal input of the error correction detector 20. The reference branch of the current mirror is thus impressed with an exact current, whereby a defined voltage drop is fed through the central tap to input 22 of the error detector. The reference branch 10b comprises two series-connected transistors for adjusting the current flow through the reference branch of the current mirror of the current source 30 and for defining the reference voltage or reference signal at input 22. The gate of transistor 101 is connected to the gate of transistor 11a (but not drawn here) and is thus part of the current mirror of reference source 10. The controllable current source 30 comprises a supply input to which the supply potential VDD is applied and a μ-type current mirror transistor 34. A capacitor 35 is connected between gate and terminal 32, so that the voltage in the reference branch is coupled to the gate. This voltage also forms the reference signal for the error detector.

The reason for using a capacitor with positive feedback instead of the usual conduction for current mirrors is, among other things, due to an additional frequency compensation for the additional control signal terminal 31, which connects the gate of transistor 35 with the error correction output 21 of detector 20. The error correction signal is thus also fed to the gate.

The gate of the transistor is also connected to the gate of an output transistor 36 via a switching device 70. This is located between supply potential VDD and output. The current of the reference branch is thus mirrored into the output branch 37 of the current source. By dimensioning the two transistors 34 and 36 accordingly, the ratio of the output current to the current through the branch with transistor 34 can be adjusted accordingly. If, for example, the channel width of output transistor 36 is 10 times that of transistor 34, then the current is also increased by the same factor in simple approximation. In the illustration in FIG. 317, the output transistor 36 is a single transistor. However, it can also be designed as several transistors arranged in parallel.

The switching device 70 in the current source 30 is configured to connect, depending on a signal, the gate of the output transistor 36 either to a fixed potential, here the supply potential, or to the gate of the current mirror transistor 34. In the former case, the output transistor 36 is de-energized, since the potential VDD blocks the gate of the μ-type transistor. Since in this case the transistor does not conduct current, it is also referred to as transistor 36 is open. In the second case, the output transistor 36 is closed and the current through the current mirror transistor 34 is mirrored into the output with the above-mentioned factor and led to LED 60.

The output of the current source 30 is connected to the load 60 or the LED as well as to a second switching device 70, which applies either the voltage at the output of the current source to the error signal input of the error detector 20, or a substitute signal. This is provided by the substitute source 40, which is formed by a μ-type output transistor 41 and a transistor 43 connected in series. The series connection of the two transistors 41 and 43 is arranged between supply potential VDD and ground potential VG. A central node 42 forms the output for the substitute signal. The gate of transistor 43 is connected to its drain terminal and thus to node 42. The gate of μ-type output transistor 41 is connected to the gate of transistor 34. Thus, a current mirror is also formed from the transistors 34 and 41. However, a different factor is selected here by appropriately dimensioning the output transistor 41 so that the current through this branch is significantly lower than that through the output branch.

The two switching devices 70 operate essentially synchronously and are designed so that the output of the current source 30 is connected to the error signal input 23 of the detector 20 when the gate of transistor 36 is connected to the gate of transistor 34. If, on the other hand, the output transistor of the current mirror is de-energized, the substitute signal of the substitute source is present at the error signal input, i.e. tap 42 is connected to input 23.

In the version shown here, the spare source is always activated, i.e. the output transistor always forms a current mirror with transistor 34 and a current flows through the branch of the spare source. In an alternative version, a switch can also be provided here which works in the opposite direction to the switching device 70, i.e. it switches the replacement source currentless, for example, if a voltage is applied to the load or a current is provided by the current source 30.

In an operation of the supply circuit, the switching device 70 is now switched in such a way that node 71 is connected to node 72 and simultaneously the gates of the transistors 34 and 36 are connected to each other. The current source then provides an output current for the load. This leads via LED 60 to a voltage drop of a few volts, for example 2 to 3 volts. The voltage drop is detected as an error signal by the differential amplifier of detector 20 and compared with the reference signal. If the current through the LED now changes, for example due to a temperature change, the error signal also changes and the detector generates a correction signal for the current mirror at the correction signal output 21 and feeds this to the control signal connection 31.

The correction signal is now also applied to the gate of output transistor 36, so that the current is adjusted accordingly. The error detector 20 controls the output current mirror so that the saturation voltage of the inverting and non-inverting transistors 27 and 28 is equal. A load-independent current source is formed by means of the error correction detector 20 and the current mirror connected to the output.

Since light emitting diodes are often operated with pulse width modulation, the current through the diode changes in defined intervals, i.e. the diode is switched on or off at high frequency. The pulse width results in the brightness of the diode 60, which is achieved by the switching device 70 in the current mirror. However, if the current is switched off, the error detector 20 counteracts this for the first time. This can cause it to run regularly out of its optimum dynamic range. The same happens when the current is switched on. Here the differential amplifier needs some time to reach its normal control range. In addition, oscillations or overshooting can occur, which reduces the life of the diode, but can also be visible to a user. The second switching device 70 prevents this by keeping the error detector in its control range by means of the replacement source.

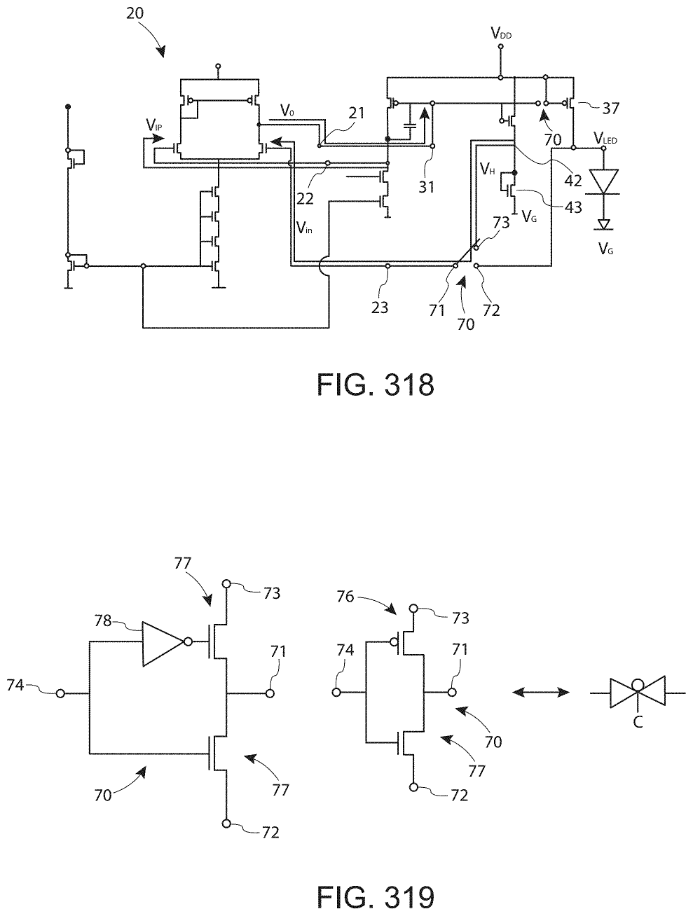

FIG. 318 shows a diagram with the main signal flows. With a switched-off diode, the gate of the μ-type field effect transistor 36 of the output branch is directly connected to the supply potential VDD. The lower switching device 70 connects the tap 42 of the substitute source 40 to the error signal input 23 of the detector 20. The substitute source reflects the current with a lower ratio and the second transistor connected in series is used for the necessary voltage generation. This is selected so that it is close to the expected voltage drop of the consumer during normal operation. This keeps the fault detector within its control range and the control loop remains in its steady state.

FIG. 319 shows two principle illustrations of two simple switch devices. Besides these, other switches can be used. They can also be easily operated with the PWM signal, which can be used to adjust the brightness of the LED. In other applications, other suitable switches are used. The switching device 70 is similar to a known inverter with the difference that the transistors shown here are transmission gates. The output 71 is connected to the error signal input. Input 74 forms the switching input to which the switching signal, for example, the PWM signal, is fed. Two transmission gates of different types connected in series are arranged in series, with output 71 being connected between the two transmission gates. Gate 73 of the p-type with its terminal 73 forms the connection to the backup source. Terminal 72 of the second transmission gate forms the connection for the voltage signal.

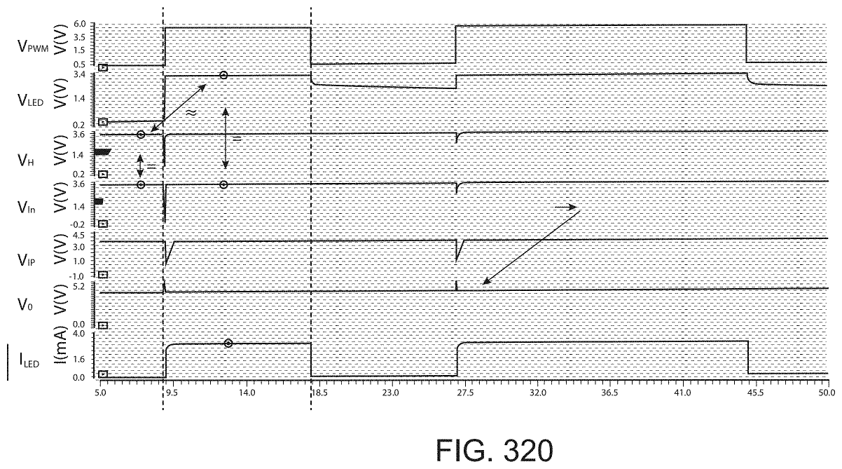

FIG. 320 shows a signal-time diagram for different signals in the supply circuit in the different operating states. V_{FMM} describes the pulse width modulation signal for operating LED 60, which is also applied to circuit devices 70. It is a logic signal and changes between two states “High” and “Low”. In the High state from about 8 μs to 18 μs and then between 26 μs and 44 μs the LED is switched on, at the other times it is switched off. The current through the LED follows these switching times as can be seen from the lowest curve marked I_{LED}.

In contrast, the voltage VLED changes only slightly between the switched on state and the switched off state. The voltage decreases continuously and would reach the starting voltage of approx. 1.4V over time, a current no longer flows, i.e. the LED is switched off. When the LED is switched on, i.e. at the time of 8 μs, the voltage drop across the LED essentially corresponds to the substitute voltage or the substitute signal V_{H}. At the time of switching on, a small voltage drop can be detected in the substitute signal, which can be process-related and depends, for example, on the parameters of the field effect transistors used. Since different types (p- or n-mos) are used, their switching behaviour is not always the same, so that residual currents could still flow during the switchover time.

Vᵢₙ shows the signal at the inverting input, i.e. the error signal input 23. Before the switching time 8 μs, the voltage V_{H} is equal to the voltage at the error signal input because of the position of the switching device 70, after switching on it corresponds to the voltage V_{LED}. This is illustrated by the “=” sign in FIG. 320. V_{H} is again selected so that it is as similar as possible to the LED voltage V_{LED} expected in normal operation.

The error correction detector 20 now compares the voltages Vᵢₙ at error signal input 23 and Vip at reference input 22 and generates a correction signal Vo. At switching time 8 μs there is a small dip of the voltage Vip at the non-inverting input, which increases a small peak in the correction signal. This may be a simulation artefact, but can also be caused by a sudden change in load in the branch of the power source. In any case, the correction signal is so small and fast that it has no effect.

The second switching point at 18 μs shows no or if only a significantly lower behaviour. Nevertheless, the control at the switch-on time does not significantly affect the output behaviour of the error detector, but rather provides a precise correction signal due to the fast feedback, so that the output current and voltage are quickly adjusted to the desired value and then remain constant. The simulation of FIG. 320 shows a control of less than 0.5 μs in this context.

The proposed supply circuit provides a high-precision current source that is particularly suitable for accurate and color-true control of light emitting diode applications. The already known PWM can be used for the contrast adjustment of the individual light emitting diodes in a pixel matrix, display or similar. The effects of switching operations during pulse width modulation on the current source are reduced by the proposed measures. As a result, even small variations in the operating current, which are only a few percent above the nominal value of the input voltage, can be realized without the switching operations affecting the stability.

In an implementation, it is possible to build the transistors of the current source close to each other, so that they are thermally strongly coupled. For the replacement branch, it makes sense to equip it with Si-pn diodes or other measures, such as amplifiers, etc., in order to approximate the replacement signal to the voltage dropping across the load during operation.

To control μ-LEDs or generally pixels in a display, the switching ratio can be controlled digitally in addition to setting the current through the μ-LED. A digital driver circuit with low own power consumption is still able to—despite the low power consumption, drive a large number of optoelectronic elements and especially μ-LEDs.

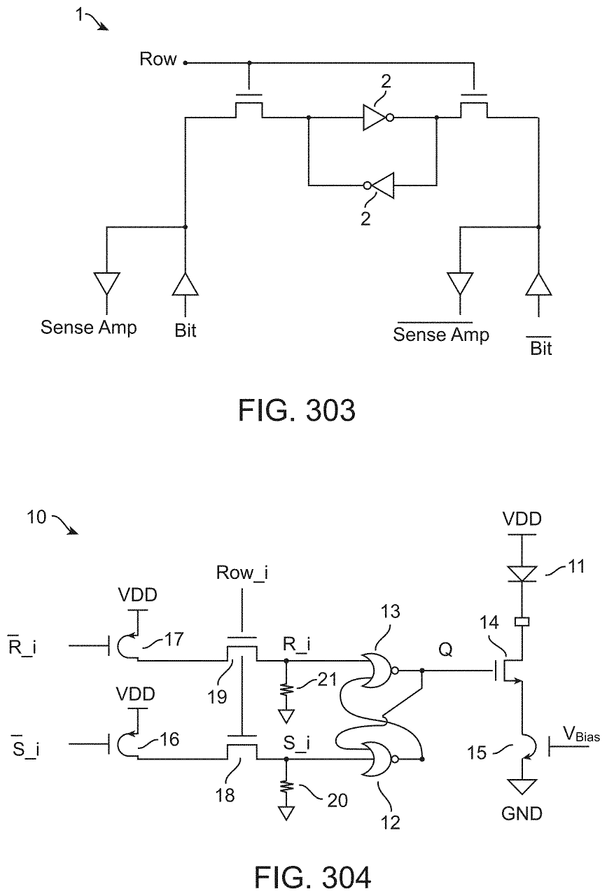

FIG. 303 illustrates a schematic circuit diagram of an implementation of a 6-T static random access memory cell, SRAM-6-T memory cell 1, which includes two cross-coupled inverters 2 as a 1-bit memory. The SRAM 6-T memory cell 1 has a compact memory size in the range of 1.08 μm2 to 1.7 μm2 per bit in 65 nm CMOS technology and a low power in the range of 0.26 μW to 0.37 μW per bit.

FIG. 304 illustrates a schematic circuit diagram of a driver circuit 10 configured to drive an optoelectronic element, which is a μ-LED 11. The driver circuit 10 is completely digital and is manufactured using CMOS technology. In this context, FIG. 304 shows only the circuit diagram. The μ-LED 11 is manufactured in a material system suitable for generating light of the desired wavelength, the circuit may be manufactured in a different material system. For the functionality shown, both elements are electrically contacted. Possibilities for this are disclosed in this application.

The driver circuit 10 includes two cross-coupled NOR gates 12, 13 which form a first memory cell or latch used to control the current through μ-LED 11. Driver circuit 10 includes additional first memory cells not shown in FIG. 304. The additional first memory cells have the same structure as the first memory cell shown in FIG. 304 and are used to control the current through additional μ-LEDs.

Each of the NOR gates 12, 13 has two inputs and one output. The output of each NOR gate 12, 13 is coupled to one of the inputs of the other NOR gate 12, 13. The other input of NOR gate 12 receives a set signal S_i and the other input of NOR gate 13 receives a reset signal R_i. The NOR gate 13 generates a signal Q at its output, which controls the gate of a transistor 14. The shown interconnection of the two NOR gates 12 and 13 with their inputs R_i, S_i and the output Q corresponds to an RS flip-flop. Accordingly, the NOR gates connected in this way can be replaced in the circuits shown.

Depending on its gate voltage, transistor 14 switches a current through μ-LED 11 on or off. The current is generated by a transistor 15. The μ-LED 11 and the channels of transistors 14, 15 are connected in series between a supply voltage VDD and ground GND. The driver circuit 10 also includes two pull-up PMOS transistors 16, 17 which are coupled to the transistors 18, 19 respectively. The transistors 16, 17 receive a signal non-S_i or a signal non-R_i at the gate terminals.

The μ-LED 11 is arranged together with other μ-LEDs in a pixel array. Each of the μ-LEDs is connected to a driver circuit as shown in FIG. 304. To enable the selection of a line i, the transistors 18, 19 are each coupled to the NOR gates 12, 13. The transistors 18, 19 are controlled by a line selection signal Line_i at the gate terminals. Pull-down resistors 20, 21 are also provided to hold back states of the cross-coupled NOR gates 12, 13. When the set non-signal S_i (active low set) is received by NOR gate 12, the output of NOR gate 13 is triggered to a high state. The cross-coupled NOR gates 12, 13 hold the high state until they are reset to a low state by the non-R_i (active low set) reset signal received from NOR gate 13.

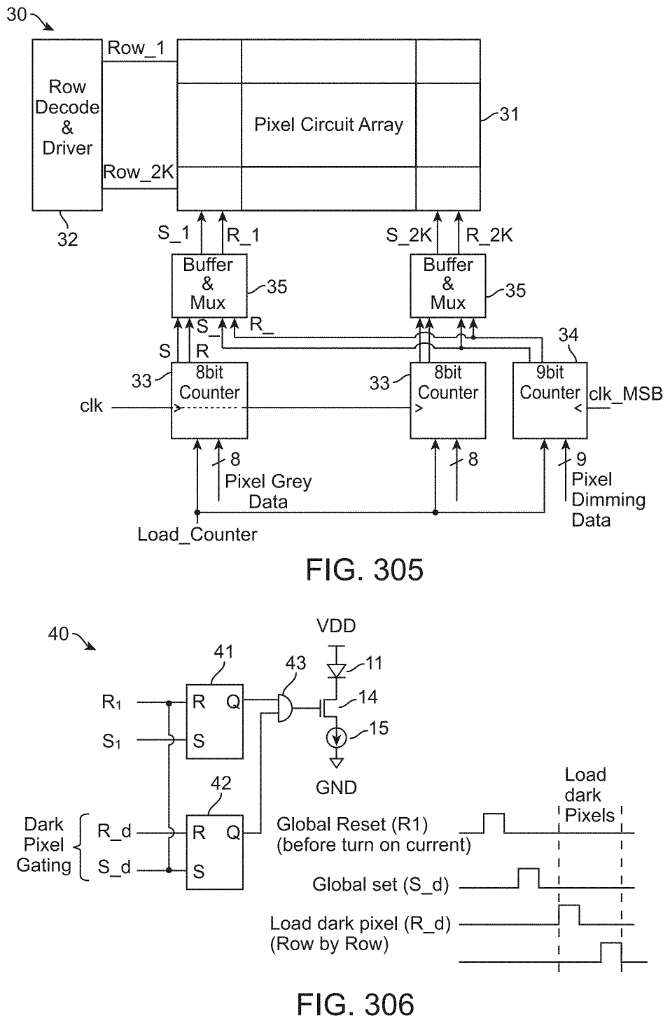

FIG. 305 shows a schematic circuit diagram of an optoelectronic device 30, the optoelectronic device 30 including a pixel circuit array 31 comprising an array of μ-LED driver circuits 10 as shown in FIG. 304. As an example, the array includes 2K rows and 2K columns. Each driver circuit 10 is connected to a respective μ-LED. In addition, the μ-LED array is made of a different III/IV material chip and each μ-LED in the array is connected to each pixel driver circuit at the drain of transistor 14 in FIG. 304.

A line decoder and driver 32 selects the lines Line_1 to Line_2K one after the other. The PWM signals controlling the current through the μ-LEDs are generated by N loadable 8-bit counters 33, where N is 2K for this example. The N counters 33 generate the set signals S_i and the reset signals R_i (or alternatively the signals non-S_i and non-R_i) for N columns of pixels simultaneously per selected row. When pixel pulse width values, i.e., 8-bit pixel gray data, are loaded into counter 33, the set signals S_i are activated to turn on the pixel stream, and the counters 33 start with a pixel clock frequency of, for example, between 40 MHz to 100 MHz. When counter 33 reaches the pixel data values, the reset signals R_i are activated to turn off the pixel stream.

There is also a 9-bit (MSB) counter 34, which generates the global or common dimming for the pixel array. The 9-bit pixel dimming data loaded into counter 34 thus determines the brightness of the background of the pixel array. If the dimming pulse width is zero, a line scan is performed so that the pixels in the lines light up. Otherwise, global pixel illumination is performed first, followed by line-by-line scanning. The set signals S_i and reset signals R_i generated by counter 33 and the global or common dimming signals generated by counter 34 are fed to N buffers and multiplexers 35, which pass the signals to the columns of the pixel circuit array 31.

The global dimming data can also be combined with the greyscale data in the video/image signal processor IC or through the μ-LED driver IC, so that no separate global dimming pulse is required and then only the greyscale data is updated line by line. The counters 33, 34 are controlled by a signal Load_Counter. Furthermore, the counters 33 receive a clock signal clk. The counter 34 receives a clock signal clk-MSB.

To get rid of dark pixels, the driver circuit can include a second memory cell or latch for each μ-LED. FIG. 306 illustrates a schematic diagram of a driver circuit 40 design based on driver circuit 10 as shown in FIG. 304. Driver circuit 40 includes a first memory cell 41 and a second memory cell 42. Both the first memory cell 41 and the second memory cell 42 have a set input S, a reset input R and an output Q. Furthermore, the reset input R of the first memory cell 41 is connected to the set input S of the second memory cell 42. The outputs Q of the first and second memory cells 41, 42 are connected to inputs of an AND gate 43. The output of AND gate 43 is connected to the gate of transistor 14.

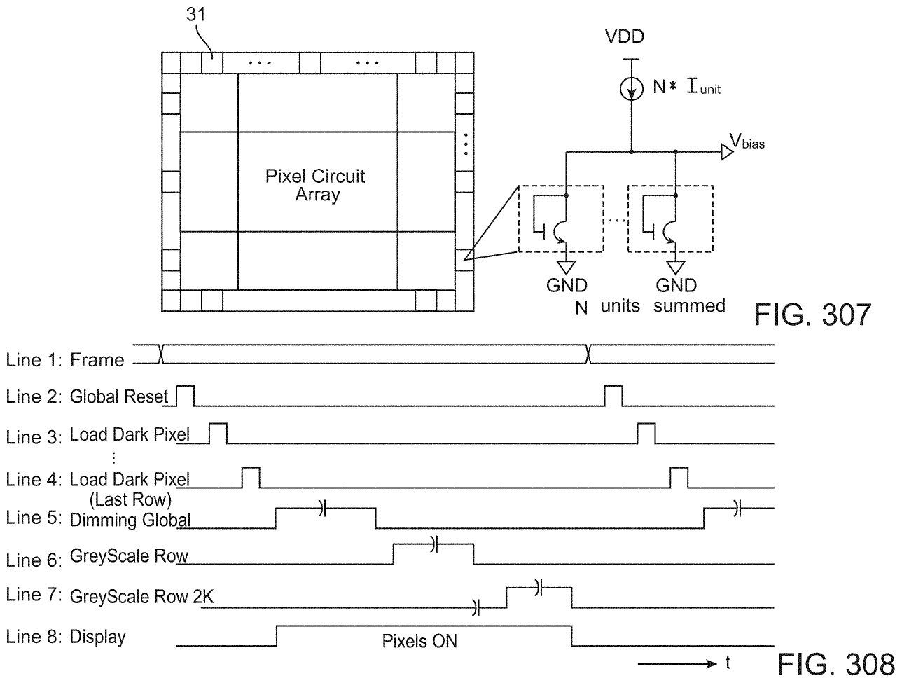

As can be seen in the function time diagram shown in FIG. 306, a global reset is performed at the beginning of each frame so that all pixels are dark. Then a global set signal S d is applied to the set inputs S of the second memory cells 42 to make all pixels “normal pixels”. Then the second memory cells 42 of the pixel circuit array are loaded or reset row by row to implement selective dark pixels. An implementation of the optoelectronic device includes a spatial averaging pixel bias current. The optoelectronic device includes a global N-bit digital-to-analogueue converter, DAC, covering a pixel current range of, for example, 22 nA to 1 μA. As illustrated in FIG. 307, identical peripheral bias currents are summed to produce a spatial average bias.

Turning the pixel stream on and off is controlled by the state of the second memory cell or the latch for dark pixels and the PWM signal for normal active pixels. FIG. 308 illustrates a function-time diagram of the optoelectronic device. Line 1 of the function timing diagram shows the duration of a frame. During the frame, the display shows a content such as a video sequence.

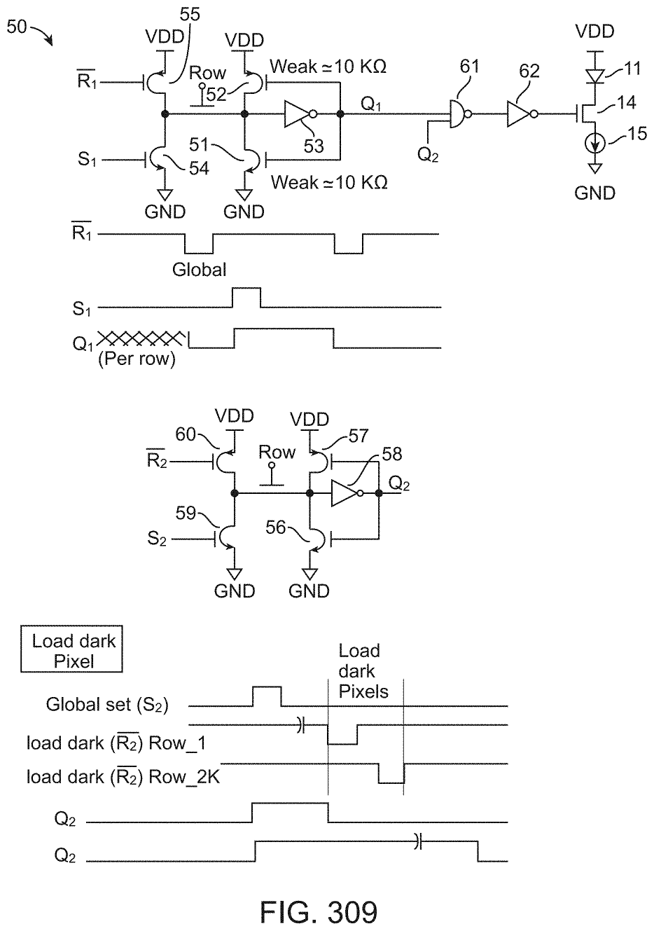

At the beginning of the frame a global reset is performed so that all pixels of the display are dark (see line 2). Then dark pixels are loaded line by line so that these pixels are permanently dark during this frame (see lines 3 to 4). Then a global dimming is applied to ensure that the background has the same brightness (see line 5). Then grayscale data is loaded to generate the PWM signals starting at line_1 and ending at line_2K (see lines 6 to 7). Finally line 8 shows when the pixels are switched on. After the frame is finished, the next frame starts. FIG. 309 illustrates a schematic circuit diagram of another version of a driver circuit 50 configured to drive the μ-LED 11. Driver circuit 50 is completely digital and requires even less space than driver circuit 10 shown in FIG. 304.

In the driver circuit 50, the first memory cell includes an NMOS transistor 51 and a PMOS transistor 52 connected in series between the supply voltage VDD and ground GND, which means that the channels of the two transistors 51, 52 are connected in series. Additionally, an input of an inverter 53 is connected between the transistors 51 and 52. The output of inverter 53 is connected to the gates of transistors 51, 52.

Furthermore, an NMOS transistor 54 and a PMOS transistor 55 are connected in series between the supply voltage VDD and ground GND. The transistors 54, 55 receive a set signal S1 or a reset signal non-R1 at their gate terminals. To remove dark pixels, the driver circuit 50 includes a second memory cell or latch that has the same structure as the first memory cell and is also illustrated in FIG. 309. The second memory cell includes an NMOS transistor 56 and a PMOS transistor 57 connected in series, an inverter 58 and an NMOS transistor 59 and a PMOS transistor 60 connected in series.

The transistors 59, 60 receive a set signal S2 or a reset signal non-R2 at their gate terminals. The output of inverter 53 of the first memory cell generates a signal Q1 and the output of inverter 58 of the second memory cell generates a signal Q2. The signals Q1 and Q2 are fed into the inputs of a NAND gate 61. An inverter 62 is located downstream of the NAND gate 61, and the output of inverter 62 is coupled to the gate of transistor 14, which switches the current through μ-LED 11 on and off depending on its gate voltage.

The function timing diagram of FIG. 309 shown above makes it clear that a global reset is performed first by applying the reset signal non-R1 to the first memory cell. Then the reset signal S1 is applied to trigger the first memory cell at output Q1 to the high state. The first memory cell holds the high state until it is reset to the low state by the reset signal non-R1. A lower function timing diagram of FIG. 309 shows the function of the second memory cell during the loading of dark pixels. First a global set signal is applied by signals S2. Then dark pixels are loaded line by line by the non-R2 reset signal.

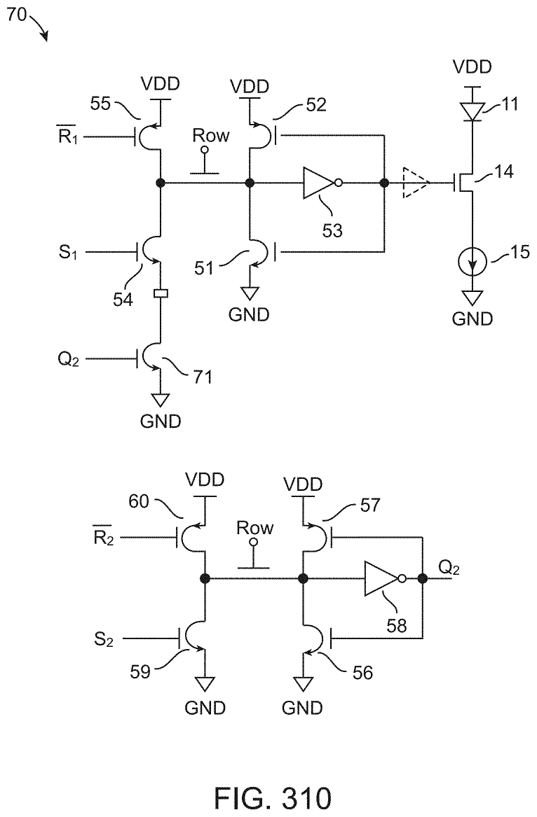

FIG. 310 illustrates a schematic circuit diagram of another embodiment of a driver circuit 70, which is a variation of the driver circuit 50 shown in FIG. 309. The driver circuit 70 contains the same first and second memory cells as the driver circuit 50, but the driver circuit 70 does not contain a NAND gate for combining the output signals of the first and second memory cells. Instead, driver circuit 70 includes an additional NMOS transistor 71 connected in series with transistor 54. In particular, transistor 71 is located between transistor 54 and ground GND. The gate of transistor 71 is controlled by the output signal Q2 of the second memory cell.

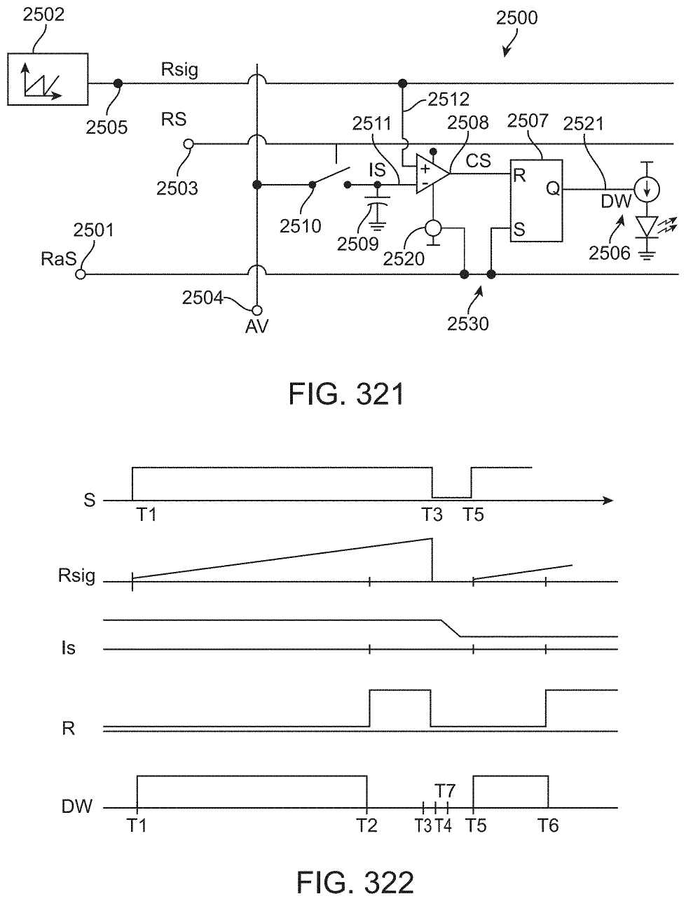

FIG. 321 illustrates a version of an analogueue ramp for current control in the form of a 2500 control circuit that includes a pixel driver with a small footprint. It is built in a semiconductor material and uses various techniques described here. Such a concept is based on a analogueue ramp for lighting control and is particularly space-saving and shows a hysteresis during operation, which reduces noise and makes double buffering possible. Double buffering allows longer operating cycles, which reduces the total power consumption. This aspect can be advantageous, especially when combined with other power saving functions.

The control circuit features a pixel driver as a combination of a 2530 pulse generator with a column data buffer as input stage. A common ramp generator 2502, which can also be used for several pixels 2506, e.g. a row or column, is part of the control circuit in this version. The control circuit is coupled with its output 2521 to a control input of an adjustable current source of a μ-LED pixel. The current source can be selectively enabled and disabled based on a pulse signal DW applied to the control input of the adjustable current source. In response to the pulse signal DW the μ-LED is switched on or off. In an alternative embodiment, the power source can be replaced by a switch or similar element to ensure that the μ-LED is selectively switched on or off. The pulse length of signal DW corresponds to the brightness of the μ-LED element of the pixel.

The control circuit 2500 comprises a line selection input 2503 for the line selection signal RS and a column data input 2504 for the data signal AV. These inputs are similar to the conventional approach and in fact, they can be used in a similar way. The control circuit also comprises a trigger input 2501 for a trigger or “ramp start” signal RaS and a ramp signal input 2505 for a ramp signal.

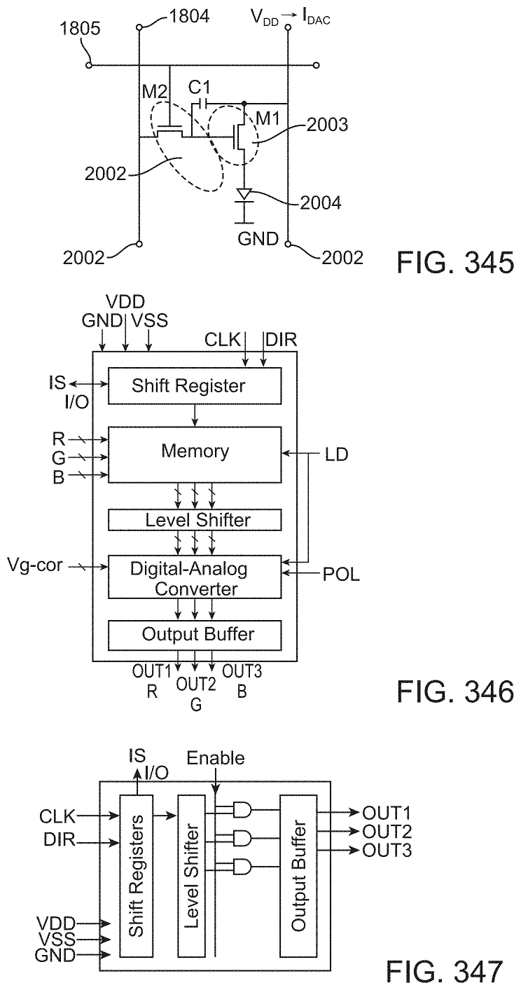

Similar to the conventional cell as shown in FIG. 345, the column data input is connected via a switch 2510 to a capacitor 2509 to store data information corresponding to the brightness of the μ-LED inside the capacitor 2509.

Switch 2510 is implemented as described here as a field effect transistor in Si technology or also in Ga or In technology. The gate or control input of switch 2510 is connected to the line selection input to receive the line selection signal RS. However, while the conventional approach uses the charge stored in the capacitor to control the current directly through the light emitting device, capacitor 2509 is used together with switch 2510 as an input buffer. The output 2511 of the input buffer and in particular the capacitor and switch are connected to the pulse generator 2530 to generate a pulse.

Pulse generator 2530 comprises a comparator 2508, which for example contains a differential amplifier and an output buffer stage 2507 implemented as an RS flip-flop, whose behaviour can be expressed with NOR and NAND gates. The differential amplifier is implemented in the same technology as switch 2510. For this purpose, it may include transistors as described in this application. The inverting input 2511 of the comparator is connected to capacitor 2509, the non-inverting input 2512 is connected to the ramp input signal 2505. Comparator 2508 can be selectively switched off to reduce power consumption as explained in detail later.

Comparator 2508 provides a status signal or comparison result CS at its output. The output of the comparator is directly connected to the reset input R of the RS flip-flop 2507. The set input S is connected to the trigger input 2501.

The operation of the control circuit is explained in more detail with reference to the various signals illustrated over time in FIG. 322. It is assumed that the line selection signal RS is applied and a constant charge is applied to capacitor 2509. A constant signal IS is applied to the non-inverting input of the comparator (corresponding to reference 2512). Signal IS corresponds to the brightness of the μ-LED associated with the control circuit.

At time T1, the trigger signal RaS changes from a low level LOW to a high level HIGH and subsequently the set input S of the RS flip-flop 2507 also goes to HIGH. At time T3, the trigger signal RaS will change back to the LOW level. The ramp signal Rsig is applied at the same time T1. Ramp signal Rsig increases linearly over the time the trigger is HIGH. This means that ramp signal Rsig starts from a first value corresponding to LOW and rises to a second level, i.e. the HIGH level. Ramp signal Rsig is also applied to the non-inverting input of the comparator. During the time period from T1 to T2, the comparator compares the signal IS buffered in capacitor 2509 with ramp signal Rsig. As long as the signal at the non-inverting input is lower than the inverting input, the output signal applied to the reset input R of the RS flip-flop remains LOW. At time T2, the reset input R receives the rising edge of the result signal CS when the output of the comparator changes from LOW to HIGH. At this time, the ramp signal becomes higher than the buffered signal IS.

As a result of this transition, output Q of the RS flip-flop resets the control signal DW for the current source to LOW value from time T2. It can thus be seen that the time T2 at which the output signal DW switches off the current source again depends on the charge stored in capacitor 2509, provided that a uniformly rising ramp Rsig is assumed. The ramp signal RSig and the signal IS thus define a pulse whose length essentially corresponds to the time period from T0 to T2.

At time T3, the trigger signal changes from HIGH to “LOW”.

At the same time, the ramp signal is switched off, causing the comparator to output a “LOW” signal. Therefore, both signals at the R and S input will change to LOW. Due to a small hysteresis in the comparator, the transition for the trigger signal at input S will be a little faster, causing the flip-flop to keep the output signal DW LOW, regardless of the transition of signal CS at input R. At time T5, trigger signal RaS is repeated at input S. Likewise, the ramp signal Rsig starts again at its start value.

The period between time T3 to T5 is the blanking time used to reprogram the corresponding columns in each row. For this purpose, the row selection signal is triggered at time T7, which connects the column data line to the capacitor via switch 2510. Capacitor 2509 is then charged or discharged to a new value. In this example, capacitor 2509 is discharged to a much smaller value that corresponds to a different (lower) brightness. The recharging is initiated at time T7 and ends at time T4, when the line selection signal RS goes LOW again, opening the switch. Another row can be addressed and reprogrammed during the cycle for the present row at time T5.

Because of the lower level for signal IS, the comparator 2508 now changes its output much earlier at time T6 in the new cycle. Consequently, output Q falls to “LOW” at time T6, which is much shorter than for the previous period of the trigger signal RaS. Output Q with its control signal DW controls the current through the μ-LED coupled to it. The longer the output signal DW remains at HIGH, the longer a current flow through the μ-LED, resulting in a high brightness for the corresponding color. Comparator 2508 and maybe the RS-Flip-Flop can be switched off during reprogramming and blanking time to reduce power consumption. For this purpose, at least the comparator comprises a 2520 power control unit connected to the trigger input. As long as the trigger signal is Rsig HIGH, the comparator 2508 is powered to perform its operation. During the sampling period, it is switched off in response to the trigger signal.

Since in some examples the sampling time can be significantly longer than the current time for the trigger signal, the whole pulse generator can be switched off.

In an alternative embodiment, reference is again made to time T2 in FIG. 322. The comparator switches its output signal CS from LOW to HIGH as soon as the ramp signal reaches the threshold of the buffered signal IS. Trigger signal S is still HIGH, which causes the RS flip-flop to switch the output signal LOW. As you can see, output Q remains LOW regardless of the level at the reset input R. Therefore, the comparator could be switched off after a reset because of the transition of the signal at input R. In some variants, the power control unit 2520 can be coupled to output Q to control the power supply to the comparator based on the state of output Q.

Segmentation and additional ramps can be used if different lines are addressed. This would allow implementing spatial-temporal multiplexing, which reduces the generation of current peaks and leads to less varying power consumption. While in the present example signals have been applied to specific inputs on the comparator, the skilled person can see that the design of this principle can be changed. For example, inverting and non-inverting inputs can be exchanged, resulting in inverse behaviour. The RS flip-flop requires two transistors and resistors, which implements a small asymmetry during the design in the RS flip-flop (e.g. by adjusting the value of one resistor), adjusts the switching behaviour and will prevent undefined states.

With some μ-displays, individual pixel errors may occur, which damage the μ-LEDs. Such errors cannot be avoided. However, a repair with the size of a μ-display is only possible with a very large effort. Therefore, it is suggested to design not only subpixels redundantly, i.e. to provide more than one subpixel of the same color, but to provide redundant μ-LED branches with selection fuse. These redundant pixels can also be connected to the same power source. In a test, the functionality of each μ-LED is now checked. If the test results in two functional μ-LEDs, one of them can be specifically deactivated to compensate for color changes or loss of brightness of the other μ-LED due to the different current flow. If, on the other hand, a fault is detected, the redundant μ-LED continues to be used.

FIG. 323 shows an embodiment of a proposed device that provides such redundancy with simultaneous selection protection. The illustration shows two pixel cells each with a first and second branch, each having a μ-LED D1a and D1b, respectively. The μ-LED D1a and D1b are connected to a common reference potential connection GND. Their other terminals are each connected to an electronic fuse Fa and Fb. These are, for example, a fuse, which melts when the current through the fuse becomes large enough. The second branch, i.e. the branch with the fuse Fb and the μ-LED D1b also shows an imprinting component EPT. This is designed as a MSOFET transistor and its drain terminal is connected between the fuse and the μ-LED. Its source contact is connected to the common reference potential, the gate can be supplied with the selection signal Vburn via the imprinting signal line EPT. In principle, lines or alternatively columns can be addressed, controlled or selected via the imprinting signal line EP, depending on the wiring.

The pixel cell also includes a 2T1C circuit with a current driving transistor T1. This transistor is connected to the supply potential on the one hand and to the first and second branch and its fuses Fa and Fb on the other hand. A charge storage C is electrically connected to the gate of the first transistor T1 and to the source terminal of the first transistor T1. Furthermore, the “t1C cell also comprises a transistor T2 which is connected between the data terminal Vdata and the gate of the transistor T1. The selection signal can be fed to its gate.

For each color of a pixel two μ-LEDs D1a and Dib, each electrically connected in series to an electrical fuse Fa and Fb, can be provided. In this way, redundancy is created for each pixel in all sub-pixels.

In the case where μ-LEDs are electrically connected along a row and along a column to a common imprinting signal line EP, each pixel cell of a column, for example, can be electrically connected and addressable to the supply potential terminal VDD by means of a common supply line to a switching transistor arranged on a common carrier outside the active display. Fuses of a column can thus be triggered or made to melt.

In the following, the mode of operation of this circuit is explained in more detail.

In the first case, one of the two μ-LEDs is defective in such a way that it is “OPEN”, i.e. there is no current flow through the defective μ-LED. Then the test gives a corresponding result and the respective other μ-LED is automatically used. On the other hand, a “SHORT”, i.e. a short circuit, can also be present. If this short-circuit occurs, the resistance through the short-circuited diode is very low, so that the current through the respective fuse is significantly higher. This also cuts the fuse in a SHORT.

A third case concerns the situation that both μ-LEDs function as expected. In this case, the current of the power source is split between both branches, which can lead to a color error. The dominant wavelength depends on the selected current. Therefore, in such a case, the signal Vburn (high potential, e.g. VDD) is applied so that the imprinting component EPT becomes conductive. If transistor T1 is simultaneously fully switched through by a corresponding signal on the data and selection line, a high potential is thus applied to the fuse. The resulting high current flow destroys fuse Fb, so that diode D1b is safely disconnected.

When designed in PMOS technology, the potentials and signals exchange their polarity accordingly.

The fuse can be designed as a metal strip with different widths. For example, one length can be 33 [μm], a width at one longitudinal end 20 [μm], at the other longitudinal end 9 [μm] and in a 12 [μm] long central area 2 [μm]. The longitudinal ends can be square or rectangular and have passages. The square longitudinal end can be in the direction of the transistor T1 and the rectangular longitudinal end can be in the direction of a light emitting diode. A material can be IGZO, for example.

Instead of the above-mentioned metal strips, a thin-film transistor can also be used, especially in diode interconnection, in which the gate and source are electrically connected permanently. Each μ-LED can be equipped with its own thin-film transistor. This can act as both a controllable current source and an electrical fuse. By means of a signal, the thin-film transistor can be pulled to zero potential, for example, so that it burns through as a result of the increased current flow and the μ-LED is switched off. In principle, all known types of electrical fuse can be used. Activation or release does not have to destroy the fuse, but in any case, it must safely disconnect the assigned μ-LED from the power supply.

In this way, an end-of-line test can be carried out without additional process steps such as laser cutting or similar. A combination with embossing diodes as embossing components is also possible.

FIG. 323 shows on the right side a neighboring cell of a first pixel cell. For each line a selection signal line Vsel, an imprint signal line EP and a data signal line Vdata can be connected. With Vsel and Vdata the selection signal line generates a signal for selecting the relevant line to activate the associated fuses. The imprinting signal line EP provides a fusing voltage V_burn for generating a fusing current I_burn.

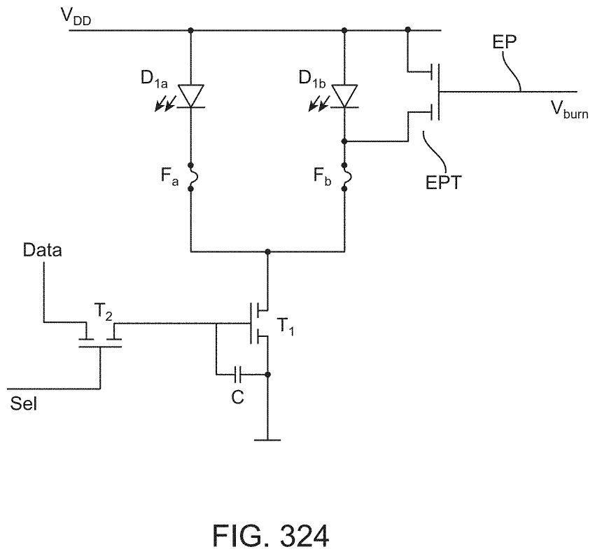

FIG. 324 shows a second embodiment of a proposed device in which the arrangement between the current source and μ-LEDs is reversed. While FIG. 323 shows a configuration with a common cathode, FIG. 324 shows a common anode configuration with the μ-LEDs.

The anode connections of the μ-LEDs D1a and Dib are connected to the supply potential connection VDD. A first current line contact of a first transistor T1 is connected to the reference potential terminal GND. The drain terminal of the first transistor T1 is connected to the common terminal of the electrical fuses Fa and Fb. The selector holding circuit comprises a charge storage C connected to the control contact of the first transistor T1 and to a source terminal of the first transistor T1. The function of this arrangement is similar, but the transistor EPT is connected between the fuse Fb and μ-LED D1b and the supply potential. A voltage V_burn can be applied to the gate of the imprinting transistor EPT via an imprinting signal line EP, thus causing the electrical fuse Fb, which is a fuse, to melt.

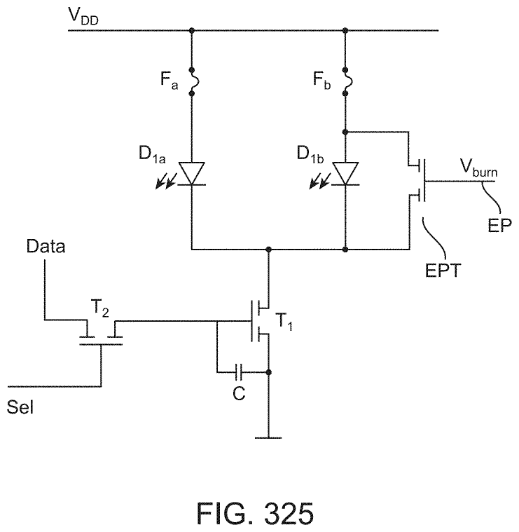

FIG. 325 shows a third embodiment of a device with redundant branches of μ-LEDs, which can be selected by means of selection fuses. In contrast to the embodiment in FIG. 325, the series connection of fuse and μ-LED is swapped in each branch. Thus, the fuse is directly connected to the supply potential terminal, the μ-LED of each branch is connected on the cathode side to a common base point and to the current driving transistor T1. Furthermore, the imprinting transistor EPT is connected with its drain terminal between fuse Fb and μ-LED D1b. Its source terminal also leads the current driving transistor T1 to the common base point for the μ-LEDs. The 2T1C cell is constructed in the same way as in the previous figure. To melt the fuse, the diode D1b is bridged with the imprinting transistor EPT and the signal Vburn, so that a high current melting the fuse flows through the fuse Fb.

As the LEDs are not connected together to the potential connections for VDD or GND, no common electrode of the μ-LEDs can be realized, i.e. one electrode for several pixels. This arrangement is suitable, for example, if no common electrode is required for process technology.

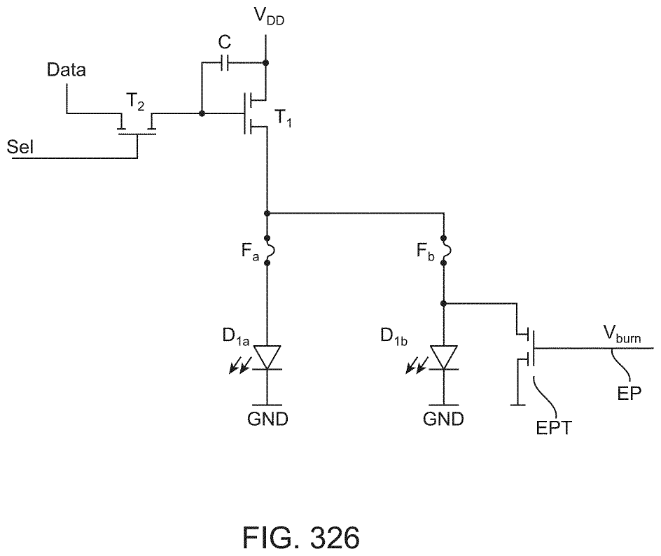

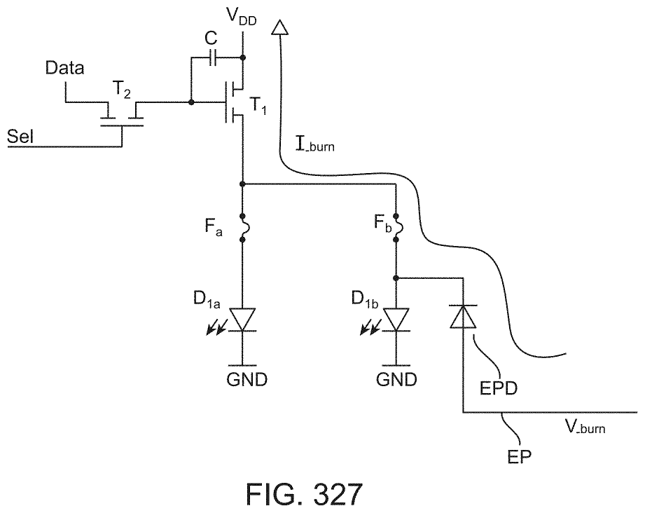

FIG. 326 shows a slight modification of the embodiment according to FIG. 323, where the transistors are PMOS (especially transistor T1) and the charge storage is connected between the gate and the fixed supply potential. The advantage of this embodiment is that the voltage across the charge storage is independent, unlike the R design in FIG. 323, in which the voltage across charge storage C can vary slightly due to the forward voltage or changes in it due to temperature fluctuations. The same advantage of independence from temperature variations is also shown in the design of FIG. 324.

FIG. 327 shows another alternative version of the embodiment shown in FIG. 326. The imprinting component here is an imprinting diode EPD with one terminal connected to a second terminal of the μ-LED D1b, to which the imprinting diode EPD is assigned, and the other terminal connected to an imprinting signal line EP, by means of which addressing can be performed. As shown in FIG. 327, a first terminal of the imprinting diode EPD is connected between fuse Fb and μ-LED D1b and a second terminal of the imprinting diode EPD is connected to the imprinting signal line EP. The melting voltage V_burn is also applied to the latter, with which the electrical fuse melts.

During operation, a selection of an electrical fuse Fb to be triggered is made by switching through the first transistor T1. This is done by programming a voltage on the charge storage C via the data line Data and the selection line Sel. The VDD connection is connected to 0 volts or a negative voltage, in contrast to normal operation. A voltage V_burn is then applied to the imprint signal line EP, which is more positive than the voltage at VDD. In this way, a high current IF or I_burn flows via the imprinting diode EPD via the electrical fuse Fb and the first transistor T1, which is switched on, whereby the fuse Fb is triggered in the selected pixel cell. The fuse Fb melts and the corresponding LED Dib is switched off. In addition, the potential at the first potential connection GND should ideally also be greater than 0 Volt, for example equal to the melting voltage V_burn, so that no large current flows via LED Dib or D1a and can damage them.

According to this embodiment, the current (IF, I_burn) required to trip the electrical fuse Fb flows in the opposite direction to that which would flow in “normal operation”. After this procedure in an EOL test, no additional process steps, such as laser cutting or similar, are required.

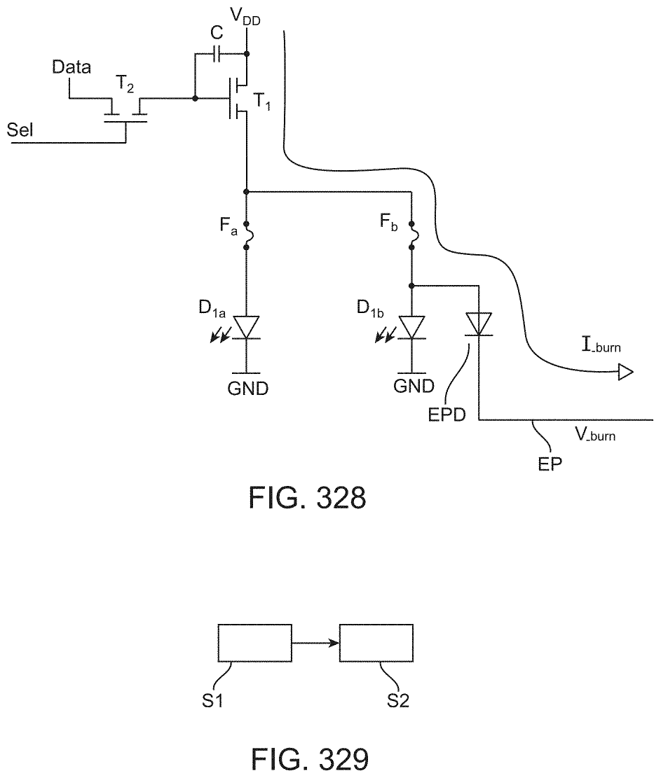

FIG. 328 shows a modification of the embodiment according to FIG. 327, in which the imprinting diode was only turned upside down. It is now connected on the anode side between fuse Fb and μ-LED Dib of the second branch. The arrangement according to FIG. 328 is created using PMOS thin-film transistors as current driver transistor T1 and a common cathode arrangement for the μ-LEDs. All imprint signal lines EP of a line of a display are connected together here. The electrical fuse Fb to be triggered is selected by switching through the first transistor T1. For this purpose, the charge storage C is set to 0 V or another voltage so that T1 becomes conductive. A voltage of 10 V or another positive voltage is applied to the VDD connection. The voltage V_burn, which is applied to the imprint signal line EP, is here more negative than the voltage at the supply potential connection VDD and is 0 Volt, for example. In this way, a high current I_burn flows through the imprinting diode EPD, through the electrical fuse Fb and the conducting first transistor T1, whereby the fuse Fb in the selected pixel cell is triggered and thus melted.

Meanwhile, the potential at the first potential connection GND should ideally be just as high as the potential at the second potential connection VDD, so that the LEDs D1a and D1b are switched in reverse direction and so that no high current flows over the LED D1b or D1a and can damage them despite the first transistor T1 being conductive. According to this embodiment, the current (IF) I_burn required to trigger fuse Fd flows in the same direction as it would in “normal operation” of the arrangement.

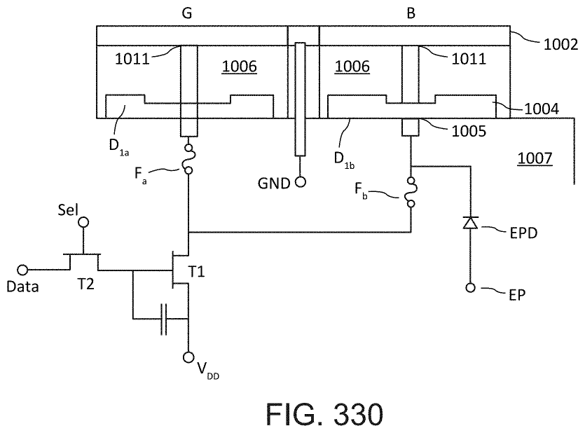

FIG. 329 shows an embodiment of a method for the electronic configuration of a plurality of μ-LEDs. In a first step S1 the μ-LEDs of the first branch and the second branch are tested for their functionality. This results in several possibilities, of which the following is probably the most common. In this case, both μ-LEDs function as expected. If this is the case, in a second step S2 an imprint signal is applied to the electronic imprinting component. A current is then provided by the current driver or current source, which flows through the now conductive current imprinting element. The current is selected so that the μ-LEDs are not damaged, but the fuse of the respective branch is destroyed. This deactivates the respective branch. In case of a fault, however, only one of the two branches is still functional. The other is either “OPEN”, i.e. no current flows over the faulty branch, or “SHORT”, i.e. a short circuit is present. In the latter case, the increased current and the low resistance in this branch can destroy the fuse in the faulty branch, so that the fuse in the faulty branch changes from SHORT and OPEN and does not affect the function of the whole arrangement any more.

With the method described above, the imprinting signal line can be designed as a global line, i.e. one connected to all pixels. Addressing is done via the supply line via transistor circuits on a panel outside an active display, as well as via the selection lines and appropriate programming of the charge accumulators of the 2T1C cells.

This results in a reduced wiring effort. Likewise, a reduction of the necessary layers can be achieved, which can lead to a reduction in costs. However, the switching transistors must be designed in such a way that they can carry the current of a column. Furthermore, there is an increased power dissipation in the panel or in the common carrier during this process.

The described circuit design with two fuses can be used for a variety of μ-LED embodiments.

FIG. 330 shows an embodiment of the circuit based on the proposed concept combined with a slot antenna arrangement disclosed in this application. The slot antenna has a stack of semiconductor layers with a lower contact area 1005 and an upper contact area 1011. The upper contact area 1011 of each slot antenna is connected to a common ground potential terminal GND within the substrate 1007 via a transparent cover electrode 1002. The substrate 1007 also houses the other circuit elements for driving and testing the slot antenna. The contact areas 1005 of both slot antennas are now connected to a fuse Fₐ or F_{b}. Between the fuse F_{b} and the contact area 1005 of the right slot antenna there is also a tap, which leads to the imprint diode EPD and the imprint signal line EP.

The respective other terminals of the fuses F. and FE are connected to the output of the current driver transistor T1. Together with the selection transistor T2 and the capacitor located between the supply potential V_{DD} and the control terminal of the current driver transistor T1, the current driver transistor T1 forms a 2T1C cell to supply the two slot antennas. In one aspect, the current driver transistor T1 is the dual-gate transistor disclosed in this application.

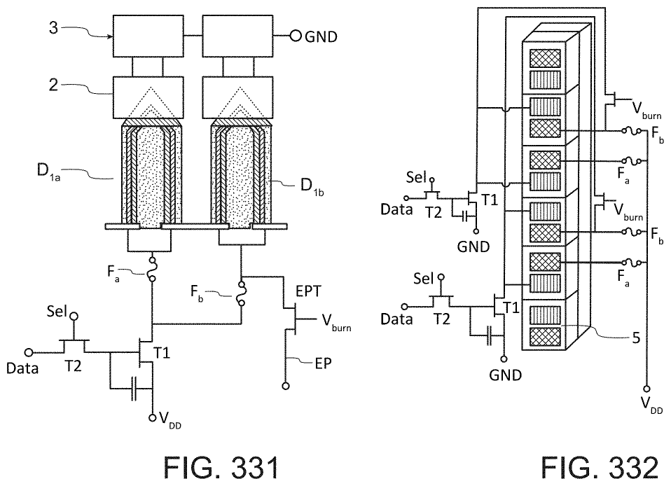

As explained in the previous examples, a test step evaluates whether the two slot antennas are functional. If this is the case, the fuse F_{b} is destroyed by the isolating element EPD and thus the right slot antenna is cut off from the power supply. If one of the two slot antennas is defective, the power supply for the remaining slot antenna is provided by the 2T1C cell. FIG. 331 shows a similar embodiment, in which μ-LEDs are provided in the form of horizontally aligned microrods. As already explained in the design of FIG. 42, these are connected with their respective contact 2 to a contact area 3 on the substrate not shown here. The contact area 3 is in turn connected to the common reference potential GND. The rear contact connection of each microrod is connected to the respective fuse Fₐ or F_{b}. μ-LED Dib is the redundant diode and its rear contact terminal is connected to the imprinting transistor EPT. To melt the fuse Fb, the imprinting signal Vburn is applied to the control connection, whereby a high current flows through the fuse from the current driver transistor T1 to the imprinting signal line EP. In this way, the horizontally oriented microrod Dib is disconnected from the power supply. In the event of a production-related failure of the microrod D1a due to either a short-circuit or a disconnection, the 2T1C cell with its current driver transistor T1 supplies the microrod Dib.

FIG. 332 shows a further embodiment, in which a series of basic modules 5 are provided. Two first adjacent contacts each are connected to the supply potential connection V_{DD} via respective fuses Fₐ and F_{b}. Between the fuse F_{b} and the respective contact, an imprint transistor is connected, which is connected to the output of the current driver transistor T1 of a respective current source. In this version, a pair of base modules is connected to a common current source comprising a 2T1C cell consisting of the current driver transistor T1, the selection transistor T2 and a capacitor. In the event of a positive test of the two base modules, a switching signal is applied via the control terminal of the imprinting transistor EPT and thus a fusing current is switched via transistor T1 to the respective fuse F_{b}.

Small-scale display arrangements with a high resolution are particularly desirable for AR systems, such as head-up displays or glasses with a light field display that projects a raster image directly onto the retina. For μ-displays with pixel-sized light sources, so-called μ-displays in matrix form based on GaN or InGaN are proposed, among others.

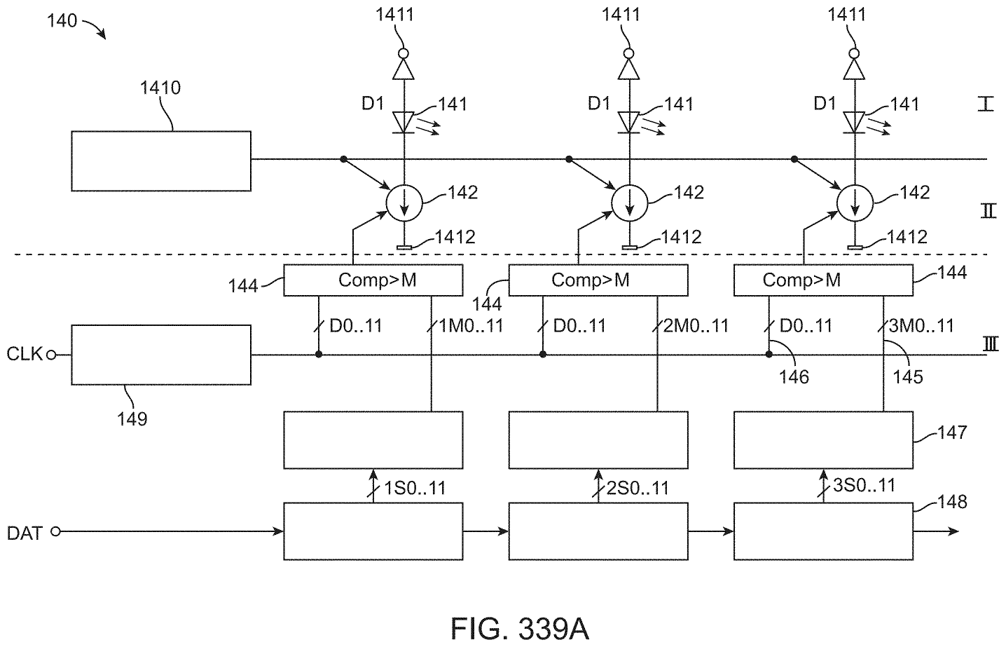

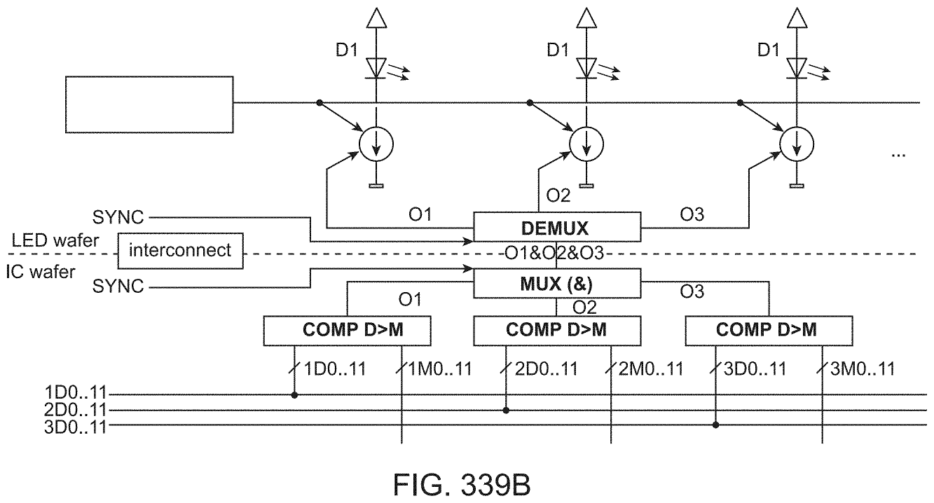

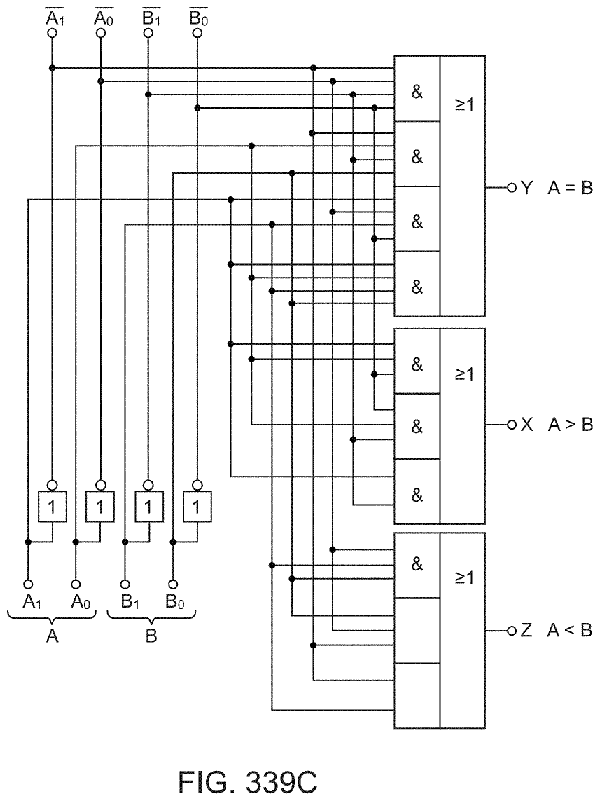

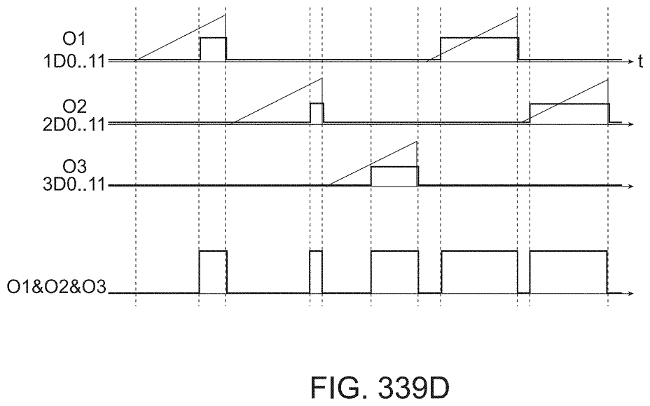

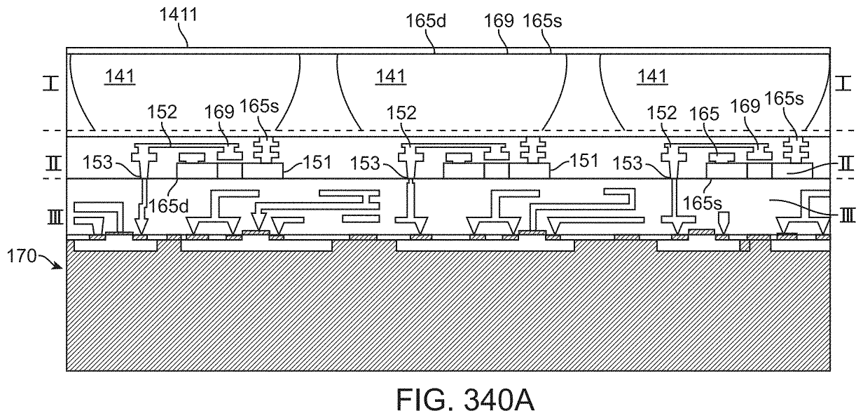

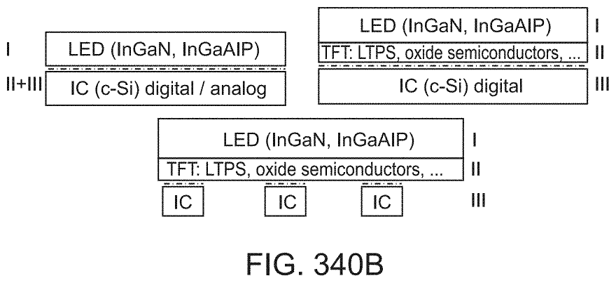

FIG. 333 shows a display device comprising an IC substrate component and a monolithic pixelated optochip mounted thereon as a first embodiment of a cross-sectional view. An IC substrate component 1 is shown with monolithic integrated circuits 2.1, 2.2, 2.3 and with IC substrate contacts 3.1, 3.2, 3.3 controlled by them. The IC substrate component 1 can comprise further components for control, power supply and for signal exchange with peripheral devices, whereby an interface 23 is sketched as an example. In this context, reference is made to further different versions in this application, which describe the digital and analogueue circuit components in more detail. FIGS. 339A to 339C, 340A and 340B with their corresponding descriptions are given as examples.

The IC substrate contacts 3.1, 3.2, 3.3. are metallic and are each separated by an insulating layer. A monolithic pixelated optochip 4 is arranged on the IC substrate component 1 and electrically and mechanically connected to the IC substrate contacts 3.1, 3.2, 3.3. To be more precise, contacts 22.1m 22.2 and 22.3 are inserted on the surface of the pixelated optochip 4 in such a way that they are opposite the IC substrate contacts 3.1, 3.2, 3.3 when they are positioned exactly on the IC. As shown, the contacts have the same size in each case, so that even a slight offset as shown has no negative effects and a short circuit is avoided. Various techniques for such a connection are disclosed in this application.

The monolithic pixelated optochip 4 comprises a semiconductor layer sequence 5 with a first semiconductor layer 6 with p-doping and a second semiconductor layer 7 with n-doping, wherein the first semiconductor layer 6 and second semiconductor layer 7 are applied over a large area and extend in the lateral direction perpendicular to the stacking direction 8 substantially over the entire monolithic pixelated optochip 4. Embodiments of the semiconductor layers 6, 7 with several individual layers of different doping levels or made of different semiconductor materials are not shown in detail. Between the first semiconductor layer 6 and the second semiconductor layer 7 there is an active layer, not shown in detail, with quantum wells in the area of which an active zone 24 emitting electromagnetic radiation forms when a current flows through the semiconductor layer sequence 5 in stack direction 8.

On the front side 17 above the semiconductor layer sequence 5, a transparent contact layer 16, for example of indium tin oxide (ITO), is applied flat. In order to achieve a μ-LED 9 with a small pixel size P, in the present embodiment of 2 μm to 5 μm diagonal size, the first light source contact 10.1, 10.2, 10.3 on the underside of the first semiconductor layer 6 facing the IC substrate component 1 is considerably smaller than the pixel size P. For the embodiment, a maximum diagonal MD of the first light source contact 10.1, 10.2, 10.3 of 300 nm is selected so that the feature is fulfilled according to which the projection area 13 of the first light source contact 10.1, 10.2, 10.3 on the μ-LED back side 12 corresponds at most to half the area of the μ-LED back side 12. For the present embodiment, the projection surface 13 comprises a diagonal of 4 μm and covers approximately 5% of the area of the μ-LED rear surface 12. This results in a laterally limited current path 25 within the μ-LED 9 between the first light source contact 10.2 and the second light source contact 11 formed by a section of the transparent contact layer 16, which leads to a laterally limited active zone 24. Additionally, non-radiative recombination at the edges of the active zone 24 are suppressed. To improve the lateral confinement of the current path 25, the doping of the first semiconductor layer 6 and the second semiconductor layer 7 is preferably selected such that they have a p or n conductivity of less than 10⁴ Sm⁻¹, preferably less than 3*10³ Sm⁻¹, more preferably less than 10³ Sm⁻¹. In addition, it is advantageous to select a small layer thickness SD of the first semiconductor layer 6. It is preferred that the layer thickness SD of the first semiconductor layer 6 in stack direction 8 is at most ten times and preferably at most five times the maximum diagonal MD of the first light source contact 10.1, 10.2, 10.3 in lateral direction.

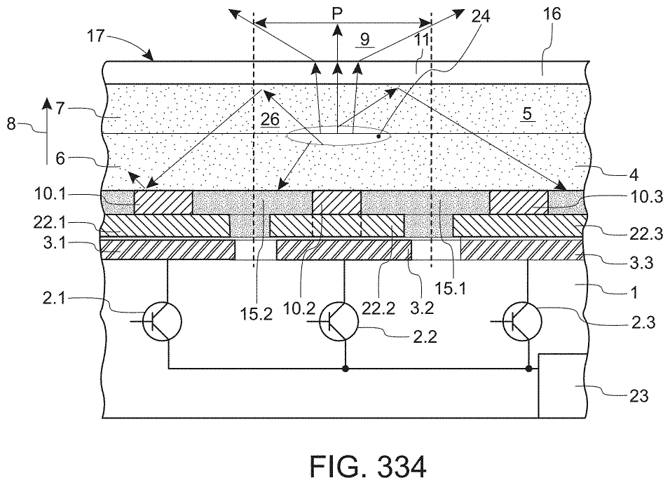

According to the invention, the first light source contact 10.2 is surrounded in a lateral direction perpendicular to the stacking direction 8 by a rear absorber 15.1, 15.2 with an optical blocking effect, the rear absorber 15.1, 15.2 preferably consisting of silicon, germanium or gallium arsenide and/or having a graphene or soot particle intercalation. From the light path 26 shown in FIG. 334 for the first embodiment, it can be seen that this measure reduces crosstalk from a driven μ-LED 9 into adjacent pixels.

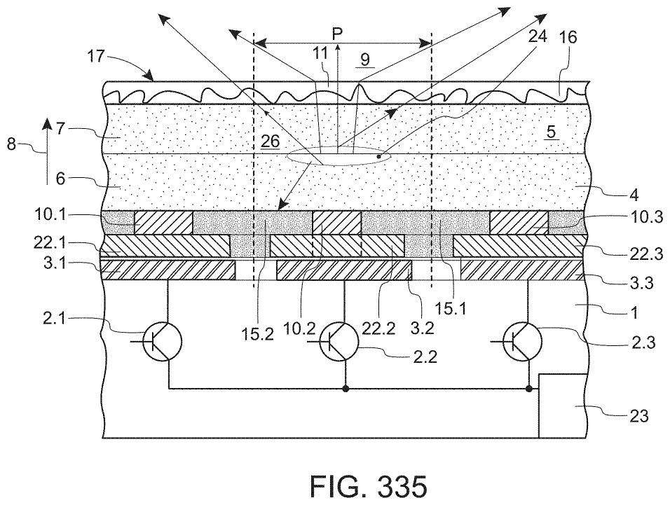

For the second embodiment shown in FIG. 335, the same reference characters are used for the components that are identical to the first embodiment. Shown are three-dimensional structures on the top of the second semiconductor layer 7, which improve the light extraction to the front side 17. It can be seen that the degree of total reflections is reduced and the output coupling cone is enlarged. For a design alternative not shown in detail, 17 Fresnel lens structures are provided on the front side. In another alternative, photonic crystal structures are arranged on the surface. Such measures are described in detail in this application. In this context, reference is made to FIGS. 223A to 223F and 225 to 247, which show various embodiments and techniques. In some of them structures are arranged above the μ-LEDs and partly extend into the active layer. Such a combination is also possible to create a constriction and localization of the recombination zone.

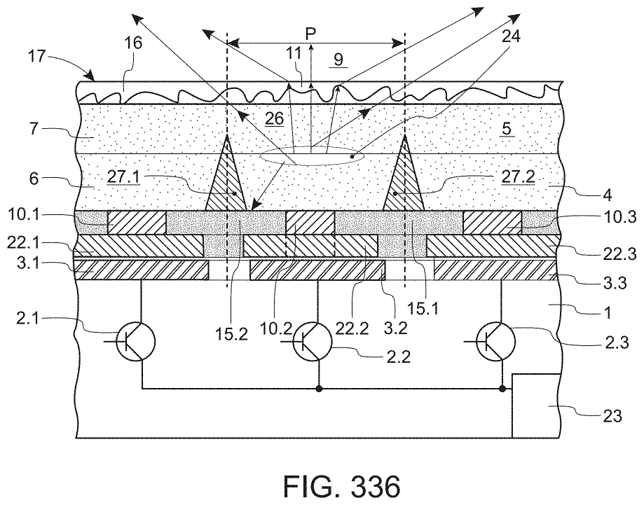

FIG. 336 shows a third embodiment with a rear absorber 15.2, 15.2, which comprises sections 27.1, 27.2 projecting into the semiconductor layer sequence 5, which additionally shield the boundary area between adjacent μ-LEDs 9. Structured elements of reflective materials such as aluminium, gold or silver or of dielectric materials whose refractive index is lower than that of the first semiconductor layers 6, 7 can be used for the subsections 27.1, 27.2. For further embodiment, subsections 27.1, 27.2 additionally improve the lateral limitation of the current path.

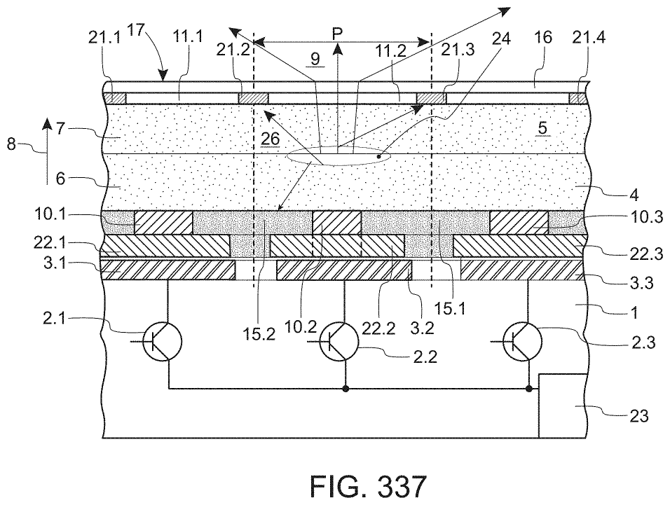

The fourth embodiment shown in FIG. 337 further reduces the optical crosstalk between adjacent μ-LEDs 9 by a frontal absorber 21.1, 21.2, 21.3, 21.4, which laterally surrounds the second light source contacts 11.1, 11.2, 11.3. If the frontal absorber 21.1, 21.2, 21.3, 21.4 is electrically insulating, the lateral restriction of the current path for the localization of the active zone 24 can additionally be improved.

For the embodiments shown in the figures, an optochip contact element 22.1, 22.2, 22.3 is arranged between the first light source contact 10.1, 10.2, 10.3 and the respectively assigned IC substrate contact 3.1, 3.2, 3.3. The cross-sectional area of the optochip contact element 22.1, 22.2, 22.3 is larger than that of the first light source contact 10.1, 10.2, 10.3, so that the monolithic pixelated optochip 4 can be contacted in a simplified manner on the IC substrate component 1.

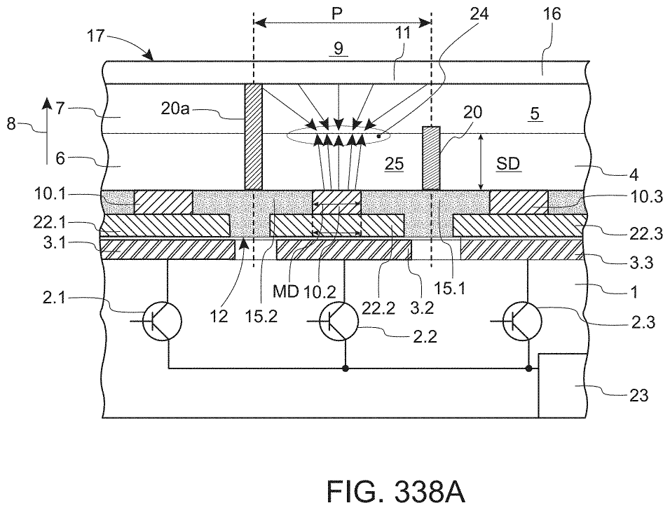

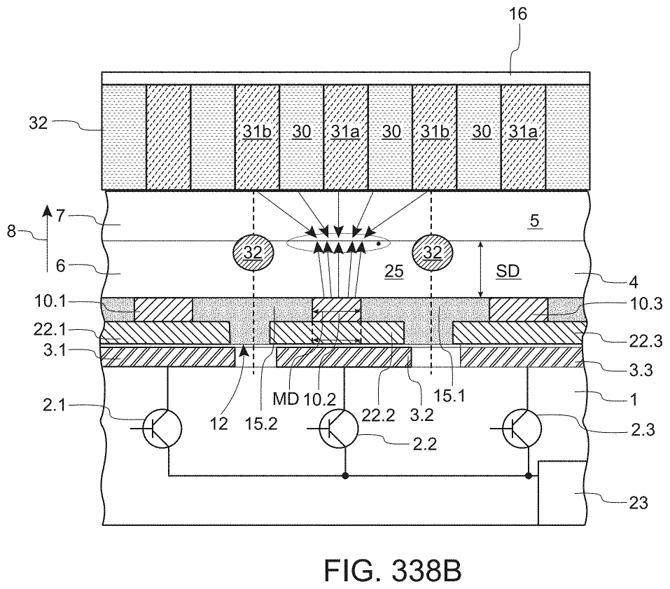

FIG. 338A shows an alternative embodiment, which is basically based on the previous example in FIG. 333. However, additional measures have been taken to reduce the current and prevent optical and electrical crosstalk. The embodiment is similar to that of FIG. 133 in this respect. In particular, a trench 20 was created between the middle and right μ-LED after the application of layers 6 and the active layer, which comprises an optically reflective but also insulating material (at least on the trench wall). The latter to avoid a short circuit between the pixels, the former to avoid optical crosstalk. Between the left and the middle pixel a larger trench is created, which essentially extends through layers 6 and 7. It forms not only an optical barrier, but also an electrical barrier between the pixels or μ-LEDs. Further aspects of this embodiment can be found in relation to FIGS. 131 to 137 and other places in this application.

FIG. 338B shows a further embodiment based on the previous examples. Identical elements carry the same reference points. In this embodiment a doping 32 is introduced in layer 6 between the individual μ-LEDs. The doping changes the band structure in this area and leads to an increase of the band gap. Injected charge carriers thereby experience a field and are kept away from this area. Together with the light source contact 10.2, effective localization is thus also achieved in the area of the recombination zone shown in FIG. 338B.

Another aspect is the photonic structure 32 on the surface of layer 16, where a transparent material 31a with a high refractive index (e.g. Nb₂O₅) is directly applied as a column or pillar over a recombination zone. Light generated in zone 24 is bundled by the column as waveguide and thus directed. Another column of the same material 31b is located in this configuration between two adjacent pixels. Between them, a transparent material with a lower refractive index is filled in. This result in a refractive index variation in lateral alignment similar to the structures described above. The periodic variation of the refractive index leads to an optical band gap. The size and shape of this band gap depends, among other things, on the periodicity, so this diagram is only an example, other periodicities are also conceivable. Such a combination of the different techniques results in a strong localization on the one hand and a good directional radiation on the other hand. Crosstalk is prevented. The IC structure and the comparatively large contacts also improve the alignment and fastening of the two layer structures.

FIG. 339A illustrates a general overview of digital and analogueue concepts of the three essential parts of a μ-LED display array with its main functionality. Sections I and II concern analogueue sections of the μ-display with a plurality of pixels arranged in rows and columns. Each pixel 141 can either consist of subpixels with different colors. Alternatively, displays with pixels of similar size can be used to obtain the different colors. The μ-LED display is implemented in this embodiment as a monolithic display comprising a first substrate carrier on or in which the μ-LED pixels are integrated. However, other designs, in particular, the designs disclosed here, are also conceivable, including the antenna slot structure and the realization of the μ-LED in bar form or in modules.

In some cases, the first substrate carrier also includes the circuit for the analogueue section II. In an alternative, the substrate of the μ-LED is thinner and comprises a large number of contacts on its underside. The contacts on the underside are then bonded or otherwise attached to a carrier that includes the analogueue section II. Alternatively, the analogueue section II can be grown on a thinned substrate that also carries the μ-LED pixels on the other side. Such an approach can reduce misalignment between the analogueue section and the μ-LED pixels. On the other hand, a material system is required that is suitable for integrating an analogueue circuit.

The analogueue section II of the arrangement contains the control for the current through the respective pixels. For this purpose, each pixel 141 with its anode contact is brought into contact with a common source potential 1411. The respective cathode of the μ-LED pixels is connected to an adjustable driver, which in this case is implemented as current source 142, which is integrated in section II and in turn connected to terminal 1412. In this design, a common anode contact is thus realized. Cover electrodes as disclosed in this application may provide such a function. However, the other case of a common cathode also exists. In this case, the μ-LED is located between cathode potential terminal 1412 and the current source. The advantage of such an arrangement is that the supply voltage can be somewhat lower and the μ-LED does not have to process a large input voltage.

Section II also includes a reference current source 1410, for example a temperature-stabilized current mirror or the like, to supply the same reference current to the respective current sources 142. While only one current source is shown in this example, multiple reference current sources may be used to provide a respective reference current for different pixels. For example, each pixel line can be assigned to a reference current source. If such reference current sources are switchable, the current sources for each row can be switched on or off periodically, thus reducing power consumption. In terms of embodiments, Section II is manufactured in polysilicon, which thus comprises a different material system than that used for the realization of the μ-LEDs in Section I.

In addition to the reference current supplied to each of the current sources 142, the current sources also include a switch input to work selectively with each current source and then separately with each pixel. Switching the current sources using PWM techniques to adjust the brightness of each pixel, as explained, further reduces overall power consumption. The PWM signal is generated in digital section III of the array.

The digital section III comprises a clock input CLK and a data input DAT. The data input DAT is coupled to 12-bit shift registers 148, which are connected in series. The shift register receives the incoming data stream and delivers a corresponding word to a 12-bit memory 147 for storage. The 12-bit memory may comprise flip-flops or a similar circuit to store the 12-bit words in memory. The memories are coupled to the other input of each comparator 144. In this way, a data stream can be used to store temporarily a whole series of brightness values in the flip-flops of memory 147.

The clock signal at input CLK defines the clock for a counter 149 that supplies a 12-bit counter word D0 . . . 11. Counter word D0 . . . 11 is applied to the respective comparators 144, which are connected to the current sources 142 of each μ-LED pixel. In an alternative embodiment, other components can also be used if necessary, for example, a combination of different gates, which check whether counter word D0 . . . 11 is smaller than the word of the memory connected to it.

When operating such an arrangement, comparator 144 compares counter word D0 . . . 11 with the memory word, i.e. the contents of the 12 bit memory. Depending on the result, for example whether the comparison with the comparator indicates whether the counter word D0 . . . 11 is larger or smaller than the memory word, the current source is switched on or off. In other words, the comparison with the comparator results in a pulse width based on the clock signal in counter 149 to operate each pixel. For example, the first pixel in the displayed chain should have a dark value, i.e. be switched off, the second pixel should have a light value or be completely switched on. The data stream then has the following relevant string of zeros and ones in two words, strung together in the form of “0000000000111111111111”. After the words are stored in one of the two memories 147 each, they are sent in inverted form to the comparator 144. The comparison is made in the comparator. As long as the counter word D is smaller than the memory word M, the driver remains switched on (in the example with the inverting comparator, “111111111111” and “000000000000” are thus compared with the counter word).

The μ-LED display array contains different parts that have different requirements and limitations, making it difficult to implement in a single semiconductor material. Nevertheless, the main challenge is the size predefined by the pixel size of the μ-LED. Transistors or other active elements in the analogueue or digital part face this limitation, which excludes certain implementations.

FIG. 339B shows another version of the three sections of a μ-LED display arrangement with its main functionality. While the first section is essentially the same as the corresponding section I of FIG. 339A, section II is slightly different. Section II now includes a DEMUX Demultiplexer, which switches between the different pixels using a higher clocked sync signal Sync. The frequency of this signal Sync has a higher frequency than the refresh rate and depends on the number of signals O1 to O3 generated by the DEMUX demultiplexer. In one configuration, the demultiplexer controls all pixels of a row or a column. In an alternative configuration, a demultiplexer can be used for each subpixel of a pixel. Combinations of these are also possible. This allows the number of necessary contact areas between section II and section III to be reduced.

Section III again comprises a multiplexer between the outputs of the respective comparators Comp. D>M and the demultiplexer of the second section II. The synchronization signal Sync is the same as for the demultiplexer in section II and is generated together. Another change compared to the execution of FIG. 339A is that the counter word (D0 . . . 11) determining the PWM modulation for the individual comparators is fed directly to the comparators individually and not jointly. In contrast to the embodiment of FIG. 339A, the implementation of a multiplexer and demultiplexer has the advantage that the number of interconnects, i.e. the number of connections between the purely digital section III and section II can be reduced. In contrast, an additional higher-frequency synchronization signal must be routed between Sections III and II via one of these interfaces.

FIG. 339C shows a functional circuit diagram of a version of a known comparator, as it can be used in parts in principle in the embodiment of FIGS. 339A and 339B. The circuit represents a 2 BIT comparator, but can be extended to several bits. In practical implementation, the inverting inputs can also be omitted. Since there is also a comparison with the counter word, it is sufficient to implement the circuit part A>B or A<B.

FIG. 339D shows a time diagram for the various counter words 1D to 3D and the memory registers as they are used to generate the output signal. The counter words D0 . . . 11 are time-shifted so that each time word starts when the previous one has passed through. With the comparator or an OR function the output signal O1 to O3 is generated, which is then fed to the multiplexer.

The μ-display arrangement comprises various parts with different requirements and limitations, making it difficult to implement in a single semiconductor material. A challenge also lies in the available space, which is essentially determined by the pixel size of the μ-LED. Transistors or other active elements in the analogueue and digital part are subject to this limitation, which excludes certain implementations.

FIG. 340A shows an exemplary sectional view of a μ-display to illustrate different aspects of contacting and wiring of the individual sections. Similar to FIG. 339A or 339B, the μ-display comprises a μ-LED section I, an analogueue section II and a digital section III. The μ-LED portion is based on GaN, InGaP or another semiconductor material capable of emitting light of blue, red or green color. The μ-LED section I comprises the common cathode or anode (+) contact layer 1411 extending on the upper surface and connecting each of the active regions of the μ-LED pixel 141. Not shown is an additional out-coupling or light-shaping structure on the surface of layer 1411, which may include photonic structures, converters or the like.

The pixels are arranged in a substrate and are optically and electrically separated from each other so that their emission does not disturb neighbouring μ-LED pixels and the pixels can be controlled separately. For example, μ-LED pixel 141 can be implemented using the current limiting doping described above. In this case, the current flow is limited to a smaller area by doping. The doping changes the band gap so that the charge carriers are effectively limited. Examples of such limitations or other structural measures to improve quantum efficiency and/or radiation characteristics are disclosed in the other sections. The pixels may also contain LED nanorods arranged in a slotted antenna structure, as also described above. Also bars or the other μ-LED structures disclosed in this application are conceivable.

The underside comprises in some areas an insulating material to prevent leakage current. The surface is shaped in such a way that area II is aligned so that the elements are mainly below the respective pixel element. Each μ-LED pixel includes a contact area facing area II, which forms the connection to area II of the μ-LED display.

The analogueue section II of the μ-display of FIG. 340A can be implemented from or based on the same semiconductor material system. For example, active and passive components used for the power sources can be implemented in GaN InGaP or InAlP systems, provided that space requirements can be met. In such cases, the forming of the components can be achieved using several conventional deposition techniques. This has the advantage that contacts of the μ-LED pixels in the interface of section I can easily be aligned with the traces within section II. Stress and strain due to different temperature coefficients can also be minimized. Alternatively, section II is formed with a different semiconductor material. For example, polycrystalline silicon or amorphous silicon structures are suitable and are understood to form small components. Both sections can be formed, aligned and joined separately.

Due to the size requirements, the alignment must be very precise, as the size of the contacts of the μ-LED can only be in the range of a few nm². As a further alternative, polysilicon material can be deposited on the lower surface layer by various growth processes to form subsequently the required circuit components. To reduce the voltage, one or more sacrificial layers can also be implemented. Furthermore, the polysilicon layer can be formed first, and then the μ-LED pixels can be formed using the desired material system. In the present example, different material systems are used for area II and I, but the expansion and other parameters are adapted so that a joint production is possible.

For this purpose, section II is manufactured with polycrystalline silicon. Polycrystalline silicon or amorphous silicon structures are well understood to form particularly small dimensioned components. For this purpose, polysilicon material is applied to a suitable carrier and the necessary components are formed in it. To reduce the thermal expansion, several intermediate or sacrificial layers are provided, which do not take over any further function, but adapt the thermal parameters by the different crystal structure. Such layers are also located between area II and area I. There a change of the material system to the material system intended for μ-LED pixel production takes place. Then the μ-LED pixels are formed.

Alternatively, all sections can be formed separately, aligned and then bonded together. Due to the size requirements, the alignment must be very precise, because the size of contacts of the μ-LED may only be in the range of a few μm².

Depending on complexity, area II as illustrated in FIG. 340A by elements 151 and interconnection layers 152 contains one or more transistors that are part of a power source or switch. Interconnection layers 152, arranged in several layers of Section II, connect the contacts on the surface of Section II to the various components in Section II. For example, contact 165s of transistor 152 is connected to the top contact via an interconnection layer and to the corresponding μ-LED. Similarly, gate contact 169, which controls transistor switching or resistor behaviour, is coupled to contact interface 153 on the bottom surface of the portion adjacent to Digital Section III.

Digital section III is based on silicon and comprises some digital circuits 170. It is normally formed separately and then electrically connected to the analogueue section II by a bonding process. Forming the digital and analogueue sections separately allows for optimized manufacturing techniques and testing of the analogueue and μ-LED sections prior to bonding to the digital section. Similar to the analogueue section, the digital section III contains some interconnections for digital and analogueue signals. Power may also be provided via the digital section III.

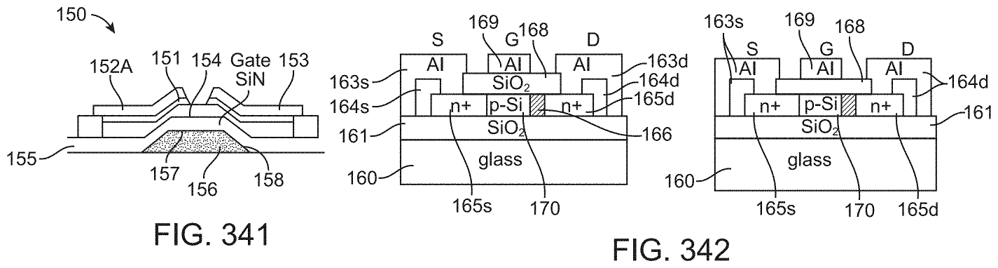

The small space available may require different setups and implementations. One aspect is the integration of transistors within the analogueue section to form the power source and control circuitry. FIG. 341 and FIG. 342 illustrate various examples of the implementation of field effect transistors with small space requirements in the semiconductor material.

FIG. 341 illustrates an inverted stacked transistor formed with amorphous silicon. The transistor has an insulating gate layer 155 formed of SiN over gate contact 156. The gate contact 156 is shaped by a small bump so that the gate layer 155 follows the bump, which has a central region 157 and two sloping sidewalls 158. A layer of amorphous silicon 154 is formed over the gate layer, thus also forming a central area and two sloped sides. The surface of the amorphous layer 154 can be highly n-doped to form a highly n-doped layer of amorphous silicon 151 with high conductivity. Alternatively, the highly n-doped layer 151 is deposited on layer 154.

Finally, a metal layer is applied to the n-doped layer 151, which also extends to the side edges of the silicon layer 154 and SiN layer 155. A gap in the metal layer and the layer 151 divides the structure and thus forms a source and a drain contact. In particular, metal layer 152 forms a drain contact, while metal layer 153 forms the source contact of the field effect transistor. The conductive channel is then formed in the polisilicon layer in the central region between source and drain. The highly n-doped polysilicon layer 151 provides a good electrical connection to the channel in layer 154. This structure allows the gate to be contacted from a side other than source and drain, taking up very little space.

FIG. 342 shows two examples of space-saving polysilicon transistors. The transistors are formed on a glass carrier with a grown SiO₂ layer as base substrate. Each transistor comprises two highly n-doped polysilicon regions 165s and 165d, separated by an undoped polysilicon layer 170, which is located between the regions 165s and 165d. Adjacent to the drain region is a lightly doped drain region 166, which is located between the polysilicon region 170 and the drain region 165d.

Alternatively, a gold-doped region 167 is formed between polysilicon 170 and drain region 165d. The source 165s, drain 165d and undoped areas 170 are then completely covered by a SiO₂ layer, which extends on the sidewalls of the areas 165s and 165d respectively. Holes are etched over areas 165s and 165d to gain access to the source and drain areas. The holes are filled with a metal, for example Al, to create electrical contacts. The contact also runs over the sidewall of the SiO₂ layer, creating a larger area for contacting. In the center above the polysilicon layer 170 a gate is formed by applying an aluminum layer 169 on top of the insulating SiO₂ layer. Gate 169 is electrically insulated from the metal contacts for source and drain.

The limited space available may also require new concepts for the implementation of control circuits. In conventional circuits for controlling LED displays, the pixels are arranged in addressable rows and columns. Each pixel consists of one LED of a certain color or alternatively of a triplet of three different LEDs. In the latter case, a pixel can also be referred to as a pixel containing three sub-pixels, each of which comprises an LED of a particular color.

Referring again to the example of FIG. 339A or 339B, FIG. 340B shows various designs for connecting μ-LED structures to digital circuit sections. The two sections can be based on different material systems or technologies. The upper first section comprises the μ-LED elements or pixels or subpixels arranged in rows and columns. Depending on the desired color, different material systems and technologies are used, for example the materials InGaN and InGaAlP. In a first example, the wafer or μ-LED structure is connected to a wafer based on crystalline silicon using a W2 W (wafer to wafer) process, which includes the digital circuit section and any necessary analogueue sections. In the example of FIG. 339B, section I is realized by the upper wafer, the lower wafer comprises sections II and III. In the second example of FIG. 340B, thin film layers of polycrystalline silicon are deposited on the bottom of the first wafer with the first section at low temperatures. This section either provides pure interconnects to connect to the digital section III or additionally houses driver circuits or other components to drive the μ-LEDs. In these two examples, the wafers are interconnected together to produce the desired display or matrix. The third example shows an alternative embodiment, in which individual chips are provided with digital circuits and are operatively connected to section II. The chips include, for example, rows and column drivers for driving parts of the display.

FIG. 344 shows an embodiment described in more detail below. In this way, individual parts of the display can be controlled separately. In addition, this type of separation during production allows individual faulty circuits to be sorted out without having to replace the entire wafer in case of a fault in one element of the digital circuit in section III.

The limited space under the analogueue sections makes new concepts for the required implementation of digital control concepts. In conventional circuits for controlling LED displays, the pixels are arranged in addressable rows and columns. The same principle can also be applied in the present case. Each pixel has one LED of a certain color or alternatively a triplet of three different LEDs. In the latter case, it can also be called a pixel if it contains three subpixels, each of which comprises a μ-LED of a certain color.

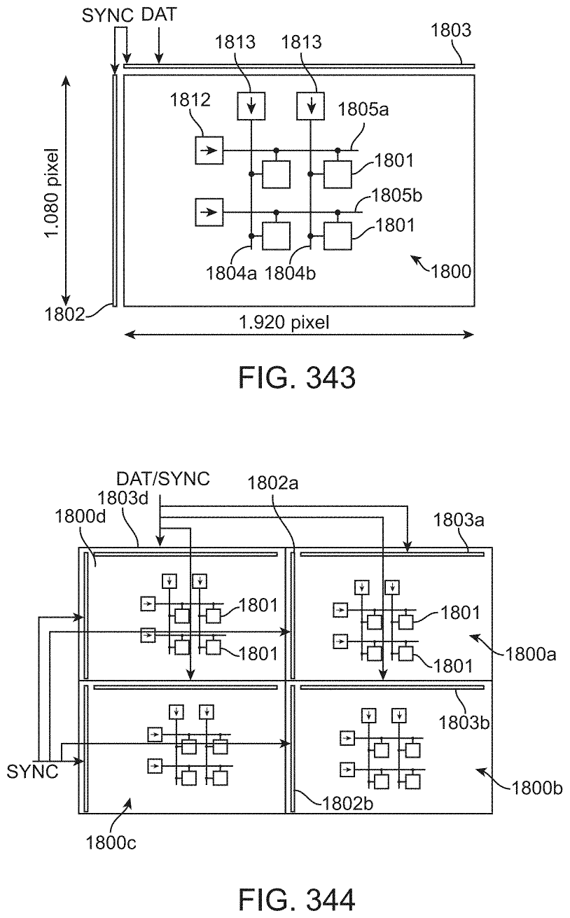

FIG. 343 shows a diagram with the elements required to address a conventional LED display. For simplicity, only one color type is shown, although each pixel contains three LEDs with different colors. The pixels are arranged in addressable columns and rows. The display comprises an 1800 pixel matrix with 1920 pixels per row and 1020 lines. The pixel matrix was constructed in a monolithic way. The display has several line drivers 1802 and several column drivers 1803 to address each pixel in the pixel matrix individually. Both driver types can be integrated into the matrix or provided as external components coupled to the matrix via an interface. A combination is also possible.

Each of the line drivers 1812 has an individual driver device that is coupled to a corresponding line 1805a, 1805b and drives the current through it. Likewise, each column driver has a driver element 1813, each driver element being connected to a data line 1804a, 1804b. Pixel drivers 1801 are located at the intersections of the rows and columns. The pixel driver 1801 is connected to the rows and columns and drives the corresponding pixel.

The display includes some control and address signals from external components, two of which are specially marked here, namely DATA and SYNC. The latter signal SYNC is used to synchronize the row and column drivers with each other to avoid artefacts and ensure clean programming. By addressing a corresponding row, the pixels connected to the corresponding row are selected. The DATA signal is then applied to the appropriate columns to program each of the pixel drivers 1801 in the selected rows.

In the case of a display with a large number of pixels, the clocking for conventional display programming can lead to high frequencies for the programming signal. For example, in the display of FIG. 343, the frequency for the programming frequency per bit and row may be several MHz depending on the color depth of each subpixel in the range. For example, with a brightness depth of 10 bits, corresponding to 1024 different illumination values, the programming frequency for 1080 display lines and a frame rate of 60 Hz is about 66 MHz.

The table below shows the frequency of the programming signal and the programming time per bit and row in μs. With increasing color or illumination depth, the PWM time units for programming and therefore the programming frequency increases.

| | | | Programming |
|---|---|---|---|
| | | Programming | frequency |
| Color bits | PWM units | time in μs | (MHz) |
| 8 | 255 | 0.06 | 17 |
| 10 | 1023 | 0.02 | 66 |
| 12 | 4096 | 0.00 | 265 |
| 14 | 16383 | 0.00 | 1062 |

The very short programming time, especially with high color or illumination bits (i.e. 12 bits or 14 bits), leads to a high load on the corresponding line and column drivers. In the extreme case of a change from white to black or vice versa of a single pixel, the column driver must reprogram (reload) the pixel in a few ns. For comparison, ultramodern DDR4 rams run at an internal frequency of about 800 MHz to 1.5 GHz, i.e. in the range of the programming frequency of 14 bit illumination depth.

In order to reduce the programming frequency, the rising and falling clock edge can be used for programming, as similarly in memories. It is also possible to segment the display and divide the display matrix into different segments. Depending on the production technology, segmentation allows individual segments to be tested separately, so that they can be replaced in the event of errors.

FIG. 344 shows an example where a display of 1920×1080 pixels is segmented into a 2×2 matrix with sub-displays. Each subdisplay 1800a to 1800d contains a pixel matrix of 960×540 pixels. Similar to the display in FIG. 343, each subdisplay comprises its own column and row drivers 1802a, up to 1802d, and 1803a to 1803d. DATA and SYNC signals are also supplied to the respective segments. The smaller number of lines reduces the programming frequency accordingly. Further segmentation of the columns as shown in FIG. 344 will also reduce the demand on the column drivers and the load with each programming cycle is reduced. The following table shows an example of programming time and programming frequency for 108 display rows per segment (there are 10 such segments in total, again with a refresh rate of 60 Hz.

| | | | Programming |
|---|---|---|---|
| | | Programming | frequency |
| Color bits | PWM units | time in μs | (Mhz) |
| 8 | 255 | 0.61 | 1.7 |
| 10 | 1023 | 0.15 | 6.6 |
| 12 | 4096 | 0.04 | 26.5 |
| 14 | 16383 | 0.01 | 106 |

As shown, the reduced number of lines due to segmentation reduces the requirements for programming time and programming frequency by roughly the factor of segmentation. Each of the segments is implemented in a similar way. Each pixel matrix 1800, 1800a to 1800d contains lines and rows on which the pixel drivers and light emitting devices are arranged.

FIG. 345 shows an example of a conventional pixel driver such as a 2T1C structure in which the current through the LED is controlled by a charge programmed during the blanking time of the display. The driver is located at the interface of a line 1805 and a data line 1804. Furthermore, a supply line 2002, which provides a supply voltage V_{DD} and a current I_{DAC}, is coupled to the light emitting device 2004 via a driver transistor 2003. The driver transistor 2003 thus operates as a controllable current source. The current through the driver transistor 2003 is controlled by the 1T1C structure 2002. In particular, a field effect transistor M2 has its gate connected to the line selection line for programming and acts as a switch.

When activated by a “HIGH” signal on the line selection line, transistor M1 closes and data line 1804 charges capacitor C1 to the desired level. During this programming, the power supply line may be switched off that the light emitting device is basically off. This will prevent various artefacts during programming. After reprogramming, transistor M2 is open again and the charge stored in the capacitor drives current transistor M1 so that a current flows through the light emitting device. The current corresponds to the stored charge and thus to the desired lighting level. FIG. 346 shows the schematic for a conventional column or data driver. The driver comprises a digital section and an analogueue section to drive the corresponding data lines. Alternatively, the output can control dedicated drivers for the data lines.

Apart from power supply connections in GND, VDD and VSS, further control signals CLK and DIR are provided. Digital values R, G and B for the different colors are stored in a buffer. They are forwarded and processed by a level shifter and then fed to a digital-analogueue converter. The DAC can also correct some values by using a separately generated correction signal Vg-cor. After conversion to analogueue signals, they are stored in an output buffer and then applied to an output buffer. The analogueue rgb signals are then applied to the data lines. Although only 3 data output lines are shown here, the column data driver provides signals for all data lines in the display matrix.

FIG. 347 shows an example of a conventional line driver. The driver comprises a shift register that receives the CLK and DIR signals and is coupled to a large number of logical AND gates via a level shifter. The gates also receive an ENABLE signal, to which the corresponding outputs in the output buffer go HIGH. During operation, the shift register shifts the bits with each CLK signal to apply selectively a HIGH signal to one of the corresponding gates. The ENABLE signal is required to activate globally line selection during reprogramming.

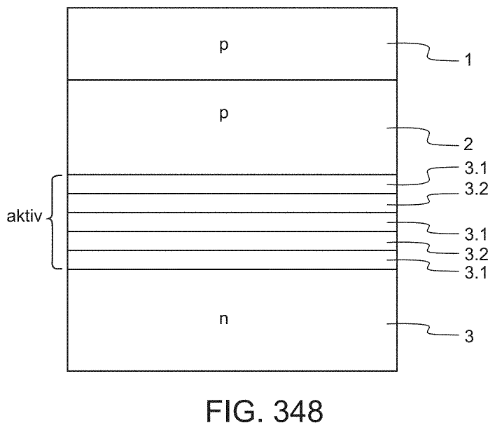

FIG. 348 generally shows a possible embodiment of a semiconductor layer stack. This comprises an n-doped layer 3, which is epitaxially deposited on a substrate not shown. The n-doped layer 3 is followed by the active region. This contains a multiquantum well structure with the quantum well layers 3.1 and 3.2. The multiquantum well structure can have a plurality of such successive layers, which are also formed with different material systems. Adjacent to this is the p-doped layer 2, followed by a current widening layer 1.

In addition to the aspects already described for the production and generation of individual μ-LEDs, monolithic arrays, pixelated arrays or μ-displays including light extraction, collimation and guidance, where the focus was on applications in the field of augmented reality, these aspects also allow further application. Examples of such can be found in the automotive sector.

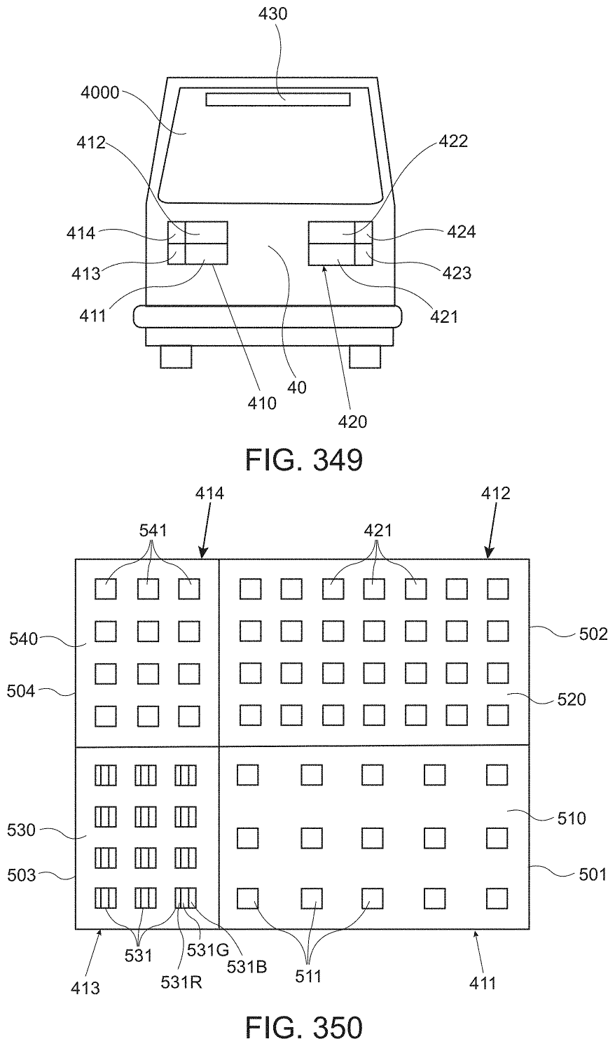

In FIGS. 349 to 351, such an application for a combined brake and tail light is shown as an exemplary vehicle component formed of μ-LED-arrays or μ-displays. This is shown in particular in a motor vehicle, which is formed by μ-LED arrays or μ-displays. The array or display is to be understood as a luminous surface rather than a display in the conventional sense for displaying information. FIG. 349 schematically shows the rear of a motor vehicle with several lights, which, according to the proposed concept, have μ-LED arrays as light sources. In particular, FIG. 349 schematically shows a left-hand rear lamp 410 and a right-hand rear lamp 420 and a raised brake light 430. The left rear lamp 410 has four spatially separated areas 411, 412, 413 and 414 for different functions of the left rear lamp 410. The first area 411 serves as a tail light, the second area 412 serves as a brake light, the third area 413 serves as a reversing light and the fourth area 414 serves as a direction indicator light.

The right combination rear lamp 420 is mirror-symmetrical to the left combination rear lamp 410 and therefore also has four spatially separated areas 421, 422, 423 and 424 for different functions of the right combination rear lamp 420. Here too, the first area 421 serves as tail light, the second area 422 as brake light, the third area 423 as reversing light and the fourth area 424 as direction indicator light.

The structure of the combination rear lamps 410, 420 is explained in more detail below using the example of the left combination rear lamp 410.

FIG. 350 shows a schematic top view of the four areas 411 to 414 of the left combination tail light 410. The tail light area 411 comprises a first μ-LED array 501. The first μ-LED array 501 has a large number of μ-LEDs 511 arranged in rows and columns on a first carrier 510, which emit red light during operation. The pixel density and spacing of the μ-LEDs 511 have preferred values of at least 50 PPI and at most 0.5 mm according to the table for the example Rear Combination Light (RCL) shown in FIG. 3B. For example, the first μ-LED array 501 may have a pixel density of 75 PPI and a pixel pitch of 0.33 mm. The brake light area 412 comprises a second μ-LED array 502. The second μ-LED array 502 also has a large number of μ-LEDs 521 arranged in rows and columns on a second carrier 520, which emit red light during operation.

The μ-LEDs 521 of the second μ-LED array 502 can be identical to the μ-LEDs 511 of the first μ-LED array 501. However, the second μ-LED array 502 has a higher pixel density and a smaller pixel pitch than the first μ-LED array 501. This means that the μ-LEDs 521 of the second μ-LED array 502 are arranged more densely on the second carrier 520 than the μ-LEDs 511 of the first μ-LED array 501 on the first carrier 510. For example, the pixel density of the second μ-LED array 502 has a value of 100 PPI and the pixel pitch is for example 0.25 mm. Due to the denser arrangement of the μ-LEDs 521, the second μ-LED array 502 generates a higher brightness during operation as a brake light than the first μ-LED array 501 during operation as a tail light. This enables the following traffic to distinguish the brake light area 411 from the tail light area 412 of combined rear light 410. In addition, the brightness for the brake light can be further increased compared to the tail light by supplying the μ-LEDs 521 of the second μ-LED array 502 during brake light operation with a higher electrical current than the μ-LEDs 511 of the first μ-LED array 501 during tail light operation.

The reversing light area 413 features a third μ-LED array 503. The third μ-LED array 503 has a large number of triples 531 of μ-LEDs arranged in rows and columns on a third carrier 530, which emit white light during operation. Each triple 531 consists of three μ-LEDs 531R, 531G, 531B, wherein the μ-LED 531R emits red light, the μ-LED 531G emits green light and the μ-LED 531B emits blue light, so that each triple 531 of μ-LEDs 531R, 531G, 531B forms a pixel of the reversing light area 413 and emits white light during operation of the reversing light. For example, the pixel density and the pitch of the triple 531 of μ-LEDs on the carrier 530 of the third μ-LED array 503 have values for the pixel density of 100 PPI and for the pixel pitch of 0.25 mm.

Alternatively, instead of the triple 531 of μ-LEDs 531R, 531G, 531B, only blue primary light emitting μ-LEDs can be used, each of which is coated with a wavelength conversion material that proportionally converts blue light from the μ-LEDs into secondary light of a different wavelength, so that the mixture of primary light and secondary light produces white light. Depending on the embodiment, the triple can be monolithic and have a shared contact terminal. Designs for such a connection are shown here. It would also be possible to provide reflective structures around each array or triplet to ensure higher directionality. Depending on the embodiment, photonic structures for collimation, lenses or other structures can also be provided.

The direction indicator area 414 comprises a fourth μ-LED array 504. The fourth μ-LED array 504 has a large number of μ-LEDs 541 arranged in rows and columns on a fourth carrier 540, which emit orange light during operation. The pixel density and the pitch of the μ-LEDs 541 on the carrier 540 of the fourth μ-LED array 504 have, for example, values for the pixel density of 100 PPI and for the pixel pitch of 0.25 mm.

Pixel density and pixel pitch are designed for all areas 411 to 414 of the combination rear lamp 410 in such a way that the observer or subsequent traffic cannot resolve the individual μ-LEDs 511, 521, 531, 541 of the μ-LED arrays 501, 502, 503, 504. Therefore, no light-scattering optics, for example in the form of a light-scattering cover lens, are required to ensure homogenization of the light. However, the individual μ-LEDs 511, 521, 531, 541 may each comprise an optical lens, in particular a microlens, for example to reduce the divergence of the light emitted by the μ-LEDs. Alternatively or additionally the μ-LED arrays 501, 502, 403, 504 may each comprise an optical lens, in particular a microlens, for example in order to reduce the divergence of the light beam emitted by the μ-LED arrays 501, 502, 403, 504 or to influence an emission direction of the aforementioned light beam.

The four carriers 510, 520, 530, 540 of the four μ-LED arrays 501, 502, 503, 504 can be mechanically connected to each other, for example by means of a plug connection. Each carrier 510, 520, 530, 540 is made of electrically insulating material and has electrical conductors (not shown) for supplying power to the μ-LEDs 511, 521, 531 and 541 arranged on it. In addition, the carriers 510, 520, 530, 540 may be electrically connected to each other to provide a common driver circuit or driving device for all four μ-LED arrays 501, 502, 503, 504.

The μ-LEDs 511 of the first μ-LED array 501 are jointly controlled and operated by means of a control device and driver circuit i.e. only jointly switched on and off and dimmed if necessary. An analogueous statement also applies to the μ-LEDs 521 of the second μ-LED array 502 and to the μ-LEDs 531 of the third μ-LED array 503 as well as to the μ-LEDs 541 of the fourth μ-LED array 504.

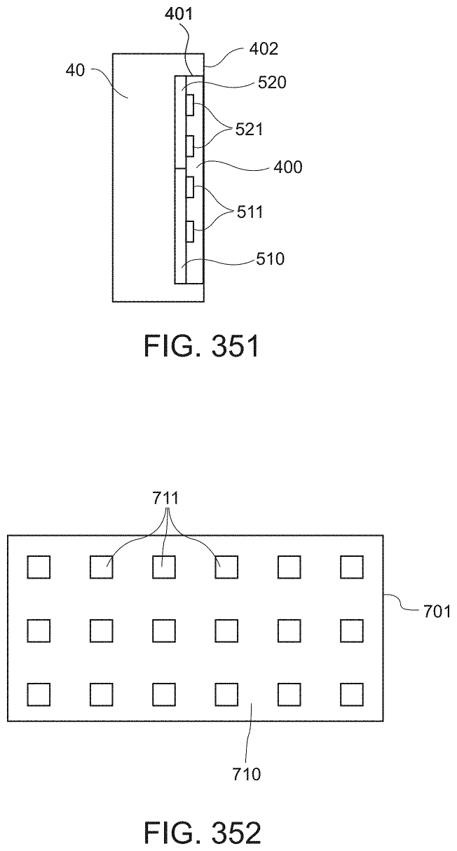

The combination rear lamp 410 is integrated into the vehicle body 40 at the rear of vehicle 4. FIG. 351 shows a schematic cross-section of this situation. FIG. 351 shows a schematic cross-section through the vehicle body 40 and the areas 411, 412 of the combination rear lamp 410. The cross-sectional plane is vertical and perpendicular to the surface of the vehicle body 40. The μ-LED arrays 501, 502, 503, 504 are arranged in a recess 401 in the vehicle body 40 on its outer surface 402, the supports 510, 520, 530, 540 of the μ-LED arrays 501, 502, 503, 504 each resting on and being fixed to the vehicle body 40 in the recess 401. The recess 401 is filled with a transparent sealing compound 400 so that any gap between the μ-LED arrays 501, 502, 503, 504 and the vehicle body 40 is filled with sealing compound 400. The outer surface 402 of the vehicle body 40 is seamlessly sealed with the potting compound 400 so that the outer surface 402 of the vehicle body 40 and the surface of the potting compound 400 form a continuous common surface and the combination rear lamp 410 does not stand out from the vehicle body 40. The carriers 510, 520, 530, 540 of the μ-LED arrays 501, 502, 503, 504 may be colored and may have the same color as the vehicle body 40, for example. This means that when the corresponding μ-LEDs 511, 521, 531, 541 are switched off, the four areas of the combination rear lamp 410 appear in the same color as the vehicle body 40. In addition, the surface of the carriers 510, 520, 530, 540 may have a high light reflectance to allow better light extraction from the combination rear lamp 410. The μ-LED arrays 501, 502, 503, 504 guarantee a luminance of at least 0.14 Cd/m2 for each of the above-mentioned lighting functions.

In the case of an alternative embodiment, areas 411 and 412 for the tail light and brake light may be formed as one unit. For example, a common μ-LED array can be provided for both applications with a pixel density of 100 PPI and a pixel pitch of 0.25 mm. For the brake light function, for example, all μ-LEDs of the common μ-LED array can be switched on. For the tail light function, for example, only half of the μ-LEDs of the common μ-LED array can be switched on, for example only every second μ-LED. Alternatively, for the taillight function, all μ-LEDs of the common μ-LED array can be operated in a dimmed state with reduced brightness.

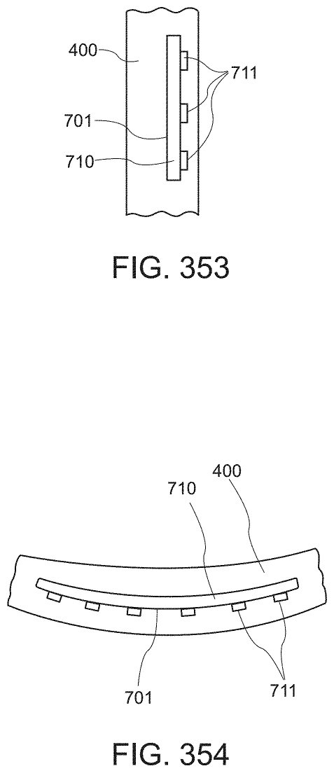

FIGS. 349 and 352 to 354 schematically show details of a raised brake light 430. The raised brake light 430 is integrated in the rear window pane 4000 of the motor vehicle, for example. FIG. 352 shows a schematic top view of a μ-LED array 701 of the raised brake light 430. FIG. 353 shows a cross-section through the rear window pane 4000 and the raised brake light with a vertical cross-sectional plane. FIG. 354 shows a cross-section through the rear window pane 4000 and the raised brake light with horizontal cross-sectional plane. The raised brake light 430 has a μ-LED array 701, which has a carrier 710 with μ-LEDs 711 arranged in rows and columns on the carrier 710. According to the table in FIG. 3B, the pixel density and pixel pitch for the application of μ-LED arrays in “CHMSL” high mounted brake lights have preferred values of at least 10 PPI and at most 2.5 mm. For example, the pixel density of μ-LED array 701 has a value of 100 PPI and the pixel pitch is 0.25 mm, for example. This means that the raised brake light 430 can also be used to display information, such as warnings, etc. The μ-LEDs 711 emit red light during operation of the raised brake light 430.

The μ-LED array 701 is completely embedded in the material of the rear window 4000. For example, the μ-LED array 701 is arranged between two glass layers of the rear window 4000. The carrier 710 of the μ-LED array 701 is transparent and adapted to the curvature of the rear window pane 4000 so that the raised brake light 430 is transparent when switched off. Conductor tracks (not shown) are arranged on the carrier 710 for electrical contacting of the μ-LEDs 711. In addition, 4000 conductor tracks for the electrical contacting of the μ-LED array 701 are integrated into the rear window pane. The conductor tracks are made of transparent material such as ITO or are metallic and so thin that they are invisible to the human eye. The luminance of the μ-LED array 701 is at least 0.14 Cd/m2.

Alternatively, the raised brake light can be integrated into the vehicle body instead of into the rear window pane 4000 in the roof area of the vehicle and the μ-LED array 701 can be designed analogueous to the μ-LED array 502 in this case.

Due to the high pixel density, warnings or other information can also be transmitted to following road users by means of the raised brake light. For example, the raised brake light can be coupled to a device with an acceleration sensor and display the warning message “Emergency braking” in the event of an abrupt sharp braking of the vehicle. In addition, the raised brake light can also be coupled to a device with a distance sensor, which detects the distance to the following vehicle and displays a corresponding warning message depending on the vehicle speed if the vehicle falls below a safety distance.

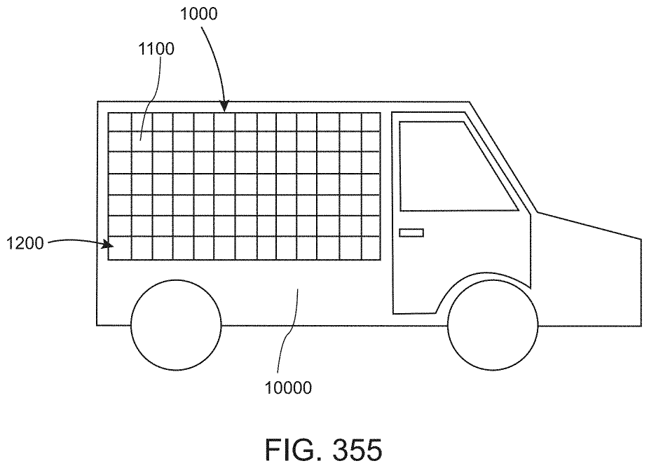

According to another embodiment schematically shown in FIGS. 355 to 357, several, preferably a large number of μ-LED arrays are combined to form a display 1000, which is arranged on the outside of a motor vehicle and is integrated into the body of the motor vehicle, for example.

FIG. 355 schematically shows the right side of a motor vehicle with a display 1000 embedded in the vehicle body. The display 1000 is formed by a large number of similar μ-LED arrays 1100, which are arranged in rows and columns and are mechanically and electrically interconnected. The display 1000, for example, has a rectangular contour as shown schematically in FIG. 355. However, any other contour is also possible.

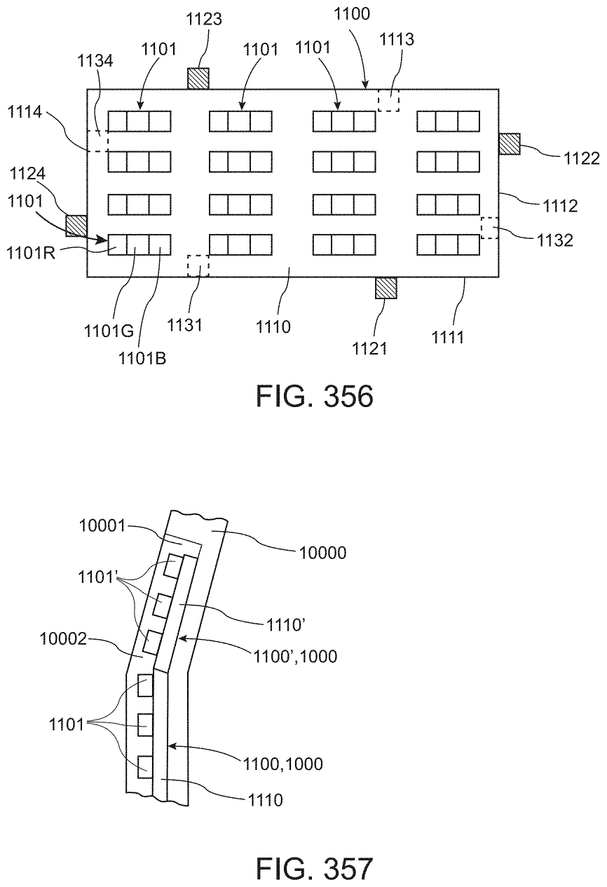

Each μ-LED array 1100 features a large number of triples 1101 of μ-LEDs 1101R, 1101G, 1101B, which are arranged in rows and columns on a common carrier 1110 of the respective μ-LED array 1100. FIG. 356 shows a schematic top view of a μ-LED array 1100 of the display 1000. Each pixel of the μ-LED array 1100 is formed by a triple 1101 of μ-LEDs 1101R, 1101G, 1101B. Each pixel of the μ-LED array 1100 thus comprises a red light emitting μ-LED 1101R, a green light emitting μ-LED 1101G and a blue light emitting μ-LED 1101B. The triples 1101 of μ-LEDs 1101R, 1101G, 1101B are arranged in rows and columns on the carrier 1110 of μ-LED array 1100.

The carrier 1110 is made of electrically insulating material and is equipped with electrical contacts (not shown) for the μ-LEDs 1101R, 1101G, 1101B and electrical tracks (not shown) for power supply and control of the μ-LEDs 1101R, 1101G, 1101B. In addition, electronic components for the operation of the μ-LEDs 1101R, 1101G, 1101B can be arranged on the carrier 1110 or in the carrier 1110. The carrier 1110, for example, comprises a rectangular contour with four side edges 1111, 1112, 1113 and 1114. At each side edge 1111, 1112, 1113, 1114 a projection 1121, 1122, 1123, 1124 and a recess 1131, 1132, 1133, 1134 are arranged mirror-symmetrically to a centerline of the carrier 1110 so that a projection 1121 of the carrier 1110 of one μ-LED array 1100 fits into a recess 1134 of the carrier 1110 of an adjacent μ-LED array 1100. By arranging the projections 1121, 1122, 1123, 1124 and recesses 1131, 1132, 1133, 1134 along the side edges 1111, 1112, 1113, 1114 of the carrier 1110, as shown schematically in FIG. 356, the carriers 1110 of the μ-LED arrays 1100 can be seamlessly joined together to form the display 1000. The projections 1121, 1122, 1123, 1124 and recesses 1131, 1132, 1133, 1134 can be used to provide an electrical connection between the μ-LED arrays 1100 of the display 1000 in addition to the mechanical connection.

FIG. 357 schematically shows a cross-section with a vertical cross-sectional plane through the car body 10000 of the motor vehicle and the display 1000. The display 1000 is located in recess 1501 on the outside of the vehicle body 10000. It adapts to the contour of the vehicle body 10000. The carriers 1110, 1110′ of the μ-LED arrays 1100, 1100′ of the display 1000 are located in the recess 10001 on the vehicle body 10000. Carriers 1110, 1110′ of adjacent μ-LED arrays 1100, 1100′ of the display 1000 can form an angle different from 0 degrees or 180 degrees with each other in order to adapt the display 1000 to the contour of the vehicle body 10000, as shown in FIG. 357 as an example and schematic.

The dimensions of the μ-LED arrays 1100, 1100′ or their carriers 1110, 1110′ can be different, for example to allow a better adaptation of the display 1000 to the contour of the vehicle body 10000. In particular, μ-LED arrays 1100, 1100′ or carriers 1110, 1110′ of μ-LED arrays 1100, 1100′ may be provided with smaller dimensions in curved areas of the vehicle body 10000 covered by the display 1000 than in non-curved areas of the vehicle body 10000 covered by the display 1000. Any spaces in the recess 10001 between the display 1000 and the vehicle body 10000 may be filled with transparent potting compound 10002.

The outer surface of the vehicle body 10000 is seamlessly sealed with the potting compound 10002, so that the outer surface of the vehicle body 10000 and the surface of the potting compound 10002 form a continuous common surface and the display 1000 does not stand out from the vehicle body 10000. The μ-LED triples 1101, 1101′ of the μ-LED arrays 1100, 1100′ can each have micro-optics (not shown), for example to enable better light extraction. The carriers 1110, 1110′ of the μ-LED arrays 1100, 1100′ of the display 1000 can be colored and for example have the same color as the car body 10000. The display 1000 is connected to a control device (not shown) for controlling the display 1000 and an operating device (not shown) for supplying power to the display 1000, whereby the control device can be a component of an on-board computer of the motor vehicle and by means of the operating device the power supply of the display 1000 is carried out from the on-board voltage of the motor vehicle.

The driving device is configured in such a way that individual μ-LED arrays 1100, 1100′ of the display 1000 and also individual μ-LEDs of a μ-LED array 1100 or 1100′ can be driven separately so that the entire screen area of the display 1000 or only selectable parts of the screen area of the display 1000 can be used. The operation of the display 1000 by a user is carried out by means of an operating module (not shown), which is located, for example, inside the motor vehicle and is integrated, for example, in the center console of the motor vehicle. Alternatively or additionally, the display 1000 can be operated with the aid of a smartphone and a corresponding smartphone app.

As listed in the table in FIG. 3B, a minimum pixel density of 100 PPI and a maximum pixel pitch of 0.25 mm are appropriate for the “Exterior Advertisement good resolution” application. For a decoration style displays application, a minimum pixel density of 50 PPI and a maximum pixel pitch of 0.5 mm is appropriate. For a pedestrian communication application, a pixel density of at least 25 PPI and a pixel pitch of no more than 1.0 mm are appropriate. For the “exterior advertisement” application, a pixel density of at least 25 PPI and a pixel pitch of 1.0 mm or less is also appropriate. The pixel density of the μ-LED arrays 1100, 1100′ and thus also of the entire display 1000 is, for example, 150 PPI and the pixel pitch is, for example, 0.17 mm in order to be able to use the display 1000 for all four applications mentioned above. For an observer looking at the display 1000 at a distance in the range of approx. 0.5 m to 20 m, a display 1000 with high resolution is thus guaranteed. At this distance, the viewer cannot distinguish individual pixels 1101, 1101′ of the display 1000 with the naked eye.

The entire image area of the display 1000 or only a part of the image area of the display 1000 can be used for decorative purposes, for example, by driving either all μ-LED arrays 1100, 1100′ or only a part of the μ-LED arrays of the display 1000 by means of a driving device (not shown), which may for example be part of an on-board computer of the motor vehicle, and an operating device for operating the μ-LED arrays 1100, 1100′ or the μ-LEDs 1101R, 1101G, 1101B. For example, individual μ-LEDs 1101R, 1101G, 1101B of some selected μ-LED arrays 1100, 1100′ can be driven and operated by means of a driving device (not shown), which for example can be part of an on-board computer of the motor vehicle, in order to produce a desired lighting design on the vehicle body 10000.

For example, the user can use the control module to select a desired design from a pool of available designs stored, for example, in a data memory. The design is generated by the control unit, which controls the μ-LEDs 1101R, 1101G, 1101B required to generate the design from some or all μ-LED arrays 1100, 1100′ of the display 1000. For example, the μ-LEDs 1101B of the μ-LED arrays 1100 arranged in a row 1200 of the display 1000 can be switched on by means of the driving device in order to create a blue illuminated trim on the vehicle body 10000. In particular, a data memory which is, for example, part of the control device or of the on-board computer or is available via an Internet connection, may contain numerous designs which can be selected by the user of the motor vehicle by means of the control module and which can be generated on the outside of the vehicle body 1500 by means of some μ-LED arrays 1100, 1100′ of the display 1000, selected under program control by the control device. Alternatively, all μ-LED arrays 1100, 1100′ of the display 1000 can also be controlled, for example to display a panoramic image or similar on the vehicle body 10000. It may also be provided that the data memory can be updated via an Internet connection, for example to supplement or update the stock of available designs.

The entire image area of the display 1000 or only a part of the image area of the display 1000 can be used for advertising purposes, for example, by controlling either all μ-LED arrays 1100, 1100′ or only a part of the μ-LED arrays of the display 1000 with the aid of a control device (not shown), which may be a component of an on-board computer of the motor vehicle, for example. For example, the display 1000 can be used to show advertising films or to display only static or animated advertising posters. The advertising films or advertising posters can be selected by the user, for example, by means of the operating module and played back with the aid of the control unit or the on-board computer, or loaded and played back from a data memory under software control. The data memory may be part of the control device or the on-board computer or may be connectable to the control device or the on-board computer via an Internet connection, for example, to enable download or updating of the advertising content.

For communication with other road users, a display in accordance with the display 1000 described in more detail above is suitably located in the front and/or rear of the motor vehicle. For example, in accordance with display 1000 described in more detail above, the display is located in the front area between the front headlights or on the bonnet of the motor vehicle, for example to enable communication with pedestrians. Alternatively or additionally, a display as described above in display 1000 can be located in the rear of the vehicle, for example to enable communication with following road users.

In particular, a display according to the display 1000 described in more detail above, which is located in the front area of the motor vehicle, may additionally have sensors or detectors which are arranged, for example, on the carriers 1110 of the μ-LED arrays 1100 in a space between the μ-LED triples 1101 and which, for example in connection with an on-board computer of the motor vehicle, serve to monitor the traffic situation so that, for example, a pedestrian crossing and the presence of pedestrians who wish to use it can be detected. In this case, it is possible, for example by means of the display 1000 in the front area of the motor vehicle and by means of a control device for the display as well as by means of the on-board computer, to give an indication to the pedestrians whether their presence has been detected by an autonomously driving motor vehicle or by the driver of the motor vehicle and whether the motor vehicle will stop at the pedestrian crossing or not.

If the display located in the front part of the motor vehicle is used only for communication with other road users and for decorative purposes, the display may have a lower pixel density and a larger pixel pitch than the display 1000 located on the side of the vehicle. For example, a display located at the front of the motor vehicle may have a pixel density of 50 PPI and a pixel pitch of 0.5 mm.

A display arranged in the rear area of the motor vehicle, which is configured in accordance with the display 1000 described above, can in particular also additionally have sensors or detectors which are arranged, for example, on the carriers 1110 of the μ-LED arrays 1100 in a space between the μ-LED triples 1101 and which, for example, in connection with an on-board computer of the motor vehicle, serve to monitor the traffic situation, for example to warn following road users of dangers. For example, it is possible to indicate that the safety distance is too small, that there are obstacles on the road, etc. If the display located at the rear of the motor vehicle is used only for communication with other road users and for decorative purposes, the display may have a lower pixel density and a greater pixel pitch than the display 1000 located on the side of the vehicle. For example, a display located at the rear of the motor vehicle may have a pixel density of 50 PPI and a pixel pitch of 0.5 mm.

In addition, displays in accordance with display 1000 described above may be arranged in both the front and rear areas of the motor vehicle, which also have sensors and detectors and are used in conjunction with an on-board computer of the motor vehicle to monitor the traffic situation. With the aid of these displays, information in the form of displays or coded light signals can be passed on from vehicle to vehicle, for example. For this purpose, the displays located in the front and rear areas of the motor vehicle can be advantageously equipped with additional μ-LED arrays, which are equipped with μ-LEDs emitting infrared radiation, so that communication between the vehicles is made possible, for example with the aid of coded infrared signals that are not visible to human observers.

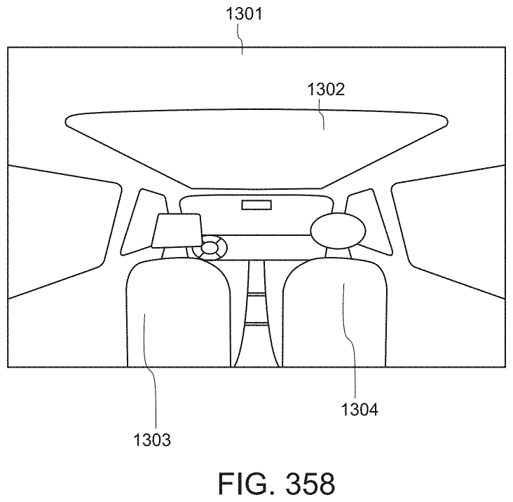

FIG. 358 shows a schematic example of the application of the present invention. FIG. 358 shows the interior of a vehicle 1300 suitable for the transport of persons. A vehicle roof 1301 is formed in the upper part of vehicle 1300. Inside the vehicle roof is an output device comprising a headliner 1302.

According to one aspect of an embodiment, the headlining extends at least partially over the vehicle roof. According to one aspect of an embodiment in FIG. 358, the headliner 1302 extends almost completely over the vehicle roof 1301. The headliner 1302 extends over the rear and front parts of the passenger compartment and from the rear seat (not shown) to the front seats, i.e. the driver's seat 1303 and the passenger's seat 1304. The light emitted by the headliner 1302 illuminates at least partially the passenger compartment of the vehicle and in particular the seats inside the vehicle. The size of the headliner 1302 may, as a rule, have a minimum size of approximately 70×40 cm and a maximum size of approximately 200×180 cm.

These sizes may vary according to the size of the vehicle, in particular the size of the vehicle roof. The typical resolution of a headliner can generally be greater than or equal to 50 PPI or less than or equal to 508 PP ([μm]), which is approximately equivalent to a medium resolution (see also FIG. 3B).

The headliner 1302 is connected to a recording device via a control device, which is not shown in FIG. 358. The headliner 1302 can be controlled via the pick-up device. The headlining 1302 is suitable for controlling the visual atmosphere inside the vehicle. The desired effect and visual atmosphere can be specified via the recording device.

The headliner 1302 is suitable for shining light into the vehicle interior and thereby illuminating the vehicle interior. This lighting can be influenced and regulated by means of visible and non-visible light and thus influences the atmosphere inside the vehicle. It is generally known that visible light with different wavelengths also has different effects on human perception. For example, light with a high blue component has the effect that people who are exposed to this light can concentrate better and gain increased attention. In contrast, subdued or reddish colored light can make it easier for people exposed to this light to relax.

In the example of the headliner 1302 shown in FIG. 358, it is configured as a display. The display can be flat. Alternatively, the display can have a free-form design, which, for example, reproduces the shape of the vehicle roof and thus fits snugly to it. In an embodiment not shown, the headlining 1302 itself forms the vehicle roof. According to another aspect, the headliner 1302 is transparent. For persons inside the vehicle, it is thus possible to look out of the vehicle and look up into the sky. In other words, light from outside can shine into the vehicle interior.

According to an embodiment not shown, the vehicle roof can be covered with material from the inside. According to one aspect of an embodiment, the μ-LEDs may be incorporated into the material. The material may include leather or other porous material. In this case, the μ-LEDs can be arranged in the pores of the material. The material can include fabric (also called knitted and/or warp-knitted fabric). According to one aspect of an embodiment, the μ-LEDs may be arranged within the loops that form a fabric. According to one aspect of an embodiment, the μ-LEDs can be distributed over the entire roof of the vehicle. According to one aspect of an embodiment, the μ-LEDs can be distributed throughout the entire vehicle interior. According to one aspect of an embodiment, the μ-LEDs can be distributed in a network over the entire vehicle interior.

Center consoles can serve as a central control element for setting various parameters. They can usually be located on the dashboard of a vehicle and can visually separate the driver's area from the passenger area. Examples of the adjustable parameters mentioned above may include settings of the vehicle's chassis and/or settings of the air conditioning or climate control systems.

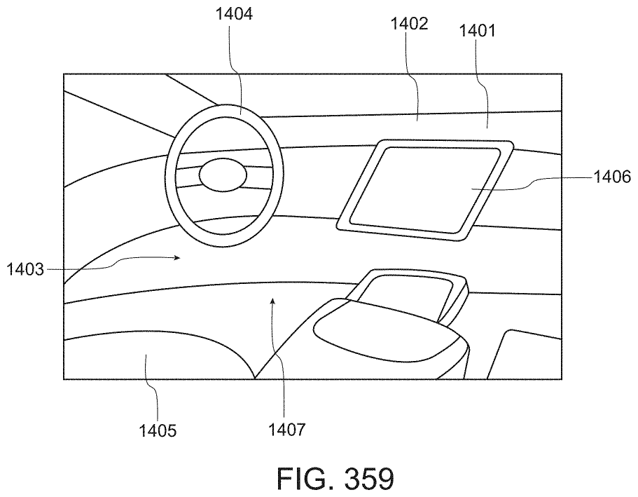

FIG. 359 shows an example of a center console 1401 inside a vehicle 1403, which can be mounted on a dashboard 1402. FIG. 359 shows the front part of the car in particular. It shows a schematic representation of the steering wheel 1404 and seat 1405 including the driver's footwell 1407 (driver's side). The center console may include a display 1406, which, according to the present embodiment, has several μ-LEDs or μ-LED arrays. The 1406 display can be set up to display a graphical interface. According to the embodiment shown in FIG. 359, the center console 1401 is located at the level of the steering wheel 1404. According to one aspect of an embodiment, the center console may extend across the entire dashboard. In particular, the area of the center console that represents a graphical interface may extend at least partially or completely across the dashboard.

Typical sizes of a display can be at least 12×9 cm and at most 40×25 cm. The resolution can be at least 200 PPI or less than or equal to 127 PP [μm]. Usually the driver may be about 40-70 cm away from the display, so that he cannot see the individual μ-LEDs at the resolution mentioned above.

According to one aspect of an embodiment, one or more sensors can be placed on recording devices that are capable of recording information. According to one aspect of an embodiment, the recording devices, in particular the sensors, can be arranged between μ-LEDs. The information may include, for example, contactless gestures, mechanical pressure on the center console, touches and gestures on the center console, ambient light intensity, temperature, humidity and/or other parameters of the passenger compartment. According to one aspect of an embodiment, the μ-LED can be applied/arranged directly on the dashboard.

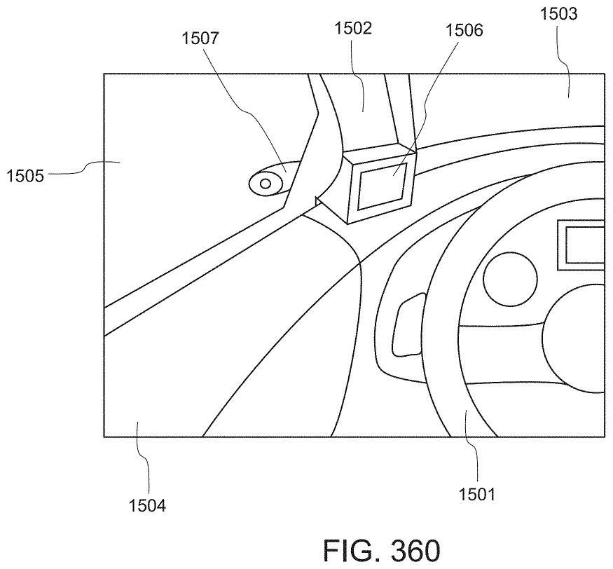

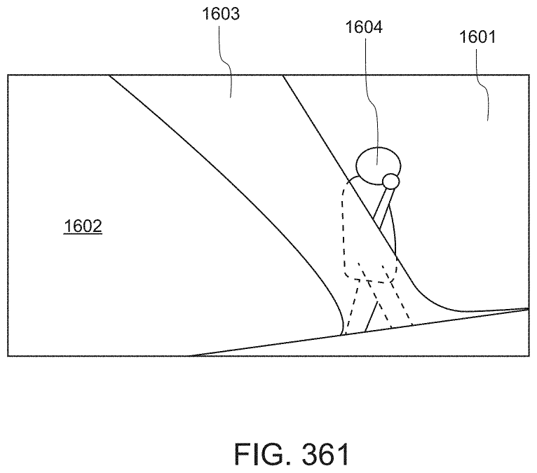

The A-pillar, the B-pillar, the C-pillar and the D-pillar of a vehicle may be configured to connect the vehicle roof to the vehicle floor. FIG. 360 shows schematically and in extracts the interior of a vehicle from the driver's perspective. FIG. 360 shows the steering wheel 1501, the A-pillar 1502, the windscreen 1503 and the side door 1504 with the window pane 1505. The A-pillar 1502 at least visually separates the windscreen 1503 from the window pane 1505.

An output device in the form of a display 1506 is arranged on the A-pillar 1502. The display 1506 is connected in terms of signal technology via a non-displayed control unit with a recording device in the form of a camera 1507. The camera is arranged outside the vehicle and is aligned in such a way that it records signals and images from the rear of the vehicle. After the signals and images have been processed by the control unit, they are shown on the display 1506. In this way, the rear of the vehicle can be shown on the display 1506. In this way, the exterior mirror of the car can be replaced by the camera display system.

A system to replace a wing mirror can typically have a minimum size of 12×8 cm and a maximum size of 20×15 cm. The resolution can be greater than or equal to 200 PPI or less than or equal to 127 PP [μm]. The display 1506 may include μ-LEDs or μ-LED arrays and may be suitable for image reproduction. According to one aspect of an embodiment, the display 1506 may have a shape that matches the shape of the A-pillar 1502.

According to one aspect of an embodiment, the image reproduction can also be used for reproduction as a rear-view mirror substitute. For this purpose, a recording device is also connected to an output device via a drive, whereby the output device can be located in the area where the rear-view mirror of a vehicle is usually located.

Output devices, which serve as a substitute for rear-view mirrors may be of a minimum size of 15×10 cm and a maximum size of 30×15 cm. The resolution may be greater than or equal to 250 PPI or less than or equal to 102 PP [μm].

FIG. 361 schematically shows a further aspect of the present concepts. The figure shows the interior of a vehicle from the driver's perspective. FIG. 361 shows a windscreen 1601, a window pane 1602 and an A-pillar 1603, which at least optically separates the windscreen 1601 from the window pane 1602. In the background a person 1604 is also visible.

Conventional vehicle pillars obscure a considerable part of the driver's field of vision. Behind these pillars is the so-called blind spot, which the driver regularly cannot see. Persons or objects located in these blind spots cannot be visually detected by the driver and are potential sources of danger.

According to one aspect of the present concepts, the output device extends at least partially across the A-pillar. According to one aspect of an embodiment of the present invention, the output device extends at least partially over a B-pillar, a C-pillar and/or a D-pillar. According to the embodiment in FIG. 361, the dispenser is integrated into the A-pillar 1603. The dispenser may comprise the A-pillar, the B-pillar, the C-pillar and/or the D-pillar. The dispenser comprises μ-LEDs or μ-LED arrays arranged on a support whose shape corresponds to the shape of the vehicle columns, according to one aspect of an embodiment. According to one aspect of an embodiment, the μ-LEDs or μ-LED arrays may be arranged on the column itself.

According to one aspect of an embodiment, the output device on columns reproduces an image corresponding to the area covered by the column in question from the driver's point of view.

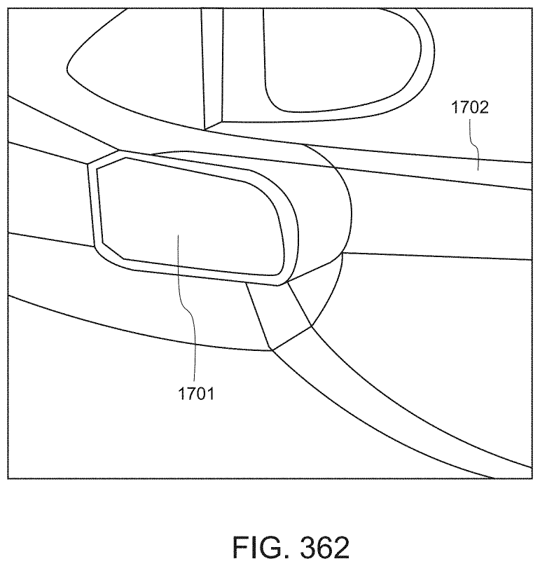

FIG. 362 shows a status display 1701 located inside a car door 1702. This status display 1701 is configured to display vehicle information in a predetermined way. For this purpose, the display comprises μ-LEDs or μ-LED arrays arranged on a carrier, which in this example is adapted to the contour of the vehicle door 1702. According to one aspect of an embodiment, the status display can be arranged at any position within the vehicle. Typical sizes for such displays can be approximately 1×0.5 cm or a maximum of 6×6 cm. The resolution can be greater than or equal to 200 PPI or less than or equal to 127 PP [μm].

A μ-LED array with μ-LEDs that emit UV radiation during operation can be used, for example, to disinfect liquids, especially water. In particular, the units described in the section entitled “Smart Dust”, which comprise μ-LED arrays, can be used advantageously for the disinfection of liquids due to their encapsulation, which provides protection against environmental influences.

A μ-LED array with μ-LEDs that emit colored or white light during operation can be embedded or woven into textiles, for example, to achieve lighting or design effects or to display or indicate information by means of light. In particular, the units described in the section entitled “Smart Dust”, which comprise μ-LED arrays, can be used advantageously in textiles due to their encapsulation, which provides protection against environmental influences.

A μ-LED array can be configured together with an operating circuit to operate the μ-LEDs as a unit. The operating circuit may include an integrated circuit (IC). The integrated circuit may be a programmable or program-controlled integrated circuit. In addition, a μ-LED array may also include one or more microscopic sensors with similar or different functions that communicate wirelessly. For example, data from the aforementioned sensors may be transmitted wirelessly to an external device for evaluation, i.e. located outside the μ-LED array. Alternatively or additionally, the data of the aforementioned sensors can also be evaluated internally by the integrated circuit of the μ-LED Array and used to control the μ-LED. Furthermore, a μ-LED Array may also include an energy storage device for the energy supply of the μ-LEDs of the μ-LED Array and, if necessary, also for the energy supply of the aforementioned microscopic sensors. The energy storage device can be configured to be inductively chargeable. The energy storage device and the aforementioned sensors may be arranged on a common carrier with the μ-LEDs of the μ-LED array.

The aforementioned μ-LEDs or μ-LED arrays containing μ-LED units are each microscopically small. The dimensions of these units in each spatial direction are preferably less than or equal to 1 millimetre. Since these units have their own energy storage, they are largely self-sufficient and can be provided with a gastight or water-tight envelope or encapsulation. If required, the energy storage unit can be charged by inductive coupling to an external energy source. The units described in this paragraph are also referred to as smart dust light emitters.

The application examples shown here, especially in a motor vehicle, require partially curved or at least non-planar and straight surfaces. Therefore, it seems appropriate to use the manufacturing techniques and components or structures disclosed in this application to buily curved displays.

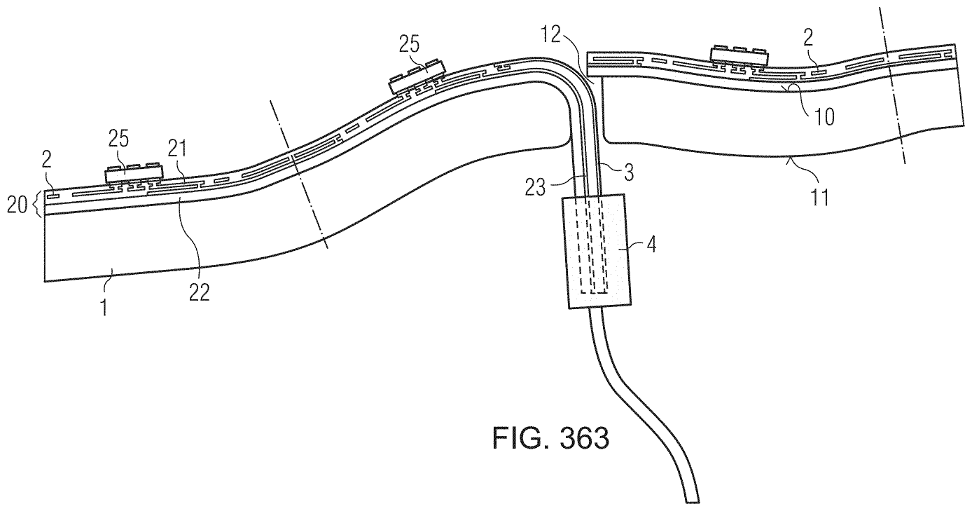

FIG. 363 shows a first embodiment of a cross-sectional view of a display device. The display device comprises a support 1, for example made of plastic or glass or metal, with a front side 10 and a rear side 11. An opening 12 extends through the support 1. Two display segments 2 are attached to the front side 10. The display segments 2 each comprise a substrate 20 on which several optoelectronic components 25 are arranged. The optoelectronic components 25 are each μ-LEDs or μ-LED arrays or modules with μ-LEDs, which can be individually and independently controlled during operation and emit radiation in the visible spectral range. The μ-LEDs or μ-LED arrays or modules with μ-LEDs are arranged in pixels. In this example, each pixel comprises three subpixels that emit different colors during operation.

The substrates 20 of the display segments 2 each comprise a connection layer 21 and an electrically insulating layer 22. The optoelectronic components 25 are electrically connected to the connection layer 21. The electrically insulating layer 22 is located between the connection layer 21 and the substrate 1. The electrically insulating layer 22 consists, for example, of an organic material such as polyimide. In particular, the electrically insulating layer 22 has a single cohesive structure and is free of interruptions or vias. The substrates 20 are therefore only provided with electrical lines on one side each, namely in the area of the connection layer 21. No electrical lines are provided on a side of the electrically insulating layer 22 facing away from the connection layer 21 and between substrate 1 and the electrically insulating layer 22.

FIG. 363 shows that the front 10 of support 1 comprises a curvature. The display segments 2 are configured to be flexible or bendable and fit snugly on the front 10. The left display segment 2 comprises a lug 23, which is passed through the opening 12 in the support 1. The lug 23 forms an electrical line 3, via which the display segment 2 can be electrically contacted from the rear side 11 of carrier 1. In this case, the part of the lug 23, which protrudes from the rear side 11 is plugged into a connector 4, such as a Flexible Printed Circuit connector or Zero Injection Force connector, and thus electrically connected.

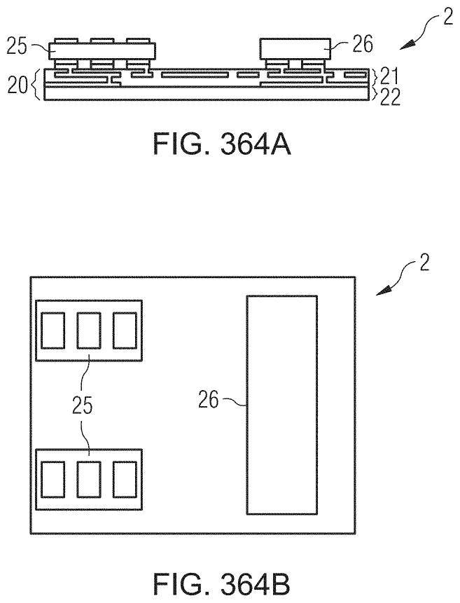

FIGS. 364A and 364B show an embodiment of a display segment 2 in cross-sectional and top view. The display segment 2 can again be flexible or bendable. In this example, two optoelectronic components 25 and one electronic component 26, for example an IC chip, are arranged on display segment 2. Such display segment 2 can be used for the display device of the present invention.

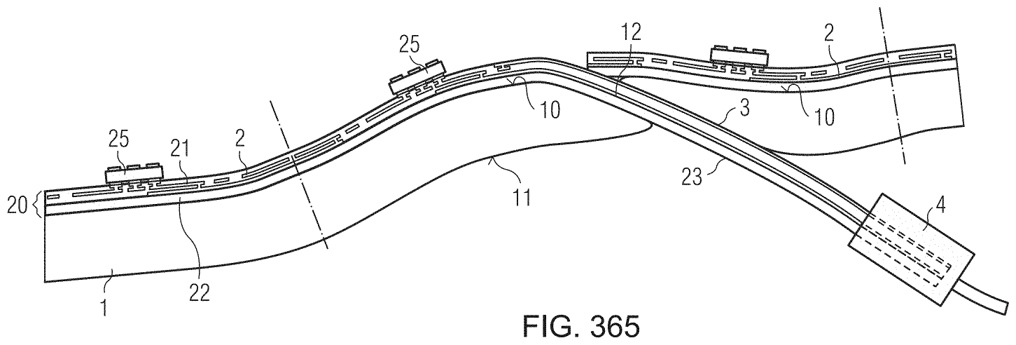

FIG. 365 shows a second embodiment of a display device in which the opening 12 in support 1 extends through support 1 at a flat angle. Accordingly, the lug 23 of the substrate 20 needs to be bent less when passing through support 1.

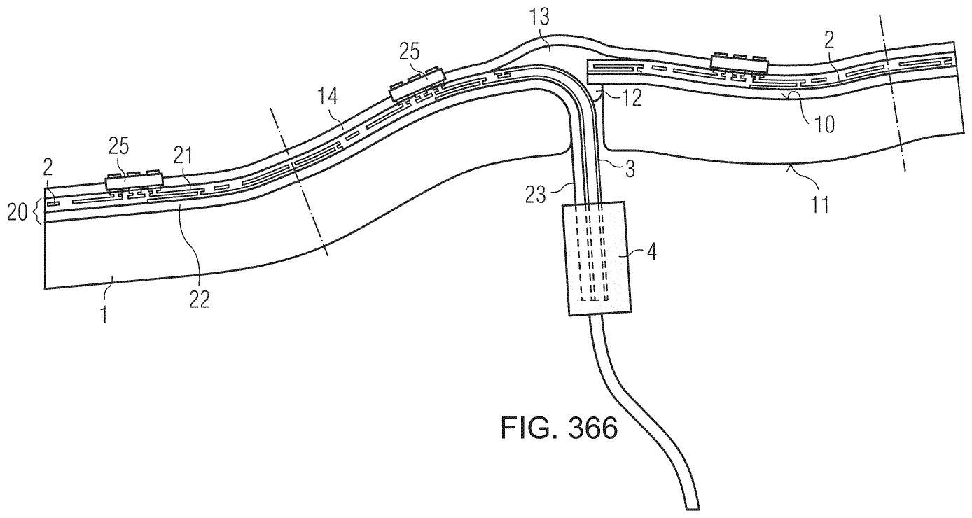

FIG. 366 shows a third embodiment of a display device, in which a filling material 13, for example silicone, is arranged on the front of support 1 in the area of opening 12. This can correct the interference in the appearance of the indicator caused by the opening. In addition, a continuous radiation-absorbing layer 14, for example a black layer, is applied to the display segments 2, leaving only the areas of the optoelectronic components exposed. This increases the contrast ratio of the display device.

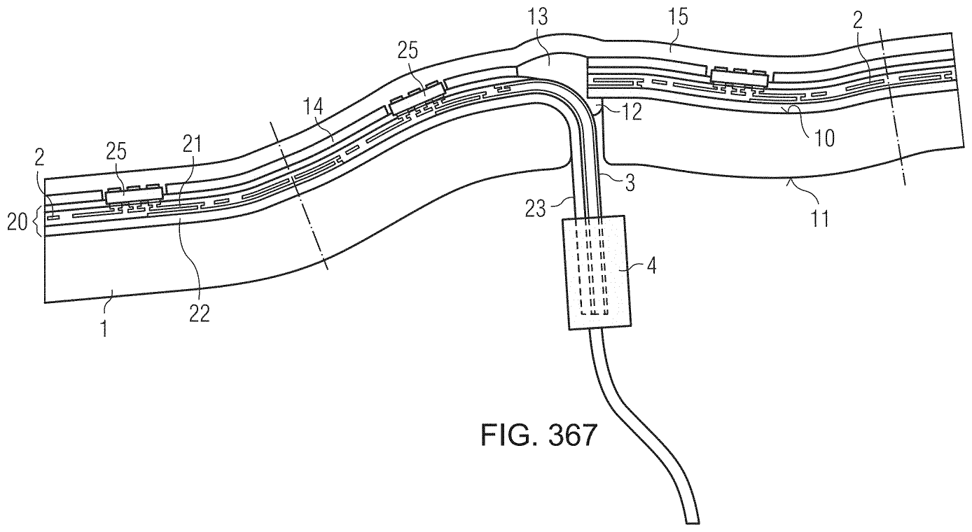

FIG. 367 shows a fourth embodiment in which, in contrast to the third embodiment, a continuous, non-reflective layer 15 is applied to the display segments 2. This layer 15 causes scattering of ambient light and is particularly useful if the absorbing layer 14 or the optoelectronic components 25 are reflective for ambient light.

FIG. 368 shows a fifth embodiment of a display device in which a reflective layer 16 is applied to the display segments 2. A functional layer 17 is applied to the reflective layer 16, comprising for example a polarizing film together with a λ/4 platelet film. Ambient light is linearly polarized on the polarizing film, circularly polarized on the λ/4 platelet film, and reflected on the reflective layer 16, whereby the direction of circulation is turned. When the polarizing film is returned to the polarizing film, the polarizing direction is rotated by 90° and the light is absorbed. This also means that an antireflection coating is achieved.

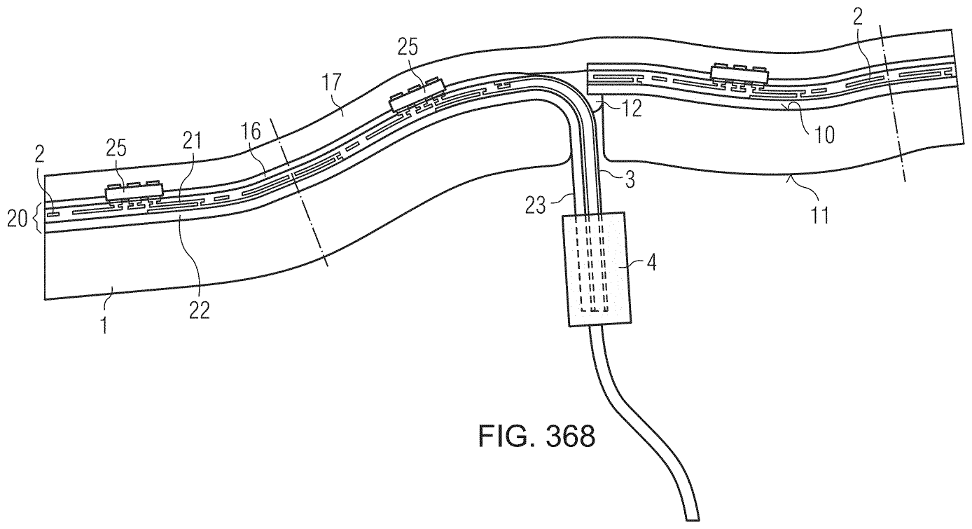

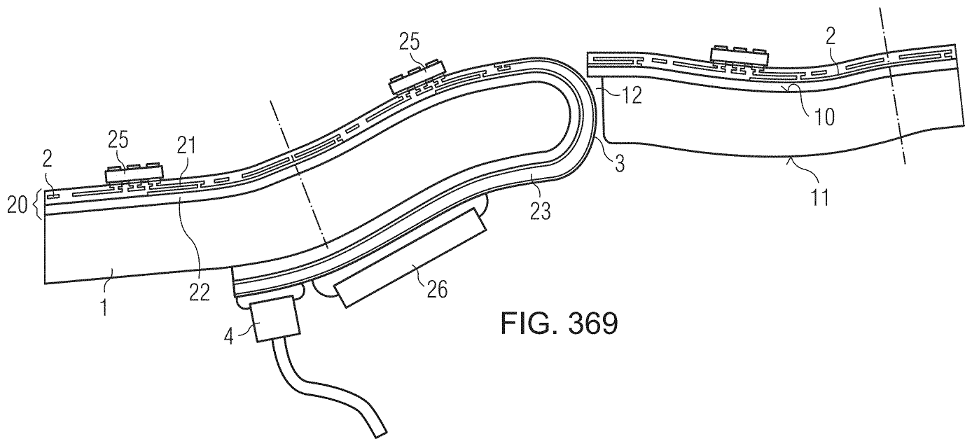

FIG. 369 shows a sixth embodiment of a display device in which the lug 23 of the substrate 20 on the rear side 11 protrudes from the opening 12 of the support 1, to such an extent that an active or passive electronic component 26 is still attached to this protruding part of the lug 23.

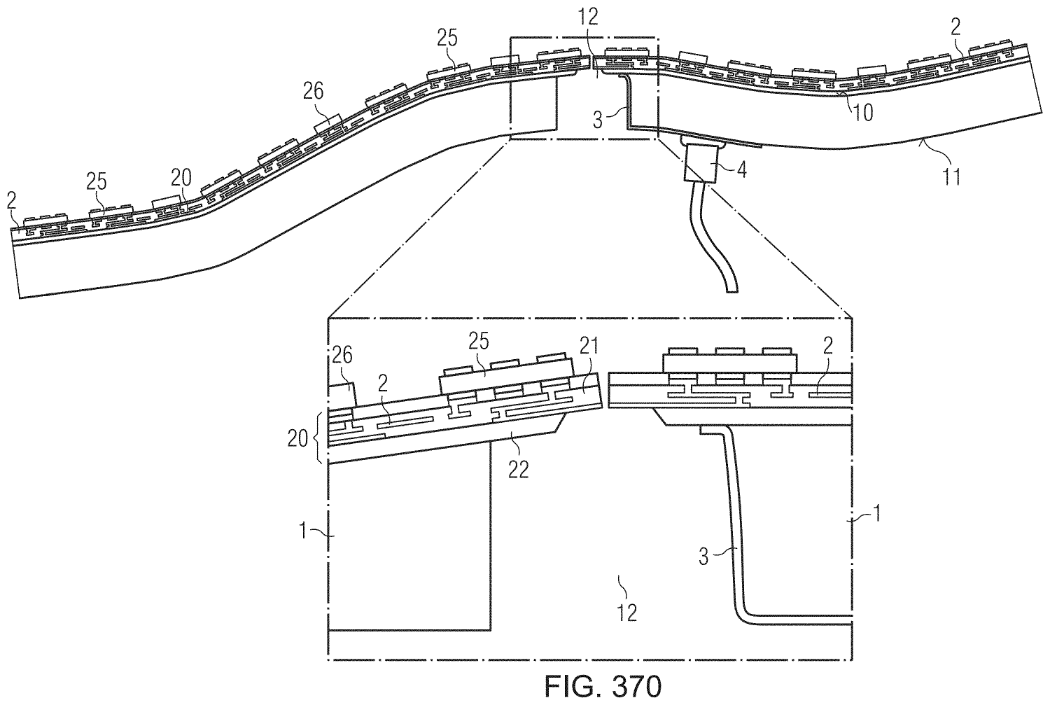

FIG. 370 shows a seventh embodiment of a display device. In contrast to the previous embodiments, no part of the substrate 20 is passed through the opening 2. Instead, the indicator segment 2 is placed on the substrate 1 in such a way that part of the indicator segment 2 covers the opening 12. In this area, a part of the electrically insulating layer 22 has been removed so that the connecting layer 21 of the substrate 20 is accessible. Via an electrical line 3 in the form of a metal layer, which is drawn over the side surfaces of the support 1 in the area of the opening 12 to the rear side 11, the display segment 2 is electrically contacted from the rear side 11, again via a connector 4. Preferably, an insulating layer is also arranged between the electrical line 3 in the form of the metal layer and the support 1.

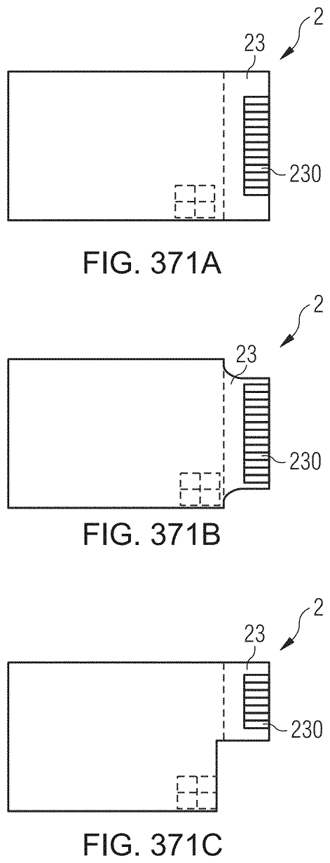

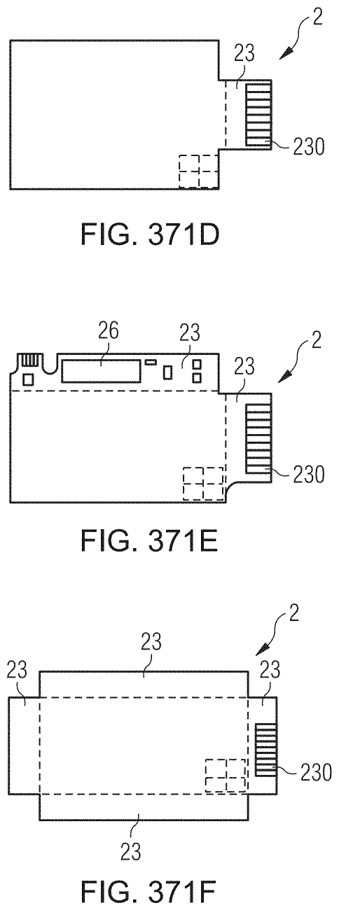

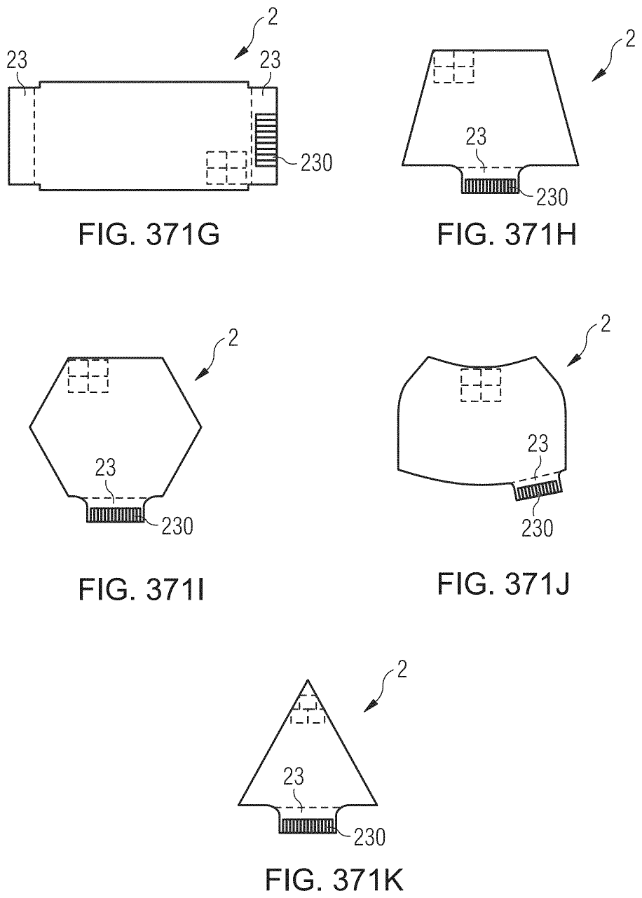

FIGS. 371A to 371K show embodiments of various display segments 2 in plan view. For reasons of clarity, the optoelectronic components are not shown. However, the rectangular, dashed boxes indicate how the optoelectronic components could be arranged in a regular pattern, for example to realize different pixels or image dots. The dotted lines indicate folding lines along which the display segments 2 can be bent or creased to guide the lugs 23 through openings in a carrier. The lugs 23 partly comprise connection pins 230 for a plug connection to a connector.

In the various embodiments of FIGS. 371A to 371K, different aspects regarding the lug and other features are shown. In FIG. 371A, lug 23 is located on only one side of display segment 2. In the embodiment in FIG. 371B, the lug 23 is constricted to allow a narrower opening in the beam.

In FIG. 371C, lug 23 is only as wide as necessary to allow a narrower opening in the beam or to allow multiple openings for adjacent display segments. FIG. 371D shows that lug 23 is located centrally on one side of display segment 2. In FIG. 371E, active or passive electronic components 26 are located on display segment 2.

In the embodiment according to FIG. 371F, lugs 23 are on all sides of indicator segment 2. In FIG. 371G, lugs 23 are only on two opposite sides of indicator segment 2. In FIG. 371H, indicator segment 2 comprises a trapezoidal shape, whereas in FIG. 371I, indicator segment 2 has a hexagonal shape. In FIG. 371J, Indicator Segment 2 is free form and in FIG. 371K, Indicator Segment 2 is triangular.

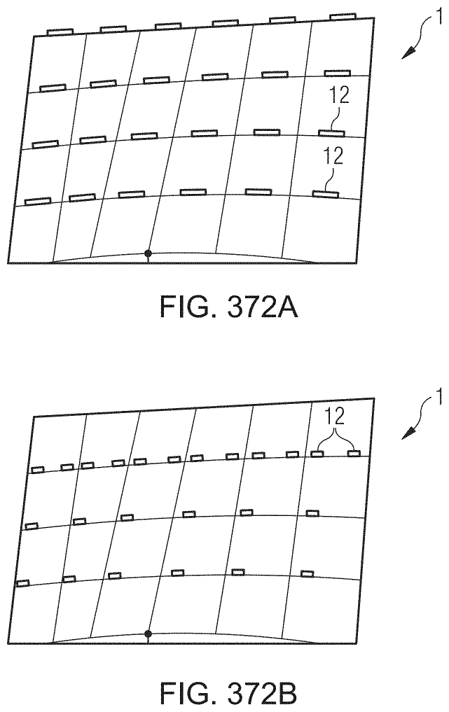

FIGS. 372A and 372B show examples of the embodiment of support 1 in plan view of the front of support 1. It can be seen that the front sides of carrier 1 are curved. The black bordered boxes indicate the areas in which a display segment 2 can be arranged. Each display segment 2 can be uniquely assigned to an opening 12 in carrier 1. In FIG. 372A, there is a discontinuity in the top row of openings 12, but in FIG. 372B, this is avoided by placing the openings 12 for the top row of display segments to be applied at the same height as the openings 12 for the display segments one row down.

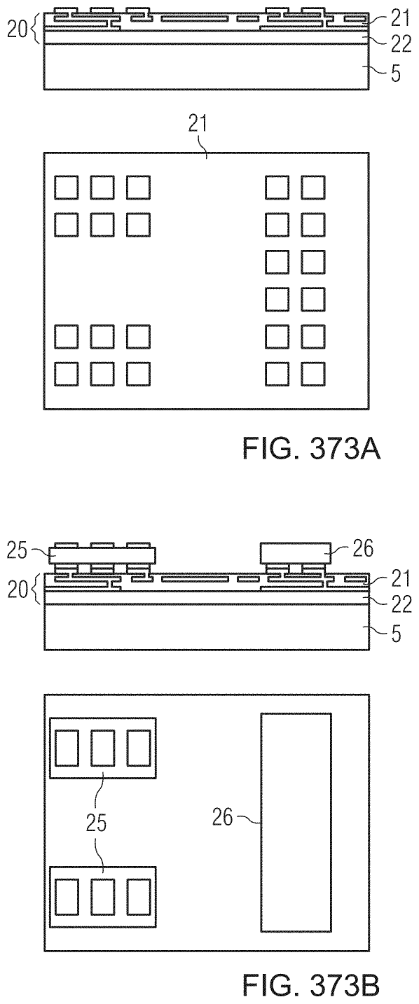

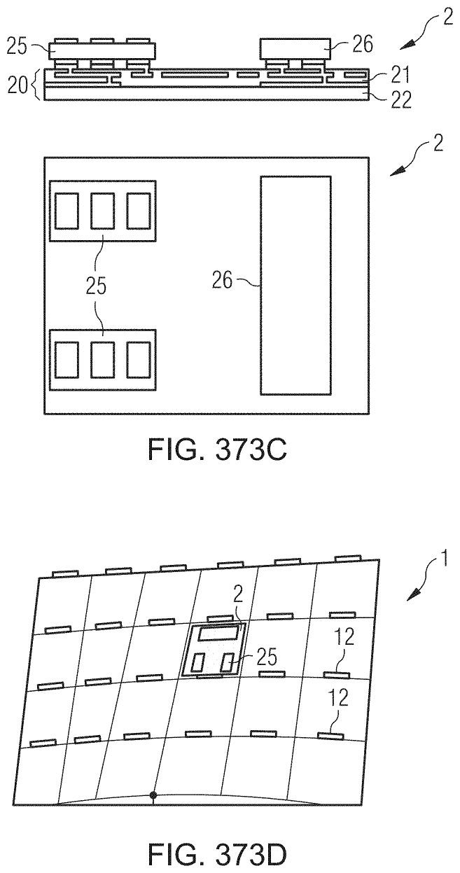

FIGS. 373A through 373D show various positions in an embodiment for making a display device. In the position shown in FIG. 373A, a display segment 2 is manufactured first. This is done by providing a substrate 20 with a connecting layer 21 and a continuous electrically insulating layer 22. The substrate is manufactured using a TFT process, for example. For processing, the substrate 20 is first applied to an auxiliary carrier 5, for example a glass carrier 5. Next, optoelectronic components 25 and an electronic component 26 are deposited on a top surface of substrate 20, for example in a parallel assembly process, and electrically interconnected by means of the connection layer 21 (see FIG. 373B). For example, an AC (Anisotropic Conductive) paste is used to deposit and electrically connect the components 25 and the component 26. Finally, in the position shown in FIG. 373C, the auxiliary carrier 5 is replaced. This leaves the self-supporting display segment 2, which is then placed on a carrier 11 in a designated area, for example glued on (see FIG. 373D). For example, a lug of display segment 2 is inserted through an opening 12 in carrier 1.

In the following, various devices and arrangements as well as methods for manufacturing, processing and operating as items are again listed as an example. The following items present different aspects and implementations of the proposed principles and concepts, which can be combined in various ways. Such combinations are not limited to those listed below:

1. A light emitting device:
an electrically conductive structure comprising an upper major surface and a lower major surface separated from the upper major surface by a distance;
a cavity in the electrically conductive structure and which has a width and length;
a semiconductor layer stack along the first main direction, which is arranged in the cavity and extends at least over the upper main surface, the semiconductor layer stack having
an active area;
a first electrical contact;
a second electrical contact;
the length of the cavity is based substantially on n/2 of a wavelength of light to be emitted during operation, where n is a natural number
   2. Light emitting device according to item 1, wherein the active region of the semiconductor layer stack is located between the upper and lower major surfaces within the cavity.
   3. Light-emitting device according to any of items 1 to 2, wherein the semiconductor layer stack is arranged substantially in the center of the cavity, in particular with its center at about half the cavity length.
   4. Light emitting device according to any of the preceding items, the second electrical contact extending beyond the lower major surface of the electrically conductive structure.
   5. Light emitting device according to any of the preceding items, the second contact being an n-contact and the first contact being a p-contact.
   6. Light emitting device according to any of the preceding items, wherein the semiconductor layer stack has a diameter of its footprint within the active region which is smaller than a wavelength emitted during operation.
   7. Light emitting device according to item 6, wherein the semiconductor layer stack forms a nanowire light emitting device.
   8. Light emitting device according to any of the preceding items, wherein the semiconductor layer stack comprises a reflective layer on at least two opposite sides, or the at least two opposite sides face a reflective region of the longitudinal sides of the cavity.
   9. Light-emitting device according to any of the preceding items, wherein the cavity, on the side adjacent to the lower major surface, is partially closed, and forms a recess within the electrically conductive structure.
   10. Light emitting device according to item 9, wherein the cavity comprises a hole for the semiconductor layer stack to extend therethrough.
   11. Light emitting device according to any of the preceding items, wherein the semiconductor layer stack is insulated in the cavity and a space between a part of the semiconductor layer stack and the electrically conductive structure is filled with at least one of:
air or other insulating gas; and
insulating material.
   12. Light-emitting device according to any of the preceding items, wherein the semiconductor layer stack comprises a passivation applied to its sidewall.
   13. Light emitting device according to any of the preceding items, the stack of semiconductor layers extending below the lower major surface
   14. Light emitting device according to any of the preceding items objects, wherein the semiconductor layer stack comprises a substantially rectangular base area.
   15. Light emitting device according to any of the preceding items, wherein the active region of the semiconductor layer stack comprise a quantum well structure.
   16. Light emitting device according to any of the preceding items, further comprising
a transparent insulating layer applied at least to the upper major surface of the electrically conductive structure;
a contact layer applied to the transparent insulating layer, which is in electrical contact with the first electrical contact.
   17. Light emitting device according to item 16, wherein the transparent insulating layer covers the lower major surface, the second contact of the semiconductor layer stack and the transparent insulating layer forming a substantially flat surface by covering the lower major surface.
   18. Light emitting device according to any of items 16 or 17, further comprising a metastructure disposed on the contact layer.
   19. Light-emitting device according to any of the preceding items, further comprising at least
a color filter mounted above the upper major surface, in particular a band-pass filter for a narrow color range;
a converter mounted above the upper major surface to convert light of a first wavelength to light of a second longer wavelength;
a light-shaping structure arranged above the upper major surface, in particular a dielectric structure, a microlens spanning the cavity or a photonic structure.
   20. μ-LED array comprising at least two light-emitting devices according to any of the preceding items, wherein said at least two elements share at least one of the following structures and/or layers
the electrically conductive structure;
the transparent insulating layer applied at least to the upper major surface of the electrically conductive structure;
the contact layer applied to the transparent insulating layer;
the color filter placed above the upper main surface; and
a converter located above the upper main surface.
   21. μ-LED array according to any of the preceding items, wherein the cavities of the at least two light-emitting arrays are of substantially equal length.
   22. μ-LED array according to any of items 20 to 21, wherein the cavity of one of said at least two light emitting arrays is disposed substantially parallel to another of said at least two light emitting arrays.
   23. μ-LED array according to any of items 20 to 22, wherein the cavity of one of said at least two light emitting arrays is substantially perpendicular to the other of said at least two light emitting arrays.
   24. μ-LED array according to any of the preceding items, wherein the second contacts of each of the at least two light emitting arrays are contacted separately.
   25. μ-LED array according to any of the preceding items, wherein the color filter of one of said at least two light emitting arrays is different from a color filter of another of said at least two light emitting arrays.
   26. μ-LED array according to any of the preceding items, wherein the converter of one of said at least two light emitting arrays is different from a converter of another of said at least two light emitting arrays.
   27. μ-LED array according to any of the preceding items, further comprising a carrier having at least two contacts for electrically contacting the respective second contacts of the at least two light emitting arrays mounted on the carrier.
   28. μ-LED array according to any of the preceding items, forming the light emitting device for a light guide device according to one of the following items.
   29. μ-LED arrangement according to any of the preceding items, in which contact elements are located on or adjacent to a side opposite the opening of the cavity, and further comprising
a carrier with contact areas on an upper side, to which the contact elements for electrical contacting are applied, wherein the carrier has several current drivers or other circuits for supplying power to the semiconductor layer stack.
   30. μ-display with a μ-LED array according to any of the preceding items, having features of a control or drive circuit according to any of the following items and features of a light guide device according to any of the following items.
   31. Method for producing a μ-LED device, comprising the steps of:
   forming pairs of polyhedron or prism shaped coated volumes of material on a growth support; and
   forming a converter material between the material volumes of a pair to emit a specific color, the converter material matched to this color.
   32. Method according to item 31, characterised by
   Depositing an active layer to the material volumes, and adding an additional layer to this to maintain the coated material volumes.
   33. Method according to any of the preceding items, characterised by
   forming metallization for each pair for electrical contacting of p-contacts with p-contact areas and n-contacts with n-contact areas.
   34. Method according to any of the preceding items, characterised by
   Forming a growth layer on the growth carrier, which comprises areas free of masking to which pairs of material volumes are grown.
   35. Method according to item 34, characterized in that
   the growth layer comprises an n-doping and especially GaN;
   the masking comprises silicon dioxide or silicon nitrogen;
   the material volumes comprises the same material as the growth layer;
   the active layer comprises In- or Al-GaN-MQW (multi quantum wells)
   the additional layer comprises a μ-doping and especially GaN.
   36. Method according to any of the preceding items, characterised by
   generating the material volumes with their longitudinal axes parallel to each other and parallel to the growth support and in the same shape as each other.
   37. Method according to any of the preceding items, characterised by
   depositing of first mirror-like metallization, in particular those providing solder, on the sides of the coated material volumes facing away from the growth carrier, whereby the p-contacts, in particular strip-shaped ones, are formed.
   38. Method according to any of the preceding items, characterised by
   depositing a solder metallization layer on a main surface of a flat carrier, wherein the solder metallization layer is connected, in particular bonded, to the first metallization of the material volumes forming the p-contacts.
   39. Method according to any of the preceding items, characterised by
   removing the growth carrier, especially by laser (LLO (Laser-Lift-Off)).
   40. Method according to one of the preceding items, characterised by
   removing the growth layer and the masking, in particular by etching (RIE (reactive ion etching) or ICP (inductively coupled plasma etching)).
   41. Method according to any of the preceding items, characterised by
   depositing, carried out on the side of the removed growth carrier, a passivation layer, in particular comprising SiO₂, which in particular completely covers the surfaces of the side.
   42. Method according to item 41, characterised by
   removing, in particular strip-shaped, areas of the passivation layer along the longitudinal axes of the material volumes on their surfaces facing away from the carrier; and
   depositing second metallization, especially strip-shaped ones, forming n-contacts on the exposed areas of the material volumes.
   43. Method according to item 41 or 42, characterised by
   depositing sidewall mirror metallization at and along the passivation layer vertically out of longitudinal axes of the n-contacts, along a sidewall of the passivation layer perpendicular to the substrate.
   44. Method according to item 43, characterised in that
   the sidewall mirror metallization are produced alternately facing away from and towards each other along a transverse axis with two adjacent coated material volumes.
   45. Method according to item 43 or 44, characterised in that
   a free interspace, along a transverse axis in the case of two adjacent coated material volumes in which the sidewall mirror metallization are produced facing away from each other, is filled by means of the respective converter material.
   46. Method according to any of the preceding items, characterised in that
   an electrical connection is formed at and along the passivation layer from the n-contacts, the sidewall mirror metallization and metallic intermediate connections deposited as third metallization to, in particular strip-shaped n-contact regions deposited as fourth metallization.
   47. Method according to any of the preceding items, characterized in that
   an electrical connection is formed to n-contact regions, in particular strip-shaped n-contact regions deposited as fourth metallization on and along the passivation layer from the n-contacts, the sidewall mirror metallization and metallic intermediate connections deposited as third metallization to n-contact plated-through holes to the other side of the carrier.
   48. Method according to any of the preceding items, characterised in that
   an electrical connection is formed on and along the passivation layer from the n-contacts and the sidewall mirror metallization to n-contact plated-through holes to the other side of the carrier to n-contact areas, in particular strip-shaped n-contact areas deposited as fourth metallization.
   49. Method by object, characterised in that
   the n-contact vias are electrically insulated by the passivation layer from the solder metallization layer and the substrate.
   50. Method according to any of the preceding items, characterised by
   removing in particular strip-shaped areas of the passivation layer covering the solder metallization layer;
   depositing, in particular strip-shaped, fifth metallization on the exposed areas of the solder metallization layer to form a p-contact area, which is electrically connected to the p-contacts by means of the solder metallization layer.
   51. Method according to any of the preceding items, characterised by
   removing, in particular strip-shaped, areas of the carrier covering the solder metallization layer;
   depositing, in particular strip-shaped, fifth metallization on the exposed areas of the solder metallization layer to form a p-contact area produced as a p-contact vias to the side of the carrier remote from the material volumes, which is electrically connected to the p-contacts by means of the solder metallization layer.
   52. Method according to item 51, characterized in that
   the p-contact vias are formed in the area of a respective converter material.
   53. Method according to any of the preceding items, characterised in that
   at least some to all metallization comprise the same material, and that, optionally, the second metallization and the sidewall mirror metallization comprise Al or Ag.
   54. Pixel arrangement comprising
at least one subpixel comprising a pair of two adjacent μ-LEDs spaced apart by a gap, wherein the μ-LEDs are adapted to emit light into the gap;
a converter material arranged inside the gap.
   55. Pixel arrangement according to item 54, in which the μ-LEDs comprise the shape of a polyhedron or a prism of coated material volumes and comprise an active layer at least along the side facing the gap.
   56. Pixel arrangement according to any of the preceding items, in which the μ-LEDs comprise a reflective layer on the side facing away from the gap
   57. Pixel arrangement according to any of the preceding items, in which the μ-LEDs comprise a common terminal layer adapted to supply current to the active layer
   58. Pixel arrangement according to item 57, in which the common terminal layer extends below a bottom of the gap isolated from the common terminal layer and/or in which a portion of the common terminal layer extends between the active layer of each μ-LED and the converter material, respectively.
   59. Pixel arrangement according to any of the preceding items, in which a contact layer on the side facing away from the interspace extends in the direction of an emission side and there contacts the volume of material for supplying current to the active layer.
   60. Pixel arrangement according to any of the preceding items, in which the converter material fills the gap at least up to an upper side of the material volumes
   61. Pixel arrangement according to any of the preceding items, in which a transparent cover layer covers the pair of sub-pixels and the gap between them.
   62. Pixel arrangement according to one of the preceding items, further comprising:
   two further subpixels, each comprising a pair of two μ-LEDs adjacent and spaced apart by a gap, the μ-LEDs being adapted to emit light into the gap;
a converter material different from the first converter material in at least one of the gaps.
   63. Pixel arrangement according to item 62, in which at least one of the contact layers of a μ-LED of a subpixel extending on the side facing away from the gap is opposite a contact layer of a μ-LED of another subpixel.
   64. Pixel arrangement according to item 62 or 63, in which the three sub-pixels are arranged substantially parallel to each other; or one sub-pixel is arranged substantially perpendicular to the two remaining sub-pixels.
   65. Pixel arrangement according to one of the preceding items, further comprising
a photonic structure according to features of one of the following items, which in particular comprises periodic areas of different refractive index.
   66. Pixel arrangement according to item 65, in which the photonic structure comprises at least one of the following characteristics:
the photonic structure is a two-dimensional crystal,
the photonic structure comprises a superlattice along at least one direction.
   67. Pixel arrangement according to any of the preceding items, further comprising a plurality of contact elements on a side facing away from the emission side, which are connected to contact areas of a carrier, the carrier comprising at least one current driver circuit, in particular according to any of the following items, for each pair of μ-LEDs
   68. Pixel arrangement according to item 67, further comprising a device for electronically driving a plurality of μ-LEDs according to any of the following items, the μ-LEDs of the device being formed by pairs of μ-LEDs.
   69. Pixel arrangement according to any of the preceding items, characterised in that
   the pixel arrangement has been generated by a method according to one of the previous methods.
   70. μ-LED arrangement comprising
at least one μ-rod arranged along a carrier, wherein the μ-rod forms an elongated core having a first doping along a longitudinal axis, and the core is coated outwardly from a layer stack from a first longitudinal end to a second longitudinal end free from the layer stack, wherein
the at least μ-rod is electrically and mechanically connected at the first longitudinal end to a first contact region of the carrier by means of the layer stack and a first contact, and is electrically and mechanically connected at the second longitudinal end to a second contact region of the carrier by means of the core and a second contact, the layer stack being electrically insulated from the second contact by an insulating layer.
   71. μ-LED arrangement according to item 70, wherein the μ-rod for an emission of light of a certain wavelength comprises a geometry adapted thereto, and is constructed in particular as at least one polyhedron, in particular as a prism or parallelepiped, the first longitudinal end terminating in particular as a pyramid, truncated pyramid, obelisk or wedge.
   72. μ-LED arrangement according to any of the preceding items, characterised in that
   the μ-rod for an emission of light of a certain wavelength comprises a spatial extension adapted thereto, in particular a certain diameter perpendicular to the longitudinal axis.
   73. μ-LED arrangement according to any of the preceding items, characterised in that
   the μ-rod is covered by a converter material matched to an emission of light of a certain wavelength.
   74. Electronic component according to any of the preceding items,
   characterised in that
   a reflective layer, in particular a layer comprising TiO2 in a silicone matrix, is formed on the μ-rod and/or on the carrier; or in that
   a dark, in particular black, layer is formed on the μ-rod and/or on the carrier.
   75. μ-LED arrangement according to any of the preceding items, characterised in that
   a transparent layer, in particular an ITO-jacket, is arranged on the μ-rod and/or on the carrier.
   76. μ-LED arrangement according to any of the preceding items, characterised in that
   a housing is produced on the μ-rod and/or on the carrier, in particular as a casting compound.
   77. Pixel element with three μ-LED arrays according to any of the preceding items, in which
   the three components are electrically and mechanically connected to one another and/or to the carrier in parallel to contact areas of the carrier, the three electronic components being configured to emit light of at least one wavelength.
   78. Pixel element according to the preceding item, in which each of the three μ-LED arrangements is configured to emit light and the frequency of an emitted light is different.
   79. Pixel element according to any of the preceding items, in which the first longitudinal ends of the μ-rods of the three μ-LED arrays are connected to a common terminal.
   80. Pixel element according to any of the preceding items, in which a reflective circumferential structure, in particular a circumferential structure according to features of one of the subsequent items is formed around the three μ-LED arrangements.
   81. Pixel element according to item 80, in which the reflecting circumferential structure forms a connection for a contact area at the first or second longitudinal end of the μ-rods of the three μ-LED arrays
   82. Pixel element according to any of the preceding items, further comprising a photonic structure, in particular according to features of one of the subsequent items, which is arranged above the μ-LED arrays.
   83. Method of manufacturing a μ-LED array comprising the steps of:
Creating a μ-rod which is arranged along a carrier, wherein the μ-rod forms an elongated core having a first doping along a longitudinal axis, and the core has been coated outwardly from a layer stack from a first longitudinal end to a second longitudinal end free from the layer stack, wherein
Connecting the μ-rod at the first longitudinal end by means of the layer stack and a first contact to a first contact area of the carrier
Connecting the μ-rod at the second longitudinal end by means of the core and a second contact to a second contact region of the carrier, the layer stack being electrically insulated to the second contact by means of an insulating layer.
   84. Method according to item 83, wherein the step of generating a μ-rod comprises
Creating the layer stack from a core outwards as a first layer comprising the first doping, an active layer and a second layer comprising a second doping.
   85. Method according to items 83 or 84, further comprising:
generating a group of, in particular three identical, μ-rods, as in particular decreasing in cross-section perpendicular to the longitudinal axis towards a first longitudinal end and/or terminating at the first longitudinal end with a point or edge or a plane.
   86. Method according to any of the preceding items, further comprising
generating a group of, in particular three, μ-rods each with different diameters and/or different geometry on the growth substrate, in particular by means of selective epitaxy, such that they are configured to emit light of different wavelengths.
   87. Method according to any of the preceding items, comprising:
producing a first transparent contact, in particular a p-contact, at the first longitudinal end of a respective μ-rod remote from the insulating layer, in particular epitaxially and in particular by means of a seed layer photo-structured by means of oxygen plasma etching and/or in particular by means of electroplating or sputtering, wherein at least one contact plane is formed in particular at the first contact.
   88. Method according to item 87, further comprising
surrounding the group of μ-rods with a connecting layer, in particular a thermoplastic connecting layer, from the first longitudinal end to the insulation layer, the first longitudinal ends temporarily abutting a replacement carrier;
removing a growth substrate.
   89. Method according to any of the preceding items, further comprising
producing a second transparent contact, in particular an n-contact, at the second longitudinal end of a respective μ-rod facing the insulating layer, in particular by means of electroplating or sputtering, wherein at least two contact planes is formed in particular on the second contact.
   90. Method according to any of the preceding items, characterised by
   transferring the group of μ-rods to a foil; and
   fixing the second contact of a respective μ-rod, in particular with a contact plane, to the foil.
   91. Method according to item 90, further comprising a separating the μ-rods of the group, whereby the compound layer is at least partially removed.
   93. Method according to item 90 or 91, further comprising lifting from the film of groups of, in particular three, separated μ-rods, and electrically and mechanically connecting them by means of their first contacts and their second contacts, in particular by means of contact planes, to first contact areas and second contact areas of the carrier, parallel to each other and/or parallel to the carrier.
   94. Method according to item 93, characterized in a simultaneously lifting and simultaneously electrical and mechanical connecting of approximately 500 to 1500 groups of prods.
   95. μ-LED comprising a three-dimensional light-emitting heterostructure having a first conductive semiconductor layer, an active layer and a second conductive semiconductor layer; characterized in that
   the light-emitting heterostructure comprises aluminium gallium arsenide and/or aluminium gallium indium phosphide and/or aluminium gallium indium phosphide arsenide; and
   wherein the light-emitting heterostructure is formed three-dimensionally by growing on a molding layer comprising a {110} oriented side surface selectively epitaxially deposited on a gallium arsenide (111)B epitaxial substrate, wherein optionally a flat top surface {111} may be provided.
   96. μ-LED according to item 95, in which the molding layer comprises gallium arsenide and/or aluminium gallium arsenide and/or aluminium gallium indium phosphide and/or a Bragg mirror stack.
   97. μ-LED according to any of the preceding items, characterized in that the molding layer is wet-chemically post-processed after selective epitaxial deposition on the gallium arsenide (111)B epitaxial substrate.
   98. μ-LED according to any of the preceding items articles in which the shape of the molding layer forms a three-sided pyramid whose side faces comprises the orientation (−1-10), (−10-1) and (0-1-1).
   99. μ-LED according to any of the preceding items articles, characterized in that the molding layer comprises a (111) or (−1-1-1) oriented surface.
   100. μ-LED according to item 99, in which the molding layer forms a three-sided truncated pyramid, the side faces of which comprise the orientation (−1-10), (−10-1) and (0-1-1) and the top face (10) of which comprises the orientation (−1-1-1).
   101. μ-LED according to any of the preceding items, characterized in that a projection of the light-emitting heterostructure onto the gallium arsenide (111)B epitaxial substrate has an edge length of <100 μm and preferably <20 μm.
   102. μ-LED according to any of the preceding items, in which the light-emitting heterostructure extends to a dielectric mask deposited on the gallium arsenide (111)B epitaxial substrate for selective epitaxial deposition of the mold layer.
   103. μ-LED according to any of the preceding items, characterized in that a transparent contact layer is applied above the light-emitting heterostructure for a main radiation direction in the growth direction of the layer stack.
   104th μ-LED according to any of the preceding items, characterized in that for a main radiation direction opposite to the growth direction of the layer stack below the light-emitting heterostructure there is a layer stack with a transparent contact layer applied after the removal of the gallium arsenide (111)B epitaxial substrate and an at least partial removal of the mold layer.
   105. μ-LED according to item 104, in which a converter material is applied to the transparent contact layer in a region below or above the active layer in the main radiation direction.
   106. μ-LED arrangement according to any of the preceding items, with a μ-LED according to any of the preceding items and further comprising a photonic structure, in particular with features according to one of the subsequent items, which is applied to a surface of the transparent contact layer.
   107. μ-LED array according to any of the preceding items, with the photonic structure extending over the conversion layer
   108. μ-display arrangement for a wavelength in the range of 560 nm to 1080 nm comprising at least one μ-LED according to any of the preceding items, arranged in particular in rows and columns
   109. Method of producing an optoelectronic semiconductor device, in particular a μ-LED comprising a three-dimensional light-emitting heterostructure with a first conductive semiconductor layer, an active layer and a second conductive semiconductor layer;
   characterised in that
   on a gallium arsenide (111)B epitaxial substrate, a shaped layer having a {110} oriented lateral surface is grown by selective epitaxy; and
   the light-emitting heterostructure is formed three-dimensionally by growing aluminium gallium arsenide and/or aluminium gallium indium phosphide layers on the mold layer.
   110. Method of producing an optoelectronic semiconductor device according to item 109, characterised in that the mold layer is formed by gallium arsenide and/or aluminium gallium arsenide and/or aluminium gallium indium phosphide and/or a Bragg mirror stack.
   111. Method of producing an optoelectronic semiconductor device according to one of the items 109 or 110, characterised in that the molded layer is wet-chemically reworked after the selective epitaxial deposition on the gallium arsenide (111)B epitaxial substrate.
   112. Method of producing an optoelectronic component, in particular a μ-LED, comprising the steps:
providing a semiconductor structure comprising a first n-doped layer, a second p-doped layer and an active layer with at least one quantum well disposed therebetween, wherein the p-doped layer comprises a first dopant;
applying of a structured mask on the semiconductor structure;
doping of the p-doped layer with a second dopant with first process parameters, so that quantum well intermixing is generated in areas of the active layer over which no area of the patterned mask is located;
annealing with second process parameters different from the first process parameters, especially without further addition of the second dopant.
   113. Method according to item 112, in which the second dopant comprises Zn and comprises the same doping type as the first dopant.
   114. Method according to any of the preceding items, in which the second process parameters comprise a temperature greater than a temperature of the first process parameters.
   115. Method according to any of the preceding items, in which the first and/or second process parameters comprise at least one of the following parameters:
Temperature;
Temperature change over a defined period;
Pressure;
Pressure change over a defined period of time;
Composition of a gas;
Duration;
Combination of these;
   and the first process parameters differ from the second process parameters in at least one parameter other than the duration.
   116. Method according to any of the preceding items, in which the mask is formed locally from a suitable layer of the semiconductor structure by a patterning step.
   117. Method according to any of the preceding items, wherein the step of curing further comprises:
adding of a precursor comprising an element from the fifth main group, in particular P or As.
   118. Method according to any of the preceding items, in which the second dopant comprises Zn or Mg.
   119. Method according to any of the preceding items, in which the semiconductor structure comprises a III-V semiconductor material having at least one of the following material systems:
InP;
GaP;
InGaP;
InAlP;
GaAlP; and
InGaAlP.
   120a. μ-LED, μ-LED arrangement, or semiconductor layer stack according to any of the preceding items, in particular items 1 to 107, or one of the subsequent items, which comprises a semiconductor structure that has been produced by a method according to any of the preceding items.
   120b. μ-LED, comprising:
a semiconductor structure comprising a III-V semiconductor material, comprising:
   an n-doped layer,
   a p-doped layer and
   an active layer with at least one quantum well disposed in between,
   wherein the p-doped layer comprises a first dopant;
a central region in the active layer laterally surrounded by a second region in the active layer whose band gap is greater than that of the central region;
   wherein a second dopant is introduced into the second region, which produces quantum well intermixing in the at least one quantum well of the active layer located in the second region.
   121 μ-LED, μ-LED arrangement, or semiconductor layer stack according to any of the preceding items, in particular items 1 to 107 or one of the subsequent items, which has a central region in the active layer which is laterally surrounded by a second region in the active layer whose band gap is greater than that of the central region;
   wherein a second dopant is introduced into the second region, which produces quantum well intermixing in the at least one quantum well of the active layer located in the second region.
   122. μ-LED according to any of the preceding items, in which a patterned mask is arranged on a partial area of the p-doped layer, which is located above the central area in the active layer.
   123. μ-LED according to item 122, in which a size of the mask corresponds substantially to a size of the central area.
   124. μ-LED according to item 122, in which a layer of a III-valent material of the III-V semiconductor material and an element of a precursor material, in particular P or As, is formed on a surface of the region of the p-doped layer not covered by the mask.
   125. Method of producing an optoelectronic component, in particular a μ-LED, comprising the steps:
providing a semiconductor structure, comprising
   a first n-doped layer,
   a second p-doped layer and
   an active layer with at least one quantum well disposed in between,
   wherein the p-doped layer comprises a first dopant;
applying a structured mask on the semiconductor structure;
doping of the p-doped layer with a second dopant so that quantum well intermixing is generated in areas of the active layer over which no region of the patterned mask is located; wherein the doping of the p-doped layer with a second dopant is carried out by a gas phase diffusion using a precursor with the second dopant and comprises the following steps:
depositing of the second dopant on the surface of the p-doped layer by decomposition of the precursor at a first temperature selected such that substantially no diffusion of the second dopant into the p-doped layer takes place;
Diffusing of the deposited second dopant into the p-doped layer at a second temperature which is higher than the first temperature
   126. Method according to item 125, in which the second dopant comprises Zn or Mg and comprises the same doping type as the first dopant.
   127. Method according to any of the preceding items, in which the amount of the second dopant deposited is chosen such that it diffuses substantially completely into the p-doped layer during diffusion.
   128. Method according to any of the preceding items, in which the amount of the second dopant is chosen such that in regions of the active layer over which no region of the patterned mask is located, a barrier to the lateral diffusion of charge carriers generated by the second dopant is greater than a barrier caused by quantum well intermixing.
   129. Method according to any of the preceding items, wherein doping the p-doped layer with a second dopant comprises the step:
Healing of the semiconductor structure after diffusion of the second dopant into the p-doped layer at a third temperature higher than the second temperature.
   130. Method according to any of the preceding items, in which the mask is formed locally by a suitable layer of the semiconductor structure by a structuring step.
   131. Method according to any one of the articles 129 to 130, wherein the step comprises curing:
providing a further precursor comprising an element from the fifth main group, in particular P or As and/or
Forming a layer of an III-V semiconductor material on the surface of the p-doped layer.
   132. Method according to any of the preceding items, in which during the steps of depositing, diffusing and annealing at least one of the following parameters is selected differently:
Temperature change over a defined period of time during one of the above steps;
Pressure;
Pressure change over a defined period of time during one of the above steps;
Composition of a gas;
Combination of these.
   133. Method according to any of the preceding items, in which the semiconductor structure comprises a III-V semiconductor material having at least one of the following material systems:
InP;
GaP;
InGaP;
InAlP;
GaAlP; and
InGaAlP.
   134. μ-LED, comprising:
a semiconductor structure comprising a III-V semiconductor material, comprising
an n-doped layer,
a p-doped layer and
an active layer with at least one quantum well disposed in between,
   wherein the p-doped layer comprises a first dopant;
a central semiconductor region in the active layer, laterally surrounded by a second semiconductor subregion in the active layer, the band gap of which is greater than that of the central region;
   wherein a second dopant is introduced into the second subregion, which mediates quantum well intermixing in the at least one quantum well of the active layer located in the second subregion;
   wherein a barrier for the lateral diffusion of charge carriers is formed in defined regions of the active layer, which barrier is composed of a barrier produced by the second dopant and of a barrier produced by quantum well intermixing.
   135. μ-LED according to item 134, where the defined areas are formed by a structured mask applied during manufacture.
   136. μ-LED according to item 134, characterized in that the doping barrier produced by the second dopant is greater than the barrier produced by quantum well intermixing.
   137. μ-LED according to any of the preceding items, in which a patterned mask is arranged on a first subarea of the p-doped layer, which is located above the central region in the active layer.
   138. μ-LED according to any of the preceding items, in which a size of the mask is substantially equal to a size of the central area.
   139. μ-LED according to any of the preceding items, in which a layer of a III-valent material of the III-V semiconductor material and an element of a precursor material, in particular P or As, is formed on a surface of a partial region of the p-doped layer lying above the defined region.
   140. μ-LED according to any of the preceding items, wherein the active layer is formed by a light-emitting heterostructure of aluminum gallium arsenide and/or aluminum gallium indium phosphide and/or aluminum gallium indium phosphide arsenide, and the light-emitting heterostructure is formed three-dimensionally by growing on a molded layer comprising a {110} oriented side surface selectively epitaxially deposited on a gallium arsenide (111)B epitaxial substrate.
   141. μ-LED according to any of the preceding items, in which at least one of the p- and n-doped layers has a cuboid or ingot shape and the active layer extends along at least one sidewall and in particular over two sidewalls and one main side.
   142. μ-LED arrangement having a μ-LED and with a photonic structure, in particular having features according to one of the subsequent items, on a side lying in a main emission direction of the μ-LED, and having a contact region on the side opposite the main emission direction.
   143. μ-LED arrangement according to item 141, in which the μ-LED is surrounded by a circumferential reflective structure, in particular with features according to any of the preceding items
   144. Use of a μ-LED in one of the arrangements following one of the preceding items.
   145. μ-LED comprising:
an n-doped first layer,
a p-doped second layer doped with a first dopant,
an active layer which is disposed between the n-doped first layer and the p-doped second layer and which comprises at least one quantum well;
   whereby the active layer is divided into at least two areas,
   wherein a second region concentrically encloses a first region, and
   wherein the at least one quantum well in the active region has a larger band gap in the second region than in the first region, and
   wherein the band gap is modified in particular by quantum well intermixing.
   146. μ-LED according to the preceding item,
   further comprising a second dopant, which is substantially uniformly arranged in the second region.
   147. μ-LED according to any of the preceding items,
   where the second dopant in the second region is
in the second p-doped layer,
in the active layer and
is at least partially formed in a region of the n-doped first layer adjacent to the active layer.
   148. μ-LED according to any of the preceding items,
   wherein the at least two areas are at least approximately circular in shape.
   149. μ-LED according to any of the preceding items, wherein the second region comprises a substantially uniform band gap change modified by the quantum well intermixing.
   150. μ-LED according to any of the preceding items,
   wherein the first region comprises substantially no quantum well intermixing.
   151. μ-LED according to any of the preceding items,
   wherein quantum well intermixing decreases in a defined transition region from the second region to the first region.
   152. μ-LED according to any of the preceding items, characterised in that the second dopant is different from the first dopant.
   153. μ-LED according to any of the preceding items, characterized in that the second dopant is formed from a group comprising at least one of the following elements: Mg, Zn, Cd.
   154. μ-LED arrangement with a plurality of μ-LEDs according to any of the preceding items and with a photonic structure arranged on a side lying in a main emission direction, in particular with features according to any of the subsequent items and with a contact area on the side opposite the main emission direction.
   155. μ-LED arrangement comprising a plurality of μ-LEDs according to any of the preceding items, in which a photonic structure is formed on a main emission side by a periodic array of columnar elements having a first refractive index surrounded by material having a second refractive index, at least some of the columnar elements being located above the active layer, in particular above the first region.
   156. μ-LED arrangement according to item 153, in which at least one of the plurality of μ-LEDs is surrounded by a circumferential reflecting structure, in particular with features according to any of the preceding items.
   157. Use of a μ-LED in an arrangement, in particular as a stack of semiconductor layers according to any of the preceding items.
   158. Method for producing an optoelectronic component, in particular a μ-LED, comprising the
providing a semiconductor structure with an in particular n-doped first layer, a second layer doped with a first dopant, in particular p-doped, and an active layer arranged in between;
applying a substantially circular diffusion mask to the in particular p-doped second layer to define a first, optically active region in the active layer surrounded by a second region of the active layer; and
creating a quantum well intermixing in the second area of the active layer.
   159. Method according to item 158, wherein the step of generating a quantum well intermixing comprises:
Diffusing of a second dopant into the second in particular p-doped layer, into the active layer in the second region and at least partially into a region of the in particular n-doped layer adjacent to the active layer;
   160. Method according to any of the preceding items,
   wherein, by applying the diffusion mask to the in particular p-doped second layer and by diffusing the second dopant into the second in particular p-doped layer, into the active layer in the second region and at least partially in a region of the in particular n-doped layer adjacent to the active layer, quantum well intermixing takes place only in the second region.
   161. Method according to any of the preceding items,
   whereby the diffusion mask is formed by a dielectric.
   162. Method, according to any of the preceding items, characterized in that the second dopant is different from the first dopant.
   163. Method, according to any of the preceding items, in which the first layer is p-doped and the second layer is n-doped.
   164. Method according to any of the preceding items, characterized in that the second dopant is formed from a group comprising at least one of the following elements: Mg, Zn, Cd.
   165. A semiconductor structure comprising:
an n-doped first layer,
a p-doped second layer doped with a first dopant,
an active layer which is disposed between the n-doped first layer and the p-doped second layer and which has at least one quantum well,
   wherein the active layer of the semiconductor structure is divided into a plurality of first optically active regions, at least one second region and at least one third region, and
   wherein said first plurality of optically active regions are spaced apart in a hexagonal pattern, and
   wherein the at least one quantum well in the active region has a larger band gap in the at least one second region than in the plurality of first optically active regions and the at least one third region, and wherein the band gap is modified in particular by quantum well intermixing, and
   wherein the at least one second region encloses the plurality of first optically active regions, and
   wherein said at least one third region is located in the spaces between said plurality of first optically active regions.
   166. Semiconductor structure according to the preceding item, wherein the plurality of first optically active regions are at least approximately circular in shape.
   167. Semiconductor structure according to any of the preceding items,
   wherein a plurality of second regions each concentrically encloses one of said plurality of first optically active regions.
   168. Semiconductor structure according to any of the preceding items,
   wherein a plurality of second areas are at least approximately circular in shape.
   169. Semiconductor structure according to any of the preceding items,
   wherein a plurality of third regions are arranged such that each of the plurality of third regions is located in the center of exactly three first optically active regions.
   170. Semiconductor structure according to the previous item, wherein each of the plurality of third regions is at least approximately circular in shape.
   171. Semiconductor structure according to item 170,
   wherein each of the plurality of third regions at least approximately represents the shape of a deltoid curve formed by exactly three of the plurality of second regions, each of which is at least approximately circular.
   172. Semiconductor structure according to any of the preceding items,
   wherein one optically active region each of the plurality of first optically active regions forms part of a respective optoelectronic component.
   173. Semiconductor structure according to any of the preceding items,
   further comprising a second dopant substantially uniformly arranged in at least one second region.
   174. Semiconductor structure according to any of the preceding items,
   wherein the second dopant is present in at least one second region
in the second p-doped layer,
in the active layer and
is at least partially formed in a region of the n-doped layer adjacent to the active layer.
   175. Semiconductor structure according to any of the preceding items,
   wherein said at least one second region has a substantially uniform band gap modified by said quantum well intermixing.
   176. Semiconductor structure according to any of the preceding items,
   wherein the plurality of first optically active regions and the at least one third region have a substantially identical band gap.
   177. Semiconductor structure according to any of the preceding items,
   wherein the plurality of first optically active regions are substantially free of quantum well intermixing.
   178. Semiconductor structure according to any of the preceding items,
   wherein said at least one third region comprises substantially no quantum well intermixing.
   179. Semiconductor structure according to any of the preceding items,
   wherein quantum well intermixing decreases in a defined transition region from the at least one second region to the plurality of first optically active regions.
   180. Semiconductor structure according to any of the preceding items,
   characterised in that the second dopant is different from the first dopant.
   181. Semiconductor structure according to any of the preceding items,
   characterized in that the second dopant is formed from a group comprising at least one of the following materials: Mg, Zn, Cd.
   182. Semiconductor structure according to any of the preceding items, further comprising an out-coupling structure, in particular a photonic structure on a side lying in the main radiation direction.
   183. μ-LED arrangement having a semiconductor structure according to any of the preceding or following items
   184. A method for producing a semiconductor structure comprising,
providing a semiconductor structure comprising an n-doped first layer, a p-doped second layer doped with a first dopant and an active layer disposed therebetween;
applying a mask to the p-doped second layer to define a plurality of first optically active regions in the active layer surrounded by at least one second region of the active layer and to define at least one third region located in the spaces between the plurality of first optically active regions;
creating quantum well intermixing in the at least one second region of the active layer.
   185. Method for producing a semiconductor structure according to item 184, the step of generating quantum well intermixing comprising:
Diffusing of a second dopant into the p-doped second layer, into the active layer in at least one second region and at least partially into a region of the n-doped layer adjacent to the active layer.
   186. Method for producing a semiconductor structure according to any of the preceding items,
   wherein quantum well intermixing takes place only in the at least one second region by applying the mask to the p-doped second layer and by diffusing the first dopant into the p-doped second layer into the active layer in the at least one second region and at least partially in a region of the n-doped layer adjacent to the active layer.
   187. Method for producing a semiconductor structure according to any of the preceding items,
   whereby the mask is formed by a mask of dielectric (e.g. SiO₂, Si₃N₄, . . . ).
   188. Method for producing a semiconductor structure according to any of the preceding items, characterized in that the second dopant is different from the first dopant.
   189. Method for producing a semiconductor structure according to any of the preceding items, characterized in that the second dopant is formed from a group comprising at least one of the following elements: Mg, Zn, Cd.
   190. Method for producing a semiconductor structure according to any of the preceding items or an optoelectronic device, in particular a μ-LED according to any of the preceding items, further comprising:
   applying of a photonic structure, in particular a photonic structure with features according to any of the preceding items on a side of the semiconductor structure or the optoelectronic component lying in the main emission direction.
   191. Method for producing optoelectronic devices from a semiconductor structure according to any of the preceding items, comprising,
separating, especially by an etching process of the individual optoelectronic components.
   192. μ-LED, or optoelectronic device, comprising a stack of layers in which
   layers extending along an X-Y plane are stacked together along a Z-axis perpendicular to the X-Y plane;
   wherein a main direction of movement of charge carriers, in particular electrons, runs along the Z-axis of the layer stack; wherein a magnetizing element provides magnetic field lines by means of which the moving charge carriers are kept away from edge regions of X-Y cross-sectional areas of the layer stack.
   193. μ-LED according to any of the preceding items, in particular according to any of the items 120a to 191, wherein a main direction of movement of charge carriers, in particular electrons, along a Z-axis passes through the μ-LED;
   and a magnetizing element provides magnetic field lines by means of which the moving charge carriers are kept away from edge regions of X-Y cross-sectional areas of the layer stack.
   194. μ-LED according to item 193, characterized in that
   the magnetizing element of at least one part along the Z-axis of the stack of layers providing magnetic field lines along the X-Y plane.
   195. μ-LED according to item 193 or 194, characterized in that the magnetization element in the region of an active layer and/or against the main direction of movement of the charge carriers in a region in front of the active layer provides the magnetic field lines running towards a pole of a magnetic dipole, in particular south pole, or along the Z-axis.
   196. μ-LED according to any of the preceding items, characterized in that
   the magnetising element provides the magnetic field lines in the edge regions of the X-Y cross-sectional surfaces of the layer stack, or that the magnetising element is arranged on at least two opposite side surfaces of the layer stack.
   197. μ-LED according to one of the items 194 to 196, characterized in that
   the magnetizing element has a number of current lines on a lateral surface of the layer stack, wherein a current flow of one current line at a time is provided antiparallel to the current flow through the μ-LED.
   198. μ-LED according to item 197, characterized in that
   the number of current lines runs along the Z-axis, circulates the stack of layers along an X-Y plane and, in particular, four, six or eight current lines are formed.
   199. μ-LED according to item 197 or 198, characterized in that the current lines are generated in stripes.
   200. μ-LED according to any of the preceding items, characterized in that
   the magnetizing element is provided by means of a number of permanent magnet dipoles rotating the layer stack along an X-Y plane, in particular arranged in the region of the active layer and/or against the main direction of movement of the charge carriers in a region in front of the active layer; and/or in that
   the magnetizing element is created by means of a number of electromagnets circulating the layer stack along an X-Y plane, in particular arranged in the region of the active layer and/or against the main direction of movement of the charge carriers in a region in front of the active layer, the current flow of which electromagnets is provided in particular by means of the current flow through the optoelectronic component; and/or in that
   the magnetizing element was deposited as a magnetic material, in particular manganese, circulating the layer stack along an X-Y plane in the region of an active layer and/or against the main direction of movement of the charge carriers in a region in front of the active layer on a lateral surface of the layer stack and magnetized by means of an external magnetic field.
   201. μ-LED according to any of the preceding items, characterized in that
   the layer stack has an electrically insulating and/or passivating coating.
   202. μ-LED according to any of the preceding items, characterized in that
   the stack of layers on a carrier comprises a first layer on which an active layer is produced, to which a second is attached, wherein in particular a first contact is formed on a surface region of the second layer facing away from the support, and wherein in particular a second contact is formed by means of the carrier on the first layer.
   203. μ-LED according to item 202, characterized in that
   the first layer is n-doped and the second layer is p-doped, and in particular the first contact is provided as anode and the second contact as cathode.
   204. μ-LED according to any of the preceding items, in which the magnetizing element has dielectric properties so that light generated in the layer stack is reflected by the magnetizing element.
   205. Method for reducing non-radiative recombination, in particular in the region of an active layer of a μ-LED, in which layers extending along an X-Y plane are stacked together along a Z-axis perpendicular to the X-Y plane;
   wherein a main direction of movement of charge carriers runs along the Z-axis;
   wherein by means of a magnetizing element a provision of magnetic field lines is carried out, by means of which the charge carriers are kept away from edge regions of X-Y cross-sectional areas of the layer stack.
   206. Method according to any of the preceding items characterized by
   forming a number of current lines on a lateral surface of the layer stack in such a way that a current flow of one current line in each case flows antiparallel to the current flow through the optoelectronic component.
   207. Method according to any of the preceding items, characterised by
   forming of a number of permanent magnet dipoles on a lateral surface of the layer stack.
   208. Method according to any of the preceding items characterised by
   forming a number of electromagnets on a lateral surface of the layer stack.
   209. Method according to any of the preceding items, characterised by
   forming of a magnetic material on a lateral surface of the stack of layers.
   210. Method for producing at least one optoelectronic component, in particular a μ-LED arrangement, comprising the following steps:
generating a first contact area and a second contact area on a surface of a substrate 1, wherein a light emitting body is vertically created and its first contact is connected to the first contact area;
generating of a reflector structure surrounding the light-emitting body at a distance
generating a first metal mirror layer and a second metal mirror layer, wherein the first metal mirror layer electrically connects a contact layer attached to a second contact of the light-emitting body to the second contact region, and the second metal mirror layer is formed on the circumferential reflector structure.
   211. Method according to item 210, further comprising:
   applying of a planarization layer to form the reflector structure; and
   optional removal of the planarization layer over the second contact area, so that it remains openly accessible for the first metal mirror layer
   212. Method according to item 211, comprising:
   structuring of the planarization layer to form the reflector structure, which encloses the light-emitting body in a mechanically contacting manner;
   applying of the electrically connecting first metal mirror layer additionally to the reflector structure, especially electrically conductive to the second metal mirror layer.
   213. Method according to item 212, in which
   the enclosure frames the light-emitting body at a distance, in particular greater than five times the edge length of the light-emitting body.
   214. Method according to item 212, comprising
   applying of the second metal mirror layer on the main surface of the reflector structure facing away from the substrate.
   215. Method according to any of the preceding items, characterised by
   applying the second metal mirror layer to the edges of the reflector structure.
   216. Method according to item 215, in which a light extraction is adjusted by an angle of inclination of the edges of the reflector structure.
   217. Method according to item 216, comprising a
   generating the edges of the reflector structure in such a way that the circumference of the reflector structure increases with increasing distance from the substrate; or
   generating the edges of the reflector structure in such a way that the circumference of the reflector structure decreases with increasing distance from the substrate.
   218. Method according to any of the preceding items, further comprising
   applying a black layer, in particular an encapsulation layer, to the substrate, between edges of reflector structures, in particular up to the height of the edges.
   219. Method according to any of the preceding items, further comprising
   applying and optional structuring of a coating for sealing, encapsulation and/or optical coupling to the substrate or to the black layer, in particular up to a height above the first metal mirror layer.
   220. Method according to any of the preceding items, in which the layers are structured in the middle by means of photolithography.
   221. μ-LED device comprising at least one μ-LED, which comprises a light-emitting body, wherein
   said light emitting body is vertically generated and a first contact of said light emitting body is connected to a first contact area on one side of a substrate;
   on the same side of the substrate, a second contact of the light-emitting body remote from the substrate is connected to a second contact region by means of a transparent contact layer and a first metal mirror layer;
   a reflector structure surrounding the light emitting body, a second metal mirror layer being attached to the reflector structure.
   222. μ-LED arrangement according to item 221, wherein the reflector structure encloses the light-emitting body in mechanical contact along the X-Y plane, and in particular the first metal mirror layer is electrically conductive to the second metal mirror layer.
   223. μ-LED arrangement according to item 221 or 222, characterized by an enclosure which encloses the light-emitting body in a mechanically contacting manner, and the reflector structure frames the enclosure at a distance, in particular between 1 and 10 times, in particular more than five times of the edge length of the light-emitting body, the first metal mirror layer and the contact layer being additionally attached to the enclosure.
   224. μ-LED arrangement according to any of the preceding items, in which three light-emitting bodies each form a sub-pixel of a pixel.
   225. μ-LED arrangement according to any of the preceding items, in which the transparent contact layer is a transparent cover electrode extending over the light-emitting body to a top surface of the reflector structure.
   226. μ-LED arrangement according to any of the preceding items, further comprising a converter material disposed at least partially over the light-emitting body.
   227. μ-LED arrangement according to any of the preceding items, further comprising a light-shaping structure, in particular a microlens or a photonic structure having first and second regions of different refractive index, wherein one of the first and second regions extends at least partially into or is formed by the semiconductor material of the light-emitting body or is formed by the converter material.
   228. μ-LED arrangement according to any of the preceding items, in which a cavity is formed by the circumferential reflector structure, in which the light-emitting body is arranged and a remaining space in the cavity is filled with a converter material, in particular of quantum dots.
   229. μ-LED display having a plurality of μ-LED arrangement according to any of the preceding items or which have been produced by any of said methods and are arranged in rows and columns in a pixel array, a plurality of pixels each being surrounded by the reflector structure, the sidewalls of which are bevelled and provided with a metal mirror layer.
   230. Pixel with a μ-LED arrangement according to any of the preceding items with three vertically arranged light emitting bodies surrounded by a reflector structure arranged on a carrier substrate.
   231. Pixel for generating a pixel of a display, comprising:
a μ-LED arrangement according to any of the preceding items articles, in particular any of articles 221 to 229,
   wherein a conductor track is provided on the second contact layer forming the contacting layer, which track is electrically connected to the contacting layer over its surface;
   wherein the electrical conductivity of the conductive path is greater than an electrical conductivity of the contacting layer.
   232. Pixel for generating a pixel of a display, comprising
a flat carrier substrate;
at least one μ-LED, which is arranged on the carrier substrate
   wherein at least one μ-LED is adapted to emit light transverse to a carrier substrate plane in a direction away from the carrier substrate;
   wherein the at least one μ-LED has an electrical contact on its upper side directed away from the carrier substrate;
   wherein the pixel has an at least partially electrically conductive flat contacting layer on the upper side of the at least one μ-LED, which is electrically connected to the electrical contact of the at least one μ-LED;
   wherein the contacting layer is at least partially transparent for the light emitted by the at least one μ-LED;
   wherein a conductor track is provided on the contacting layer, which is electrically connected to the contacting layer over its entire surface;
   wherein the electrical conductivity of the conductive path is greater than an electrical conductivity of the contacting layer.
   233. Pixel according to item 231 or 232, wherein the conductor track is arranged between two μ-LEDs arranged adjacent on the carrier substrate outside a primary emission area.
   234. Pixel according to item 231 or 232, wherein the conductor track is configured to absorb and/or reflect light components outside the primary emission range for beam-shaping of the at least one μ-LED.
   235. Pixel according to any of the preceding items, wherein the conductor track has a light-absorbing layer on its side facing the carrier substrate.
   236. Pixel according to any of the preceding items, wherein the conductor track extends over a plurality of μ-LEDs in area and recesses are provided on the conductor path in the region of the respective primary emission areas of the μ-LEDs for passing the light emitted by the respective μ-LEDs.
   237. Pixel according to any of the preceding items, the conductor track being deposited on a side of the contacting layer facing away from the carrier substrate.
   238. Pixel according to any of the preceding items, wherein the conductor track is deposited on a side of the contacting layer facing the carrier substrate.
   239. Pixel according to item 238, where the conductor track is applied to the carrier substrate.
   240. Pixel according to any of the preceding items, wherein the at least one μ-LED is disposed in a cavity of the carrier substrate and the conductive path is disposed outside the cavity.
   241. Pixel according to any of the preceding items, where a converter material is arranged in the cavity.
   242. Pixel according to any of the preceding items, wherein a connecting element for electrically connecting the contacting layer to a terminal element of the carrier substrate is provided at the pixel element.
   243. Method of manufacturing pixel elements for producing a display, comprising
providing a flat carrier substrate and generating a plurality of light-emitting components, in particular μ-LEDs on the carrier substrate, each with an electrical contact on the upper side facing away from the carrier substrate;
applying of an at least partially electrically conductive flat contacting layer which is electrically connected to the electrical contacts of the plurality of light-emitting components; wherein the contacting layer is at least partially transparent for the light emitted by the plurality of light-emitting components;
providing a conductor track on the contacting layer, which is electrically connected to the contacting layer over the entire surface;
   wherein the electrical conductivity of the conductive path is greater than an electrical conductivity of the contacting layer.
   244. μ-LED arrangement comprising a substrate and at least one μ-LED raw chip fixed to one side of the substrate,
which has a first electrical contact on a side facing away from the substrate, which is electrically connected by means of a mirror coating to an electrical control contact on the surface of the substrate, and
wherein the mirror coating at least partially covers the substrate surface facing the at least one chip.
   245. μ-LED arrangement according to item 244, further comprising:
   a transparent cover electrode, which extends over the electrical contact and connects it to the mirror coating, the mirror coating being arranged at least partially below the cover electrode and spaced therefrom.
   246. μ-LED arrangement according to any of items 244 and 245, in which the control contact is not located below the cover electrode, and the mirror coating at least one area is not located below the cover electrode.
   247. μ-LED arrangement according to any of the preceding items, in which the mirror has a metal mirror, in particular comprising at least one of the following metals: Al, Ag, AgPdCu, Nd, Nb, La, Au, Cu, Pd, Pt, Mg, Mo, Cr, Ni, Os, Sn, Zn and combinations of the above.
   248. μ-LED arrangement according to any of the preceding items, wherein
   the cover electrode has an electrically conductive oxide layer, in particular a material comprising IGZO, metal oxides, zinc oxide, tin oxide, cadmium oxide, indium-doped tin oxide (ITO), aluminium-doped (AZO), Zn₂SnO₄, CdSnO₃, ZnSnO₃, In₄Sn₃O₁₂ or mixtures of different transparent conductive oxides.
   249. μ-LED arrangement according to any of the preceding items, wherein the substrate comprises a border at least partially surrounding the at least one μ-LED raw chip, on the upper side of which border the mirror coating is arranged, which there is electrically connected to the cover electrode surface.
   250. μ-LED arrangement according to any of the preceding items, wherein the substrate has a cavity in which the at least one μ-LED die is disposed, the cavity having a depth substantially equal to a height of the at least one die.
   251. μ-LED arrangement according to any of the preceding items, in which an insulating planar isolation layer is provided around the μ-LED raw chip, the height of which is substantially less than or equal to a height of the μ-LED raw chip.
   252. μ-LED arrangement according to any of the preceding items, in which the insulating planar insulating layer, at least partially between the cover electrode layer and the mirroring layer, extends in particular above the substrate between μ-LED chip and surrounding border.
   253. μ-LED arrangement according to one of the objects 239 to 252, in which mirroring extends at least partially on a side surface of the border facing the μ-LED raw chip, and the side surface in particular extends at a bevelled angle to the surface of the substrate.
   254. μ-LED arrangement according to any of the preceding items, wherein direct electrical contact of the cover electrode with the mirror coating is provided by means of a via or via of the mirror coating material through the insulating layer.
   255. μ-LED arrangement according to any of the preceding items, wherein the insulating layer is chamfered at a distance from the μ-LED raw chip in at least one region and the cover electrode extends in the direction of the mirroring thereof.
   256. μ-LED arrangement according to item 255, in which the edges of the bevelled area have a flat pitch angle.
   257. μ-LED arrangement according to any of the preceding items, in which the μ-LED raw chip has a second electrical contact directly connected to a contact on a surface of the substrate.
   258. Pixel with a μ-LED arrangement according to any of the preceding items, in which a red, a green and a blue light-providing μ-LED raw chip is fixed on the substrate, the first electrical contacts of which are connected to the conductive reflective layer via a transparent conductive cover electrode.
   259. Pixel according to item 258, in which the μ-LED raw chips are surrounded by a common border or arranged in a common cavity.
   260. Pixel according to any of the preceding items, in which areas on the substrate between the μ-LED raw chips are at least partially covered with a reflective layer, in particular the mirror layer.
   261. Pixel according to any of the preceding items, in which the μ-LED raw chips are embedded in a transparent and non-conductive material.
   262. Pixel according to any of the preceding items, in which the substrate has leads configured to individually control each of the μ-LED die.
   263. Pixel according to any of the preceding items, in which the substrate has TFT structures and electrical leads for an individual power supply to each μ-LED raw chip.
   264. Pixel according to any of the preceding items, further comprising a light-shaping patterned layer on or in the transparent cover electrode, which has a lenticular element, a photonic crystal or a quasi-crystal structure and is adapted to suppress or reduce light emitted parallel to a surface of the substrate.
   265. Pixel according to any of the preceding items, in which the transparent cover electrode is structured, in particular to collimate and radiate light in a direction away from the substrate surface, or to couple out light.
   266. Pixel according to any of the preceding items, in which a converter material for light conversion is arranged at least above and/or around one of the μ-LED raw chips, wherein the converter material can be electrically insulated from the transparent cover electrode in particular by an insulating layer.
   267. μ-display module with a large number of pixels according to any of the preceding items, arranged in rows and columns and individually controllable.
   268. μ-display module according to item 267, in which pixels arranged in a row have a common cover layer and a common electrical control contact.
   269. μ-display module according to any of the preceding items, in which the μ-pixels are separated from each other by a raised area on the substrate.
   270. μ-display module according to any of the preceding items, wherein the substrate has a plurality of cavities separated from one another, one of the plurality of μ-pixels being located in each of the cavities.
   271. μ-display module according to the preceding item, in which a converter material for light conversion, in particular with quantum dots, is incorporated in at least some cavities.
   272a. μ-display module according to any of the preceding items, in which sidewalls of the elevation or the sidewalls between the cavities comprise a reflective layer, especially the mirror coating.
   272b. μ-display module according to any of the preceding items, in which the substrate comprise conductive structures, in particular according to any of the preceding or subsequent items, which are configured to address and drive the μ-pixels individually.
   273a. method for producing a μ-pixel comprising the steps of:
providing a substrate with a number of contacts on the surface;
attaching at least one μ-LED raw chip to one of the contacts, the μ-LED raw chip having a further contact on its side facing away from the substrate surface;
providing a reflective layer on the substrate surface, which is electrically connected to an electrical control contact on the surface of the substrate and at least partially covers the surface;
forming of a transparent cover electrode on the further contact, which electrically contacts the reflective layer.
   273b. Method according to any of the preceding items, in which the substrate has an elevation which at least partially surrounds the at least one μ-LED raw chip.
   273c. Method according to any of the preceding items, wherein the mirror coating is applied at least partially to sidewalls of the elevation or cavity, in particular those facing the μ-LED raw chips.
   273d. Method according to any of the preceding items, further comprising:
depositing a transparent insulating layer on the substrate surface and surrounding the at least one μ-LED raw chip; wherein the cover electrode is deposited on the transparent insulating layer.
   273e. Method according to any of the preceding items, further comprising at least one of the following steps:
forming an overlapping contact of the cover electrode surface and a mirroring surface in the area of the elevation or at the end of the cavity remote from the at least one μ-LED raw chip; or
forming a through hole through a transparent insulating layer, and filling the through hole so that the cover electrode contacts the reflective layer thereover; or
applying of a conductive connection on bevelled sides of the transparent insulating layer, which contacts the transparent cover electrode with the reflective layer.
   273f. Method according to any of the preceding items, further comprising:
mirroring of a part of the substrate surface between the μ-LED raw chips, in particular applying of the mirroring layer substrate surface between the μ-LED raw chips
   273g. Method according to any of the preceding items, further comprising:
   forming a patterned layer on the transparent cover electrode having a photonic crystal or quasi-crystal structure and adapted to suppress or reduce light emitted parallel to a surface of the substrate.
   273h. Method according to any of the preceding items, further comprising:
   structuring of the transparent cover electrode, in particular to collimate light and emit it directed away from the substrate surface, or to couple out light.
   273i. Method according to any of the preceding items, further comprising:
   applying of a converter material for light conversion over at least one of the μ-LED raw chips, the converter material being electrically insulated from the transparent cover electrode in particular by an insulating layer.
   274. μ-LED device comprising:
   a carrier substrate;
   a column connected at least indirectly to the carrier substrate and pointing in a longitudinal direction from the latter, in particular a nanopillar with a semiconductor sequence, which comprises at least one active layer,
   wherein the active layer is formed for the emission of electromagnetic radiation and is arranged such that at least part of the radiation emission is transverse to the longitudinal direction;
   characterised in that
   a reflector device is arranged on the carrier substrate laterally to the column, which deflects the radiation emission transversely to the longitudinal direction at least partially into a main radiation direction running parallel to the longitudinal direction.
   275. μ-LED device according to item 274, characterized in that the reflector device comprises a first reflective optical element and a second reflective optical element arranged on different sides of the column.
   276. μ-LED device according to any of the preceding items, characterized in that the reflector device is arranged between two columns.
   277. μ-LED device according to any of the preceding items, characterized in that the reflector device comprises a shaped layer monolithically formed with a layer of the semiconductor sequence of the column.
   278. μ-LED device according to any of the preceding items, characterized in that the reflector device comprises a metallic reflective layer and/or a Bragg mirror.
   279. μ-LED device according to any of the preceding items, characterized in that the reflector device comprises a Fresnel lens array.
   280. μ-LED device according to any of the preceding items, characterized in that a wavelength conversion element is arranged in the beam path between the column and the reflector device.
   281. μ-LED device according to item 280, characterized in that a first wavelength conversion element associated with a first column is applied for emitting electromagnetic radiation, which is spectrally different from the emission of a second wavelength conversion element associated with a second column.
   282. μ-LED device according to item 280 or 281, in which the wavelength conversion element comprises a converter material, in particular an inorganic dye or quantum dots.
   283. μ-LED device according to any of the preceding items, characterized in that the reflector device comprises an optical separation element arranged between adjacent columns.
   284. μ-LED device according to any of the preceding items, in which the reflector arrangement in plan view is formed as a four-sided pyramid and the side surface of each of which faces a column.
   285. μ-LED device according to any of the preceding items articles, characterized in that the μ-LED array comprises a plurality of columns and a plurality of reflector devices disposed on the support substrate adjacent the columns, the columns and the reflector devices forming a matrix array.
   286. μ-LED device according to any of the preceding items, further comprising a light-shaping structure, in particular a microlens or a photonic structure, extending across the column towards the reflector structure, in particular towards the reflector structure on each side
   287. μ-LED device according to any of the preceding items, in which the light-shaping structure extends at least partially into the column and/or reflector structure.
   288. Method for producing a μ-LED device comprising the steps: applying of at least one column, in particular a nanopillar with an at least indirect connection to a carrier substrate, wherein the nanopillar comprises a semiconductor sequence with at least one active layer formed for the emission of electromagnetic radiation; and
   wherein the active layer is applied so that at least part of the radiation emission is transverse to the longitudinal direction,
   characterised in that
   a reflector device is arranged on the carrier substrate laterally to the nanopillar, which redirects the radiation emission transversely to the longitudinal direction at least partially into a main radiation direction running parallel to the longitudinal direction.
   289. Method according to item 288, characterized in that at least one form layer of the reflector device and/or a layer of the semiconductor sequence of the column are structured photolithographically.
   290. Method according to item 289, characterized in that at least one shaped layer of the reflector device is structured by an anisotropic etching process and an etch stop layer is used between the shaped layer and the column.
   291. Method according to any of the preceding items, characterized in that a shaped layer of the reflector device and/or a layer of the semiconductor sequence of the column is grown epitaxially.
   292. Method according to any of the preceding items, characterized in that at least one reflector surface of the reflector device is formed by a nano-stamping process.
   293. Method according to any of the preceding items, further comprising introducing a converter material into a space between the reflector structure and the column, the converter material comprising in particular an inorganic dye and/or quantum dots.
   294. Method according to any of the preceding items, further comprising depositing and subsequent patterning a layer over the column and reflector structure to produce a light-shaping structure.
   295. Method according to the preceding item in which microlenses are formed over the column and reflector structure.
   296. μ-displays having a plurality of μ-LED devices according to any of the preceding items, wherein columns of the plurality of μ-LED arrays are arranged in rows and columns.
   297. An optoelectronic device, in particular a display device or headlamp, comprising
at least one light source with a semiconductor layer sequence, which comprises an active zone for generating light
   wherein a light exit surface for the generated light is formed on an upper side of the light source,
   wherein the light source comprises, in addition to the upper side, at least one further boundary surface which delimits the light source to the side and/or downwards,
   characterised in that
   a dielectric reflector is arranged at the interface, which is configured to reflect the generated light.
   298. Optoelectronic device according to item 297, characterised in that
   the interface has a lateral surface circumferentially surrounding the light source and a lower surface, the lower surface being opposite the upper surface.
   299. Optoelectronic device according to item 298, characterised in that
   the dielectric reflector is arranged exclusively on the lateral surface or exclusively on the underside, or
   in that the dielectric reflector is arranged both on the side surface and on the underside.
   300. Optoelectronic device according to any of the preceding items, characterized in that
   with the exception of the upper side, the dielectric reflector is arranged over the entire boundary surface bounding the light source.
   301. Optoelectronic device according to any of the preceding items, characterized in that the dielectric reflector is formed on two opposite side faces of the light source.
   302. Optoelectronic device according to any of the preceding items, characterized in that the dielectric reflector comprises a sequence, in particular a periodic or non-periodic sequence, of two alternating layers of material, which have different refractive indices.
   303. Optoelectronic device according to any of the preceding items, in which the dielectric reflector is configured with at least one contacting conductive layer, which electrically connects a contact of the light source in such a way that a current direction within the semiconductor layer sequence, is opposite to a current direction through the conductive layer.
   304. Optoelectronic device according to item 301, in which the conductive layer is substantially parallel along a lateral surface of the semiconductor layer sequence
   305. Optoelectronic device according to any of the preceding items 302 to 304, in which the contacting conductive layer of the dielectric reflector is formed on two opposite side surfaces and a dielectric reflector without such a contacting conductive layer is formed on the other two side surfaces.
   306. Optoelectronic device according to any of the preceding items, characterized in that
   the thickness of the layers of material is adapted to a wavelength of the emitted light in such a way that the dielectric reflector reflects light of that wavelength.
   307. Optoelectronic device according to any of the preceding items, characterized in that
   the dielectric reflector is configured as a Bragg mirror.
   308. Optoelectronic device according to any of the preceding items, further comprising:
   a converter material on the light-emitting surface, wherein the converter material comprises an inorganic dye or quantum dots.
   309. Optoelectronic device according to any of the preceding items, further comprising
   a light-shaping structure on the light-emitting surface, in particular a photonic structure or a microlens.
   310. Optoelectronic device according to the preceding item, in which the light-shaping structure comprises at least one of the following characteristics:
the light-shaping structure comprises periodic regions of different refractive index;
the light-shaping structure comprises first and second regions of different refractive index; wherein converter material forms the first regions; and
the light-forming structure is at least partially formed in the semiconductor layer sequence.
   311. μ-display array or monolithic array or headlight array, comprising a plurality of optoelectronic devices according to any of the preceding items, the light sources of the optoelectronic devices being arrayed.
   312. μ-display arrangement according to any of the preceding items, characterized in that
   the light sources of the optoelectronic devices are embedded in a carrier, in particular in such a way that only the light exit surfaces of the light sources constitute free, external surfaces, while the remaining interfaces of the light sources are surrounded by material of the carrier.
   313. Method for producing an optoelectronic device, in particular a display device or headlamp, in which:
   an optoelectronic light source based on semiconductor materials is provided, the light source having an active zone for generating light and a light exit surface for the generated light at an upper side, and
   a dielectric reflector is arranged at an interface of the light source, preferably not comprising the upper side, which is designed to reflect the light generated, the interface delimiting the light source laterally and/or downward.
   314. Method for producing an optoelectronic device, in particular a display arrangement or a headlight arrangement, in which method the light sources of a plurality of optoelectronic devices are arranged in an array according to any of the preceding items and are embedded in a carrier in such a way that only the top sides with light exit surfaces of the light sources represent free, external surfaces and otherwise material of the carrier surrounds the interfaces of the light sources.
   315. Method for producing a μ-display, a monolithic array or a headlamp assembly, in particular comprising a plurality of optoelectronic devices according to any of the preceding items, in which method
   optoelectronic light sources based on semiconductor materials are formed in an array on a carrier in such a way that each light source comprises an active zone for generating light and a free, external top surface on the top side as a light exit surface for the light,
   wherein for each light source a dielectric reflector is arranged on at least one boundary surface, which delimits the light source laterally and/or downwardly with respect to a material of the carrier, which reflector is configured to reflect the light generated in the light source.
   316. Method according to any of the preceding items, characterised in that
   the arrangement of the dielectric reflector comprises applying material for the dielectric reflector by means of atomic layer deposition.
   317. Method according to any of the preceding items, characterised in that
   arranging the dielectric reflector comprises arranging the material for at least one layer of the dielectric reflector by means of a first method and arranging the material for the other layers by means of a second method, preferably the first method is a vapour phase deposition method, and preferably the second method is atomic layer deposition.
   318. Method for producing a μ-display, in particular with a plurality of optoelectronic devices according to any of the preceding items, in which method
   optoelectronic light sources based on semiconductor materials can be arranged in an array on a carrier in such a way that each light source comprises an active zone for generating light and, on the upper side, a free, external upper side as light exit surface for the light,
   wherein the light sources are arranged in such a way that there is at least a slight gap between adjacent light sources on the upper side with an intermediate space behind it,
   wherein for each light source a dielectric reflector is arranged at at least one boundary surface, which delimits the light source laterally and/or downwardly with respect to a material of the support, which reflector is configured to reflect the light generated in the light source, and
   wherein the dielectric reflectors of the light sources are formed by introducing material for the dielectric reflectors from the top side into the respective gap between adjacent light sources, in particular by means of atomic layer deposition, and the dielectric reflectors are formed in the respective space located behind a gap.
   319. Method according to item 318, characterised in that at least the light emission surfaces of the light sources are covered, in particular with a photomask, while the dielectric reflectors are formed in the interspaces.
   320. μ-LED device or optoelectronic device comprising:
at least one semiconductor element, in particular a μ-LED with an active zone designed to generate light
a dielectric filter disposed above a first major surface of said at least one semiconductor element and adapted to transmit only light in predetermined directions, and
a reflective material disposed on at least one side surface of said at least one semiconductor element and on at least one side surface of said dielectric filter.
   321. μ-LED device according to item 320, wherein at least one side surface of the at least one semiconductor element is inclined at the height of the active region.
   322. μ-LED device according to any of the preceding items, wherein
   the at least one semiconductor element has a first terminal and a second terminal, and
   the reflective material is electrically conductive and is coupled to the first terminal of the at least one semiconductor element.
   323. μ-LED device according to any of the preceding item, characterized in that the reflective material is conductive only on two opposite side faces of the light source in such a way that it contacts the first terminal for power supply.
   324. μ-LED device according to any of the preceding item, characterized in that the reflecting material on the other two sides is non-conductive, such that it is isolated from the connection to the power supply.
   325. μ-LED device according to any of the preceding items, in which the dielectric filter is formed at least partially in a layer of the semiconductor element adjacent to the direction of emission.
   326. μ-LED device according to any of the preceding items, wherein the dielectric filter has first and second regions of different refractive index; wherein converter material forms said first regions.
   327. μ-LED device according to any of the preceding items, wherein
the at least one semiconductor element comprises a second major surface opposite the first major surface, and
a reflective layer is disposed below the second major surface of the at least one semiconductor element.
   328. μ-LED device according to any of the preceding items, wherein the reflective layer is at least partially electrically conductive and is coupled to the second terminal of the at least one semiconductor element.
   329. μ-LED device according to item 323, wherein the reflective layer is electrically insulating and one or more electrically conductive layers are arranged above and/or below the reflective layer.
   330. μ-LED device according to any of the preceding items, wherein an electrically insulating first material is disposed between the reflecting material and the reflecting layer, the electrically insulating first material comprising in particular a lower refractive index than the at least one semiconductor element.
   331. μ-LED device according to any of the preceding items, wherein a layer having a roughened surface is disposed between the at least one semiconductor element and the dielectric filter.
   332. μ-LED device according to any of the preceding items, further comprising
a converter material on the light-emitting surface, the converter material comprising an inorganic dye or quantum dots; or
a converter material between the dielectric filter and the μ-LED, wherein the converter material comprises an inorganic dye or quantum dots.
   333. μ-LED device according to any of the preceding items, wherein the first major surface of said at least one semiconductor element has a roughened surface.
   334. μ-LED arrangement according to any of the preceding items, wherein the at least one semiconductor element has a lateral dimension of not more than 50 μm and/or a height of not more than 2 μm.
   335. μ-LED device according to any of the preceding items, wherein said at least one semiconductor element comprises a plurality of semiconductor elements arranged in an array, adjacent semiconductor elements being separated from each other by the reflective material.
   336. μ-LED device according to item 330, where the reflective material is electrically conductive and the first terminals of the semiconductor elements are connected to a common external terminal via the reflective material.
   337. μ-LED device according to any of the preceding items, wherein the at least one semiconductor element comprises a plurality of semiconductor elements arranged side by side with an electrically insulating second material disposed between adjacent semiconductor elements.
   338. μ-LED device according to any of the preceding items, wherein the reflective material is electrically conductive and conductive tracks extend above and/or below and/or within the electrically insulating second material connecting the first terminals of the semiconductor elements to a common external terminal.
   339. μ-LED device according to any of the preceding items, whereby the second connections of the semiconductor elements can be individually controlled.
   340. μ-LED device according to any of the preceding items, further comprising a microlens positioned above the dielectric filter.
   341. Method of manufacturing a μ-LED device or optoelectronic component, comprising
providing at least one semiconductor element, in particular a μ-LED according to one of the preceding or following items with an active zone configured to generate light is provided,
disposing a dielectric filter above a first major surface of the at least one semiconductor element, the dielectric filter being adapted to transmit only light in predetermined directions, and
   disposing a reflective material on at least one side surface of said at least one semiconductor element and on at least one side surface of said dielectric filter.
   342. Pixel with several μ-LEDs for generating a pixel of a display, where
   the pixel is formed from at least two subpixels, in particular two subpixels of the same color emission, and in particular each subpixel is formed by a μ-LED;
   wherein a subpixel separating element is provided between two adjacent subpixels of the same pixel element; and
   wherein the subpixel separating element is configured to be separating with respect to electrical control of the respective subpixels and is configured to be optically coupling with respect to the light emitted by the respective subpixels.
   343. Pixel according to item 342, wherein the subpixels have a common epitaxial layer and the subpixel separating element extends trench-like into the epitaxial layer transversely to an epitaxial layer plane in a main emission direction.
   344. Pixel according to any of the preceding items, wherein the subpixels of the pixel are independently electrically contactable and/or controllable.
   345. Pixel according to any of the preceding items, in which the at least two sub-pixels have a common active layer separated by the sub-pixel separator.
   346. Pixel according to any of the preceding items, in which the subpixel separator extends to or at least partially through an active layer of the pixel.
   347. Pixel according to any of the preceding items, in which the subpixel separation element is formed by quantum well intermixing generated by a diffused dopant, in particular in the region of the active layer.
   348. Pixel according to any of the preceding items, in which a light-shaping structure is formed having first and second regions, the regions extending at least partially into a semiconductor material of the pixel.
   349. Pixels according to item 348, wherein the light-shaping structure extends into a partial area of the active layer.
   350. Pixel according to any of the preceding items, in which the light-shaping structure has a converter material in second areas.
   351. Pixel according to any of the preceding items with a light-shaping or photonic structure having features according to any of the following or preceding items
   352. Pixel according to any of the preceding items, further comprising a microlens extending over the surface of a pixel.
   353. Pixel according to any of the preceding items, in which a transparent conductive layer is formed on a surface.
   354. Pixel according to any of the preceding items, wherein at least one contact surface for contacting at least one subpixel is provided on a side opposite to the light emission side.
   355. Display with a large number of pixels according to any of the preceding items,
   wherein a pixel element separation layer is provided between two adjacent pixels, which is adapted to separate electrically the adjacent pixels with respect to the controlling of the respective pixels and to separate optically the adjacent pixels with respect to the light emitted by the pixels.
   356. Display according to item 355, wherein the pixels and the associated sub-pixels have a common epitaxial layer and the pixel element separation layer extends trench-like into the epitaxial layer transversely to the epitaxial layer plane in the main emission direction.
   357. Display according to any of the preceding items, wherein a trench depth dl of the pixel element separation layer is greater than a trench depth of the sub-pixel separation element.
   358. Display according to any of the preceding items, in which adjacent pixels or sub-pixels comprise an active layer separated by a pixel element separation layer and/or a sub-pixel separation element.
   359. Display according to any of the preceding items, further comprising a support layer having contact areas corresponding to contact areas of pixels, wherein in the support layer at least one of the following elements is provided:
electrically conductive lines to a power supply of the pixel,
Current driver circuits or supply circuits, in particular according to any of the items 836 to 930;
Control circuit for adjusting a brightness;
one or more fuses that are electrically connected to at least one subpixel of a pixel.
   360. Method for calibrating a pixel, comprising the steps of:
driving a subpixel of a pixel according to any of the item 836 to 930;
acquiring of defect information of a subpixel;
storing of the defect information in a memory unit of the control unit.
   361. Method according to item 360, wherein the driving, acquisition and storage is performed sequentially for all individual subpixels of a pixel
   362. Array with at least two μ-LEDs, wherein a respective μ-LED between an n-doped layer and a p-doped layer forms an active zone suitable for light emission, characterized in that between two adjacent formed μ-LEDs material of the layer sequence from the n-doped side and from the p-doped side up to or in cladding layers or up to or at least partially into the active zone is interrupted or removed in such a way that material transitions with a maximum thickness dC are formed, whereby electrical and/or optical conductivities in the material transition are reduced.
   363. Array according to any of the preceding items, characterized in that, at the material transition, the active zone and, at least on one side of the active zone, a residual layer of small thickness.
   364. Array according to item 362 or 363, characterized in that the removed material is at least partially replaced by a filling material.
   365. Array according to any of the preceding item, characterized in that
   the removed material is at least partially replaced by a material comprising a relatively small band gap and thus absorbing light of the active zone.
   366. Array according to any of the preceding items, characterized in that
   the removed material is at least partially replaced by a material with an increased refractive index, in particular greater than the refractive index of the doped material or a filler material.
   367. Array according to any of the preceding items, characterized in that
   the light absorbing material and/or the material with increased refractive index has been applied to a respective material transition.
   368. Array according to any of the preceding items, characterised in that the material has been formed with an increased refractive index by diffusing or implanting a refractive index-increasing material into the filling material, in particular into a respective cladding layer.
   369. Array according to any of the preceding items, characterised in that
   a material for increasing light absorption and/or a material for increasing electrical resistance has been diffused or implanted into the active zone of a respective material transition.
   370. Array according to any of the preceding items, characterised in that
   along the material transitions, at or in these, at least one optical structure, in particular a photonic crystal and/or a Bragg mirror, is generated.
   371. Array according to any of the preceding items, characterised in that
   an electrical bias voltage is applied to the two main surfaces of the material transitions by means of two opposite electrical contacts and an electrical field is generated by a respective material transition.
   372. Array according to any of the preceding items, characterised in that
   by means of an n-doped material and/or p-doped material applied or grown on at least one of the two main surfaces of the material transitions, an electric field is generated by a respective material transition.
   373. Array according to any of the preceding items, characterised in that
   the exposed main surfaces of the material transitions and/or exposed surface regions of the μ-LED are electrically insulated and passivated by means of a respective passivation layer, in particular comprising silicon dioxide.
   374. Array according to any of the preceding items, characterised in that
   the main surfaces of the μ-LED by contact layers are electrically contacted.
   375. Array according to any of the preceding items, characterised in that
   the material and/or the material transitions between one μ-LED and its adjacent μ-LEDs are formed differently from one another, in particular depending on the direction.
   376. Array according to any of the preceding items, further comprising a light-shaping structure which is applied to a surface of the array facing the main emission direction, which in particular has a photonic structure with features according to any one of the following or previous items.
   377. Array according to any of the preceding items, in which the light-shaping structure has areas of different refractive index.
   378. Array according to item 376, in which the light-shaping structure extends into the semiconductor material of the μ-LED
   379. Array following any of items 376 to 378, in which portions of the light-shaping structure are filled with a converter material.
   380. Array according to any of the preceding items, further comprising a converter material applied to a surface facing the main radiation direction.
   381. Method for producing an array of optoelectronic pixels, in particular a micropixel emitter array or a micropixel detector array, comprising the steps:
providing a whole-surface layer sequence of an n-doped layer and a p-doped layer along the array, between which an active zone suitable for light emission is formed;
at least partially removing of material between adjacent pixels to be formed from the n-doped side and from the p-doped side so that a material transition with a maximum thickness dC remains, which comprises the active zone, such that the electrical and/or optical conductivities between adjacent pixels are reduced.
   382. Method according to item 381, wherein the step of removing material comprises removing the layer sequence from the n-doped side and from the p-doped side up to or into undoped cladding layers or up to or at least partially into the active zone.
   383. Method according to item 381, characterized in that from the n-doped side and/or from the p-doped side the removed material is at least partially replaced by a filler material.
   384. Method according to any of the preceding items, characterised in that
   the removed material is at least partially replaced from the n-doped side and/or from the p-doped side by a material having a relatively small band gap and thus absorbing light of the active zone.
   385. Method according to any of the preceding items, characterised in that
   the removed material is replaced from the n-doped side and/or from the p-doped side by a material with an increased refractive index, in particular greater than the refractive index of the doped material or a filler material.
   386. Method according to any of the preceding items, characterised in that
   the light absorbing material and/or the material with increased refractive index is applied to a respective material transition.
   387. Method according to any of the preceding items, characterised in that
   the material with increased refractive index is formed by diffusing or implanting a material increasing the refractive index into the filling material, in particular into a respective cladding layer.
   388. Method according to any of the preceding items, characterised in that
   a material for increasing light absorption and/or a material for increasing electrical resistance is diffused or implanted into the active zone from the n-doped side and/or from the p-doped side.
   389. Method according to any of the preceding items, characterised in that
   at least one optical structure, in particular a photonic crystal and/or a Bragg mirror, is generated from the n-doped side and/or from the p-doped side along the material transitions, at or in these.
   390. Method according to any of the preceding items, characterized in that
   two electrical contacts opposite each other are formed from the n-doped side and from the p-doped side for applying an electrical bias voltage to the two main surfaces of the material transitions and for generating an electric field through a respective material transition.
   391. Method according to any of the preceding items, characterised in that
   by means of an n-doped material and/or p-doped material applied or grown on at least one of the two main surfaces of the material transitions, an electric field is established through a respective material transition.
   392. Method according to any of the preceding items, characterised by
   electrically insulating and passivating the exposed main surfaces of the material transitions and/or exposed surface areas of the pixels by means of a respective passivation layer, in particular comprising silicon dioxide.
   393. Method according to any of the preceding items, characterised by
   electrical contacting of the main surfaces of the pixels by means of contact layers.
   394. Method according to any of the preceding items, characterised in that
   the material and/or the material transitions between a pixel and its neighbouring pixels are formed differently from one another, in particular depending on the direction.
   395. Method according to any of the preceding items, characterised in that
   the steps are first performed for one major surface of the array and then, after a substrate change, for the other major surface of the array.
   396. Carrier structure with flat optoelectronic components, especially μ-LEDs, comprising
a flat carrier substrate, and
at least two receiving elements that are designed to hold a first μ-LED detachably between the at least two receiving elements in such a way that the μ-LED can be moved out with a defined minimum force perpendicular to a carrier structural plane; wherein at least one receiving element of the at least two receiving elements is designed to simultaneously hold and/or support a second, adjacently arranged μ-LED.
   397. Carrier structure according to item 396, wherein the receiving elements are arranged on the support substrate in such a way that the μ-LED is held by three receiving elements.
   398. Carrier structure according to item 396, wherein at least two receiving elements of the three receiving elements are configured to hold and/or support a further adjacent μ-LED.
   399. Carrier structure according to one of the items 396 to 398, wherein a delamination layer is provided, which is arranged between the receiving element and the μ-LED and remains on the receiving element in particular after the μ-LED has been moved out.
   400. Carrier structure according to any of the preceding items, wherein the receiving elements are arranged in a mesa trench of a semiconductor wafer.
   401. Carrier structure according to any of the preceding items, in which the support substrate and the receiving elements are made in one piece.
   402. Carrier structure according to any of the preceding items, wherein the support elements are configured to hold a μ-LED laterally and from a bottom side of the μ-LED.
   403. Carrier structure according to any of the preceding items, wherein the receptacle elements have μ-LED holding surfaces which are inclined relative to the carrier substrate plane so that a holding force on the μ-LED is reduced when the μ-LED is moved away from the receptacle elements.
   404. Carrier structure according to any of the preceding items, wherein at least one of the receiving elements is adapted to receive a lateral corner portion or side surface of a μ-LED.
   405. Carrier structure according to any of the preceding items, wherein a contact area between the receiving element and μ-LED is less than 1/20, in particular less than 1/50 of a total area of the μ-LED.
   406. Carrier structure according to any of the preceding items, in which the first μ-LED and second μ-LED partially rest on the at least one receiving element, and between the first and second μ-LED a part of the surface of the receiving element is exposed or rises between the first and second μ-LED.
   407. μ-LED with a semiconductor layer stack which comprises an active layer and which is arranged on a carrier structure according to any of the preceding items.
   408. μ-LED according to item 407, said LED comprising a peripheral region formed by the mesa trench, wherein the active layer in said peripheral region has a band gap increased by quantum well intermixing.
   409. μ-LED according to any of the preceding items, in which an edge region comprises a protuberance, which is arranged on the support structure.
   410. Carrier structure according to any of the preceding items articles containing a μ-LED, in particular a μ-LED according to any of the preceding items.
   411. Method for transferring at least two μ-LEDs, in particular optoelectronic components, wherein the at least two μ-LEDs are arranged on a common receiving element of a carrier and the carrier comprises a sacrificial layer on which the μ-LEDs are arranged, comprising the steps:
removing of the sacrificial layer on which the μ-LEDs are arranged, so that the μ-LEDs are held by the common receiving element;
removing at least one of the at least two μ-LEDs from the common mounting element.
   412. Method for producing a μ-LED, comprising the steps:
providing of a substrate;
applying of a sacrificial layer, in particular comprising AlGaAs or InGaAlP, to the substrate;
creating a functional layer stack with an active layer between oppositely doped semiconductor layers;
applying of a first electrically conductive contact layer on a first major surface side of the functional layer stack;
forming at least one holding structure which is attached to the substrate, supports the functional layer stack and from which a contacted functional layer stack can be broken off during lift-off;
at least partial removing of the sacrificial layer located between a second major surface side of the functional layer stack and the substrate;
applying a second electrically conductive contact layer to the second main surface side of the functional layer stack in the area of the removed sacrificial layer.
   413. Method according to item 412, wherein the step of generating a functional layer stack comprises the step of forming one or more quantum wells or quantum wells in the active layer.
   414. Method according to any of the preceding items, wherein the step of creating a functional layer stack comprises the step of:
forming of a quantum well intermixing in edge regions of the active layer and/or in regions, which are at least adjacent to the retaining structure or adjacent to a possible break-off edge.
   415. Method according to item 414, wherein the step of forming a quantum well intermixing comprises:
providing a structured photomask on the functional layer stack;
applying of a dopant with first process parameters;
diffusing and/or formation of quantum well intermixing with second process parameters.
   416. Method according to any of the preceding items, in which the step of creating a functional layer stack comprises the step forming a quantum well intermixing with features according to any of the preceding items.
   417. Method one of the previous articles, further comprising: lifting the contacted functional layer stack by breaking it off the holding structure and positioning it on a secondary substrate.
   418. Method according to any of the preceding items, in which the step of forming the support structure comprises forming of the retaining structure, in particular having a conical shape, on the functional layer stack from its first main surface side into the substrate.
   419. Method according to any of the preceding items, in which the step of applying a first electrically conductive contact layer comprises:
   Application of a first bearing layer to the functional layer stack on its first main surface side;
   applying of the first electrically conductive contact layer to the first support layer, wherein the first support layer and the first electrically conductive contact layer are attached to the substrate at least at one point and thus form the support structure at least partially.
   420. Method according to any of the preceding items, wherein the step comprises applying a second electrically conductive contact layer:
   applying a second support layer to the second major surface side of the functional layer stack facing the substrate directly to the functional layer stack; and
   applying the second electrically conductive contact layer to the second base layer.
   421. Method according to any of the preceding items, in which the structure is formed at least partially epitaxially or by means of steam or electroplating.
   422. Method according to any of the preceding items, in which the structure of the functional layer stack is passivated by means of the retaining structure, whereby the retaining structure can in particular be transparent.
   423. Method according to any of the preceding items, characterised by
   removing of the sacrificial layer by wet chemical etching.
   424. Method according to any of the preceding items, characterised by removing of the sacrificial layer in two steps, before and after applying the second electrically conductive contact layer.
   425. Method according to any of the preceding items, further comprising:
   covering one flank of the functional layer stack with a passivation layer.
   426. Method according to any of the preceding items, characterised by
   diffusing of a metal, in particular Zn, from a flank of the functional layer stack into an outer edge region of the functional layer stack.
   427. Method according to any of the preceding items, characterised by
   applying of the first and/or the second electrically conductive contact layer by sputtering, vaporizing or electroplating.
   428. μ-LED or μ-LED module or array of μ-LEDs, comprising:
a functional layer stack; wherein
a first electrically conductive contact layer is applied to a first main surface side of the functional layer stack facing away from a substrate and a second electrically conductive contact layer is applied to a second main surface side of the functional layer stack facing the substrate; wherein
the contacted functional layer stack is supported by at least one holding structure which is attached to the substrate and from which the contacted functional layer stack can be broken off during lift-off.
   429. μ-LED or μ-LED module or array of μ-LEDs according to item
   428, characterized in that
   the functional layer stack has an optically active layer between oppositely doped layers, in particular an active layer formed by one or more quantum wells.
   430. μ-LED or μ-LED module or array of μ-LEDs according to any of the preceding items, in which the active layer has an increased band gap in edge regions of the μ-LED and/or in regions, which are at least adjacent to the holding structure or adjacent to a possible break-off edge.
   431. μ-LED or μ-LED module or array of μ-LEDs according to any of the preceding items, comprising quantum well intermixing in edge regions of the active layer or in regions of the active layer adjacent to the support structure or adjacent to a possible break-off edge.
   432. μ-LED or μ-LED module or array of μ-LEDs according to any of the preceding items, characterized in that
   the contacted functional layer stack was transferred to a secondary substrate by lifting and positioning.
   433. μ-LED or μ-LED module or array of μ-LEDs according to any of the preceding items characterized in that
   the substrate comprises GaAs.
   434. μ-LED or μ-LED module or array of μ-LEDs according to any of the preceding items, characterised in that
   the support structure comprises in particular InGaAlP or AlGaAs or BCB or an oxide, for example SiO₂, or a nitride or a combination of such materials, and/or is in particular electrically non-conductive.
   435. μ-LED or μ-LED module or array of μ-LEDs according to any of the preceding items, characterised in that
   a first supporting layer comprises, in particular InGaAlP and/or AlGaAs, attached to the functional layer stack on the first main surface side.
   436. μ-LED or μ-LED module or array of μ-LEDs according to any of the preceding items, characterised in that
   a second supporting layer attached to the functional layer stack on the second main surface side comprises in particular InGaAlP and/or AlGaAs.
   437. μ-LED or μ-LED module or array of μ-LEDs according to any of the preceding items, characterised in that
   the first and/or the second electrically conductive contact layer comprises ITO or ZnO or a metal and/or in particular are attached to a first and a second supporting layer.
   438. μ-LED or μ-LED module or array of μ-LEDs according to any of the preceding items, characterised in that
   the μ-LED is smaller than 70 μm, in particular smaller than 50 μm or smaller than 20 μm or smaller than 10 μm.
   439. Method for picking up and placing optoelectronic semiconductor chips, wherein
   electron-hole pairs are generated in optoelectronic semiconductor chips and an electric dipole field is thereby generated in the vicinity of the respective optoelectronic semiconductor chip,
   a recording tool generates an electric field, and
   the optoelectronic semiconductor chips are picked up with the pick-up tool during or after the generation of the electron-hole pairs and deposited at predetermined positions.
   440. Method according to item 439, where the optoelectronic semiconductor chips are μ-LEDs or LEDs.
   441. Method according to item 439 or 440, wherein the optoelectronic semiconductor chips for generating the electron-hole pairs are irradiated with light having a predetermined wavelength or a predetermined wavelength range.
   442. Method according to item 441, wherein the light for generating the electron-hole pairs is incident on the optoelectronic semiconductor chips through the pick-up tool.
   443. Method according to item 442, wherein the optoelectronic semiconductor chips are arranged on a carrier and the light for generating the electron-hole pairs falls through the carrier onto the optoelectronic semiconductor chips.
   444. Method according to any of the preceding items, wherein a plurality of optoelectronic semiconductor chips are provided and the electrical dipole fields are generated only in selected optoelectronic semiconductor chips of the plurality of optoelectronic semiconductor chips.
   445. Method according to any of the preceding items, whereby the pick-up tool generates an electric field only in predetermined areas
   446. Method according to any of the preceding items, wherein the pick-up tool has a plurality of elevations on a surface facing the optoelectronic semiconductor chips, and the optoelectronic semiconductor chips are picked up by the elevations of the pick-up tool.
   447. Method according to any of the preceding items, wherein at least a portion of a surface of the pick-up tool facing the optoelectronic semiconductor chips is flat, and the optoelectronic semiconductor chips are picked up with the flat portion of the pick-up tool.
   448. Method according to any of the preceding items, wherein the pick-up tool has the shape of a cylinder, which is rolled over the optoelectronic semiconductor chips to pick up the optoelectronic semiconductor chips.
   449. Method according to any of the preceding items, wherein for depositing the optoelectronic semiconductor chips the electric field generated by the pick-up tool is changed.
   450. Method according to any of the preceding items, wherein the pick-up tool for picking up the optoelectronic semiconductor chips directly contacts the optoelectronic semiconductor chips and holds them by means of Van der Waals forces.
   451. Apparatus for picking up and putting down optoelectronic semiconductor chips, μ-LED arrays or μ-LED according to any of the preceding or subsequent items, comprising:
   an excitation element for generating electron-hole pairs in optoelectronic semiconductor chips in order to generate an electric dipole field in the vicinity of the respective optoelectronic semiconductor chip, and
   a pick-up tool for picking up and depositing the optoelectronic semiconductor chips, wherein the pick-up tool is configured such that it generates an electric field, then picks up the optoelectronic semiconductor chips with the electron-hole pairs generated by the excitation element and deposits the optoelectronic semiconductor chips at predetermined locations.
   452. Apparatus according to item 451, wherein the excitation element is configured to generate light with a predetermined wavelength or a predetermined wavelength range for generating the electron-hole pairs in the optoelectronic semiconductor chips.
   453. Apparatus according to item 452, wherein the excitation element is arranged in such a way that the light for generating the electron-hole pairs is incident on the optoelectronic semiconductor chips through the pick-up tool or through a carrier on which the optoelectronic semiconductor chips are arranged.
   454. Apparatus according to one of the items 451 to 453, wherein the pick-up tool has a plurality of projections on a surface facing the optoelectronic semiconductor chips, and the optoelectronic semiconductor chips are picked up by the projections of the pick-up tool.
   455. Apparatus according to any one of the items 451 to 453, wherein at least a portion of a surface of the pick-up tool facing the optoelectronic semiconductor chips is flat and the optoelectronic semiconductor chips are picked up with the flat portion of the pick-up tool.
   456. Apparatus according to any one of the items 451 to 453, wherein the pick-up tool has the shape of a cylinder, which is rolled over the optoelectronic semiconductor, chips to pick up the optoelectronic semiconductor chips.
   457. Method for processing a number of arrays of optoelectronic components, in particular μ-LEDs or μ-LED arrangements, comprising the following steps:
generating of μ-LEDs on a carrier substrate with a first density;
executing of first transfer steps by means of a first transfer stamp, which transfers the optoelectronic microchips onto an intermediate carrier of the first density;
carrying out second transfer steps by means of a second transfer stamp, which transfers the optoelectronic microchips from the intermediate carrier to a target substrate with a second density smaller by a factor n than the first density, which provides a common array area for a respective one of the number of arrays, in particular for all three colors, wherein the size of the intermediate carrier is equal to or larger than that of the second transfer stamp and the size of the second transfer stamp is equal to or smaller by a factor k than that of the array area.
   458. Method according to item 457, characterized in that the μ-LEDs are generated connected to respective module areas, which are generated connected to the carrier substrate.
   459. Method according to item 458, characterized in that when the μ-LEDs are generated, first armature elements for connecting with a first adhesive force are formed between module areas and the carrier substrate and/or second armature elements for connecting with a second adhesive force are formed between the μ-LEDs and the module areas.
   460. Method according to any of the preceding items, characterised in that
   when carrying out the first transfer steps, the lifting force of the lifting first transfer stamp is set to be greater than the first adhesive force and less than the second adhesive force in such a way that the module areas are lifted off the carrier substrate and transferred to the intermediate carrier.
   461. Method according to any of the preceding items, characterised in that
   when carrying out the second transfer steps, the lifting force of the lifting second transfer stamp is set to be greater than the second holding force in such a way that the μ-LEDs are lifted off the module areas and transferred to the target substrate.
   462. Method according to any of the preceding items, characterised in that
   when generating the μ-LEDs, first release elements for connecting with an additional first adhesive force are additionally formed between the module areas and the carrier substrate and/or second release elements for connecting with an additional second adhesive force are additionally formed between the μ-LEDs and the module areas.
   463. Method according to item 462, characterized in that
   when carrying out the first transfer steps, the lifting force of the lifting first transfer stamp is set to be greater than the total first adhesive force and less than the total second adhesive force in such a way that the module areas are lifted off the wafer and transferred to the intermediate carrier.
   464. Method according to item 463, characterized in that
   the additional initial holding force has been reduced, especially to zero, by removing the first release elements beforehand.
   465. Method according to any of the preceding items, characterised in that
   when carrying out the second transfer steps, the lifting force of the lifting second transfer stamp is set to be greater than the total second holding force in such a way that the μ-LEDs are lifted off the module areas and transferred to the target substrate.
   466. Method according to item 465, characterized in that
   the additional second holding force has been reduced, in particular to zero, by means of prior removing the second release elements.
   467. Method according to any of the preceding items, characterized in that
   for the adhesion of the module areas on the intermediate carrier, materials with a respective adhesive force greater than the total second adhesive force must be used.
   468. Method according to any of the preceding items, characterized in that
   when generating the μ-LEDs for carrying out the first transfer steps, lifting elements are formed directly on the module areas for lifting and transferring the module areas to the intermediate carrier.
   469. Method according to any of the preceding items, characterised in that
   when generating the microchips for carrying out the first transfer steps, positioning elements are formed directly on the module areas for the precise transfer of the module areas to the intermediate carrier.
   470. Method according to any of the preceding items, characterised in that
   to carry out the second transfer steps, tapping elements are formed on the second transfer die for thinning the microchips to the second density.
   471. Method according to any of the preceding items, characterised in that
   the size of the, in particular rectangular, first transfer stamp is chosen to be smaller by a factor s than the size of the, in particular round, wafer in such a way that the size of an area of lost μ-LEDs at the edge of the carrier substrate for the first transfer for complete loading of the intermediate carrier is small, in particular per color less than or equal to 20% or less than or equal to 30% of the carrier substrate area.
   472. Method according to any of the preceding items, characterised in that
   the size of the, in particular rectangular, first transfer stamp is chosen to be smaller than the size of the intermediate carrier by the factor r in such a way that the number of first transfer steps r for the first transfer for complete loading of the intermediate carrier is small, in particular per color less than or equal to 10 or less than or equal to 50.
   473. Method according to any of the preceding items, characterised in that
   the shape of the intermediate carrier corresponds to the shape of the second transfer stamp and said shape in particular to the shape of the array surface.
   474. Method according to any of the previous items, characterised in that
   the intermediate carrier is equipped with tested module areas of the carrier substrate or several, in particular different, carrier substrates.
   475. Method according to any of the preceding items, characterised in that
   the distances between the μ-LEDs on the respective carrier substrate correspond to the distances between the μ-LEDs on the intermediate carrier substrate.
   476. Method according to any of the preceding items, characterised in that
   the distances between microchip on a respective intermediate carrier and on a respective target substrate in an x-direction are different from those in a y-direction.
   477. Method according to any of the preceding items, characterised in that
   the target substrate is loaded with several intermediate carriers.
   478. Method according to any of the preceding items, characterised in that
   the color of the μ-LEDs of a respective intermediate carrier is monochrome red, green or blue and the number of arrays is formed from three intermediate carriers, which have μ-LEDs of different colors to each other.
   479. Method according to any of the preceding items, characterised in that
   between carrier substrate and module areas first release elements and then between μ-LEDs and module areas second release elements are selectively removed.
   480. Array with a multitude of μ-LEDs, μ-LED modules or μ-LED arrays, which are manufactured in particular for each of the colors red, green and blue by the following steps:
generating μ-LEDs, on a carrier substrate with a first density;
executing of first transfer steps by means of a first transfer stamp, which transfers the μ-LEDs to an intermediate carrier of the first density;
carrying out second transfer steps by means of a second transfer stamp which transfers the μ-LEDs from the intermediate carrier to a target substrate with a second density which is smaller by a factor n than the first density, wherein the intermediate carrier provides a common array area for a respective one of the arrays, in particular for all three colors, wherein the size of the intermediate carrier is equal to or larger than that of the second transfer stamp and the size of the second transfer stamp is equal to or smaller by a factor k than that of the array area.
   481. Array comprising a plurality of μ-LEDs, μ-LED modules or μ-LED arrays manufactured by a process according to any of the preceding items.
   482. Start structure for use in a process according to any of the preceding items, characterized in that
   module areas are attached to a carrier substrate by means of first anchor elements, and
   μ-LEDs are attached to the module areas by means of second armature elements.
   483. Start structure for use in a process according to any of the preceding items,
   characterised in that
   module areas are fixed to a carrier substrate by means of first anchor elements and removable first release elements, and μ-LEDs are attached to the module areas by means of second armature elements and removable second release elements.
   484. Method for producing modules of μ-LEDs, comprising the steps of:
generating at least one layer stack providing a base module on a carrier having a first layer, an active layer applied thereto and a second layer formed thereon;
exposing a surface area of the first layer facing away from the substrate;
forming a first contact on a surface area of the second layer facing away from the carrier;
forming a second contact on the surface area of the first layer facing away from the carrier.
   485. Method according to item 484, characterized in that forming a second contact comprises:
forming an electrically insulating dielectric over a portion of the active layer and the second layer
forming the second contact with a conductive material, which electrically contacts the remote surface area of the first layer via the dielectric to a surface area of the second layer remote from the carrier.
   486. Method according to item 484 or 485, characterised by exposing the surface region of the first layer remote from the substrate by means of a flat edge structuring of the at least one stack of layers, in particular from the side of the second layer, a flat trench in particular being produced around the respective stack of layers.
   487. Method according to any of the preceding items, characterised by
   generating a plurality of base modules as a matrix along an X-Y plane along at least one row and along at least one column, wherein base modules of a respective row are oriented in the same way.
   488. Method according to item 487, characterized in that
   the base modules of two adjacent lines are oriented in the same way; or that
   the base modules of two adjacent lines are oriented in opposite directions, whereby contacts of the same polarity, in particular first contacts, are thus arranged adjacent to one another.
   489. Method according to item 488, characterised by generating of a common layer stack of two adjacent base modules oriented opposite to each other.
   490. Method according to any of the preceding items, characterised by at least one of the following steps:
grouping a number of base modules to form at least one μ-LED module, in particular rectangular or square along the X-Y plane, wherein, in particular in a plurality of rows, each row has the same columns occupied by base modules; and
forming the at least one μ-LED module from the plurality of base modules by means of a deep edge structuring through the first layer, in particular from the side of the second layer.
   491. Method according to any of the preceding items, characterised in that
   the base modules are arranged on a different carrier when structuring the deep edges, as opposed to exposing the first and second contacts.
   492. Method according to any of the preceding items, characterised by at least one of the following steps:
detaching the base module or μ-LED module from the carrier Laser Lift-Off; and
detaching the base module or μ-LED module from the carrier, using a mechanical process.
   493. Method according to any of the preceding items, characterised by a
   contacting the contacts of the μ-LED module to a replacement carrier or end carrier, especially by means of flip-chip technology.
   494. Method according to item 493, characterized in that common contact areas can be created for contacts of adjacent oppositely oriented base modules of the μ-LED module.
   495. Method according to any of the preceding items, characterized in that
   the first layer is n-doped and the second layer is p-doped, the active layer being configured in particular to emit blue or green light; and/or in that
   the first layer is p-doped and the second layer is n-doped, the active layer being configured in particular to emit red light.
   496. Method according to any of the preceding items, characterized in that
   the at least one layer stack is created by epitaxy; and/or in that
   exposure and/or grouping is performed by means of etching.
   497. Method according to any of the preceding items, further comprising a
   generating of quantum well intermixing in areas of the active layer adjacent to a deep edge structuring.
   498. μ-LED module comprising at least one layer stack forming a base module, with a first layer formed on a carrier, an active layer and a second layer, wherein a first contact is formed in or on a surface region of the second layer facing away from the carrier, and a second contact is formed in or on the surface region of the first layer facing away from the carrier, and the first and second contact are spaced apart from one another.
   499. μ-LED module according to item 498, in which a light-emitting surface is formed on a side of the stack of layers facing away from the first and second contact.
   500. μ-LED module according to item 498, characterized in that the second contact is formed by means of a dielectric to the transition layer and to the second layer electrically insulated from and on the surface region of the second layer remote from the carrier.
   501. μ-LED module according to item 499, characterized in that the μ-LED module comprises a plurality of base modules arranged in a matrix of at least one row and at least one column.
   502. μ-LED module according to item 501, in which a μ-LED adjacent to the μ-LED module is separated by a deep edge structuring.
   503. μ-LED module according to item 502, in which regions of the active layer which run adjacent to a deep edge structure have an elevated band structure produced in particular by quantum well intermixing.
   504. μ-LED module according to any of the preceding items, characterized in that
   the base modules of two adjacent lines are oriented in opposite directions so that contacts of the same polarity, in particular first contacts, are arranged adjacent to each other.
   505. μ-LED module after any of the previous items, characterised in that
   the module, in particular a light-emitting diode module, has been produced by means of a process according to any of the preceding items.
   506. μ-display or μ-LED display module with
an all-surface target matrix formed on a first carrier, which has rows and columns of μ-LEDs, occupy-able locations,
one or more μ-LED modules following one of the items 498 to 505 comprising one or more base modules whose size corresponds to the vacant positions;
   characterised in that
   the μ-LED modules are positioned and electrically connected to the first carrier in the target matrix in such a way that a number of base modules remain unoccupied in the target matrix, at least some of which each have at least one sensor element positioned and electrically connected.
   507. μ-display or μ-LED display module according to item 506, characterized in that
   a plurality of full-surface target matrices formed on the first carrier and of equal or different size to one another are formed along rows and columns with target matrix-occupy-able locations at respective distances from one another.
   508. μ-display or μ-LED display module according to item 506 or 507, characterized in that
   the base modules form rectangles in a matrix plane, and in μ-LED modules any number of base modules adjacent to each other along a common side are grouped together.
   509. μ-display or μ-LED display module according to any of the preceding items, characterized in that
   at least one μ-LED module comprises four base modules in two rows and two columns.
   510. μ-display or μ-LED display module according to any of the preceding items, characterized in that
   at least one μ-LED module comprises three base modules in two rows and two columns.
   511. μ-display or μ-LED display module according to any of the preceding items, characterized in that
   at least seven μ-LED modules, each with four base modules, and at least two μ-LED modules, each with three base modules, are positioned and electrically connected to the target matrix.
   512. μ-display or μ-LED display module according to item 511, characterized in that
   in that at least two positions which are unoccupied by base modules are produced, at which in each case at least one sensor element is positioned and electrically connected.
   513. μ-display or μ-LED display module according to item 512, characterized in that
   the positions occupied by sensor elements are framed by base modules.
   514. μ-display or μ-LED display module according to any of the preceding items, characterized in that
   the base modules are configured to emit electromagnetic radiation from a first side of the first carrier.
   515. μ-display or μ-LED display module according to any of the preceding items, characterized in that
   the μ-LED modules comprise base modules, which are configured as subpixels.
   516. μ-display or μ-LED display module according to any of the preceding items, characterized in that
   the locations of the target matrices are configured as subpixels of a pixel.
   517. μ-display or μ-LED display module according to any of the preceding items, characterized in that
   a plurality of sensor elements are formed as part of sensor means formed on said first carrier to receive electromagnetic radiation incident on a first side of said first carrier.
   518. μ-display or μ-LED display module according to any of the preceding items, characterized in that
   at least one sensor element is configured as a vital sign monitoring sensor.
   519. μ-display or μ-LED display module according to item 519, where
   said vital sign monitoring sensor is disposed within a display screen or behind the rear surface of a display screen, and said vital sign monitoring sensor is adapted to measure one or more vital sign parameters of a user placing a body part to the front major surface of the display screen at said vital sign monitoring sensor.
   520. μ-display or μ-LED display module according to any of the preceding items, characterized in that
   a base module comprises in each case a first layer, which is formed on a second carrier and on which an active transition layer is formed and on which a second layer is formed, a first contact being connected to a surface region of the second layer which faces away from the second support, a second contact being connected to a surface region of the first layer which faces away from the second support.
   521. μ-display or μ-LED display module according to item 520, in which
   the second contact is formed by means of a dielectric to the transition layer and to the second layer, electrically insulated from and on the surface region of the second layer remote from the second carrier.
   522. μ-display or μ-LED display module according to any of the preceding items, characterized in that
   the respective sensor element is adapted in the form of a μ-photodiode, or in the form of a phototransistor, or in the form of a photoconductor, or in the form of an ambient light sensor, or in the form of an infrared sensor, or in the form of an ultraviolet sensor, or in the form of a proximity sensor, or in the form of an infrared component.
   523. Method for producing a μ-display or μ-LED display module with a whole-surface target matrix formed on a first carrier and having rows and columns of target matrixes which can be occupied by base modules,
   wherein a number of base modules are formed on a second carrier in a starting matrix having a spacing, equal to the target matrix, of points which can be occupied by base modules, in particular by means of a flat mesa etching, are grouped there, in particular by means of a deep mesa etching, to form a number of μ-LED modules and these μ-LED modules are separated from the second carrier, in particular by means of laser lift-off or a mechanical or chemical process,
   characterised in that
   the μ-LED modules are positioned and electrically connected on the first carrier in the target matrix in such a way that a number of base modules remain unoccupied in the target matrix, at least some of which at least one sensor element in each case is positioned and electrically connected.
   524. Method according to item 523, characterized in that
   a plurality of full-surface target matrices of identical or different sizes formed on the first carrier are formed along rows and columns with target matrix-occupy-able locations at respective distances from one another.
   525. Method according to any of the preceding items, characterised in that
   the base modules form rectangles in a matrix plane, and in μ-LED modules any number of base modules adjacent to each other along a common side can be grouped together.
   526. Method according to any of the preceding items, wherein in at least one μ-LED module four base modules can be grouped in two rows and two columns.
   527. Method according to any of the preceding items, wherein in at least one μ-LED module three base modules can be grouped in two rows and two columns.
   528. Method according to any of the preceding items, characterised in that
   at least seven μ-LED modules, each with four base modules, and at least two μ-LED modules, each with three base modules, are positioned and electrically connected to the target matrix in such a way that at least two positions which are unoccupied by base modules are generated at which in each case at least one sensor element is positioned and electrically connected.
   529. Method according to any of the preceding items, wherein the positions occupied by sensor elements are framed by base modules.
   530. Method according to any of the preceding items, wherein the base modules are configured to emit electromagnetic radiation from a first side of the first carrier.
   531. Method according to any of the preceding items, characterised in that
   a plurality of sensor elements are formed as part of sensor means formed on said first carrier to receive electromagnetic radiation incident on a first side of said first carrier.
   532. Method according to any of the preceding items, characterised in that
   a sensor element is configured as a vital sign monitoring sensor.
   533. Method according to item 532, characterised in that
   said vital sign monitoring sensor is disposed within a display screen or behind the rear surface of a display screen, wherein said vital sign monitoring sensor is adapted to measure one or more vital sign parameters of a user who places a body part to the front major surface of the display screen at said vital sign monitoring sensor.
   534. Method according to any of the preceding items, characterised in that
   a base module has in each case a first layer formed on a second carrier, on which an active transition layer and on said active transition layer a second layer is formed, a first contact being connected to a surface region of the second layer facing away from the support, a second contact being connected to a surface region of the first layer facing away from the second support.
   535. Method according to item 534, characterized in that
   the second contact is formed by means of a dielectric to the transition layer and to the second layer, electrically insulated from and on the surface region of the second layer remote from the second carrier.
   536. Method according to any of the preceding items, characterised in that
   a sensor element is formed in each case in the form of a micro-photodiode, or in the form of a phototransistor, or in the form of a photo-resistor, or in the form of an ambient light sensor, or in the form of an infrared sensor, or in the form of an ultraviolet sensor, or in the form of a proximity sensor, or in the form of an infrared component.
   537. μ-LED module comprising:
a body with a first major surface and four lateral surfaces;
at least three contact pads arranged on the first main surface, wherein a μ-LED with an edge length of 15 μm or less is arranged on at least one of the at least three contact pads;
a plurality of contact bars, one contact bar being electrically connected to one of the at least three contact pads in each case, and the three contact bars being arranged on the first main surface and at least one of the four side surfaces.
   538. μ-LED module according to item 537, further comprising: a fourth contact bar arranged on a second of the four side faces and which
is connected on the first major surface to a fourth contact pad electrically connected to the at least one μ-LED; or
is electrically connected on the first main surface to an optically transparent contact pad which electrically connects the at least one μ-LED on a side opposite the at least one of the three contact pads.
   539. μ-LED module according to item 537, in which the second side surface of the four side surfaces has only the fourth contact bar.
   540. μ-LED module according to any of the preceding items, where at least two of the three contact bars are arranged on different side surfaces.
   541. μ-LED module according to any of the preceding items, in which the body forms a prismatic body in which the first major surface forms an angle of 90° or more with each of the four lateral surfaces.
   542. μ-LED module according to any of the preceding items, further comprising:
a second major surface substantially opposite the first major surface; wherein
   the second main surface has a larger area than the area of the first main surface.
   543. μ-LED module according to any of the preceding items, where the side surfaces are not perpendicular to the first main surface.
   544. μ-LED module according to any of the preceding items, further comprising:
a second main surface opposite the first main surface;
at least three contact pads arranged on the second main surface and connected to one of the at least three contact bars on at least one of the four side surfaces.
   545. μ-LED module according to any of the preceding items, in which the contact bars and/or the contact pads comprise a metal tab, in particular a vapour-deposited metal tab, the thickness of which is less than 5 μm, in particular less than 2 μm.
   546. μ-LED module according to any of the preceding items, the body comprising
at least one through hole at least partially filled with an electrically conductive material, wherein the electrically conductive material on the first main surface is connected to one of the at least three contact pads arranged on the first main surface.
   547. μ-LED module according to any of the preceding items, in which the body comprises a recess on the second main surface in which at least one contact bar runs, which connects a contact pad on the second main surface to a through-hole and at least one optoelectronic component arranged on the first main surface is connected to the through-hole.
   548. μ-LED module according to any of the preceding items, in which the body comprises silicon and/or has a thickness of less than 30 μm, in particular in the range 5 to 15 μm.
   549. μ-LED module according to any of the preceding items, in which the contact bars each run along one corner of two side surfaces from the first main surface to the second main surface.
   550. Method for producing μ-LED module, comprising the steps:
providing a structured membrane wafer having a plurality of substantially V-shaped trench-shaped depressions such that a first major surface of the structured membrane wafer bounded by trenches forms an angle of 90° or greater with the edges of the trenches;
producing of contact pads on the first main surface of the membrane wafer, including optional rewiring
applying of at least one μ-LED;
applying of a temporary support facing the first main surface;
Etching back the membrane wafer to around or just before the trenches;
applying of rear contacts and optional separation to form a μ-LED module.
   551. Method for producing a pixel array comprising the steps of:
providing a substrate for the field-like arrangement of pixels on the substrate and for electrical contacting of the pixels, said substrate providing a set of primary contacts for a pixel, said set of primary contacts being for electrically contacting a group of μ-LEDs of said pixel, said substrate also providing a set of spare contacts for said pixel,
equipping the primary contacts of the pixel with the group of μ-LEDs, whereby the set of replacement contacts of the pixel is not equipped,
identifying a faulty μ-LED or a faulty contact in the group of μ-LEDs, and
equipping one spare contact of the set of spare contacts of the pixel with a spare μ-LED for the faulty μ-LED or the faulty contacting.
   552. Method according to item 551, characterized in that
   the steps of identifying a defective μ-LED in the group of μ-LEDs and providing a replacement contact with a replacement μ-LED for the identified μ-LED are repeated until a replacement μ-LED is present in the pixel for each μ-LED identified as defective.
   553. Method according to any of the preceding items, characterised in that
   a μ-LED identified as faulty is not removed.
   554. Method according to any of the preceding items, characterised in that
   a μ-LED identified as defective and the replacement μ-LED are intended to emit light of the same color.
   555. Method according to any of the preceding items, characterised in that
   the group of μ-LEDs comprises one or more sets of RGB μ-LEDs.
   556. Method according to any of the preceding items, characterised in that
   no replacement contact of the pixel is equipped with a replacement μ-LED, if no faulty μ-LED is found in the pixel.
   557. Method according to any of the preceding items, characterised in that
   the primary contacts and/or the replacement contacts are configured for contacting the μ-LED or the replacement μ-LEDs on the anode side or on the cathode side or both on the anode and cathode side.
   558. Method according to any of the preceding items, characterised in that
   a μ-LED or a replacement μ-LED is a μ-LED or a μ-LED module or a base module according to features according to any of the preceding items.
   559. Method according to any of the preceding items, characterised in that
   an electrical contact for an identified, faulty μ-LED is disconnected.
   560. Method according to any of the preceding items, characterised in that
   the replacement contact is equipped with a replacement μ-LED for a μ-LED identified as faulty, irrespective of the color of the light emitted by the replacement μ-LED.
   561. Method according to any of the preceding items, characterised in that
   all primary contacts of the pixel are equipped with μ-LEDs.
   562. Pixel field, with:
   a substrate for field-like arrangement of pixels on the substrate and for electrical contacting of the pixels,
   the substrate providing a set of primary contacts for at least one pixel, the set of primary contacts of the pixel being adapted for electrical contacting of a group of μ-LEDs, the substrate also providing a set of spare contacts for the at least one pixel,
   wherein the primary contacts of the pixel are equipped with the group of μ-LEDs,
   wherein the group of μ-LEDs comprises a faulty, deactivated μ-LED, and
   wherein one spare contact of said set of spare contacts of said pixel is equipped with a spare μ-LED as a replacement for said faulty, deactivated μ-LED.
   563. Pixel field according to item 562, characterised in that
   the number of occupied spare contacts is different for at least two pixels.
   564. μ-display comprising a pixel array according to any of the preceding items or a pixel array produced by a process according to any of the preceding items.
   565. μ-LED, comprising:
a layer stack of a p-doped layer;
an n-doped layer;
an active region located between the p-doped and n-doped layer;
   wherein the layer stack rises above a major surface and the active region is located above a center of the layer stack as viewed from the major surface, wherein the layer stack has a reducing diameter from the major surface;
   a reflective layer over a surface of the layer stack.
   566. μ-LED according to item 565,
   in which the stack of layers comprise the shape of a hemisphere or a paraboloid or an ellipsoid.
   567. μ-LED according to any of the preceding items, in which areas of the active layer adjacent to the reflective layer comprise an increased bandgap.
   568. μ-LED according to any of the preceding items, in which areas of the active layer adjacent to the reflective layer exhibit quantum well intermixing.
   569. μ-LED according to any of the preceding items, in which the reflective layer comprises a dielectric between the active region and the layer of the layer stack adjacent to the surface region.
   570. μ-LED arrangement for generating a pixel of a display, comprising
a flat carrier substrate; and
at least one μ-LED, which is arranged on a mounting side of the carrier substrate
   wherein the μ-LED is adapted to emit light transverse to a carrier substrate plane in a direction away from the carrier substrate;
a flat reflector element;
   wherein the reflector element is spatially arranged on the assembly side relative to the at least one μ-LED and is configured to reflect light emitted by the at least one μ-LED in the direction of the carrier substrate;
   wherein the carrier substrate is at least partially transparent so that light reflected from the reflector element propagates through the carrier substrate and emerges at a display side of the carrier substrate opposite the mounting side.
   571. μ-LED arrangement according to item 570, wherein a diffuser layer is provided and/or a reflector material has diffuser particles for scattering the light reflected by the at least one μ-LED on the side of the reflector element directed towards the at least one μ-LED.
   572. μ-LED arrangement according to item 571, wherein the diffuser layer and/or the diffuser particles comprise Al₂O₃ and/or TiO₂.
   573. μ-LED arrangement according to any of the preceding items, wherein the reflector element surrounds the at least one μ-LED in a circular, polygonal or parabolic shape.
   574. μ-LED arrangement according to any of the preceding items, wherein the reflector element forms an electrical contact of the at least one μ-LED.
   575. μ-LED arrangement according to any of the preceding items, wherein the reflector element is configured and shaped such that at least 90% of the light emitted by the at least one μ-LED is incident on the mounting side of the carrier substrate at an angle between 45 and 90 degrees relative to the carrier substrate plane.
   576. μ-LED arrangement according to any of the preceding items, in which the at least one μ-LED comprises three μ-LEDs surrounded by the reflector element
   577. μ-LED arrangement according to item 576, in which the at least three μ-LEDs have a contact area on the side facing the reflector element, which is covered with a transparent cover layer for common electrical contact.
   578. μ-LED array according to any of the preceding items, wherein the supporting substrate comprises polyamide, a transparent plastic, resin or glass.
   579. μ-LED arrangement according to any of the preceding items, wherein the reflector element is formed as a reflective layer of the at least one μ-LED.
   580. μ-LED arrangement according to any of the preceding items, wherein a passivation layer is additionally provided for attenuating or eliminating reflections of the light at mesa edges of the at least one μ-LED.
   581. μ-LED arrangement according to any of the preceding items, wherein a light absorbing coating is provided on the assembly side and/or display side of the carrier substrate outside the reflector element.
   582. μ-LED arrangement according to any of the preceding items, wherein the display side of the supporting substrate has an uneven and/or roughened structure.
   583. μ-LED arrangement according to any of the preceding items, wherein a color filter element is arranged on the display side of the carrier substrate opposite the reflector element; wherein the color filter element allows a primary color spectrum of the at least one μ-LED to pass and attenuates deviating color spectra.
   584a. μ-LED arrangement according to any of the preceding items, in which a light-shaping structure, in particular a photonic structure with features after one of the following objects is incorporated in the carrier substrate, which first and second regions with different refractive indexes are incorporated.
   584b. μ-LED arrangement according to any of the preceding items, in which a light-shaping and/or light-converting structure having first and second areas is arranged on the display side of the carrier substrate.
   585. μ-LED arrangement according to item 583 or 584, where first areas comprise a converter material.
   586. μ-LED arrangement according to any of the preceding items, comprising a converter material surrounding the at least one μ-LED and filling the space between μ-LED and reflector material.
   587. μ-LED arrangement according to any of the preceding items, comprising a converter material on the display side of the supporting substrate.
   588. Optical display comprising a plurality of pixel elements each according to any of the preceding items.
   589. A method for producing an optical pixel element, comprising the steps of
fixing of at least one μ-LED on an assembly side of a flat carrier substrate;
creating a reflector element;
   wherein the reflector element is formed as a light-reflecting layer on the at least one μ-LED so that light emitted from the at least one μ-LED is reflected towards the carrier substrate.
   590. Photonic structure on an optoelectronic device, in particular a μ-LED, comprising
   a set of layers including an active zone for generating electromagnetic radiation forming the optoelectronic device, and at least one layer on a main radiation surface having a photonic crystal structure.
   591. Photonic structure on an optoelectronic device according to item 590, the layers of the set of layers and the at least one layer having the photonic crystal structure are arranged one upon another along a growth direction of the layers, and wherein the photonic crystal structure comprise a periodicity in a plane perpendicular to the growth direction.
   592. Photonic structure on an optoelectronic device according to item 590, in which the photonic crystal structure has first and second regions of different refractive index.
   593. Photonic structure on an optoelectronic device according to any of the preceding items, wherein the photonic structure has a first periodicity in a first direction and a second periodicity in a second direction.
   594. Photonic structure on an optoelectronic device as defined in item 593, in which the first and second periodicity are the same.
   595. Photonic structure on an optoelectronic device according to any of the preceding items, in which the photonic crystal structure extends at least partially into one of the layers of the set of layers.
   596. Photonic structure on an optoelectronic device according to any of the preceding items, the periodicity corresponding to about half a specific wavelength, the wavelength corresponding to the wavelength of electromagnetic radiation to be diffracted by the photonic crystal structure.
   597. Photonic structure on an optoelectronic device according to any of the preceding items, wherein the layer having the photonic crystal structure is a dielectric layer containing or consisting of, for example, silicon dioxide, SiO₂, and/or wherein the space within the photonic crystal structure is filled with or consists of a second material having a refractive index different from the refractive index of a first material forming the photonic crystal structure.
   598. Photonic structure on an optoelectronic device according to any of the preceding items, wherein a lower surface of the layer having the photonic crystal structure is disposed on an upper surface of the set of layers.
   599. Photonic structure on an optoelectronic device according to item 598, wherein a portion of at least one layer of the set of layers protrudes into the layer with the photonic crystal structure.
   600. Photonic structure on an optoelectronic device according to item 597 or 599, wherein the upper surface of the set of layers is provided with a surface roughening, for example, a wigwam surface roughening.
   601. Photonic structure on an optoelectronic device after any of the foregoing, wherein the photonic crystal structure is located at a distance from the upper surface of the set of layers.
   602. Photonic structure on an optoelectronic device according to any of the preceding items, further comprising a mirror layer disposed on the layer having the photonic crystal structure.
   603. Photonic structure on an optoelectronic device according to any of the preceding items, further comprising a metal mirror layer, with the set of semiconductor layers disposed between the metal mirror layer and the layer containing the photonic crystal structure.
   604. Photonic structure on an optoelectronic device according to any of the preceding items, wherein the optoelectronic device is a μ-LED.
   605. Optoelectronic device comprising:
   at least one optoelectronic light emitting device, for example a μ-LED, wherein said optoelectronic light emitting device is configured to emit light through at least one light emitting surface of said optoelectronic light emitting device,
   at least one photonic crystal structure, said photonic crystal structure being disposed between the light-emitting surface of said optoelectronic light-emitting device and a light-emitting surface of said optoelectronic device.
   606. Method for producing an optoelectronic device, in particular according to any of the preceding items, comprising method:
growing of a set of layers including an active zone for the generation of electromagnetic radiation,
growing at least one layer having a photonic crystal structure on the upper side of the set of layers,
   optionally providing a mirror layer over the layer with the photonic crystal structure,
   optionally providing a mirror layer under the set of layers with the active zone,
   optional executing an etching process, such as a Mesa dry etching process
   607. Method for producing a μ-LED comprising a
   creating of an out-coupling structure in a surface region of a semiconductor body providing the active layer of the μ-LED by means of
   structuring of the surface area; and
   planarizing the structured surface area to obtain a planarized surface of the surface area.
   608. Method according to item 607, wherein the step of structuring the surface area comprises at least one of the following steps:
generating of a random topology at the surface area;
roughening the surface of the surface region of the semiconductor body comprising a first material;
applying, in particular layer-by-layer applying of a transparent second material having a high refractive index, in particular greater than 2, to the surface region and roughening of the second material;
creating an ordered topology on the surface area;
   applying, in particular layer-by-layer applying of a transparent second material having a high refractive index, in particular greater than 2, to the surface region and structuring of periodic photonic structures or non-periodic photonic structures, in particular quasi-periodic or deterministic aperiodic photonic structures, into the second material.
   609. Method according to item 608, characterised in that
   the transparent second material with the high refractive index Nb₂O₅.
   610. Method according to any of the preceding items, in which the step of planarizing comprises:
   applying, in particular layer by layer, a transparent third material of low refractive index, in particular less than 1.5, to the structured surface region; and
   optionally thinning the applied transparent third material of low refractive index until the surface of the structured surface region terminates flat and/or smooth with highest elevations in the first material of the semiconductor body or in the second material of high refractive index.
   611. Method according to item 610, in which
   the transparent third material having a low refractive index SiO₂, and is applied in particular by means of TEOS (tetraethylorthosilicate).
   612. μ-LED comprising an out-coupling structure in a surface region of a semiconductor body providing the μ-LED
   in which the surface area is planarized so that a smooth surface area is created.
   613. μ-LED according to item 612, characterised in that the smooth surface region comprises a roughness in the range of less than 20 nanometres, in particular less than 1 nanometre, as mean roughness value.
   614. μ-LED to any of the preceding items, wherein
   the out-coupling structure comprises a transparent third material with a low refractive index, in particular SiO₂, on a roughened first material of the semiconductor of the device.
   615. μ-LED according to any of the preceding items, in which the output coupling structure comprises a transparent third material of low refractive index, in particular SiO₂, on a roughened transparent second material of high refractive index, in particular Nb₂O₅, the second material being attached to a first material of the semiconductor of the device.
   616. μ-LED according to any of the preceding items, in which the output structure comprises a transparent third material of low refractive index, in particular SiO₂, on a transparent second material of high refractive index, the second material being attached to a first material of the semiconductor of the device and comprising periodic photonic crystals or non-periodic photonic structures, in particular quasi-periodic or deterministic aperiodic photonic structures.
   617. Converter element for an optoelectronic component, which has at least one layer comprising a converter material which, when excited by an incident excitation radiation, emits a converted radiation into an emission region,
   characterized in that the layer has at least in some areas a structure on which the converter material is arranged at least in sections and which is configured in such a way that the radiation is emitted as a directed beam of rays into the emission area.
   618. Converter element according to item 617,
   characterised in that the structure is quasi-periodic or deterministically aperiodic.
   619. Converter element according to item 617 or 618,
   characterised in that the layer comprises at least one photonic crystal, a quasi-periodic photonic structure or a deterministically aperiodic photonic structure.
   620. Converter element according to any of the preceding items, characterised in that the structure comprises at least one recess in which the converter material is located.
   621. Converter element according to any of the preceding items, characterised in that the layer comprises an optical band gap.
   622. Converter element according to any of the preceding items, characterized in that the structure comprises an average thickness of at least 500 nm.
   623. Converter element according to any of the preceding items, characterized in that the layer with the structure is configured such that the directed beam of rays is emitted perpendicularly to a plane in which the layer is arranged.
   624. Converter element according to any of the preceding items, characterized in that an optical filter element is arranged at least on one side of the layer.
   625. Light-shaping structure for an optoelectronic device comprising at least one layer with a converter material which, when excited by an incident excitation radiation, emits a converted radiation into an emission region
   characterized in that the layer has at least in some areas a structure on which the converter material is arranged at least in sections and which is configured in such a way that the radiation is emitted as a directed beam of rays into the emission area.
   626. Light forming structure according to item 625,
   characterised in that the structure is quasi-periodic or deterministically aperiodic.
   627. Light forming structure according to item 625 or 626, characterised in that the layer comprises at least one photonic crystal, a quasi-periodic photonic structure or a deterministically aperiodic photonic structure.
   628. Light-shaping structure according to any of the preceding items,
   characterised in that the structure comprises at least one recess in which the converter material is located.
   629. Light-shaping structure according to any of the preceding items,
   characterised in that the layer comprises an optical band gap.
   630. Light-shaping structure according to any of the preceding items,
   characterized in that the structure comprises an average thickness of at least 500 nm.
   631. Light-shaping structure according to any of the preceding items,
   characterized in that the layer with the structure is configured such that the directed beam of rays is emitted perpendicularly to a plane in which the layer is arranged.
   632. Light-shaping structure according to any of the preceding items,
   characterized in that an optical filter element is arranged at least on one side of the layer.
   633. μ-LED arrangement comprising a μ-LED and a converter element according to any of the preceding items, wherein the μ-LED is adapted to radiate an excitation radiation into the converter element, and wherein the converter element comprises at least one layer comprising a converter material.
   634. μ-LED arrangement comprising a μ-LED and having a light-shaping structure according to any of the preceding items, wherein the μ-LED is adapted to irradiate an excitation radiation into the light-shaping structure, and wherein the light-shaping structure comprises at least one layer comprising a converter material.
   635. μ-LED arrangement according to item 633 or 634, characterized in that the layer is part of a semiconductor substrate of the μ-LED.
   636. μ-LED arrangement according to any of the items 633 to 635, characterized in that the structure of the converter element or light-shaping structure is formed in the semiconductor substrate of the μ-LED.
   637. μ-LED arrangement according to any of the items 633 to 636, characterized in that the structure with the converter material is configured in such a way that the converted radiation is emitted into the emission region perpendicular to a plane in which the semiconductor substrate is arranged.
   638. μ-LED arrangement according to any of the items 633 to 637, characterised in that the structure of the converter element or light-shaping structure is at least partially disposed in an active layer of the μ-LED.
   639. Method for producing a μ-LED arrangement according to any of the items 633 to 638,
   characterized in that the structure of the converter element or the light-shaping structure is formed by at least one etching step in a semiconductor substrate of the μ-LED.
   640. Method according to item 639,
   characterised in that the structure of the converter element or light-shaping structure is at least partially filled with the converter material.
   641. Optoelectronic device or μ-LED array, comprising:
   an arrangement comprising a plurality of μ-LEDs for generating light emerging from a light exit surface from the optoelectronic device, and
   at least one photonic structure arranged between the light-emitting surface and the plurality of μ-LEDs.
   642. Optoelectronic device according to item 641, in which the photonic structure is configured for beam-shaping of the light generated by the μ-LEDs, in particular in such a way that the light emerges at least substantially perpendicularly from the light exit surface.
   643. Optoelectronic device according to any of the preceding items, in which the photonic structure comprises a photonic crystal.
   644. Optoelectronic device according to any of the preceding items, in which
   the arrangement is an array in which the μ-LEDs represent a plurality of pixels and are arranged in a layer, and in that a photonic crystal is arranged or formed in the layer.
   645. Optoelectronic device according to any of the preceding items, characterized in that
   the arrangement is an array in which the μ-LEDs represent a plurality of pixels arranged in a first layer and in that a photonic crystal is arranged in a further, second layer, the second layer being located between the first layer and the light-emitting surface.
   646. Optoelectronic device according to any of the preceding items, characterized in that
   the arrangement comprises a plurality of μ-LEDs arranged in a first layer, and that a photonic crystal is arranged in the further, second layer, the second layer being located between the first layer and the light-emitting surface.
   647. Optoelectronic device according to any of the preceding items, characterized in that
   each of the μ-LEDs comprises a recombination zone and the photonic crystal is located so close to the recombination zones that the photonic crystal changes an optical state density present in the region of the recombination zones, in particular in such a way that a band gap is generated for at least one optical mode with a direction of propagation parallel and/or at a small angle to the light exit surface.
   648. Optoelectronic device according to any of the preceding items, characterized in that
   the photonic crystal is arranged in relation to a plane parallel to the light-emitting surface independently of the positioning of the light points, and/or
   the photonic crystal is a two-dimensional photonic crystal, which exhibits a periodic variation of the optical refractive index in two spatial directions perpendicular to each other and spanning the plane.
   649. Optoelectronic device according to any of the preceding items, characterized in that
   the photonic structure comprises a plurality of pillar structures extending at least partially between the light-emitting surface and the plurality of μ-LEDs, wherein one pillar is associated with each μ-LED and is aligned with the light-emitting surface when viewed in a direction perpendicular to the light-emitting surface.
   650. Optoelectronic device according to item 649, characterised in that
   the device is an array in which the μ-LEDs represent a plurality of pixels arranged in a first layer and in that the pixels are arranged in a further, second layer, the second layer being located between the first layer and the light-emitting surface.
   651. Optoelectronic device according to item 649, characterised in that
   the device comprises a plurality of μ-LEDs, arranged in a first layer, and that the pillars are arranged or formed in a further, second layer, the second layer being located between the first layer and the light-emitting surface.
   652. Optoelectronic device according to item 649, characterised in that
   the arrangement is an array in which the μ-LEDs represent a plurality of pixels, one pixel being formed by each pillar.
   653. Method for producing an optoelectronic device, in particular a device according to any of the preceding items, wherein an arrangement comprising a plurality of μ-LEDs is provided or made for generating light emerging from a light exit surface from the optoelectronic device, and
   at least one photonic structure is arranged between the light-emitting surface and the plurality of μ-LEDs.
   654. μ-LED arrangement having at least one μ-LED which emits radiation via a light-emitting surface, and having a polarization element which adjoins the light-emitting surface at least in sections and changes a polarization and/or an intensity of a radiation emanating from the μ-LED when the radiation passes through the polarization element,
   characterised in that
   the polarizing element comprises a photonic structure.
   655. μ-LED arrangement according to item 654, characterized in that
   it is a three-dimensional photonic structure and/or that the polarizing element is configured in the form of a layer which is arranged at least in regions on the light-emitting surface.
   656. μ-LED arrangement according to item 654 or 655, in which the μ-LED is a vertical μ-LED with one connecting contact on opposite sides.
   657. μ-LED arrangement according to any of the preceding items, characterized in that
   the μ-LED, which is configured to emit light, in particular red, green, blue, ultraviolet or infrared light, which is irradiated into the polarizing element, and that the polarizing element polarizes the radiation in an oscillation direction when passing through the polarizing element.
   658. μ-LED arrangement according to any of the preceding items, wherein
   the polarising element has spiral and/or rod-shaped structural elements.
   659. μ-LED arrangement according to any of the preceding items, wherein
   the μ-LED comprises at least one converter element with a converter material which, excited by excitation radiation emanating from the μ-LED, emits converted radiation.
   660. μ-LED arrangement according to any of the preceding items, characterised in that
   the polarizing element comprises at least one three-dimensional photonic crystal.
   661. μ-LED array according to any of the preceding items, wherein
   the polarizing element comprises at least two two-dimensional photonic crystals arranged one behind the other along a beam path of the radiation penetrating the polarizing element.
   662. μ-LED array according to any of the preceding items, wherein
   the polarizing element has at least two different polarization properties and/or degrees of transmission depending on a wavelength of the radiation passing through the polarizing element.
   663. μ-LED arrangement according to any of the preceding items, characterised in that
   the μ-LED has a converter element with a converter material which, excited by excitation radiation emanating from the μ-LED, emits converted radiation, and in that excitation radiation incident on the polarizing element is polarized differently and/or absorbed to a different extent when passing through the polarizing element compared with converted radiation passing through.
   664. μ-LED arrangement according to any of the preceding items, where
   a three-dimensional structure of the polarizing element is at least partially incorporated in a semiconductor layer of the μ-LED adjacent to the light-emitting surface.
   665. μ-LED array according to any of the preceding items, which is a three-dimensional photonic structure and converter material is disposed in the three-dimensional photonic structure.
   666th method for producing a μ-LED arrangement having at least one μ-LED which emits radiation via a light-emitting surface, and having a polarization element which adjoins the light-emitting surface at least in sections and changes a polarization and/or an intensity of a radiation emanating from the μ-LED when the radiation passes through the polarization element, characterised in that
   an in particular three-dimensional photonic structure, in particular by two-photon lithography or glancing angle deposition, is applied to the light-emitting surface of the μ-LED as polarization element and/or the photonic structure is arranged in a semiconductor layer of the μ-LED adjoining the light-emitting surface.
   667. Method according to item 666, characterized in that the photonic structure is dimensioned as a function of the wavelength of the radiation emitted by the μ-LED
   668. Use of a μ-LED array according to any of the preceding items in a device for generating three-dimensional images.
   669. Use of a μ-LED array according to any of the preceding items, characterized in that the μ-LED arrangement is used after one of the objects 654 to 665 for computer-aided generation of three-dimensional images for an augmented reality application.
   670. Optoelectronic component, in particular comprising a μ-LED array
   at least one μ-LED which emits electromagnetic radiation via a light emission surface, and
   a photonic structure for beam-shaping of the electromagnetic radiation before it exits via the light emission surface, wherein the photonic structure shapes the electromagnetic radiation such that the electromagnetic radiation has a specific far field.
   671. Optoelectronic component according to item 670, characterized in that
   the photonic structure is a one-dimensional photonic structure, in particular a one-dimensional photonic crystal
   672. Optoelectronic component according to item 670 or 671, characterized in that
   the photonic structure is formed, in particular as a one-dimensional photonic crystal, in such a way that the radiated electromagnetic radiation is at least approximately collimated in a first spatial direction.
   673. Optoelectronic component according to item 672, characterized in that
   a collimating optical system is arranged downstream of the light exit surface, as viewed in the main radiation direction, the optical system being designed to collimate the electromagnetic radiation in a further, second spatial direction (R2), which is orthogonal to the first spatial direction.
   674. Optoelectronic component according to one of the preceding items, characterized in that
   the photonic structure, in particular formed as a one-dimensional photonic crystal, is designed in such a way that a main radiation direction of the electromagnetic radiation runs at an angle to the normal of the light exit surface, the angle being not equal to zero degrees.
   675. Optoelectronic component according to item 674, characterized in that
   the photonic structure formed as a one-dimensional photonic crystal is arranged in a layer below the light-emitting surface, wherein the one-dimensional photonic crystal comprises a periodically repeating sequence of two materials with different optical refractive indices extending in a first direction, wherein the materials have abutting interfaces, which are not orthogonal but inclined to the light-emitting surface.
   676. Optoelectronic component according to one of the preceding items, characterized in that
   the photonic structure is a two-dimensional photonic structure, in particular a two-dimensional photonic crystal
   677. Optoelectronic component according to item 676, characterized in that
   the two-dimensional photonic structure is designed such that the electromagnetic radiation produces a defined, in particular a discrete, pattern in the far field.
   678. Optoelectronic component according to any of the preceding items, characterized in that
   the photonic structure is arranged in a layer, in particular a semiconductor layer, below the light emission surface, and/or the photonic structure is formed in a semiconductor layer of the optoelectronic emitter unit, and/or
   the optoelectronic emitter unit comprises a converter material layer and the photonic structure is formed in the converter material layer or in a layer between the converter material layer and the light-emitting surface.
   679. Optoelectronic component according to one of the preceding items, characterized in that
   the photonic structure, in particular instead of a photonic crystal, is a quasi-periodic or deterministically aperiodic photonic structure.
   680. Surface topography recognition system, with:
   an optoelectronic device, comprising:
   at least one optoelectronic emitter unit which emits electromagnetic radiation via a light exit surface, and
   a photonic structure for beam-shaping of the electromagnetic radiation before it exits via the light emission surface, wherein the photonic structure shapes the electromagnetic radiation such that the electromagnetic radiation has a specific far field,
   wherein the photonic structure is a two-dimensional photonic structure, in particular a two-dimensional photonic crystal, and
   wherein the two-dimensional photonic structure is designed such that the electromagnetic radiation generates a defined, in particular a discrete, pattern in the far field, and
   wherein said surface topography detection system further comprises a detection unit, in particular with a camera, which is designed to detect the pattern in the far field
   681. surface topography recognition system according to item 680 characterized in that
   it comprises an analysis device adapted to detect a distortion of the pattern with respect to a predetermined reference pattern.
   682. Surface topography detection system according to item 681, characterized in that
   the analysis means is adapted to determine a shape and/or a structure of an object illuminated by the pattern as a function of the distortion detected.
   683. Scanner for scanning an object, comprising at least one optoelectronic component for one of the previous objects.
   684. Optical fibre device, comprising:
a light-emitting device comprising at least two light-emitting elements, in particular μ-LEDs, which emit light of two different colors;
an elongated first light guide to guide light of a first color and having an output part;
an elongated second light guide to guide light of a second color and having an output portion;
a first coupling element disposed adjacent to the first light guide and configured to reflect the light of the first color into the elongated first light guide;
a second coupling element disposed adjacent to the second light guide and configured to reflect the light of the second color into the elongated second light guide.
   685. Light guide device according to item 684, further comprising:
a third launching member mounted opposite the second launching member and adjacent the elongated second light guide, the third launching member being configured to reflect light of a third color into the elongated second light guide.
   686. Light guide device according to any of items 684 to 685, wherein the first coupling element is transparent to light of a color different from the first color.
   687. Light guide device according to object 685, the second coupling element being transparent to light of the third color.
   688. Light guide device according to any of the preceding items, wherein the light of different colors has an angle of incidence between 45° and 90° with respect to the surface of the respective light guide
   689. Light guide device according to any of the preceding items, where light of the third color has a wavelength greater than the light of the second color
   690. Light guide device according to any of the preceding items, wherein at least one of the first and second coupling elements is arranged on a sidewall of the respective elongated light guide.
   691. Light guide device according to any of the preceding items, wherein the first and second elongated light guides are substantially parallel to each other
   692. Light guide device according to any of the preceding items, further comprising spacer elements for spacing the first and second elongated light guides apart.
   693. Light guide device according to any of the preceding items, further comprising
a first decoupling element arranged on the output part of the elongated first light guide for decoupling light of the first color;
a second out-coupling element arranged on the output part of the elongated second light guide to couple out light of the second color.
   694. Light guide device according to item 693, further comprising:
a third out-coupling element arranged on the elongated second light guide opposite the second out-coupling element to couple out light of the third color.
   695. Light guide device according to one of the objects 693 to 694, wherein the first decoupling element is transparent to light of the second and/or the third color.
   696. Light guide device according to any of items 693 to 695, wherein the second output coupler is transparent to light of the third color or the third output coupler is transparent to light of the second color.
   697. Lighting device comprising a light-emitting optoelectronic element and an optical device for beam conversion of the electromagnetic radiation generated by the light-emitting optoelectronic element
   wherein said light-emitting optoelectronic element comprises a plurality of emission regions arranged in a matrix form; and wherein each emission region is assigned a main beam direction; and
   at least part of the emission zones are arranged in such a way that the centers of the emission regions lie on a curved surface.
   698. Lighting arrangement according to item 697, characterized in that the curved surface has a concave curvature.
   699. Lighting arrangement according to any of the preceding items, characterized in that the main directions of radiation of the emission regions are at an angle to each other.
   700. lighting arrangement according to any of the preceding items, characterized in that there are emission regions with a coinciding main beam direction, which are arranged on different planes at a different distance in the main beam direction from the optical device.
   701. lighting arrangement according to any of the preceding items, characterized in that the curved surface forms a spherical segment, the associated spherical center lying on the optical axis of the optical device,
   or in that the curved surface has the shape of at least a portion of a rotated conical section, in particular an ellipsoid, paraboloid or hyperboloid.
   702. Lighting arrangement according to any of the preceding items, characterized in that the emission regions whose centers are located on the curved surface, each form Lambert radiators.
   703. Lighting arrangement according to any of the preceding items, characterized in that at least one of the emission regions is the aperture of a primary optical element associated with a μ-LED or of a converter element associated with a μ-LED.
   704. Lighting arrangement according to any of the preceding items, characterized in that the emission regions whose centers lie on a curved surface are part of a monolithic pixelated optochip.
   705. Lighting arrangement according to item 704, in which the monolithic pixelated optochip has a plurality of μ-LEDs arranged in rows and columns.
   706. Lighting arrangement according to any of the preceding items, in which the emission regions constitute the surface of a coupling-out structure, and which comprises a photonic crystal or photonic structure for beam-shaping
   707. Lighting arrangement according to any of the preceding items characterized in that the emission regions, whose centers lie on a curved surface, are assigned to separate μ-LEDs arranged on a non-planar IC substrate.
   708. Lighting arrangement according to any of the preceding items, characterized in that the optical device comprises a system optic and between the system optic and the emission areas there is a curved collimating optical element or several nonplanarly arranged collimating optical elements.
   709. Lighting arrangement according to any of the preceding items, characterized in that the optical device comprises a system optic, which forms an imaging projection optic.
   710. Lighting arrangement according to any of the preceding items, in which the light-emitting optoelectronic element has a layer comprising a plurality of drive elements, in particular current sources for individual drive of each of the emission areas.
   711. Method of producing an illumination assembly comprising a light-emitting optoelectronic element and an optical device for beam conversion of the electromagnetic radiation generated by the light-emitting optoelectronic element; wherein
   the optoelectronic element comprises a plurality of emission regions arranged in matrix form;
   characterised in that
   at least part of the emission regions are arranged in such a way that the centers of the emission regions lie on a curved surface.
   712. Method according to item 711, characterized in that separate μ-LEDs are arranged on a non-planar IC substrate to create the emission regions.
   713. Method according to any of the preceding items, characterized in that at least one of the emission regions is formed by the aperture of a primary optic associated with a μ-LED or a converter element associated with a μ-LED
   714. Light guide arrangement comprising a μ-display and a projection optics, wherein the μ-display comprises a matrix with pixels for emission of visible light and wherein each pixel comprises several μ-LEDs with spectrally different light emission; and wherein each pixel is assigned a separate collimation optics preceding the projection optics,
   characterised in that
   the collimation optics are configured in such a way that enlarged and overlapping intermediate images of the μ-LEDs of the respective pixel are generated in the beam path in front of the projection optics.
   715. Light guide arrangement according to item 714, characterized in that the intermediate images of the μ-LEDs of the respective pixel generated by the collimation optics overlap each other over at least 70%, 80% or 90% of their intermediate image area.
   716. Light guide arrangement according to item 714 or 715, characterized in that the intermediate images μ-LEDs are virtual intermediate images.
   717. Light guide arrangement according to any of the preceding items, characterized in that the collimation optics is arranged between the μ-LEDs of a pixel and the projection optics.
   718. Light guide arrangement according to any of the preceding items, characterized in that the μ-LEDs of a pixel occupy not more than 30%, particularly preferably not more than 15% and most particularly preferably not more than 10% of the pixel area.
   719. Light guide arrangement according to any of the preceding items, characterized in that the μ-LEDs are configured as color converted μ-LEDs or as VCSELs or as edge-emitting laser diodes and optionally have illuminated optical waveguide end pieces.
   720. Light guide arrangement according to any of the preceding items, characterized in that the collimation optics are designed such that the total area of the overlapping intermediate images of the μ-LEDs of the respective pixel corresponds to at least 70%, 80% or 90% of the pixel area.
   721. Light guide arrangement according to any of the preceding items, characterized in that the collimation optics comprise a holographic optical element (HOE) and/or refractive optical element (ROE) and/or a diffractive optical element (DOE).
   722. Light guide arrangement according to any of the preceding items,
   characterised in that the radiation emitted by the projection optics is directed directly or indirectly onto a display.
   723. Light guide array according to any of the preceding items, in which each pixel comprises a μ-LED array according to any of the preceding items.
   724. Light guide arrangement according to any of the preceding items, in which each pixel comprises a μ-LED following one of the preceding objects.
   725. Light guide arrangement according to any of the preceding items, in which the μ-LEDs of a pixel are each formed by a horizontally arranged microrod according to any of the preceding items.
   726. Light guide arrangement according to any of the preceding items, in which the μ-LEDs of a pixel are each formed by at least one antenna slit structure according to any of the preceding items.
   727. Light guide arrangement according to any of the preceding items, in which the μ-LEDs of a pixel are each formed by a pair of emitting elements with a converter material arranged therebetween according to any of the preceding items.
   728. Light guide arrangement according to any of the preceding items, in which the μ-LEDs of a pixel each have a quantum well intermixing in an edge region of an active layer of the μ-LED, in particular a quantum well intermixing generated according to one of the items 112 to 192.
   729. Light guide arrangement according to any of the preceding items, in which the matrix comprises a light-shaping structure, in particular a photonic crystal, which is in particular arranged at least partially in a semiconductor material of the μ-LEDs of the pixels.
   730. Light guide arrangement according to any of the preceding items, further comprising a drive unit arranged in a substrate, in particular with current drivers or current sources according to any of the following items, wherein the μ-display is arranged on the substrate and the pixels are electrically connected to the current drivers or current sources.
   731. Light guide arrangement according to any of the preceding items, in which a plurality of pixels of the matrix each have a microlens arranged above the μ-LEDs.
   732. Light guide arrangement according to any of the preceding items, in which a plurality of pixels of the matrix has a reflection structure limiting the pixels, in particular with features according to any of the preceding items, which surrounds the μ-LED of the pixel.
   733. Light guide arrangement according to any of the preceding items, in which at least some of the pixels of the matrix have a redundant μ-LED.
   734. Light guide arrangement according to any of the preceding items, in which the matrix comprises a plurality of μ-LED base modules or a μ-display according to any of the items 484 to 536.
   735. Light guide array according to any of the preceding items according to any of the preceding items, in which the pixels of the array comprise an optoelectronic device or a μ-LED array according to any of the items 297 to 340 or a μ-LED according to any of the items 94 to 111.
   736. Use of a projection unit according to any of the preceding items to produce an image in an augmented reality display unit, a virtual reality display unit and/or on a head-up display.
   737. Light guide arrangement comprising:
at least one optoelectronic imaging device, in particular a μ-display for generating at least a first image and a second image, and
   at least one imaging optic adapted to project a first image of the first image at a first resolution onto a first region of a retina of a user and to project a second image of the second image at a second resolution onto another, second region of the retina, the first resolution being different from the second resolution.
   738. Light guide arrangement according to item 737, characterized in that
   the first area is closer to the center of the retina than the second area and that
   the first resolution is higher than the second resolution
   739. Light guide arrangement according to any of the preceding items, characterized in that
   the imaging optics comprises beam steering means which directs light rays of the first image onto the first area and light rays of the second image onto the second area.
   740. Light guide arrangement according to any of the preceding items, characterized in that
   the imaging optics comprise at least one beam-shaping device which focuses the light beams of the first image more strongly than the light beams of the second image.
   741. Light guide arrangement according to item 740, characterised in that
   the beam-shaping device comprises at least a first beam-shaping element and a second beam-shaping element, the first beam-shaping element focusing the light beams of the first image and the second beam-shaping element focusing the light beams of the second image.
   742. Light guide arrangement according to any of the preceding items, characterized in that
   the beam steering device for steering the beam has at least one movable and/or fixed mirror
   743. Light guide arrangement according to any of the preceding items, characterized in that
   the beam steering device for steering the beam comprises at least one and preferably at least two glass fibres.
   744. Light guide arrangement according to any of the preceding items, characterized in that
   the first and the second image are temporarily displayed one after the other, especially on the same imager.
   745. Light guide arrangement according to any of the preceding items, characterized in that
   the first and second images are displayed at least substantially simultaneously, in particular on at least two different display devices.
   746. Light guide arrangement according to any of the preceding items, characterized in that
   said at least one optoelectronic imager is formed by a μ-display with a plurality of μ-LED arrays, in particular according to any of the preceding items or a monolithic pixelated array.
   747. Light guide arrangement according to any of the preceding items, characterized in that
   the second area concentrically encloses the first area.
   748. Light guide arrangement according to any of the preceding items, in which the at least one optoelectronic imager comprises at least one matrix of pixels formed by a μ-LED arrangement according to any of the preceding items.
   749. Light guide device according to any of the preceding items, in which the at least one optoelectronic imager comprises a matrix of pixels formed by one or more μ-LED according to any of the preceding items.
   750. Light guide arrangement according to any of the preceding items, wherein the μ-LEDs of a pixel are each formed by a horizontally arranged microrod according to any of the preceding items, or wherein the μ-LEDs of a pixel are each formed by at least one antenna slot structure according to any of the preceding items.
   751. Light guide arrangement according to any of the preceding items, in which the μ-LEDs of a pixel are each formed by a pair of emitting elements with a converter material arranged therebetween according to any of the preceding items.
   752. Light guide arrangement according to any of the preceding items, in which the μ-LEDs of a pixel each have a quantum well intermixing in an edge region of an active layer of the μ-LED, in particular a quantum well intermixing generated according to any of the items 112 to 192.
   753. Light guide arrangement according to any of the preceding items, further comprising a drive circuit according to any of the subsequent items, which is implemented in a substrate from which the μ-display is arranged.
   754. Light guide arrangement according to any of the preceding items, in which the μ-display of the at least one optical imager comprises a matrix with a light-shaping structure, in particular a photonic crystal.
   755. Light guide arrangement according to item 754, in which the light-shaping structure is at least partially arranged in a semiconductor material of the μ-LEDs of the pixels of the at least one optical imager.
   756. Light guide arrangement according to any of the preceding items, in which the plurality of pixels of the at least one optical imager each have a microlens arranged above the μ-LEDs of each pixel.
   757. Light guide arrangement according to any of the preceding items, in which the plurality of pixels of the at least one optical imager has a reflection structure delimiting the pixels, in particular with features according to any of the preceding items, which surrounds the μ-LED of each pixel.
   758. Light guide arrangement according to any of the preceding items, in which a first and a second optical imaging device, each comprising a μ-display, formed with μ-LED arrays, optoelectronic devices or μ-LEDs according to any of the preceding items.
   759. Light guide arrangement according to any of the preceding items, in which at least some pixels of the matrix have a redundant μ-LED.
   760. Light guide arrangement according to any of the preceding items, wherein the matrix comprises a plurality of μ-LED base modules or a μ-display according to any of the items 484 to 536.
   761. Light guide arrangement according to any of the preceding items, in which the pixels of the array comprise an optoelectronic device or a μ-LED array according to any of the items 297 to 340 or a μ-LED according to any of the items 94 to 111.
   762. Use of a light guide arrangement according to any of the preceding items to produce an image in an augmented reality display unit, a virtual reality display unit and/or on a head-up display.
   763. Light guide arrangement comprising:
at least three μ-displays, each comprising a matrix of pixels arranged in rows and columns, each with at least one μ-LED, configured to emit a light of a main wavelength
a projection unit, which is arranged in a beam path of each μ-display and is designed to project images generated by the μ-displays in overlapping manner onto an image plane, the image plane being in particular a retina of an observer.
   764. Light guide arrangement according to item 763, characterized in that the projection unit comprises a lens or a mirror mounted in at least one axis for each μ-display.
   765. Light guide arrangement according to any of the preceding items, in which at least one glass fibre are used to direct the light of the displays onto the projection unit.
   766. Light guide arrangement according to any of the preceding items, further comprising a collimation optics, which is configured to generate enlarged and overlapping intermediate images of the μ-LEDs of the respective pixel in the beam path in front of the projection optics.
   767. Light guide arrangement according to any of the preceding items, wherein the matrix comprises a plurality of μ-LED base modules or a μ-display according to any of the items 484 to 536.
   768. Light guide array according to any of the preceding items, in which the pixels of the array comprise an optoelectronic device or a μ-LED array according to any of the items 297 to 340 or a μ-LED according to any of the items 94 to 111.
   769. Light guide arrangement according to any of the preceding items, in which the μ-LEDs of a pixel are each formed by a horizontally arranged microrod or by at least one antenna slot structure or by a pair of emitting elements with a converter material arranged therebetween according to any of the preceding items.
   770. Light guide arrangement according to any of the preceding items, further comprising a light-shaping structure on the pixels of each μ-display, wherein the light-shaping structure is a microlens or a photonic structure having features according to any of items 607 to 679.
   771. Light guide arrangement according to any of the preceding items, in which the μ-LEDs of a pixel comprise a reflective lateral surface, in particular according to any of the items 297 to 314.
   772. Light guide arrangement according to any of the preceding items, in which a drive circuit is provided in a substrate, which comprises at least one current driver circuit or a supply circuit, in particular according to any of the subsequent items for supplying at least one pixel, the μ-display being arranged on the substrate.
   773. Light guide arrangement with
a dichroic cube;
three μ-displays with a matrix of pixels arranged in rows and columns, one μ-display of which is arranged substantially parallel to one side of the dichroic cube;
a light-emitting surface on the dichroic cube.
   774. Light guide arrangement according to item 773, in which the μ-displays with the matrix of pixels arranged in rows and columns comprise an optoelectronic device or a μ-LED arrangement according to any of the items 297 to 340 or a μ-LED according to any of the items 94 to 111.
   775. Light guiding arrangement according to any of the preceding items, in which the pixels each comprise μ-LEDs formed by horizontally arranged microrods or by at least one antenna slot structure or by a pair of emitting elements with a converter material arranged therebetween according to any of the preceding items.
   776. Light guide arrangement according to any of the preceding items objects, further comprising a light-shaping structure on the pixels of each μ-display, wherein the light-shaping structure is a microlens or a photonic structure having features according to any of items 607 to 679.
   777. Light guide arrangement according to any of the preceding items, in which the μ-LEDs of a pixel comprise a reflective side surface, in particular according to any of the items 297 to 314.
   778. Light guide arrangement according to any of the preceding items, further comprising collimation optics, which are designed to produce enlarged and superimposed intermediate images of the respective μ-display in the beam path according to the dichroic cube.
   779. Light guide arrangement according to any of the preceding items, in which the light-shaping structure is at least partially arranged in a semiconductor material of the μ-LEDs of the pixels of the at least one optical imager.
   780. Light guide arrangement according to any of the preceding items, further comprising a drive unit arranged in a substrate, in particular with current drivers or current sources according to any of the subsequent items, wherein the μ-display is arranged on the substrate and the pixels are electrically connected to the current drivers or current sources.
   781. System, comprising:
   a light guide arrangement according to any of the preceding items, and
   a control unit for controlling the image generator or the imaging optics of the optoelectronic device, in particular in such a way that projected images of a frame of images, in particular comprising the first and second image, on the retina produce a coherent overall image.
   782. System according to item 781, in which fuse elements are electrically coupled to at least some of the μ-LEDs or pixels of the μ-displays, the at least some of the μ-LEDs or pixels forming redundant elements and the fuse elements activating the redundant elements or deactivating them when not required.
   783. System according to any of the preceding items, comprising supply drivers, or control units having characteristics based on any of the subsequent items.
   784. System according to any of the preceding items, in which the control unit is implemented in a substrate on which the μ-display is arranged and electrically connected to the control unit
   785. Light field display comprehensive:
   an optoelectronic device, in particular a μ-display for generating a raster image;
   an optics module, for direct retinal projection of the raster image into a user's eye;
   characterised in that
   said optoelectronic device comprises a first imaging unit generating a first raster field image and a second imaging unit generating a second raster field image;
   wherein the halftone image comprises the first halftone subimage and the second halftone subimage; and
   the optics module comprises an adjustment optic for the retinal projection of the second raster partial image onto the fovea centralis in the viewer's eye; and
   wherein the retinal projection of the second raster subimage has a higher resolution than that of the first raster subimage.
   786. Light field display according to item 785, characterized in that the adjusting optics is configured in such a way that the relative position of the retinal projection of the second raster partial image can be adjusted with respect to the retinal projection of the first raster partial image.
   787. Light field display according to any of the preceding items, characterized in that the retinal projection of the second raster partial image in the user eye has a smaller spatial extension than the retinal projection of the first raster partial image.
   788. Light field display according to any of the preceding items, characterized in that the adjusting optics comprises a switchable Bragg grating.
   789. Light field display according to any of the preceding items, characterized in that the adjusting optics comprises an adjustable Alvarez lens arrangement.
   790. Light field display according to item 789, characterized in that the adjusting optics comprises a Moire lens arrangement.
   791. Light field display according to any of the preceding items, characterized in that a collimation optic is arranged in the beam path of the first imaging unit and/or the second imaging unit.
   792. Light field display according to item 791, characterised in that the adjusting optics is at least partially arranged in the collimating optics.
   793. Light field display according to any of the preceding items, characterized in that the adjusting optics is arranged at least partially between the collimating optics and a waveguide.
   794. Light field display according to any of the preceding items, characterized in that the adjusting optics are arranged at least partially in a waveguide.
   795. Light field display according to any of the preceding items, characterized in that the first imaging unit and/or the second imaging unit comprises a μ-LED array having a plurality of μ-LEDs.
   796. Light field display according to any of the preceding items, characterized in that the first imaging unit and/or the second imaging unit comprises a matrix of a plurality of μ-LED base modules or a μ-display according to any of items 484 to 536.
   797. Light field display according to any of the preceding items, characterized in that the first imaging unit and/or the second imaging unit comprise a matrix of optoelectronic device arranged in rows and columns or μ-LED arrangements according to any of items 297 to 340 or μ-LEDs according to any of items 94 to 111.
   798. Light field display according to any of the preceding items, characterized in that the first imaging unit and/or the second imaging unit comprises a matrix with a light-forming structure, wherein the light-forming structure is a microlens or a photonic structure, in particular with features according to one of the items 607 to 679.
   799. Light field display according to item 798, in which the light-shaping structure is at least partially arranged in a semiconductor material of the μ-LEDs of the pixels of the at least one optical imager.
   800. Light field display according to any of the preceding items, further comprising a drive circuit according to any of the following items, which is implemented in a substrate on which the μ-display is arranged.
   801. Light field display according to any of the items 795 to 800, characterized in that the μ-LEDs comprise arrangements in which the μ-LEDs of a pixel comprise a reflective side surface, in particular according to any of the items 297 to 314.
   802. Light field display according to any of the items 795 to 801, characterized in that at least some of the μ-LEDs form arrays or μ-LEDs form redundant elements which are separated from adjacent μ-LED arrays or μ-LEDs by electrically insulating but optically crosstalking elements.
   803. Light field display according to any of the items 795 to 802, characterized in that the μ-LED arrangements are configured to be of different sizes depending on the color, or that a total area of the μ-LED arrangements or μ-LEDs of a pixel is smaller than the area of the pixel, in particular only 50% to 70% of the area of the pixel.
   804. Light field display according to any of the preceding items, characterized in that the light field display comprises a measuring device for determining the position of the fovea centralis.
   805. Light field display according to any of the preceding items, characterized in that the light field display comprises an eye movement detection device and a control device for dynamic tracking of the adjustment optics for the retinal projection of the second raster partial image onto the fovea centralis.
   806. Method of operating a light field display according to any of the preceding items, characterized in that a first raster partial image is imaged onto the retina of a user and a second raster partial image, which has a higher resolution than that of the first raster partial image, is imaged at least onto the fovea centralis in the user's eye.
   807. Pixel array, in particular for a display in polar coordinates, comprising
a plurality of pixel elements arranged from a starting point on an axis through the starting point in at least one line, wherein
the first plurality of pixel elements in plan view have a length and a variable width such that the width of the pixel elements substantially increases from the starting point.
   808. Pixel array according to item 807, in which the starting point forms a central point and the plurality of pixel elements are arranged symmetrically about the central point along the axis in a line.
   809. Pixel array according to any of the preceding items, in which any two adjacent pixel elements of the plurality of pixel elements have at least one of the following characteristics:
luminous areas of equal size, the distance between them increasing with increasing distance from the starting point;
luminous areas, the corresponding increasing width of the pixels becomes larger; or
a combination of these two possibilities.
   810. Pixel array according to any of the preceding items, in which the plurality of pixel elements have a variable length such that the length of the pixel elements increases with increasing distance from the starting point.
   811. Pixel array according to any of the preceding items, where two adjacent subpixels of the multiplicity of pixels have different colors.
   812. Pixel array according to any of the preceding items, in which the plurality of pixel elements have at least three different colors, the number of pixels of each color being different.
   813. Pixel array according to any of the preceding items, in which a first number of said plurality of pixel elements are arranged in a first line and a second number of said plurality of pixel elements are arranged in at least one second line, said first and second numbers of pixel elements having a different color in operation.
   814. Pixel array according to item 813, in which pixels in each of at least two lines have different colors in operation, the pixels being arranged such that the n-th pixel of a first line has a different color from an n-th pixel of the at least one second line.
   815. Pixel array according to item 813, in which at least three lines of pixel elements are arranged, the colors of which are different in operation.
   816. Pixel array according to any one of the items 813 to 815, in which the first line runs along a first axis and the at least one second line runs along a second axis different from the first axis through a common center point.
   817. Pixel array according to any of the preceding items, in which the first number of the plurality of pixel elements in the first row is different from the second number of the plurality of pixel elements in the at least one second row.
   818. Pixel array according to any of the preceding items, in which at least some pixels of the first and at least one second line have the same width and from an n-th pixel of the first line onwards the width is different from the width of the n-th pixel of the at least one second line.
   819. Pixel array according to any of the preceding items, in which the first line and the at least one second line comprise pixels of different colors, and are arranged along the axis and starting from the starting point.
   820. Pixel array according to any of the preceding items, where the line with the largest number of pixels preferably comprises pixel sin a green color.
   821. Pixel array according to any of the preceding items, where from an nth pixel of the first line onwards the width of adjacent pixels in the first line is smaller than that from the nth pixel onwards in the at least one second line.
   822. Pixel array according to any of the preceding items, where a number of pixels of the color green is greater than a number of pixels of the other colors.
   823. Pixel array according to any of the preceding items, in which the plurality of pixel elements in the at least one row are formed by a monolithically shaped pixelated array of μ-LEDs.
   824. Pixel array according to any of the preceding items, in which at least some of the plurality of pixel elements in the at least one row are formed by transferred μ-LEDs.
   825. Pixel array according to any of the preceding items, in which the μ-LEDs each comprise a horizontally aligned microrod contacted on a substrate, in particular according to any of the items 70 to 94.
   826. Pixel array according to any of the preceding items, in which the μ-LEDs each comprise a pair of spaced light-emitting elements with a converter material disposed therebetween, in particular according to any of items 31 to 69.
   827. pixel array according to any of the preceding items, in which the μ-LEDs have been manufactured by a process according to any of the preceding items, in particular any of items 1 to 347, or comprising μ-LEDs based on any of these items.
   828. Pixel array according to any of the preceding items objects, in which at least some μ-LEDs are assigned redundant μ-LEDs of the same color, at least one of the μ-LEDs and the redundant μ-LEDs being assigned a fuse element.
   829. Pixel array according to any of the preceding items, in which the μ-LEDs are composed of μ-LED modules, each module comprising at least one base module according to any of the preceding items, in particular items 484 to 505, the number of base modules per μ-LED module increasing towards the outside.
   830. Pixel array according to any of the preceding items, in which the pixel elements have a light-shaping structure, in particular a reflective structure, a microlens or a photonic crystal.
   831. Pixel array according to any of the preceding items, comprising a substrate on which the pixel array is disposed, the substrate having a supply circuit or driver circuit following one of the following objects.
   832. Pixel matrix comprising at least two pixel arrays according to any of the preceding items, in particular for a display in polar coordinates, in which the at least two pixel arrays have a common center point and enclose an angle substantially equal to 360° divided by twice the number of the at least two pixel arrays.
   833. Pixel matrix according to item 832, in which three pixel arrays are provided, each of which has a different color.
   834. Display arrangement in polar coordinates with an array or matrix of pixels according to any of the preceding items, further comprising
an optical system comprising at least one mirror movable about two axes, which is arranged in a main radiation direction of the pixel array or pixel matrix and is adapted to rotate radiated light from the pixels arranged in line about a point corresponding to the starting point.
   835. Method of operating a pixel array or a pixel matrix according to any of the preceding items, comprising the steps of;
creating a first light line with the multitude of pixel elements arranged in a line;
guiding the first light line to a destination;
creating a second light line;
rotating the second light line by a certain angle and a rotation point corresponding to the starting point of the pixel elements arranged in line;
guiding the second light line to the destination.
   836. Device for electronic control of a μ-LED pixel cell, in particular created with NMOS technology, comprising
a data signal line, a threshold line and a selection signal line;
a μ-LED electrically connected in series to a dual-gate transistor and together with it between a first and second potential terminal;
wherein the dual-gate transistor is arranged with its current conduction contacts between a terminal of the μ-LED and a potential terminal, and a first control gate of the dual-gate transistor is connected to the threshold line;
a selection hold circuit comprising a capacitor coupled to a second control gate of the dual-gate transistor and to a current conduction contact of the dual-gate transistor, and a control transistor having its control terminal connected to the selection signal line.
   837. Device according to item 836, the dual-gate transistor comprising a backgate transistor in which the backgate forms the first control gate.
   838. Device according to item 836 or 837, where the first control gate of the dual-gate transistor is configured to set a threshold voltage.
   839. Device according to any of the preceding items, in which the dual-gate transistor comprises a thin-film transistor with two opposite control gates.
   840. Device according to any of the preceding items, which is configured in such a way that a switching signal (PWM signal) is applied to the threshold line during operation.
   841. Device according to any of the preceding items, in which a first terminal of the μ-LED is connected to the first potential terminal; and in which the dual-gate transistor is arranged with its current conducting contacts between a second terminal of the μ-LED and the second potential terminal; and the capacitor is connected to the second control gate of the dual-gate transistor and to the second terminal of the optoelectronic component.
   842. Device according to any of the preceding items, in which the first terminal of the μ-LED is connected to a second current line contact of the dual-gate transistor and its second terminal is connected to the second potential terminal;
   the dual-gate transistor with its current line contacts is located between a first terminal of the μ-LED and the first potential terminal;
   the capacitor is connected to the second control gate of the dual-gate transistor as well as to the first potential terminal.
   843. Device according to any of the preceding items, in which
the first terminal of the μ-LED is connected to the first potential terminal;
the dual-gate transistor with its current line contacts is arranged between a second terminal of the μ-LED and the second potential terminal;
the capacitor is connected to the second control gate of the dual-gate transistor and to the second potential terminal.
   844. Device according to any of the preceding items, in which the selection hold circuit comprises another control transistor.
   845. Device according to item 844, in which the further control transistor is connected in parallel with the μ-LED and its control terminal is connected to the selection signal line.
   846. Device according to item 845, in the case of the dual-gate transistor is configured as a transistor with one gate providing the second control gate.
   847. Device according to any of the preceding items, in which the charge storage is connected to the second control gate of the dual-gate transistor and to the first potential terminal, and further comprising:
   a temperature compensation circuit with a negative feedback based on the detection of a forward voltage by the μ-LED, the temperature compensation circuit being configured on the output side to output a signal on the threshold line.
   848. Device according to item 847, in which the temperature compensation circuit comprises a control path arranged in parallel with the dual-gate transistor and having two paths connected in series.
   849. Device according to item 847, in which the threshold line is connected from a node between the two controlled paths provided by a third control transistor and a fourth control transistor, to the first control gate of the dual-gate transistor.
   850. Device according to item 849, in which the control terminal of the fourth control transistor is connected to the second potential terminal.
   851. Device according to any of items 847 to 850, in which the temperature compensation circuit comprises a second charge storage device connected to a control terminal of a control transistor providing one of the two paths and to the first potential terminal.
   852. Device according to item 851, in which a second data signal line for programming a negative feedback factor is provided, which is coupled to the second charge storage and the third control transistor.
   853. Device according to item 852, in which
   the coupling is established via a fifth control transistor controlled by a second selection signal line.
   854. Device according to any of the items 847 to 850, in which the temperature compensation circuit is connected to the second potential terminal via its third control transistor
   855. Device according to any of the items, in which
   a fifth control transistor is connected in parallel to the μ-LED, on which a switching signal (PWM signal) is applied to its control terminal during operation.
   856. Device according to any of the preceding items, in which the transistors are field-effect transistors using NMOS technology.
   857. Method of operating a device according to any of the preceding items, wherein an analogueue data drive signal for color control of the μ-LED is applied to the μ-LED via the selection hold circuit by means of the selection signal, and brightness control of the μ-LED is effected by means of a coupled pulse width modulation signal.
   858. Use of a device according to any of the items 836 to 856 for driving a μ-LED or m-LED array or optoelectronic device according to any of the preceding items.
   859. Driver circuit for driving a plurality of optoelectronic elements, comprising:
   a plurality of first memory cells, each comprising a set input,
   a reset input and an output,
   wherein each first memory cell at said output is triggered to a first state by a set signal at said set input and maintains said first state until reset to a second state at said reset input, and
   wherein the output of each first memory cell is configured to control a respective one of said optoelectronic elements.
   860. Driving circuit according to item 859, wherein each first memory cell provides a pulse width modulation signal, PWM signal at the output, and the PWM signal controls a switch configured to switch a current through the respective optoelectronic element on and off.
   861. Driver circuit according to any of the preceding items, wherein each first memory cell comprises two cross-coupled NOR gates or two cross-coupled NAND gates.
   862. Driver circuit according to any of the preceding items, each first memory cell comprising an NMOS transistor and a PMOS transistor connected in series, and an inverter having an input connected between the NMOS transistor and the PMOS transistor and an output connected to the gates of the NMOS and PMOS transistors.
   863. Driver circuit according to any of the preceding items, further comprising a plurality of counters each configured to activate a set signal when a data value is loaded into the respective counter and to activate a reset signal when the respective counter reaches the loaded data value.
   864. Driver circuit according to any of the preceding items, further comprising a common counter configured to generate a common dimming signal for the plurality of optoelectronic elements.
   865. Driver circuit according to any of the preceding items, further comprising a plurality of second memory cells, each second memory cell being coupled to a respective one of the first memory cells and configured to override an output signal of the respective first memory cell as necessary to leave the respective optoelectronic element turned off.
   866. Optoelectronic device, comprising:
   a plurality of optoelectronic elements, in particular μ-LEDs or μ-LED arrangements according to any of the preceding items, and a driving circuit for driving the plurality of optoelectronic elements according to one of the preceding items.
   867. Optoelectronic device according to item 866, where the optoelectronic elements are μ-LEDs.
   868. Method of operating an optoelectronic device according to item 866, comprising the following steps performed in the specified order during a frame:
switching off all optoelectronic elements;
controlling the optoelectronic elements that darken during framing by means of the second memory cells; and
controlling the current through the optoelectronic elements by means of the first memory cells.
   869. Method according to item 868, in which a common dimming of the optoelectronic elements is carried out before the current through the optoelectronic elements is controlled by means of the first memory cells.
   870. Control circuit for adjusting a brightness of at least one μ-LED, comprising a current driving element having
a control terminal, the first terminal of which is connected to a first potential;
a capacitor connected between the control terminal and the first potential and forming a capacitive voltage divider with a defined capacitance between the control terminal and the first terminal;
a control element adapted to apply a control signal to the control terminal during a first time period, on the basis of which a current flowing through the at least one μ-LED is adjustable during the first time period;
   wherein during a second time period subsequent to the first time period, a current flowing through the μ-LED is determined by a reduced control signal formed by the control signal during the first time period and the capacitive voltage divider; and
   the control element is arranged to provide a first or a second control signal during the first time period in order to operate the μ-LED at at least two different brightness levels.
   871. Control circuit according to item 870, in which the current driving element comprises a field effect transistor whose gate forms the control terminal and the defined capacitance is a gate-source capacitance predetermined by design.
   872. Control circuit according to any of the preceding items, in which the reduced control signal applied to the control terminal during the second time period is obtained from the control signal during the first time period and the ratio of a capacitance of the capacitor and the sum of the capacitance of the capacitor and the defined capacitance.
   873. Control circuit according to any of the preceding items, characterised in that
   the control is set to operate the first and second time periods at a repetition frequency of 60 Hz or more.
   874. Control circuit according to any of the preceding items, in which the control element comprises a control transistor at whose control terminal the first and second time periods are adjustable by means of a signal.
   875. Control circuit according to any of the preceding items, in which a ratio of the second time period to the first time period is in the range of 300:1 to 100:1, in particular in the range of 100:1
   876. Control circuit according to any of the preceding items, adapted to operate the μ-LED at a first, darker brightness level when a voltage of the first control signal is within a first voltage interval, and to operate the μ-LED at at least a second, brighter brightness level when a voltage of the second control signal is within a second voltage interval which is at least partially above the first voltage interval.
   877. Control circuit according to item 876, characterized in that the first voltage interval is in the range of 1.3 V to 4.5 V.
   878. Control circuit according to item 876 or 877, characterized in that the second voltage interval is in the range of 4.0 V to 10.0 V.
   879. Method for adjusting a brightness of at least one μ-LED which is connected to a current driver element having a control terminal, the first terminal of which is connected to a first potential and in which a capacitor is connected between the control terminal and the first potential so that it forms a capacitive voltage divider with a defined capacitance between the control terminal and the first terminal, comprising the steps
applying a control signal to the control terminal during a first period of time, thereby adjusting a current flowing through the at least one μ-LED during the first period of time; and
switching off the control signal during a second time period following the first time period, whereby the current flowing through the μ-LED is adjusted by a reduced control signal formed by the control signal during the first time period and the capacitive voltage divider.
   880. Method according to item 879, in which the reduced control signal applied to the control terminal during the second time period is obtained from the control signal during the first time period by the ratio of a capacity of the capacitor and the sum of the capacity of the capacitor and the defined capacity.
   881. Method based on one of the preceding articles, in which a ratio of the second period to the first period is in the range 300:1 to 100:1, in particular in the range 100:1.
   882. Method according to any of the preceding items, in which the μ-LED is operated at a first, darker brightness level if a voltage of the first control signal is within a first voltage interval, and the μ-LED is operated at at least a second, brighter brightness level if a voltage of the second control signal is within a second voltage interval which is at least partially above the first voltage interval.
   883. Method according to any of the preceding items, in which the control signal is derived from a digital control word having a number n of bits, the n bits corresponding to the second control signal and the least significant m bits corresponding to the first control signal.
   884. Use of a control circuit according to any of the preceding items for driving a μ-LED, μ-LED array or μ-LED module according to any of the preceding items. O
   885. Supply circuit, comprising:
an error correction detector having a reference signal input, an error signal input and a correction signal output;
a controllable current source with current output and a control signal terminal, the control signal terminal being connected to the correction signal output to form a control loop for the controllable current source, the current source configured to provide a current at the current output in dependence on a signal at the control signal terminal;
a substitute source with one output configured to provide a substitute signal;
a switching device which is configured to supply, depending on a switching signal, either a signal derived from the current at the current output or the substitute signal to the error signal input with additional disconnection of the current output of the current source
   886. Supply circuit according to item 885, in which the substitute signal is substantially the same as the signal derived from the current signal.
   887. Supply circuit according to any of the preceding items, in which the variable current source comprises a current mirror having a switchable output branch connected to the current output.
   888. Supply circuit according to item 887, in which the output branch comprises an output transistor whose control terminal is connected via the switching device to a fixed potential for opening the transistor in dependence on a switching signal.
   889. Supply circuit according to any of the preceding items, in which the adjustable current source comprises an input branch to which a reference current can be supplied and which has a node which is connected to the reference signal input of the error correction detector.
   890. Supply circuit according to any of the preceding items, in which the controllable current source comprises a current mirror, the control signal terminal being connected to the control terminal of an output transistor of the current mirror.
   891. Supply circuit according to any of the preceding items, in which the error correction detector comprises a differential amplifier, the two branches of which are connected together to a supply potential via a current mirror.
   892. Supply circuit according to item 891, in which the two branches of the differential amplifier each comprise an input transistor, which have different geometric parameters.
   893. Supply circuit according to any of the preceding items, in which the replacement source comprises an element coupled to the output for generating a voltage so that the replacement signal is substantially equal to the signal derived from the current signal.
   894. Supply circuit according to any of the preceding items, in which the replacement source comprises a series connection of a current-generating element and a voltage-generating element, the output being disposed between the two elements.
   895. Supply circuit according to any of the preceding items, in which the replacement source comprises a transistor whose control terminal is connected to the control terminal of the current mirror transistor of the current source.
   896. Supply circuit according to any of the preceding items, in which the switching device comprises one or more transmission gates.
   897. Supply circuit according to any of the preceding items, comprising a reference current mirror configured to supply a current defined on the input side to the error correction detector and to the current source on the output side.
   898. Method for powering a μ-LED comprising:
detecting of a supply current by the μ-LED;
comparing the supply current with a reference signal and deriving a correction signal from the comparison;
changing the supply current in response to the correction signal to control the supply current to a setpoint;
switching off a supply current through the μ-LED and simultaneous supply of a substitute signal for the comparison step.
   899. Method according to item 898, in which the substitute signal is substantially equivalent to a supply current through the μ-LED or a signal derived therefrom.
   900. Use of a supply circuit according to any of the preceding items for supplying a μ-LED or μ-LED device, in particular according to any of the preceding items, which is operated by a signal which pulse-width modulates the power supply.
   901. Arrangement with
the supply circuit implemented in a substrate according to any of the preceding items; and
a μ-display according to any of the preceding items or comprising a matrix of pixels arranged in rows and columns and having at least one μ-Led or μ-LED array according to any of the preceding items.
   902. Display matrix control circuit comprising a plurality of light emitting devices arranged in rows and columns, comprising:
a row selection input for a row selection signal and a column data input for a data signal;
a ramp signal input for a ramp signal having a level between a first value and a second value and a trigger input for a trigger signal;
a column data buffer configured to buffer the data signal in response to the row select signal;
a pulse generator coupled to the column data buffer and said ramp signal input and configured to provide a buffered output signal to control the on/off ratio of at least one of said plurality of light emitting devices in response to the trigger signal, the data signal and the ramp signal.
   903. Control circuit according to item 902, wherein the pulse generator comprises
comparator means for comparing the buffered data signal with the ramp signal; and
an output buffer coupled to an output of the comparator device and the trigger input.
   904. Control circuit according to object 903, wherein the output buffer comprises a flip-flop, in particular an RS flip-flop with its input coupled to the output of the comparator device and the trigger input respectively.
   950. Control circuit according to any of items 902 to 904, wherein the column data buffer comprises a capacitor for storing the data signal and a switch disposed between the capacitor and the column data input.
   906. Control circuit according to any one of items 902 to 905, the comparator device comprising a power control input coupled to the trigger input to adjust its power consumption based on the trigger signal.
   907. Control circuit according to any one of items 902 to 906, wherein the comparator device is coupled to the output buffer to control its power consumption based on an output state of the output buffer.
   908. Control circuit according to one of the items 902 to 907, wherein the comparator is coupled with its inverting input to the data column buffer and with its non-inverting input to the ramp signal input.
   909. Control circuit according to any of the items 902 to 907, further comprising:
a ramp generator for supplying the ramp signal to the ramp signal input, the ramp generator being configured to generate a signal varying between an initial value and a final value in response to the trigger signal.
   910. Method of controlling the illuminance of a light emitting device in a matrix display having a plurality of light emitting devices arranged in addressable rows and columns, the method comprising
providing a data signal for a selected row and at least one light emitting device;
supplying a trigger signal;
converting a level of the data signal to a pulse with respect to a trigger signal; and
controlling the on/off ratio of the light emitting device with the pulse.
   911. Method according to item 910, wherein the step of converting a level of the data signal comprises:
generating a ramp signal between a first value and a second value;
comparing the data signal with the ramp signal to generate a comparison signal;
generating of a pulse based on the trigger signal and a change in the comparison signal.
   912 Method according to item 910, wherein the generation of a pulse comprises setting a level of an output signal to a first value in response to a trigger signal and resetting the level of the output signal to a second value in response to the change in the comparison signal.
   913. Method according to items 911 or 912, where the ramp signal is generated in response to the trigger signal.
   914. Method according to any of the items 910 to 913, wherein delivery of a data signal comprises pre-buffering the data signal, in particular pre-buffering the data signal in a memory device.
   915. Use of the control circuit according to any of the preceding items in a μ-display or for driving a μ-LED, μ-LED array or an array of μ-LEDS, in particular according to any of the items 94 to 111 or 297 to 340 and 484 to 536.
   916. Device for electronically driving a plurality of μ-LEDs, comprising
a first and at least one second branch each having a μ-LED connected therein and an electronic fuse arranged in series with the μ-LED, the first and the at least one second branch being connected to a potential terminal on one side;
a driver circuit having a data signal input, a selection signal input and a driver output connected to the other side of the first and at least one second branch;
an imprinting component associated with the at least one second branch, which is designed to generate a current flow triggering the electronic fuse arranged in series.
   917. Device according to item 916, in which
the μ-LED is configured according to any of the subsequent or preceding items; and/or
the μ-LED comprises a light-shaping or light-guiding element on its surface according to any of the subsequent or preceding items; and/or
the μ-LED of each branch comprises a common electrically conductive, in particular transparent, contact layer
   918. Device according to any of the preceding items, characterised in that
   the imprinting component comprises an imprinting transistor, which is electrically connected with its current line contacts in parallel with the μ-LED to which the imprinting transistor is assigned and whose control contact is connected to an imprinting signal line.
   919. Device according to any of the preceding items, characterised in that
   the imprinting component comprises an imprinting diode having one terminal connected to a second terminal of the μ-LED with which the imprinting diode is associated and the other terminal of which is connected to an imprinting signal line.
   920. Device according to any of the preceding items, characterised in that
   first terminals of the μ-LED are connected to a reference potential terminal;
   a first transistor with its current conduction contacts is arranged between a common terminal of the fuses of the μ-LED and a supply potential terminal;
   a charge storage device is electrically connected to a control contact of the first transistor and to a first current conduction contact of the first transistor.
   921. Device according to any of the preceding items, characterised in that
   second terminals of the μ-LED are connected to a supply potential terminal;
   a first current conducting contact of a first transistor is connected to a reference potential terminal and a second current conducting contact of the first transistor is connected to a common terminal of the electrical fuses;
   a capacitor is connected to a control contact of the first transistor and to the first current conduction contact of the first transistor.
   922. Device according to any of the preceding items, characterised in that
   second terminals of the μ-LED are connected to the fuse assigned to the μ-LED;
   a first current conducting contact of a first transistor is connected to a reference potential terminal and a second current conducting contact of the first transistor is connected to first terminals of the μ-LED;
   a capacitor is connected to a control contact of the first transistor and to the first current conduction contact of the first transistor.
   923. Device according to any of the preceding items, characterised in that
   first terminals of the μ-LED are connected to a reference potential terminal;
   a first transistor with its current line contacts is arranged between a common terminal of the fuses of the μ-LED and a supply potential terminal;
   the charge storage device is electrically connected to a control contact of the first transistor and to a second current conduction contact of the first transistor.
   924. Device according to any of the preceding items, characterised in that
   first terminals of the μ-LED are connected to a first reference potential terminal;
   a first transistor with its current conduction contacts is arranged between a common terminal of the fuses of the μ-LEDs and a supply potential terminal;
   a capacitor is electrically connected to a control contact of the first transistor and to a second current conduction contact of the first transistor, a first terminal of the imprinting diode being connected to a second terminal of the μ-LED and a second terminal of the imprinting diode being connected to the imprinting signal line.
   925. Device according to any of the preceding items, characterised in that
   first terminals of the μ-LEDs are connected to a reference potential terminal;
   a first transistor with its current line contacts is arranged between a common terminal of the fuses of the μ-LEDs and a supply potential terminal;
   a capacitor is electrically connected to a control contact of the first transistor and to a second current conduction contact of the first transistor, a second terminal of the imprinting diode being connected to the second terminal of the μ-LED and a first terminal of the imprinting diode being connected to the imprinting signal line.
   926. Device current line contact, characterised in that
   the driver circuit comprises the first transistor, a second transistor and the charge storage, the selection signal line being applied to a control contact of the second transistor and the data signal input being applied to a current conduction contact of the second transistor, and a first or a second current conduction contact of the first transistor providing the driver output which is connected to the μ-LEDs of the first branch and a second branch to provide a power supply.
   927. μ-display or μ-display module comprising a plurality of the devices according to any of the preceding items, in which pixel cells of the μ-display are each electrically connected along a row and/or along a column on a common imprinting signal line, and
   each pixel cell of a column is electrically connected to the supply potential terminal by means of a common supply line to a switching transistor arranged on a common carrier outside the μ-display.
   928. μ-display or μ-display module according to item 927, in which the μ-LEDs connected in the first and at least one second branch at least comprise
features according to any of the preceding items, in particular items 94 to 111 or 297 to 340;
features according to any of the items 484 to 536;
a photonic structure according to any of items 607 to 679.
   929. Method for electronically configuring a plurality of μ-LEDs according to any of the preceding items articles, comprising the steps of:
testing a function of the μ-LED of the first and second branch;
if there is no error in the μ-LED in the first and second branch:
applying of an imprinting signal to the electronic imprinting component;
imprinting into the second branch a current flow which triggers the fuse connected in series to the μ-LED of the second branch.
   930. Use of a device according to any of the preceding items in a display arrangement according to any of the preceding or subsequent items.
   931. Display arrangement comprising
   an IC substrate component with monolithic integrated circuits and with IC substrate contacts arranged as a matrix; and a monolithic pixelated optochip comprising a semiconductor layer sequence with a first semiconductor layer having a first doping and a second semiconductor layer having a second doping, wherein the polarity of the charge carriers in the first semiconductor layer differs from that of the second semiconductor layer and the semiconductor layer sequence defines a stacking direction; and
   wherein μ-LEDs arranged as a matrix are present in the monolithic pixelated optochip; and
   wherein each μ-LED has a μ-LED rear side facing the IC substrate component and a first light source contact which adjoins the first semiconductor layer in a contacting manner and is electrically conductively connected to a respective one of the IC substrate contacts;
   characterised in that
   the projection area of the first light source contact on the μ-LED rear surface is at most half the area of the μ-LED rear surface; and
   the first light source contact in a lateral direction perpendicular to the stacking direction is surrounded by an absorber on the rear side.
   932. Display arrangement according to item 931, characterized in that the first semiconductor layer and the second semiconductor layer comprise a μ- or n-conductivity lower than 104 Sm⁻¹, preferably lower than 3*103 Sm⁻¹, more preferably lower than 103 Sm⁻¹.
   933. display arrangement according to any of the preceding items, characterized in that the layer thickness of the first semiconductor layer in the stacking direction is at most ten times and preferably at most five times the maximum diagonal of the first light source contact in the lateral direction.
   934. Display arrangement according to any of the preceding items, characterized in that the pixel size of the μ-LED is <10 μm and preferably <5 μm and particularly preferably <2 μm.
   935. Display arrangement according to one of the preceding items, characterized in that the projection area of the first light source contact on the μ-LED back is at most 25% and preferably at most 10% of the area of the μ-LED back.
   936. Display arrangement according to any of the preceding items, characterized in that the rear absorber extends in the stacking direction in the semiconductor layer sequence.
   937. Display arrangement according to any of the preceding items, characterized in that a second light source contact made of a transparent material is arranged in the stacking direction above the second semiconductor layer for each μ-LED, which is electrically conductively connected to a transparent contact layer on the front side of the monolithic pixelated optochip.
   938. Display arrangement according to item 937, characterized in that the second light source contact is formed by the transparent contact layer itself.
   939. display arrangement according to any of the preceding items, characterized in that the second light source contact is adjacent to the transparent contact layer and the second light source contact of adjacent μ-LEDs are separated from each other by an absorber on the front side in a lateral direction perpendicular to the stacking direction.
   940. Display arrangement according to any of the preceding items, characterized in that the front absorber extends against the stacking direction up to and preferably into the second semiconductor layer.
   941. Display arrangement according to any of the preceding items, characterized in that, with respect to the stacking direction, an optochip contact element whose cross-sectional area is larger than that of the first light source contact is adjacent below the first light source contact.
   942. Display arrangement according to any of the preceding items, further comprising:
   a light-shaping structure, in particular a microlens or a photonic crystal, which is arranged on the monolithic pixelated optochip and directs light emitted by the monolithic pixelated Optochip.
   943. Display arrangement according to any of the preceding items, further comprising a light-converting element on the surface of the monolithic pixelated Optochip.
   944. Display arrangement according to any of the preceding items, wherein, in the case of two adjacent μ-LEDs, one μ-LED is configured as a redundant element to the other μ-LED, to which a fuse element in the IC substrate component is assigned, which fuse element is designed to replace the other μ-LED by the redundant element if the other μ-LED fails or to disconnect the redundant element from a power supply if the other μ-LED is functional.
   945. Method of manufacturing a display device,
   wherein an IC substrate component with monolithic integrated circuits and with IC substrate contacts arranged as a matrix and a monolithic pixelated optochip are electrically conductively connected; and
   a semiconductor layer sequence with a first semiconductor layer having a first doping and a second semiconductor layer having a second doping is grown in the monolithic pixelated optochip, the polarity of the charge carriers in the first semiconductor layer differing from that of the second semiconductor layer and the half-conductor layer sequence defining a stacking direction; and
   wherein μ-LEDs arranged in the monolithic pixelated optochip as a matrix are applied, each μ-LED comprising a μ-LED rear side facing the IC substrate component and a first light source contact which adjoins the first semiconductor layer in a contacting manner and is electrically conductively connected to a respective one of the IC substrate contacts;
   characterised in that
   the first light source contact is applied with a size such that its projection area perpendicular to the stacking direction occupies at most half the area of the μ-LED backside; and
   the first light source contact in a lateral direction perpendicular to the stacking direction is surrounded by an absorber on the rear side.
   946. Display arrangement with a μ-display comprising a plurality of pixels arranged in rows and columns, comprising:
a first substrate structure with μ-LEDs arranged therein or applied thereto, the edge length of which is less than 50 μm, in particular less than 20 μm, and which form the pixel structure arranged in rows and columns, wherein
   the μ-LEDs are individually controllable; and
   a plurality of contacts are arranged on the surface of the first substrate structure opposite to a light emission direction;
a second substrate structure comprising on a surface a plurality of contacts corresponding to the contacts of the first substrate structure and having a plurality of digital circuits for addressing the μ-LEDs;
   wherein the first and second substrate structures are connected together and the plurality of contacts are electrically connected to the corresponding contacts, and
   wherein the first substrate structure is formed with a first material system and the second substrate structure is formed with a second material system different therefrom.
   947. Display arrangement according to item 946, in which at least some contacts of the plurality of contacts have an edge length of less than 10 μm or an area of less than 20 μm².
   948. Display arrangement according to any of the preceding items, in which the μ-LEDs are formed with an edge length of less than 10 μm and/or have a distance to adjacent μ-LED of less than 7 μm.
   949. Display arrangement according to any of the preceding items, comprising an adhesive or other form-fitting element partially disposed between and holding together the first and second substrate structures
   950. Display arrangement according to any of the preceding items, wherein the μ-display comprises a plurality of pixels arranged in rows and columns, at least some of the μ-LEDs or μ-LED arrays or optoelectronic devices according to any of the preceding items, or elements according to any of the preceding items.
   951. Display arrangement according to any of the preceding items, in which the second substrate structure comprises at least some of the circuitry according to any of the preceding items.
   952. Display arrangement according to any of the preceding items, further comprising at least one light guiding arrangement having features according to any of the preceding items.
   953. Display arrangement according to any of the preceding items, in which the first substrate structure is separated from the second substrate structure by an intermediate structure through which at least contact lines extend which connect the contacts of the first substrate structure with contacts of the second substrate structure.
   954. Display arrangement according to any of the preceding items, in which the first system of materials comprises at least one of the following compounds GaN, GaP, GaInP, InAlP, GaAlP or GaAlInP, GaAs, AlGaAs, and the second material system comprises at least one of the following material systems: monocrystalline, polycrystalline, amorphous silicon, indium-gallium-zinc oxide, GaN or GaAs.
   955. Display arrangement according to any of the preceding items, in which in the first carrier structure comprises a plurality of switchable current sources, each of which is connected to a pixel for the supply thereof, and whose switch inputs are coupled to the contacts for supplying switching signals from the digital circuits.
   956. Display arrangement according to item 955, in which the switchable current sources are arranged in a material system, which is different from the material system used for the μ-LEDs or from the first material system.
   957. Display arrangement according to any of the preceding items, in which the plurality of digital circuits of the second substrate structure are adapted to generate a PWM-like signal from a clock signal and a data word for each pixel.
   958. Display arrangement according to item 957, in which the plurality of digital circuits comprises a number of serially connected shift registers, the respective length of which corresponds to the data word for one pixel, each shift register being connected to a buffer for intermediate storage.
   959. Display arrangement according to any of the preceding items, wherein the plurality of digital circuits comprise a multiplexer electrically coupled to a demultiplexer in the first substrate structure for driving multiple optoelectronic devices.
   960. Arrangement of a plurality of light-emitting diodes, wherein the extent of each light-emitting diode along at least one spatial direction is respectively less than or equal to 70 micrometers.
   961. Arrangement according to item 960, where a common carrier is provided for the light-emitting diodes.
   962. Arrangement according to item 961, wherein the support comprises transparent material or is made of transparent material.
   963. Arrangement according to item 961 or 962, whereby the carrier is flexible.
   964. Arrangement according to any of the preceding items, in which electronic components of an operating circuit or drive for the light-emitting diodes are arranged on the carrier.
   965. Arrangement according to any of the preceding items, at least one sensor being arranged on the carrier.
   966. Arrangement according to any of the preceding items, the support being an integral part of a component, in particular a vehicle component.
   967. Arrangement according to any of the preceding items, wherein optics are provided for at least one light-emitting diode of the arrangement.
   968. Arrangement according to item 967, with the optics arranged on the carrier.
   969. Device with at least one arrangement according to any of the preceding items.
   970. Device according to item 969, configured as a rear lamp of a motor vehicle.
   971. Device according to item 970, wherein the at least one array of light-emitting diodes of the rear lamp has a pixel density of at least 50 PPI and a pixel pitch of at most 0.5 mm.
   972. Device according to item 970 or 971, wherein the rear lamp is configured as a combined tail light and stop light and has a tail light area and a stop light area.
   973. Device according to item 972, wherein the stop light region and the tail light region each comprise at least one array of light emitting diodes, and wherein the pixel density of the array of light emitting diodes in the stop light region is higher than the pixel density of the array of light emitting diodes in the tail light region.
   974. Device according to item 969, configured as a raised stop lamp of a motor vehicle.
   975. Device according to item 974, wherein the at least one array of light emitting diodes of the high level stop lamp has a pixel density of at least 10 PPI and a pixel pitch of at most 2.5 mm.
   976. Device according to item 974 or 975, where the raised stop lamp is embedded in a rear window pane of a motor vehicle.
   977. Device according to item 976, wherein the raised stop lamp is transparent.
   978. Device according to item 974 or 975, where the raised stop lamp is located in the roof area of the bodywork of a motor vehicle.
   979. Device according to item 969, said apparatus comprising a display disposed on the outside of a motor vehicle and comprising at least one array of light emitting diodes according to one of items 960 to 968.
   980. Device according to item 979, wherein the pixel density of the array of light emitting diodes of the display is at least 100 PPI and the pixel pitch is at most 0.25 mm.
   981. Device according to item 979 or 980, wherein the display is integrated into the vehicle body.
   982. Device according to item 981, wherein the shape of the display is adapted to a contour of the vehicle body.
   983. Device according to any of the preceding items, the apparatus comprising display drive means for enabling control of display operation by a user or computer program.
   984. Device according to item 983, wherein the apparatus comprises at least one sensor or detector and is designed to control the display of the display as a function of measurement signals from the at least one sensor or detector.
   985. Device according to any of the preceding items, wherein the apparatus is configured to exchange communication signals.
   986. Device according to item 969, wherein the device comprises a headliner of a vehicle.
   987. Device according to item 969, wherein the device comprises a center console of a vehicle.
   988. Device according to item 969, wherein the device comprises a display on an A, or B, or C, or D pillar of a vehicle.
   989. Device according to item 969, wherein the device comprises a status display of a vehicle.
   990. Device according to item 969, configured as a sterilisation device or as a component of a sterilisation device
   991. Device according to any of the preceding items configured as a vehicle component.
   992. Device according to any of the preceding items configured as a component of textiles.
   993. Display device comprising
a carrier with a front and a back,
a self-supporting display segment applied to the front of the support, wherein
the display segment comprises a substrate with an electrically conductive connection layer and an electrically insulating layer and at least one μ-LED,
the at least one μ-LED is arranged on the connection layer and is electrically conductively connected to the connection layer,
the electrically insulating layer is arranged on one of the sides of the connecting layer remote from the at least one μ-LED and between the support and the connecting layer,
the electrically insulating layer is formed as a single continuous layer,
the support comprises at least one opening extending from the front to the rear,
the display segment can be electrically contacted from the rear of the support by means of an electrical line extending through the opening.
   994. Display device according to item 993, where the display segment is flexible.
   995. Display device according to item 993 or 994, wherein the front side of the carrier comprises a concave and/or convex curvature where the display segment is applied.
   996. Display device according to any of the preceding items, wherein the electrical conduction is formed by a tab of the substrate and the tab is inserted through the opening.
   997. Display device according to item 996, where
part of the tab on the back protrudes from the opening,
an active or passive electronic component is located on the part of the tab protruding at the rear and electrically connected to the substrate.
   998. Display device according to any of the preceding items, wherein
the substrate of the display segment at least partially covers the opening,
the electrically insulating layer in the area of the opening is removed,
the electrical cable is routed to the connection layer in the area of the opening and electrically connected to the connection layer.
   999. Display device according to any of the preceding items, wherein
the display segment comprises a plurality of optoelectronic components, each μ-LED being associated with a pixel of the display segment,
the display device comprises a plurality of display segments applied to the front of the support.
   1000. Method of manufacturing a display device comprising the steps:
   A) providing a carrier with a front, a back and at least one opening extending from the front to the back;
   B) providing of a self-supporting display segment comprising:
a substrate with an electrically conductive connection layer and a single cohesive, electrically insulating layer;
at least one optoelectronic component, wherein
the optoelectronic component is arranged on the connection layer and is electrically conductively connected to the connection layer,
the electrically insulating layer is arranged on a side of the connecting layer facing away from the component;
   C) applying of the display segment on the front of the carrier;
   D) forming an electrical line extending through the opening so that the display segment can be electrically contacted from the back of the carrier via the electrical line.
   1001. Method according to item 1000, wherein the substrate comprises a tab which is inserted through the opening in step D) and which forms the electrical lead.
   1002. Method according to item 1001, wherein
the display segment is arranged in step C) in such a way that the electrically insulating layer at least partially covers the opening,
in step D) the electrically insulating layer in the area of the opening is removed and then the electrical line in the area of the opening is led to the connecting layer and electrically connected to the connecting layer.
   1003. Active layer in an arrangement, μ-LED, semiconductor layer stack, optoelectronic device or array according to any of the preceding items, characterized by one or more quantum wells configured for light emission.

The description with the help of the exemplary embodiments does not limit the various embodiments shown in the examples to these. Rather, the disclosure depicts several aspects, which can be combined with each other and also with each other. Aspects that relate to processes, for example, can thus also be combined with aspects where light extraction is the main focus. This is also made clear by the various objects shown above.

The invention thus comprises any features and also any combination of features, including in particular any combination of features in the subject-matter and claims, even if that feature or combination is not explicitly specified in the exemplary embodiments.

1. Arrangement comprising:
at least one light-emitting device, in particular at least one μ-LED, which comprises:
an electrically conductive structure comprising an upper major surface and a lower major surface separated from the upper major surface by a distance;
a cavity in the electrically conductive structure and which has a width and length;
a semiconductor layer stack along the first main direction arranged in the cavity and extending at least over the upper main surface, the semiconductor layer stack having
an active layer;
a first electrical contact;
a second electrical contact;
the length of the cavity is based essentially on n/2 of a wavelength of light to be emitted during operation, where n is a natural number;
and/or
at least one μ-LED or optoelectronic semiconductor device comprising a three-dimensional light-emitting heterostructure having a first conductive semiconductor layer, an active layer and a second conductive semiconductor layer; wherein
the light-emitting heterostructure comprises aluminium gallium arsenide and/or aluminium gallium indium phosphide and/or aluminium gallium indium phosphide arsenide; and
the light-emitting heterostructure is formed three-dimensionally by growing on a mold layer comprising a {110} oriented side surface and selectively epitaxially deposited on a gallium arsenide (111) B epitaxial substrate, optionally a flat top surface {111} may be envisaged;
and/or
at least two μ-LEDs, in particular an array of μ-LEDs, wherein a respective μ-LED between an n-doped layer and a p-doped layer forms an active layer suitable for light emission; and
between two adjacent formed μ-LEDs material of the layer sequence from the n-doped side and from the p-doped side up to or in cladding layers or up to or at least partially into the active layer is interrupted or removed in such a way that material transitions with a maximum thickness dC are formed, whereby electrical and/or optical conductivities in the material transition are reduced;
and/or
a μ-LED module comprising:
at least one layer stack providing a base module, comprising a first layer formed on a carrier, in particular a growth carrier, on which an active layer and on which a second layer is formed, a first contact being connected to a surface region of the second layer facing away from the carrier, a second contact being connected to a surface region of the first layer facing away from the carrier;
optionally the base module comprising a full area target matrix formed on a first carrier comprising rows and columns of μ-LEDs, occupyable locations;
one or more μ-LED modules comprise at least two components, the size of which corresponds to the vacant positions; and the μ-LED modules are positioned and electrically connected on the first carrier in the target matrix in such a way that a number of components remain unoccupied in the target matrix, at least some of which are each positioned and electrically connected to at least one sensor element;
and/or
a μ-LED array characterized in that the μ-LED array comprises pairs of polyhedron or prism shaped coated volumes of material with an active layer disposed therein; and
for emission of a certain color a converter material matched to this color is formed between the material volumes of a pair;
where
the active layer of the μ-LED has at least one quantum well, and a central region in the active layer is laterally surrounded by a second region in the active layer whose band gap is greater than that of the central region, and a dopant is introduced into the second region which produces quantum well intermixing in the at least one quantum well of the active layer located in the second region;
and/or where
the μ-LED is part of an array comprising at least the μ-LED and the μ-LED is vertically generated and a first contact of the light emitting body is connected to a first contact region on one side of a substrate;
on the same side of the substrate, a second contact of the light-emitting body facing away from the substrate is connected to a second contact region by means of a transparent contact layer and a first metal mirror layer; and
a reflector structure surrounding the light emitting body, a second metal mirror layer being attached to the reflector structure;
and/or where
at least the μ-LED is arranged on a flat carrier substrate of a pixel element and is configured to emit light transversely to a carrier substrate plane in a direction away from the carrier substrate;
the μ-LED has an electrical contact on its upper side facing away from the carrier substrate;
the pixel element has an at least partially electrically conductive flat contacting layer on the upper side of the at least one μ-LED, which is electrically connected to the electrical contact of the at least one μ-LED;
the contacting layer is at least partially transparent to the light emitted by the at least one μ-LED, and a conductor track is provided on the contacting layer, which is electrically connected to the contacting layer over its entire surface; and
wherein the electrical conductivity of the conductive path is greater than an electrical conductivity of the contacting layer;
and/or where
the at least one μ-LED is fixed to one side of a substrate;
has a first electrical contact on a side facing away from the substrate, which is electrically connected by means of a mirror coating to an electrical control contact on the surface of the substrate; and
the mirror coating at least partially covers the substrate surface facing the at least one μ-LED;
and/or where
the μ-LED is a sub-pixel of a pixel element for generating a pixel of a display; and the pixel element is formed by at least two sub-pixels of the same color emission, in particular by the μ-LED and a further μ-LED;
a subpixel separating element is provided between two adjacent subpixels of the same pixel element; and
the subpixel separating element is configured to separate the respective subpixels with respect to electrical control of the respective subpixels and is configured to optically couple with respect to the light emitted by the respective subpixels;
and/or where
the device comprises an array of pixels with a substrate for the array-like arrangement of pixels on the substrate and for electrical contacting of the pixels;
the substrate provides a set of primary contacts for at least one pixel, the set of primary contacts of the pixel being provided for electrical contacting of a group of subpixels, the substrate further comprising a set of spare contacts for the at least one pixel;
wherein the primary contacts of the pixel are populated with the group of subpixels;
the group of subpixels comprises an erroneous, disabled subpixel; and
wherein one spare contact of said set of spare contacts of said pixel is equipped with a spare subpixel as a replacement for said faulty, disabled subpixel;
in which for improving the transfer of the light emitting device, the at least one or two μ-LEDs, the μ-LED array or the μ-LED module
a flat carrier substrate at least two receiving elements are provided, which are configured to
releasably holding the μ-LED, μ-LED array, μ-LED module or light-emitting device between the at least two receiving elements in such a way that the μ-LED, μ-LED array, μ-LED module or light-emitting device can be moved out perpendicularly to a carrier structure plane with a defined minimum force; and
at least one receiving element of the at least two receiving elements is configured to simultaneously hold and/or support a second, adjacently arranged μ-LED;
and/or
μ-LEDs can be generated on a carrier substrate with a first density;
a first transfer step is performed by means of a first transfer stamp, which transfers the μ-LEDs to an intermediate carrier with the first density;
a second transfer step is carried out by means of a second transfer stamp which transfers the μ-LEDs from the intermediate carrier to a target substrate with a second density smaller by a factor n than the first density, which provides a common array area for a respective one of the arrays, in particular for all three colors, the size of the intermediate carrier being equal to or larger than that of the second transfer stamp and the size of the second transfer stamp being equal to or smaller by a factor k than the array area;
and in which the arrangement
comprises a pixel array, in particular for a display in polar coordinates, which:
has a plurality of light emitting devices, μ-LEDs, μ-LED arrays or μ-LED modules
which are arranged in at least one line starting from a starting point on an axis through the starting point, wherein
the plurality of pixel elements have a height and a variable width such that the width of the pixel elements substantially increases from the starting point;
and the arrangement further
comprises a plurality of pixel structure arranged in rows and columns, which comprise
a first substrate structure with μ-LEDs, μ-LED arrangements, μ-LED modules or light-emitting devices arranged therein or applied thereto, the edge length of which is less than 50 μm, in particular less than 20 μm, and which form the pixel structure arranged in rows and columns, wherein
the μ-LEDs, μ-LED arrays, μ-LED modules or light emitting devices are individually controllable; and
a plurality of contacts are arranged on the surface of the first substrate structure opposite to a light emission direction;
a second substrate structure comprising on a surface a plurality of contacts corresponding to the contacts of the first substrate structure and a plurality of digital circuits for addressing the optoelectronic components;
wherein the first and second substrate structures are connected together and the plurality of contacts are electrically connected to the corresponding contacts, and
wherein the first substrate structure is formed with a first material system and the second substrate structure is formed with a second material system, in particular different therefrom;
and the second substrate structure comprising:
a device for electronically driving a μ-LED pixel cell, in particular created with NMOS technology, comprising:
a data signal line, a threshold line and a selection signal line;
wherein contacting the second substrate structure to the μ-LED, μ-LED array, μ-LED module or light emitting device results in it being electrically connected in series to a dual-gate transistor and together therewith between first and second potential terminals, the dual-gate transistor being arranged with its current conduction contacts between one terminal of the μ-LED, μ-LED array, μ-LED module or light emitting device and a potential terminal, and a first control gate of the dual-gate transistor being connected to the threshold line; and
a selection latch circuit with a capacitor coupled to a second control gate of the dual-gate transistor and to a current conduction contact of the dual-gate transistor, and with a control transistor having its control terminal connected to the selection signal line
and/or
a supply circuit comprising
an error correction detector having a reference signal input, an error signal input and a correction signal output;
a controllable current source with current output and a control signal terminal, the control signal terminal being connected to the correction signal output to form a control loop for the controllable current source, the current source being configured to provide a current at the current output in dependence on a signal at the control signal terminal;
a backup source with an output designed to provide a backup signal; and
a switching device which is configured, depending on a switching signal (VPWM), to supply either a signal derived from the current at the current output or the substitute signal to the fault signal input with additional disconnection of the current output of the current source;
and/or
a driver circuit for driving a plurality of μ-LEDs, μ-LED arrays, μ-LED modules or light emitting devices, comprising
a plurality of first memory cells, each comprising a set input, a reset input and an output
each first memory cell at the output is triggered to a first state by a set signal at the set input and holds the first state until it is reset to a second state at the reset input; and
the output of each first memory cell is configured to drive a respective one of the μ-LEDs, μ-LED arrays, μ-LED modules or light emitting devices;
and/or the arrangement is configured:
having an IC substrate component with monolithic integrated circuits and with IC substrate contacts arranged as a matrix; and
having a monolithic pixelated optochip comprising a semiconductor layer sequence with a first semiconductor layer having a first doping and a second semiconductor layer having a second doping, the polarity of the charge carriers in the first semiconductor layer differing from that of the second semiconductor layer and the semiconductor layer sequence defining a stacking direction;
wherein μ-LEDs arranged as a matrix are present in the monolithic pixelated optochip; and
wherein each μ-LED has a μ-LED rear side facing the IC substrate component and a first light source contact which adjoins the first semiconductor layer in a contacting manner and is electrically conductively connected to a respective one of the IC substrate contacts;
characterized in that the projection area of the first light source contact on the μ-LED backside is at most half the area of the μ-LED backside; and
the first light source contact in a lateral direction perpendicular to the stacking direction is surrounded by an absorber on the rear side
and the arrangement comprises a plurality of μ-LEDs, μ-LED arrays, μ-LED modules or light emitting devices, wherein the extension of each μ-LED, μ-LED array, μ-LED module or light emitting device along at least one spatial direction is less than or equal to 70 micrometers, respectively.
